(19) United States
(12) Patent Application Publication
(10) Pub. No.: US 2026/0314168 A1
(43) Pub. Date: Oct. 8, 2026

(54) ORGANIC ELECTROLUMINESCENT DEVICE AND DISPLAY APPARATUS THEREOF

(71) Applicant: BEIJING SUMMER SPROUT TECHNOLOGY CO., LTD., Beijing (CN)

(72) Inventors: Zhen Wang, Beijing (CN); Hongbo Li, Beijing (CN); Zheng Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/633,192

(22) Filed: Mar. 30, 2026

(30) Foreign Application Priority Data
Mar. 30, 2025 (CN) 202510386028.1
Mar. 13, 2026 (CN) 202610310858.0

(51) Int. Cl. H10K 50/12; H10K 85/30; H10K 85/60; H10K 101/00; H10K 101/20

(52) U.S. Cl. CPC H10K 50/121; H10K 85/342; H10K 85/622; H10K 85/626; H10K 85/636; H10K 85/654; H10K 85/656; H10K 85/6572; H10K 85/6574; H10K 85/6576; H10K 85/658; H10K 2101/20; H10K 2101/90

(57) ABSTRACT

The present disclosure relates to an organic electronic device, for example, an organic light-emitting device. More particularly, the present disclosure relates to a light-emitting device comprising a phosphorescence sensitizer and a fluorescent material. The phosphorescence sensitizer is a metal complex, and the metal is Ir. The phosphorescence sensitizer comprises a structure represented by a fragment of Formula 1. The fluorescent material comprises at least one B atom. The organic electroluminescent device disclosed in the present disclosure has better device performance. In particular, the organic electroluminescent device has apparent effects and advantages in terms of CE and EQE and has a relatively low voltage, thereby better improving the overall performance of the electroluminescent device. Further provided are a material combination comprising the phosphorescence sensitizer and the fluorescent material and a display assembly. These electroluminescent devices, material combinations or display assemblies have relatively good application prospects.

### CROSS-REFERENCE TO RELATED APPLICATION(S)

This application claims priority to Chinese Patent Application No. 202510386028.1 filed on Mar. 30, 2025, and Chinese Patent Application No. 202610310858.0 filed on Mar. 13, 2026, the disclosure of which is incorporated herein by reference in its entirety.

### TECHNICAL FIELD

The present disclosure relates to an organic electronic device, for example, an organic light-emitting device. More particularly, the present disclosure relates to a light-emitting device comprising a phosphorescence sensitizer and a fluorescent material and a display assembly comprising the light-emitting device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This invention has laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20230134165A1 has disclosed a composition. The composition comprises a phosphorescent compound represented by Formula (1) and Compound F with a fused heterocyclic skeleton where an atom a selected from at least one of a nitrogen atom and a boron atom is comprised within the ring,

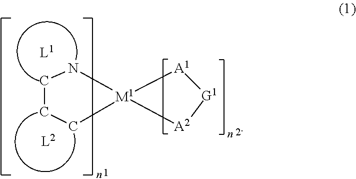

US20230134165A1 has further disclosed a light-emitting element containing the composition, for example, a light-emitting device comprising a combination of

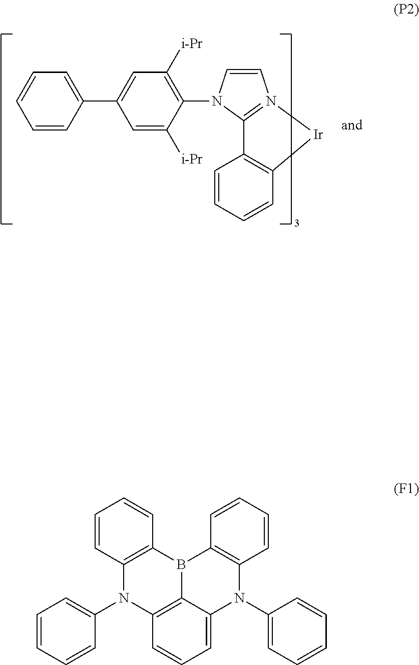

and a light-emitting device comprising a combination of

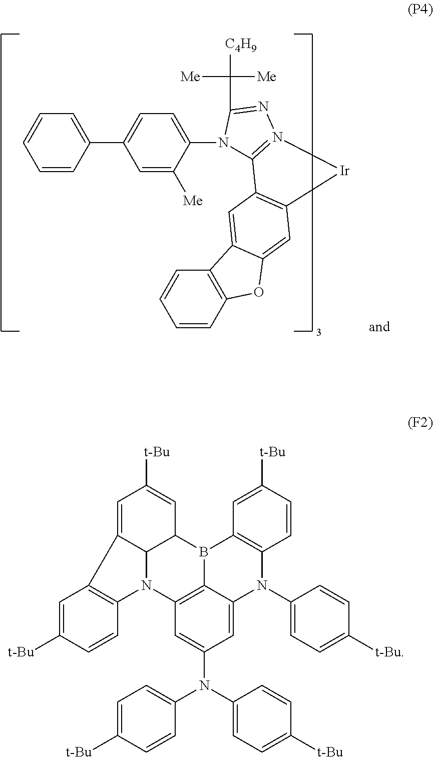

US20230134165A1 has neither disclosed nor taught a composition and its corresponding light-emitting device and performance when Formula (1) contains at most two five-membered rings coordinated to the metal.

US20240206208A1 has disclosed an organic electroluminescent device comprising a cathode, an anode and an emissive layer. The emissive layer includes a first compound S1, a second compound A1 and a third compound H1. The first compound S1, which is a phosphorescence sensitizer, can transfer energy to the second compound A1 as an acceptor. At least one of the following conditions needs to be satisfied: (1) the third compound comprises a B atom; (2) the first compound comprises a metal M and a ligand La, and La comprises a fused ring fragment F joined to the metal M through an anionic bond. US20240206208A1 has further disclosed device data that the phosphorescent compound

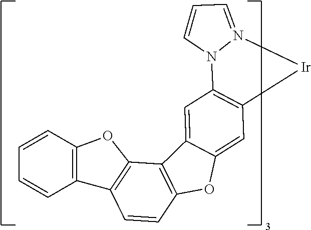

sensitizes the acceptor

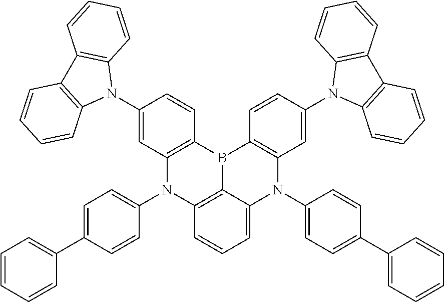 [SMILES: c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cccc3c54)cc2)cc1]

to emit blue light. US20240206208A1 has not specifically disclosed a composition and its corresponding light-emitting device and performance when at most two five-membered rings coordinated to the metal are contained.

The present disclosure provides a new organic electroluminescent device comprising a phosphorescence sensitizer and a fluorescent material. The phosphorescence sensitizer contains at most two five-membered rings with specific structures coordinated to the metal. The organic electroluminescent device has better device performance.

### SUMMARY

The present disclosure aims to provide a new organic electroluminescent device comprising a phosphorescence sensitizer and a fluorescent material. The phosphorescence sensitizer contains a five-membered ring structure represented by a particular structure of Formula 1. The fluorescent material comprises at least one B atom. The organic electroluminescent device has better device performance.

According to an embodiment of the present disclosure, an organic electroluminescent device is disclosed, which comprises:
an anode,
a cathode, and
an emissive layer disposed between the anode and the cathode, wherein the emissive layer comprises at least a phosphorescence sensitizer and a fluorescent material;
the fluorescent material comprises at least one B atom;
the phosphorescence sensitizer is a metal complex, and the metal is Ir;
the phosphorescence sensitizer comprises a structure represented by a fragment of Formula 1;

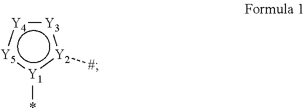

wherein “#” represents a position where the metal Ir is joined, and “*” represents a position where another fragment in the metal complex is joined;
Y₁ and Y₂ are each independently selected from C or N;
Y₃ to Y₅ are each independently selected from CR_{y}, N, NR_{y1}, O or Se;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
the phosphorescence sensitizer comprises at most two fragments of Formula 1.

According to another embodiment of the present disclosure, a material combination is further disclosed, which comprises the phosphorescence sensitizer having the structure of Formula 1 in the preceding embodiment and the fluorescent material in the preceding embodiment.

According to another embodiment of the present disclosure, a display assembly is further disclosed, which comprises the material combination comprising the phosphorescence sensitizer having the structure of Formula 1 in the preceding embodiment and the fluorescent material in the preceding embodiment, or the organic electroluminescent device in the preceding embodiment.

The organic electroluminescent device disclosed in the present disclosure has better device performance. In particular, the organic electroluminescent device has apparent effects and advantages in terms of CE and EQE and has a relatively low voltage, thereby better improving the overall performance of the electroluminescent device.

### BRIEF DESCRIPTION OF DRAWINGS

FIG. 1 is a schematic diagram of an organic light-emitting device that may comprise a phosphorescence sensitizer, a fluorescent material and a device thereof disclosed herein.

FIG. 2 is another schematic diagram of an organic light-emitting device that may comprise a phosphorescence sensitizer, a fluorescent material and a device thereof disclosed herein.

### DETAILED DESCRIPTION

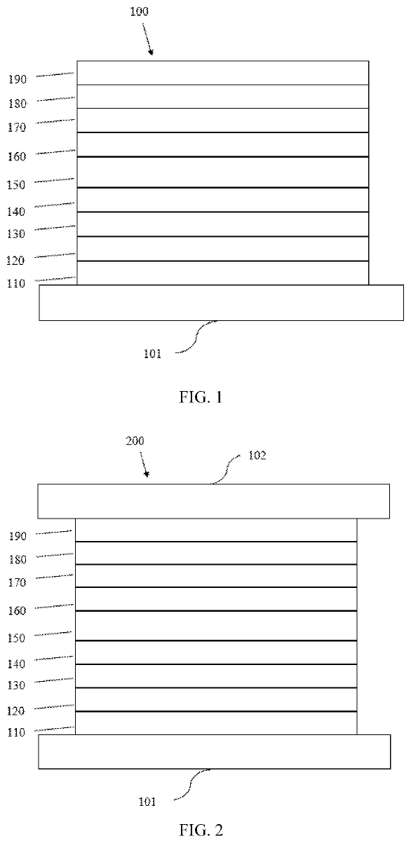

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of the alkyl group include methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, 1-methylpentyl group, 2-methylpentyl group, 1-pentylhexyl group, 1-butylpentyl group, 1-heptyloctyl group, and 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein contemplates cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or aromatic group or aromatic ring—as used herein includes noncondensed and condensed systems. Aryl or aromatic group or aromatic ring may be those having 6 to 30 carbon atoms, preferably those having 6 to 20 carbon atoms, and more preferably those having 6 to 12 carbon atoms. Examples of aryl groups (aromatic rings) include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl group, p-cyanobenzyl group, m-cyanobenzyl group, o-cyanobenzyl group, 1-phenylethyl group, 2-phenylethyl group, 1-phenylisopropyl group, and 2-phenylisopropyl group. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogues with two or more nitrogens in the ring system. One of ordinary skill in the art can readily envision other nitrogen analogs of the aza-derivatives described above, and all such analogs are intended to be encompassed by the terms as set forth herein.

Herein, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned Herein, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned Herein, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned Herein, adjacent substituents in the compounds cannot be joined to form a ring unless otherwise explicitly defined, for example, adjacent substituents can be optionally joined to form a ring. In the compounds mentioned Herein, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fused cyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

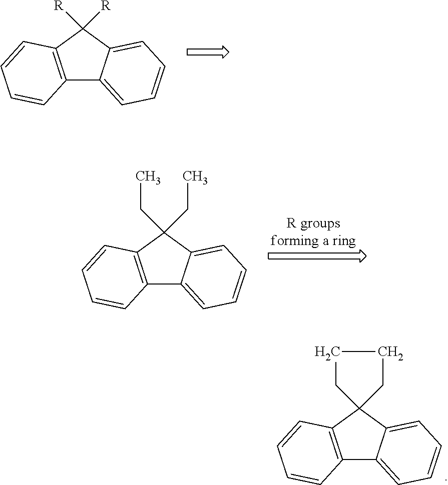

The expression that adjacent substituents can be optionally joined to form a ring is also intended to mean that two substituents bonded to carbon atoms which are directly bonded to each other are joined to each other via a chemical bond to form a ring, which can be exemplified by the following formula:

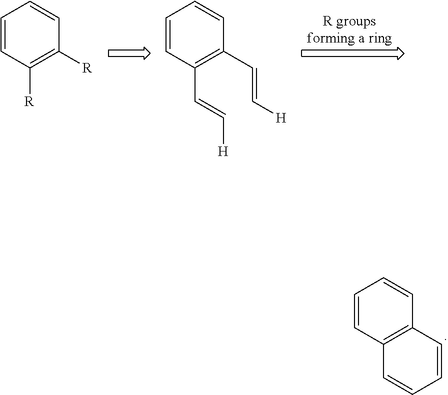

The expression that adjacent substituents can be optionally joined to form a ring is also intended to mean that two substituents bonded to further distant carbon atoms are joined to each other via a chemical bond to form a ring, which can be exemplified by the following formula:

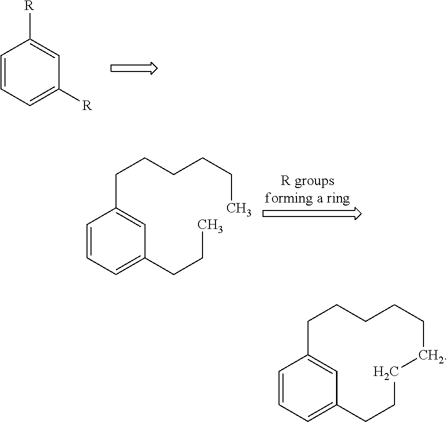

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

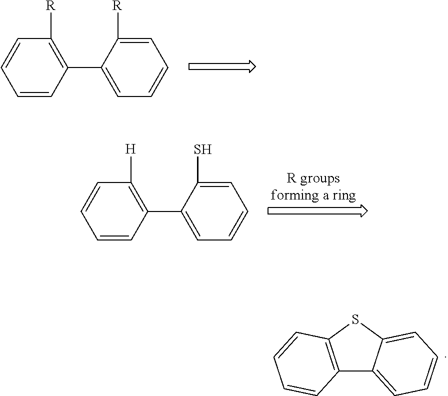

According to an embodiment of the present disclosure, an organic electroluminescent device is disclosed, which comprises:
an anode,
a cathode, and
an emissive layer disposed between the anode and the cathode, wherein the emissive layer comprises at least a phosphorescence sensitizer and a fluorescent material;
the fluorescent material comprises at least one B atom;
the phosphorescence sensitizer is a metal complex, and the metal is Ir;
the phosphorescence sensitizer comprises a structure represented by a fragment of Formula 1;

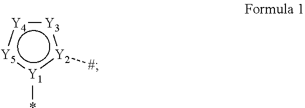

wherein “#” represents a position where the metal Ir is joined, and “*” represents a position where another fragment in the metal complex is joined;
Y₁ and Y₂ are each independently selected from C or N;
Y₃ to Y₅ are each independently selected from CR_{y}, N, NR_{y1}, O or Se;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
the phosphorescence sensitizer comprises at most two fragments of Formula 1.

Herein, the expression that “adjacent substituents R_{y} and R_{y1} can be optionally joined to form a ring” is intended to mean that any one or more of groups of adjacent substituents, such as two substituents R_{y}, two substituents R_{y1}, and substituents R_{y} and R_{y1}, can be joined to form a ring. Obviously, it is also possible that none of these substituents are joined to form a ring.

According to an embodiment of the present disclosure, the fragment of Formula 1 comprised in the phosphorescence sensitizer is, at each occurrence identically or differently, selected from any structure of Formula 1-1 to Formula 1-10:

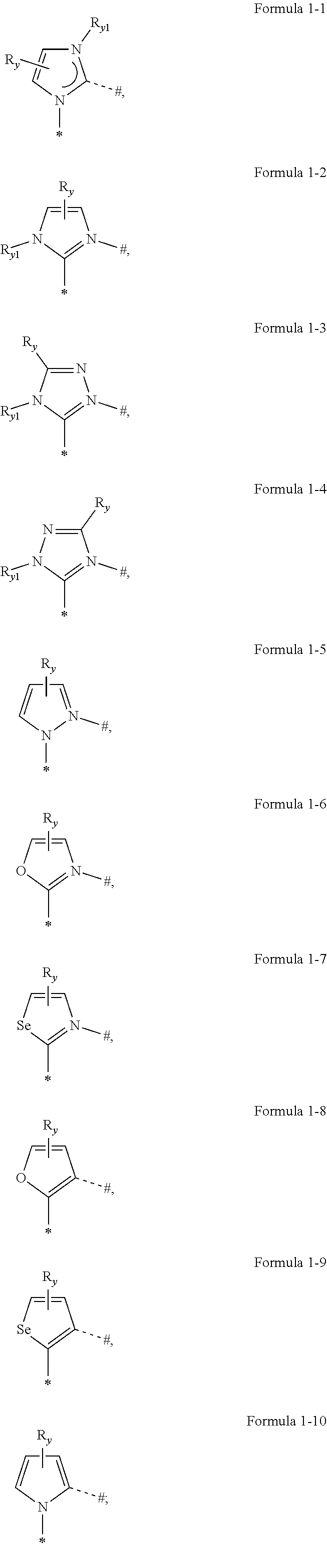

wherein “#” represents a position where the metal Ir is joined, and “*” represents a position where another fragment in the metal complex is joined;
R_{y} represents, at each occurrence identically or differently, mono-substitution, multiple substitutions or non-substitution;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{y} and R_{y1} can be optionally joined to form a ring.

According to an embodiment of the present disclosure, the phosphorescence sensitizer comprises a structure represented by a fragment of Formula 1-2.

According to an embodiment of the present disclosure, the phosphorescence sensitizer comprises a structure represented by a fragment of Formula 2:

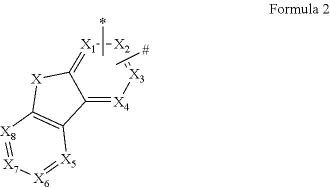

wherein “#” represents a position where the metal Ir is joined, and “*” represents a position where another fragment in the metal complex is joined;
X is, at each occurrence identically or differently, selected from the group consisting of O, S, Se, NR₁, CR₁R₁, SiR₁R₁ and GeR₁R₁;
X₁ to X₄ are each independently selected from C, CRₓ or N, one of X₁ to X₄ is selected from C and joined to the metal Ir, and one of X₁ to X₄ is selected from C and joined to another fragment;
X₅ to X₈ are each independently selected from CRₓ or N;
Rₓ and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ and R₁ can be optionally joined to form a ring.

Herein, the expression that “adjacent substituents Rₓ and R₁ can be optionally joined to form a ring” is intended to mean that any one or more of groups of adjacent substituents, such as two substituents Rₓ, two substituents R₁, and substituents Rₓ and R₁, can be joined to form a ring. Obviously, it is also possible that none of these substituents are joined to form a ring.

According to an embodiment of the present disclosure, the phosphorescence sensitizer has a structure of Formula Ir(Lₐ)ₘ(L_{b})ₙ(L_{c})_{q}, wherein the ligands Lₐ, L_{b} and L_{c} are a first ligand, a second ligand and a third ligand coordinated to the metal Ir, respectively, and the ligands Lₐ, L_{b} and L_{c} can be optionally joined to form a multidentate ligand;
L_{c} is a monoanionic bidentate ligand;
m is selected from 1, 2 or 3, n is selected from 0, 1 or 2, q is selected from 0, 1 or 2, and m+n+q is equal to 3; when m is greater than or equal to 2, multiple Lₐ are the same or different; when n is equal to 2, two L_{b} are the same or different; when q is equal to 2, two L_{c} are the same or different;
the ligands Lₐ and L_{b} satisfy any one of the following conditions:
condition one: the ligand Lₐ comprises the structure represented by the fragment of Formula 2, the ligand L_{b} comprises the structure represented by the fragment of Formula 1-2, and n is selected from 1 or 2;
condition two: the ligand Lₐ comprises both the structure represented by the fragment of Formula 1-2 and the structure represented by the fragment of Formula 2, the fragment of Formula 1-2 is joined to the fragment of Formula 2 through “*”, and m is selected from 1 or 2;

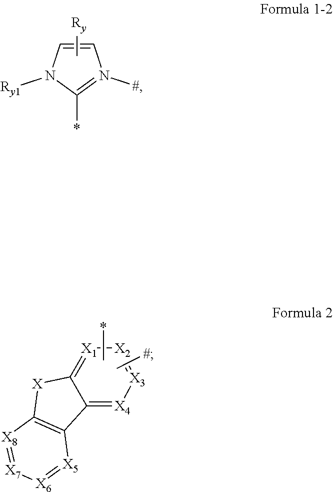

wherein “#” represents a position where the metal Ir is joined, and “*” represents a position where another fragment in the metal complex is joined;
R_{y} represents, at each occurrence identically or differently, mono-substitution, di-substitution or non-substitution;
X is, at each occurrence identically or differently, selected from the group consisting of O, S, Se, NR₁, CR₁R₁, SiR₁R₁ and GeR₁R₁;
X₁ to X₄ are each independently selected from C, CRₓ or N, one of X₁ to X₄ is selected from C and joined to the metal Ir, and one of X₁ to X₄ is selected from C and joined to another fragment;
X₅ to X₈ are each independently selected from CRₓ or N;
Rₓ, R_{y1}, R_{y} and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₓ and R₁ can be optionally joined to form a ring; and
adjacent substituents R_{y} and R_{y1} can be optionally joined to form a ring.

According to an embodiment of the present disclosure, the phosphorescence sensitizer has a general formula of Ir(Lₐ)ₘ(L_{b})₃₋ₘ and has a structure represented by Formula 3:

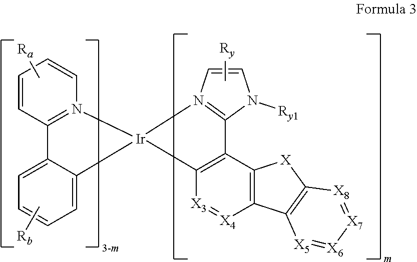

wherein,
m is selected from 1 or 2; when m is selected from 1, two L_{b} are the same or different; when m is selected from 2, two Lₐ are the same or different;
R_{y} represents, at each occurrence identically or differently, mono-substitution, di-substitution or non-substitution; Rₐ and R_{b} represent, at each occurrence identically or differently, mono-substitution, multiple substitutions or non-substitution;
X is, at each occurrence identically or differently, selected from the group consisting of O, S, Se, NR₁, CR₁R₁ and SiR₁R₁; when two R₁ are present at the same time, the two R₁ are the same or different;
X₃ to X₈ are, at each occurrence identically or differently, selected from CRₓ or N;
R₁, Rₓ, R_{y}, R_{y1}, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, Rₓ, R_{y}, R_{y1}, Rₐ and R_{b} can be optionally joined to form a ring.

Herein, the expression that adjacent substituents R₁, Rₓ, R_{y}, R_{y1}, Rₐ and R_{b} can be optionally joined to form a ring is intended to mean that any one or more of groups of adjacent substituents, such as two substituents R₁, two substituents Rₓ, two substituents R_{y}, substituents R_{y} and Rₓ, substituents R_{y} and R_{y1}, substituents R₁ and Rₓ, substituents R₁ and R_{y}, substituents R₁ and R_{y1}, two substituents Rₐ, two substituents R_{b}, and substituents Rₐ and R_{b}, can be joined to form a ring. Obviously, it is possible that none of these groups of adjacent substituents are joined to form a ring.

According to an embodiment of the present disclosure, the metal complex has a structure of Formula Ir(Lₐ)ₘ(L_{b})₃₋ₘ and has a structure represented by Formula 3-1:

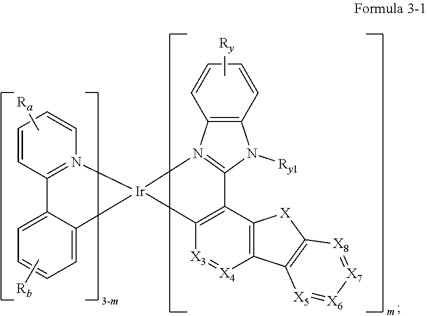

wherein,
m is selected from 1 or 2; when m is selected from 1, two L_{b} are the same or different; when m is selected from 2, two Lₐ are the same or different;
X is, at each occurrence identically or differently, selected from the group consisting of O, S, Se, NR₁, CR₁R₁ and SiR₁R₁; when two R₁ are present at the same time, the two R₁ are the same or different;
X₃ to X₈ are, at each occurrence identically or differently, selected from CRₓ or N;
R_{y}, Rₐ and R_{b} represent, at each occurrence identically or differently, mono-substitution, multiple substitutions or non-substitution;
R₁, Rₓ, R_{y}, R_{y1}, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, Rₓ, R_{y}, R_{y1}, Rₐ and R_{b} can be optionally joined to form a ring.

According to an embodiment of the present disclosure, the phosphorescence sensitizer has a general formula of Ir(Lₐ)ₘ(L_{b})₃₋ₘ and has a structure represented by Formula 4:

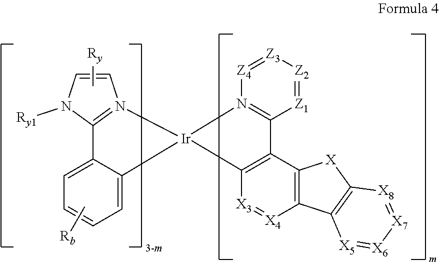

wherein,
m is selected from 1 or 2; when m is selected from 1, two L_{b} are the same or different; when m is selected from 2, two Lₐ are the same or different;
R_{y} represents, at each occurrence identically or differently, mono-substitution, di-substitution or non-substitution; R_{b} represents, at each occurrence identically or differently, mono-substitution, multiple substitutions or non-substitution;
X is, at each occurrence identically or differently, selected from the group consisting of O, S, Se, NR₁, CR₁R₁ and SiR₁R₁; when two R₁ are present at the same time, the two R₁ are the same or different;
X₃ to X₈ are, at each occurrence identically or differently, selected from CRₓ or N;
Z₁ to Z₄ are, at each occurrence identically or differently, selected from CR_{z} or N;
R₁, Rₓ, R_{y}, R_{y1}, R_{z} and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
adjacent substituents R₁, Rₓ, R_{z} and R_{b} can be optionally joined to form a ring.

Herein, the expression that “adjacent substituents R_{y} and R_{y1} can be optionally joined to form a ring” is intended to mean that any one or more of groups of adjacent substituents, such as two substituents R_{y}, two substituents R_{y1}, and substituents R_{y} and R_{y1}, can be joined to form a ring. Obviously, it is also possible that none of these substituents are joined to form a ring.

Herein, the expression that “adjacent substituents R₁, Rₓ, R_{z} and R_{b} can be optionally joined to form a ring” is intended to mean that any one or more of groups of adjacent substituents, such as two substituents R₁, two substituents Rₓ, two substituents R_{z}, two substituents R_{b}, substituents Rₓ and R₁, substituents Rₓ and R_{z}, and substituents R₁ and R_{z}, can be joined to form a ring. Obviously, it is also possible that none of these substituents are joined to form a ring.

According to an embodiment of the present disclosure, X is selected from O and S.

According to an embodiment of the present disclosure, X is O.

According to an embodiment of the present disclosure, m is selected from 1 or 2; preferably, m is selected from 1.

According to an embodiment of the present disclosure, X₃ to X₈ are, at each occurrence identically or differently, selected from CRₓ, and at least one Rₓ is cyano or fluorine.

According to an embodiment of the present disclosure, X₅ to X₈ are selected from CRₓ, and at least one Rₓ is cyano or fluorine.

According to an embodiment of the present disclosure, X₇ is CRₓ and the Rₓ is cyano or fluorine; or X₈ is CRₓ and the Rₓ is cyano.

According to an embodiment of the present disclosure, one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, one Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, X₇ is selected from CRₓ, and the Rₓ is cyano; X₈ is selected from CRₓ, and the Rₓ is selected from the group consisting of: deuterium, substituted or unsubstituted aryl having 6 to 30 carbon atoms, substituted or unsubstituted heteroaryl having 3 to 30 carbon atoms and combinations thereof.

According to an embodiment of the present disclosure, X₇ is selected from CRₓ, and the Rₓ is cyano; X₄ is selected from CRₓ, and the Rₓ is selected from the group consisting of: substituted or unsubstituted alkyl having 1 to 20 carbon atoms, substituted or unsubstituted cycloalkyl having 3 to 20 ring carbon atoms and combinations thereof.

According to an embodiment of the present disclosure, R_{y1} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, R_{y1} is, at each occurrence identically or differently, selected from the group consisting of: substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, R_{y1} is, at each occurrence identically or differently, selected from substituted or unsubstituted aryl having 6 to 30 carbon atoms.

According to an embodiment of the present disclosure, adjacent R_{y} are joined to form a substituted or unsubstituted carbocyclic ring or heterocyclic ring.

According to an embodiment of the present disclosure, adjacent R_{y} are joined to form a substituted or unsubstituted aromatic ring or heteroaromatic ring.

According to an embodiment of the present disclosure, adjacent R_{y} are joined to form a substituted or unsubstituted benzene ring.

According to an embodiment of the present disclosure, Lₐ is, at each occurrence identically or differently, selected from the group consisting of Lₐ₁ to Lₐ₂₈₇₄, wherein Lₐ₁ to Lₐ₂₈₇₄ are referred to claim 12.

According to an embodiment of the present disclosure, L_{b} is, at each occurrence identically or differently, selected from the group consisting of L_{b1} to L_{b170}, wherein L_{b1} to L_{b170} are referred to claim 13.

According to an embodiment of the present disclosure, L_{c} is, at each occurrence identically or differently, selected from the group consisting of L_{c1} to L_{c50}, wherein L_{c1} to L_{c50} are referred to claim 13.

According to an embodiment of the present disclosure, the metal complex has a structure of Ir(Lₐ)(L_{b})₂, wherein the two L_{b} are the same or different, Lₐ is, at each occurrence identically or differently, selected from any one of the group consisting of Lₐ₁ to Lₐ₂₈₇₄, and L_{b} is, at each occurrence identically or differently, selected from any two of the group consisting of L_{b1} to L_{b170}.

According to an embodiment of the present disclosure, the metal complex is selected from the group consisting of Metal Complex 1 to Metal Complex 2530, wherein Metal Complex 1 to Metal Complex 2530 are referred to claim 14.

According to an embodiment of the present disclosure, hydrogen in Metal Complex 1 to Metal Complex 2530 can be partially or fully substituted with deuterium.

According to an embodiment of the present disclosure, the fluorescent material comprises at least one boron-nitrogen heterocyclic structure.

According to an embodiment of the present disclosure, the fluorescent material comprises at least one substituted or unsubstituted carbazole structure.

According to an embodiment of the present disclosure, the fluorescent material comprises at least two substituted or unsubstituted carbazole structures.

According to an embodiment of the present disclosure, the fluorescent material comprises at least one substituted or unsubstituted diarylamino structure.

According to an embodiment of the present disclosure, the fluorescent material comprises at least two substituted or unsubstituted diarylamino structures.

According to an embodiment of the present disclosure, the fluorescent material comprises at least one substituted or unsubstituted carbazole group and at least one substituted or unsubstituted diarylamino structure.

According to an embodiment of the present disclosure, the fluorescent material has a structure represented by Formula 5:

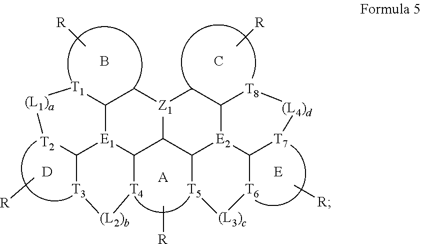

wherein the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1};
T₁ to T₈ are each independently selected from C, CRₜ or N;
a, b, c and d are each independently selected from 0 or 1;
L₁, L₂, L₃ and L₄ are, at each occurrence identically or differently, selected from a single bond, O, S, Se, BR_{L} or NR_{L};
R represents, at each occurrence identically or differently, mono-substitution, multiple substitutions or non-substitution;
R, R₁, R_{L}, R_{Si1} and R_{Ge1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R₁, R_{L}, R_{Si1}, R_{Ge1} and R^{B} can be optionally joined to form a ring.

Herein, the expression that “adjacent substituents R, R₁, R_{L}, R_{Si1}, R_{Ge1} and R^{B} can be optionally joined to form a ring” is intended to mean that any one or more of groups of adjacent substituents, such as two substituents R, two substituents R₁, two substituents R_{L}, two substituents R_{Si1}, two substituents R_{Ge1}, two substituents R^{B}, substituents R and R₁, substituents Rₜ and R_{L}, and substituents R_{Si1} and R_{Ge1}, can be joined to form a ring. Obviously, it is also possible that none of these substituents are joined to form a ring.

Herein, a “carbocyclic ring” comprises a saturated carbocyclic ring and an unsaturated carbocyclic ring, the “unsaturated carbocyclic ring” comprises an aromatic unsaturated carbocyclic ring and a non-aromatic unsaturated carbocyclic ring, a “heterocyclic ring” comprises a saturated heterocyclic ring and an unsaturated heterocyclic ring, and the “unsaturated heterocyclic ring” comprises an aromatic unsaturated heterocyclic ring and a non-aromatic unsaturated heterocyclic ring.

According to an embodiment of the present disclosure, the “unsaturated carbocyclic ring” comprises an aromatic unsaturated carbocyclic ring, and the aromatic unsaturated carbocyclic ring includes, but is not limited to, the “aromatic ring”, the “aryl” and the “aromatic group” in the present disclosure.

According to an embodiment of the present disclosure, the “unsaturated carbocyclic ring” comprises a non-aromatic unsaturated carbocyclic ring, and the non-aromatic unsaturated carbocyclic ring includes, but is not limited to, the “five-membered unsaturated carbocyclic ring” in the present disclosure.

According to an embodiment of the present disclosure, the “unsaturated heterocyclic ring” comprises an aromatic unsaturated heterocyclic ring, and the aromatic unsaturated heterocyclic ring includes, but is not limited to, the “heteroaromatic ring” and the “heteroaryl” in the present disclosure.

According to an embodiment of the present disclosure, the “unsaturated heterocyclic ring” comprises a non-aromatic unsaturated heterocyclic ring, and the non-aromatic unsaturated heterocyclic ring includes, but is not limited to, the “heterocyclic group” in the present disclosure.

According to an embodiment of the present disclosure, the fluorescent material has a structure represented by Formula 6:

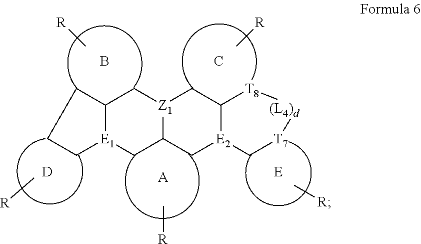

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1};
T₇ and T₈ are each independently selected from C, CRₜ or N;
d is selected from 0 and 1;
L₄ is, at each occurrence identically or differently, selected from a single bond, O, S, Se, BR_{L} or NR_{L};
R represents, at each occurrence identically or differently, mono-substitution, multiple substitutions or non-substitution;
R, R₁, R_{L}, R_{Si1} and R_{Ge1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R₁, R_{L}, R_{Si1}, R_{Ge1} and R^{B} can be optionally joined to form a ring.

According to an embodiment of the present disclosure, the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring C, the ring D and the ring E are each independently selected from a five-membered unsaturated carbocyclic ring, an aromatic ring having 6 to 18 carbon atoms or a heteroaromatic ring having 3 to 18 carbon atoms.

According to an embodiment of the present disclosure, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

According to an embodiment of the present disclosure, the ring A, the ring B, the ring C, the ring D and the ring E are selected from a benzene ring.

According to an embodiment of the present disclosure, Z₁ is selected from B, P═O or P═S, and E₁ and E₂ are each independently selected from N or P.

According to an embodiment of the present disclosure, Z₁ is selected from B, and E₁ and E₂ are selected from N.

According to an embodiment of the present disclosure, Z₁ is selected from N or P, and E₁ and E₂ are each independently selected from B, P═O or P═S.

According to an embodiment of the present disclosure, Z₁ is selected from N, and E₁ and E₂ are selected from B.

According to an embodiment of the present disclosure, L₁, L₂, L₃ and L₄ are, at each occurrence identically or differently, selected from a single bond, O, BR_{L} or NR_{L}.

According to an embodiment of the present disclosure, a+b+c+d is greater than or equal to 1.

According to an embodiment of the present disclosure, a+d is greater than or equal to 1.

According to an embodiment of the present disclosure, a is 0, and d is 1.

According to an embodiment of the present disclosure, a is 1, and d is 1.

According to an embodiment of the present disclosure, the fluorescent material has a structure represented by any one of Formula 5-1 to Formula 5-8:

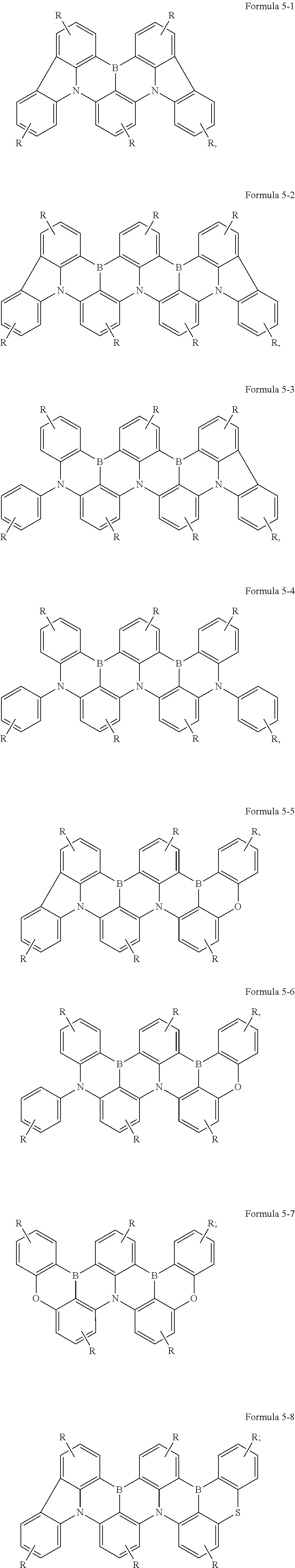

R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R and R^{B} can be optionally joined to form a ring.

According to an embodiment of the present disclosure, the fluorescent material has a structure represented by Formula 5-1 or Formula 5-2.

According to an embodiment of the present disclosure, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms and combinations thereof.

According to an embodiment of the present disclosure, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof.

According to an embodiment of the present disclosure, multiple R are present in Formula 5-1 to Formula 5-8, and at least one (for example, one, two, three or four) of the multiple R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof.

According to an embodiment of the present disclosure, the fluorescent material is selected from the group consisting of Compound DF-1 to Compound DF-160, wherein Compound DF-1 to Compound DF-160 are referred to claim 25.

According to an embodiment of the present disclosure, hydrogen in Compound DF-1 to Compound DF-160 can be partially or fully substituted with deuterium.

According to an embodiment of the present disclosure, the fluorescent material is a delayed fluorescent material.

According to an embodiment of the present disclosure, the fluorescent material is a thermally activated delayed fluorescence (TADF) material.

According to an embodiment of the present disclosure, the fluorescent material is used as a main light-emitting source in the organic electroluminescent device.

According to an embodiment of the present disclosure, the fluorescent material is a terminal light-emitting material of the organic electroluminescent device.

According to an embodiment of the present disclosure, the fluorescent material is selected from one type of material or multiple types of different materials.

According to an embodiment of the present disclosure, the organic electroluminescent device emits fluorescence.

According to an embodiment of the present disclosure, the organic electroluminescent device emits delayed fluorescence.

According to an embodiment of the present disclosure, the emissive layer further comprises a host material.

According to another embodiment of the present disclosure, the host material comprises a first host compound.

According to another embodiment of the present disclosure, the host material further comprises a second host compound.

According to another embodiment of the present disclosure, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to another embodiment of the present disclosure, the first host compound has a structure represented by Formula X-1 or Formula X-2:

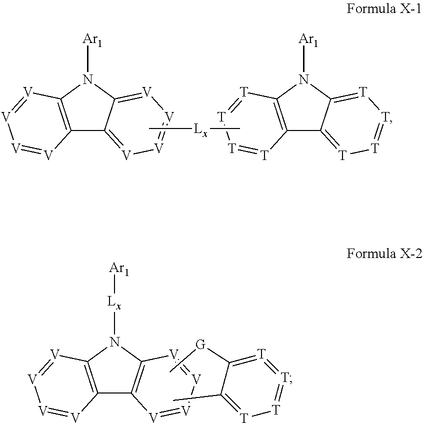

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CR, or N;
in Formula X-1, T is, at each occurrence identically or differently, selected from C, CR_{T} or N;
in Formula X-2, T is, at each occurrence identically or differently, selected from CR_{T} or N;
R_{g}, Rᵥ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and R_{T} can be optionally joined to form a ring.

In this embodiment, the expression that “adjacent substituents R_{g}, Rᵥ and R_{T} can be optionally joined to form a ring” is intended to mean that any one or more of groups of adjacent substituents, such as two substituents Rᵥ, two substituents R_{T}, two substituents R_{g}, substituents Rᵥ and R_{T}, substituents Rᵥ and R_{g}, and substituents R_{g} and R_{T}, can be joined to form a ring. Obviously, it is also possible that none of these substituents are joined to form a ring.

According to an embodiment of the present disclosure, the first host compound has a structure represented by one of Formula X-a to Formula X-p:

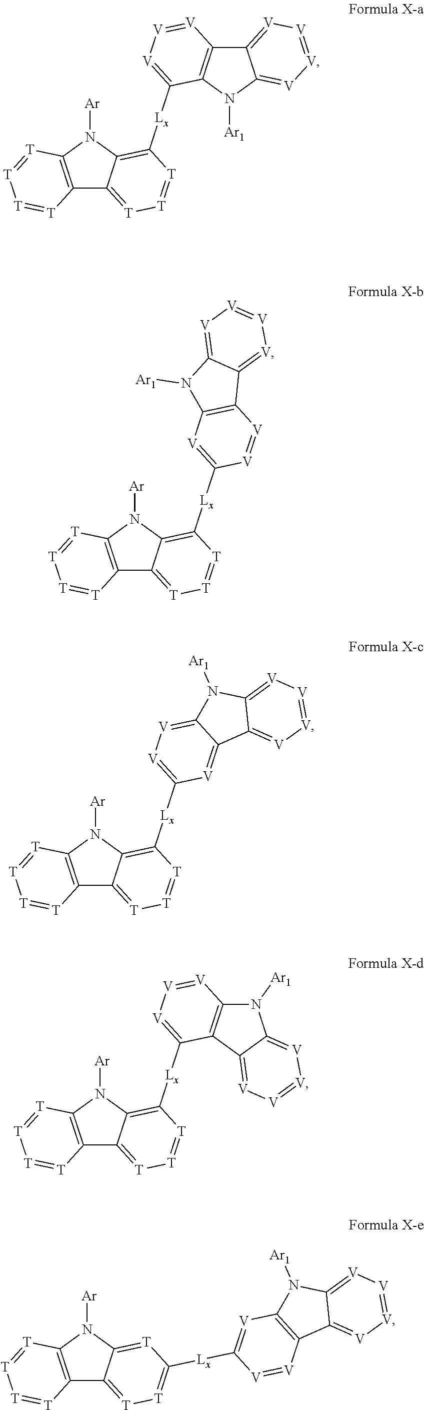

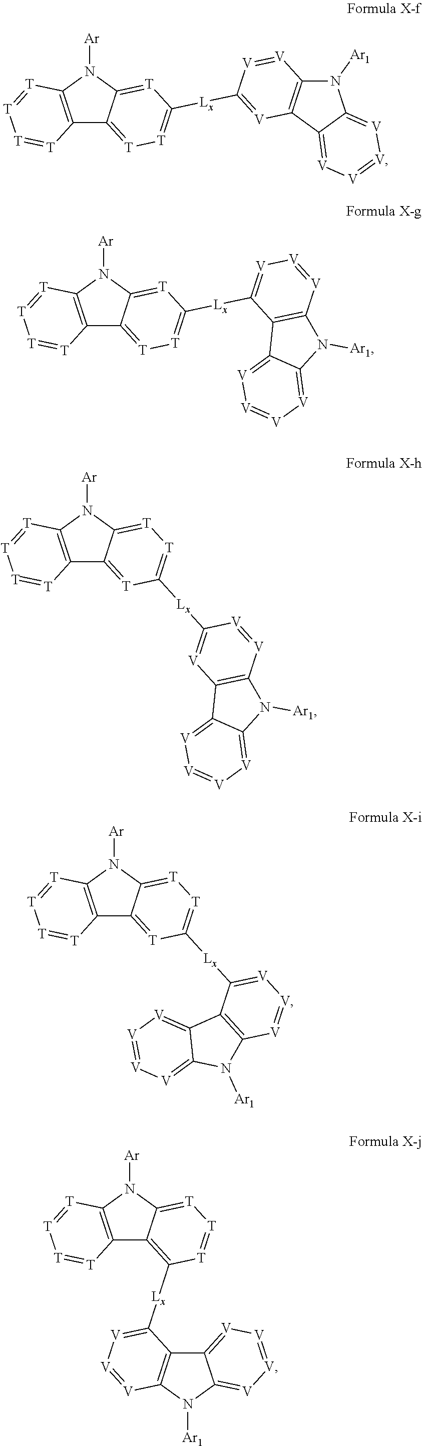

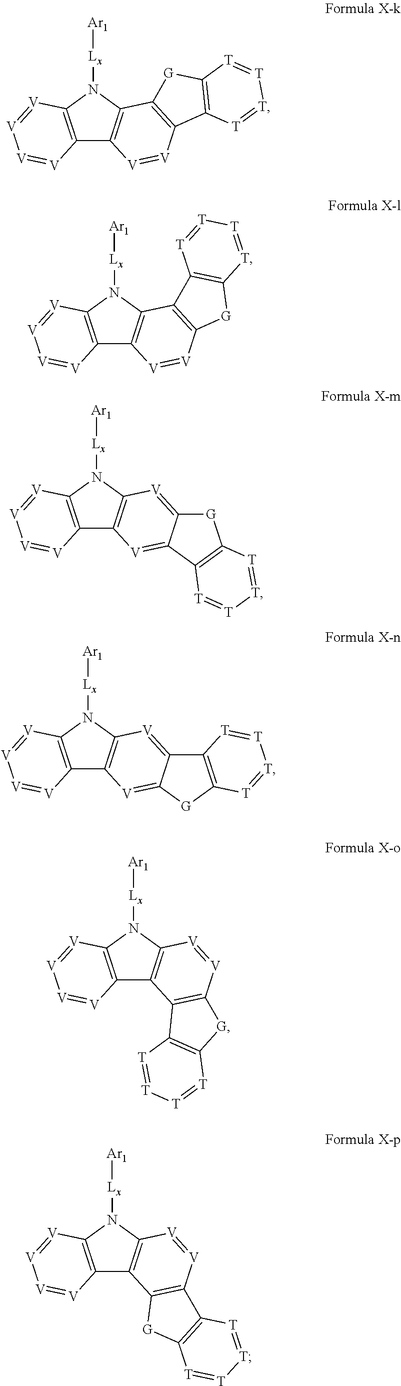

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from CR, or N;
T is, at each occurrence identically or differently, selected from CR_{T} or N;
R_{g}, Rᵥ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and R_{T} can be optionally joined to form a ring.

According to an embodiment of the present disclosure, the first host compound is selected from the group consisting of the following compounds:

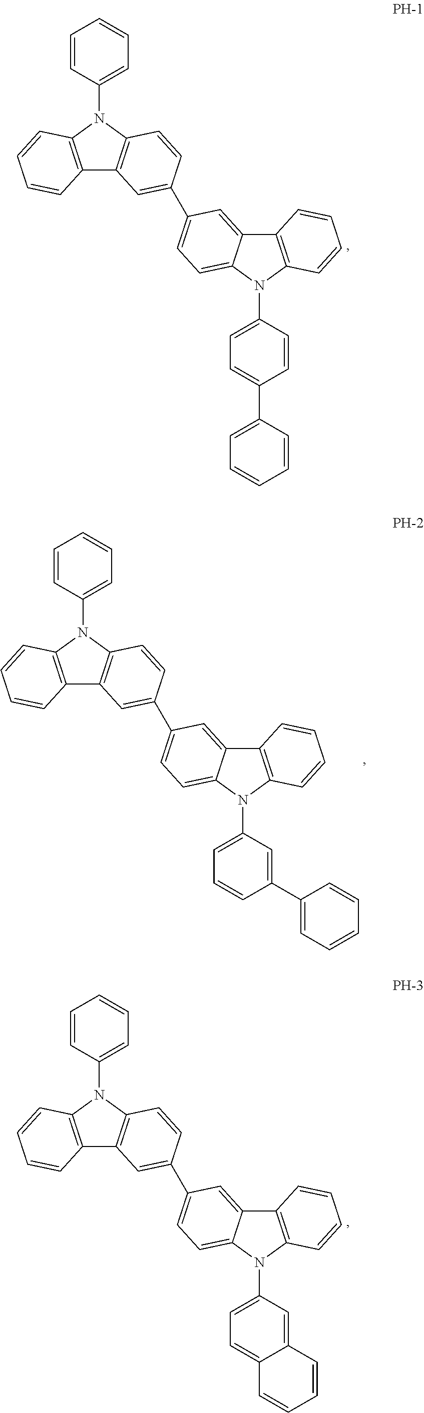 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

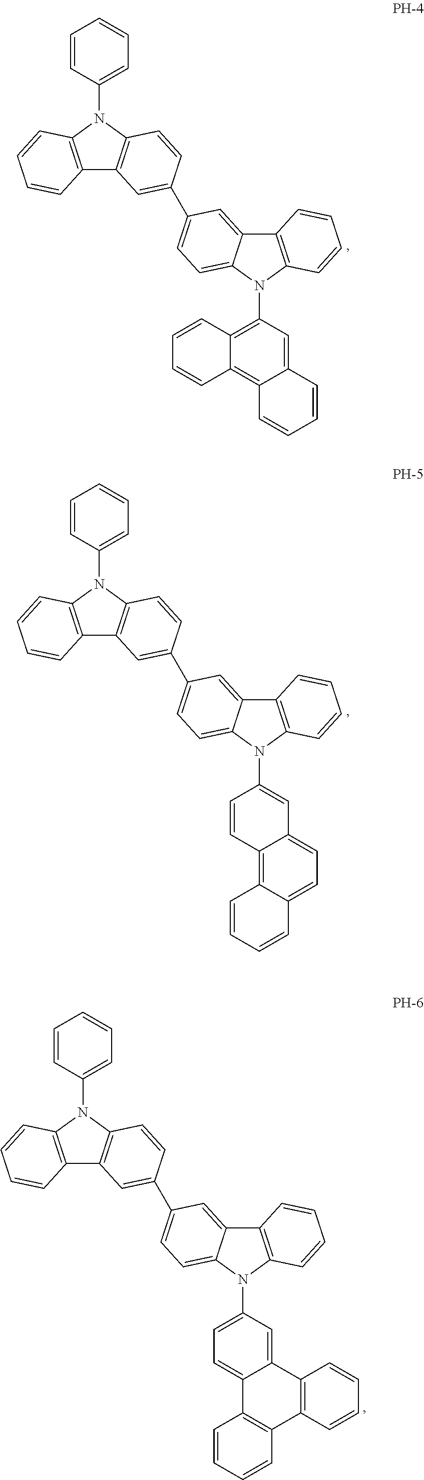 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

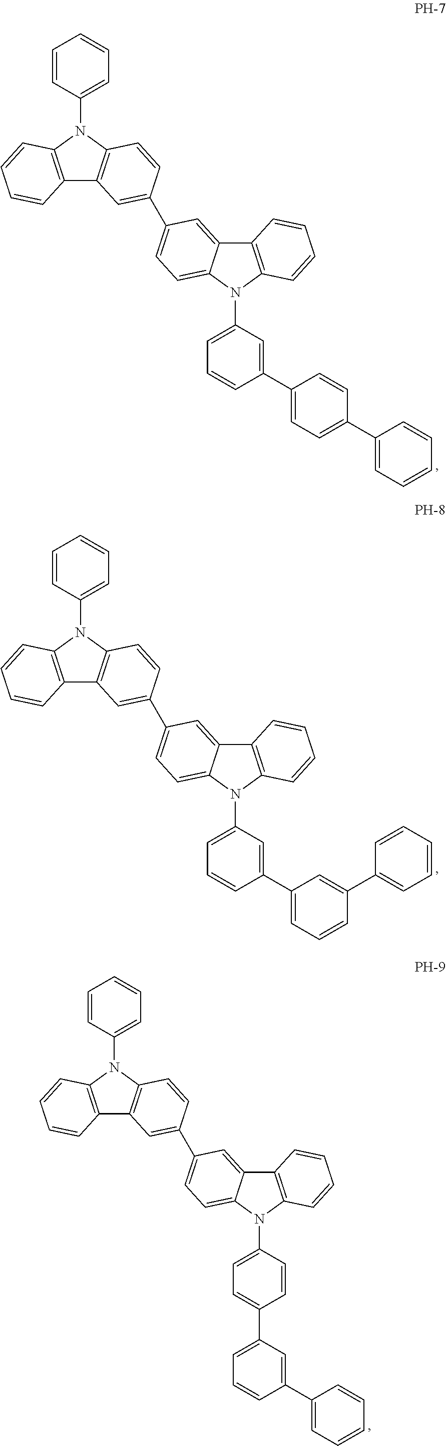 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

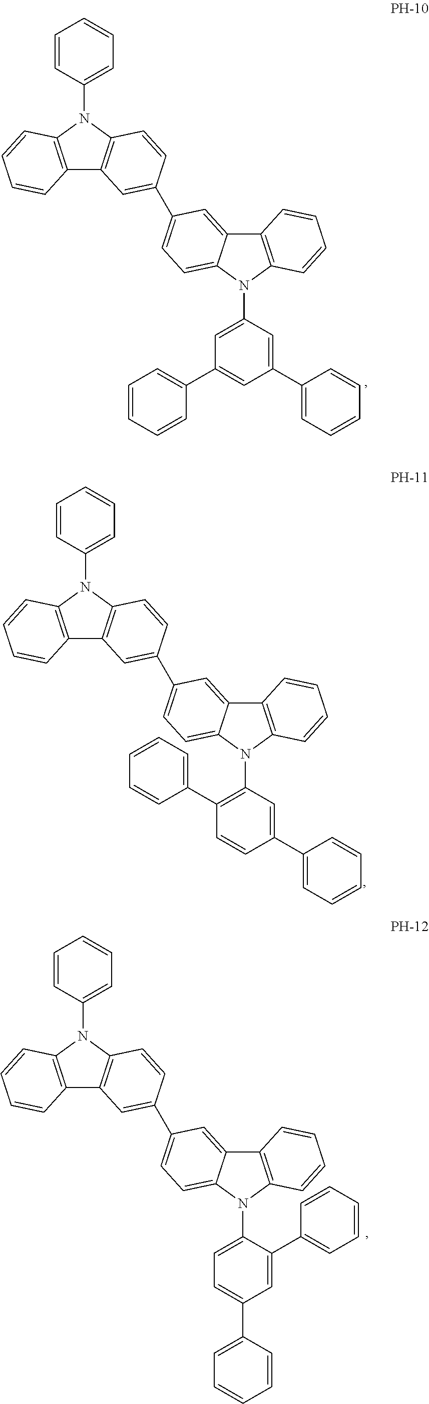 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

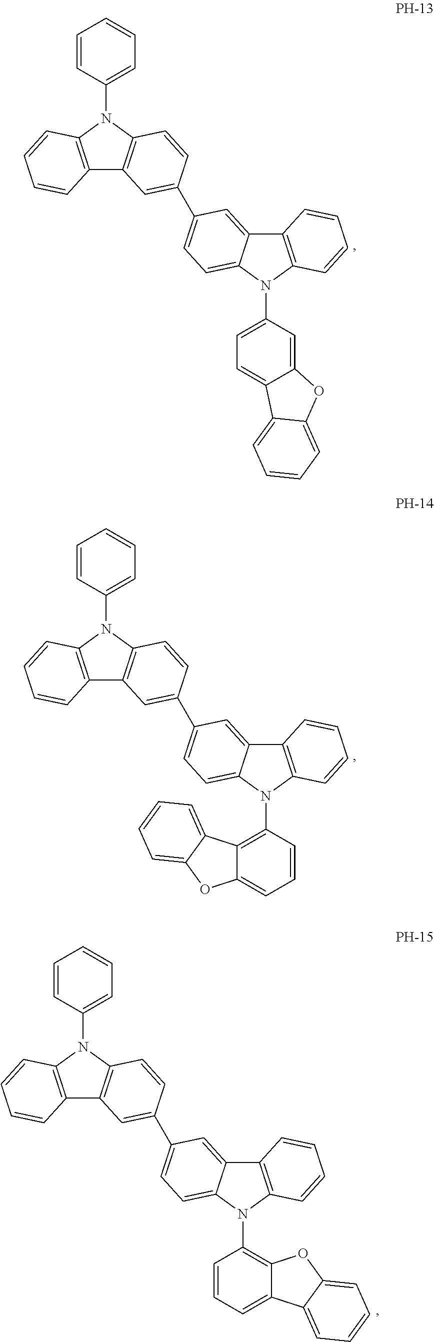 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

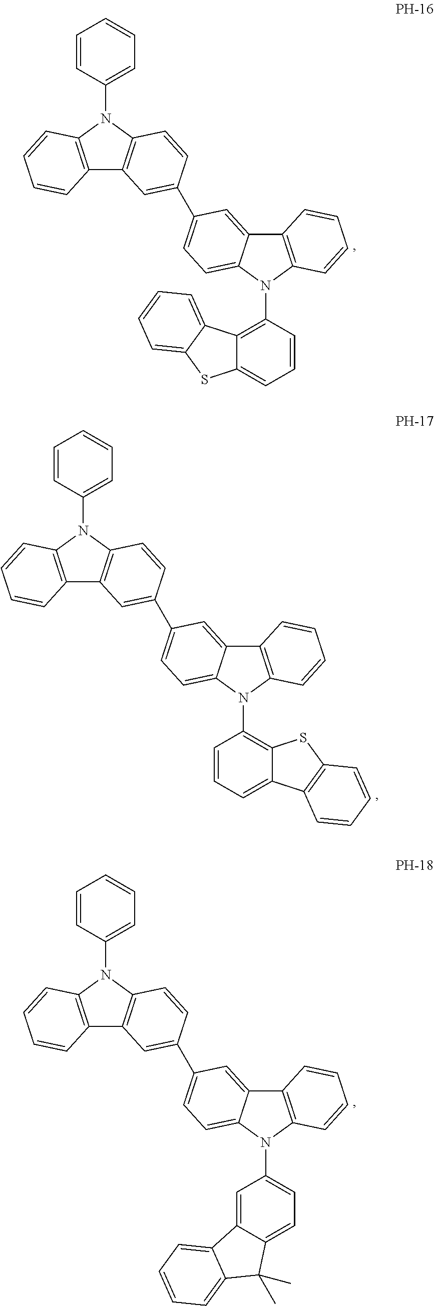 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21]

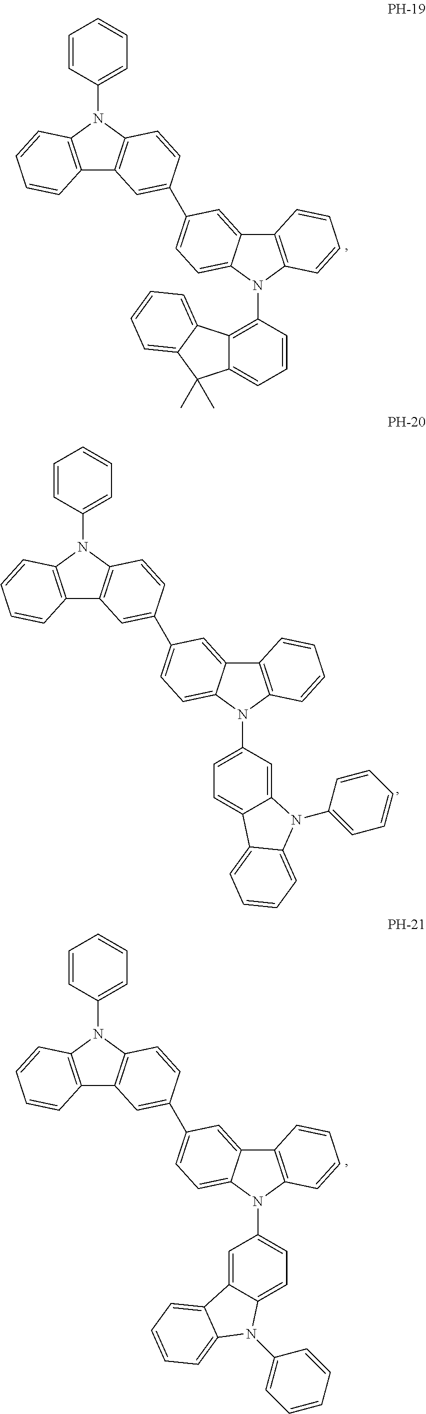 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

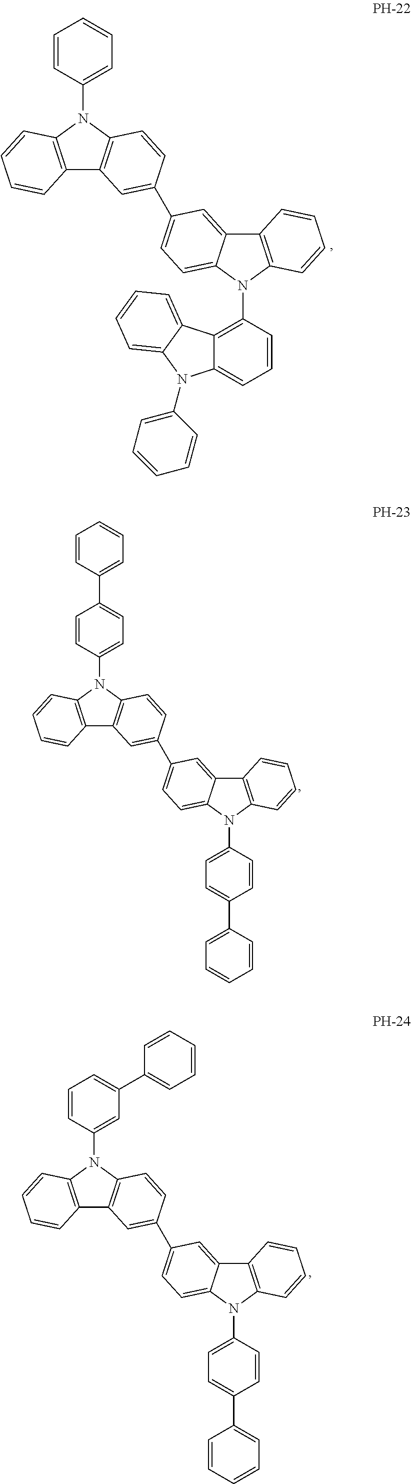 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

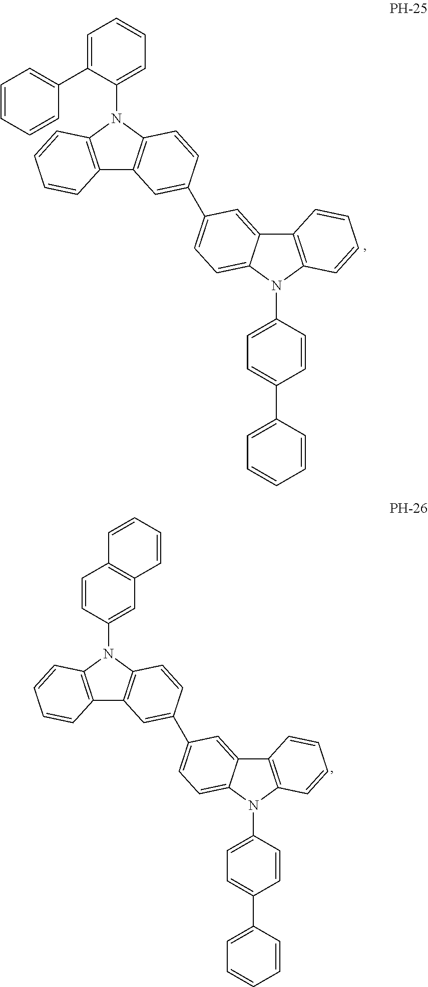 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1]

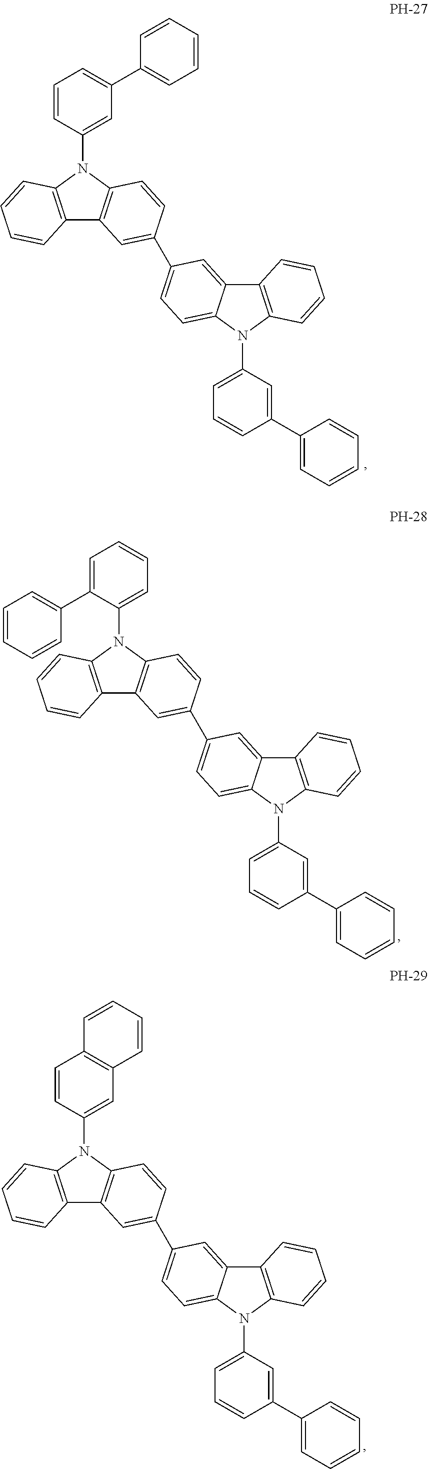 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1]

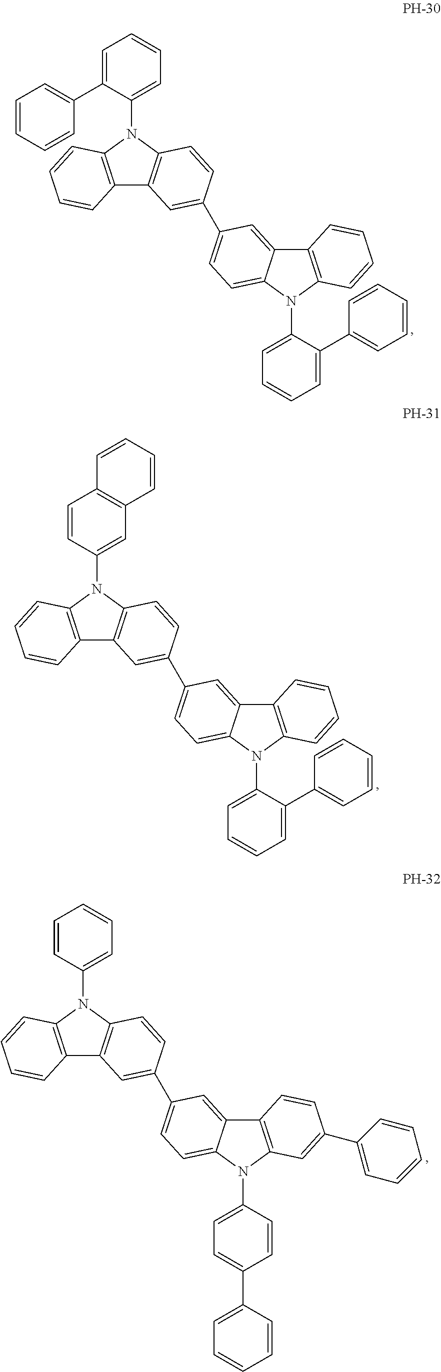 [SMILES: c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1]

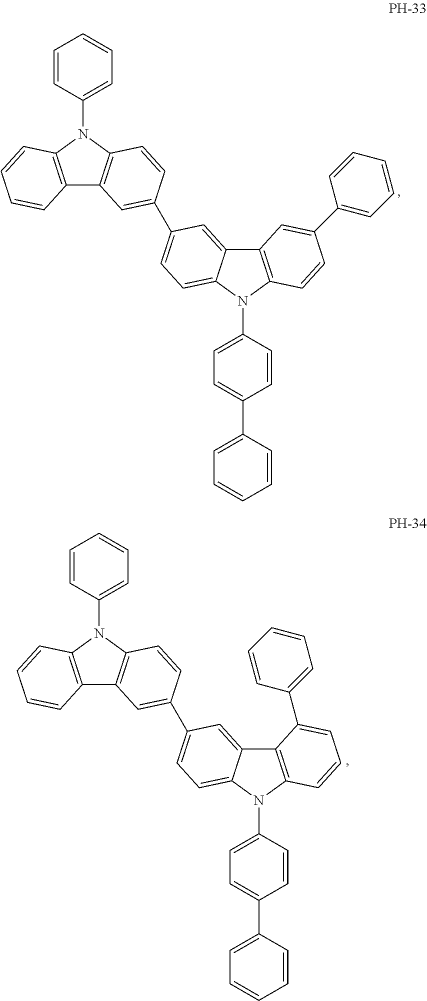 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

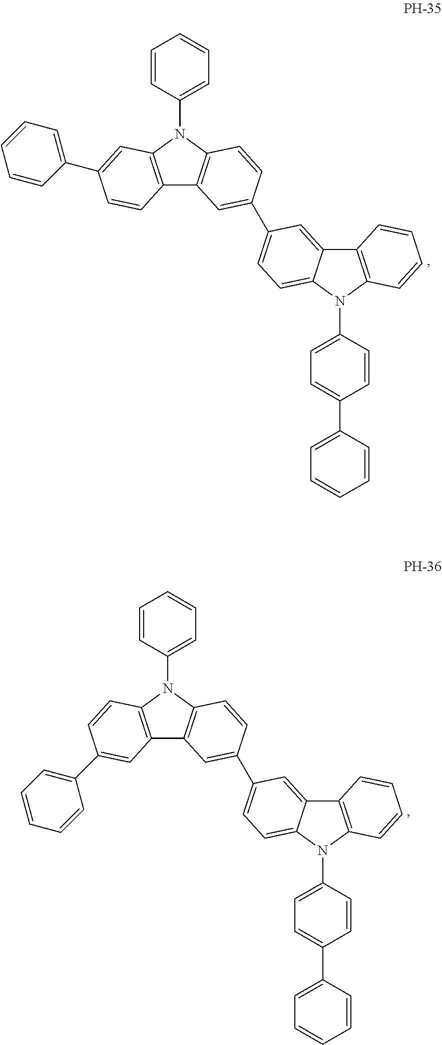 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

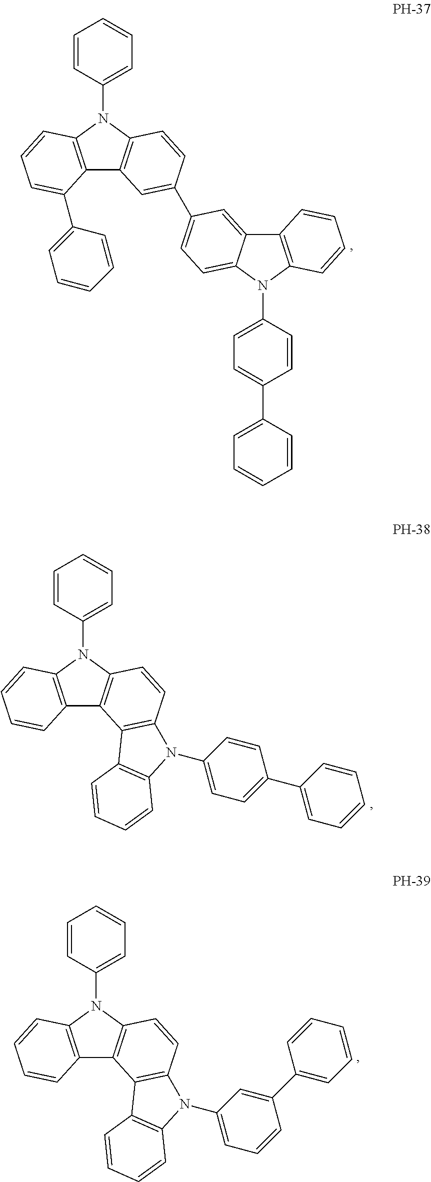 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

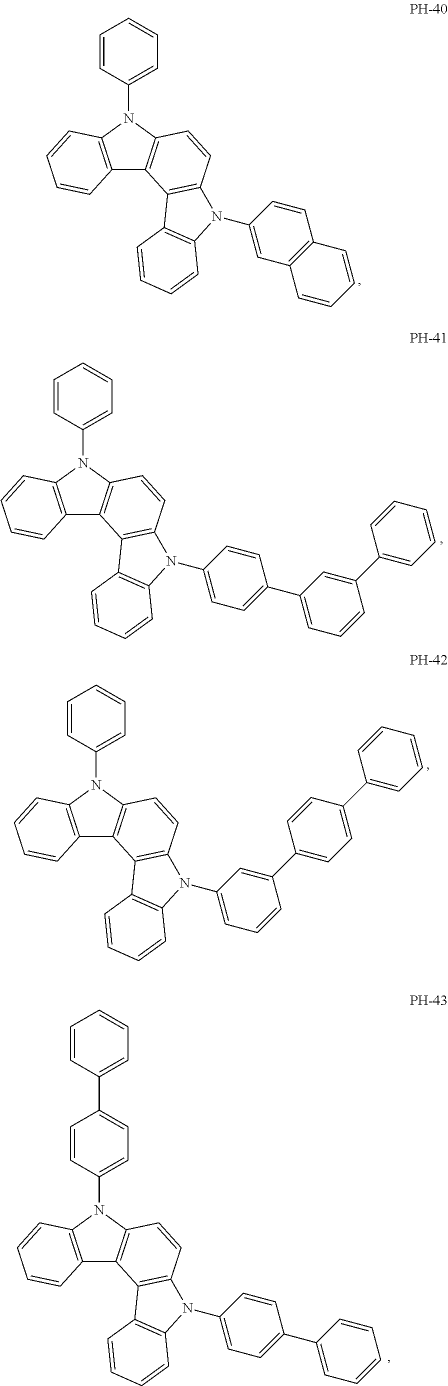 [SMILES: c1ccc(-n2c3ccccc3c3c4c5ccccc5n(-c5ccc6ccccc6c5)c4ccc32)cc1 ; c1ccc(-c2cccc(-c3ccc(-n4c5ccccc5c5c6c7ccccc7n(-c7ccccc7)c6ccc54)cc3)c2)cc1 ; c1ccc(-c2ccc(-c3cccc(-n4c5ccccc5c5c6c7ccccc7n(-c7ccccc7)c6ccc54)c3)cc2)cc1 ; c1ccc(-c2ccc(-n3c4ccccc4c4c5c6ccccc6n(-c6ccc(-c7ccccc7)cc6)c5ccc43)cc2)cc1]

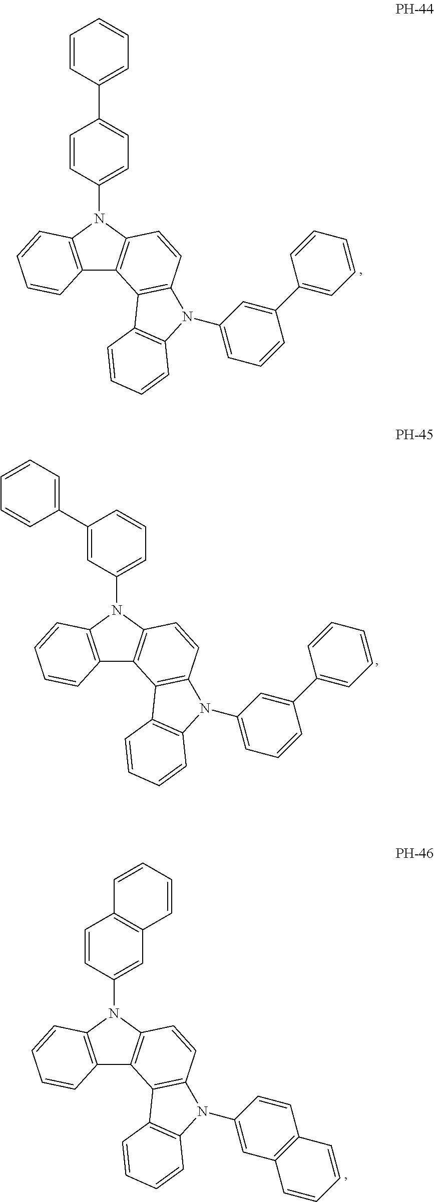 [SMILES: c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1]

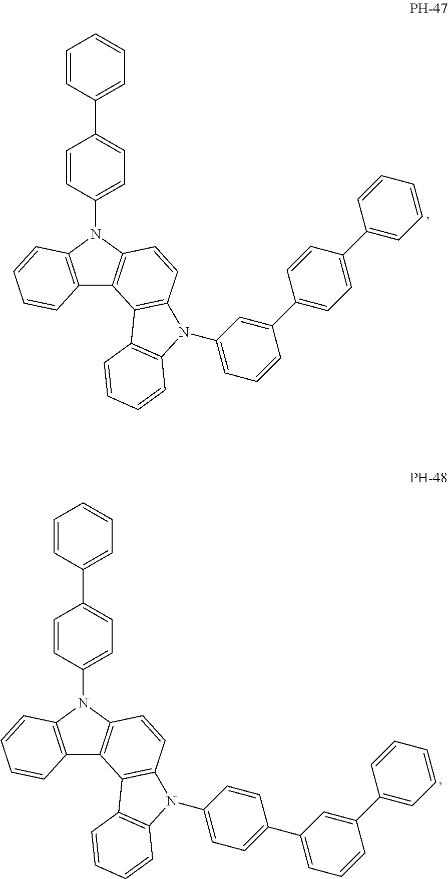 [SMILES: c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1]

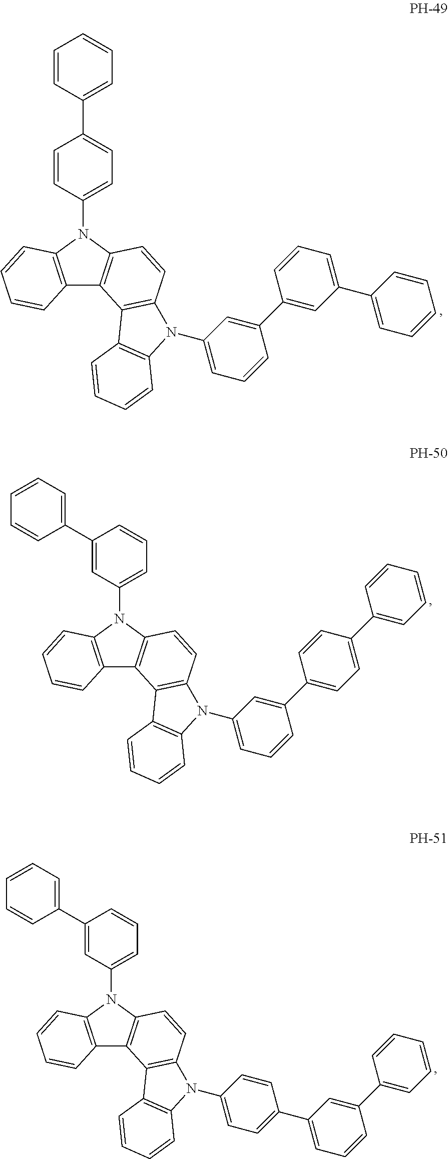 [SMILES: c1ccc(-c2ccc(-n3c4ccccc4c4c5c6ccccc6n(-c6cccc(-c7cccc(-c8ccccc8)c7)c6)c5ccc43)cc2)cc1 ; c1ccc(-c2ccc(-c3cccc(-n4c5ccccc5c5c6c7ccccc7n(-c7cccc(-c8ccccc8)c7)c6ccc54)c3)cc2)cc1 ; c1ccc(-c2cccc(-c3ccc(-n4c5ccccc5c5c6c7ccccc7n(-c7cccc(-c8ccccc8)c7)c6ccc54)cc3)c2)cc1]

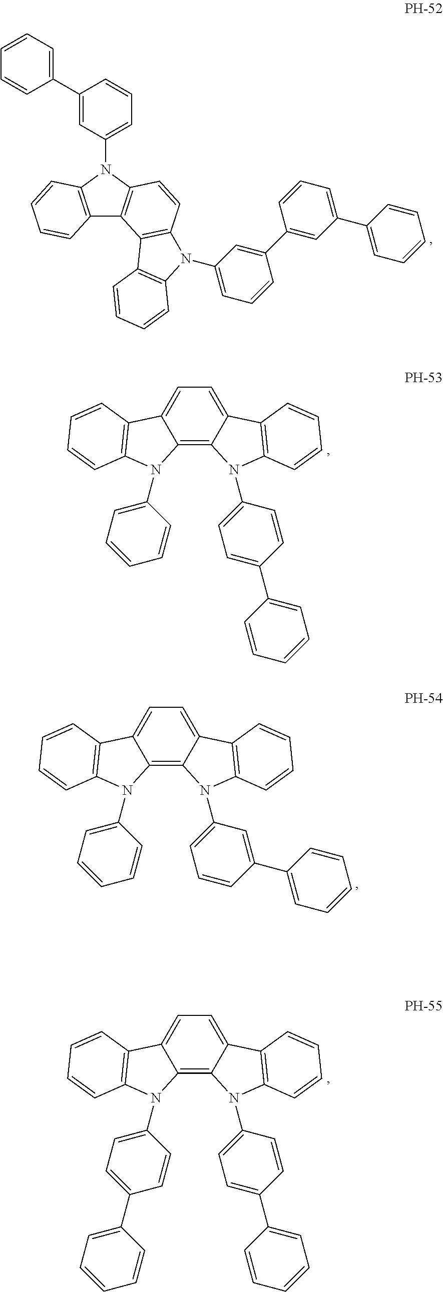 [SMILES: c1ccc(-c2cccc(-c3cccc(-n4c5ccccc5c5c6c7ccccc7n(-c7cccc(-c8ccccc8)c7)c6ccc54)c3)c2)cc1 ; c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1]

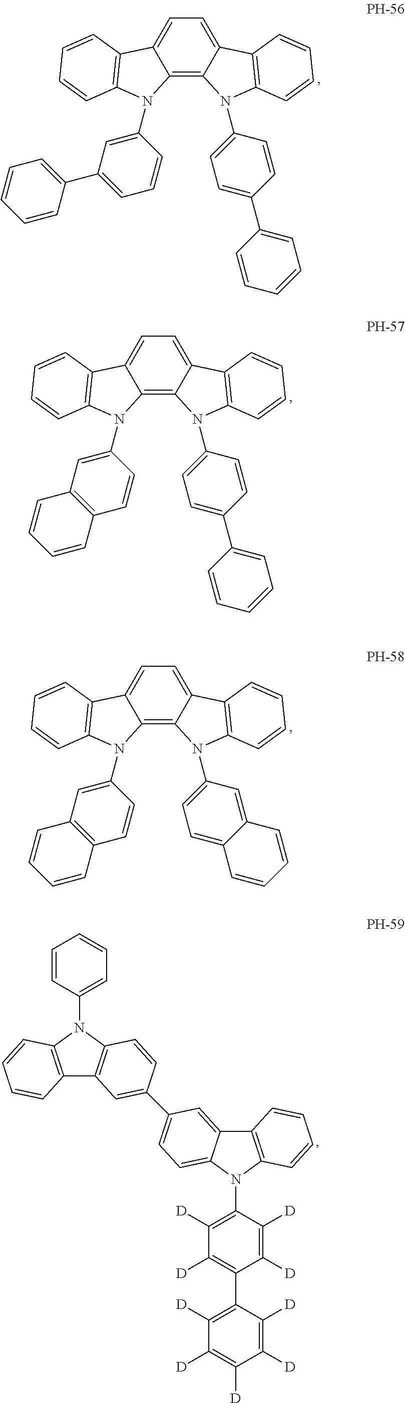 [SMILES: c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1 ; [2H]c1c([2H])c([2H])c(-c2c([2H])c([2H])c(-n3c4ccccc4c4cc(-c5ccc6c(c5)c5ccccc5n6-c5ccccc5)ccc43)c([2H])c2[2H])c([2H])c1[2H]]

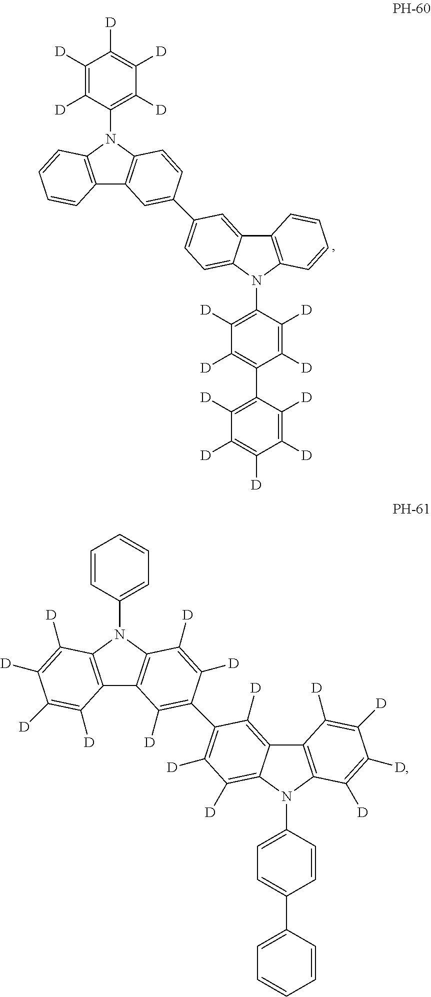

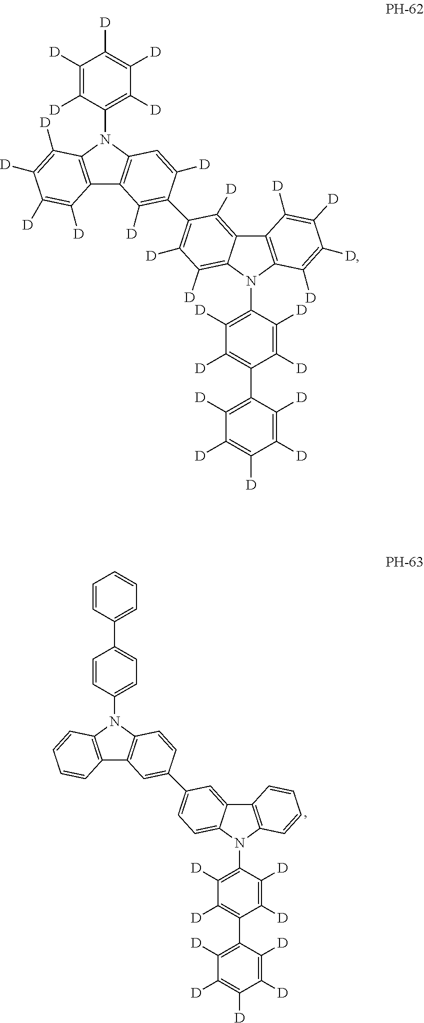

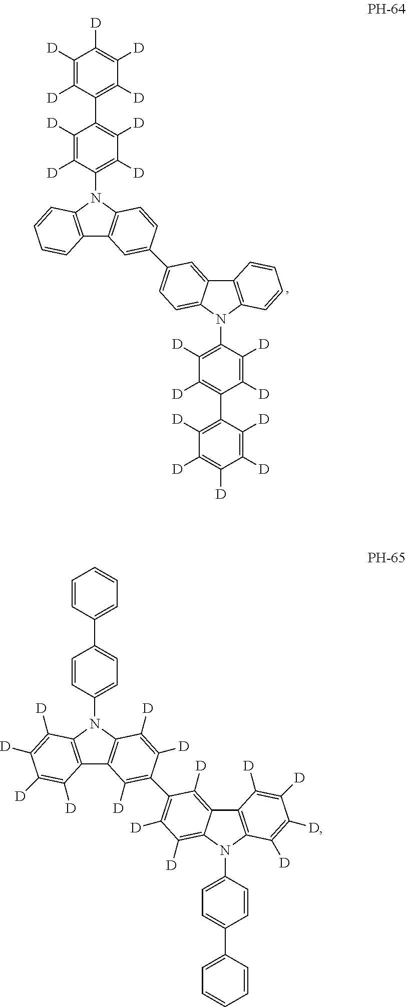

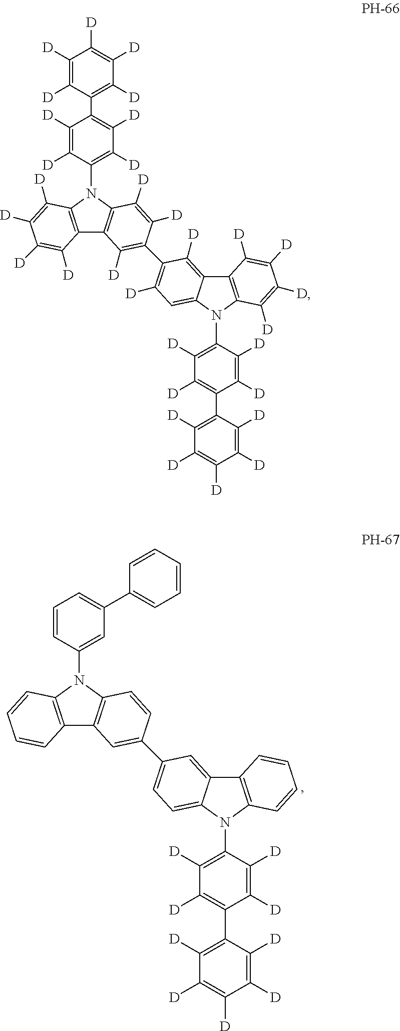

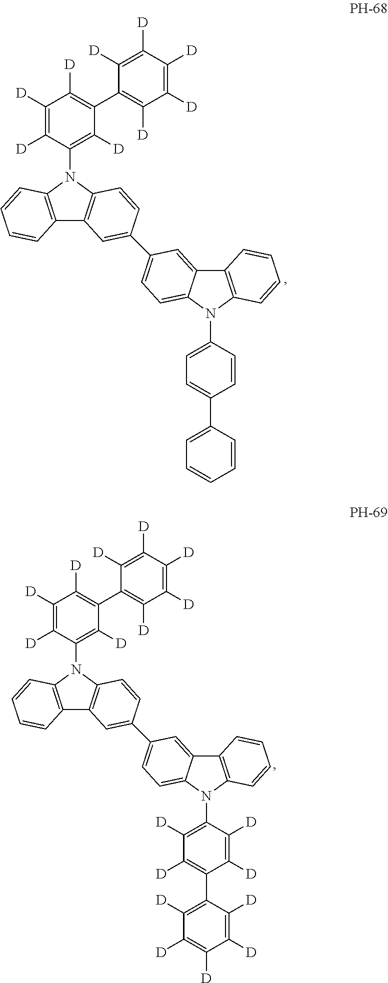 [SMILES: [2H]c1c([2H])c([2H])c(-c2c([2H])c([2H])c([2H])c(-n3c4ccccc4c4cc(-c5ccc6c(c5)c5ccccc5n6-c5ccc(-c6ccccc6)cc5)ccc43)c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c([2H])c2[2H])c([2H])c1[2H]]

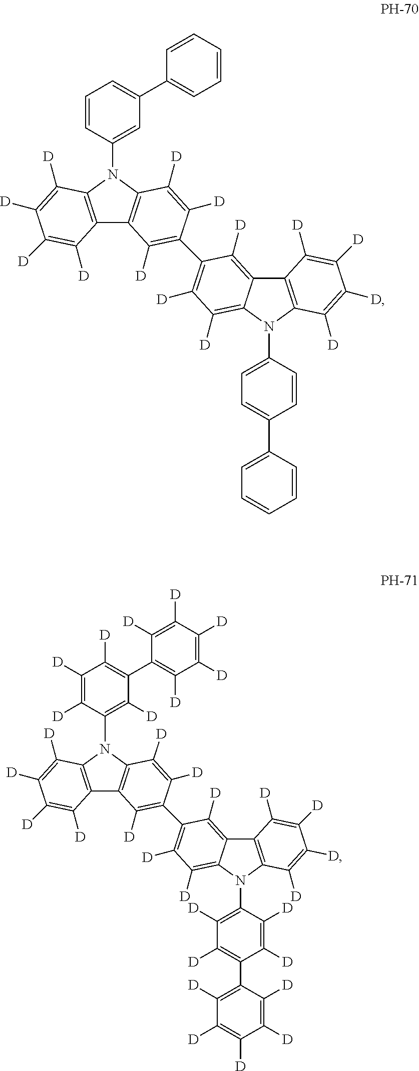

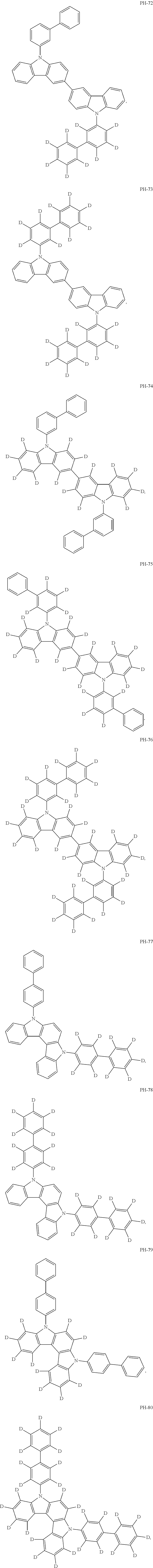

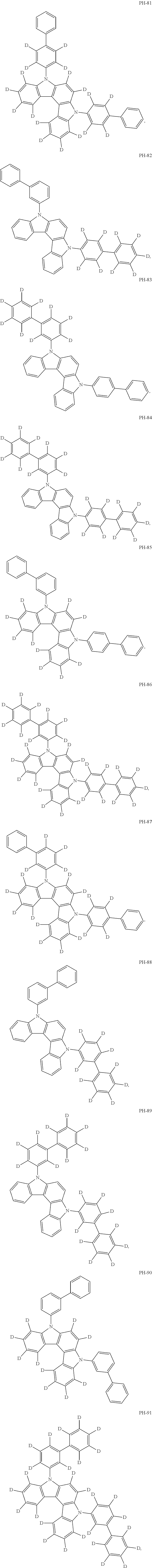

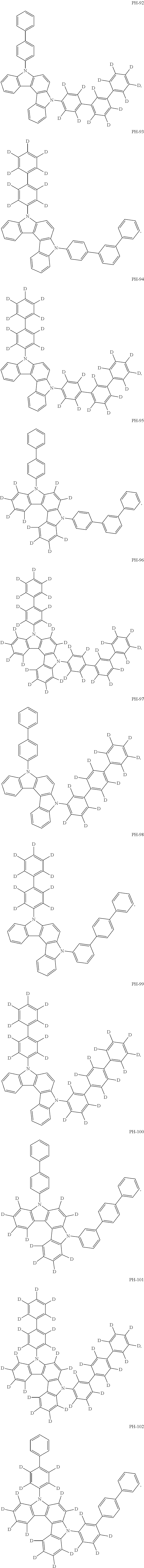

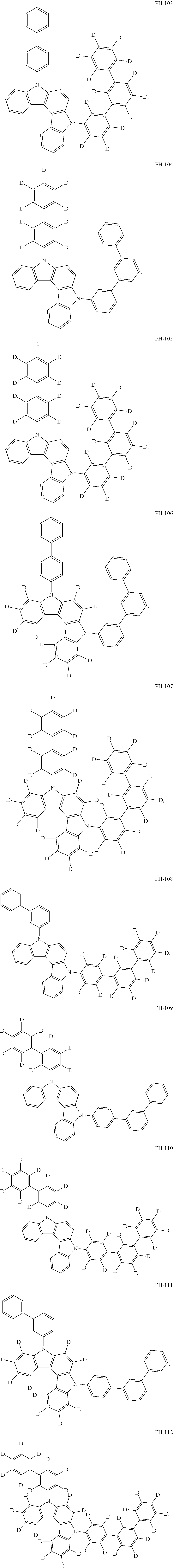

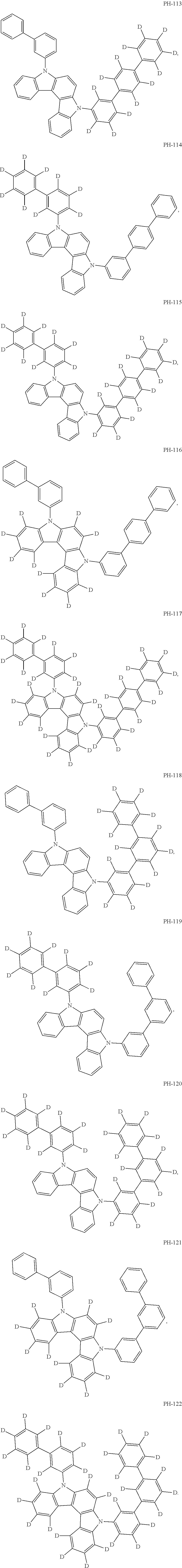

According to an embodiment of the present disclosure, the emissive layer further comprises a second host compound, wherein the second host compound has a structure represented by Formula Y.

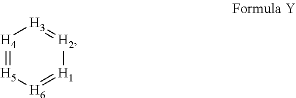

wherein,
H₁ to H₆ are, at each occurrence identically or differently, selected from C, CRₕ or N, at least two of H₁ to H₆ are N, and at least one of H₁ to H₆ is C and joined to Formula A:

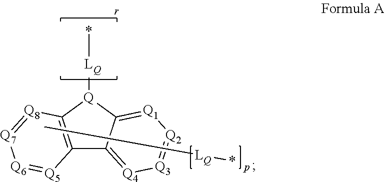

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be the same or different;
p is 0 or 1; r is 0 or 1;
when Q is selected from N, p is 0 and r is 1;
when Q is selected from the group consisting of O, S, Se, NR_{Q}, CR_{Q}R_{Q}, SiR_{Q}R_{Q}, GeR_{Q}R_{Q} and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₕ, R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“*” represents a position where Formula A is joined to Formula Y; and
adjacent substituents Rₕ, R_{Q} and R_{q} can be optionally joined to form a ring.

Herein, the expression that “adjacent substituents Rₕ, R_{Q} and R_{q} can be optionally joined to form a ring” is intended to mean that any one or more of groups of adjacent substituents, such as two substituents Rₕ, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the second host compound is selected from the group consisting of the following compounds:

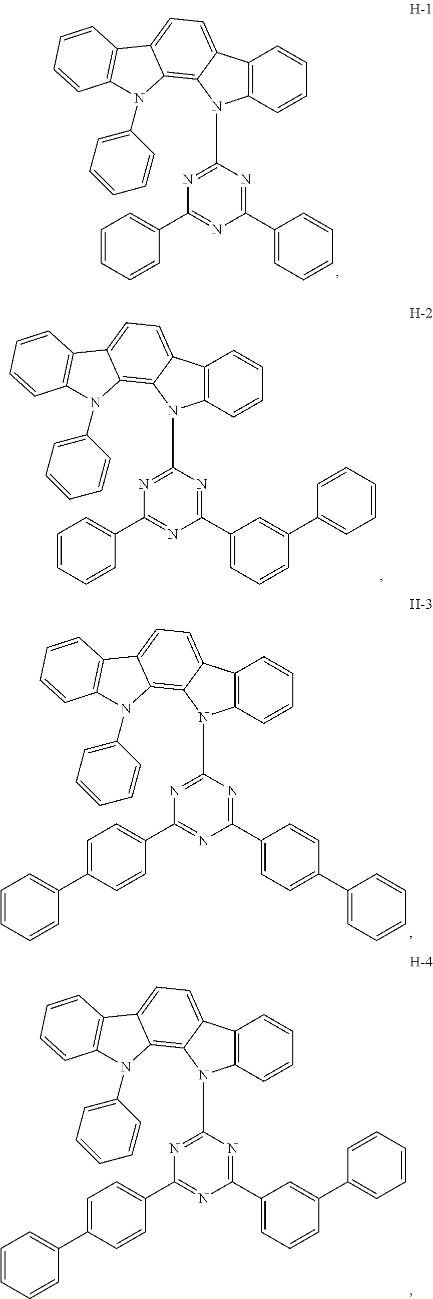

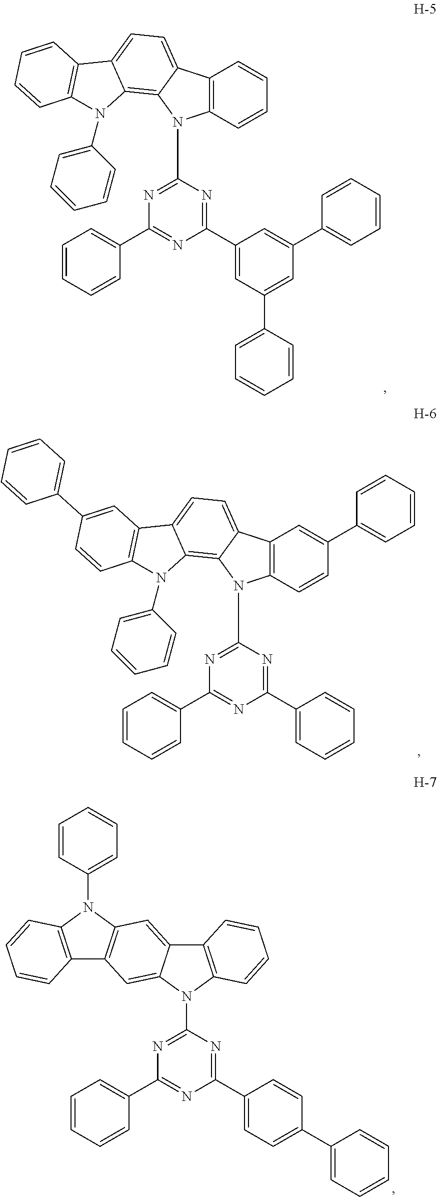 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2ccc(-c3nc(-c4ccccc4)nc(-n4c5ccccc5c5cc6c(cc54)c4ccccc4n6-c4ccccc4)n3)cc2)cc1]

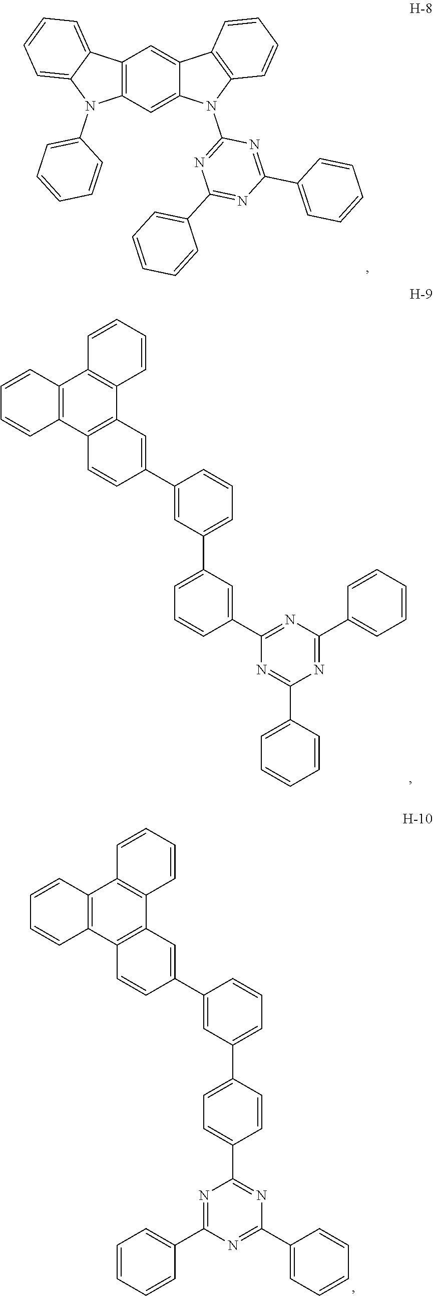 [SMILES: c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3ccc(-c4cccc(-c5ccc6c7ccccc7c7ccccc7c6c5)c4)cc3)n2)cc1]

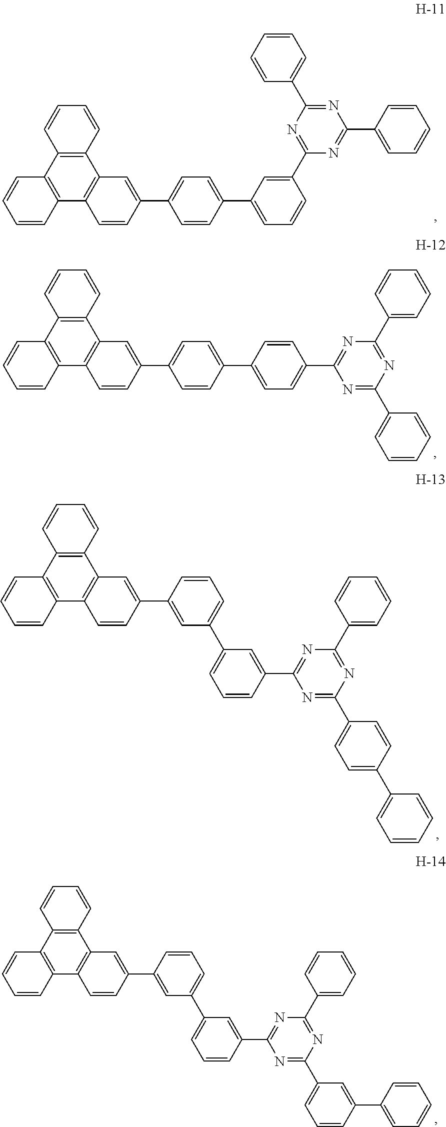 [SMILES: c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1]

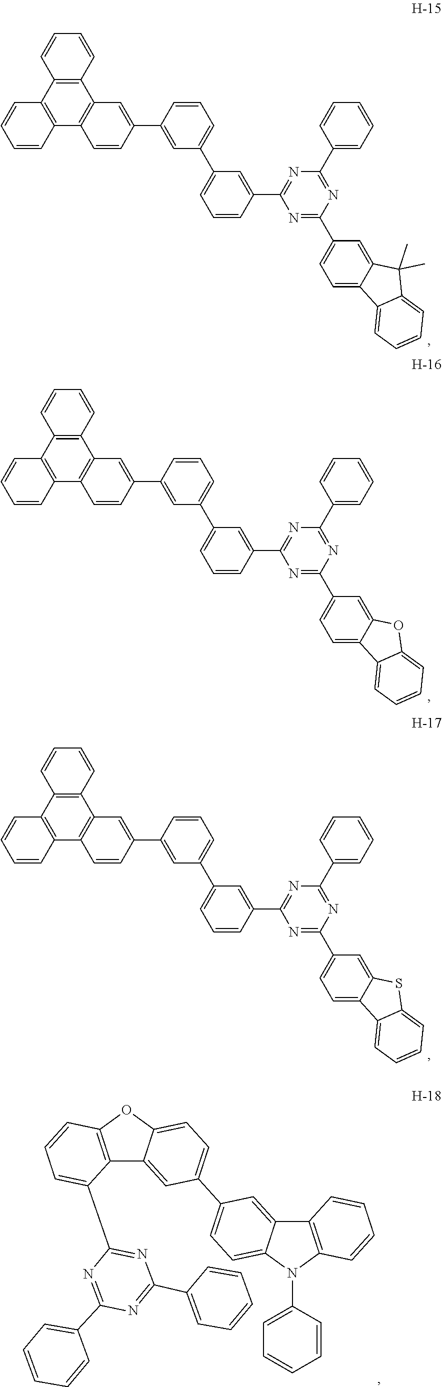 [SMILES: CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1 ; c1ccc(-c2nc(-c3ccccc3)nc(-c3cccc4oc5ccc(-c6ccc7c(c6)c6ccccc6n7-c6ccccc6)cc5c34)n2)cc1]

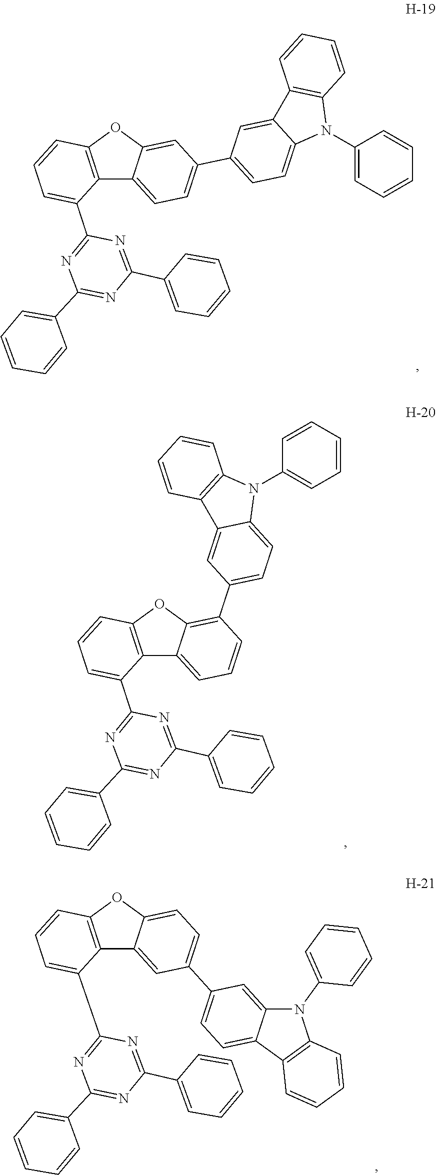 [SMILES: c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1 ; c1ccc(-c2nc(-c3ccccc3)nc(-c3cccc4oc5ccc(-c6ccc7c8ccccc8n(-c8ccccc8)c7c6)cc5c34)n2)cc1]

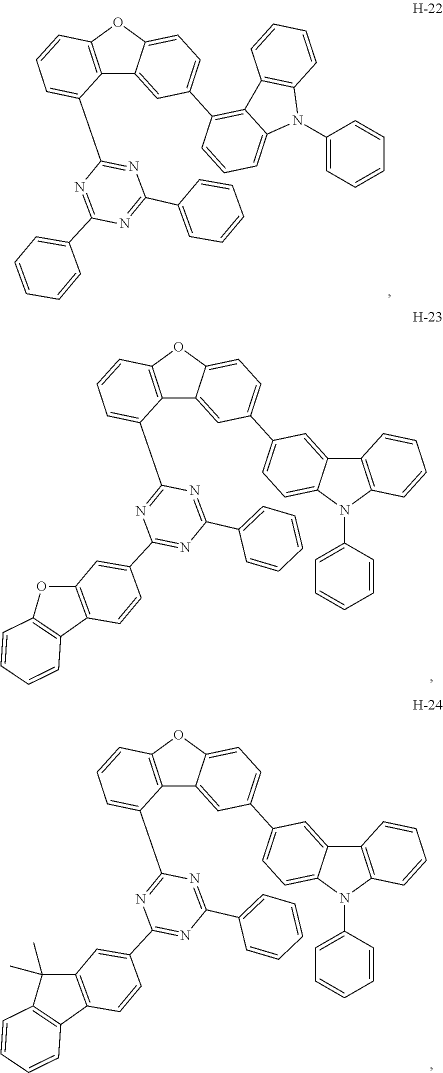 [SMILES: c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1 ; CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21]

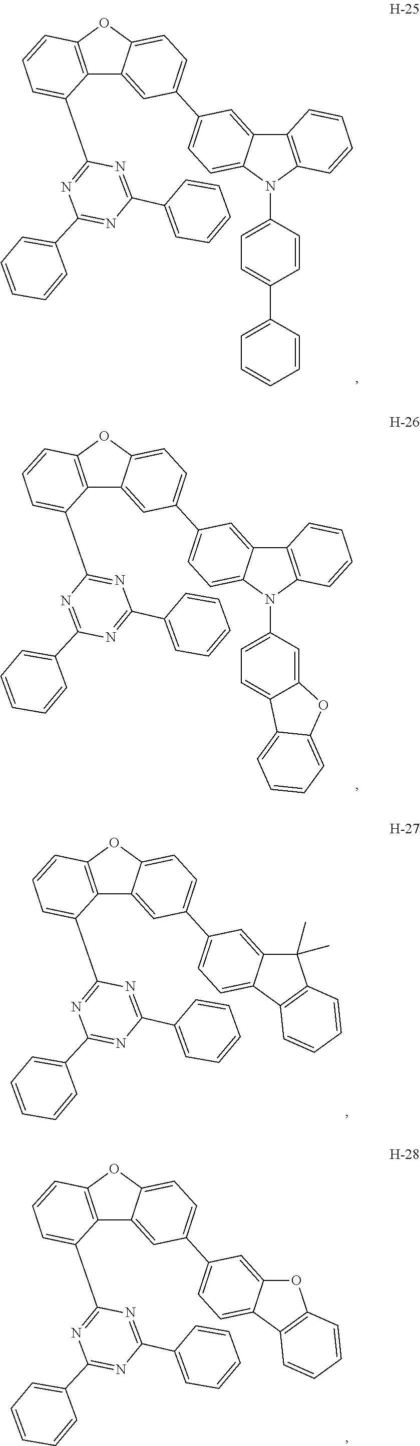 [SMILES: c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1 ; CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1]

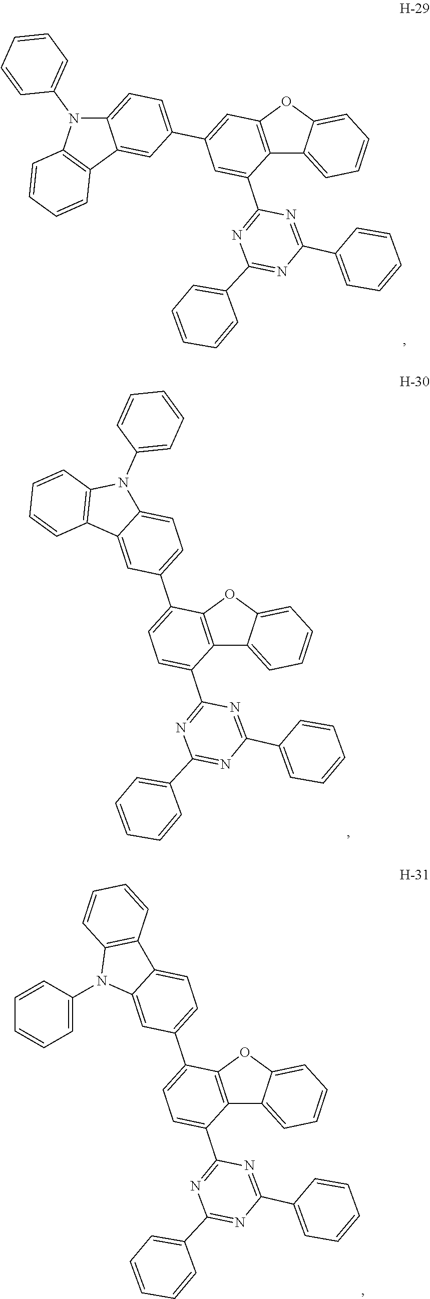 [SMILES: c1ccc(-c2nc(-c3ccccc3)nc(-c3cc(-c4ccc5c(c4)c4ccccc4n5-c4ccccc4)cc4oc5ccccc5c34)n2)cc1 ; c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1]

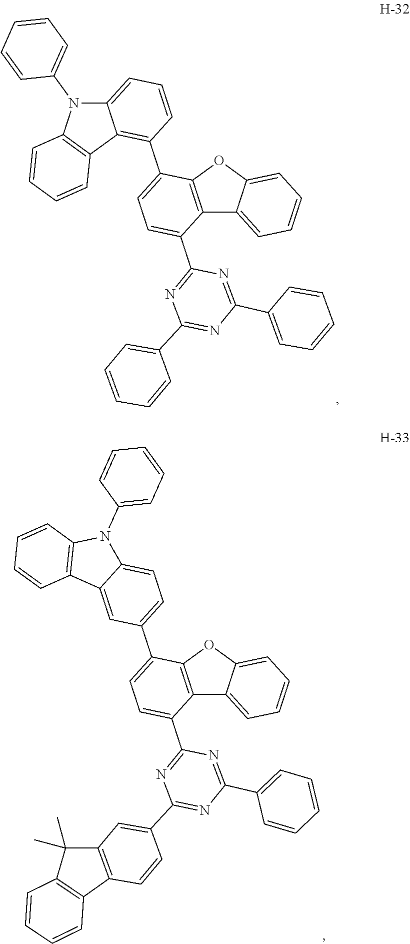

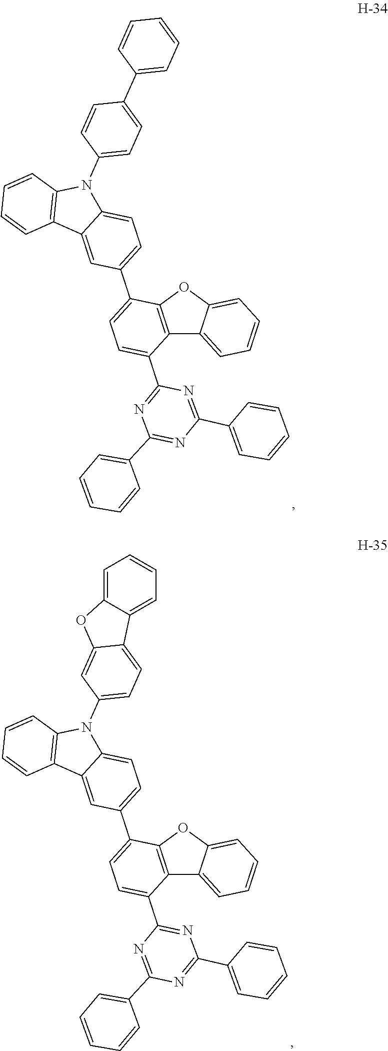 [SMILES: c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1 ; c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1]

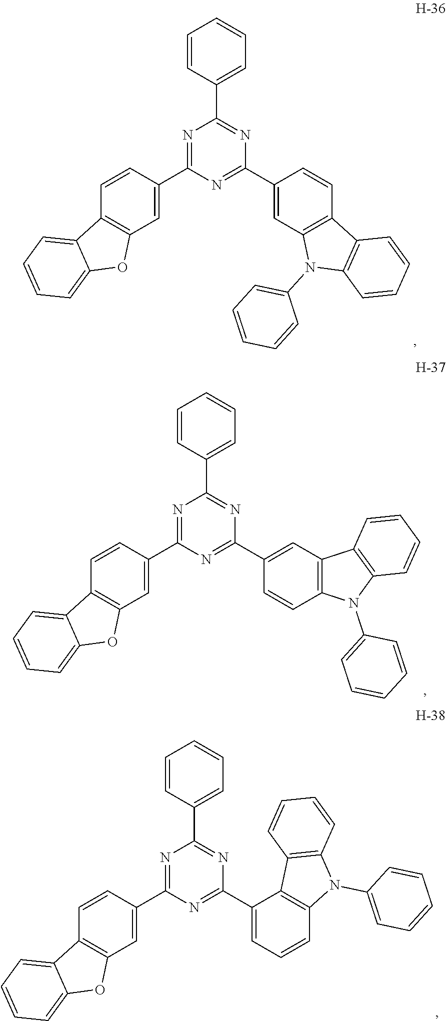 [SMILES: c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1 ; c1ccc(-c2nc(-c3ccc4c(c3)oc3ccccc34)nc(-c3cccc4c3c3ccccc3n4-c3ccccc3)n2)cc1]

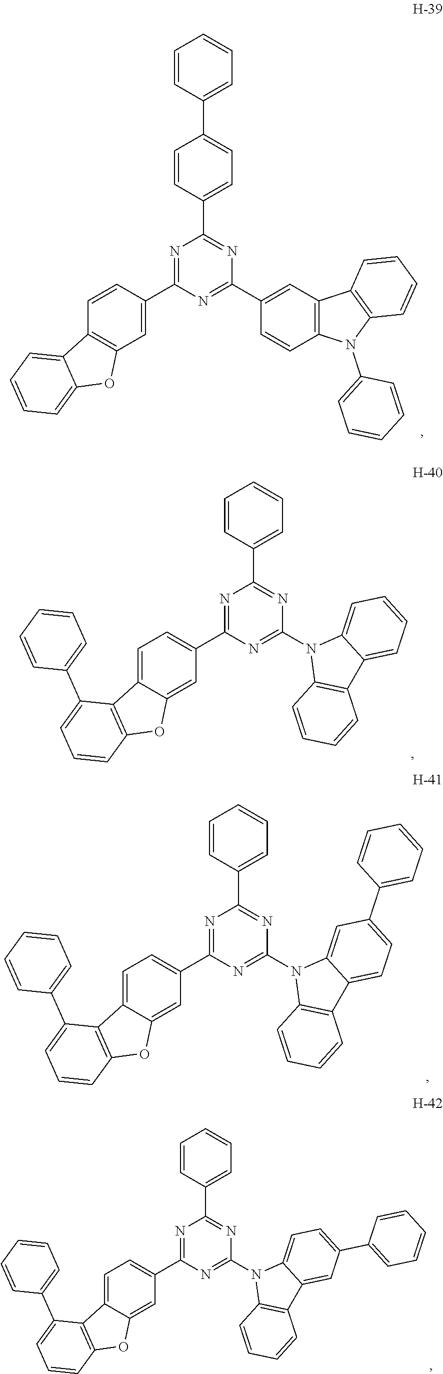 [SMILES: c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1]

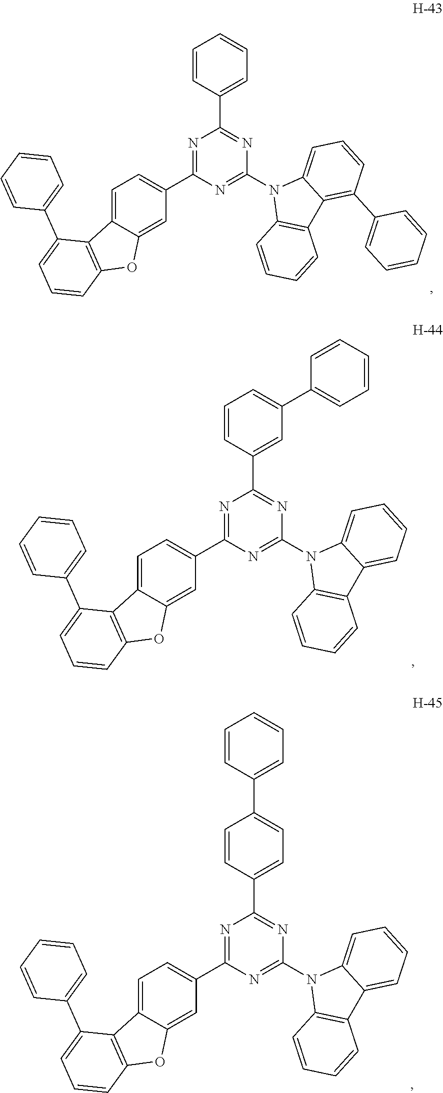 [SMILES: c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1 ; c1ccc(-c2ccc(-c3nc(-c4ccc5c(c4)oc4cccc(-c6ccccc6)c45)nc(-n4c5ccccc5c5ccccc54)n3)cc2)cc1]

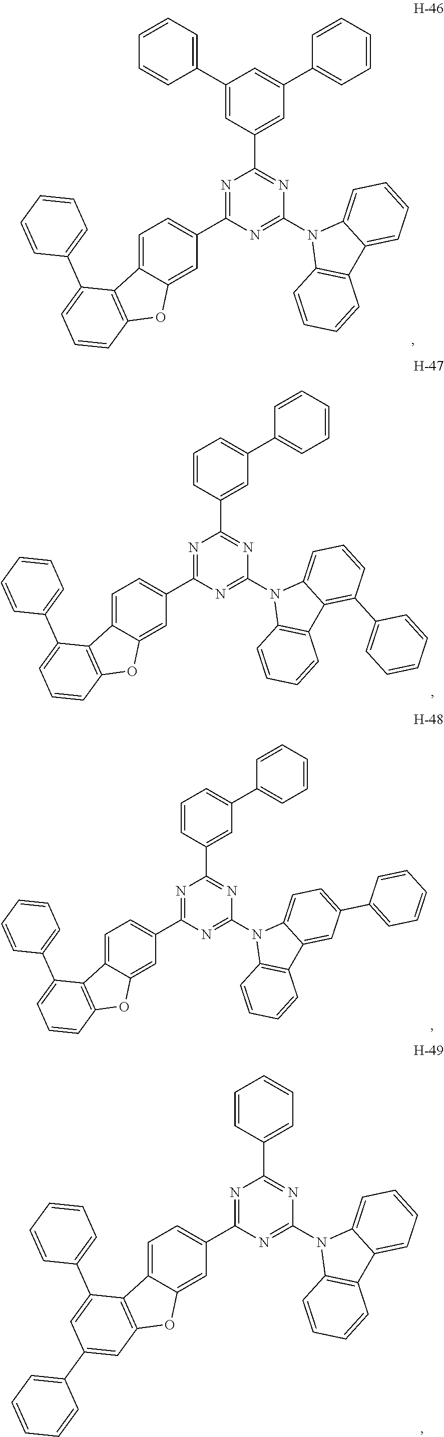 [SMILES: c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1 ; c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1]

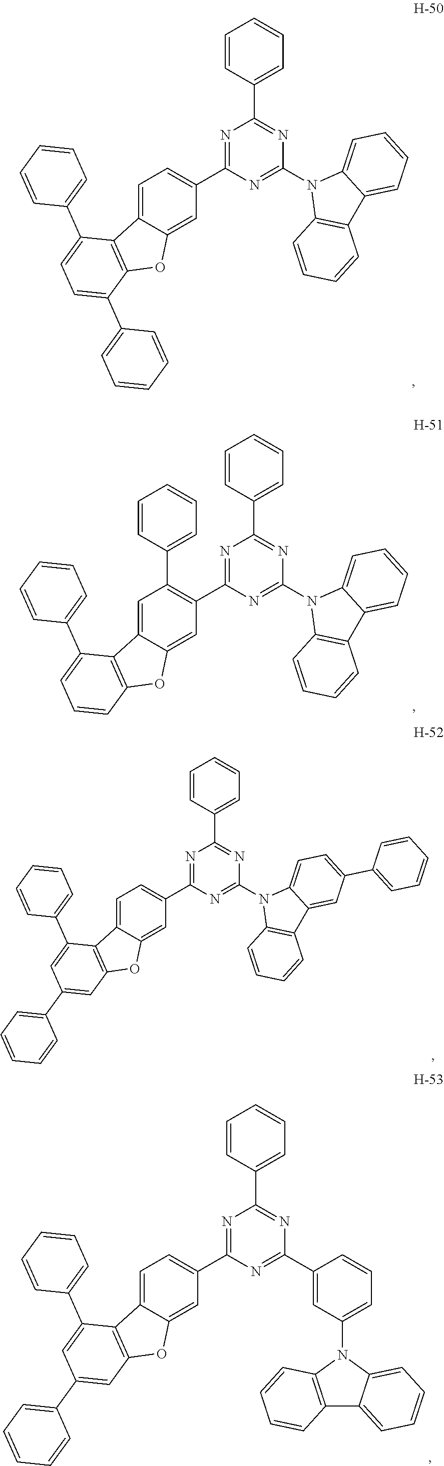 [SMILES: c1ccc(-c2nc(-c3ccc4c(c3)oc3c(-c5ccccc5)ccc(-c5ccccc5)c34)nc(-n3c4ccccc4c4ccccc43)n2)cc1 ; c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1]

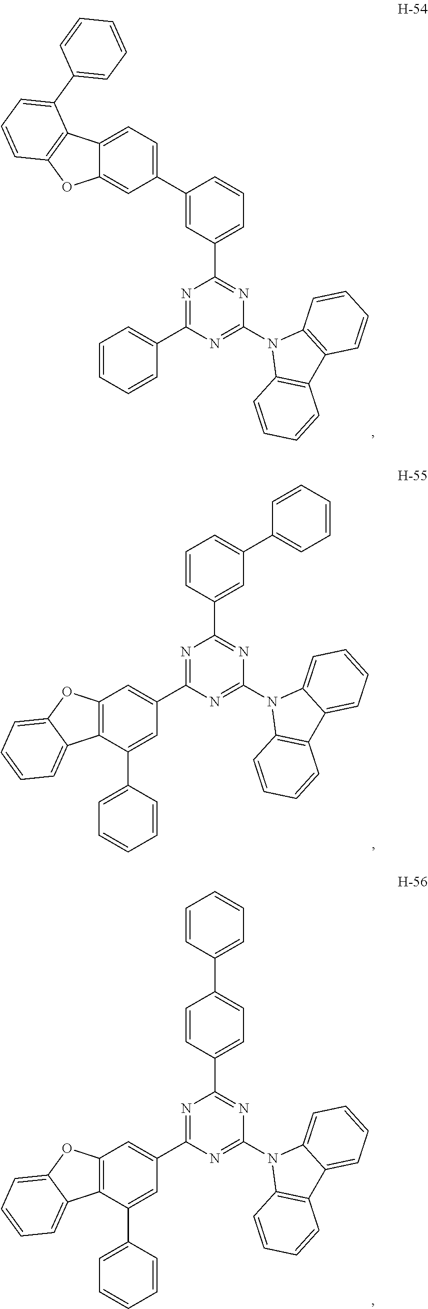

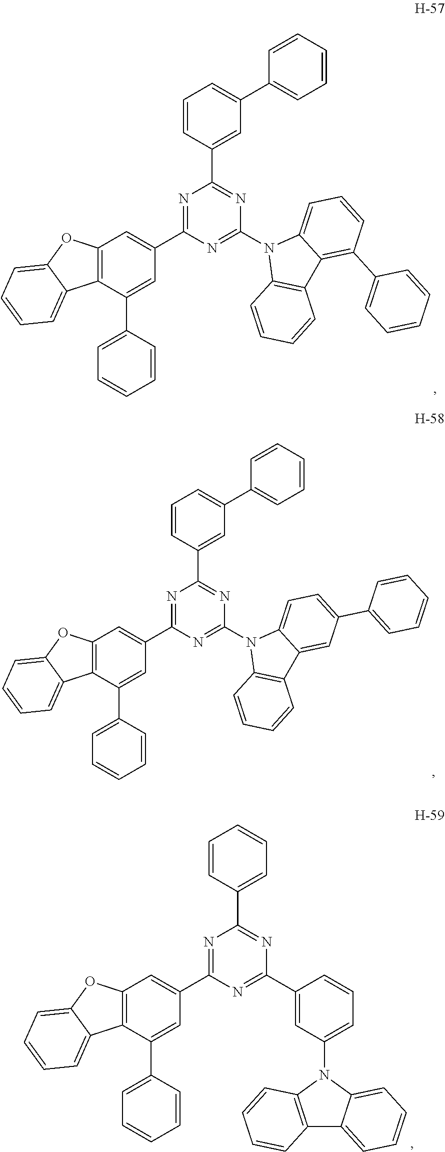 [SMILES: c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3cc(-c4ccccc4)c4c(c3)oc3ccccc34)n2)cc1]

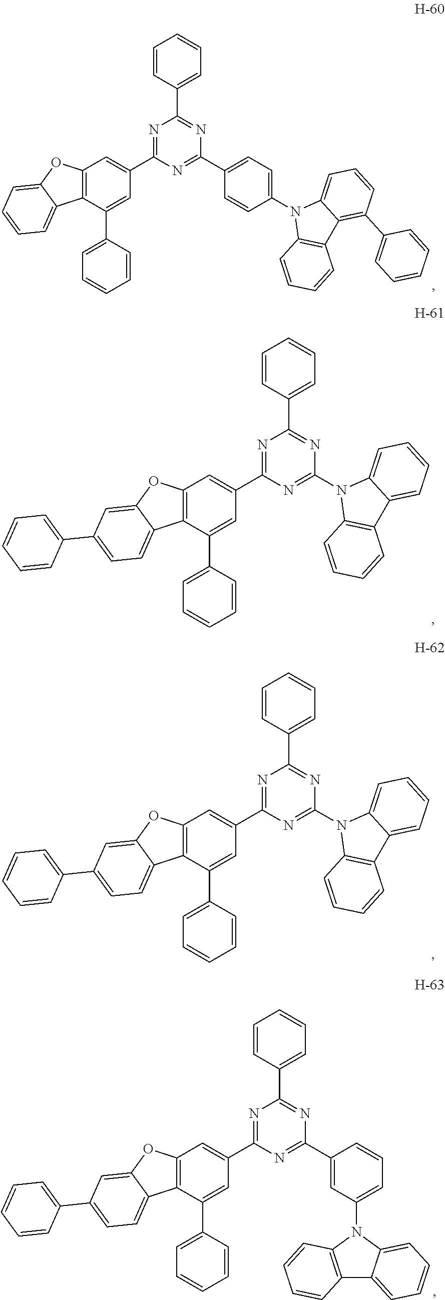 [SMILES: c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1]

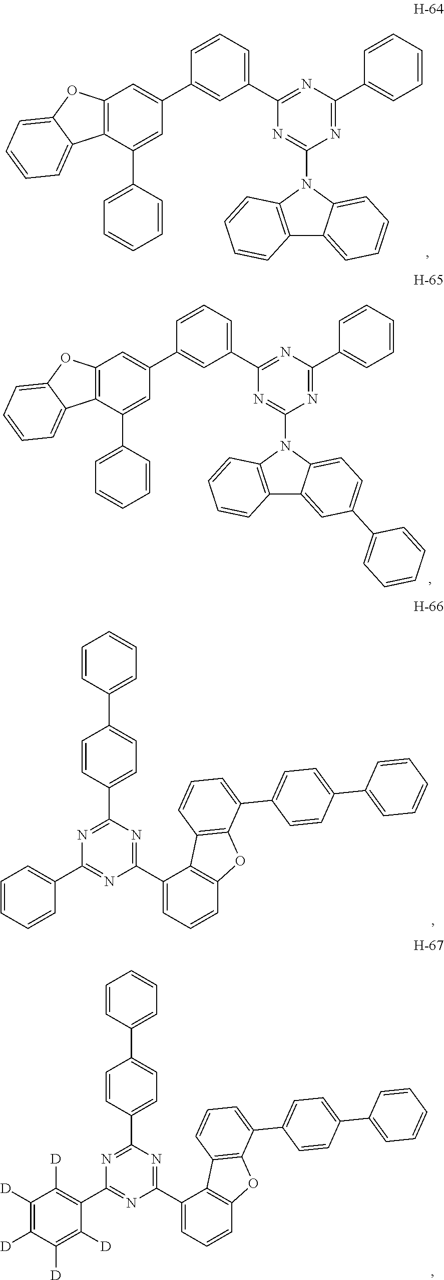 [SMILES: c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1 ; c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H]]

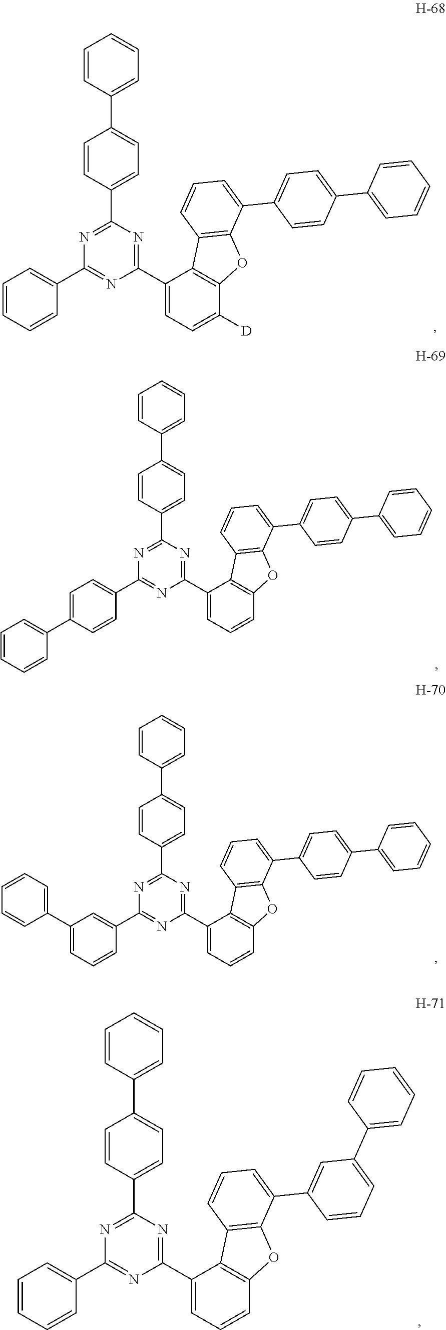 [SMILES: [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1]

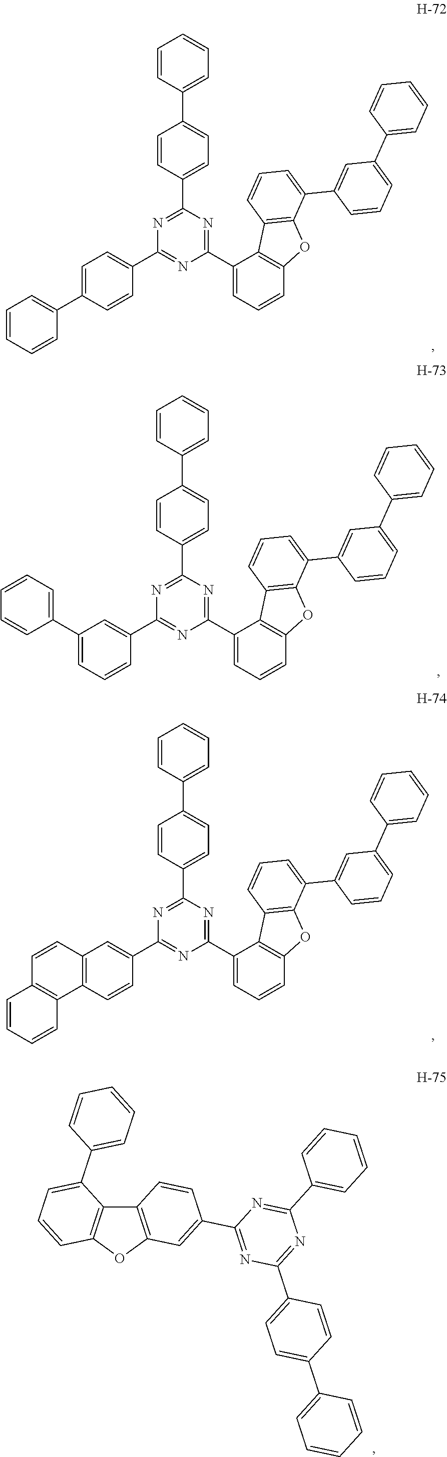 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1]

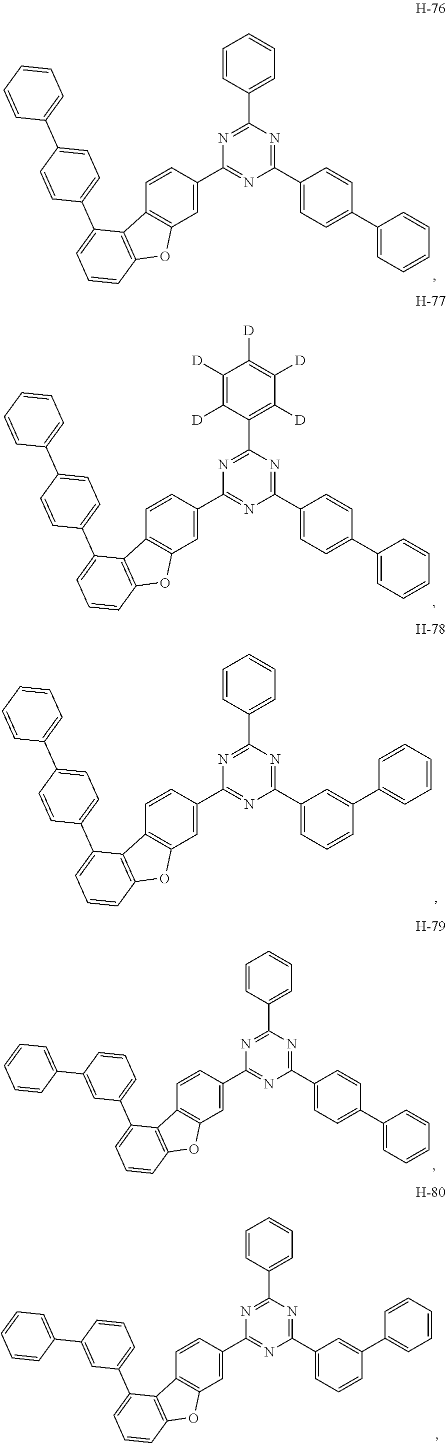 [SMILES: c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1]

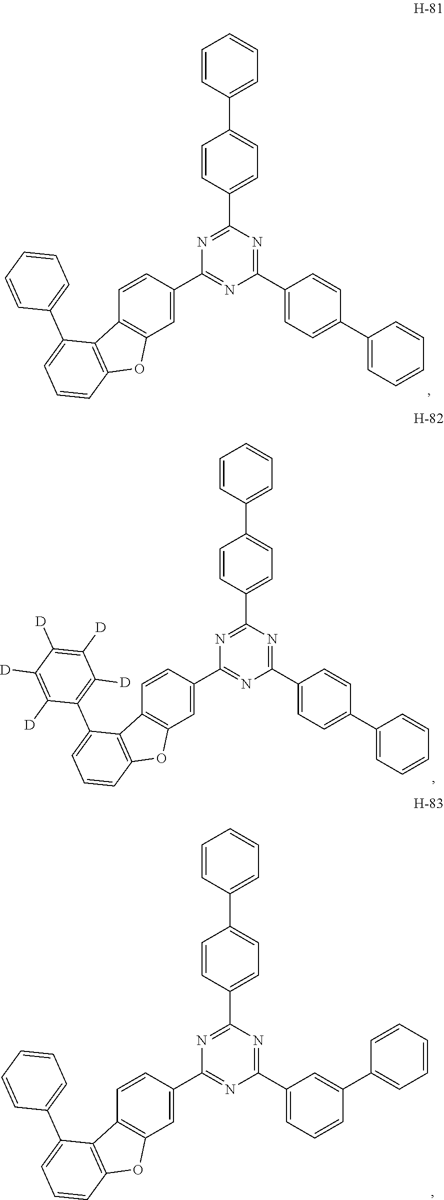 [SMILES: c1ccc(-c2ccc(-c3nc(-c4ccc(-c5ccccc5)cc4)nc(-c4ccc5c(c4)oc4cccc(-c6ccccc6)c45)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1]

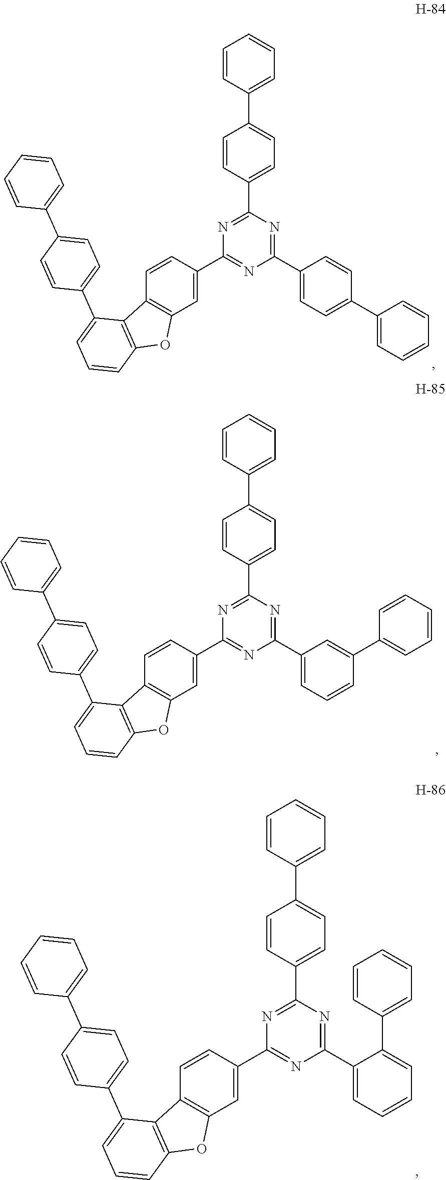 [SMILES: c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1]

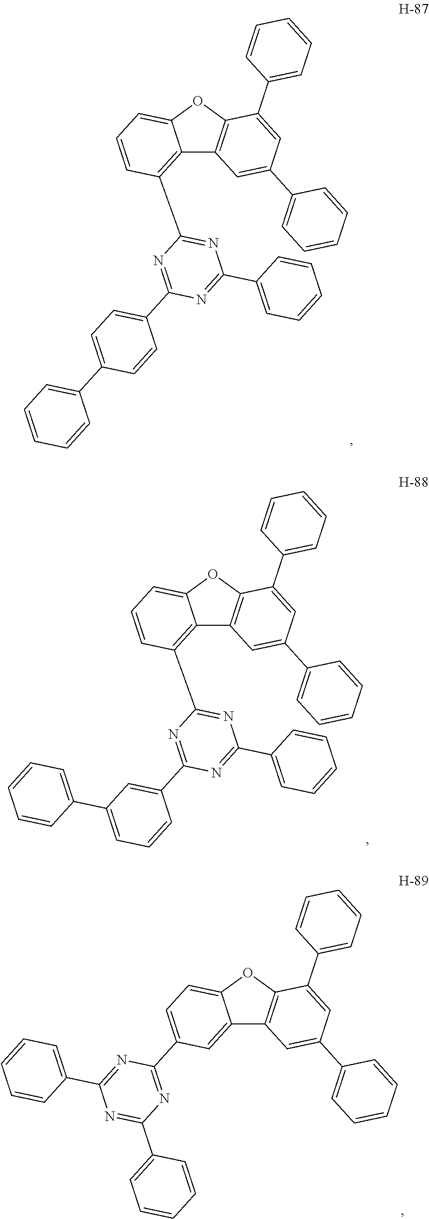 [SMILES: c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1]

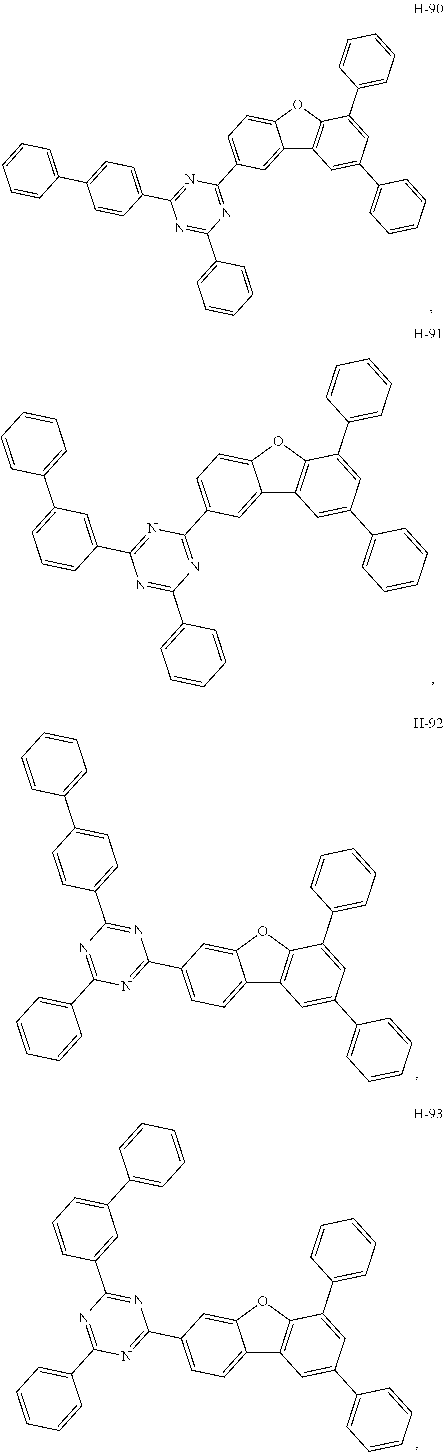 [SMILES: c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1]

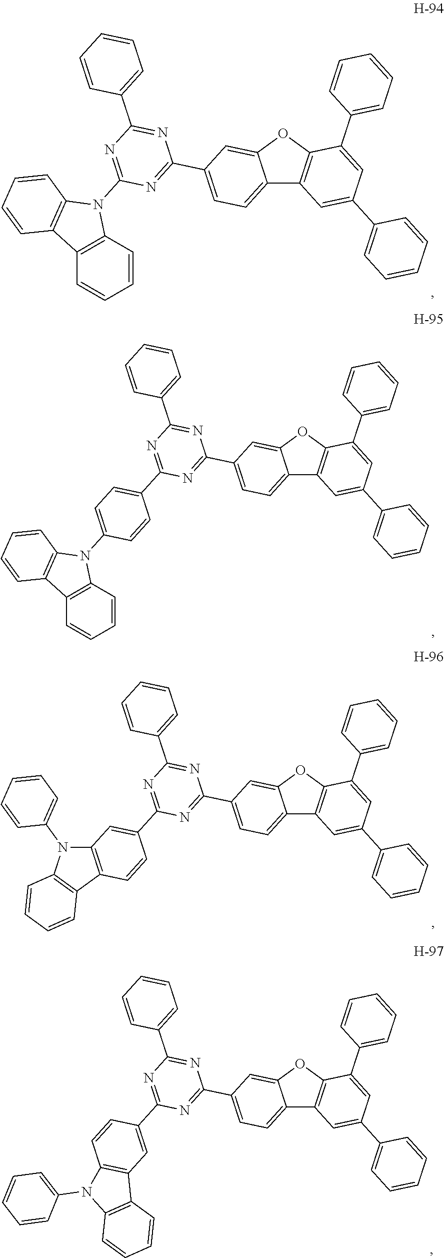 [SMILES: c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1]

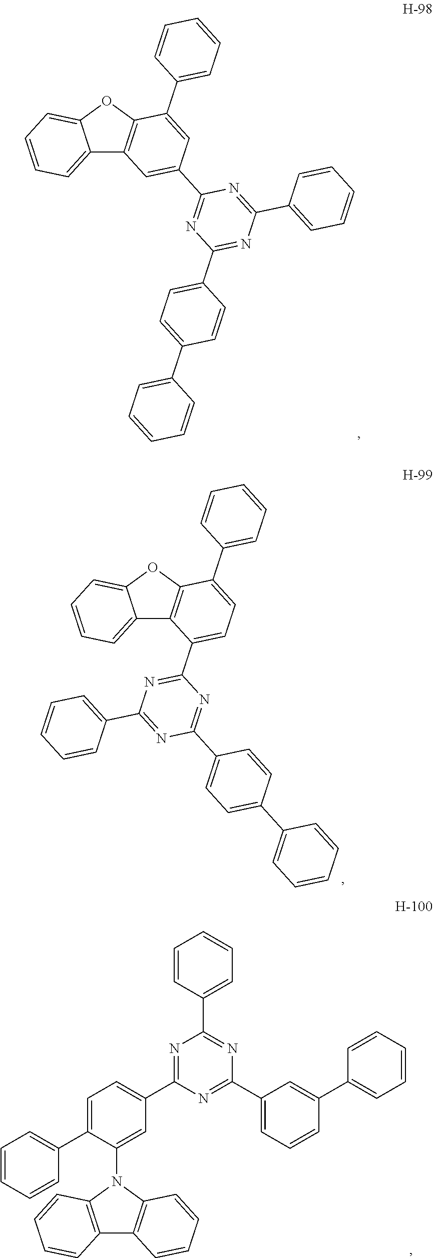 [SMILES: c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1]

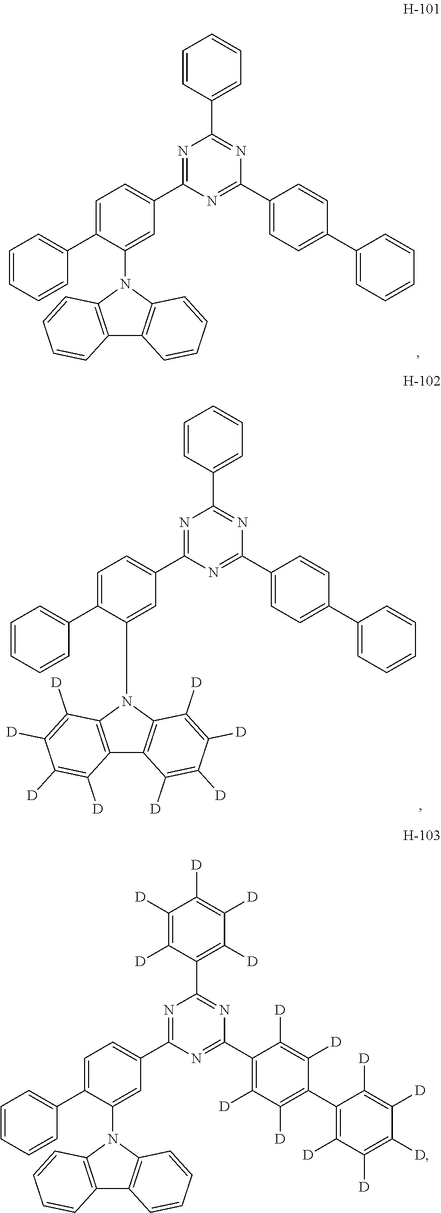

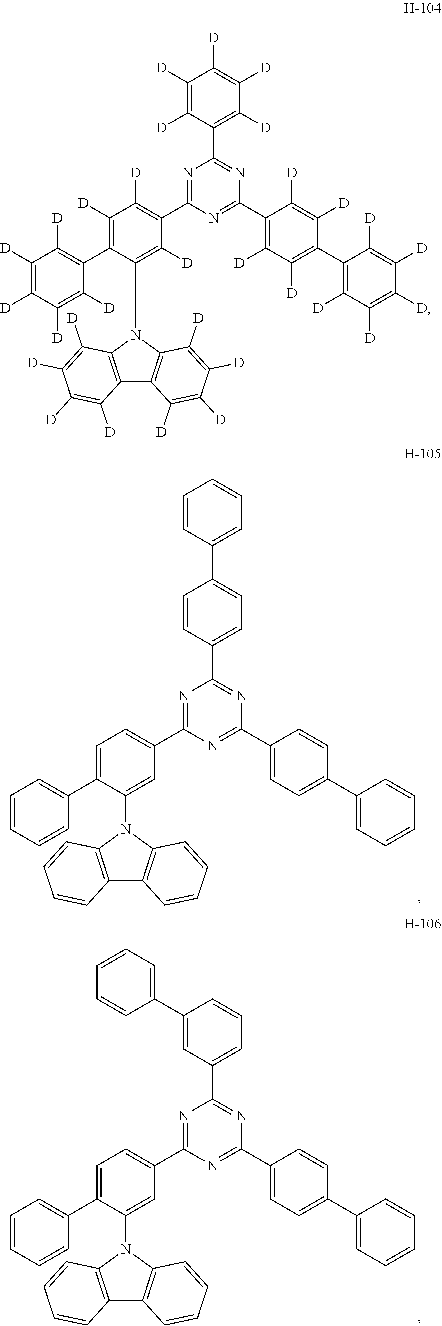

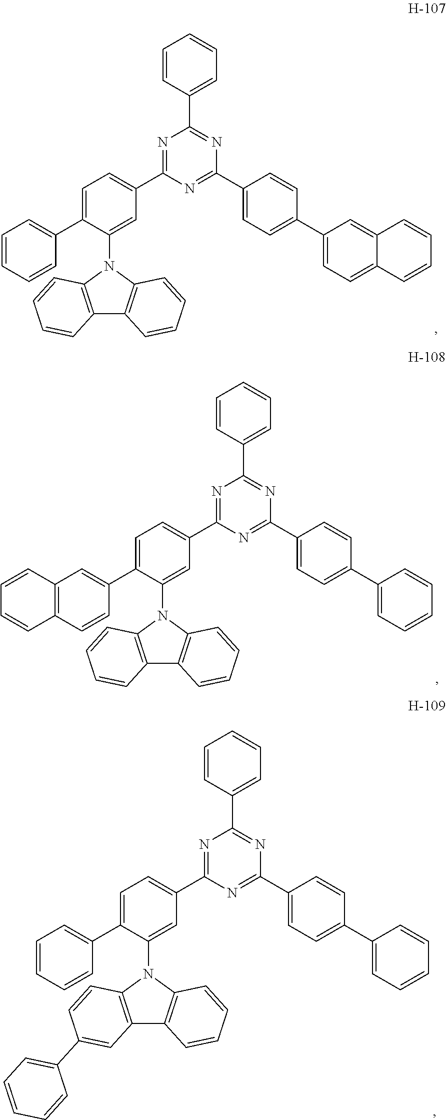 [SMILES: c1ccc(-c2nc(-c3ccc(-c4ccc5ccccc5c4)cc3)nc(-c3ccc(-c4ccccc4)c(-n4c5ccccc5c5ccccc54)c3)n2)cc1 ; c1ccc(-c2ccc(-c3nc(-c4ccccc4)nc(-c4ccc(-c5ccc6ccccc6c5)c(-n5c6ccccc6c6ccccc65)c4)n3)cc2)cc1 ; c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1]

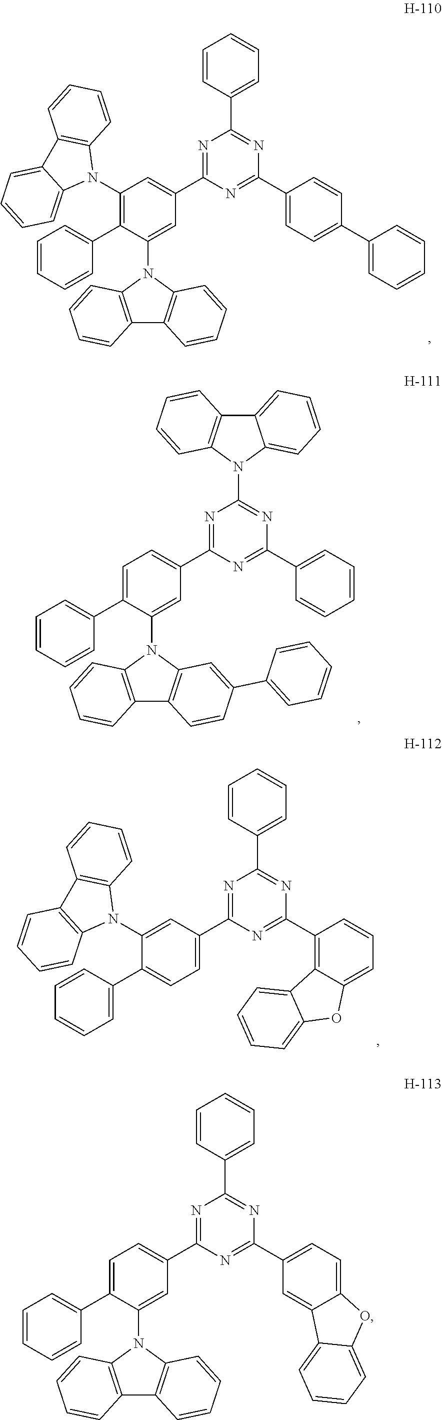

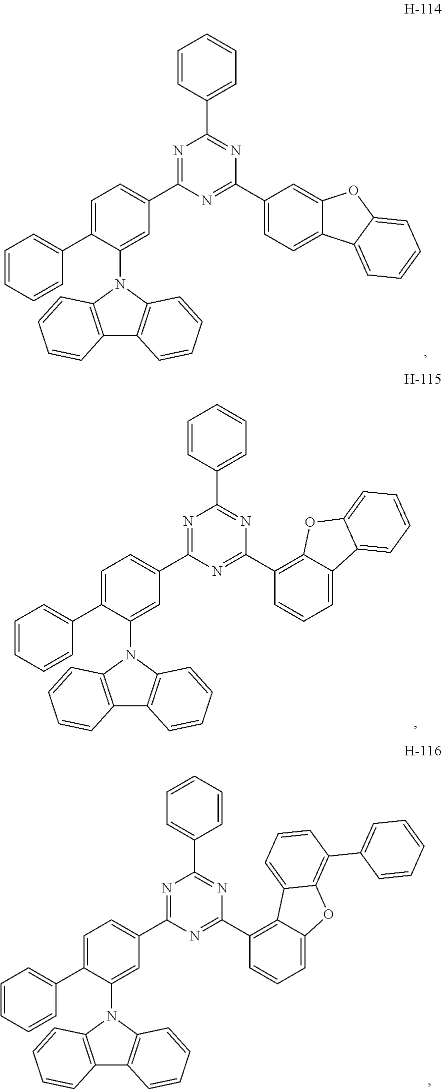 [SMILES: c1ccc(-c2nc(-c3ccc(-c4ccccc4)c(-n4c5ccccc5c5ccccc54)c3)nc(-c3ccc4c(c3)oc3ccccc34)n2)cc1 ; c1ccc(-c2nc(-c3ccc(-c4ccccc4)c(-n4c5ccccc5c5ccccc54)c3)nc(-c3cccc4c3oc3ccccc34)n2)cc1 ; c1ccc(-c2nc(-c3ccc(-c4ccccc4)c(-n4c5ccccc5c5ccccc54)c3)nc(-c3cccc4oc5c(-c6ccccc6)cccc5c34)n2)cc1]

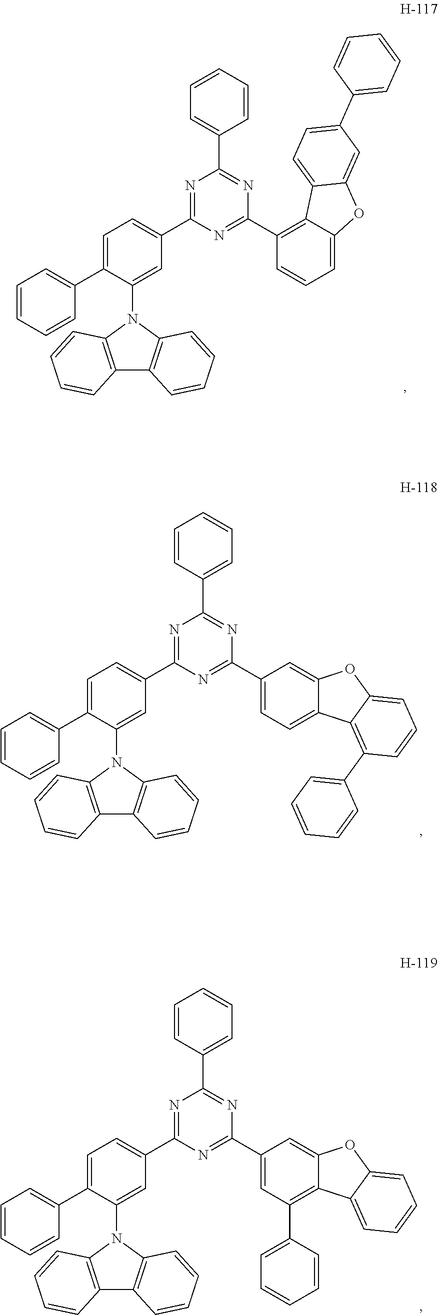 [SMILES: c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1 ; c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1]

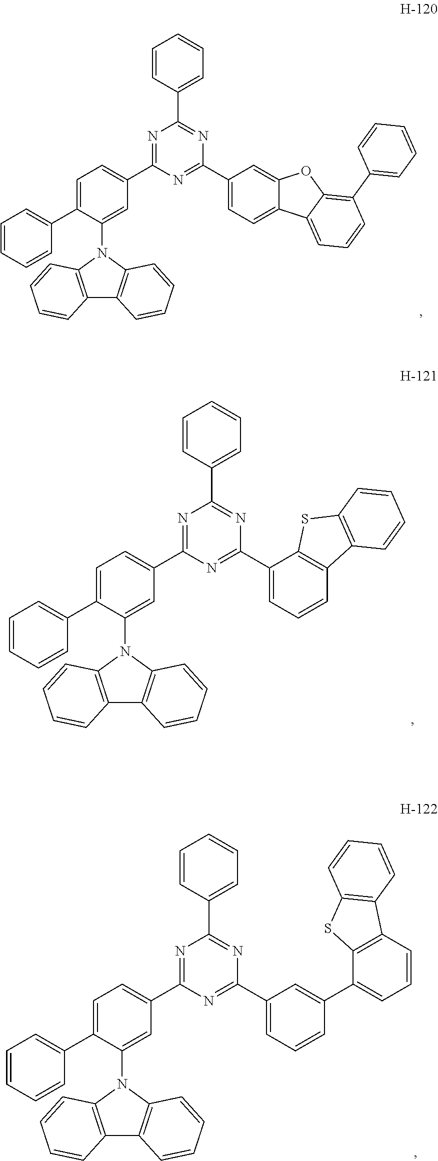 [SMILES: c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1 ; c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3cccc(-c4cccc5c4sc4ccccc45)c3)nc(-c3ccc(-c4ccccc4)c(-n4c5ccccc5c5ccccc54)c3)n2)cc1]

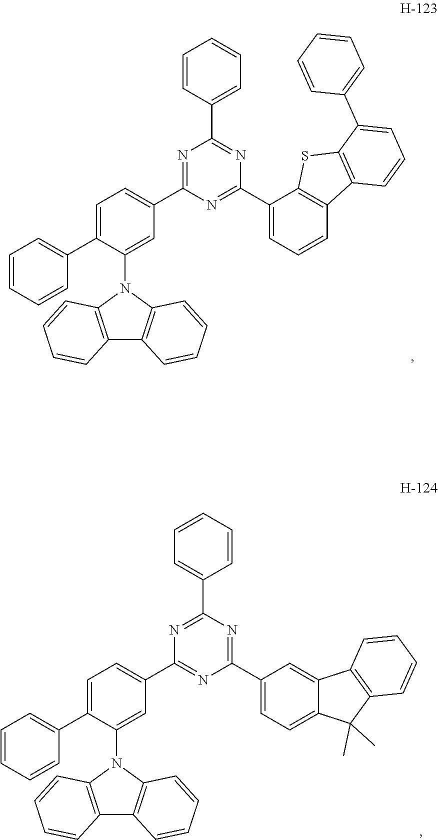 [SMILES: c1ccc(-c2nc(-c3ccc(-c4ccccc4)c(-n4c5ccccc5c5ccccc54)c3)nc(-c3cccc4c3sc3c(-c5ccccc5)cccc34)n2)cc1 ; CC1(C)c2ccccc2-c2cc(-c3nc(-c4ccccc4)nc(-c4ccc(-c5ccccc5)c(-n5c6ccccc6c6ccccc65)c4)n3)ccc21]

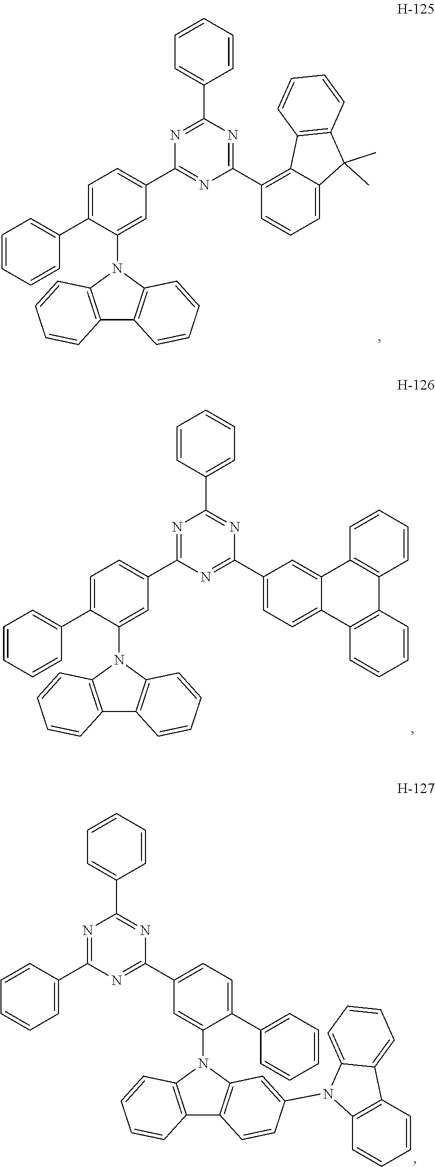 [SMILES: CC1(C)c2ccccc2-c2c(-c3nc(-c4ccccc4)nc(-c4ccc(-c5ccccc5)c(-n5c6ccccc6c6ccccc65)c4)n3)cccc21 ; c1ccc(-c2nc(-c3ccc(-c4ccccc4)c(-n4c5ccccc5c5ccccc54)c3)nc(-c3ccc4c5ccccc5c5ccccc5c4c3)n2)cc1 ; c1ccc(-c2nc(-c3ccccc3)nc(-c3ccc(-c4ccccc4)c(-n4c5ccccc5c5ccc(-n6c7ccccc7c7ccccc76)cc54)c3)n2)cc1]

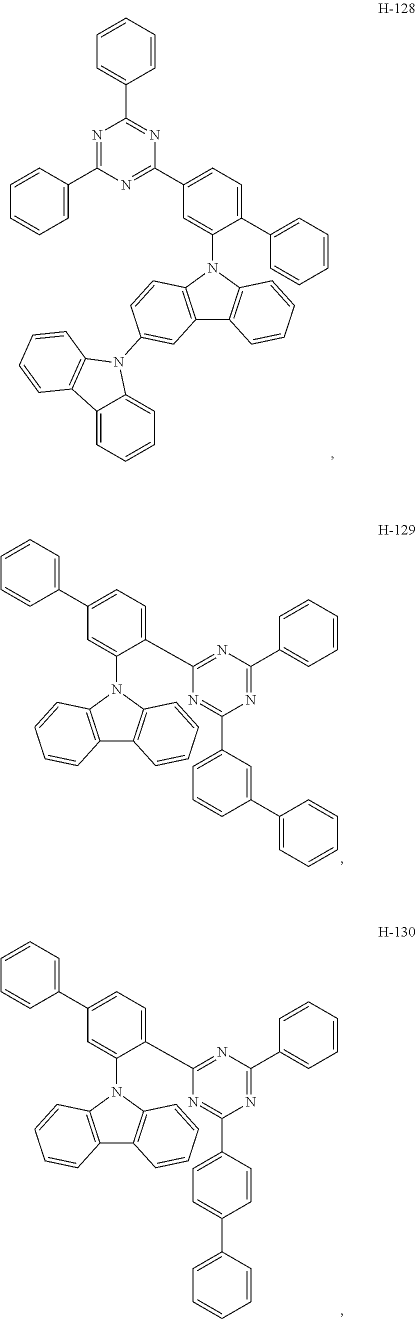 [SMILES: c1ccc(-c2nc(-c3ccccc3)nc(-c3ccc(-c4ccccc4)c(-n4c5ccccc5c5cc(-n6c7ccccc7c7ccccc76)ccc54)c3)n2)cc1 ; c1ccc(-c2cccc(-c3nc(-c4ccccc4)nc(-c4ccc(-c5ccccc5)cc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)cc2)cc1]

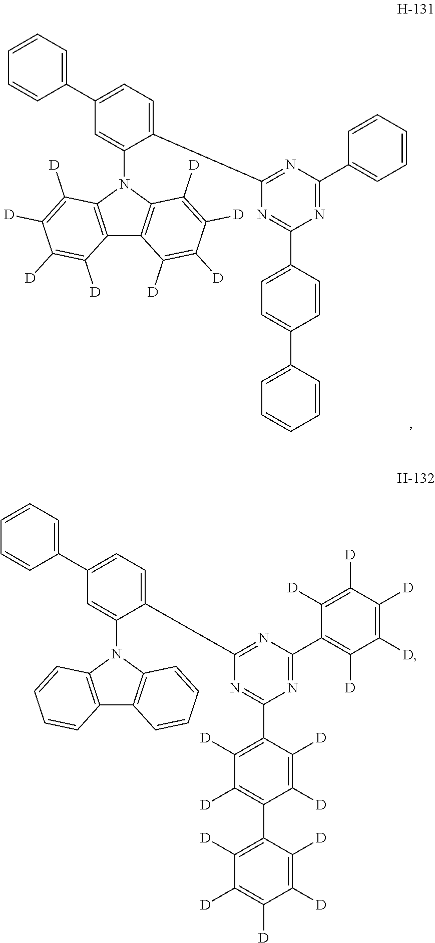

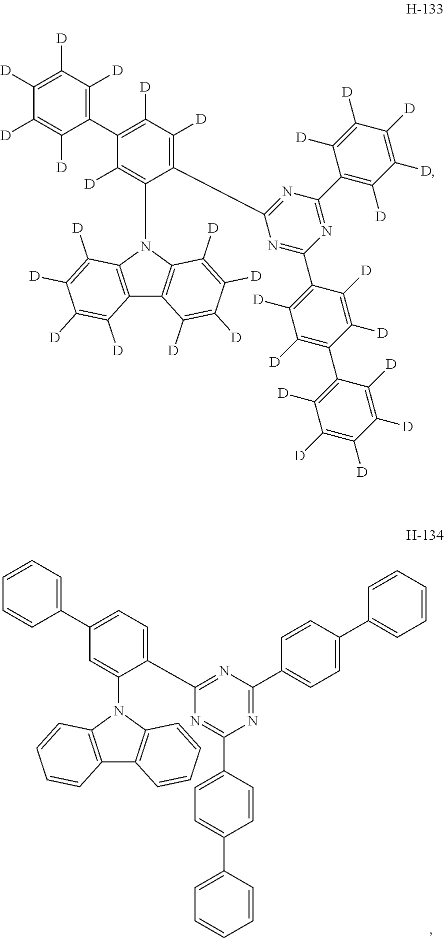

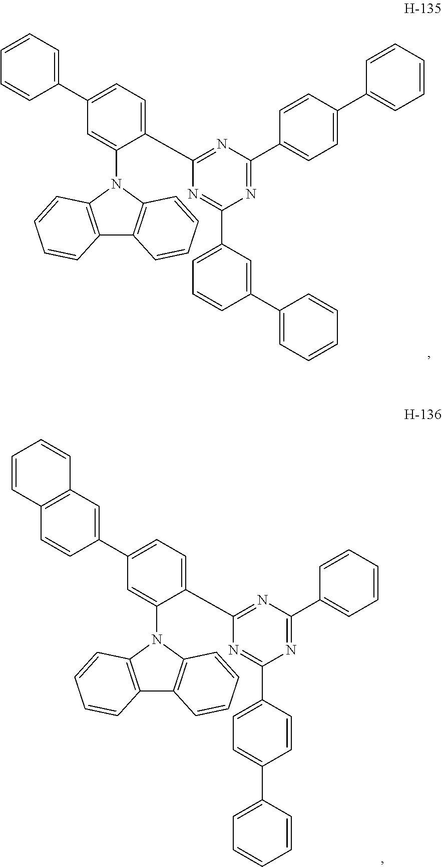 [SMILES: c1ccc(-c2ccc(-c3nc(-c4cccc(-c5ccccc5)c4)nc(-c4ccc(-c5ccccc5)cc4-n4c5ccccc5c5ccccc54)n3)cc2)cc1 ; c1ccc(-c2ccc(-c3nc(-c4ccccc4)nc(-c4ccc(-c5ccc6ccccc6c5)cc4-n4c5ccccc5c5ccccc54)n3)cc2)cc1]

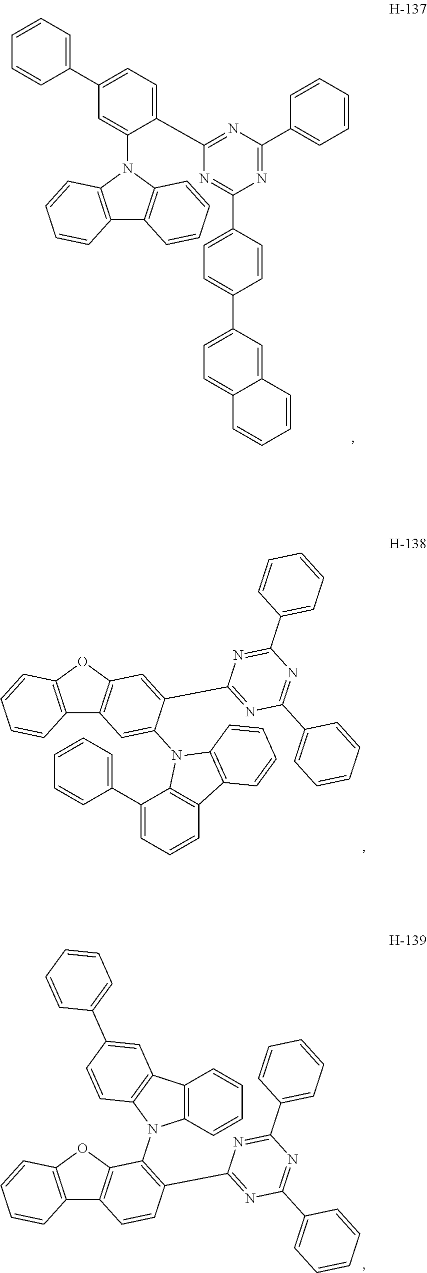 [SMILES: c1ccc(-c2ccc(-c3nc(-c4ccccc4)nc(-c4ccc(-c5ccc6ccccc6c5)cc4)n3)c(-n3c4ccccc4c4ccccc43)c2)cc1 ; c1ccc(-c2nc(-c3ccccc3)nc(-c3cc4oc5ccccc5c4cc3-n3c4ccccc4c4cccc(-c5ccccc5)c43)n2)cc1 ; c1ccc(-c2ccc3c(c2)c2ccccc2n3-c2c(-c3nc(-c4ccccc4)nc(-c4ccccc4)n3)ccc3c2oc2ccccc23)cc1]

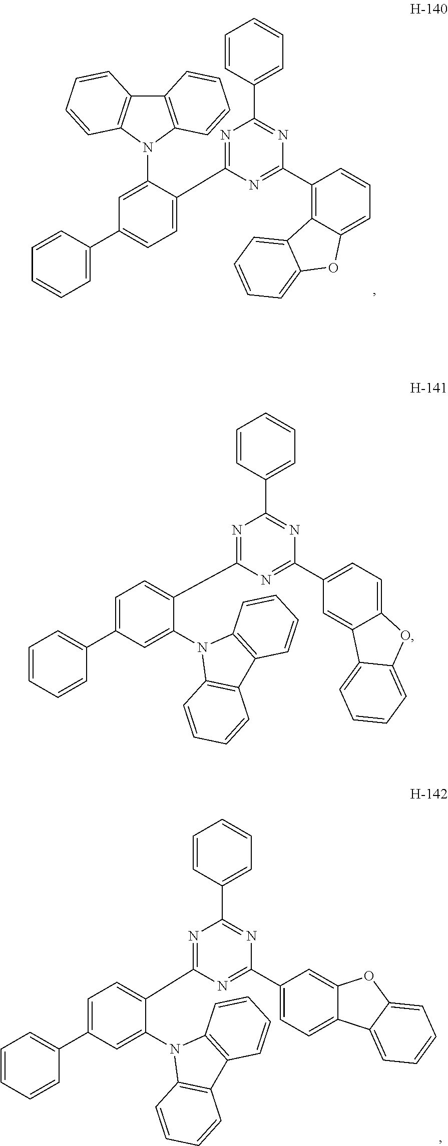 [SMILES: c1ccc(-c2ccc(-c3nc(-c4ccccc4)nc(-c4cccc5oc6ccccc6c45)n3)c(-n3c4ccccc4c4ccccc43)c2)cc1 ; c1ccc(-c2ccc(-c3nc(-c4ccccc4)nc(-c4ccc5oc6ccccc6c5c4)n3)c(-n3c4ccccc4c4ccccc43)c2)cc1 ; c1ccc(-c2ccc(-c3nc(-c4ccccc4)nc(-c4ccc5c(c4)oc4ccccc45)n3)c(-n3c4ccccc4c4ccccc43)c2)cc1]

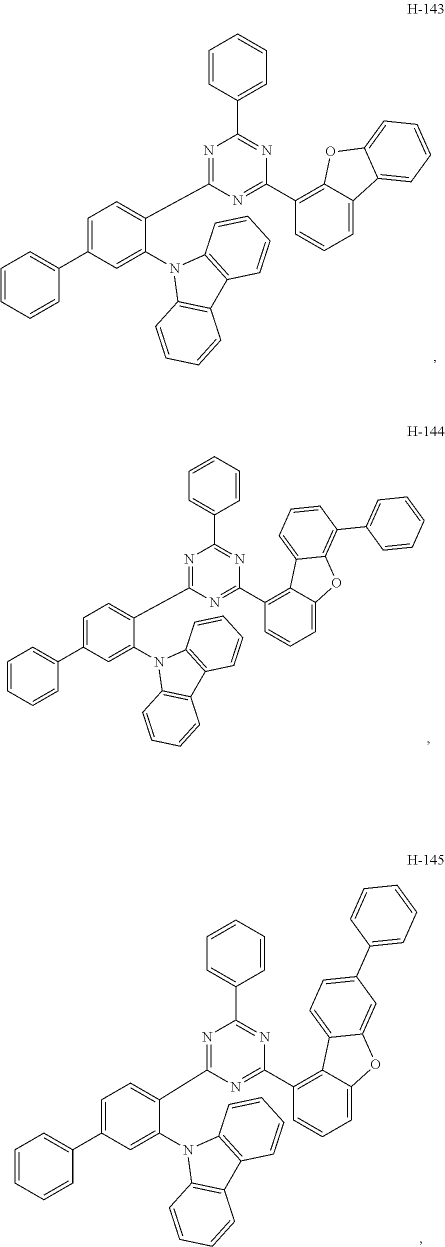 [SMILES: c1ccc(-c2ccc(-c3nc(-c4ccccc4)nc(-c4cccc5c4oc4ccccc45)n3)c(-n3c4ccccc4c4ccccc43)c2)cc1 ; c1ccc(-c2ccc(-c3nc(-c4ccccc4)nc(-c4cccc5oc6c(-c7ccccc7)cccc6c45)n3)c(-n3c4ccccc4c4ccccc43)c2)cc1 ; c1ccc(-c2ccc(-c3nc(-c4ccccc4)nc(-c4cccc5oc6cc(-c7ccccc7)ccc6c45)n3)c(-n3c4ccccc4c4ccccc43)c2)cc1]

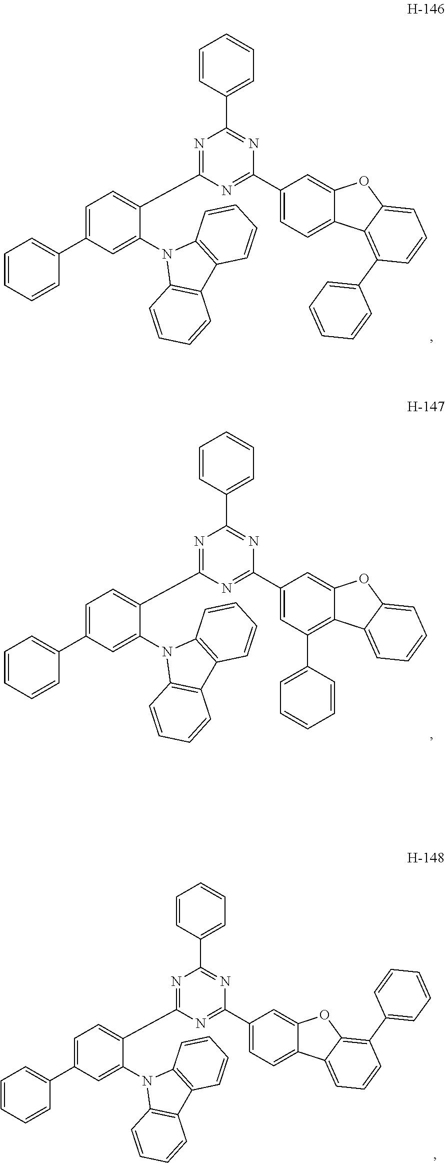 [SMILES: c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1 ; c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1 ; c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1]

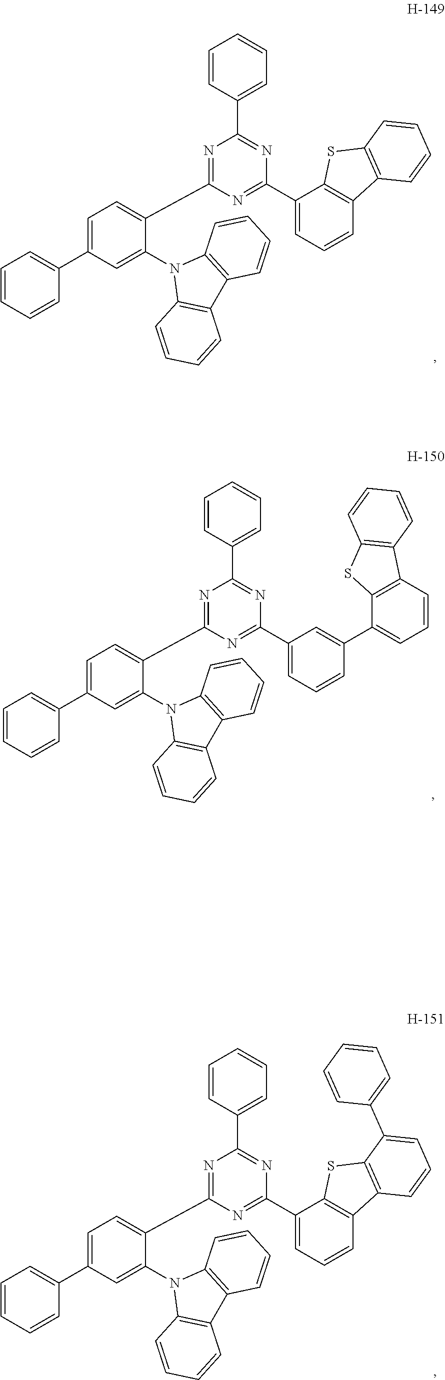 [SMILES: c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1 ; c1ccc(-c2ccc(-c3nc(-c4ccccc4)nc(-c4cccc5c4sc4c(-c6ccccc6)cccc45)n3)c(-n3c4ccccc4c4ccccc43)c2)cc1]

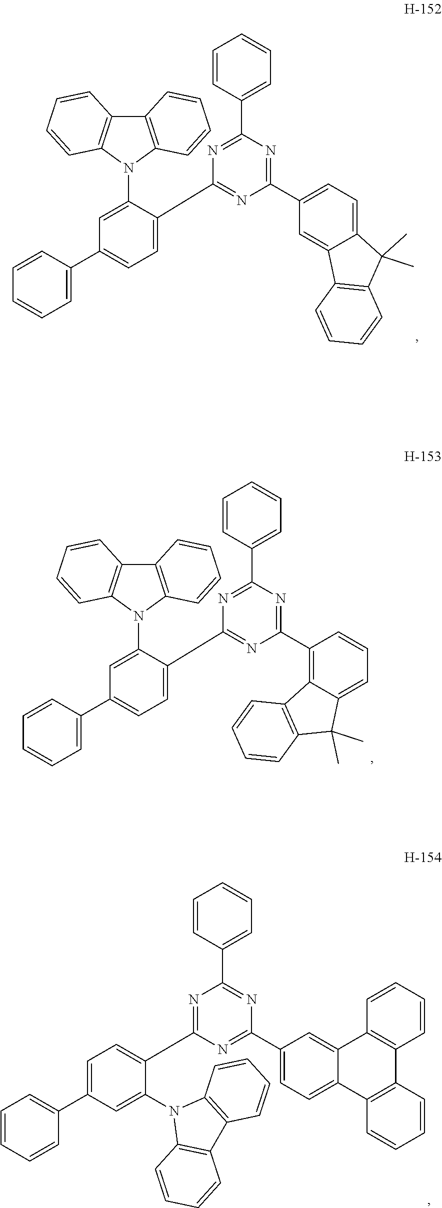 [SMILES: CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21 ; c1ccc(-c2ccc(-c3nc(-c4ccccc4)nc(-c4ccc5c6ccccc6c6ccccc6c5c4)n3)c(-n3c4ccccc4c4ccccc43)c2)cc1]

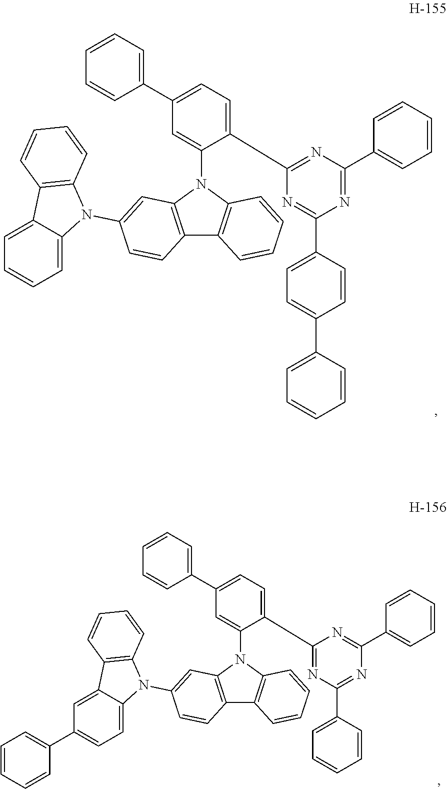 [SMILES: c1ccc(-c2ccc(-c3nc(-c4ccccc4)nc(-c4ccc(-c5ccccc5)cc4-n4c5ccccc5c5ccc(-n6c7ccccc7c7ccccc76)cc54)n3)cc2)cc1 ; c1ccc(-c2ccc(-c3nc(-c4ccccc4)nc(-c4ccccc4)n3)c(-n3c4ccccc4c4ccc(-n5c6ccccc6c6cc(-c7ccccc7)ccc65)cc43)c2)cc1]

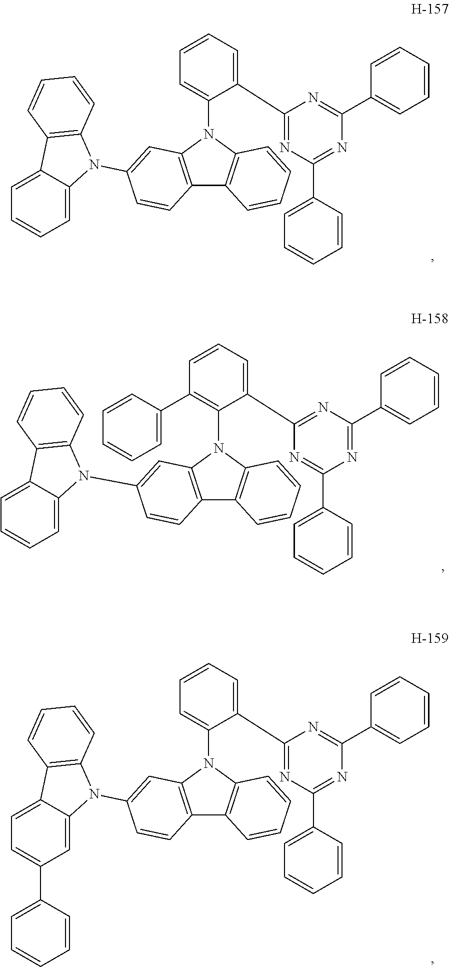 [SMILES: c1ccc(-c2nc(-c3ccccc3)nc(-c3ccccc3-n3c4ccccc4c4ccc(-n5c6ccccc6c6ccccc65)cc43)n2)cc1 ; c1ccc(-c2nc(-c3ccccc3)nc(-c3cccc(-c4ccccc4)c3-n3c4ccccc4c4ccc(-n5c6ccccc6c6ccccc65)cc43)n2)cc1 ; c1ccc(-c2ccc3c4ccccc4n(-c4ccc5c6ccccc6n(-c6ccccc6-c6nc(-c7ccccc7)nc(-c7ccccc7)n6)c5c4)c3c2)cc1]

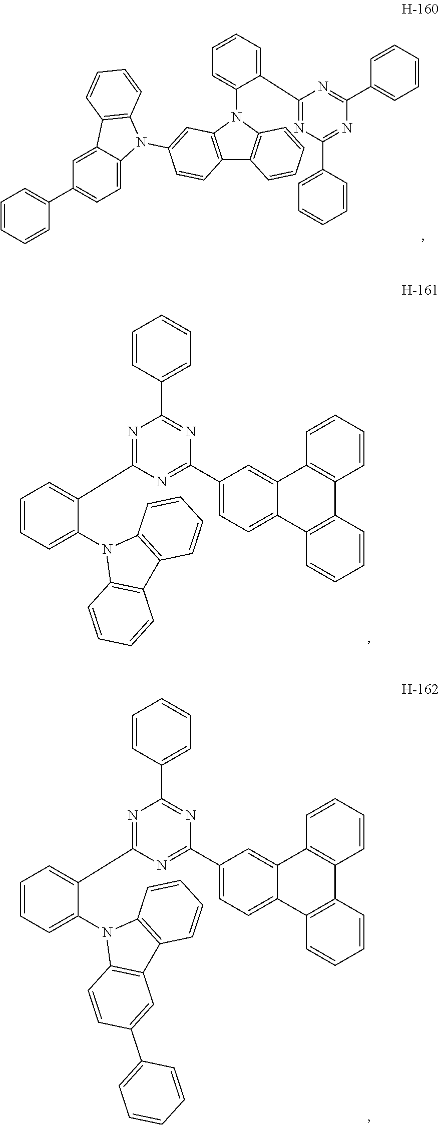 [SMILES: c1ccc(-c2ccc3c(c2)c2ccccc2n3-c2ccc3c4ccccc4n(-c4ccccc4-c4nc(-c5ccccc5)nc(-c5ccccc5)n4)c3c2)cc1 ; c1ccc(-c2nc(-c3ccc4c5ccccc5c5ccccc5c4c3)nc(-c3ccccc3-n3c4ccccc4c4ccccc43)n2)cc1 ; c1ccc(-c2ccc3c(c2)c2ccccc2n3-c2ccccc2-c2nc(-c3ccccc3)nc(-c3ccc4c5ccccc5c5ccccc5c4c3)n2)cc1]

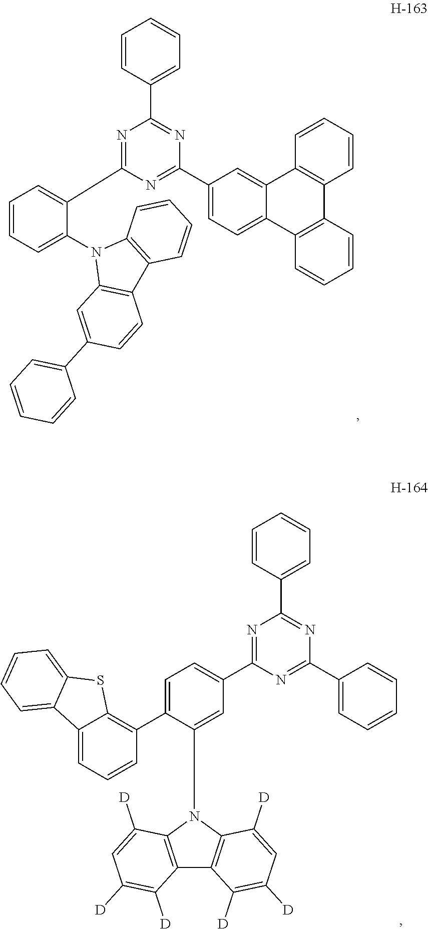 [SMILES: c1ccc(-c2ccc3c4ccccc4n(-c4ccccc4-c4nc(-c5ccccc5)nc(-c5ccc6c7ccccc7c7ccccc7c6c5)n4)c3c2)cc1 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1sc1ccccc12]

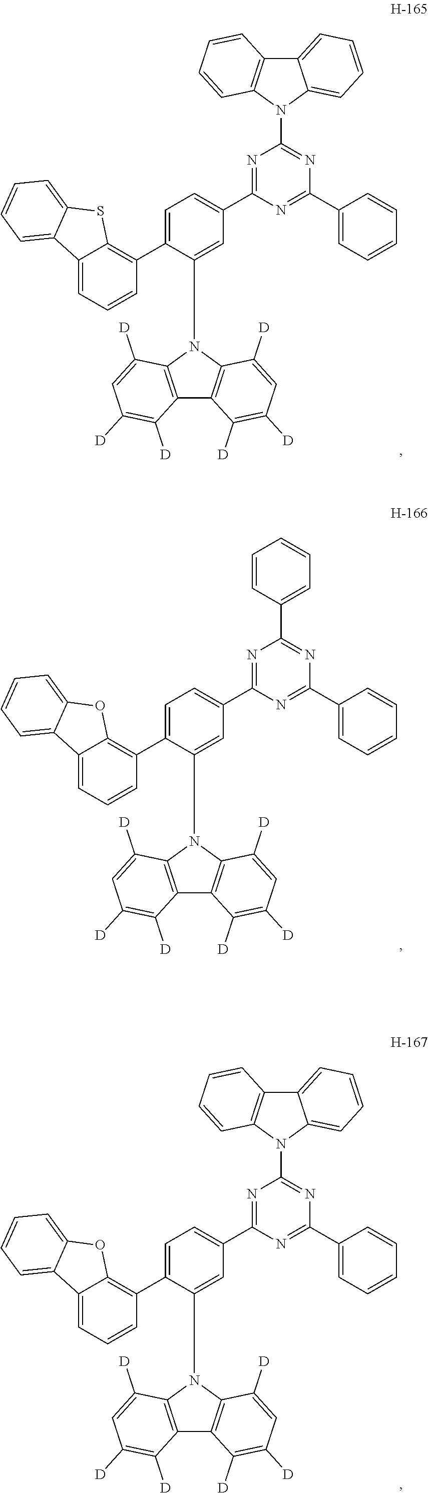 [SMILES: [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1sc1ccccc12 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1oc1ccccc12 ; [2H]c1cc([2H])c2c(c1[2H])c1c([2H])c([2H])cc([2H])c1n2-c1cc(-c2nc(-c3ccccc3)nc(-n3c4ccccc4c4ccccc43)n2)ccc1-c1cccc2c1oc1ccccc12]

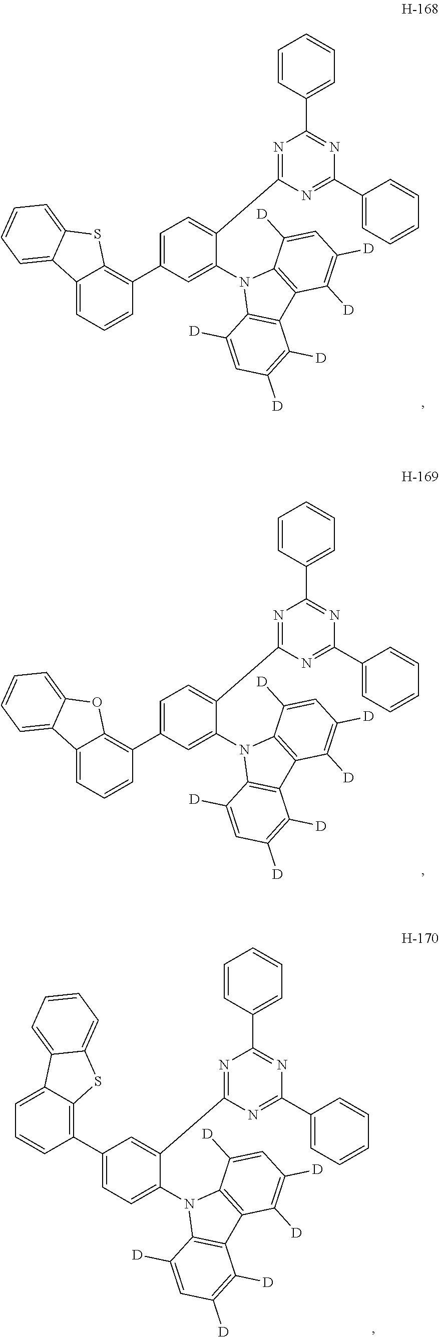 [SMILES: [2H]c1cc([2H])c2c(c1[2H])c1c([2H])c([2H])cc([2H])c1n2-c1cc(-c2cccc3c2sc2ccccc23)ccc1-c1nc(-c2ccccc2)nc(-c2ccccc2)n1 ; [2H]c1cc([2H])c2c(c1[2H])c1c([2H])c([2H])cc([2H])c1n2-c1cc(-c2cccc3c2oc2ccccc23)ccc1-c1nc(-c2ccccc2)nc(-c2ccccc2)n1 ; [2H]c1cc([2H])c2c(c1[2H])c1c([2H])c([2H])cc([2H])c1n2-c1ccc(-c2cccc3c2sc2ccccc23)cc1-c1nc(-c2ccccc2)nc(-c2ccccc2)n1]

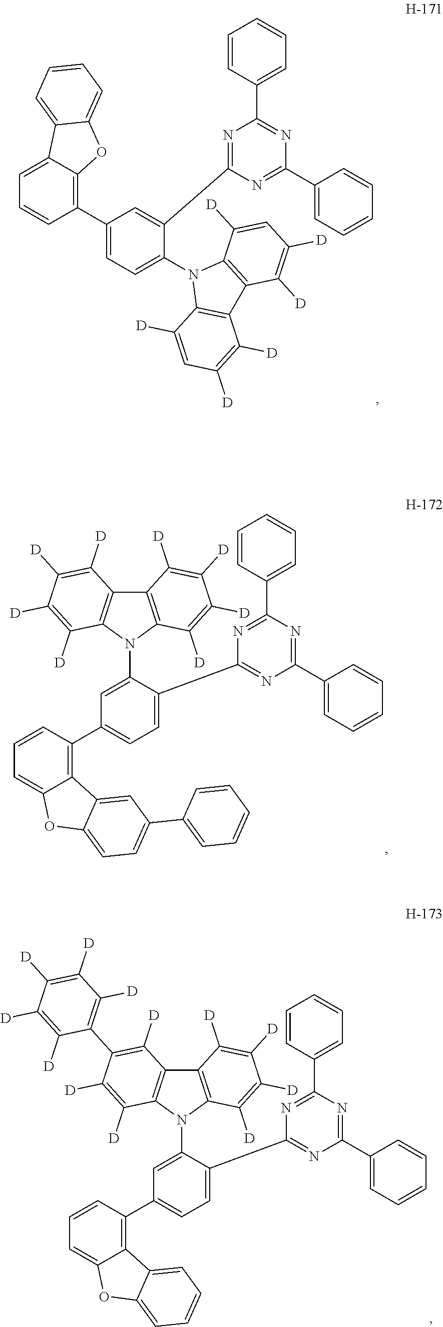 [SMILES: [2H]c1cc([2H])c2c(c1[2H])c1c([2H])c([2H])cc([2H])c1n2-c1ccc(-c2cccc3c2oc2ccccc23)cc1-c1nc(-c2ccccc2)nc(-c2ccccc2)n1 ; [2H]c1c([2H])c([2H])c2c(c1[2H])c1c([2H])c([2H])c([2H])c([2H])c1n2-c1cc(-c2cccc3oc4ccc(-c5ccccc5)cc4c23)ccc1-c1nc(-c2ccccc2)nc(-c2ccccc2)n1 ; [2H]c1c([2H])c([2H])c(-c2c([2H])c([2H])c3c(c2[2H])c2c([2H])c([2H])c([2H])c([2H])c2n3-c2cc(-c3cccc4oc5ccccc5c34)ccc2-c2nc(-c3ccccc3)nc(-c3ccccc3)n2)c([2H])c1[2H]]

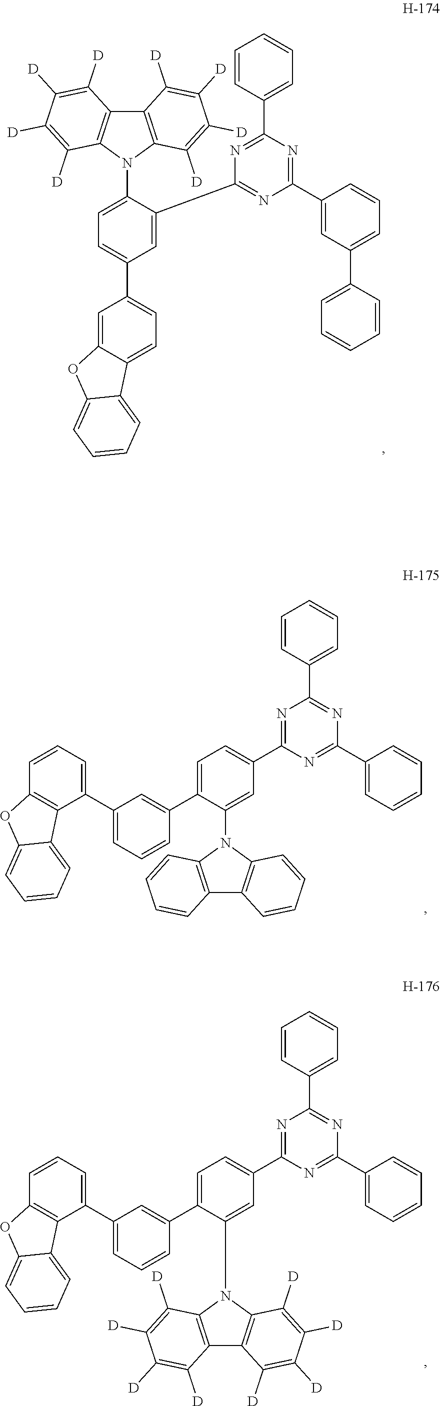 [SMILES: [2H]c1c([2H])c([2H])c2c(c1[2H])c1c([2H])c([2H])c([2H])c([2H])c1n2-c1ccc(-c2ccc3c(c2)oc2ccccc23)cc1-c1nc(-c2ccccc2)nc(-c2cccc(-c3ccccc3)c2)n1 ; c1ccc(-c2nc(-c3ccccc3)nc(-c3ccc(-c4cccc(-c5cccc6oc7ccccc7c56)c4)c(-n4c5ccccc5c5ccccc54)c3)n2)cc1 ; [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc(-c2cccc3oc4ccccc4c23)c1]

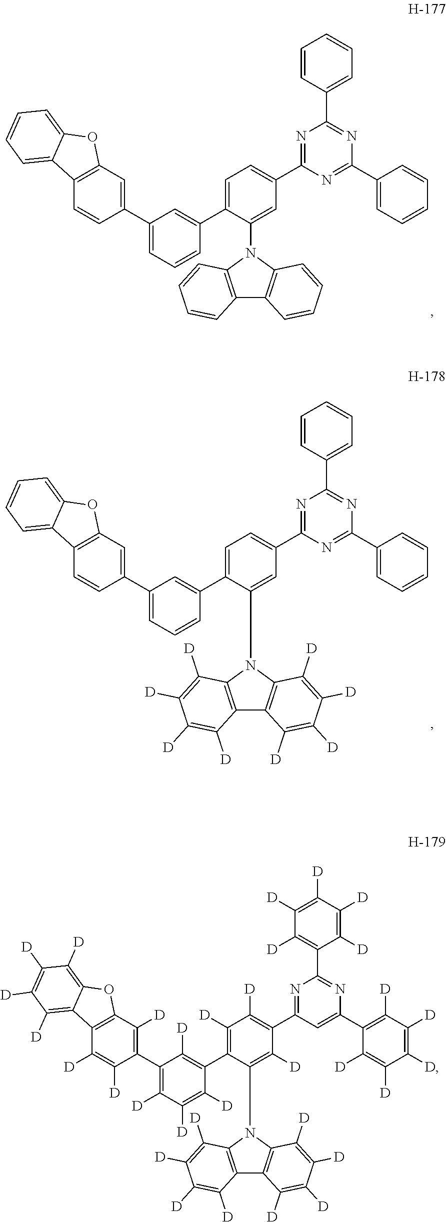

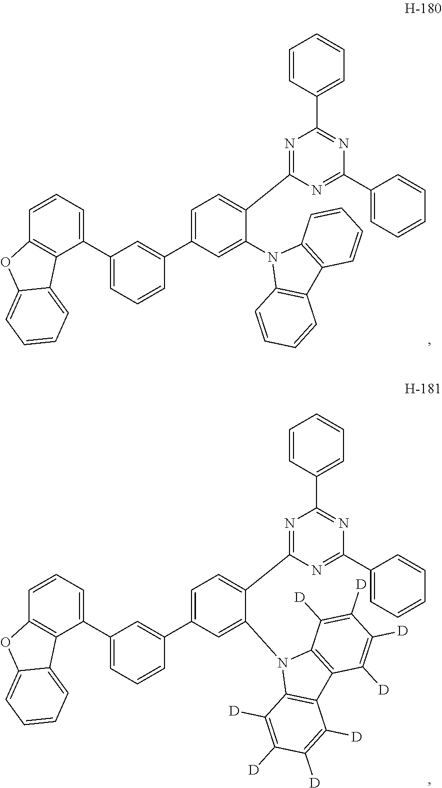 [SMILES: c1ccc(-c2nc(-c3ccccc3)nc(-c3ccc(-c4cccc(-c5cccc6oc7ccccc7c56)c4)cc3-n3c4ccccc4c4ccccc43)n2)cc1 ; [2H]c1c([2H])c([2H])c2c(c1[2H])c1c([2H])c([2H])c([2H])c([2H])c1n2-c1cc(-c2cccc(-c3cccc4oc5ccccc5c34)c2)ccc1-c1nc(-c2ccccc2)nc(-c2ccccc2)n1]

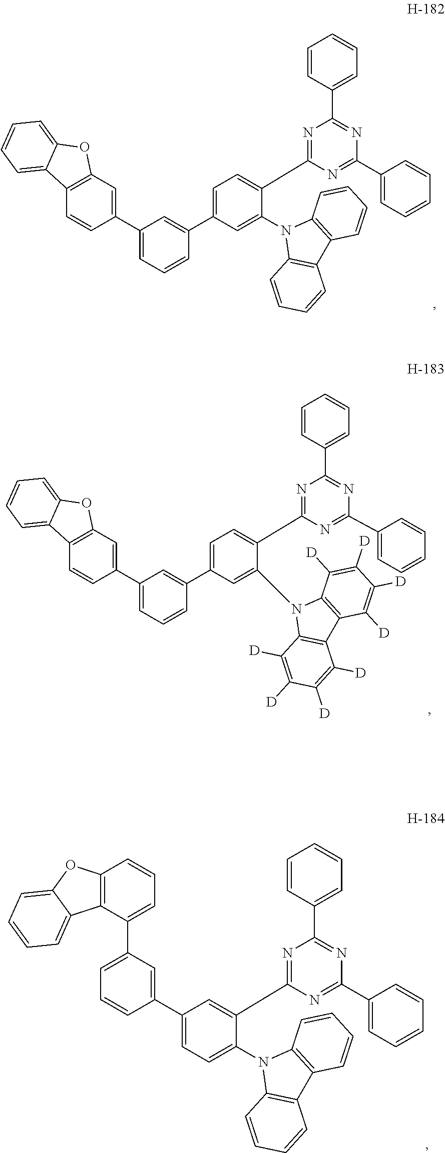 [SMILES: c1ccc(-c2nc(-c3ccccc3)nc(-c3ccc(-c4cccc(-c5ccc6c(c5)oc5ccccc56)c4)cc3-n3c4ccccc4c4ccccc43)n2)cc1 ; [2H]c1c([2H])c([2H])c2c(c1[2H])c1c([2H])c([2H])c([2H])c([2H])c1n2-c1cc(-c2cccc(-c3ccc4c(c3)oc3ccccc34)c2)ccc1-c1nc(-c2ccccc2)nc(-c2ccccc2)n1 ; c1ccc(-c2nc(-c3ccccc3)nc(-c3cc(-c4cccc(-c5cccc6oc7ccccc7c56)c4)ccc3-n3c4ccccc4c4ccccc43)n2)cc1]

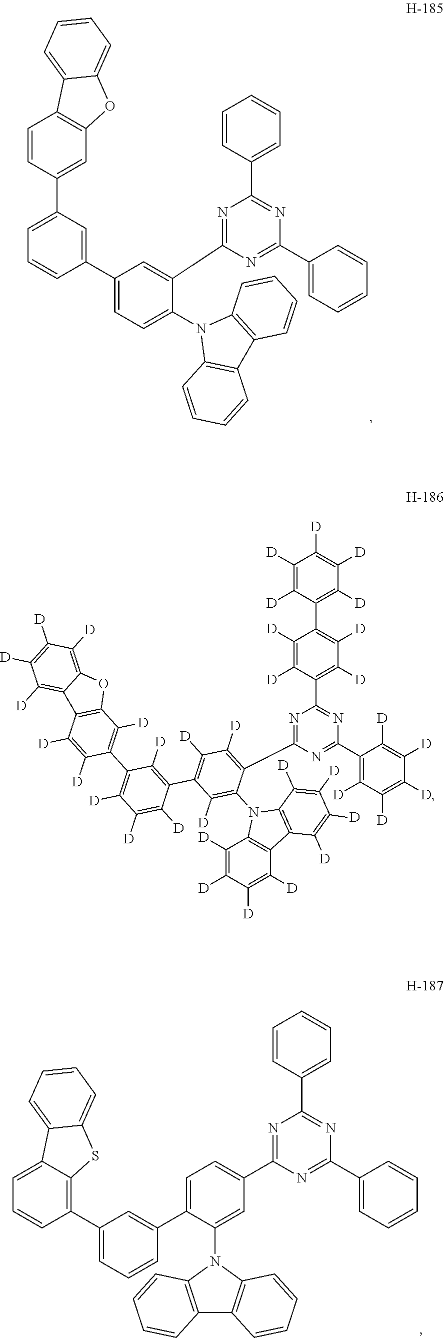

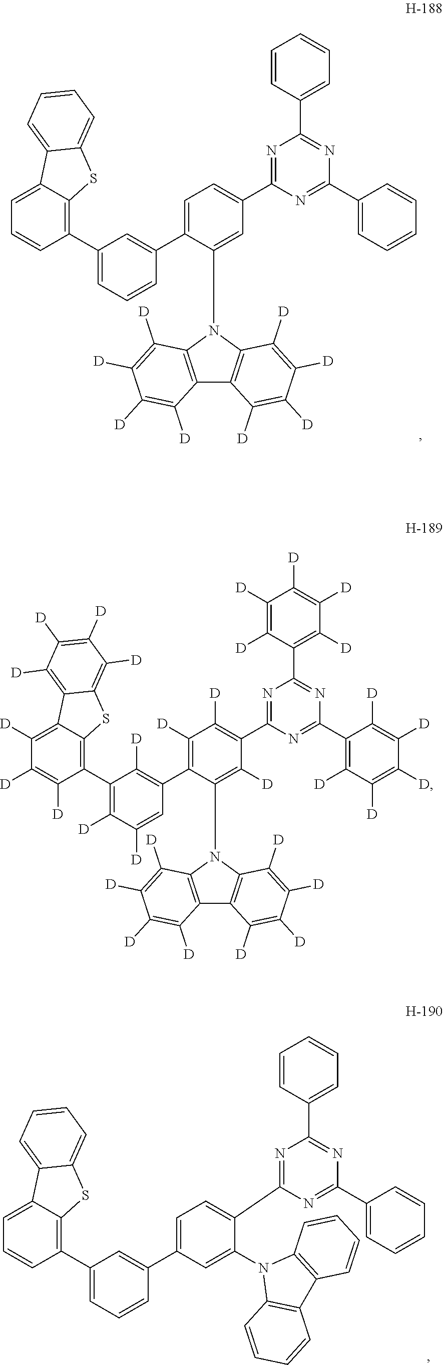

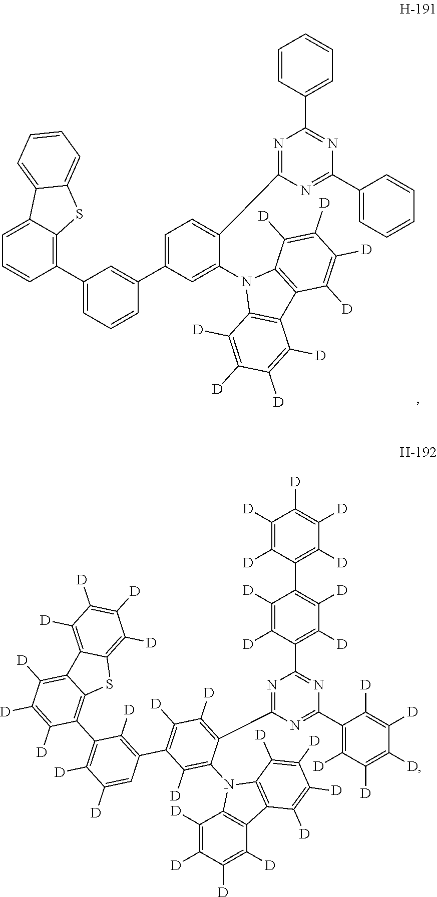

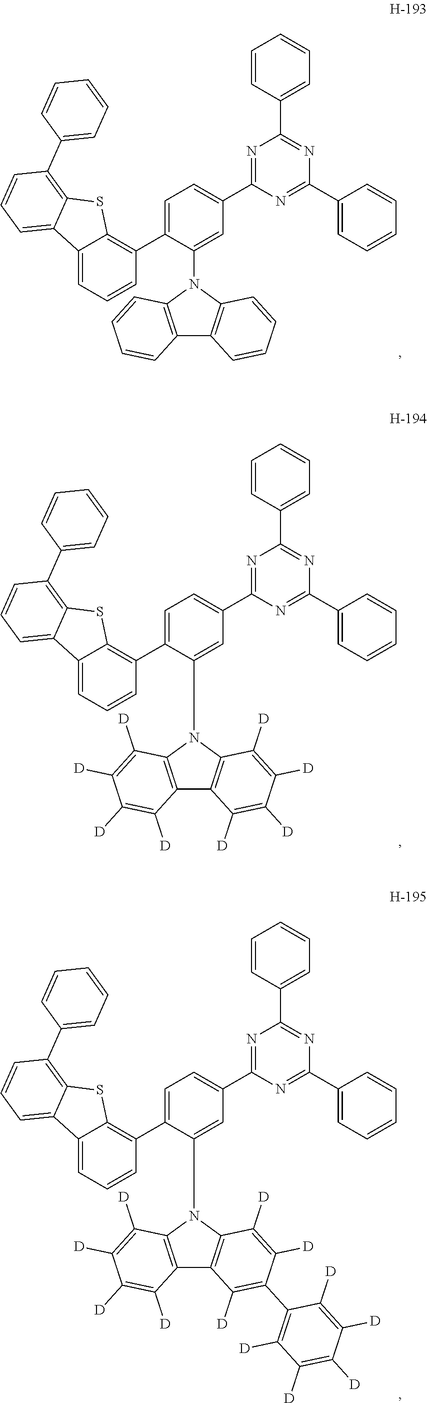 [SMILES: c1ccc(-c2nc(-c3ccccc3)nc(-c3ccc(-c4cccc5c4sc4c(-c6ccccc6)cccc45)c(-n4c5ccccc5c5ccccc54)c3)n2)cc1 ; [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc2c1sc1c(-c3ccccc3)cccc12 ; [2H]c1c([2H])c([2H])c(-c2c([2H])c([2H])c3c(c2[2H])c2c([2H])c([2H])c([2H])c([2H])c2n3-c2cc(-c3nc(-c4ccccc4)nc(-c4ccccc4)n3)ccc2-c2cccc3c2sc2c(-c4ccccc4)cccc23)c([2H])c1[2H]]

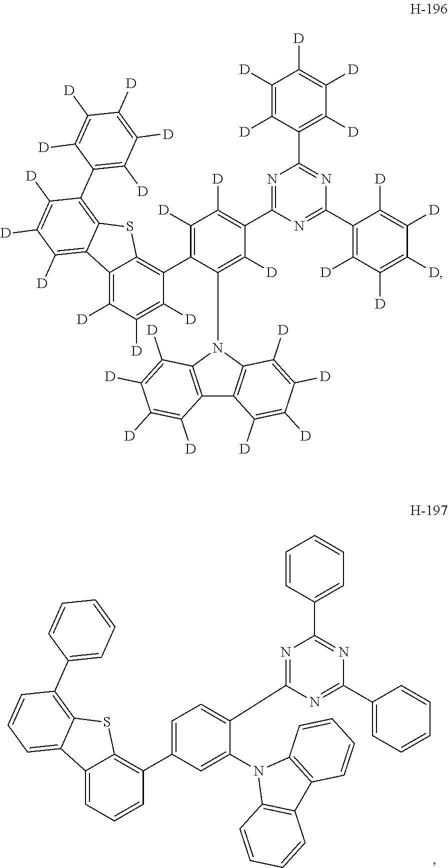

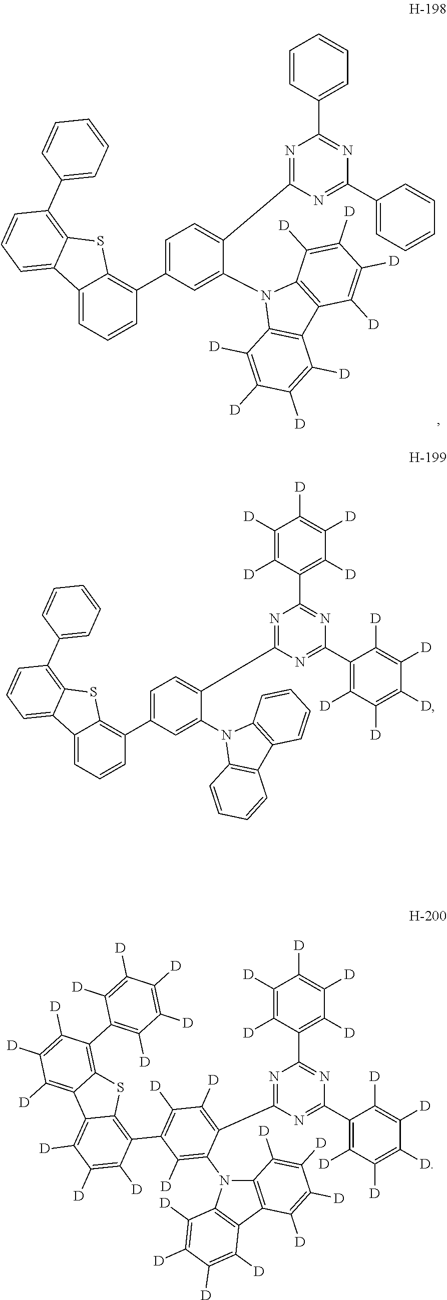

According to an embodiment of the present disclosure, at least one hydrogen in the structure of the first host compound and/or the structure of the second host compound is substituted with deuterium.

According to an embodiment of the present disclosure, hydrogens in the first host compound and/or the second host compound can be partially or fully substituted with deuterium.

According to an embodiment of the present disclosure, a deuteration rate of the first host compound and/or a deuteration rate of the second host compound are 5% to 100%.

According to an embodiment of the present disclosure, a deuteration rate of the first host compound and/or a deuteration rate of the second host compound are 30% to 100%.

According to an embodiment of the present disclosure, a deuteration rate of the first host compound and/or a deuteration rate of the second host compound are 50% to 100%.

In this embodiment, the “deuteration rate of a compound” refers to a percentage of the number of deuteriums in the compound structure relative to the total number of hydrogens and deuteriums in the compound structure.

According to an embodiment of the present disclosure, the organic electroluminescent device further comprises a hole injection layer. The hole injection layer may be a functional layer comprising a single material or a functional layer comprising multiple materials, wherein the comprised multiple materials are most commonly used as hole transporting materials doped with a certain proportion of p-type conductive doping material. Common p-type doping materials comprise

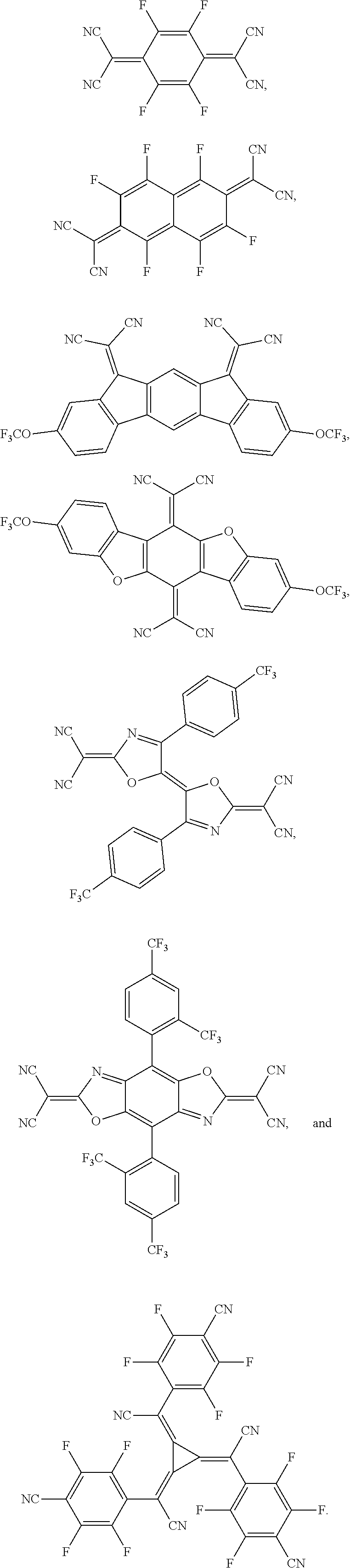

According to another embodiment of the present disclosure, in the emissive layer, the phosphorescence sensitizer accounts for a proportion of 0.001% to 25% of a total weight of the emissive layer.

According to another embodiment of the present disclosure, in the emissive layer, the phosphorescence sensitizer accounts for a proportion of less than 0.01% to 15% of a total weight of the emissive layer.

According to another embodiment of the present disclosure, in the emissive layer, the phosphorescence sensitizer accounts for a proportion of less than 0.1% to 10% of a total weight of the emissive layer.

According to another embodiment of the present disclosure, a material combination is further disclosed, which comprises the phosphorescence sensitizer having the structure of Formula 1 in the preceding embodiment and the fluorescent material in the preceding embodiment.

According to another embodiment of the present disclosure, a display assembly is further disclosed, which comprises the material combination comprising the phosphorescence sensitizer having the structure of Formula 1 in the preceding embodiment and the fluorescent material in the preceding embodiment, or the organic electroluminescent device in the preceding embodiment.

Combination with Other Materials

The materials described in the present disclosure for a particular layer in an organic light emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. Pub. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art.

### Material Synthesis Example

A method for preparing the compound of the present disclosure is not limited. Typically, the following compounds are used as examples without limitation, and the synthesis routes and preparation methods thereof are described below.

### Synthesis Example 1

### Synthesis of Compound DF-135

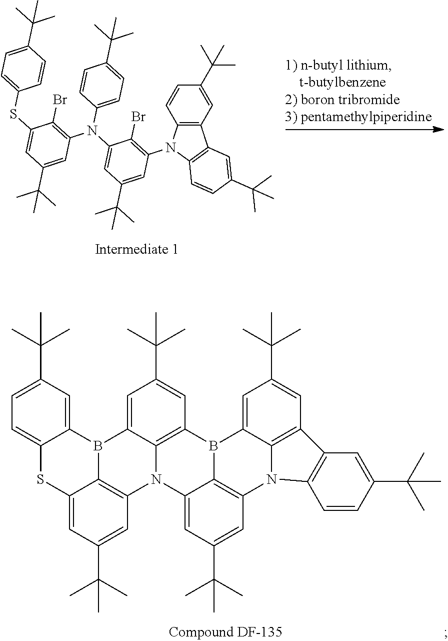 [SMILES: CC(C)(C)c1ccc(Sc2cc(C(C)(C)C)cc(N(c3ccc(C(C)(C)C)cc3)c3cc(C(C)(C)C)cc(-n4c5ccc(C(C)(C)C)cc5c5cc(C(C)(C)C)ccc54)c3Br)c2Br)cc1 ; CC(C)(C)c1ccc2c(c1)B1c3cc(C(C)(C)C)cc4c3N(c3cc(C(C)(C)C)cc(c31)S2)c1cc(C(C)(C)C)cc2c1B4c1cc(C(C)(C)C)cc3c4cc(C(C)(C)C)ccc4n-2c13]

Under nitrogen protection at room temperature, Intermediate 1 (5.6 g, 5.5 mmol) was added to tert-butylbenzene (80.0 ml), and n-butyllithium (13.8 mmol) was added at −70° C. The mixture was allowed to react at room temperature for 1.5 h, heated to 60° C. and reacted for 1 h. The mixture was cooled to 0° C., and boron tribromide (16.1 mmol) was added. The mixture was heated to 80° C. and reacted for 12 h. The mixture was cooled to 0° C., and pentamethylpiperidine (19.2 mmol) was added. The mixture was heated to 180° C. and reacted for 48 h. After cooling, the mixture was filtered, and the filtrate was concentrated and subjected to column chromatography (toluene/n-hexane=1/5) to obtain an orange solid Compound DF-135 (360 mg, 0.4 mmol, with a yield of 7%). The product was confirmed as the target product with a molecular weight of 870.5.

With reference to preparation methods in the related art or prior applications of the applicant, the fluorescent material Compound DF-157 can be easily obtained. For example, the fluorescent material Compound DF-157 is prepared with reference to literature such as Angew. Chem. Int. Ed. 2023, 62, e202304104 (DOI: 10.1002/anie.202304104), Adv. Funct. Mater. 2021, 2102017 (DOI: 10.1002/adfm.202102017), the phosphorescence sensitizer of the present disclosure can be prepared with reference to U.S. Pat. No. 8,367,223B2 and US20200251666A1, the first host compound of the host material of the present disclosure can be prepared with reference to US20240016057A1 and CN117327056A, and the second host compound of the present disclosure can be prepared with reference to US2019198780A1 and CN115368293A. Methods for preparing the fluorescent material Compound DF-157, the phosphorescence sensitizer, the first host compound of the host material and the second host compound are not repeated here. The documents listed above are merely exemplary, and other documents can be easily obtained by those skilled in the art.

A method for preparing an electroluminescent device is not limited. The preparation methods of the following examples are merely illustrative and are not to be construed as limiting. Based on the related art, those skilled in the art can make reasonable improvements on the preparation methods of the following examples. For example, the proportions of various materials in an emissive layer are not particularly limited. Those skilled in the art can reasonably select the proportions within a certain range based on the related art. For example, taking the total weight of the materials in the emissive layer for reference, a host material may account for 80% to 99% and a light-emitting material may account for 1% to 20%; or the host material may account for 90% to 99% and the light-emitting material may account for 1% to 10%; or the host material may account for 94% to 99% and the light-emitting material may account for 1% to 6%. Further, the host material may include one material or two materials, where the ratio of two host materials may be 99:1 to 1:99, may be 80:20 to 20:80, or may be 60:40 to 40:60. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art.

### DEVICE EXAMPLE

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2-2 Angstroms per second and a vacuum degree of about 10⁻⁸ Torr. Compound HT and Compound HT1 were co-deposited for use as a hole injection layer (HIL, with a weight ratio of 97:3). Compound HT was used as a hole transport layer (HTL). Compound PH-23 was used as an electron blocking layer (EBL). Then, First Host Compound PH-75, Second Host Compound H-106, Metal Complex 1845 as a phosphorescence sensitizer and Compound DF-157 as a fluorescent material were co-deposited for use as an emissive layer (EML, with a weight ratio of 65.2:28.0:6.0:0.8). On the EML, Compound H-1 was used as a hole blocking layer (HBL). On the HBL, Compound ET and 8-hydroxyquinolinolato-lithium (Liq) were co-deposited for use as an electron transport layer (ETL, with a weight ratio of 40:60). Finally, Liq was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Comparative Example 1

The implementation mode in Device Comparative Example 1 was the same as that in Device Example 1, except that First Host Compound PH-75, Second Host Compound H-106 and DF-157 as the fluorescent material were co-deposited for use as the emissive layer (EML) with a weight ratio of 69.4:29.8:0.8.

### Device Comparative Example 2

The implementation mode in Device Comparative Example 2 was the same as that in Device Example 1, except that First Host Compound PH-75, Second Host Compound H-106 and Metal Complex 1845 were co-deposited for use as the emissive layer (EML) with a weight ratio of 66:28:6.

### Device Comparative Example 3

The implementation mode in Device Comparative Example 3 was the same as that in Device Example 1, except that First Host Compound PH-75, Second Host Compound H-106, Compound 1 and DF-157 as the fluorescent material were co-deposited for use as the emissive layer (EML) with a weight ratio of 65.2:28.0:6.0:0.8.

Detailed structures and thicknesses of layers of the devices are shown in the following table. A layer using more than one material is obtained by doping different compounds at their weight ratio as recorded.

TABLE 1
Part of device structures in Example 1 and Comparative Examples 1 to 3

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | PH-23 | PH-75:Compound | H-1 | ET:Liq |
| | HT1 (97:3) | (350 Å) | (50 Å) | H-106:Metal | (50 Å) | (40:60) (350 |
| | (100 Å) | | | Complex | | Å) |
| | | | | 1845:Compound | | |
| | | | | DF-157 | | |
| | | | | (65.2:28.0:6.0:0.8) | | |
| | | | | (400 Å) | | |
| Comparative | Compound | Compound | Compound | Compound | Compound | Compound |
| Example 1 | HT:Compound | HT | PH-23 | PH-75:Compound | H-1 | ET:Liq |
| | HT1 (97:3) | (350 Å) | (50 Å) | H-106:Compound | (50 Å) | (40:60) (350 |
| | (100 Å) | | | DF-157 | | Å) |
| | | | | (69.4:29.8:0.8) | | |
| | | | | (400 Å) | | |
| Comparative | Compound | Compound | Compound | Compound | Compound | Compound |
| Example 2 | HT:Compound | HT | PH-23 | PH-75:Compound | H-1 | ET:Liq |
| | HT1 (97:3) | (350 Å) | (50 Å) | H-106:Metal | (50 Å) | (40:60) (350 |
| | (100 Å) | | | Complex 1845 | | Å) |
| | | | | (66:28:6) (400 Å) | | |
| Comparative | Compound | Compound | Compound | Compound | Compound | Compound |
| Example 3 | HT:Compound | HT | PH-23 | PH-75:Compound | H-1 | ET:Liq |
| | HT1 (97:3) | (350 Å) | (50 Å) | H-106:Compound | (50 Å) | (40:60) (350 |
| | (100 Å) | | | 1:Compound | | Å) |
| | | | | DF-157 | | |
| | | | | (65.2:28.0:6.0:0.8) | | |
| | | | | (400 Å) | | |

The materials used in the devices have the following structures:

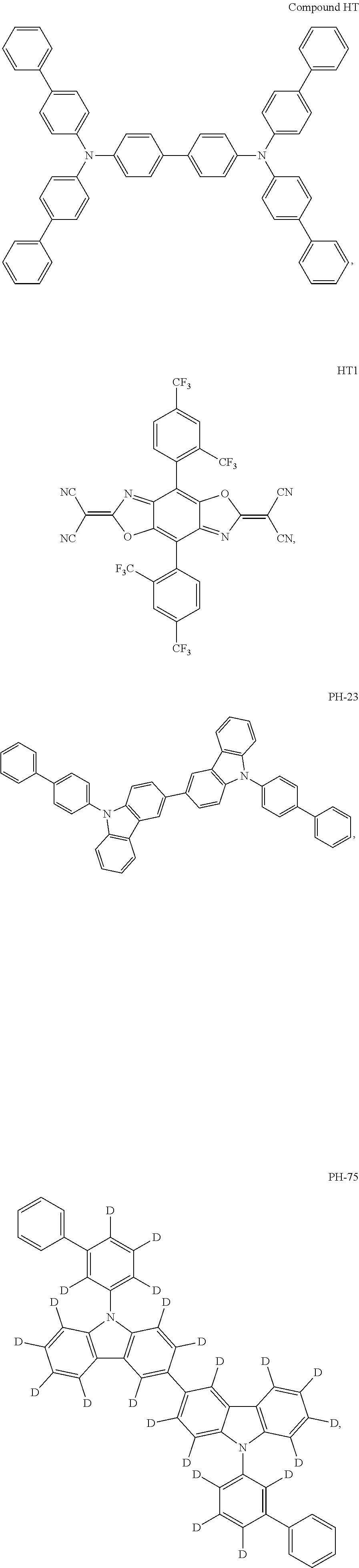

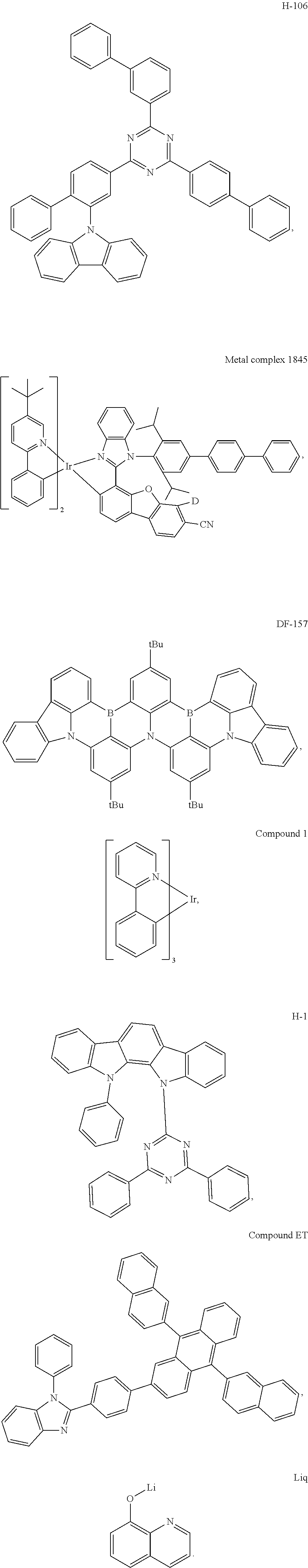

The CIE data, maximum emission wavelength (λₘₐₓ), driving voltage (V), current efficiency (CE), power efficiency (PE) and external quantum efficiency (EQE) of the devices were measured at a constant current of 15 mA/cm². These data were recorded and shown in Table 2.

TABLE 2
Device data in Example 1 and Comparative Examples 1 to 3

| | | λₘₐₓ | Voltage | CE | PE | EQE |
|---|---|---|---|---|---|---|
| Device ID | CIE (x, y) | (nm) | (V) | (cd/A) | (lm/W) | (%) |
| Example 1 | (0.329, 0.655) | 543 | 3.8 | 122 | 101 | 28.1 |
| Comparative | (0.325, 0.652) | 543 | 3.8 | 52 | 43 | 12.2 |
| Example 1 | | | | | | |
| Comparative | (0.335, 0.634) | 525 | 3.8 | 97 | 80 | 25.5 |
| Example 2 | | | | | | |
| Comparative | (0.329, 0.653) | 544 | 4.6 | 116 | 79 | 26.6 |
| Example 3 | | | | | | |

Example 1 differs from Comparative Example 1 only in that: in the emissive layer of Example 1, the metal complex which comprises a five-membered ring fragment represented by a structure of Formula 1 coordinated to Ir is used as a phosphorescence sensitizer for sensitizing the fluorescent material; while no phosphorescence sensitizer is used in corresponding Comparative Example 1.

As can be seen from the data in Table 2, the maximum emission wavelength of Example 1 is consistent with that of Comparative Example 1, indicating that light emitted by the device of Example 1 comes from the fluorescent material. However, compared with the common fluorescent light-emitting device of Comparative Example 1, Device Example 1 of the present disclosure can further achieve an unexpected significant improvement in device efficiency on the basis of maintaining a level of a low voltage that is equivalent to the voltage of Comparative Example 1. Specifically, the CE, the PE and the EQE are significantly improved by 134.6%, 134.9% and 130.3%, respectively.

Example 1 differs from Comparative Example 2 only in that: in Example 1, both the metal complex and the fluorescent material of the present disclosure are used, and the device emits fluorescence; while in Comparative Example 2, only the metal complex is used without using a fluorescent material, and the device emits phosphorescence. Compared with the phosphorescent device of Comparative Example 2, the performance of the sensitized fluorescent device of Example 1 unexpectedly exhibits more excellent effects in all aspects, especially higher CE, PE and EQE. Specifically, the CE, the PE and the EQE are significantly improved by 25.8%, 26.3% and 10.2%, respectively.

Example 1 differs from Comparative Example 3 only in that: in the emissive layer of Example 1, the metal complex which comprises a five-membered ring fragment represented by a structure of Formula 1 coordinated to Ir is used as a phosphorescence sensitizer for sensitizing the fluorescent material; while in corresponding Comparative Example 3, a metal complex without the characteristics of the present disclosure is used as the sensitizer.

As can be seen from the data in Table 2, the maximum emission wavelengths of Example 1 and Comparative Example 3 are consistent, indicating that both Example 1 and Comparative Example 3 are sensitized fluorescent light-emitting devices. However, compared with Comparative Example 3, which is a device sensitized by the sensitizer without the characteristics of the present disclosure, Device Example 1 of the present disclosure can achieve a lower device voltage and higher device efficiency. Specifically, the voltage of Example 1 is 0.8 V lower than that of Comparative Example 3, and CE, PE and EQE are 5.2%, 27.8% and 5.6% higher, respectively, exhibiting more excellent overall device performance.

### Device Example 2

The implementation mode in Device Example 2 was the same as that in Device Example 1, except that Compound PH-75 as the first host material, Compound H-106 as the second host material, Metal Complex 1935 and DF-135 as the fluorescent material were co-deposited for use as the emissive layer (EML) with a weight ratio of 65.2:28.0:6.0:0.8.

### Device Comparative Example 4

The implementation mode in Device Comparative Example 4 was the same as that in Device Example 2, except that Compound PH-75 as the first host material, Compound H-106 as the second host material and DF-135 as the fluorescent material were co-deposited for use as the emissive layer (EML) with a weight ratio of 69.4:29.8:0.8.

### Device Comparative Example 5

The implementation mode in Device Comparative Example 5 was the same as that in Device Example 2, except that Compound PH-75 as the first host material, Compound H-106 as the second host material and Metal Complex 1935 were co-deposited for use as the emissive layer (EML) with a weight ratio of 66:28:6.

### Device Comparative Example 6

The implementation mode in Device Comparative Example 6 was the same as that in Device Example 2, except that Compound PH-75 as the first host material, Compound H-106 as the second host material, Compound 1 and DF-135 as the fluorescent material were co-deposited for use as the emissive layer (EML) with a weight ratio of 65.2:28.0:6.0:0.8.

Detailed structures and thicknesses of layers of the devices are shown in the following table. A layer using more than one material is obtained by doping different compounds at their weight ratio as recorded.

TABLE 3
Part of device structures in Example 2 and Comparative Examples 4 to 6

| Device ID | HIL | HTL | EBL | EML | HBL | ETL |
|---|---|---|---|---|---|---|
| Example 2 | Compound | Compound | Compound | Compound | Compound | Compound |
| | HT:Compound | HT | PH-23 | PH-75:Compound | H-1 | ET:Liq |
| | HT1 (97:3) | (350 Å) | (50 Å) | H-106:Metal | (50 Å) | (40:60) |
| | (100 Å) | | | Complex | | (350 Å) |
| | | | | 1935:Compound | | |
| | | | | DF-135 | | |
| | | | | (65.2:28.0:6.0:0.8) | | |
| | | | | (400 Å) | | |
| Comparative | Compound | Compound | Compound | Compound | Compound | Compound |
| Example 4 | HT:Compound | HT | PH-23 | PH-75:Compound | H-1 | ET:Liq |
| | HT1 (97:3) | (350 Å) | (50 Å) | H-106:Compound | (50 Å) | (40:60) |
| | (100 Å) | | | DF-135 | | (350 Å) |
| | | | | (69.4:29.8:0.8) | | |
| | | | | (400 Å) | | |
| Comparative | Compound | Compound | Compound | Compound | Compound | Compound |
| Example 5 | HT:Compound | HT | PH-23 | PH-75:Compound | H-1 | ET:Liq |
| | HT1 (97:3) | (350 Å) | (50 Å) | H-106:Metal | (50 Å) | (40:60) |
| | (100 Å) | | | Complex 1935 | | (350 Å) |
| | | | | (66:28:6) (400 Å) | | |
| Comparative | Compound | Compound | Compound | Compound | Compound | Compound |
| Example 6 | HT:Compound | HT | PH-23 | PH-75:Compound | H-1 | ET:Liq |
| | HT1 (97:3) | (350 Å) | (50 Å) | H-106:Compound | (50 Å) | (40:60) |
| | (100 Å) | | | 1:Compound DF-135 | | (350 Å) |
| | | | | (65.2:28.0:6.0:0.8) | | |
| | | | | (400 Å) | | |

The new materials used in the devices have the following structures:

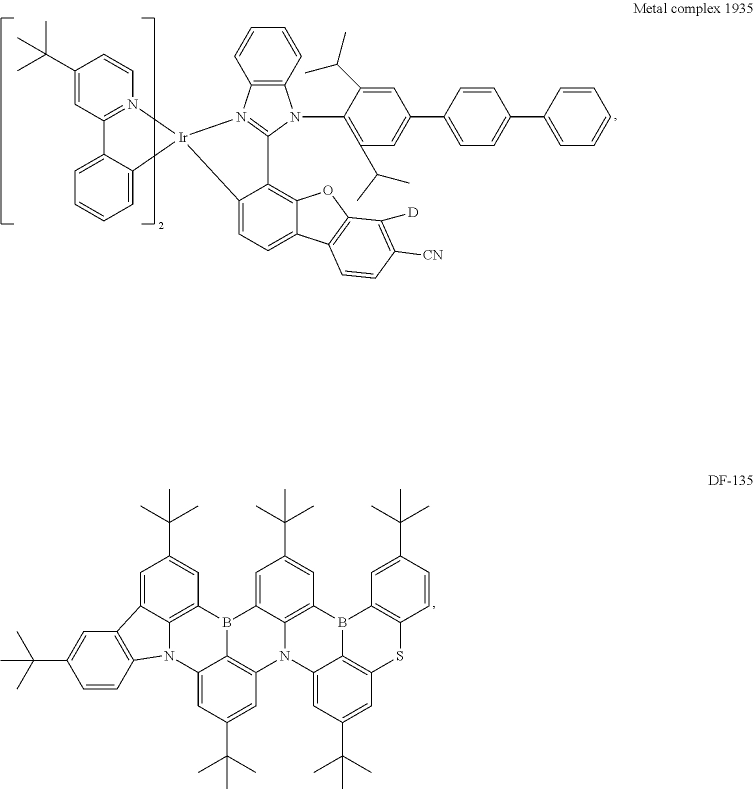

The CIE data, maximum emission wavelength (λₘₐₓ), driving voltage (V), current efficiency (CE), power efficiency (PE) and external quantum efficiency (EQE) of the devices were measured at a brightness of 1000 cd/m². These data were recorded and shown in Table 4.

TABLE 4
Device data in Example 2 and Comparative Examples 4 to 6

| | | λₘₐₓ | Voltage | CE | PE | EQE |
|---|---|---|---|---|---|---|
| Device ID | CIE (x, y) | (nm) | (V) | (cd/A) | (lm/W) | (%) |
| Example 2 | (0.300, 0.677) | 536 | 2.8 | 126 | 142 | 29.6 |
| Comparative | (0.281, 0.682) | 536 | 3.1 | 51 | 51 | 11.9 |
| Example 4 | | | | | | |
| Comparative | (0.335, 0.636) | 525 | 2.8 | 107 | 120 | 28.1 |
| Example 5 | | | | | | |
| Comparative | (0.291, 0.681) | 537 | 3.4 | 114 | 104 | 26.8 |
| Example 6 | | | | | | |

Example 2 differs from Comparative Example 4 only in that: in the emissive layer of Example 2, the metal complex which comprises a five-membered ring fragment represented by a structure of Formula 1 coordinated to Ir is used as a phosphorescence sensitizer for sensitizing the fluorescent material; while no phosphorescence sensitizer is used in corresponding Comparative Example 4.

As can be seen from the data in Table 4, the maximum emission wavelength of Example 2 is consistent with that of Comparative Example 4, indicating that light emitted by the device of Example 2 comes from the fluorescent material. However, compared with the common fluorescent light-emitting device of Comparative Example 4, Device Example 2 of the present disclosure has a lower driving voltage and further achieves an unexpected significant improvement in device efficiency. Specifically, the CE, the PE and the EQE are significantly improved by 147.1%, 178.4% and 148.7%, respectively.

Example 2 differs from Comparative Example 5 only in that: in Example 2, both the metal complex and the fluorescent material of the present disclosure are used and the device emits fluorescence; while in Comparative Example 5, only the metal complex is used without using a fluorescent material and the device emits phosphorescence. Compared with the phosphorescent device of Comparative Example 5, the performance of the sensitized fluorescent device of Example 2 unexpectedly exhibits more excellent effects in all aspects with higher CE, PE and EQE. Specifically, the CE, the PE and the EQE are significantly improved by 17.8%, 18.3% and 5.3%, respectively.

Example 2 differs from Comparative Example 6 only in that: in the emissive layer of Example 2, the metal complex which comprises a five-membered ring fragment represented by a structure of Formula 1 coordinated to Ir is used as a phosphorescence sensitizer for sensitizing the fluorescent material; while in corresponding Comparative Example 6, the metal complex without the characteristics of the present disclosure is used as the sensitizer.

As can be seen from the data in Table 4, the maximum emission wavelengths of Example 2 and Comparative Example 6 are consistent, indicating that both Example 2 and Comparative Example 6 are sensitized fluorescent light-emitting devices. However, compared with Comparative Example 6, which is a device sensitized by the sensitizer without the characteristics of the present disclosure, Device Example 2 of the present disclosure can achieve a lower device voltage and higher device efficiency. Specifically, the voltage of Example 2 is 0.6 V lower than that of Comparative Example 6, and CE, PE and EQE are 10.5%, 36.5% and 10.4% higher, respectively.

### Device Example 3

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2-2 Angstroms per second and a vacuum degree of about 10⁻⁸ Torr. Compound HT and Compound HT1 were co-deposited for use as a hole injection layer (HIL, with a weight ratio of 97:3). Compound HT was used as a hole transport layer (HTL). Compound PH-23 was used as an electron blocking layer (EBL). Then, First Host Compound PH-87, Second Host Compound H-102, Metal Complex 1837 as a phosphorescence sensitizer and Compound DF-157 as a fluorescent material were co-deposited for use as an emissive layer (EML, with a weight ratio of 56.1:37.4:6.0:0.5). On the EML, Compound H-1 was used as a hole blocking layer (HBL). On the HBL, Compound ET and 8-hydroxyquinolinolato-lithium (Liq) were co-deposited for use as an electron transport layer (ETL, with a weight ratio of 40:60). Finally, Liq was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Comparative Example 7

The implementation mode in Device Comparative Example 7 was the same as that in Device Example 3, except that Compound PH-87 as the first host material, Compound H-102 as the second host material, DF-157 as the fluorescent material were co-deposited for use as the emissive layer (EML) with a weight ratio of 59.7:39.8:0.5.

### Device Comparative Example 8

The implementation mode in Device Comparative Example 8 was the same as that in Device Example 3, except that Compound PH-87 as the first host material, Compound H-102 as the second host material, and Metal Complex 1837 were co-deposited for use as the emissive layer (EML) with a weight ratio of 56.4:37.6:6.

Detailed structures and thicknesses of layers of the devices are shown in the following table. A layer using more than one material is obtained by doping different compounds at their weight ratio as recorded.

TABLE 5
Part of device structures in Example 3 and Comparative Examples 7 to 8

| Device ID | HIL | HTL | EBL | EML | HBL | ETL |
|---|---|---|---|---|---|---|
| Example 3 | Compound | Compound | Compound | Compound | Compound | Compound |
| | HT:Compound | HT | PH-23 | PH-87:Compound | H-1 | ET:Liq |
| | HT1 (97:3) | (350 Å) | (50 Å) | H-102:Metal | (50 Å) | (40:60) |
| | (100 Å) | | | Complex | | (350 Å) |
| | | | | 1837:Compound | | |
| | | | | DF-157 | | |
| | | | | (56.1:37.4:6.0:0.58) | | |
| | | | | (400 Å) | | |
| Comparative | Compound | Compound | Compound | Compound | Compound | Compound |
| Example 7 | HT:Compound | HT | PH-23 | PH-87:Compound | H-1 | ET:Liq |
| | HT1 (97:3) | (350 Å) | (50 Å) | H-102:Compound | (50 Å) | (40:60) |
| | (100 Å) | | | DF-157 | | (350 Å) |
| | | | | (59.7:39.8:0.5) | | |
| | | | | (400 Å) | | |
| Comparative | Compound | Compound | Compound | Compound | Compound | Compound |
| Example 8 | HT:Compound | HT | PH-23 | PH-87:Compound | H-1 | ET:Liq |
| | HT1 (97:3) | (350 Å) | (50 Å) | H-102:Metal | (50 Å) | (40:60) |
| | (100 Å) | | | Complex | | (350 Å) |
| | | | | 1837(56.4:37.6:6) | | |
| | | | | (400 Å) | | |

The new materials used in the devices have the following structures:

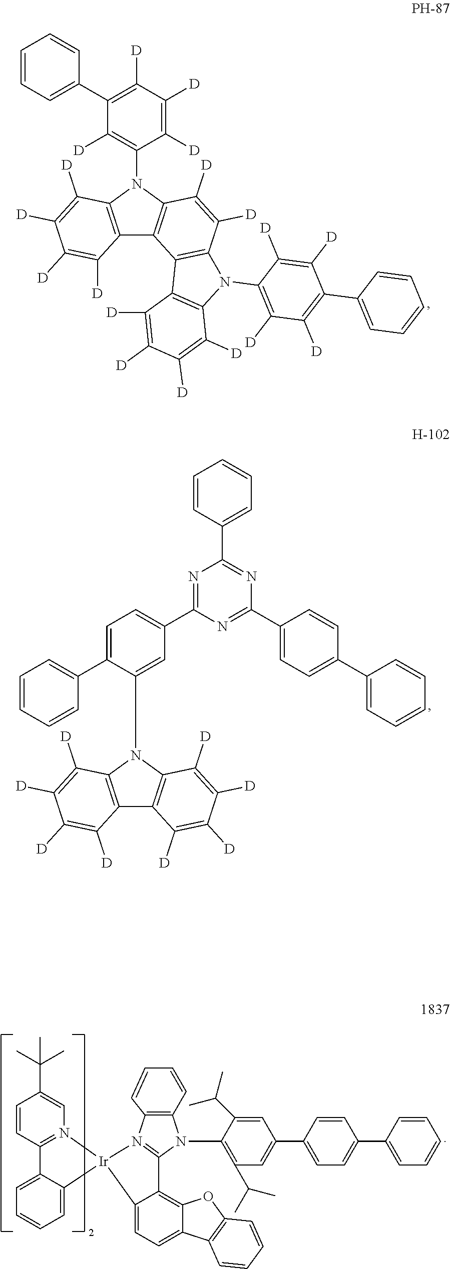

The CIE data, maximum emission wavelength (λₘₐₓ), driving voltage (V), current efficiency (CE), power efficiency (PE) and external quantum efficiency (EQE) of the devices were measured at a brightness of 1000 cd/m². These data were recorded and shown in Table 4.

TABLE 6
Device data in Example 3 and Comparative Examples 7 to 8

| | | λₘₐₓ | Voltage | CE | PE | EQE |
|---|---|---|---|---|---|---|
| Device ID | CIE (x, y) | (nm) | (V) | (cd/A) | (lm/W) | (%) |
| Example 3 | (0.341, 0.645) | 545 | 2.55 | 124 | 153 | 28.9 |
| Comparative | (0.332, 0.653) | 545 | 2.65 | 112 | 133 | 26.0 |
| Example 7 | | | | | | |
| Comparative | (0.365, 0.612 | 528 | 2.71 | 104 | 121 | 28.0 |
| Example 8 | | | | | | |

Example 3 differs from Comparative Example 7 only in that: in the emissive layer of Example 3, the metal complex which comprises a five-membered ring fragment represented by a structure of Formula 1 coordinated to Ir is used as a phosphorescence sensitizer for sensitizing the fluorescent material; while no phosphorescence sensitizer is used in corresponding Comparative Example 7.

As can be seen from the data in Table 6, the maximum emission wavelength of Example 3 is consistent with that of Comparative Example 7, indicating that light emitted by the device of Example 3 comes from the fluorescent material. However, compared with the common fluorescent light-emitting device of Comparative Example 7, Device Example 3 of the present disclosure has a lower driving voltage and further achieves an unexpected significant improvement in device efficiency. Specifically, the CE, the PE and the EQE are significantly improved by 10.7%, 15.0% and 11.2%, respectively.

Example 3 differs from Comparative Example 8 only in that: in Example 3, both the metal complex and the fluorescent material of the present disclosure are used, and the device emits fluorescence; while in Comparative Example 8, only the metal complex is used without using a fluorescent material, and the device emits phosphorescence. Compared with the phosphorescent device of Comparative Example 8, the performance of the sensitized fluorescent device of Example 3 unexpectedly exhibits more excellent effects in all aspects, especially higher CE, PE and EQE. Specifically, the CE, the PE and the EQE are significantly improved by 19.2%, 26.4% and 3.2%, respectively.

The above results indicate that compared with the common fluorescent light-emitting device that does not comprise a phosphorescence sensitizer, the common phosphorescent light-emitting device that does not comprise a fluorescent material and the sensitized fluorescent light-emitting device that has the sensitizer without the characteristics of the present disclosure, the sensitized fluorescent light-emitting device of the present disclosure can obtain more excellent device performance, especially a low driving voltage and higher device efficiency (CE, PE and EQE), since the metal complex which comprises a five-membered ring fragment represented by a structure of Formula 1 coordinated to Ir and the fluorescent material of the present disclosure are both comprised in the emissive layer.

In conclusion, using the metal complex according to the present disclosure, which comprises the fragment represented by Formula 1 which is coordinated to Ir, in the emissive layer of the device of the present disclosure can sensitize the fluorescent material efficiently to obtain a light-emitting device with excellent performance, having extremely high application prospects.

It should be understood that various embodiments described herein are merely examples and not intended to limit the scope of the present disclosure. Therefore, it is apparent to those skilled in the art that the present disclosure as claimed may include variations of specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
an emissive layer disposed between the anode and the cathode, wherein the emissive layer comprises at least a phosphorescence sensitizer and a fluorescent material;
the fluorescent material comprises at least one B atom;
the phosphorescence sensitizer is a metal complex, and the metal is Ir;
the phosphorescence sensitizer comprises a structure represented by a fragment of Formula 1; 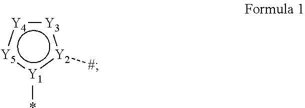
wherein “#” represents a position where the metal Ir is joined, and “*” represents a position where another fragment in the metal complex is joined;
Y₁ and Y₂ are each independently selected from C or N;
Y₃ to Y₅ are each independently selected from CR_{y}, N, NR_{y1}, O or Se;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
the phosphorescence sensitizer comprises at most two fragments of Formula 1.

2. The organic electroluminescent device of claim 1, wherein the fragment of Formula 1 comprised in the phosphorescence sensitizer is, at each occurrence identically or differently, selected from any structure of Formula 1-1 to Formula 1-10: 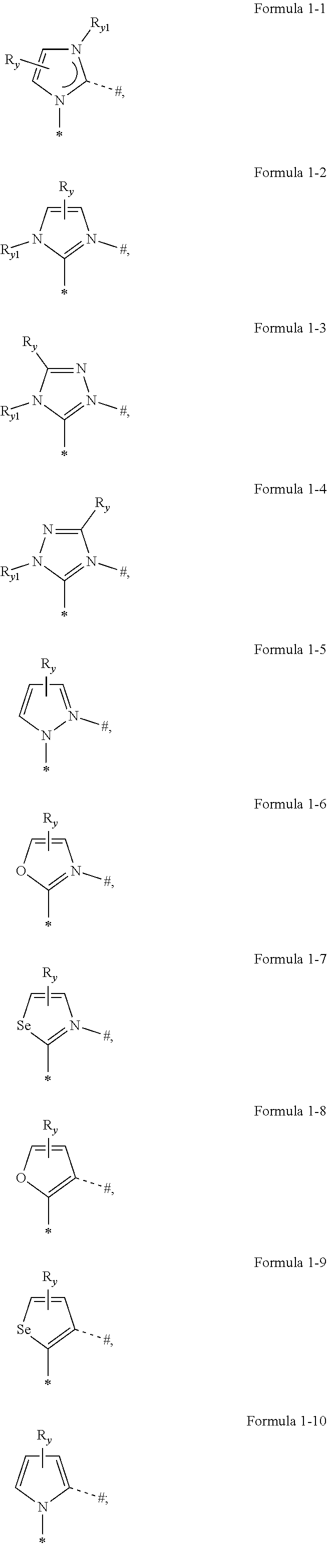
wherein “#” represents a position where the metal Ir is joined, and “*” represents a position where another fragment in the metal complex is joined;
R_{y} represents, at each occurrence identically or differently, mono-substitution, multiple substitutions or non-substitution;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
preferably, the phosphorescence sensitizer comprises a structure represented by a fragment of Formula 1-2.

3. The organic electroluminescent device of claim 2, wherein the phosphorescence sensitizer further comprises a structure represented by a fragment of Formula 2: 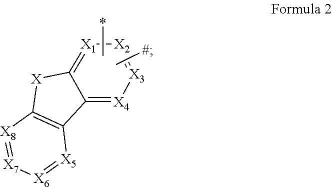
wherein “#” represents a position where the metal Ir is joined, and “*” represents a position where another fragment in the metal complex is joined;
X is, at each occurrence identically or differently, selected from the group consisting of O, S, Se, NR₁, CR₁R₁, SiR₁R₁ and GeR₁R₁;
X₁ to X₄ are each independently selected from C, CRₓ or N, one of X₁ to X₄ is selected from C and joined to the metal Ir, and one of X₁ to X₄ is selected from C and joined to another fragment;
X₅ to X₈ are each independently selected from CRₓ or N;
Rₓ and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ and R₁ can be optionally joined to form a ring.

4. The organic electroluminescent device of claim 3, wherein the phosphorescence sensitizer has a structure of Formula Ir(Lₐ)ₘ(L_{b})ₙ(L_{c})_{q}, wherein the ligands Lₐ, L_{b} and L_{c} are a first ligand, a second ligand and a third ligand coordinated to the metal Ir, respectively, and the ligands Lₐ, L_{b} and L_{c} can be optionally joined to form a multidentate ligand;
L_{c} is a monoanionic bidentate ligand;
m is selected from 1, 2 or 3, n is selected from 0, 1 or 2, q is selected from 0, 1 or 2, and m+n+q is equal to 3; when m is greater than or equal to 2, multiple Lₐ are the same or different;
when n is equal to 2, two L_{b} are the same or different; when q is equal to 2, two L_{c} are the same or different;
the ligands Lₐ and L_{b} satisfy any one of the following conditions:
condition one: the ligand Lₐ comprises the structure represented by the fragment of Formula 2, the ligand L_{b} comprises the structure represented by the fragment of Formula 1-2, and n is selected from 1 or 2;
condition two: the ligand Lₐ comprises both the structure represented by the fragment of Formula 1-2 and the structure represented by the fragment of Formula 2, the fragment of Formula 1-2 is joined to the fragment of Formula 2 through “*”, and m is selected from 1 or 2; 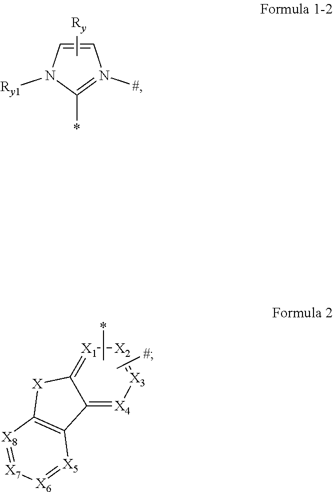
wherein “#” represents a position where the metal Ir is joined, and “*” represents a position where another fragment in the metal complex is joined;
R_{y} represents, at each occurrence identically or differently, mono-substitution, di-substitution or non-substitution;
X is, at each occurrence identically or differently, selected from the group consisting of O, S, Se, NR₁, CR₁R₁, SiR₁R₁ and GeR₁R₁;
X₁ to X₄ are each independently selected from C, CRₓ or N, one of X₁ to X₄ is selected from C and joined to the metal Ir, and one of X₁ to X₄ is selected from C and joined to another fragment;
X₅ to X₈ are each independently selected from CRₓ or N;
Rₓ, R_{y1}, R_{y} and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₓ and R₁ can be optionally joined to form a ring; and
adjacent substituents R_{y} and R_{y1} can be optionally joined to form a ring.

5. The organic electroluminescent device of claim 4, wherein the phosphorescence sensitizer has a general formula of Ir(Lₐ)ₘ(L_{b})₃₋ₘ and has a structure represented by Formula 3: 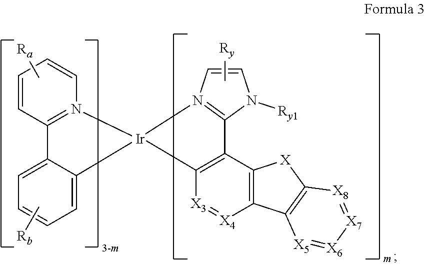
wherein,
m is selected from 1 or 2; when m is selected from 1, two L_{b} are the same or different; when m is selected from 2, two Lₐ are the same or different;
R_{y} represents, at each occurrence identically or differently, mono-substitution, di-substitution or non-substitution; Rₐ and R_{b} represent, at each occurrence identically or differently, mono-substitution, multiple substitutions or non-substitution;
X is, at each occurrence identically or differently, selected from the group consisting of O, S, Se, NR₁, CR₁R₁ and SiR₁R₁; when two R₁ are present at the same time, the two R₁ are the same or different;
X₃ to X₈ are, at each occurrence identically or differently, selected from CRₓ or N;
R₁, Rₓ, R_{y}, R_{y1}, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, Rₓ, R_{y}, R_{y1}, Rₐ and R_{b} can be optionally joined to form a ring.

6. The organic electroluminescent device of claim 4, wherein the phosphorescence sensitizer has a general formula of Ir(Lₐ)ₘ(L_{b})₃₋ₘ and has a structure represented by Formula 4: 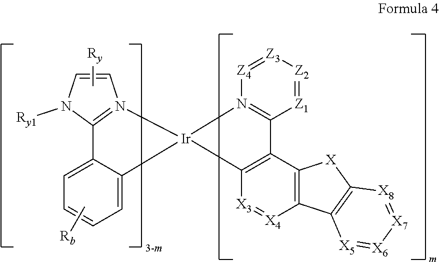
wherein,
m is selected from 1 or 2; when m is selected from 1, two L_{b} are the same or different; when m is selected from 2, two Lₐ are the same or different;
R_{y} represents, at each occurrence identically or differently, mono-substitution, di-substitution or non-substitution; R_{b} represents, at each occurrence identically or differently, mono-substitution, multiple substitutions or non-substitution;
X is, at each occurrence identically or differently, selected from the group consisting of O, S, Se, NR₁, CR₁R₁ and SiR₁R₁; when two R₁ are present at the same time, the two R₁ are the same or different;
X₃ to X₈ are, at each occurrence identically or differently, selected from CRₓ or N;
Z₁ to Z₄ are, at each occurrence identically or differently, selected from CR_{z} or N;
R₁, Rₓ, R_{y}, R_{y1}, R_{z} and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
adjacent substituents R₁, Rₓ, R_{z} and R_{b} can be optionally joined to form a ring.

7. The organic electroluminescent device of claim 3, wherein X is selected from O and S; preferably, X is O.

8. The organic electroluminescent device of claim 3, wherein X₃ to X₈ are, at each occurrence identically or differently, selected from CRₓ, and at least one Rₓ is cyano or fluorine;
preferably, X₅ to X₈ are selected from CRₓ, and at least one Rₓ is cyano or fluorine; and
more preferably, X₇ is CRₓ and the Rₓ is cyano or fluorine; or X₈ is CRₓ and the Rₓ is cyano.

9. The organic electroluminescent device of claim 3, wherein one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof;
more preferably, one Rₓ is cyano, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, X₇ is selected from CRₓ, and the Rₓ is cyano; X₈ is selected from CRₓ, and the Rₓ is selected from the group consisting of: deuterium, substituted or unsubstituted aryl having 6 to 30 carbon atoms, substituted or unsubstituted heteroaryl having 3 to 30 carbon atoms and combinations thereof; and
preferably, X₇ is selected from CRₓ, and the Rₓ is cyano; X₄ is selected from CRₓ, and the Rₓ is selected from the group consisting of: substituted or unsubstituted alkyl having 1 to 20 carbon atoms, substituted or unsubstituted cycloalkyl having 3 to 20 ring carbon atoms and combinations thereof.

10. The organic electroluminescent device of claim 3, wherein R_{y1} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof;
preferably, R_{y1} is, at each occurrence identically or differently, selected from the group consisting of: substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; and
more preferably, R_{y1} is, at each occurrence identically or differently, selected from substituted or unsubstituted aryl having 6 to 30 carbon atoms.

11. The organic electroluminescent device of claim 3, wherein adjacent R_{y} are joined to form a substituted or unsubstituted carbocyclic ring or heterocyclic ring;
preferably, adjacent R_{y} are joined to form a substituted or unsubstituted aromatic ring or heteroaromatic ring; and
more preferably, adjacent R_{y} are joined to form a substituted or unsubstituted benzene ring.

12. The organic electroluminescent device of claim 3, wherein Lₐ is, at each occurrence identically or differently, selected from the group consisting of Lₐ₁ to Lₐ₂₈₇₄;
wherein Lₐ₁ to Lₐ₁₂₈₄ each have the following structure: 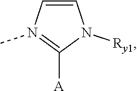
wherein R_{y1} and Fragment A are selected from the atoms or groups in the following table:

| Lₐ | R_{y1} | Fragment A | Lₐ | R_{y1} | Fragment A |
|---|---|---|---|---|---|
| Lₐ₁ | R_{y1}-3 | A-1 | Lₐ₂ | R_{y1}-3 | A-2 |
| Lₐ₃ | R_{y1}-3 | A-3 | Lₐ₄ | R_{y1}-3 | A-4 |
| Lₐ₅ | R_{y1}-3 | A-5 | Lₐ₆ | R_{y1}-3 | A-6 |
| Lₐ₇ | R_{y1}-3 | A-7 | Lₐ₈ | R_{y1}-3 | A-8 |
| Lₐ₉ | R_{y1}-3 | A-9 | Lₐ₁₀ | R_{y1}-3 | A-10 |
| Lₐ₁₁ | R_{y1}-3 | A-11 | Lₐ₁₂ | R_{y1}-3 | A-12 |
| Lₐ₁₃ | R_{y1}-3 | A-13 | Lₐ₁₄ | R_{y1}-3 | A-14 |
| Lₐ₁₅ | R_{y1}-3 | A-15 | Lₐ₁₆ | R_{y1}-3 | A-16 |
| Lₐ₁₇ | R_{y1}-3 | A-17 | Lₐ₁₈ | R_{y1}-3 | A-18 |
| Lₐ₁₉ | R_{y1}-3 | A-19 | Lₐ₂₀ | R_{y1}-3 | A-20 |
| Lₐ₂₁ | R_{y1}-3 | A-21 | Lₐ₂₂ | R_{y1}-3 | A-22 |
| Lₐ₂₃ | R_{y1}-3 | A-23 | Lₐ₂₄ | R_{y1}-3 | A-24 |
| Lₐ₂₅ | R_{y1}-3 | A-25 | Lₐ₂₆ | R_{y1}-3 | A-26 |
| Lₐ₂₇ | R_{y1}-3 | A-27 | Lₐ₂₈ | R_{y1}-3 | A-28 |
| Lₐ₂₉ | R_{y1}-3 | A-29 | Lₐ₃₀ | R_{y1}-3 | A-30 |
| Lₐ₃₁ | R_{y1}-3 | A-31 | Lₐ₃₂ | R_{y1}-3 | A-32 |
| Lₐ₃₃ | R_{y1}-3 | A-33 | Lₐ₃₄ | R_{y1}-3 | A-34 |
| Lₐ₃₅ | R_{y1}-3 | A-35 | Lₐ₃₆ | R_{y1}-3 | A-36 |
| Lₐ₃₇ | R_{y1}-3 | A-37 | Lₐ₃₈ | R_{y1}-3 | A-38 |
| Lₐ₃₉ | R_{y1}-3 | A-39 | Lₐ₄₀ | R_{y1}-3 | A-40 |
| Lₐ₄₁ | R_{y1}-3 | A-41 | Lₐ₄₂ | R_{y1}-3 | A-42 |
| Lₐ₄₃ | R_{y1}-3 | A-43 | Lₐ₄₄ | R_{y1}-3 | A-44 |
| Lₐ₄₅ | R_{y1}-3 | A-45 | Lₐ₄₆ | R_{y1}-3 | A-46 |
| Lₐ₄₇ | R_{y1}-3 | A-47 | Lₐ₄₈ | R_{y1}-3 | A-48 |
| Lₐ₄₉ | R_{y1}-3 | A-49 | Lₐ₅₀ | R_{y1}-3 | A-50 |
| Lₐ₅₁ | R_{y1}-3 | A-51 | Lₐ₅₂ | R_{y1}-3 | A-52 |
| Lₐ₅₃ | R_{y1}-3 | A-53 | Lₐ₅₄ | R_{y1}-3 | A-54 |
| Lₐ₅₅ | R_{y1}-3 | A-55 | Lₐ₅₆ | R_{y1}-3 | A-56 |
| Lₐ₅₇ | R_{y1}-3 | A-57 | Lₐ₅₈ | R_{y1}-3 | A-58 |
| Lₐ₅₉ | R_{y1}-3 | A-59 | Lₐ₆₀ | R_{y1}-3 | A-60 |
| Lₐ₆₁ | R_{y1}-3 | A-61 | Lₐ₆₂ | R_{y1}-3 | A-62 |
| Lₐ₆₃ | R_{y1}-3 | A-63 | Lₐ₆₄ | R_{y1}-3 | A-64 |
| Lₐ₆₅ | R_{y1}-3 | A-65 | Lₐ₆₆ | R_{y1}-3 | A-66 |
| Lₐ₆₇ | R_{y1}-3 | A-67 | Lₐ₆₈ | R_{y1}-3 | A-68 |
| Lₐ₆₉ | R_{y1}-3 | A-69 | Lₐ₇₀ | R_{y1}-3 | A-70 |
| Lₐ₇₁ | R_{y1}-3 | A-71 | Lₐ₇₂ | R_{y1}-3 | A-72 |
| Lₐ₇₃ | R_{y1}-3 | A-73 | Lₐ₇₄ | R_{y1}-3 | A-74 |
| Lₐ₇₅ | R_{y1}-3 | A-75 | Lₐ₇₆ | R_{y1}-3 | A-76 |
| Lₐ₇₇ | R_{y1}-3 | A-77 | Lₐ₇₈ | R_{y1}-3 | A-78 |
| Lₐ₇₉ | R_{y1}-3 | A-79 | Lₐ₈₀ | R_{y1}-3 | A-80 |
| Lₐ₈₁ | R_{y1}-3 | A-81 | Lₐ₈₂ | R_{y1}-3 | A-82 |
| Lₐ₈₃ | R_{y1}-3 | A-83 | Lₐ₈₄ | R_{y1}-3 | A-84 |
| Lₐ₈₅ | R_{y1}-3 | A-85 | Lₐ₈₆ | R_{y1}-3 | A-86 |
| Lₐ₈₇ | R_{y1}-3 | A-87 | Lₐ₈₈ | R_{y1}-3 | A-88 |
| Lₐ₈₉ | R_{y1}-3 | A-89 | Lₐ₉₀ | R_{y1}-3 | A-90 |
| Lₐ₉₁ | R_{y1}-5 | A-1 | Lₐ₉₂ | R_{y1}-5 | A-2 |
| Lₐ₉₃ | R_{y1}-5 | A-3 | Lₐ₉₄ | R_{y1}-5 | A-4 |
| Lₐ₉₅ | R_{y1}-5 | A-5 | Lₐ₉₆ | R_{y1}-5 | A-6 |
| Lₐ₉₇ | R_{y1}-5 | A-7 | Lₐ₉₈ | R_{y1}-5 | A-8 |
| Lₐ₉₉ | R_{y1}-5 | A-9 | Lₐ₁₀₀ | R_{y1}-5 | A-10 |
| Lₐ₁₀₁ | R_{y1}-5 | A-11 | Lₐ₁₀₂ | R_{y1}-5 | A-12 |
| Lₐ₁₀₃ | R_{y1}-5 | A-13 | Lₐ₁₀₄ | R_{y1}-5 | A-14 |
| Lₐ₁₀₅ | R_{y1}-5 | A-15 | Lₐ₁₀₆ | R_{y1}-5 | A-16 |
| Lₐ₁₀₇ | R_{y1}-5 | A-17 | Lₐ₁₀₈ | R_{y1}-5 | A-18 |
| Lₐ₁₀₉ | R_{y1}-5 | A-19 | Lₐ₁₁₀ | R_{y1}-5 | A-20 |
| Lₐ₁₁₁ | R_{y1}-5 | A-21 | Lₐ₁₁₂ | R_{y1}-5 | A-22 |
| Lₐ₁₁₃ | R_{y1}-5 | A-23 | Lₐ₁₁₄ | R_{y1}-5 | A-24 |
| Lₐ₁₁₅ | R_{y1}-5 | A-25 | Lₐ₁₁₆ | R_{y1}-5 | A-26 |
| Lₐ₁₁₇ | R_{y1}-5 | A-27 | Lₐ₁₁₈ | R_{y1}-5 | A-28 |
| Lₐ₁₁₉ | R_{y1}-5 | A-29 | Lₐ₁₂₀ | R_{y1}-5 | A-30 |
| Lₐ₁₂₁ | R_{y1}-5 | A-31 | Lₐ₁₂₂ | R_{y1}-5 | A-32 |
| Lₐ₁₂₃ | R_{y1}-5 | A-33 | Lₐ₁₂₄ | R_{y1}-5 | A-34 |
| Lₐ₁₂₅ | R_{y1}-5 | A-35 | Lₐ₁₂₆ | R_{y1}-5 | A-36 |
| Lₐ₁₂₇ | R_{y1}-5 | A-37 | Lₐ₁₂₈ | R_{y1}-5 | A-38 |
| Lₐ₁₂₉ | R_{y1}-5 | A-39 | Lₐ₁₃₀ | R_{y1}-5 | A-40 |
| Lₐ₁₃₁ | R_{y1}-5 | A-41 | Lₐ₁₃₂ | R_{y1}-5 | A-42 |
| Lₐ₁₃₃ | R_{y1}-5 | A-43 | Lₐ₁₃₄ | R_{y1}-5 | A-44 |
| Lₐ₁₃₅ | R_{y1}-5 | A-45 | Lₐ₁₃₆ | R_{y1}-5 | A-46 |
| Lₐ₁₃₇ | R_{y1}-5 | A-47 | Lₐ₁₃₈ | R_{y1}-5 | A-48 |
| Lₐ₁₃₉ | R_{y1}-5 | A-49 | Lₐ₁₄₀ | R_{y1}-5 | A-50 |
| Lₐ₁₄₁ | R_{y1}-5 | A-51 | Lₐ₁₄₂ | R_{y1}-5 | A-52 |
| Lₐ₁₄₃ | R_{y1}-5 | A-53 | Lₐ₁₄₄ | R_{y1}-5 | A-54 |
| Lₐ₁₄₅ | R_{y1}-5 | A-55 | Lₐ₁₄₆ | R_{y1}-5 | A-56 |
| Lₐ₁₄₇ | R_{y1}-5 | A-57 | Lₐ₁₄₈ | R_{y1}-5 | A-58 |
| Lₐ₁₄₉ | R_{y1}-5 | A-59 | Lₐ₁₅₀ | R_{y1}-5 | A-60 |
| Lₐ₁₅₁ | R_{y1}-5 | A-61 | Lₐ₁₅₂ | R_{y1}-5 | A-62 |
| Lₐ₁₅₃ | R_{y1}-5 | A-63 | Lₐ₁₅₄ | R_{y1}-5 | A-64 |
| Lₐ₁₅₅ | R_{y1}-5 | A-65 | Lₐ₁₅₆ | R_{y1}-5 | A-66 |
| Lₐ₁₅₇ | R_{y1}-5 | A-67 | Lₐ₁₅₈ | R_{y1}-5 | A-68 |
| Lₐ₁₅₉ | R_{y1}-5 | A-69 | Lₐ₁₆₀ | R_{y1}-5 | A-70 |
| Lₐ₁₆₁ | R_{y1}-5 | A-71 | Lₐ₁₆₂ | R_{y1}-5 | A-72 |
| Lₐ₁₆₃ | R_{y1}-5 | A-73 | Lₐ₁₆₄ | R_{y1}-5 | A-74 |
| Lₐ₁₆₅ | R_{y1}-5 | A-75 | Lₐ₁₆₆ | R_{y1}-5 | A-76 |
| Lₐ₁₆₇ | R_{y1}-5 | A-77 | Lₐ₁₆₈ | R_{y1}-5 | A-78 |
| Lₐ₁₆₉ | R_{y1}-5 | A-79 | Lₐ₁₇₀ | R_{y1}-5 | A-80 |
| Lₐ₁₇₁ | R_{y1}-5 | A-81 | Lₐ₁₇₂ | R_{y1}-5 | A-82 |
| Lₐ₁₇₃ | R_{y1}-5 | A-83 | Lₐ₁₇₄ | R_{y1}-5 | A-84 |
| Lₐ₁₇₅ | R_{y1}-5 | A-85 | Lₐ₁₇₆ | R_{y1}-5 | A-86 |
| Lₐ₁₇₇ | R_{y1}-5 | A-87 | Lₐ₁₇₈ | R_{y1}-5 | A-88 |
| Lₐ₁₇₉ | R_{y1}-5 | A-89 | Lₐ₁₈₀ | R_{y1}-5 | A-90 |
| Lₐ₁₈₁ | R_{y1}-12 | A-1 | Lₐ₁₈₂ | R_{y1}-12 | A-2 |
| Lₐ₁₈₃ | R_{y1}-12 | A-3 | Lₐ₁₈₄ | R_{y1}-12 | A-4 |
| Lₐ₁₈₅ | R_{y1}-12 | A-5 | Lₐ₁₈₆ | R_{y1}-12 | A-6 |
| Lₐ₁₈₇ | R_{y1}-12 | A-7 | Lₐ₁₈₈ | R_{y1}-12 | A-8 |
| Lₐ₁₈₉ | R_{y1}-12 | A-9 | Lₐ₁₉₀ | R_{y1}-12 | A-10 |
| Lₐ₁₉₁ | R_{y1}-12 | A-11 | Lₐ₁₉₂ | R_{y1}-12 | A-12 |
| Lₐ₁₉₃ | R_{y1}-12 | A-13 | Lₐ₁₉₄ | R_{y1}-12 | A-14 |
| Lₐ₁₉₅ | R_{y1}-12 | A-15 | Lₐ₁₉₆ | R_{y1}-12 | A-16 |
| Lₐ₁₉₇ | R_{y1}-12 | A-17 | Lₐ₁₉₈ | R_{y1}-12 | A-18 |
| Lₐ₁₉₉ | R_{y1}-12 | A-19 | Lₐ₂₀₀ | R_{y1}-12 | A-20 |
| Lₐ₂₀₁ | R_{y1}-12 | A-21 | Lₐ₂₀₂ | R_{y1}-12 | A-22 |
| Lₐ₂₀₃ | R_{y1}-12 | A-23 | Lₐ₂₀₄ | R_{y1}-12 | A-24 |
| Lₐ₂₀₅ | R_{y1}-12 | A-25 | Lₐ₂₀₆ | R_{y1}-12 | A-26 |
| Lₐ₂₀₇ | R_{y1}-12 | A-27 | Lₐ₂₀₈ | R_{y1}-12 | A-28 |
| Lₐ₂₀₉ | R_{y1}-12 | A-29 | Lₐ₂₁₀ | R_{y1}-12 | A-30 |
| Lₐ₂₁₁ | R_{y1}-12 | A-31 | Lₐ₂₁₂ | R_{y1}-12 | A-32 |
| Lₐ₂₁₃ | R_{y1}-12 | A-33 | Lₐ₂₁₄ | R_{y1}-12 | A-34 |
| Lₐ₂₁₅ | R_{y1}-12 | A-35 | Lₐ₂₁₆ | R_{y1}-12 | A-36 |
| Lₐ₂₁₇ | R_{y1}-12 | A-37 | Lₐ₂₁₈ | R_{y1}-12 | A-38 |
| Lₐ₂₁₉ | R_{y1}-12 | A-39 | Lₐ₂₂₀ | R_{y1}-12 | A-40 |
| Lₐ₂₂₁ | R_{y1}-12 | A-41 | Lₐ₂₂₂ | R_{y1}-12 | A-42 |
| Lₐ₂₂₃ | R_{y1}-12 | A-43 | Lₐ₂₂₄ | R_{y1}-12 | A-44 |
| Lₐ₂₂₅ | R_{y1}-12 | A-45 | Lₐ₂₂₆ | R_{y1}-12 | A-46 |
| Lₐ₂₂₇ | R_{y1}-12 | A-47 | Lₐ₂₂₈ | R_{y1}-12 | A-48 |
| Lₐ₂₂₉ | R_{y1}-12 | A-49 | Lₐ₂₃₀ | R_{y1}-12 | A-50 |
| Lₐ₂₃₁ | R_{y1}-12 | A-51 | Lₐ₂₃₂ | R_{y1}-12 | A-52 |
| Lₐ₂₃₃ | R_{y1}-12 | A-53 | Lₐ₂₃₄ | R_{y1}-12 | A-54 |
| Lₐ₂₃₅ | R_{y1}-12 | A-55 | Lₐ₂₃₆ | R_{y1}-12 | A-56 |
| Lₐ₂₃₇ | R_{y1}-12 | A-57 | Lₐ₂₃₈ | R_{y1}-12 | A-58 |
| Lₐ₂₃₉ | R_{y1}-12 | A-59 | Lₐ₂₄₀ | R_{y1}-12 | A-60 |
| Lₐ₂₄₁ | R_{y1}-12 | A-61 | Lₐ₂₄₂ | R_{y1}-12 | A-62 |
| Lₐ₂₄₃ | R_{y1}-12 | A-63 | Lₐ₂₄₄ | R_{y1}-12 | A-64 |
| Lₐ₂₄₅ | R_{y1}-12 | A-65 | Lₐ₂₄₆ | R_{y1}-12 | A-66 |
| Lₐ₂₄₇ | R_{y1}-12 | A-67 | Lₐ₂₄₈ | R_{y1}-12 | A-68 |
| Lₐ₂₄₉ | R_{y1}-12 | A-69 | Lₐ₂₅₀ | R_{y1}-12 | A-70 |
| Lₐ₂₅₁ | R_{y1}-12 | A-71 | Lₐ₂₅₂ | R_{y1}-12 | A-72 |
| Lₐ₂₅₃ | R_{y1}-12 | A-73 | Lₐ₂₅₄ | R_{y1}-12 | A-74 |
| Lₐ₂₅₅ | R_{y1}-12 | A-75 | Lₐ₂₅₆ | R_{y1}-12 | A-76 |
| Lₐ₂₅₇ | R_{y1}-12 | A-77 | Lₐ₂₅₈ | R_{y1}-12 | A-78 |
| Lₐ₂₅₉ | R_{y1}-12 | A-79 | Lₐ₂₆₀ | R_{y1}-12 | A-80 |
| Lₐ₂₆₁ | R_{y1}-12 | A-81 | Lₐ₂₆₂ | R_{y1}-12 | A-82 |
| Lₐ₂₆₃ | R_{y1}-12 | A-83 | Lₐ₂₆₄ | R_{y1}-12 | A-84 |
| Lₐ₂₆₅ | R_{y1}-12 | A-85 | Lₐ₂₆₆ | R_{y1}-12 | A-86 |
| Lₐ₂₆₇ | R_{y1}-12 | A-87 | Lₐ₂₆₈ | R_{y1}-12 | A-88 |
| Lₐ₂₆₉ | R_{y1}-12 | A-89 | Lₐ₂₇₀ | R_{y1}-12 | A-90 |
| Lₐ₂₇₁ | R_{y1}-15 | A-1 | Lₐ₂₇₂ | R_{y1}-15 | A-2 |
| Lₐ₂₇₃ | R_{y1}-15 | A-3 | Lₐ₂₇₄ | R_{y1}-15 | A-4 |
| Lₐ₂₇₅ | R_{y1}-15 | A-5 | Lₐ₂₇₆ | R_{y1}-15 | A-6 |
| Lₐ₂₇₇ | R_{y1}-15 | A-7 | Lₐ₂₇₈ | R_{y1}-15 | A-8 |
| Lₐ₂₇₉ | R_{y1}-15 | A-9 | Lₐ₂₈₀ | R_{y1}-15 | A-10 |
| Lₐ₂₈₁ | R_{y1}-15 | A-11 | Lₐ₂₈₂ | R_{y1}-15 | A-12 |
| Lₐ₂₈₃ | R_{y1}-15 | A-13 | Lₐ₂₈₄ | R_{y1}-15 | A-14 |
| Lₐ₂₈₅ | R_{y1}-15 | A-15 | Lₐ₂₈₆ | R_{y1}-15 | A-16 |
| Lₐ₂₈₇ | R_{y1}-15 | A-17 | Lₐ₂₈₈ | R_{y1}-15 | A-18 |
| Lₐ₂₈₉ | R_{y1}-15 | A-19 | Lₐ₂₉₀ | R_{y1}-15 | A-20 |
| Lₐ₂₉₁ | R_{y1}-15 | A-21 | Lₐ₂₉₂ | R_{y1}-15 | A-22 |
| Lₐ₂₉₃ | R_{y1}-15 | A-23 | Lₐ₂₉₄ | R_{y1}-15 | A-24 |
| Lₐ₂₉₅ | R_{y1}-15 | A-25 | Lₐ₂₉₆ | R_{y1}-15 | A-26 |
| Lₐ₂₉₇ | R_{y1}-15 | A-27 | Lₐ₂₉₈ | R_{y1}-15 | A-28 |
| Lₐ₂₉₉ | R_{y1}-15 | A-29 | Lₐ₃₀₀ | R_{y1}-15 | A-30 |
| Lₐ₃₀₁ | R_{y1}-15 | A-31 | Lₐ₃₀₂ | R_{y1}-15 | A-32 |
| Lₐ₃₀₃ | R_{y1}-15 | A-33 | Lₐ₃₀₄ | R_{y1}-15 | A-34 |
| Lₐ₃₀₅ | R_{y1}-15 | A-35 | Lₐ₃₀₆ | R_{y1}-15 | A-36 |
| Lₐ₃₀₇ | R_{y1}-15 | A-37 | Lₐ₃₀₈ | R_{y1}-15 | A-38 |
| Lₐ₃₀₉ | R_{y1}-15 | A-39 | Lₐ₃₁₀ | R_{y1}-15 | A-40 |
| Lₐ₃₁₁ | R_{y1}-15 | A-41 | Lₐ₃₁₂ | R_{y1}-15 | A-42 |
| Lₐ₃₁₃ | R_{y1}-15 | A-43 | Lₐ₃₁₄ | R_{y1}-15 | A-44 |
| Lₐ₃₁₅ | R_{y1}-15 | A-45 | Lₐ₃₁₆ | R_{y1}-15 | A-46 |
| Lₐ₃₁₇ | R_{y1}-15 | A-47 | Lₐ₃₁₈ | R_{y1}-15 | A-48 |
| Lₐ₃₁₉ | R_{y1}-15 | A-49 | Lₐ₃₂₀ | R_{y1}-15 | A-50 |
| Lₐ₃₂₁ | R_{y1}-15 | A-51 | Lₐ₃₂₂ | R_{y1}-15 | A-52 |
| Lₐ₃₂₃ | R_{y1}-15 | A-53 | Lₐ₃₂₄ | R_{y1}-15 | A-54 |
| Lₐ₃₂₅ | R_{y1}-15 | A-55 | Lₐ₃₂₆ | R_{y1}-15 | A-56 |
| Lₐ₃₂₇ | R_{y1}-15 | A-57 | Lₐ₃₂₈ | R_{y1}-15 | A-58 |
| Lₐ₃₂₉ | R_{y1}-15 | A-59 | Lₐ₃₃₀ | R_{y1}-15 | A-60 |
| Lₐ₃₃₁ | R_{y1}-15 | A-61 | Lₐ₃₃₂ | R_{y1}-15 | A-62 |
| Lₐ₃₃₃ | R_{y1}-15 | A-63 | Lₐ₃₃₄ | R_{y1}-15 | A-64 |
| Lₐ₃₃₅ | R_{y1}-15 | A-65 | Lₐ₃₃₆ | R_{y1}-15 | A-66 |
| Lₐ₃₃₇ | R_{y1}-15 | A-67 | Lₐ₃₃₈ | R_{y1}-15 | A-68 |
| Lₐ₃₃₉ | R_{y1}-15 | A-69 | Lₐ₃₄₀ | R_{y1}-15 | A-70 |
| Lₐ₃₄₁ | R_{y1}-15 | A-71 | Lₐ₃₄₂ | R_{y1}-15 | A-72 |
| Lₐ₃₄₃ | R_{y1}-15 | A-73 | Lₐ₃₄₄ | R_{y1}-15 | A-74 |
| Lₐ₃₄₅ | R_{y1}-15 | A-75 | Lₐ₃₄₆ | R_{y1}-15 | A-76 |
| Lₐ₃₄₇ | R_{y1}-15 | A-77 | Lₐ₃₄₈ | R_{y1}-15 | A-78 |
| Lₐ₃₄₉ | R_{y1}-15 | A-79 | Lₐ₃₅₀ | R_{y1}-15 | A-80 |
| Lₐ₃₅₁ | R_{y1}-15 | A-81 | Lₐ₃₅₂ | R_{y1}-15 | A-82 |
| Lₐ₃₅₃ | R_{y1}-15 | A-83 | Lₐ₃₅₄ | R_{y1}-15 | A-84 |
| Lₐ₃₅₅ | R_{y1}-15 | A-85 | Lₐ₃₅₆ | R_{y1}-15 | A-86 |
| Lₐ₃₅₇ | R_{y1}-15 | A-87 | Lₐ₃₅₈ | R_{y1}-15 | A-88 |
| Lₐ₃₅₉ | R_{y1}-15 | A-89 | Lₐ₃₆₀ | R_{y1}-15 | A-90 |
| Lₐ₃₆₁ | R_{y1}-16 | A-1 | Lₐ₃₆₂ | R_{y1}-16 | A-2 |
| Lₐ₃₆₃ | R_{y1}-16 | A-3 | Lₐ₃₆₄ | R_{y1}-16 | A-4 |
| Lₐ₃₆₅ | R_{y1}-16 | A-5 | Lₐ₃₆₆ | R_{y1}-16 | A-6 |
| Lₐ₃₆₇ | R_{y1}-16 | A-7 | Lₐ₃₆₈ | R_{y1}-16 | A-8 |
| Lₐ₃₆₉ | R_{y1}-16 | A-9 | Lₐ₃₇₀ | R_{y1}-16 | A-10 |
| Lₐ₃₇₁ | R_{y1}-16 | A-11 | Lₐ₃₇₂ | R_{y1}-16 | A-12 |
| Lₐ₃₇₃ | R_{y1}-16 | A-13 | Lₐ₃₇₄ | R_{y1}-16 | A-14 |
| Lₐ₃₇₅ | R_{y1}-16 | A-15 | Lₐ₃₇₆ | R_{y1}-16 | A-16 |
| Lₐ₃₇₇ | R_{y1}-16 | A-17 | Lₐ₃₇₈ | R_{y1}-16 | A-18 |
| Lₐ₃₇₉ | R_{y1}-16 | A-19 | Lₐ₃₈₀ | R_{y1}-16 | A-20 |
| Lₐ₃₈₁ | R_{y1}-16 | A-21 | Lₐ₃₈₂ | R_{y1}-16 | A-22 |
| Lₐ₃₈₃ | R_{y1}-16 | A-23 | Lₐ₃₈₄ | R_{y1}-16 | A-24 |
| Lₐ₃₈₅ | R_{y1}-16 | A-25 | Lₐ₃₈₆ | R_{y1}-16 | A-26 |
| Lₐ₃₈₇ | R_{y1}-16 | A-27 | Lₐ₃₈₈ | R_{y1}-16 | A-28 |
| Lₐ₃₈₉ | R_{y1}-16 | A-29 | Lₐ₃₉₀ | R_{y1}-16 | A-30 |
| Lₐ₃₉₁ | R_{y1}-16 | A-31 | Lₐ₃₉₂ | R_{y1}-16 | A-32 |
| Lₐ₃₉₃ | R_{y1}-16 | A-33 | Lₐ₃₉₄ | R_{y1}-16 | A-34 |
| Lₐ₃₉₅ | R_{y1}-16 | A-35 | Lₐ₃₉₆ | R_{y1}-16 | A-36 |
| Lₐ₃₉₇ | R_{y1}-16 | A-37 | Lₐ₃₉₈ | R_{y1}-16 | A-38 |
| Lₐ₃₉₉ | R_{y1}-16 | A-39 | Lₐ₄₀₀ | R_{y1}-16 | A-40 |
| Lₐ₄₀₁ | R_{y1}-16 | A-41 | Lₐ₄₀₂ | R_{y1}-16 | A-42 |
| Lₐ₄₀₃ | R_{y1}-16 | A-43 | Lₐ₄₀₄ | R_{y1}-16 | A-44 |
| Lₐ₄₀₅ | R_{y1}-16 | A-45 | Lₐ₄₀₆ | R_{y1}-16 | A-46 |
| Lₐ₄₀₇ | R_{y1}-16 | A-47 | Lₐ₄₀₈ | R_{y1}-16 | A-48 |
| Lₐ₄₀₉ | R_{y1}-16 | A-49 | Lₐ₄₁₀ | R_{y1}-16 | A-50 |
| Lₐ₄₁₁ | R_{y1}-16 | A-51 | Lₐ₄₁₂ | R_{y1}-16 | A-52 |
| Lₐ₄₁₃ | R_{y1}-16 | A-53 | Lₐ₄₁₄ | R_{y1}-16 | A-54 |
| Lₐ₄₁₅ | R_{y1}-16 | A-55 | Lₐ₄₁₆ | R_{y1}-16 | A-56 |
| Lₐ₄₁₇ | R_{y1}-16 | A-57 | Lₐ₄₁₈ | R_{y1}-16 | A-58 |
| Lₐ₄₁₉ | R_{y1}-16 | A-59 | Lₐ₄₂₀ | R_{y1}-16 | A-60 |
| Lₐ₄₂₁ | R_{y1}-16 | A-61 | Lₐ₄₂₂ | R_{y1}-16 | A-62 |
| Lₐ₄₂₃ | R_{y1}-16 | A-63 | Lₐ₄₂₄ | R_{y1}-16 | A-64 |
| Lₐ₄₂₅ | R_{y1}-16 | A-65 | Lₐ₄₂₆ | R_{y1}-16 | A-66 |
| Lₐ₄₂₇ | R_{y1}-16 | A-67 | Lₐ₄₂₈ | R_{y1}-16 | A-68 |
| Lₐ₄₂₉ | R_{y1}-16 | A-69 | Lₐ₄₃₀ | R_{y1}-16 | A-70 |
| Lₐ₄₃₁ | R_{y1}-16 | A-71 | Lₐ₄₃₂ | R_{y1}-16 | A-72 |
| Lₐ₄₃₃ | R_{y1}-16 | A-73 | Lₐ₄₃₄ | R_{y1}-16 | A-74 |
| Lₐ₄₃₅ | R_{y1}-16 | A-75 | Lₐ₄₃₆ | R_{y1}-16 | A-76 |
| Lₐ₄₃₇ | R_{y1}-16 | A-77 | Lₐ₄₃₈ | R_{y1}-16 | A-78 |
| Lₐ₄₃₉ | R_{y1}-16 | A-79 | Lₐ₄₄₀ | R_{y1}-16 | A-80 |
| Lₐ₄₄₁ | R_{y1}-16 | A-81 | Lₐ₄₄₂ | R_{y1}-16 | A-82 |
| Lₐ₄₄₃ | R_{y1}-16 | A-83 | Lₐ₄₄₄ | R_{y1}-16 | A-84 |
| Lₐ₄₄₅ | R_{y1}-16 | A-85 | Lₐ₄₄₆ | R_{y1}-16 | A-86 |
| Lₐ₄₄₇ | R_{y1}-16 | A-87 | Lₐ₄₄₈ | R_{y1}-16 | A-88 |
| Lₐ₄₄₉ | R_{y1}-16 | A-89 | Lₐ₄₅₀ | R_{y1}-16 | A-90 |
| Lₐ₄₅₁ | R_{y1}-20 | A-1 | Lₐ₄₅₂ | R_{y1}-20 | A-2 |
| Lₐ₄₅₃ | R_{y1}-20 | A-3 | Lₐ₄₅₄ | R_{y1}-20 | A-4 |
| Lₐ₄₅₅ | R_{y1}-20 | A-5 | Lₐ₄₅₆ | R_{y1}-20 | A-6 |
| Lₐ₄₅₇ | R_{y1}-20 | A-7 | Lₐ₄₅₈ | R_{y1}-20 | A-8 |
| Lₐ₄₅₉ | R_{y1}-20 | A-9 | Lₐ₄₆₀ | R_{y1}-20 | A-10 |
| Lₐ₄₆₁ | R_{y1}-20 | A-11 | Lₐ₄₆₂ | R_{y1}-20 | A-12 |
| Lₐ₄₆₃ | R_{y1}-20 | A-13 | Lₐ₄₆₄ | R_{y1}-20 | A-14 |
| Lₐ₄₆₅ | R_{y1}-20 | A-15 | Lₐ₄₆₆ | R_{y1}-20 | A-16 |
| Lₐ₄₆₇ | R_{y1}-20 | A-17 | Lₐ₄₆₈ | R_{y1}-20 | A-18 |
| Lₐ₄₆₉ | R_{y1}-20 | A-19 | Lₐ₄₇₀ | R_{y1}-20 | A-20 |
| Lₐ₄₇₁ | R_{y1}-20 | A-21 | Lₐ₄₇₂ | R_{y1}-20 | A-22 |
| Lₐ₄₇₃ | R_{y1}-20 | A-23 | Lₐ₄₇₄ | R_{y1}-20 | A-24 |
| Lₐ₄₇₅ | R_{y1}-20 | A-25 | Lₐ₄₇₆ | R_{y1}-20 | A-26 |
| Lₐ₄₇₇ | R_{y1}-20 | A-27 | Lₐ₄₇₈ | R_{y1}-20 | A-28 |
| Lₐ₄₇₉ | R_{y1}-20 | A-29 | Lₐ₄₈₀ | R_{y1}-20 | A-30 |
| Lₐ₄₈₁ | R_{y1}-20 | A-31 | Lₐ₄₈₂ | R_{y1}-20 | A-32 |
| Lₐ₄₈₃ | R_{y1}-20 | A-33 | Lₐ₄₈₄ | R_{y1}-20 | A-34 |
| Lₐ₄₈₅ | R_{y1}-20 | A-35 | Lₐ₄₈₆ | R_{y1}-20 | A-36 |
| Lₐ₄₈₇ | R_{y1}-20 | A-37 | Lₐ₄₈₈ | R_{y1}-20 | A-38 |
| Lₐ₄₈₉ | R_{y1}-20 | A-39 | Lₐ₄₉₀ | R_{y1}-20 | A-40 |
| Lₐ₄₉₁ | R_{y1}-20 | A-41 | Lₐ₄₉₂ | R_{y1}-20 | A-42 |
| Lₐ₄₉₃ | R_{y1}-20 | A-43 | Lₐ₄₉₄ | R_{y1}-20 | A-44 |
| Lₐ₄₉₅ | R_{y1}-20 | A-45 | Lₐ₄₉₆ | R_{y1}-20 | A-46 |
| Lₐ₄₉₇ | R_{y1}-20 | A-47 | Lₐ₄₉₈ | R_{y1}-20 | A-48 |
| Lₐ₄₉₉ | R_{y1}-20 | A-49 | Lₐ₅₀₀ | R_{y1}-20 | A-50 |
| Lₐ₅₀₁ | R_{y1}-20 | A-51 | Lₐ₅₀₂ | R_{y1}-20 | A-52 |
| Lₐ₅₀₃ | R_{y1}-20 | A-53 | Lₐ₅₀₄ | R_{y1}-20 | A-54 |
| Lₐ₅₀₅ | R_{y1}-20 | A-55 | Lₐ₅₀₆ | R_{y1}-20 | A-56 |
| Lₐ₅₀₇ | R_{y1}-20 | A-57 | Lₐ₅₀₈ | R_{y1}-20 | A-58 |
| Lₐ₅₀₉ | R_{y1}-20 | A-59 | Lₐ₅₁₀ | R_{y1}-20 | A-60 |
| Lₐ₅₁₁ | R_{y1}-20 | A-61 | Lₐ₅₁₂ | R_{y1}-20 | A-62 |
| Lₐ₅₁₃ | R_{y1}-20 | A-63 | Lₐ₅₁₄ | R_{y1}-20 | A-64 |
| Lₐ₅₁₅ | R_{y1}-20 | A-65 | Lₐ₅₁₆ | R_{y1}-20 | A-66 |
| Lₐ₅₁₇ | R_{y1}-20 | A-67 | Lₐ₅₁₈ | R_{y1}-20 | A-68 |
| Lₐ₅₁₉ | R_{y1}-20 | A-69 | Lₐ₅₂₀ | R_{y1}-20 | A-70 |
| Lₐ₅₂₁ | R_{y1}-20 | A-71 | Lₐ₅₂₂ | R_{y1}-20 | A-72 |
| Lₐ₅₂₃ | R_{y1}-20 | A-73 | Lₐ₅₂₄ | R_{y1}-20 | A-74 |
| Lₐ₅₂₅ | R_{y1}-20 | A-75 | Lₐ₅₂₆ | R_{y1}-20 | A-76 |
| Lₐ₅₂₇ | R_{y1}-20 | A-77 | Lₐ₅₂₈ | R_{y1}-20 | A-78 |
| Lₐ₅₂₉ | R_{y1}-20 | A-79 | Lₐ₅₃₀ | R_{y1}-20 | A-80 |
| Lₐ₅₃₁ | R_{y1}-20 | A-81 | Lₐ₅₃₂ | R_{y1}-20 | A-82 |
| Lₐ₅₃₃ | R_{y1}-20 | A-83 | Lₐ₅₃₄ | R_{y1}-20 | A-84 |
| Lₐ₅₃₅ | R_{y1}-20 | A-85 | Lₐ₅₃₆ | R_{y1}-20 | A-86 |
| Lₐ₅₃₇ | R_{y1}-20 | A-87 | Lₐ₅₃₈ | R_{y1}-20 | A-88 |
| Lₐ₅₃₉ | R_{y1}-20 | A-89 | Lₐ₅₄₀ | R_{y1}-20 | A-90 |
| Lₐ₅₄₁ | R_{y1}-21 | A-1 | Lₐ₅₄₂ | R_{y1}-21 | A-2 |
| Lₐ₅₄₃ | R_{y1}-21 | A-3 | Lₐ₅₄₄ | R_{y1}-21 | A-4 |
| Lₐ₅₄₅ | R_{y1}-21 | A-5 | Lₐ₅₄₆ | R_{y1}-21 | A-6 |
| Lₐ₅₄₇ | R_{y1}-21 | A-7 | Lₐ₅₄₈ | R_{y1}-21 | A-8 |
| Lₐ₅₄₉ | R_{y1}-21 | A-9 | Lₐ₅₅₀ | R_{y1}-21 | A-10 |
| Lₐ₅₅₁ | R_{y1}-21 | A-11 | Lₐ₅₅₂ | R_{y1}-21 | A-12 |
| Lₐ₅₅₃ | R_{y1}-21 | A-13 | Lₐ₅₅₄ | R_{y1}-21 | A-14 |
| Lₐ₅₅₅ | R_{y1}-21 | A-15 | Lₐ₅₅₆ | R_{y1}-21 | A-16 |
| Lₐ₅₅₇ | R_{y1}-21 | A-17 | Lₐ₅₅₈ | R_{y1}-21 | A-18 |
| Lₐ₅₅₉ | R_{y1}-21 | A-19 | Lₐ₅₆₀ | R_{y1}-21 | A-20 |
| Lₐ₅₆₁ | R_{y1}-21 | A-21 | Lₐ₅₆₂ | R_{y1}-21 | A-22 |
| Lₐ₅₆₃ | R_{y1}-21 | A-23 | Lₐ₅₆₄ | R_{y1}-21 | A-24 |
| Lₐ₅₆₅ | R_{y1}-21 | A-25 | Lₐ₅₆₆ | R_{y1}-21 | A-26 |
| Lₐ₅₆₇ | R_{y1}-21 | A-27 | Lₐ₅₆₈ | R_{y1}-21 | A-28 |
| Lₐ₅₆₉ | R_{y1}-21 | A-29 | Lₐ₅₇₀ | R_{y1}-21 | A-30 |
| Lₐ₅₇₁ | R_{y1}-21 | A-31 | Lₐ₅₇₂ | R_{y1}-21 | A-32 |
| Lₐ₅₇₃ | R_{y1}-21 | A-33 | Lₐ₅₇₄ | R_{y1}-21 | A-34 |
| Lₐ₅₇₅ | R_{y1}-21 | A-35 | Lₐ₅₇₆ | R_{y1}-21 | A-36 |
| Lₐ₅₇₇ | R_{y1}-21 | A-37 | Lₐ₅₇₈ | R_{y1}-21 | A-38 |
| Lₐ₅₇₉ | R_{y1}-21 | A-39 | Lₐ₅₈₀ | R_{y1}-21 | A-40 |
| Lₐ₅₈₁ | R_{y1}-21 | A-41 | Lₐ₅₈₂ | R_{y1}-21 | A-42 |
| Lₐ₅₈₃ | R_{y1}-21 | A-43 | Lₐ₅₈₄ | R_{y1}-21 | A-44 |
| Lₐ₅₈₅ | R_{y1}-21 | A-45 | Lₐ₅₈₆ | R_{y1}-21 | A-46 |
| Lₐ₅₈₇ | R_{y1}-21 | A-47 | Lₐ₅₈₈ | R_{y1}-21 | A-48 |
| Lₐ₅₈₉ | R_{y1}-21 | A-49 | Lₐ₅₉₀ | R_{y1}-21 | A-50 |
| Lₐ₅₉₁ | R_{y1}-21 | A-51 | Lₐ₅₉₂ | R_{y1}-21 | A-52 |
| Lₐ₅₉₃ | R_{y1}-21 | A-53 | Lₐ₅₉₄ | R_{y1}-21 | A-54 |
| Lₐ₅₉₅ | R_{y1}-21 | A-55 | Lₐ₅₉₆ | R_{y1}-21 | A-56 |
| Lₐ₅₉₇ | R_{y1}-21 | A-57 | Lₐ₅₉₈ | R_{y1}-21 | A-58 |
| Lₐ₅₉₉ | R_{y1}-21 | A-59 | Lₐ₆₀₀ | R_{y1}-21 | A-60 |
| Lₐ₆₀₁ | R_{y1}-21 | A-61 | Lₐ₆₀₂ | R_{y1}-21 | A-62 |
| Lₐ₆₀₃ | R_{y1}-21 | A-63 | Lₐ₆₀₄ | R_{y1}-21 | A-64 |
| Lₐ₆₀₅ | R_{y1}-21 | A-65 | Lₐ₆₀₆ | R_{y1}-21 | A-66 |
| Lₐ₆₀₇ | R_{y1}-21 | A-67 | Lₐ₆₀₈ | R_{y1}-21 | A-68 |
| Lₐ₆₀₉ | R_{y1}-21 | A-69 | Lₐ₆₁₀ | R_{y1}-21 | A-70 |
| Lₐ₆₁₁ | R_{y1}-21 | A-71 | Lₐ₆₁₂ | R_{y1}-21 | A-72 |
| Lₐ₆₁₃ | R_{y1}-21 | A-73 | Lₐ₆₁₄ | R_{y1}-21 | A-74 |
| Lₐ₆₁₅ | R_{y1}-21 | A-75 | Lₐ₆₁₆ | R_{y1}-21 | A-76 |
| Lₐ₆₁₇ | R_{y1}-21 | A-77 | Lₐ₆₁₈ | R_{y1}-21 | A-78 |
| Lₐ₆₁₉ | R_{y1}-21 | A-79 | Lₐ₆₂₀ | R_{y1}-21 | A-80 |
| Lₐ₆₂₁ | R_{y1}-21 | A-81 | Lₐ₆₂₂ | R_{y1}-21 | A-82 |
| Lₐ₆₂₃ | R_{y1}-21 | A-83 | Lₐ₆₂₄ | R_{y1}-21 | A-84 |
| Lₐ₆₂₅ | R_{y1}-21 | A-85 | Lₐ₆₂₆ | R_{y1}-21 | A-86 |
| Lₐ₆₂₇ | R_{y1}-21 | A-87 | Lₐ₆₂₈ | R_{y1}-21 | A-88 |
| Lₐ₆₂₉ | R_{y1}-21 | A-89 | Lₐ₆₃₀ | R_{y1}-21 | A-90 |
| Lₐ₆₃₁ | R_{y1}-25 | A-1 | Lₐ₆₃₂ | R_{y1}-25 | A-2 |
| Lₐ₆₃₃ | R_{y1}-25 | A-3 | Lₐ₆₃₄ | R_{y1}-25 | A-4 |
| Lₐ₆₃₅ | R_{y1}-25 | A-5 | Lₐ₆₃₆ | R_{y1}-25 | A-6 |
| Lₐ₆₃₇ | R_{y1}-25 | A-7 | Lₐ₆₃₈ | R_{y1}-25 | A-8 |
| Lₐ₆₃₉ | R_{y1}-25 | A-9 | Lₐ₆₄₀ | R_{y1}-25 | A-10 |
| Lₐ₆₄₁ | R_{y1}-25 | A-11 | Lₐ₆₄₂ | R_{y1}-25 | A-12 |
| Lₐ₆₄₃ | R_{y1}-25 | A-13 | Lₐ₆₄₄ | R_{y1}-25 | A-14 |
| Lₐ₆₄₅ | R_{y1}-25 | A-15 | Lₐ₆₄₆ | R_{y1}-25 | A-16 |
| Lₐ₆₄₇ | R_{y1}-25 | A-17 | Lₐ₆₄₈ | R_{y1}-25 | A-18 |
| Lₐ₆₄₉ | R_{y1}-25 | A-19 | Lₐ₆₅₀ | R_{y1}-25 | A-20 |
| Lₐ₆₅₁ | R_{y1}-25 | A-21 | Lₐ₆₅₂ | R_{y1}-25 | A-22 |
| Lₐ₆₅₃ | R_{y1}-25 | A-23 | Lₐ₆₅₄ | R_{y1}-25 | A-24 |
| Lₐ₆₅₅ | R_{y1}-25 | A-25 | Lₐ₆₅₆ | R_{y1}-25 | A-26 |
| Lₐ₆₅₇ | R_{y1}-25 | A-27 | Lₐ₆₅₈ | R_{y1}-25 | A-28 |
| Lₐ₆₅₉ | R_{y1}-25 | A-29 | Lₐ₆₆₀ | R_{y1}-25 | A-30 |
| Lₐ₆₆₁ | R_{y1}-25 | A-31 | Lₐ₆₆₂ | R_{y1}-25 | A-32 |
| Lₐ₆₆₃ | R_{y1}-25 | A-33 | Lₐ₆₆₄ | R_{y1}-25 | A-34 |
| Lₐ₆₆₅ | R_{y1}-25 | A-35 | Lₐ₆₆₆ | R_{y1}-25 | A-36 |
| Lₐ₆₆₇ | R_{y1}-25 | A-37 | Lₐ₆₆₈ | R_{y1}-25 | A-38 |
| Lₐ₆₆₉ | R_{y1}-25 | A-39 | Lₐ₆₇₀ | R_{y1}-25 | A-40 |
| Lₐ₆₇₁ | R_{y1}-25 | A-41 | Lₐ₆₇₂ | R_{y1}-25 | A-42 |
| Lₐ₆₇₃ | R_{y1}-25 | A-43 | Lₐ₆₇₄ | R_{y1}-25 | A-44 |
| Lₐ₆₇₅ | R_{y1}-25 | A-45 | Lₐ₆₇₆ | R_{y1}-25 | A-46 |
| Lₐ₆₇₇ | R_{y1}-25 | A-47 | Lₐ₆₇₈ | R_{y1}-25 | A-48 |
| Lₐ₆₇₉ | R_{y1}-25 | A-49 | Lₐ₆₈₀ | R_{y1}-25 | A-50 |
| Lₐ₆₈₁ | R_{y1}-25 | A-51 | Lₐ₆₈₂ | R_{y1}-25 | A-52 |
| Lₐ₆₈₃ | R_{y1}-25 | A-53 | Lₐ₆₈₄ | R_{y1}-25 | A-54 |
| Lₐ₆₈₅ | R_{y1}-25 | A-55 | Lₐ₆₈₆ | R_{y1}-25 | A-56 |
| Lₐ₆₈₇ | R_{y1}-25 | A-57 | Lₐ₆₈₈ | R_{y1}-25 | A-58 |
| Lₐ₆₈₉ | R_{y1}-25 | A-59 | Lₐ₆₉₀ | R_{y1}-25 | A-60 |
| Lₐ₆₉₁ | R_{y1}-25 | A-61 | Lₐ₆₉₂ | R_{y1}-25 | A-62 |
| Lₐ₆₉₃ | R_{y1}-25 | A-63 | Lₐ₆₉₄ | R_{y1}-25 | A-64 |
| Lₐ₆₉₅ | R_{y1}-25 | A-65 | Lₐ₆₉₆ | R_{y1}-25 | A-66 |
| Lₐ₆₉₇ | R_{y1}-25 | A-67 | Lₐ₆₉₈ | R_{y1}-25 | A-68 |
| Lₐ₆₉₉ | R_{y1}-25 | A-69 | Lₐ₇₀₀ | R_{y1}-25 | A-70 |
| Lₐ₇₀₁ | R_{y1}-25 | A-71 | Lₐ₇₀₂ | R_{y1}-25 | A-72 |
| Lₐ₇₀₃ | R_{y1}-25 | A-73 | Lₐ₇₀₄ | R_{y1}-25 | A-74 |
| Lₐ₇₀₅ | R_{y1}-25 | A-75 | Lₐ₇₀₆ | R_{y1}-25 | A-76 |
| Lₐ₇₀₇ | R_{y1}-25 | A-77 | Lₐ₇₀₈ | R_{y1}-25 | A-78 |
| Lₐ₇₀₉ | R_{y1}-25 | A-79 | Lₐ₇₁₀ | R_{y1}-25 | A-80 |
| Lₐ₇₁₁ | R_{y1}-25 | A-81 | Lₐ₇₁₂ | R_{y1}-25 | A-82 |
| Lₐ₇₁₃ | R_{y1}-25 | A-83 | Lₐ₇₁₄ | R_{y1}-25 | A-84 |
| Lₐ₇₁₅ | R_{y1}-25 | A-85 | Lₐ₇₁₆ | R_{y1}-25 | A-86 |
| Lₐ₇₁₇ | R_{y1}-25 | A-87 | Lₐ₇₁₈ | R_{y1}-25 | A-88 |
| Lₐ₇₁₉ | R_{y1}-25 | A-89 | Lₐ₇₂₀ | R_{y1}-25 | A-90 |
| Lₐ₇₂₁ | R_{y1}-26 | A-1 | Lₐ₇₂₂ | R_{y1}-26 | A-2 |
| Lₐ₇₂₃ | R_{y1}-26 | A-3 | Lₐ₇₂₄ | R_{y1}-26 | A-4 |
| Lₐ₇₂₅ | R_{y1}-26 | A-5 | Lₐ₇₂₆ | R_{y1}-26 | A-6 |
| Lₐ₇₂₇ | R_{y1}-26 | A-7 | Lₐ₇₂₈ | R_{y1}-26 | A-8 |
| Lₐ₇₂₉ | R_{y1}-26 | A-9 | Lₐ₇₃₀ | R_{y1}-26 | A-10 |
| Lₐ₇₃₁ | R_{y1}-26 | A-11 | Lₐ₇₃₂ | R_{y1}-26 | A-12 |
| Lₐ₇₃₃ | R_{y1}-26 | A-13 | Lₐ₇₃₄ | R_{y1}-26 | A-14 |
| Lₐ₇₃₅ | R_{y1}-26 | A-15 | Lₐ₇₃₆ | R_{y1}-26 | A-16 |
| Lₐ₇₃₇ | R_{y1}-26 | A-17 | Lₐ₇₃₈ | R_{y1}-26 | A-18 |
| Lₐ₇₃₉ | R_{y1}-26 | A-19 | Lₐ₇₄₀ | R_{y1}-26 | A-20 |
| Lₐ₇₄₁ | R_{y1}-26 | A-21 | Lₐ₇₄₂ | R_{y1}-26 | A-22 |
| Lₐ₇₄₃ | R_{y1}-26 | A-23 | Lₐ₇₄₄ | R_{y1}-26 | A-24 |
| Lₐ₇₄₅ | R_{y1}-26 | A-25 | Lₐ₇₄₆ | R_{y1}-26 | A-26 |
| Lₐ₇₄₇ | R_{y1}-26 | A-27 | Lₐ₇₄₈ | R_{y1}-26 | A-28 |
| Lₐ₇₄₉ | R_{y1}-26 | A-29 | Lₐ₇₅₀ | R_{y1}-26 | A-30 |
| Lₐ₇₅₁ | R_{y1}-26 | A-31 | Lₐ₇₅₂ | R_{y1}-26 | A-32 |
| Lₐ₇₅₃ | R_{y1}-26 | A-33 | Lₐ₇₅₄ | R_{y1}-26 | A-34 |
| Lₐ₇₅₅ | R_{y1}-26 | A-35 | Lₐ₇₅₆ | R_{y1}-26 | A-36 |
| Lₐ₇₅₇ | R_{y1}-26 | A-37 | Lₐ₇₅₈ | R_{y1}-26 | A-38 |
| Lₐ₇₅₉ | R_{y1}-26 | A-39 | Lₐ₇₆₀ | R_{y1}-26 | A-40 |
| Lₐ₇₆₁ | R_{y1}-26 | A-41 | Lₐ₇₆₂ | R_{y1}-26 | A-42 |
| Lₐ₇₆₃ | R_{y1}-26 | A-43 | Lₐ₇₆₄ | R_{y1}-26 | A-44 |
| Lₐ₇₆₅ | R_{y1}-26 | A-45 | Lₐ₇₆₆ | R_{y1}-26 | A-46 |
| Lₐ₇₆₇ | R_{y1}-26 | A-47 | Lₐ₇₆₈ | R_{y1}-26 | A-48 |
| Lₐ₇₆₉ | R_{y1}-26 | A-49 | Lₐ₇₇₀ | R_{y1}-26 | A-50 |
| Lₐ₇₇₁ | R_{y1}-26 | A-51 | Lₐ₇₇₂ | R_{y1}-26 | A-52 |
| Lₐ₇₇₃ | R_{y1}-26 | A-53 | Lₐ₇₇₄ | R_{y1}-26 | A-54 |
| Lₐ₇₇₅ | R_{y1}-26 | A-55 | Lₐ₇₇₆ | R_{y1}-26 | A-56 |
| Lₐ₇₇₇ | R_{y1}-26 | A-57 | Lₐ₇₇₈ | R_{y1}-26 | A-58 |
| Lₐ₇₇₉ | R_{y1}-26 | A-59 | Lₐ₇₈₀ | R_{y1}-26 | A-60 |
| Lₐ₇₈₁ | R_{y1}-26 | A-61 | Lₐ₇₈₂ | R_{y1}-26 | A-62 |
| Lₐ₇₈₃ | R_{y1}-26 | A-63 | Lₐ₇₈₄ | R_{y1}-26 | A-64 |
| Lₐ₇₈₅ | R_{y1}-26 | A-65 | Lₐ₇₈₆ | R_{y1}-26 | A-66 |
| Lₐ₇₈₇ | R_{y1}-26 | A-67 | Lₐ₇₈₈ | R_{y1}-26 | A-68 |
| Lₐ₇₈₉ | R_{y1}-26 | A-69 | Lₐ₇₉₀ | R_{y1}-26 | A-70 |
| Lₐ₇₉₁ | R_{y1}-26 | A-71 | Lₐ₇₉₂ | R_{y1}-26 | A-72 |
| Lₐ₇₉₃ | R_{y1}-26 | A-73 | Lₐ₇₉₄ | R_{y1}-26 | A-74 |
| Lₐ₇₉₅ | R_{y1}-26 | A-75 | Lₐ₇₉₆ | R_{y1}-26 | A-76 |
| Lₐ₇₉₇ | R_{y1}-26 | A-77 | Lₐ₇₉₈ | R_{y1}-26 | A-78 |
| Lₐ₇₉₉ | R_{y1}-26 | A-79 | Lₐ₈₀₀ | R_{y1}-26 | A-80 |
| Lₐ₈₀₁ | R_{y1}-26 | A-81 | Lₐ₈₀₂ | R_{y1}-26 | A-82 |
| Lₐ₈₀₃ | R_{y1}-26 | A-83 | Lₐ₈₀₄ | R_{y1}-26 | A-84 |
| Lₐ₈₀₅ | R_{y1}-26 | A-85 | Lₐ₈₀₆ | R_{y1}-26 | A-86 |
| Lₐ₈₀₇ | R_{y1}-26 | A-87 | Lₐ₈₀₈ | R_{y1}-26 | A-88 |
| Lₐ₈₀₉ | R_{y1}-26 | A-89 | Lₐ₈₁₀ | R_{y1}-26 | A-90 |
| Lₐ₈₁₁ | R_{y1}-28 | A-1 | Lₐ₈₁₂ | R_{y1}-28 | A-2 |
| Lₐ₈₁₃ | R_{y1}-28 | A-3 | Lₐ₈₁₄ | R_{y1}-28 | A-4 |
| Lₐ₈₁₅ | R_{y1}-28 | A-5 | Lₐ₈₁₆ | R_{y1}-28 | A-6 |
| Lₐ₈₁₇ | R_{y1}-28 | A-7 | Lₐ₈₁₈ | R_{y1}-28 | A-8 |
| Lₐ₈₁₉ | R_{y1}-28 | A-9 | Lₐ₈₂₀ | R_{y1}-28 | A-10 |
| Lₐ₈₂₁ | R_{y1}-28 | A-11 | Lₐ₈₂₂ | R_{y1}-28 | A-12 |
| Lₐ₈₂₃ | R_{y1}-28 | A-13 | Lₐ₈₂₄ | R_{y1}-28 | A-14 |
| Lₐ₈₂₅ | R_{y1}-28 | A-15 | Lₐ₈₂₆ | R_{y1}-28 | A-16 |
| Lₐ₈₂₇ | R_{y1}-28 | A-17 | Lₐ₈₂₈ | R_{y1}-28 | A-18 |
| Lₐ₈₂₉ | R_{y1}-28 | A-19 | Lₐ₈₃₀ | R_{y1}-28 | A-20 |
| Lₐ₈₃₁ | R_{y1}-28 | A-21 | Lₐ₈₃₂ | R_{y1}-28 | A-22 |
| Lₐ₈₃₃ | R_{y1}-28 | A-23 | Lₐ₈₃₄ | R_{y1}-28 | A-24 |
| Lₐ₈₃₅ | R_{y1}-28 | A-25 | Lₐ₈₃₆ | R_{y1}-28 | A-26 |
| Lₐ₈₃₇ | R_{y1}-28 | A-27 | Lₐ₈₃₈ | R_{y1}-28 | A-28 |
| Lₐ₈₃₉ | R_{y1}-28 | A-29 | Lₐ₈₄₀ | R_{y1}-28 | A-30 |
| Lₐ₈₄₁ | R_{y1}-28 | A-31 | Lₐ₈₄₂ | R_{y1}-28 | A-32 |
| Lₐ₈₄₃ | R_{y1}-28 | A-33 | Lₐ₈₄₄ | R_{y1}-28 | A-34 |
| Lₐ₈₄₅ | R_{y1}-28 | A-35 | Lₐ₈₄₆ | R_{y1}-28 | A-36 |
| Lₐ₈₄₇ | R_{y1}-28 | A-37 | Lₐ₈₄₈ | R_{y1}-28 | A-38 |
| Lₐ₈₄₉ | R_{y1}-28 | A-39 | Lₐ₈₅₀ | R_{y1}-28 | A-40 |
| Lₐ₈₅₁ | R_{y1}-28 | A-41 | Lₐ₈₅₂ | R_{y1}-28 | A-42 |
| Lₐ₈₅₃ | R_{y1}-28 | A-43 | Lₐ₈₅₄ | R_{y1}-28 | A-44 |
| Lₐ₈₅₅ | R_{y1}-28 | A-45 | Lₐ₈₅₆ | R_{y1}-28 | A-46 |
| Lₐ₈₅₇ | R_{y1}-28 | A-47 | Lₐ₈₅₈ | R_{y1}-28 | A-48 |
| Lₐ₈₅₉ | R_{y1}-28 | A-49 | Lₐ₈₆₀ | R_{y1}-28 | A-50 |
| Lₐ₈₆₁ | R_{y1}-28 | A-51 | Lₐ₈₆₂ | R_{y1}-28 | A-52 |
| Lₐ₈₆₃ | R_{y1}-28 | A-53 | Lₐ₈₆₄ | R_{y1}-28 | A-54 |
| Lₐ₈₆₅ | R_{y1}-28 | A-55 | Lₐ₈₆₆ | R_{y1}-28 | A-56 |
| Lₐ₈₆₇ | R_{y1}-28 | A-57 | Lₐ₈₆₈ | R_{y1}-28 | A-58 |
| Lₐ₈₆₉ | R_{y1}-28 | A-59 | Lₐ₈₇₀ | R_{y1}-28 | A-60 |
| Lₐ₈₇₁ | R_{y1}-28 | A-61 | Lₐ₈₇₂ | R_{y1}-28 | A-62 |
| Lₐ₈₇₃ | R_{y1}-28 | A-63 | Lₐ₈₇₄ | R_{y1}-28 | A-64 |
| Lₐ₈₇₅ | R_{y1}-28 | A-65 | Lₐ₈₇₆ | R_{y1}-28 | A-66 |
| Lₐ₈₇₇ | R_{y1}-28 | A-67 | Lₐ₈₇₈ | R_{y1}-28 | A-68 |
| Lₐ₈₇₉ | R_{y1}-28 | A-69 | Lₐ₈₈₀ | R_{y1}-28 | A-70 |
| Lₐ₈₈₁ | R_{y1}-28 | A-71 | Lₐ₈₈₂ | R_{y1}-28 | A-72 |
| Lₐ₈₈₃ | R_{y1}-28 | A-73 | Lₐ₈₈₄ | R_{y1}-28 | A-74 |
| Lₐ₈₈₅ | R_{y1}-28 | A-75 | Lₐ₈₈₆ | R_{y1}-28 | A-76 |
| Lₐ₈₈₇ | R_{y1}-28 | A-77 | Lₐ₈₈₈ | R_{y1}-28 | A-78 |
| Lₐ₈₈₉ | R_{y1}-28 | A-79 | Lₐ₈₉₀ | R_{y1}-28 | A-80 |
| Lₐ₈₉₁ | R_{y1}-28 | A-81 | Lₐ₈₉₂ | R_{y1}-28 | A-82 |
| Lₐ₈₉₃ | R_{y1}-28 | A-83 | Lₐ₈₉₄ | R_{y1}-28 | A-84 |
| Lₐ₈₉₅ | R_{y1}-28 | A-85 | Lₐ₈₉₆ | R_{y1}-28 | A-86 |
| Lₐ₈₉₇ | R_{y1}-28 | A-87 | Lₐ₈₉₈ | R_{y1}-28 | A-88 |
| Lₐ₈₉₉ | R_{y1}-28 | A-89 | Lₐ₉₀₀ | R_{y1}-28 | A-90 |
| Lₐ₉₀₁ | R_{y1}-40 | A-1 | Lₐ₉₀₂ | R_{y1}-40 | A-2 |
| Lₐ₉₀₃ | R_{y1}-40 | A-3 | Lₐ₉₀₄ | R_{y1}-40 | A-4 |
| Lₐ₉₀₅ | R_{y1}-40 | A-5 | Lₐ₉₀₆ | R_{y1}-40 | A-6 |
| Lₐ₉₀₇ | R_{y1}-40 | A-7 | Lₐ₉₀₈ | R_{y1}-40 | A-8 |
| Lₐ₉₀₉ | R_{y1}-40 | A-9 | Lₐ₉₁₀ | R_{y1}-40 | A-10 |
| Lₐ₉₁₁ | R_{y1}-40 | A-11 | Lₐ₉₁₂ | R_{y1}-40 | A-12 |
| Lₐ₉₁₃ | R_{y1}-40 | A-13 | Lₐ₉₁₄ | R_{y1}-40 | A-14 |
| Lₐ₉₁₅ | R_{y1}-40 | A-15 | Lₐ₉₁₆ | R_{y1}-40 | A-16 |
| Lₐ₉₁₇ | R_{y1}-40 | A-17 | Lₐ₉₁₈ | R_{y1}-40 | A-18 |
| Lₐ₉₁₉ | R_{y1}-40 | A-19 | Lₐ₉₂₀ | R_{y1}-40 | A-20 |
| Lₐ₉₂₁ | R_{y1}-40 | A-21 | Lₐ₉₂₂ | R_{y1}-40 | A-22 |
| Lₐ₉₂₃ | R_{y1}-40 | A-23 | Lₐ₉₂₄ | R_{y1}-40 | A-24 |
| Lₐ₉₂₅ | R_{y1}-40 | A-25 | Lₐ₉₂₆ | R_{y1}-40 | A-26 |
| Lₐ₉₂₇ | R_{y1}-40 | A-27 | Lₐ₉₂₈ | R_{y1}-40 | A-28 |
| Lₐ₉₂₉ | R_{y1}-40 | A-29 | Lₐ₉₃₀ | R_{y1}-40 | A-30 |
| Lₐ₉₃₁ | R_{y1}-40 | A-31 | Lₐ₉₃₂ | R_{y1}-40 | A-32 |
| Lₐ₉₃₃ | R_{y1}-40 | A-33 | Lₐ₉₃₄ | R_{y1}-40 | A-34 |
| Lₐ₉₃₅ | R_{y1}-40 | A-35 | Lₐ₉₃₆ | R_{y1}-40 | A-36 |
| Lₐ₉₃₇ | R_{y1}-40 | A-37 | Lₐ₉₃₈ | R_{y1}-40 | A-38 |
| Lₐ₉₃₉ | R_{y1}-40 | A-39 | Lₐ₉₄₀ | R_{y1}-40 | A-40 |
| Lₐ₉₄₁ | R_{y1}-40 | A-41 | Lₐ₉₄₂ | R_{y1}-40 | A-42 |
| Lₐ₉₄₃ | R_{y1}-40 | A-43 | Lₐ₉₄₄ | R_{y1}-40 | A-44 |
| Lₐ₉₄₅ | R_{y1}-40 | A-45 | Lₐ₉₄₆ | R_{y1}-40 | A-46 |
| Lₐ₉₄₇ | R_{y1}-40 | A-47 | Lₐ₉₄₈ | R_{y1}-40 | A-48 |
| Lₐ₉₄₉ | R_{y1}-40 | A-49 | Lₐ₉₅₀ | R_{y1}-40 | A-50 |
| Lₐ₉₅₁ | R_{y1}-40 | A-51 | Lₐ₉₅₂ | R_{y1}-40 | A-52 |
| Lₐ₉₅₃ | R_{y1}-40 | A-53 | Lₐ₉₅₄ | R_{y1}-40 | A-54 |
| Lₐ₉₅₅ | R_{y1}-40 | A-55 | Lₐ₉₅₆ | R_{y1}-40 | A-56 |
| Lₐ₉₅₇ | R_{y1}-40 | A-57 | Lₐ₉₅₈ | R_{y1}-40 | A-58 |
| Lₐ₉₅₉ | R_{y1}-40 | A-59 | Lₐ₉₆₀ | R_{y1}-40 | A-60 |
| Lₐ₉₆₁ | R_{y1}-40 | A-61 | Lₐ₉₆₂ | R_{y1}-40 | A-62 |
| Lₐ₉₆₃ | R_{y1}-40 | A-63 | Lₐ₉₆₄ | R_{y1}-40 | A-64 |
| Lₐ₉₆₅ | R_{y1}-40 | A-65 | Lₐ₉₆₆ | R_{y1}-40 | A-66 |
| Lₐ₉₆₇ | R_{y1}-40 | A-67 | Lₐ₉₆₈ | R_{y1}-40 | A-68 |
| Lₐ₉₆₉ | R_{y1}-40 | A-69 | Lₐ₉₇₀ | R_{y1}-40 | A-70 |
| Lₐ₉₇₁ | R_{y1}-40 | A-71 | Lₐ₉₇₂ | R_{y1}-40 | A-72 |
| Lₐ₉₇₃ | R_{y1}-40 | A-73 | Lₐ₉₇₄ | R_{y1}-40 | A-74 |
| Lₐ₉₇₅ | R_{y1}-40 | A-75 | Lₐ₉₇₆ | R_{y1}-40 | A-76 |
| Lₐ₉₇₇ | R_{y1}-40 | A-77 | Lₐ₉₇₈ | R_{y1}-40 | A-78 |
| Lₐ₉₇₉ | R_{y1}-40 | A-79 | Lₐ₉₈₀ | R_{y1}-40 | A-80 |
| Lₐ₉₈₁ | R_{y1}-40 | A-81 | Lₐ₉₈₂ | R_{y1}-40 | A-82 |
| Lₐ₉₈₃ | R_{y1}-40 | A-83 | Lₐ₉₈₄ | R_{y1}-40 | A-84 |
| Lₐ₉₈₅ | R_{y1}-40 | A-85 | Lₐ₉₈₆ | R_{y1}-40 | A-86 |
| Lₐ₉₈₇ | R_{y1}-40 | A-87 | Lₐ₉₈₈ | R_{y1}-40 | A-88 |
| Lₐ₉₈₉ | R_{y1}-40 | A-89 | Lₐ₉₉₀ | R_{y1}-40 | A-90 |
| Lₐ₉₉₁ | R_{y1}-41 | A-1 | Lₐ₉₉₂ | R_{y1}-41 | A-2 |
| Lₐ₉₉₃ | R_{y1}-41 | A-3 | Lₐ₉₉₄ | R_{y1}-41 | A-4 |
| Lₐ₉₉₅ | R_{y1}-41 | A-5 | Lₐ₉₉₆ | R_{y1}-41 | A-6 |
| Lₐ₉₉₇ | R_{y1}-41 | A-7 | Lₐ₉₉₈ | R_{y1}-41 | A-8 |
| Lₐ₉₉₉ | R_{y1}-41 | A-9 | Lₐ₁₀₀₀ | R_{y1}-41 | A-10 |
| Lₐ₁₀₀₁ | R_{y1}-41 | A-11 | Lₐ₁₀₀₂ | R_{y1}-41 | A-12 |
| Lₐ₁₀₀₃ | R_{y1}-41 | A-13 | Lₐ₁₀₀₄ | R_{y1}-41 | A-14 |
| Lₐ₁₀₀₅ | R_{y1}-41 | A-15 | Lₐ₁₀₀₆ | R_{y1}-41 | A-16 |
| Lₐ₁₀₀₇ | R_{y1}-41 | A-17 | Lₐ₁₀₀₈ | R_{y1}-41 | A-18 |
| Lₐ₁₀₀₉ | R_{y1}-41 | A-19 | Lₐ₁₀₁₀ | R_{y1}-41 | A-20 |
| Lₐ₁₀₁₁ | R_{y1}-41 | A-21 | Lₐ₁₀₁₂ | R_{y1}-41 | A-22 |
| Lₐ₁₀₁₃ | R_{y1}-41 | A-23 | Lₐ₁₀₁₄ | R_{y1}-41 | A-24 |
| Lₐ₁₀₁₅ | R_{y1}-41 | A-25 | Lₐ₁₀₁₆ | R_{y1}-41 | A-26 |
| Lₐ₁₀₁₇ | R_{y1}-41 | A-27 | Lₐ₁₀₁₈ | R_{y1}-41 | A-28 |
| Lₐ₁₀₁₉ | R_{y1}-41 | A-29 | Lₐ₁₀₂₀ | R_{y1}-41 | A-30 |
| Lₐ₁₀₂₁ | R_{y1}-41 | A-31 | Lₐ₁₀₂₂ | R_{y1}-41 | A-32 |
| Lₐ₁₀₂₃ | R_{y1}-41 | A-33 | Lₐ₁₀₂₄ | R_{y1}-41 | A-34 |
| Lₐ₁₀₂₅ | R_{y1}-41 | A-35 | Lₐ₁₀₂₆ | R_{y1}-41 | A-36 |
| Lₐ₁₀₂₇ | R_{y1}-41 | A-37 | Lₐ₁₀₂₈ | R_{y1}-41 | A-38 |
| Lₐ₁₀₂₉ | R_{y1}-41 | A-39 | Lₐ₁₀₃₀ | R_{y1}-41 | A-40 |
| Lₐ₁₀₃₁ | R_{y1}-41 | A-41 | Lₐ₁₀₃₂ | R_{y1}-41 | A-42 |
| Lₐ₁₀₃₃ | R_{y1}-41 | A-43 | Lₐ₁₀₃₄ | R_{y1}-41 | A-44 |
| Lₐ₁₀₃₅ | R_{y1}-41 | A-45 | Lₐ₁₀₃₆ | R_{y1}-41 | A-46 |
| Lₐ₁₀₃₇ | R_{y1}-41 | A-47 | Lₐ₁₀₃₈ | R_{y1}-41 | A-48 |
| Lₐ₁₀₃₉ | R_{y1}-41 | A-49 | Lₐ₁₀₄₀ | R_{y1}-41 | A-50 |
| Lₐ₁₀₄₁ | R_{y1}-41 | A-51 | Lₐ₁₀₄₂ | R_{y1}-41 | A-52 |
| Lₐ₁₀₄₃ | R_{y1}-41 | A-53 | Lₐ₁₀₄₄ | R_{y1}-41 | A-54 |
| Lₐ₁₀₄₅ | R_{y1}-41 | A-55 | Lₐ₁₀₄₆ | R_{y1}-41 | A-56 |
| Lₐ₁₀₄₇ | R_{y1}-41 | A-57 | Lₐ₁₀₄₈ | R_{y1}-41 | A-58 |
| Lₐ₁₀₄₉ | R_{y1}-41 | A-59 | Lₐ₁₀₅₀ | R_{y1}-41 | A-60 |
| Lₐ₁₀₅₁ | R_{y1}-41 | A-61 | Lₐ₁₀₅₂ | R_{y1}-41 | A-62 |
| Lₐ₁₀₅₃ | R_{y1}-41 | A-63 | Lₐ₁₀₅₄ | R_{y1}-41 | A-64 |
| Lₐ₁₀₅₅ | R_{y1}-41 | A-65 | Lₐ₁₀₅₆ | R_{y1}-41 | A-66 |
| Lₐ₁₀₅₇ | R_{y1}-41 | A-67 | Lₐ₁₀₅₈ | R_{y1}-41 | A-68 |
| Lₐ₁₀₅₉ | R_{y1}-41 | A-69 | Lₐ₁₀₆₀ | R_{y1}-41 | A-70 |
| Lₐ₁₀₆₁ | R_{y1}-41 | A-71 | Lₐ₁₀₆₂ | R_{y1}-41 | A-72 |
| Lₐ₁₀₆₃ | R_{y1}-41 | A-73 | Lₐ₁₀₆₄ | R_{y1}-41 | A-74 |
| Lₐ₁₀₆₅ | R_{y1}-41 | A-75 | Lₐ₁₀₆₆ | R_{y1}-41 | A-76 |
| Lₐ₁₀₆₇ | R_{y1}-41 | A-77 | Lₐ₁₀₆₈ | R_{y1}-41 | A-78 |
| Lₐ₁₀₆₉ | R_{y1}-41 | A-79 | Lₐ₁₀₇₀ | R_{y1}-41 | A-80 |
| Lₐ₁₀₇₁ | R_{y1}-41 | A-81 | Lₐ₁₀₇₂ | R_{y1}-41 | A-82 |
| Lₐ₁₀₇₃ | R_{y1}-41 | A-83 | Lₐ₁₀₇₄ | R_{y1}-41 | A-84 |
| Lₐ₁₀₇₅ | R_{y1}-41 | A-85 | Lₐ₁₀₇₆ | R_{y1}-41 | A-86 |
| Lₐ₁₀₇₇ | R_{y1}-41 | A-87 | Lₐ₁₀₇₈ | R_{y1}-41 | A-88 |
| Lₐ₁₀₇₉ | R_{y1}-41 | A-89 | Lₐ₁₀₈₀ | R_{y1}-41 | A-90 |
| Lₐ₁₀₈₁ | R_{y1}-1 | A-12 | Lₐ₁₀₈₂ | R_{y1}-2 | A-12 |
| Lₐ₁₀₈₃ | R_{y1}-4 | A-12 | Lₐ₁₀₈₄ | R_{y1}-6 | A-12 |
| Lₐ₁₀₈₅ | R_{y1}-7 | A-12 | Lₐ₁₀₈₆ | R_{y1}-8 | A-12 |
| Lₐ₁₀₈₇ | R_{y1}-9 | A-12 | Lₐ₁₀₈₈ | R_{y1}-10 | A-12 |
| Lₐ₁₀₈₉ | R_{y1}-11 | A-12 | Lₐ₁₀₉₀ | R_{y1}-13 | A-12 |
| Lₐ₁₀₉₁ | R_{y1}-14 | A-12 | Lₐ₁₀₉₂ | R_{y1}-17 | A-12 |
| Lₐ₁₀₉₃ | R_{y1}-18 | A-12 | Lₐ₁₀₉₄ | R_{y1}-19 | A-12 |
| Lₐ₁₀₉₅ | R_{y1}-22 | A-12 | Lₐ₁₀₉₆ | R_{y1}-23 | A-12 |
| Lₐ₁₀₉₇ | R_{y1}-24 | A-12 | Lₐ₁₀₉₈ | R_{y1}-27 | A-12 |
| Lₐ₁₀₉₉ | R_{y1}-29 | A-12 | Lₐ₁₁₀₀ | R_{y1}-30 | A-12 |
| Lₐ₁₁₀₁ | R_{y1}-31 | A-12 | Lₐ₁₁₀₂ | R_{y1}-32 | A-12 |
| Lₐ₁₁₀₃ | R_{y1}-33 | A-12 | Lₐ₁₁₀₄ | R_{y1}-34 | A-12 |
| Lₐ₁₁₀₅ | R_{y1}-35 | A-12 | Lₐ₁₁₀₆ | R_{y1}-36 | A-12 |
| Lₐ₁₁₀₇ | R_{y1}-37 | A-12 | Lₐ₁₁₀₈ | R_{y1}-38 | A-12 |
| Lₐ₁₁₀₉ | R_{y1}-39 | A-12 | Lₐ₁₁₁₀ | R_{y1}-42 | A-12 |
| Lₐ₁₁₁₁ | R_{y1}-43 | A-12 | Lₐ₁₁₁₂ | R_{y1}-44 | A-12 |
| Lₐ₁₁₁₃ | R_{y1}-45 | A-12 | Lₐ₁₁₁₄ | R_{y1}-46 | A-12 |
| Lₐ₁₁₁₅ | R_{y1}-1 | A-13 | Lₐ₁₁₁₆ | R_{y1}-2 | A-13 |
| Lₐ₁₁₁₇ | R_{y1}-4 | A-13 | Lₐ₁₁₁₈ | R_{y1}-6 | A-13 |
| Lₐ₁₁₁₉ | R_{y1}-7 | A-13 | Lₐ₁₁₂₀ | R_{y1}-8 | A-13 |
| Lₐ₁₁₂₁ | R_{y1}-9 | A-13 | Lₐ₁₁₂₂ | R_{y1}-10 | A-13 |
| Lₐ₁₁₂₃ | R_{y1}-11 | A-13 | Lₐ₁₁₂₄ | R_{y1}-13 | A-13 |
| Lₐ₁₁₂₅ | R_{y1}-14 | A-13 | Lₐ₁₁₂₆ | R_{y1}-17 | A-13 |
| Lₐ₁₁₂₇ | R_{y1}-18 | A-13 | Lₐ₁₁₂₈ | R_{y1}-19 | A-13 |
| Lₐ₁₁₂₉ | R_{y1}-22 | A-13 | Lₐ₁₁₃₀ | R_{y1}-23 | A-13 |
| Lₐ₁₁₃₁ | R_{y1}-24 | A-13 | Lₐ₁₁₃₂ | R_{y1}-27 | A-13 |
| Lₐ₁₁₃₃ | R_{y1}-29 | A-13 | Lₐ₁₁₃₄ | R_{y1}-30 | A-13 |
| Lₐ₁₁₃₅ | R_{y1}-31 | A-13 | Lₐ₁₁₃₆ | R_{y1}-32 | A-13 |
| Lₐ₁₁₃₇ | R_{y1}-33 | A-13 | Lₐ₁₁₃₈ | R_{y1}-34 | A-13 |
| Lₐ₁₁₃₉ | R_{y1}-35 | A-13 | Lₐ₁₁₄₀ | R_{y1}-36 | A-13 |
| Lₐ₁₁₄₁ | R_{y1}-37 | A-13 | Lₐ₁₁₄₂ | R_{y1}-38 | A-13 |
| Lₐ₁₁₄₃ | R_{y1}-39 | A-13 | Lₐ₁₁₄₄ | R_{y1}-42 | A-13 |
| Lₐ₁₁₄₅ | R_{y1}-43 | A-13 | Lₐ₁₁₄₆ | R_{y1}-44 | A-13 |
| Lₐ₁₁₄₇ | R_{y1}-45 | A-13 | Lₐ₁₁₄₈ | R_{y1}-46 | A-13 |
| Lₐ₁₁₄₉ | R_{y1}-1 | A-26 | Lₐ₁₁₅₀ | R_{y1}-2 | A-26 |
| Lₐ₁₁₅₁ | R_{y1}-4 | A-26 | Lₐ₁₁₅₂ | R_{y1}-6 | A-26 |
| Lₐ₁₁₅₃ | R_{y1}-7 | A-26 | Lₐ₁₁₅₄ | R_{y1}-8 | A-26 |
| Lₐ₁₁₅₅ | R_{y1}-9 | A-26 | Lₐ₁₁₅₆ | R_{y1}-10 | A-26 |
| Lₐ₁₁₅₇ | R_{y1}-11 | A-26 | Lₐ₁₁₅₈ | R_{y1}-13 | A-26 |
| Lₐ₁₁₅₉ | R_{y1}-14 | A-26 | Lₐ₁₁₆₀ | R_{y1}-17 | A-26 |
| Lₐ₁₁₆₁ | R_{y1}-18 | A-26 | Lₐ₁₁₆₂ | R_{y1}-19 | A-26 |
| Lₐ₁₁₆₃ | R_{y1}-22 | A-26 | Lₐ₁₁₆₄ | R_{y1}-23 | A-26 |
| Lₐ₁₁₆₅ | R_{y1}-24 | A-26 | Lₐ₁₁₆₆ | R_{y1}-27 | A-26 |
| Lₐ₁₁₆₇ | R_{y1}-29 | A-26 | Lₐ₁₁₆₈ | R_{y1}-30 | A-26 |
| Lₐ₁₁₆₉ | R_{y1}-31 | A-26 | Lₐ₁₁₇₀ | R_{y1}-32 | A-26 |
| Lₐ₁₁₇₁ | R_{y1}-33 | A-26 | Lₐ₁₁₇₂ | R_{y1}-34 | A-26 |
| Lₐ₁₁₇₃ | R_{y1}-35 | A-26 | Lₐ₁₁₇₄ | R_{y1}-36 | A-26 |
| Lₐ₁₁₇₅ | R_{y1}-37 | A-26 | Lₐ₁₁₇₆ | R_{y1}-38 | A-26 |
| Lₐ₁₁₇₇ | R_{y1}-39 | A-26 | Lₐ₁₁₇₈ | R_{y1}-42 | A-26 |
| Lₐ₁₁₇₉ | R_{y1}-43 | A-26 | Lₐ₁₁₈₀ | R_{y1}-44 | A-26 |
| Lₐ₁₁₈₁ | R_{y1}-45 | A-26 | Lₐ₁₁₈₂ | R_{y1}-46 | A-26 |
| Lₐ₁₁₈₃ | R_{y1}-1 | A-28 | Lₐ₁₁₈₄ | R_{y1}-2 | A-28 |
| Lₐ₁₁₈₅ | R_{y1}-4 | A-28 | Lₐ₁₁₈₆ | R_{y1}-6 | A-28 |
| Lₐ₁₁₈₇ | R_{y1}-7 | A-28 | Lₐ₁₁₈₈ | R_{y1}-8 | A-28 |
| Lₐ₁₁₈₉ | R_{y1}-9 | A-28 | Lₐ₁₁₉₀ | R_{y1}-10 | A-28 |
| Lₐ₁₁₉₁ | R_{y1}-11 | A-28 | Lₐ₁₁₉₂ | R_{y1}-13 | A-28 |
| Lₐ₁₁₉₃ | R_{y1}-14 | A-28 | Lₐ₁₁₉₄ | R_{y1}-17 | A-28 |
| Lₐ₁₁₉₅ | R_{y1}-18 | A-28 | Lₐ₁₁₉₆ | R_{y1}-19 | A-28 |
| Lₐ₁₁₉₇ | R_{y1}-22 | A-28 | Lₐ₁₁₉₈ | R_{y1}-23 | A-28 |
| Lₐ₁₁₉₉ | R_{y1}-24 | A-28 | Lₐ₁₂₀₀ | R_{y1}-27 | A-28 |
| Lₐ₁₂₀₁ | R_{y1}-29 | A-28 | Lₐ₁₂₀₂ | R_{y1}-30 | A-28 |
| Lₐ₁₂₀₃ | R_{y1}-31 | A-28 | Lₐ₁₂₀₄ | R_{y1}-32 | A-28 |
| Lₐ₁₂₀₅ | R_{y1}-33 | A-28 | Lₐ₁₂₀₆ | R_{y1}-34 | A-28 |
| Lₐ₁₂₀₇ | R_{y1}-35 | A-28 | Lₐ₁₂₀₈ | R_{y1}-36 | A-28 |
| Lₐ₁₂₀₉ | R_{y1}-37 | A-28 | Lₐ₁₂₁₀ | R_{y1}-38 | A-28 |
| Lₐ₁₂₁₁ | R_{y1}-39 | A-28 | Lₐ₁₂₁₂ | R_{y1}-42 | A-28 |
| Lₐ₁₂₁₃ | R_{y1}-43 | A-28 | Lₐ₁₂₁₄ | R_{y1}-44 | A-28 |
| Lₐ₁₂₁₅ | R_{y1}-45 | A-28 | Lₐ₁₂₁₆ | R_{y1}-46 | A-28 |
| Lₐ₁₂₁₇ | R_{y1}-1 | A-39 | Lₐ₁₂₁₈ | R_{y1}-2 | A-39 |
| Lₐ₁₂₁₉ | R_{y1}-4 | A-39 | Lₐ₁₂₂₀ | R_{y1}-6 | A-39 |
| Lₐ₁₂₂₁ | R_{y1}-7 | A-39 | Lₐ₁₂₂₂ | R_{y1}-8 | A-39 |
| Lₐ₁₂₂₃ | R_{y1}-9 | A-39 | Lₐ₁₂₂₄ | R_{y1}-10 | A-39 |
| Lₐ₁₂₂₅ | R_{y1}-11 | A-39 | Lₐ₁₂₂₆ | R_{y1}-13 | A-39 |
| Lₐ₁₂₂₇ | R_{y1}-14 | A-39 | Lₐ₁₂₂₈ | R_{y1}-17 | A-39 |
| Lₐ₁₂₂₉ | R_{y1}-18 | A-39 | Lₐ₁₂₃₀ | R_{y1}-19 | A-39 |
| Lₐ₁₂₃₁ | R_{y1}-22 | A-39 | Lₐ₁₂₃₂ | R_{y1}-23 | A-39 |
| Lₐ₁₂₃₃ | R_{y1}-24 | A-39 | Lₐ₁₂₃₄ | R_{y1}-27 | A-39 |
| Lₐ₁₂₃₅ | R_{y1}-29 | A-39 | Lₐ₁₂₃₆ | R_{y1}-30 | A-39 |
| Lₐ₁₂₃₇ | R_{y1}-31 | A-39 | Lₐ₁₂₃₈ | R_{y1}-32 | A-39 |
| Lₐ₁₂₃₉ | R_{y1}-33 | A-39 | Lₐ₁₂₄₀ | R_{y1}-34 | A-39 |
| Lₐ₁₂₄₁ | R_{y1}-35 | A-39 | Lₐ₁₂₄₂ | R_{y1}-36 | A-39 |
| Lₐ₁₂₄₃ | R_{y1}-37 | A-39 | Lₐ₁₂₄₄ | R_{y1}-38 | A-39 |
| Lₐ₁₂₄₅ | R_{y1}-39 | A-39 | Lₐ₁₂₄₆ | R_{y1}-42 | A-39 |
| Lₐ₁₂₄₇ | R_{y1}-43 | A-39 | Lₐ₁₂₄₈ | R_{y1}-44 | A-39 |
| Lₐ₁₂₄₉ | R_{y1}-45 | A-39 | Lₐ₁₂₅₀ | R_{y1}-46 | A-39 |
| Lₐ₁₂₅₁ | R_{y1}-1 | A-40 | Lₐ₁₂₅₂ | R_{y1}-2 | A-40 |
| Lₐ₁₂₅₃ | R_{y1}-4 | A-40 | Lₐ₁₂₅₄ | R_{y1}-6 | A-40 |
| Lₐ₁₂₅₅ | R_{y1}-7 | A-40 | Lₐ₁₂₅₆ | R_{y1}-8 | A-40 |
| Lₐ₁₂₅₇ | R_{y1}-9 | A-40 | Lₐ₁₂₅₈ | R_{y1}-10 | A-40 |
| Lₐ₁₂₅₉ | R_{y1}-11 | A-40 | Lₐ₁₂₆₀ | R_{y1}-13 | A-40 |
| Lₐ₁₂₆₁ | R_{y1}-14 | A-40 | Lₐ₁₂₆₂ | R_{y1}-17 | A-40 |
| Lₐ₁₂₆₃ | R_{y1}-18 | A-40 | Lₐ₁₂₆₄ | R_{y1}-19 | A-40 |
| Lₐ₁₂₆₅ | R_{y1}-22 | A-40 | Lₐ₁₂₆₆ | R_{y1}-23 | A-40 |
| Lₐ₁₂₆₇ | R_{y1}-24 | A-40 | Lₐ₁₂₆₈ | R_{y1}-27 | A-40 |
| Lₐ₁₂₆₉ | R_{y1}-29 | A-40 | Lₐ₁₂₇₀ | R_{y1}-30 | A-40 |
| Lₐ₁₂₇₁ | R_{y1}-31 | A-40 | Lₐ₁₂₇₂ | R_{y1}-32 | A-40 |
| Lₐ₁₂₇₃ | R_{y1}-33 | A-40 | Lₐ₁₂₇₄ | R_{y1}-34 | A-40 |
| Lₐ₁₂₇₅ | R_{y1}-35 | A-40 | Lₐ₁₂₇₆ | R_{y1}-36 | A-40 |
| Lₐ₁₂₇₇ | R_{y1}-37 | A-40 | Lₐ₁₂₇₈ | R_{y1}-38 | A-40 |
| Lₐ₁₂₇₉ | R_{y1}-39 | A-40 | Lₐ₁₂₈₀ | R_{y1}-42 | A-40 |
| Lₐ₁₂₈₁ | R_{y1}-43 | A-40 | Lₐ₁₂₈₂ | R_{y1}-44 | A-40 |
| Lₐ₁₂₈₃ | R_{y1}-45 | A-40 | Lₐ₁₂₈₄ | R_{y1}-46 | A-40 |

wherein Lₐ₁₂₈₅ to Lₐ₂₅₆₈ each have the following structure: 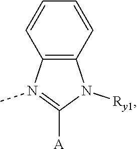
wherein R_{y1} and the fragment A are selected from the atoms or groups in the following table:

| Lₐ | R_{y1} | Fragment A | Lₐ | R_{y1} | Fragment A |
|---|---|---|---|---|---|
| Lₐ₁₂₈₅ | R_{y1}-3 | A-1 | Lₐ₁₂₈₆ | R_{y1}-3 | A-2 |
| Lₐ₁₂₈₇ | R_{y1}-3 | A-3 | Lₐ₁₂₈₈ | R_{y1}-3 | A-4 |
| Lₐ₁₂₈₉ | R_{y1}-3 | A-5 | Lₐ₁₂₉₀ | R_{y1}-3 | A-6 |
| Lₐ₁₂₉₁ | R_{y1}-3 | A-7 | Lₐ₁₂₉₂ | R_{y1}-3 | A-8 |
| Lₐ₁₂₉₃ | R_{y1}-3 | A-9 | Lₐ₁₂₉₄ | R_{y1}-3 | A-10 |
| Lₐ₁₂₉₅ | R_{y1}-3 | A-11 | Lₐ₁₂₉₆ | R_{y1}-3 | A-12 |
| Lₐ₁₂₉₇ | R_{y1}-3 | A-13 | Lₐ₁₂₉₈ | R_{y1}-3 | A-14 |
| Lₐ₁₂₉₉ | R_{y1}-3 | A-15 | Lₐ₁₃₀₀ | R_{y1}-3 | A-16 |
| Lₐ₁₃₀₁ | R_{y1}-3 | A-17 | Lₐ₁₃₀₂ | R_{y1}-3 | A-18 |
| Lₐ₁₃₀₃ | R_{y1}-3 | A-19 | Lₐ₁₃₀₄ | R_{y1}-3 | A-20 |
| Lₐ₁₃₀₅ | R_{y1}-3 | A-21 | Lₐ₁₃₀₆ | R_{y1}-3 | A-22 |
| Lₐ₁₃₀₇ | R_{y1}-3 | A-23 | Lₐ₁₃₀₈ | R_{y1}-3 | A-24 |
| Lₐ₁₃₀₉ | R_{y1}-3 | A-25 | Lₐ₁₃₁₀ | R_{y1}-3 | A-26 |
| Lₐ₁₃₁₁ | R_{y1}-3 | A-27 | Lₐ₁₃₁₂ | R_{y1}-3 | A-28 |
| Lₐ₁₃₁₃ | R_{y1}-3 | A-29 | Lₐ₁₃₁₄ | R_{y1}-3 | A-30 |
| Lₐ₁₃₁₅ | R_{y1}-3 | A-31 | Lₐ₁₃₁₆ | R_{y1}-3 | A-32 |
| Lₐ₁₃₁₇ | R_{y1}-3 | A-33 | Lₐ₁₃₁₈ | R_{y1}-3 | A-34 |
| Lₐ₁₃₁₉ | R_{y1}-3 | A-35 | Lₐ₁₃₂₀ | R_{y1}-3 | A-36 |
| Lₐ₁₃₂₁ | R_{y1}-3 | A-37 | Lₐ₁₃₂₂ | R_{y1}-3 | A-38 |
| Lₐ₁₃₂₃ | R_{y1}-3 | A-39 | Lₐ₁₃₂₄ | R_{y1}-3 | A-40 |
| Lₐ₁₃₂₅ | R_{y1}-3 | A-41 | Lₐ₁₃₂₆ | R_{y1}-3 | A-42 |
| Lₐ₁₃₂₇ | R_{y1}-3 | A-43 | Lₐ₁₃₂₈ | R_{y1}-3 | A-44 |
| Lₐ₁₃₂₉ | R_{y1}-3 | A-45 | Lₐ₁₃₃₀ | R_{y1}-3 | A-46 |
| Lₐ₁₃₃₁ | R_{y1}-3 | A-47 | Lₐ₁₃₃₂ | R_{y1}-3 | A-48 |
| Lₐ₁₃₃₃ | R_{y1}-3 | A-49 | Lₐ₁₃₃₄ | R_{y1}-3 | A-50 |
| Lₐ₁₃₃₅ | R_{y1}-3 | A-51 | Lₐ₁₃₃₆ | R_{y1}-3 | A-52 |
| Lₐ₁₃₃₇ | R_{y1}-3 | A-53 | Lₐ₁₃₃₈ | R_{y1}-3 | A-54 |
| Lₐ₁₃₃₉ | R_{y1}-3 | A-55 | Lₐ₁₃₄₀ | R_{y1}-3 | A-56 |
| Lₐ₁₃₄₁ | R_{y1}-3 | A-57 | Lₐ₁₃₄₂ | R_{y1}-3 | A-58 |
| Lₐ₁₃₄₃ | R_{y1}-3 | A-59 | Lₐ₁₃₄₄ | R_{y1}-3 | A-60 |
| Lₐ₁₃₄₅ | R_{y1}-3 | A-61 | Lₐ₁₃₄₆ | R_{y1}-3 | A-62 |
| Lₐ₁₃₄₇ | R_{y1}-3 | A-63 | Lₐ₁₃₄₈ | R_{y1}-3 | A-64 |
| Lₐ₁₃₄₉ | R_{y1}-3 | A-65 | Lₐ₁₃₅₀ | R_{y1}-3 | A-66 |
| Lₐ₁₃₅₁ | R_{y1}-3 | A-67 | Lₐ₁₃₅₂ | R_{y1}-3 | A-68 |
| Lₐ₁₃₅₃ | R_{y1}-3 | A-69 | Lₐ₁₃₅₄ | R_{y1}-3 | A-70 |
| Lₐ₁₃₅₅ | R_{y1}-3 | A-71 | Lₐ₁₃₅₆ | R_{y1}-3 | A-72 |
| Lₐ₁₃₅₇ | R_{y1}-3 | A-73 | Lₐ₁₃₅₈ | R_{y1}-3 | A-74 |
| Lₐ₁₃₅₉ | R_{y1}-3 | A-75 | Lₐ₁₃₆₀ | R_{y1}-3 | A-76 |
| Lₐ₁₃₆₁ | R_{y1}-3 | A-77 | Lₐ₁₃₆₂ | R_{y1}-3 | A-78 |
| Lₐ₁₃₆₃ | R_{y1}-3 | A-79 | Lₐ₁₃₆₄ | R_{y1}-3 | A-80 |
| Lₐ₁₃₆₅ | R_{y1}-3 | A-81 | Lₐ₁₃₆₆ | R_{y1}-3 | A-82 |
| Lₐ₁₃₆₇ | R_{y1}-3 | A-83 | Lₐ₁₃₆₈ | R_{y1}-3 | A-84 |
| Lₐ₁₃₆₉ | R_{y1}-3 | A-85 | Lₐ₁₃₇₀ | R_{y1}-3 | A-86 |
| Lₐ₁₃₇₁ | R_{y1}-3 | A-87 | Lₐ₁₃₇₂ | R_{y1}-3 | A-88 |
| Lₐ₁₃₇₃ | R_{y1}-3 | A-89 | Lₐ₁₃₇₄ | R_{y1}-3 | A-90 |
| Lₐ₁₃₇₅ | R_{y1}-5 | A-1 | Lₐ₁₃₇₆ | R_{y1}-5 | A-2 |
| Lₐ₁₃₇₇ | R_{y1}-5 | A-3 | Lₐ₁₃₇₈ | R_{y1}-5 | A-4 |
| Lₐ₁₃₇₉ | R_{y1}-5 | A-5 | Lₐ₁₃₈₀ | R_{y1}-5 | A-6 |
| Lₐ₁₃₈₁ | R_{y1}-5 | A-7 | Lₐ₁₃₈₂ | R_{y1}-5 | A-8 |
| Lₐ₁₃₈₃ | R_{y1}-5 | A-9 | Lₐ₁₃₈₄ | R_{y1}-5 | A-10 |
| Lₐ₁₃₈₅ | R_{y1}-5 | A-11 | Lₐ₁₃₈₆ | R_{y1}-5 | A-12 |
| Lₐ₁₃₈₇ | R_{y1}-5 | A-13 | Lₐ₁₃₈₈ | R_{y1}-5 | A-14 |
| Lₐ₁₃₈₉ | R_{y1}-5 | A-15 | Lₐ₁₃₉₀ | R_{y1}-5 | A-16 |
| Lₐ₁₃₉₁ | R_{y1}-5 | A-17 | Lₐ₁₃₉₂ | R_{y1}-5 | A-18 |
| Lₐ₁₃₉₃ | R_{y1}-5 | A-19 | Lₐ₁₃₉₄ | R_{y1}-5 | A-20 |
| Lₐ₁₃₉₅ | R_{y1}-5 | A-21 | Lₐ₁₃₉₆ | R_{y1}-5 | A-22 |
| Lₐ₁₃₉₇ | R_{y1}-5 | A-23 | Lₐ₁₃₉₈ | R_{y1}-5 | A-24 |
| Lₐ₁₃₉₉ | R_{y1}-5 | A-25 | Lₐ₁₄₀₀ | R_{y1}-5 | A-26 |
| Lₐ₁₄₀₁ | R_{y1}-5 | A-27 | Lₐ₁₄₀₂ | R_{y1}-5 | A-28 |
| Lₐ₁₄₀₃ | R_{y1}-5 | A-29 | Lₐ₁₄₀₄ | R_{y1}-5 | A-30 |
| Lₐ₁₄₀₅ | R_{y1}-5 | A-31 | Lₐ₁₄₀₆ | R_{y1}-5 | A-32 |
| Lₐ₁₄₀₇ | R_{y1}-5 | A-33 | Lₐ₁₄₀₈ | R_{y1}-5 | A-34 |
| Lₐ₁₄₀₉ | R_{y1}-5 | A-35 | Lₐ₁₄₁₀ | R_{y1}-5 | A-36 |
| Lₐ₁₄₁₁ | R_{y1}-5 | A-37 | Lₐ₁₄₁₂ | R_{y1}-5 | A-38 |
| Lₐ₁₄₁₃ | R_{y1}-5 | A-39 | Lₐ₁₄₁₄ | R_{y1}-5 | A-40 |
| Lₐ₁₄₁₅ | R_{y1}-5 | A-41 | Lₐ₁₄₁₆ | R_{y1}-5 | A-42 |
| Lₐ₁₄₁₇ | R_{y1}-5 | A-43 | Lₐ₁₄₁₈ | R_{y1}-5 | A-44 |
| Lₐ₁₄₁₉ | R_{y1}-5 | A-45 | Lₐ₁₄₂₀ | R_{y1}-5 | A-46 |
| Lₐ₁₄₂₁ | R_{y1}-5 | A-47 | Lₐ₁₄₂₂ | R_{y1}-5 | A-48 |
| Lₐ₁₄₂₃ | R_{y1}-5 | A-49 | Lₐ₁₄₂₄ | R_{y1}-5 | A-50 |
| Lₐ₁₄₂₅ | R_{y1}-5 | A-51 | Lₐ₁₄₂₆ | R_{y1}-5 | A-52 |
| Lₐ₁₄₂₇ | R_{y1}-5 | A-53 | Lₐ₁₄₂₈ | R_{y1}-5 | A-54 |
| Lₐ₁₄₂₉ | R_{y1}-5 | A-55 | Lₐ₁₄₃₀ | R_{y1}-5 | A-56 |
| Lₐ₁₄₃₁ | R_{y1}-5 | A-57 | Lₐ₁₄₃₂ | R_{y1}-5 | A-58 |
| Lₐ₁₄₃₃ | R_{y1}-5 | A-59 | Lₐ₁₄₃₄ | R_{y1}-5 | A-60 |
| Lₐ₁₄₃₅ | R_{y1}-5 | A-61 | Lₐ₁₄₃₆ | R_{y1}-5 | A-62 |
| Lₐ₁₄₃₇ | R_{y1}-5 | A-63 | Lₐ₁₄₃₈ | R_{y1}-5 | A-64 |
| Lₐ₁₄₃₉ | R_{y1}-5 | A-65 | Lₐ₁₄₄₀ | R_{y1}-5 | A-66 |
| Lₐ₁₄₄₁ | R_{y1}-5 | A-67 | Lₐ₁₄₄₂ | R_{y1}-5 | A-68 |
| Lₐ₁₄₄₃ | R_{y1}-5 | A-69 | Lₐ₁₄₄₄ | R_{y1}-5 | A-70 |
| Lₐ₁₄₄₅ | R_{y1}-5 | A-71 | Lₐ₁₄₄₆ | R_{y1}-5 | A-72 |
| Lₐ₁₄₄₇ | R_{y1}-5 | A-73 | Lₐ₁₄₄₈ | R_{y1}-5 | A-74 |
| Lₐ₁₄₄₉ | R_{y1}-5 | A-75 | Lₐ₁₄₅₀ | R_{y1}-5 | A-76 |
| Lₐ₁₄₅₁ | R_{y1}-5 | A-77 | Lₐ₁₄₅₂ | R_{y1}-5 | A-78 |
| Lₐ₁₄₅₃ | R_{y1}-5 | A-79 | Lₐ₁₄₅₄ | R_{y1}-5 | A-80 |
| Lₐ₁₄₅₅ | R_{y1}-5 | A-81 | Lₐ₁₄₅₆ | R_{y1}-5 | A-82 |
| Lₐ₁₄₅₇ | R_{y1}-5 | A-83 | Lₐ₁₄₅₈ | R_{y1}-5 | A-84 |
| Lₐ₁₄₅₉ | R_{y1}-5 | A-85 | Lₐ₁₄₆₀ | R_{y1}-5 | A-86 |
| Lₐ₁₄₆₁ | R_{y1}-5 | A-87 | Lₐ₁₄₆₂ | R_{y1}-5 | A-88 |
| Lₐ₁₄₆₃ | R_{y1}-5 | A-89 | Lₐ₁₄₆₄ | R_{y1}-5 | A-90 |
| Lₐ₁₄₆₅ | R_{y1}-12 | A-1 | Lₐ₁₄₆₆ | R_{y1}-12 | A-2 |
| Lₐ₁₄₆₇ | R_{y1}-12 | A-3 | Lₐ₁₄₆₈ | R_{y1}-12 | A-4 |
| Lₐ₁₄₆₉ | R_{y1}-12 | A-5 | Lₐ₁₄₇₀ | R_{y1}-12 | A-6 |
| Lₐ₁₄₇₁ | R_{y1}-12 | A-7 | Lₐ₁₄₇₂ | R_{y1}-12 | A-8 |
| Lₐ₁₄₇₃ | R_{y1}-12 | A-9 | Lₐ₁₄₇₄ | R_{y1}-12 | A-10 |
| Lₐ₁₄₇₅ | R_{y1}-12 | A-11 | Lₐ₁₄₇₆ | R_{y1}-12 | A-12 |
| Lₐ₁₄₇₇ | R_{y1}-12 | A-13 | Lₐ₁₄₇₈ | R_{y1}-12 | A-14 |
| Lₐ₁₄₇₉ | R_{y1}-12 | A-15 | Lₐ₁₄₈₀ | R_{y1}-12 | A-16 |
| Lₐ₁₄₈₁ | R_{y1}-12 | A-17 | Lₐ₁₄₈₂ | R_{y1}-12 | A-18 |
| Lₐ₁₄₈₃ | R_{y1}-12 | A-19 | Lₐ₁₄₈₄ | R_{y1}-12 | A-20 |
| Lₐ₁₄₈₅ | R_{y1}-12 | A-21 | Lₐ₁₄₈₆ | R_{y1}-12 | A-22 |
| Lₐ₁₄₈₇ | R_{y1}-12 | A-23 | Lₐ₁₄₈₈ | R_{y1}-12 | A-24 |
| Lₐ₁₄₈₉ | R_{y1}-12 | A-25 | Lₐ₁₄₉₀ | R_{y1}-12 | A-26 |
| Lₐ₁₄₉₁ | R_{y1}-12 | A-27 | Lₐ₁₄₉₂ | R_{y1}-12 | A-28 |
| Lₐ₁₄₉₃ | R_{y1}-12 | A-29 | Lₐ₁₄₉₄ | R_{y1}-12 | A-30 |
| Lₐ₁₄₉₅ | R_{y1}-12 | A-31 | Lₐ₁₄₉₆ | R_{y1}-12 | A-32 |
| Lₐ₁₄₉₇ | R_{y1}-12 | A-33 | Lₐ₁₄₉₈ | R_{y1}-12 | A-34 |
| Lₐ₁₄₉₉ | R_{y1}-12 | A-35 | Lₐ₁₅₀₀ | R_{y1}-12 | A-36 |
| Lₐ₁₅₀₁ | R_{y1}-12 | A-37 | Lₐ₁₅₀₂ | R_{y1}-12 | A-38 |
| Lₐ₁₅₀₃ | R_{y1}-12 | A-39 | Lₐ₁₅₀₄ | R_{y1}-12 | A-40 |
| Lₐ₁₅₀₅ | R_{y1}-12 | A-41 | Lₐ₁₅₀₆ | R_{y1}-12 | A-42 |
| Lₐ₁₅₀₇ | R_{y1}-12 | A-43 | Lₐ₁₅₀₈ | R_{y1}-12 | A-44 |
| Lₐ₁₅₀₉ | R_{y1}-12 | A-45 | Lₐ₁₅₁₀ | R_{y1}-12 | A-46 |
| Lₐ₁₅₁₁ | R_{y1}-12 | A-47 | Lₐ₁₅₁₂ | R_{y1}-12 | A-48 |
| Lₐ₁₅₁₃ | R_{y1}-12 | A-49 | Lₐ₁₅₁₄ | R_{y1}-12 | A-50 |
| Lₐ₁₅₁₅ | R_{y1}-12 | A-51 | Lₐ₁₅₁₆ | R_{y1}-12 | A-52 |
| Lₐ₁₅₁₇ | R_{y1}-12 | A-53 | Lₐ₁₅₁₈ | R_{y1}-12 | A-54 |
| Lₐ₁₅₁₉ | R_{y1}-12 | A-55 | Lₐ₁₅₂₀ | R_{y1}-12 | A-56 |
| Lₐ₁₅₂₁ | R_{y1}-12 | A-57 | Lₐ₁₅₂₂ | R_{y1}-12 | A-58 |
| Lₐ₁₅₂₃ | R_{y1}-12 | A-59 | Lₐ₁₅₂₄ | R_{y1}-12 | A-60 |
| Lₐ₁₅₂₅ | R_{y1}-12 | A-61 | Lₐ₁₅₂₆ | R_{y1}-12 | A-62 |
| Lₐ₁₅₂₇ | R_{y1}-12 | A-63 | Lₐ₁₅₂₈ | R_{y1}-12 | A-64 |
| Lₐ₁₅₂₉ | R_{y1}-12 | A-65 | Lₐ₁₅₃₀ | R_{y1}-12 | A-66 |
| Lₐ₁₅₃₁ | R_{y1}-12 | A-67 | Lₐ₁₅₃₂ | R_{y1}-12 | A-68 |
| Lₐ₁₅₃₃ | R_{y1}-12 | A-69 | Lₐ₁₅₃₄ | R_{y1}-12 | A-70 |
| Lₐ₁₅₃₅ | R_{y1}-12 | A-71 | Lₐ₁₅₃₆ | R_{y1}-12 | A-72 |
| Lₐ₁₅₃₇ | R_{y1}-12 | A-73 | Lₐ₁₅₃₈ | R_{y1}-12 | A-74 |
| Lₐ₁₅₃₉ | R_{y1}-12 | A-75 | Lₐ₁₅₄₀ | R_{y1}-12 | A-76 |
| Lₐ₁₅₄₁ | R_{y1}-12 | A-77 | Lₐ₁₅₄₂ | R_{y1}-12 | A-78 |
| Lₐ₁₅₄₃ | R_{y1}-12 | A-79 | Lₐ₁₅₄₄ | R_{y1}-12 | A-80 |
| Lₐ₁₅₄₅ | R_{y1}-12 | A-81 | Lₐ₁₅₄₆ | R_{y1}-12 | A-82 |
| Lₐ₁₅₄₇ | R_{y1}-12 | A-83 | Lₐ₁₅₄₈ | R_{y1}-12 | A-84 |
| Lₐ₁₅₄₉ | R_{y1}-12 | A-85 | Lₐ₁₅₅₀ | R_{y1}-12 | A-86 |
| Lₐ₁₅₅₁ | R_{y1}-12 | A-87 | Lₐ₁₅₅₂ | R_{y1}-12 | A-88 |
| Lₐ₁₅₅₃ | R_{y1}-12 | A-89 | Lₐ₁₅₅₄ | R_{y1}-12 | A-90 |
| Lₐ₁₅₅₅ | R_{y1}-15 | A-1 | Lₐ₁₅₅₆ | R_{y1}-15 | A-2 |
| Lₐ₁₅₅₇ | R_{y1}-15 | A-3 | Lₐ₁₅₅₈ | R_{y1}-15 | A-4 |
| Lₐ₁₅₅₉ | R_{y1}-15 | A-5 | Lₐ₁₅₆₀ | R_{y1}-15 | A-6 |
| Lₐ₁₅₆₁ | R_{y1}-15 | A-7 | Lₐ₁₅₆₂ | R_{y1}-15 | A-8 |
| Lₐ₁₅₆₃ | R_{y1}-15 | A-9 | Lₐ₁₅₆₄ | R_{y1}-15 | A-10 |
| Lₐ₁₅₆₅ | R_{y1}-15 | A-11 | Lₐ₁₅₆₆ | R_{y1}-15 | A-12 |
| Lₐ₁₅₆₇ | R_{y1}-15 | A-13 | Lₐ₁₅₆₈ | R_{y1}-15 | A-14 |
| Lₐ₁₅₆₉ | R_{y1}-15 | A-15 | Lₐ₁₅₇₀ | R_{y1}-15 | A-16 |
| Lₐ₁₅₇₁ | R_{y1}-15 | A-17 | Lₐ₁₅₇₂ | R_{y1}-15 | A-18 |
| Lₐ₁₅₇₃ | R_{y1}-15 | A-19 | Lₐ₁₅₇₄ | R_{y1}-15 | A-20 |
| Lₐ₁₅₇₅ | R_{y1}-15 | A-21 | Lₐ₁₅₇₆ | R_{y1}-15 | A-22 |
| Lₐ₁₅₇₇ | R_{y1}-15 | A-23 | Lₐ₁₅₇₈ | R_{y1}-15 | A-24 |
| Lₐ₁₅₇₉ | R_{y1}-15 | A-25 | Lₐ₁₅₈₀ | R_{y1}-15 | A-26 |
| Lₐ₁₅₈₁ | R_{y1}-15 | A-27 | Lₐ₁₅₈₂ | R_{y1}-15 | A-28 |
| Lₐ₁₅₈₃ | R_{y1}-15 | A-29 | Lₐ₁₅₈₄ | R_{y1}-15 | A-30 |
| Lₐ₁₅₈₅ | R_{y1}-15 | A-31 | Lₐ₁₅₈₆ | R_{y1}-15 | A-32 |
| Lₐ₁₅₈₇ | R_{y1}-15 | A-33 | Lₐ₁₅₈₈ | R_{y1}-15 | A-34 |
| Lₐ₁₅₈₉ | R_{y1}-15 | A-35 | Lₐ₁₅₉₀ | R_{y1}-15 | A-36 |
| Lₐ₁₅₉₁ | R_{y1}-15 | A-37 | Lₐ₁₅₉₂ | R_{y1}-15 | A-38 |
| Lₐ₁₅₉₃ | R_{y1}-15 | A-39 | Lₐ₁₅₉₄ | R_{y1}-15 | A-40 |
| Lₐ₁₅₉₅ | R_{y1}-15 | A-41 | Lₐ₁₅₉₆ | R_{y1}-15 | A-42 |
| Lₐ₁₅₉₇ | R_{y1}-15 | A-43 | Lₐ₁₅₉₈ | R_{y1}-15 | A-44 |
| Lₐ₁₅₉₉ | R_{y1}-15 | A-45 | Lₐ₁₆₀₀ | R_{y1}-15 | A-46 |
| Lₐ₁₆₀₁ | R_{y1}-15 | A-47 | Lₐ₁₆₀₂ | R_{y1}-15 | A-48 |
| Lₐ₁₆₀₃ | R_{y1}-15 | A-49 | Lₐ₁₆₀₄ | R_{y1}-15 | A-50 |
| Lₐ₁₆₀₅ | R_{y1}-15 | A-51 | Lₐ₁₆₀₆ | R_{y1}-15 | A-52 |
| Lₐ₁₆₀₇ | R_{y1}-15 | A-53 | Lₐ₁₆₀₈ | R_{y1}-15 | A-54 |
| Lₐ₁₆₀₉ | R_{y1}-15 | A-55 | Lₐ₁₆₁₀ | R_{y1}-15 | A-56 |
| Lₐ₁₆₁₁ | R_{y1}-15 | A-57 | Lₐ₁₆₁₂ | R_{y1}-15 | A-58 |
| Lₐ₁₆₁₃ | R_{y1}-15 | A-59 | Lₐ₁₆₁₄ | R_{y1}-15 | A-60 |
| Lₐ₁₆₁₅ | R_{y1}-15 | A-61 | Lₐ₁₆₁₆ | R_{y1}-15 | A-62 |
| Lₐ₁₆₁₇ | R_{y1}-15 | A-63 | Lₐ₁₆₁₈ | R_{y1}-15 | A-64 |
| Lₐ₁₆₁₉ | R_{y1}-15 | A-65 | Lₐ₁₆₂₀ | R_{y1}-15 | A-66 |
| Lₐ₁₆₂₁ | R_{y1}-15 | A-67 | Lₐ₁₆₂₂ | R_{y1}-15 | A-68 |
| Lₐ₁₆₂₃ | R_{y1}-15 | A-69 | Lₐ₁₆₂₄ | R_{y1}-15 | A-70 |
| Lₐ₁₆₂₅ | R_{y1}-15 | A-71 | Lₐ₁₆₂₆ | R_{y1}-15 | A-72 |
| Lₐ₁₆₂₇ | R_{y1}-15 | A-73 | Lₐ₁₆₂₈ | R_{y1}-15 | A-74 |
| Lₐ₁₆₂₉ | R_{y1}-15 | A-75 | Lₐ₁₆₃₀ | R_{y1}-15 | A-76 |
| Lₐ₁₆₃₁ | R_{y1}-15 | A-77 | Lₐ₁₆₃₂ | R_{y1}-15 | A-78 |
| Lₐ₁₆₃₃ | R_{y1}-15 | A-79 | Lₐ₁₆₃₄ | R_{y1}-15 | A-80 |
| Lₐ₁₆₃₅ | R_{y1}-15 | A-81 | Lₐ₁₆₃₆ | R_{y1}-15 | A-82 |
| Lₐ₁₆₃₇ | R_{y1}-15 | A-83 | Lₐ₁₆₃₈ | R_{y1}-15 | A-84 |
| Lₐ₁₆₃₉ | R_{y1}-15 | A-85 | Lₐ₁₆₄₀ | R_{y1}-15 | A-86 |
| Lₐ₁₆₄₁ | R_{y1}-15 | A-87 | Lₐ₁₆₄₂ | R_{y1}-15 | A-88 |
| Lₐ₁₆₄₃ | R_{y1}-15 | A-89 | Lₐ₁₆₄₄ | R_{y1}-15 | A-90 |
| Lₐ₁₆₄₅ | R_{y1}-16 | A-1 | Lₐ₁₆₄₆ | R_{y1}-16 | A-2 |
| Lₐ₁₆₄₇ | R_{y1}-16 | A-3 | Lₐ₁₆₄₈ | R_{y1}-16 | A-4 |
| Lₐ₁₆₄₉ | R_{y1}-16 | A-5 | Lₐ₁₆₅₀ | R_{y1}-16 | A-6 |
| Lₐ₁₆₅₁ | R_{y1}-16 | A-7 | Lₐ₁₆₅₂ | R_{y1}-16 | A-8 |
| Lₐ₁₆₅₃ | R_{y1}-16 | A-9 | Lₐ₁₆₅₄ | R_{y1}-16 | A-10 |
| Lₐ₁₆₅₅ | R_{y1}-16 | A-11 | Lₐ₁₆₅₆ | R_{y1}-16 | A-12 |
| Lₐ₁₆₅₇ | R_{y1}-16 | A-13 | Lₐ₁₆₅₈ | R_{y1}-16 | A-14 |
| Lₐ₁₆₅₉ | R_{y1}-16 | A-15 | Lₐ₁₆₆₀ | R_{y1}-16 | A-16 |
| Lₐ₁₆₆₁ | R_{y1}-16 | A-17 | Lₐ₁₆₆₂ | R_{y1}-16 | A-18 |
| Lₐ₁₆₆₃ | R_{y1}-16 | A-19 | Lₐ₁₆₆₄ | R_{y1}-16 | A-20 |
| Lₐ₁₆₆₅ | R_{y1}-16 | A-21 | Lₐ₁₆₆₆ | R_{y1}-16 | A-22 |
| Lₐ₁₆₆₇ | R_{y1}-16 | A-23 | Lₐ₁₆₆₈ | R_{y1}-16 | A-24 |
| Lₐ₁₆₆₉ | R_{y1}-16 | A-25 | Lₐ₁₆₇₀ | R_{y1}-16 | A-26 |
| Lₐ₁₆₇₁ | R_{y1}-16 | A-27 | Lₐ₁₆₇₂ | R_{y1}-16 | A-28 |
| Lₐ₁₆₇₃ | R_{y1}-16 | A-29 | Lₐ₁₆₇₄ | R_{y1}-16 | A-30 |
| Lₐ₁₆₇₅ | R_{y1}-16 | A-31 | Lₐ₁₆₇₆ | R_{y1}-16 | A-32 |
| Lₐ₁₆₇₇ | R_{y1}-16 | A-33 | Lₐ₁₆₇₈ | R_{y1}-16 | A-34 |
| Lₐ₁₆₇₉ | R_{y1}-16 | A-35 | Lₐ₁₆₈₀ | R_{y1}-16 | A-36 |
| Lₐ₁₆₈₁ | R_{y1}-16 | A-37 | Lₐ₁₆₈₂ | R_{y1}-16 | A-38 |
| Lₐ₁₆₈₃ | R_{y1}-16 | A-39 | Lₐ₁₆₈₄ | R_{y1}-16 | A-40 |
| Lₐ₁₆₈₅ | R_{y1}-16 | A-41 | Lₐ₁₆₈₆ | R_{y1}-16 | A-42 |
| Lₐ₁₆₈₇ | R_{y1}-16 | A-43 | Lₐ₁₆₈₈ | R_{y1}-16 | A-44 |
| Lₐ₁₆₈₉ | R_{y1}-16 | A-45 | Lₐ₁₆₉₀ | R_{y1}-16 | A-46 |
| Lₐ₁₆₉₁ | R_{y1}-16 | A-47 | Lₐ₁₆₉₂ | R_{y1}-16 | A-48 |
| Lₐ₁₆₉₃ | R_{y1}-16 | A-49 | Lₐ₁₆₉₄ | R_{y1}-16 | A-50 |
| Lₐ₁₆₉₅ | R_{y1}-16 | A-51 | Lₐ₁₆₉₆ | R_{y1}-16 | A-52 |
| Lₐ₁₆₉₇ | R_{y1}-16 | A-53 | Lₐ₁₆₉₈ | R_{y1}-16 | A-54 |
| Lₐ₁₆₉₉ | R_{y1}-16 | A-55 | Lₐ₁₇₀₀ | R_{y1}-16 | A-56 |
| Lₐ₁₇₀₁ | R_{y1}-16 | A-57 | Lₐ₁₇₀₂ | R_{y1}-16 | A-58 |
| Lₐ₁₇₀₃ | R_{y1}-16 | A-59 | Lₐ₁₇₀₄ | R_{y1}-16 | A-60 |
| Lₐ₁₇₀₅ | R_{y1}-16 | A-61 | Lₐ₁₇₀₆ | R_{y1}-16 | A-62 |
| Lₐ₁₇₀₇ | R_{y1}-16 | A-63 | Lₐ₁₇₀₈ | R_{y1}-16 | A-64 |
| Lₐ₁₇₀₉ | R_{y1}-16 | A-65 | Lₐ₁₇₁₀ | R_{y1}-16 | A-66 |
| Lₐ₁₇₁₁ | R_{y1}-16 | A-67 | Lₐ₁₇₁₂ | R_{y1}-16 | A-68 |
| Lₐ₁₇₁₃ | R_{y1}-16 | A-69 | Lₐ₁₇₁₄ | R_{y1}-16 | A-70 |
| Lₐ₁₇₁₅ | R_{y1}-16 | A-71 | Lₐ₁₇₁₆ | R_{y1}-16 | A-72 |
| Lₐ₁₇₁₇ | R_{y1}-16 | A-73 | Lₐ₁₇₁₈ | R_{y1}-16 | A-74 |
| Lₐ₁₇₁₉ | R_{y1}-16 | A-75 | Lₐ₁₇₂₀ | R_{y1}-16 | A-76 |
| Lₐ₁₇₂₁ | R_{y1}-16 | A-77 | Lₐ₁₇₂₂ | R_{y1}-16 | A-78 |
| Lₐ₁₇₂₃ | R_{y1}-16 | A-79 | Lₐ₁₇₂₄ | R_{y1}-16 | A-80 |
| Lₐ₁₇₂₅ | R_{y1}-16 | A-81 | Lₐ₁₇₂₆ | R_{y1}-16 | A-82 |
| Lₐ₁₇₂₇ | R_{y1}-16 | A-83 | Lₐ₁₇₂₈ | R_{y1}-16 | A-84 |
| Lₐ₁₇₂₉ | R_{y1}-16 | A-85 | Lₐ₁₇₃₀ | R_{y1}-16 | A-86 |
| Lₐ₁₇₃₁ | R_{y1}-16 | A-87 | Lₐ₁₇₃₂ | R_{y1}-16 | A-88 |
| Lₐ₁₇₃₃ | R_{y1}-16 | A-89 | Lₐ₁₇₃₄ | R_{y1}-16 | A-90 |
| Lₐ₁₇₃₅ | R_{y1}-20 | A-1 | Lₐ₁₇₃₆ | R_{y1}-20 | A-2 |
| Lₐ₁₇₃₇ | R_{y1}-20 | A-3 | Lₐ₁₇₃₈ | R_{y1}-20 | A-4 |
| Lₐ₁₇₃₉ | R_{y1}-20 | A-5 | Lₐ₁₇₄₀ | R_{y1}-20 | A-6 |
| Lₐ₁₇₄₁ | R_{y1}-20 | A-7 | Lₐ₁₇₄₂ | R_{y1}-20 | A-8 |
| Lₐ₁₇₄₃ | R_{y1}-20 | A-9 | Lₐ₁₇₄₄ | R_{y1}-20 | A-10 |
| Lₐ₁₇₄₅ | R_{y1}-20 | A-11 | Lₐ₁₇₄₆ | R_{y1}-20 | A-12 |
| Lₐ₁₇₄₇ | R_{y1}-20 | A-13 | Lₐ₁₇₄₈ | R_{y1}-20 | A-14 |
| Lₐ₁₇₄₉ | R_{y1}-20 | A-15 | Lₐ₁₇₅₀ | R_{y1}-20 | A-16 |
| Lₐ₁₇₅₁ | R_{y1}-20 | A-17 | Lₐ₁₇₅₂ | R_{y1}-20 | A-18 |
| Lₐ₁₇₅₃ | R_{y1}-20 | A-19 | Lₐ₁₇₅₄ | R_{y1}-20 | A-20 |
| Lₐ₁₇₅₅ | R_{y1}-20 | A-21 | Lₐ₁₇₅₆ | R_{y1}-20 | A-22 |
| Lₐ₁₇₅₇ | R_{y1}-20 | A-23 | Lₐ₁₇₅₈ | R_{y1}-20 | A-24 |
| Lₐ₁₇₅₉ | R_{y1}-20 | A-25 | Lₐ₁₇₆₀ | R_{y1}-20 | A-26 |
| Lₐ₁₇₆₁ | R_{y1}-20 | A-27 | Lₐ₁₇₆₂ | R_{y1}-20 | A-28 |
| Lₐ₁₇₆₃ | R_{y1}-20 | A-29 | Lₐ₁₇₆₄ | R_{y1}-20 | A-30 |
| Lₐ₁₇₆₅ | R_{y1}-20 | A-31 | Lₐ₁₇₆₆ | R_{y1}-20 | A-32 |
| Lₐ₁₇₆₇ | R_{y1}-20 | A-33 | Lₐ₁₇₆₈ | R_{y1}-20 | A-34 |
| Lₐ₁₇₆₉ | R_{y1}-20 | A-35 | Lₐ₁₇₇₀ | R_{y1}-20 | A-36 |
| Lₐ₁₇₇₁ | R_{y1}-20 | A-37 | Lₐ₁₇₇₂ | R_{y1}-20 | A-38 |
| Lₐ₁₇₇₃ | R_{y1}-20 | A-39 | Lₐ₁₇₇₄ | R_{y1}-20 | A-40 |
| Lₐ₁₇₇₅ | R_{y1}-20 | A-41 | Lₐ₁₇₇₆ | R_{y1}-20 | A-42 |
| Lₐ₁₇₇₇ | R_{y1}-20 | A-43 | Lₐ₁₇₇₈ | R_{y1}-20 | A-44 |
| Lₐ₁₇₇₉ | R_{y1}-20 | A-45 | Lₐ₁₇₈₀ | R_{y1}-20 | A-46 |
| Lₐ₁₇₈₁ | R_{y1}-20 | A-47 | Lₐ₁₇₈₂ | R_{y1}-20 | A-48 |
| Lₐ₁₇₈₃ | R_{y1}-20 | A-49 | Lₐ₁₇₈₄ | R_{y1}-20 | A-50 |
| Lₐ₁₇₈₅ | R_{y1}-20 | A-51 | Lₐ₁₇₈₆ | R_{y1}-20 | A-52 |
| Lₐ₁₇₈₇ | R_{y1}-20 | A-53 | Lₐ₁₇₈₈ | R_{y1}-20 | A-54 |
| Lₐ₁₇₈₉ | R_{y1}-20 | A-55 | Lₐ₁₇₉₀ | R_{y1}-20 | A-56 |
| Lₐ₁₇₉₁ | R_{y1}-20 | A-57 | Lₐ₁₇₉₂ | R_{y1}-20 | A-58 |
| Lₐ₁₇₉₃ | R_{y1}-20 | A-59 | Lₐ₁₇₉₄ | R_{y1}-20 | A-60 |
| Lₐ₁₇₉₅ | R_{y1}-20 | A-61 | Lₐ₁₇₉₆ | R_{y1}-20 | A-62 |
| Lₐ₁₇₉₇ | R_{y1}-20 | A-63 | Lₐ₁₇₉₈ | R_{y1}-20 | A-64 |
| Lₐ₁₇₉₉ | R_{y1}-20 | A-65 | Lₐ₁₈₀₀ | R_{y1}-20 | A-66 |
| Lₐ₁₈₀₁ | R_{y1}-20 | A-67 | Lₐ₁₈₀₂ | R_{y1}-20 | A-68 |
| Lₐ₁₈₀₃ | R_{y1}-20 | A-69 | Lₐ₁₈₀₄ | R_{y1}-20 | A-70 |
| Lₐ₁₈₀₅ | R_{y1}-20 | A-71 | Lₐ₁₈₀₆ | R_{y1}-20 | A-72 |
| Lₐ₁₈₀₇ | R_{y1}-20 | A-73 | Lₐ₁₈₀₈ | R_{y1}-20 | A-74 |
| Lₐ₁₈₀₉ | R_{y1}-20 | A-75 | Lₐ₁₈₁₀ | R_{y1}-20 | A-76 |
| Lₐ₁₈₁₁ | R_{y1}-20 | A-77 | Lₐ₁₈₁₂ | R_{y1}-20 | A-78 |
| Lₐ₁₈₁₃ | R_{y1}-20 | A-79 | Lₐ₁₈₁₄ | R_{y1}-20 | A-80 |
| Lₐ₁₈₁₅ | R_{y1}-20 | A-81 | Lₐ₁₈₁₆ | R_{y1}-20 | A-82 |
| Lₐ₁₈₁₇ | R_{y1}-20 | A-83 | Lₐ₁₈₁₈ | R_{y1}-20 | A-84 |
| Lₐ₁₈₁₉ | R_{y1}-20 | A-85 | Lₐ₁₈₂₀ | R_{y1}-20 | A-86 |
| Lₐ₁₈₂₁ | R_{y1}-20 | A-87 | Lₐ₁₈₂₂ | R_{y1}-20 | A-88 |
| Lₐ₁₈₂₃ | R_{y1}-20 | A-89 | Lₐ₁₈₂₄ | R_{y1}-20 | A-90 |
| Lₐ₁₈₂₅ | R_{y1}-21 | A-1 | Lₐ₁₈₂₆ | R_{y1}-21 | A-2 |
| Lₐ₁₈₂₇ | R_{y1}-21 | A-3 | Lₐ₁₈₂₈ | R_{y1}-21 | A-4 |
| Lₐ₁₈₂₉ | R_{y1}-21 | A-5 | Lₐ₁₈₃₀ | R_{y1}-21 | A-6 |
| Lₐ₁₈₃₁ | R_{y1}-21 | A-7 | Lₐ₁₈₃₂ | R_{y1}-21 | A-8 |
| Lₐ₁₈₃₃ | R_{y1}-21 | A-9 | Lₐ₁₈₃₄ | R_{y1}-21 | A-10 |
| Lₐ₁₈₃₅ | R_{y1}-21 | A-11 | Lₐ₁₈₃₆ | R_{y1}-21 | A-12 |
| Lₐ₁₈₃₇ | R_{y1}-21 | A-13 | Lₐ₁₈₃₈ | R_{y1}-21 | A-14 |
| Lₐ₁₈₃₉ | R_{y1}-21 | A-15 | Lₐ₁₈₄₀ | R_{y1}-21 | A-16 |
| Lₐ₁₈₄₁ | R_{y1}-21 | A-17 | Lₐ₁₈₄₂ | R_{y1}-21 | A-18 |
| Lₐ₁₈₄₃ | R_{y1}-21 | A-19 | Lₐ₁₈₄₄ | R_{y1}-21 | A-20 |
| Lₐ₁₈₄₅ | R_{y1}-21 | A-21 | Lₐ₁₈₄₆ | R_{y1}-21 | A-22 |
| Lₐ₁₈₄₇ | R_{y1}-21 | A-23 | Lₐ₁₈₄₈ | R_{y1}-21 | A-24 |
| Lₐ₁₈₄₉ | R_{y1}-21 | A-25 | Lₐ₁₈₅₀ | R_{y1}-21 | A-26 |
| Lₐ₁₈₅₁ | R_{y1}-21 | A-27 | Lₐ₁₈₅₂ | R_{y1}-21 | A-28 |
| Lₐ₁₈₅₃ | R_{y1}-21 | A-29 | Lₐ₁₈₅₄ | R_{y1}-21 | A-30 |
| Lₐ₁₈₅₅ | R_{y1}-21 | A-31 | Lₐ₁₈₅₆ | R_{y1}-21 | A-32 |
| Lₐ₁₈₅₇ | R_{y1}-21 | A-33 | Lₐ₁₈₅₈ | R_{y1}-21 | A-34 |
| Lₐ₁₈₅₉ | R_{y1}-21 | A-35 | Lₐ₁₈₆₀ | R_{y1}-21 | A-36 |
| Lₐ₁₈₆₁ | R_{y1}-21 | A-37 | Lₐ₁₈₆₂ | R_{y1}-21 | A-38 |
| Lₐ₁₈₆₃ | R_{y1}-21 | A-39 | Lₐ₁₈₆₄ | R_{y1}-21 | A-40 |
| Lₐ₁₈₆₅ | R_{y1}-21 | A-41 | Lₐ₁₈₆₆ | R_{y1}-21 | A-42 |
| Lₐ₁₈₆₇ | R_{y1}-21 | A-43 | Lₐ₁₈₆₈ | R_{y1}-21 | A-44 |
| Lₐ₁₈₆₉ | R_{y1}-21 | A-45 | Lₐ₁₈₇₀ | R_{y1}-21 | A-46 |
| Lₐ₁₈₇₁ | R_{y1}-21 | A-47 | Lₐ₁₈₇₂ | R_{y1}-21 | A-48 |
| Lₐ₁₈₇₃ | R_{y1}-21 | A-49 | Lₐ₁₈₇₄ | R_{y1}-21 | A-50 |
| Lₐ₁₈₇₅ | R_{y1}-21 | A-51 | Lₐ₁₈₇₆ | R_{y1}-21 | A-52 |
| Lₐ₁₈₇₇ | R_{y1}-21 | A-53 | Lₐ₁₈₇₈ | R_{y1}-21 | A-54 |
| Lₐ₁₈₇₉ | R_{y1}-21 | A-55 | Lₐ₁₈₈₀ | R_{y1}-21 | A-56 |
| Lₐ₁₈₈₁ | R_{y1}-21 | A-57 | Lₐ₁₈₈₂ | R_{y1}-21 | A-58 |
| Lₐ₁₈₈₃ | R_{y1}-21 | A-59 | Lₐ₁₈₈₄ | R_{y1}-21 | A-60 |
| Lₐ₁₈₈₅ | R_{y1}-21 | A-61 | Lₐ₁₈₈₆ | R_{y1}-21 | A-62 |
| Lₐ₁₈₈₇ | R_{y1}-21 | A-63 | Lₐ₁₈₈₈ | R_{y1}-21 | A-64 |
| Lₐ₁₈₈₉ | R_{y1}-21 | A-65 | Lₐ₁₈₉₀ | R_{y1}-21 | A-66 |
| Lₐ₁₈₉₁ | R_{y1}-21 | A-67 | Lₐ₁₈₉₂ | R_{y1}-21 | A-68 |
| Lₐ₁₈₉₃ | R_{y1}-21 | A-69 | Lₐ₁₈₉₄ | R_{y1}-21 | A-70 |
| Lₐ₁₈₉₅ | R_{y1}-21 | A-71 | Lₐ₁₈₉₆ | R_{y1}-21 | A-72 |
| Lₐ₁₈₉₇ | R_{y1}-21 | A-73 | Lₐ₁₈₉₈ | R_{y1}-21 | A-74 |
| Lₐ₁₈₉₉ | R_{y1}-21 | A-75 | Lₐ₁₉₀₀ | R_{y1}-21 | A-76 |
| Lₐ₁₉₀₁ | R_{y1}-21 | A-77 | Lₐ₁₉₀₂ | R_{y1}-21 | A-78 |
| Lₐ₁₉₀₃ | R_{y1}-21 | A-79 | Lₐ₁₉₀₄ | R_{y1}-21 | A-80 |
| Lₐ₁₉₀₅ | R_{y1}-21 | A-81 | Lₐ₁₉₀₆ | R_{y1}-21 | A-82 |
| Lₐ₁₉₀₇ | R_{y1}-21 | A-83 | Lₐ₁₉₀₈ | R_{y1}-21 | A-84 |
| Lₐ₁₉₀₉ | R_{y1}-21 | A-85 | Lₐ₁₉₁₀ | R_{y1}-21 | A-86 |
| Lₐ₁₉₁₁ | R_{y1}-21 | A-87 | Lₐ₁₉₁₂ | R_{y1}-21 | A-88 |
| Lₐ₁₉₁₃ | R_{y1}-21 | A-89 | Lₐ₁₉₁₄ | R_{y1}-21 | A-90 |
| Lₐ₁₉₁₅ | R_{y1}-25 | A-1 | Lₐ₁₉₁₆ | R_{y1}-25 | A-2 |
| Lₐ₁₉₁₇ | R_{y1}-25 | A-3 | Lₐ₁₉₁₈ | R_{y1}-25 | A-4 |
| Lₐ₁₉₁₉ | R_{y1}-25 | A-5 | Lₐ₁₉₂₀ | R_{y1}-25 | A-6 |
| Lₐ₁₉₂₁ | R_{y1}-25 | A-7 | Lₐ₁₉₂₂ | R_{y1}-25 | A-8 |
| Lₐ₁₉₂₃ | R_{y1}-25 | A-9 | Lₐ₁₉₂₄ | R_{y1}-25 | A-10 |
| Lₐ₁₉₂₅ | R_{y1}-25 | A-11 | Lₐ₁₉₂₆ | R_{y1}-25 | A-12 |
| Lₐ₁₉₂₇ | R_{y1}-25 | A-13 | Lₐ₁₉₂₈ | R_{y1}-25 | A-14 |
| Lₐ₁₉₂₉ | R_{y1}-25 | A-15 | Lₐ₁₉₃₀ | R_{y1}-25 | A-16 |
| Lₐ₁₉₃₁ | R_{y1}-25 | A-17 | Lₐ₁₉₃₂ | R_{y1}-25 | A-18 |
| Lₐ₁₉₃₃ | R_{y1}-25 | A-19 | Lₐ₁₉₃₄ | R_{y1}-25 | A-20 |
| Lₐ₁₉₃₅ | R_{y1}-25 | A-21 | Lₐ₁₉₃₆ | R_{y1}-25 | A-22 |
| Lₐ₁₉₃₇ | R_{y1}-25 | A-23 | Lₐ₁₉₃₈ | R_{y1}-25 | A-24 |
| Lₐ₁₉₃₉ | R_{y1}-25 | A-25 | Lₐ₁₉₄₀ | R_{y1}-25 | A-26 |
| Lₐ₁₉₄₁ | R_{y1}-25 | A-27 | Lₐ₁₉₄₂ | R_{y1}-25 | A-28 |
| Lₐ₁₉₄₃ | R_{y1}-25 | A-29 | Lₐ₁₉₄₄ | R_{y1}-25 | A-30 |
| Lₐ₁₉₄₅ | R_{y1}-25 | A-31 | Lₐ₁₉₄₆ | R_{y1}-25 | A-32 |
| Lₐ₁₉₄₇ | R_{y1}-25 | A-33 | Lₐ₁₉₄₈ | R_{y1}-25 | A-34 |
| Lₐ₁₉₄₉ | R_{y1}-25 | A-35 | Lₐ₁₉₅₀ | R_{y1}-25 | A-36 |
| Lₐ₁₉₅₁ | R_{y1}-25 | A-37 | Lₐ₁₉₅₂ | R_{y1}-25 | A-38 |
| Lₐ₁₉₅₃ | R_{y1}-25 | A-39 | Lₐ₁₉₅₄ | R_{y1}-25 | A-40 |
| Lₐ₁₉₅₅ | R_{y1}-25 | A-41 | Lₐ₁₉₅₆ | R_{y1}-25 | A-42 |
| Lₐ₁₉₅₇ | R_{y1}-25 | A-43 | Lₐ₁₉₅₈ | R_{y1}-25 | A-44 |
| Lₐ₁₉₅₉ | R_{y1}-25 | A-45 | Lₐ₁₉₆₀ | R_{y1}-25 | A-46 |
| Lₐ₁₉₆₁ | R_{y1}-25 | A-47 | Lₐ₁₉₆₂ | R_{y1}-25 | A-48 |
| Lₐ₁₉₆₃ | R_{y1}-25 | A-49 | Lₐ₁₉₆₄ | R_{y1}-25 | A-50 |
| Lₐ₁₉₆₅ | R_{y1}-25 | A-51 | Lₐ₁₉₆₆ | R_{y1}-25 | A-52 |
| Lₐ₁₉₆₇ | R_{y1}-25 | A-53 | Lₐ₁₉₆₈ | R_{y1}-25 | A-54 |
| Lₐ₁₉₆₉ | R_{y1}-25 | A-55 | Lₐ₁₉₇₀ | R_{y1}-25 | A-56 |
| Lₐ₁₉₇₁ | R_{y1}-25 | A-57 | Lₐ₁₉₇₂ | R_{y1}-25 | A-58 |
| Lₐ₁₉₇₃ | R_{y1}-25 | A-59 | Lₐ₁₉₇₄ | R_{y1}-25 | A-60 |
| Lₐ₁₉₇₅ | R_{y1}-25 | A-61 | Lₐ₁₉₇₆ | R_{y1}-25 | A-62 |
| Lₐ₁₉₇₇ | R_{y1}-25 | A-63 | Lₐ₁₉₇₈ | R_{y1}-25 | A-64 |
| Lₐ₁₉₇₉ | R_{y1}-25 | A-65 | Lₐ₁₉₈₀ | R_{y1}-25 | A-66 |
| Lₐ₁₉₈₁ | R_{y1}-25 | A-67 | Lₐ₁₉₈₂ | R_{y1}-25 | A-68 |
| Lₐ₁₉₈₃ | R_{y1}-25 | A-69 | Lₐ₁₉₈₄ | R_{y1}-25 | A-70 |
| Lₐ₁₉₈₅ | R_{y1}-25 | A-71 | Lₐ₁₉₈₆ | R_{y1}-25 | A-72 |
| Lₐ₁₉₈₇ | R_{y1}-25 | A-73 | Lₐ₁₉₈₈ | R_{y1}-25 | A-74 |
| Lₐ₁₉₈₉ | R_{y1}-25 | A-75 | Lₐ₁₉₉₀ | R_{y1}-25 | A-76 |
| Lₐ₁₉₉₁ | R_{y1}-25 | A-77 | Lₐ₁₉₉₂ | R_{y1}-25 | A-78 |
| Lₐ₁₉₉₃ | R_{y1}-25 | A-79 | Lₐ₁₉₉₄ | R_{y1}-25 | A-80 |
| Lₐ₁₉₉₅ | R_{y1}-25 | A-81 | Lₐ₁₉₉₆ | R_{y1}-25 | A-82 |
| Lₐ₁₉₉₇ | R_{y1}-25 | A-83 | Lₐ₁₉₉₈ | R_{y1}-25 | A-84 |
| Lₐ₁₉₉₉ | R_{y1}-25 | A-85 | Lₐ₂₀₀₀ | R_{y1}-25 | A-86 |
| Lₐ₂₀₀₁ | R_{y1}-25 | A-87 | Lₐ₂₀₀₂ | R_{y1}-25 | A-88 |
| Lₐ₂₀₀₃ | R_{y1}-25 | A-89 | Lₐ₂₀₀₄ | R_{y1}-25 | A-90 |
| Lₐ₂₀₀₅ | R_{y1}-26 | A-1 | Lₐ₂₀₀₆ | R_{y1}-26 | A-2 |
| Lₐ₂₀₀₇ | R_{y1}-26 | A-3 | Lₐ₂₀₀₈ | R_{y1}-26 | A-4 |
| Lₐ₂₀₀₉ | R_{y1}-26 | A-5 | Lₐ₂₀₁₀ | R_{y1}-26 | A-6 |
| Lₐ₂₀₁₁ | R_{y1}-26 | A-7 | Lₐ₂₀₁₂ | R_{y1}-26 | A-8 |
| Lₐ₂₀₁₃ | R_{y1}-26 | A-9 | Lₐ₂₀₁₄ | R_{y1}-26 | A-10 |
| Lₐ₂₀₁₅ | R_{y1}-26 | A-11 | Lₐ₂₀₁₆ | R_{y1}-26 | A-12 |
| Lₐ₂₀₁₇ | R_{y1}-26 | A-13 | Lₐ₂₀₁₈ | R_{y1}-26 | A-14 |
| Lₐ₂₀₁₉ | R_{y1}-26 | A-15 | Lₐ₂₀₂₀ | R_{y1}-26 | A-16 |
| Lₐ₂₀₂₁ | R_{y1}-26 | A-17 | Lₐ₂₀₂₂ | R_{y1}-26 | A-18 |
| Lₐ₂₀₂₃ | R_{y1}-26 | A-19 | Lₐ₂₀₂₄ | R_{y1}-26 | A-20 |
| Lₐ₂₀₂₅ | R_{y1}-26 | A-21 | Lₐ₂₀₂₆ | R_{y1}-26 | A-22 |
| Lₐ₂₀₂₇ | R_{y1}-26 | A-23 | Lₐ₂₀₂₈ | R_{y1}-26 | A-24 |
| Lₐ₂₀₂₉ | R_{y1}-26 | A-25 | Lₐ₂₀₃₀ | R_{y1}-26 | A-26 |
| Lₐ₂₀₃₁ | R_{y1}-26 | A-27 | Lₐ₂₀₃₂ | R_{y1}-26 | A-28 |
| Lₐ₂₀₃₃ | R_{y1}-26 | A-29 | Lₐ₂₀₃₄ | R_{y1}-26 | A-30 |
| Lₐ₂₀₃₅ | R_{y1}-26 | A-31 | Lₐ₂₀₃₆ | R_{y1}-26 | A-32 |
| Lₐ₂₀₃₇ | R_{y1}-26 | A-33 | Lₐ₂₀₃₈ | R_{y1}-26 | A-34 |
| Lₐ₂₀₃₉ | R_{y1}-26 | A-35 | Lₐ₂₀₄₀ | R_{y1}-26 | A-36 |
| Lₐ₂₀₄₁ | R_{y1}-26 | A-37 | Lₐ₂₀₄₂ | R_{y1}-26 | A-38 |
| Lₐ₂₀₄₃ | R_{y1}-26 | A-39 | Lₐ₂₀₄₄ | R_{y1}-26 | A-40 |
| Lₐ₂₀₄₅ | R_{y1}-26 | A-41 | Lₐ₂₀₄₆ | R_{y1}-26 | A-42 |
| Lₐ₂₀₄₇ | R_{y1}-26 | A-43 | Lₐ₂₀₄₈ | R_{y1}-26 | A-44 |
| Lₐ₂₀₄₉ | R_{y1}-26 | A-45 | Lₐ₂₀₅₀ | R_{y1}-26 | A-46 |
| Lₐ₂₀₅₁ | R_{y1}-26 | A-47 | Lₐ₂₀₅₂ | R_{y1}-26 | A-48 |
| Lₐ₂₀₅₃ | R_{y1}-26 | A-49 | Lₐ₂₀₅₄ | R_{y1}-26 | A-50 |
| Lₐ₂₀₅₅ | R_{y1}-26 | A-51 | Lₐ₂₀₅₆ | R_{y1}-26 | A-52 |
| Lₐ₂₀₅₇ | R_{y1}-26 | A-53 | Lₐ₂₀₅₈ | R_{y1}-26 | A-54 |
| Lₐ₂₀₅₉ | R_{y1}-26 | A-55 | Lₐ₂₀₆₀ | R_{y1}-26 | A-56 |
| Lₐ₂₀₆₁ | R_{y1}-26 | A-57 | Lₐ₂₀₆₂ | R_{y1}-26 | A-58 |
| Lₐ₂₀₆₃ | R_{y1}-26 | A-59 | Lₐ₂₀₆₄ | R_{y1}-26 | A-60 |
| Lₐ₂₀₆₅ | R_{y1}-26 | A-61 | Lₐ₂₀₆₆ | R_{y1}-26 | A-62 |
| Lₐ₂₀₆₇ | R_{y1}-26 | A-63 | Lₐ₂₀₆₈ | R_{y1}-26 | A-64 |
| Lₐ₂₀₆₉ | R_{y1}-26 | A-65 | Lₐ₂₀₇₀ | R_{y1}-26 | A-66 |
| Lₐ₂₀₇₁ | R_{y1}-26 | A-67 | Lₐ₂₀₇₂ | R_{y1}-26 | A-68 |
| Lₐ₂₀₇₃ | R_{y1}-26 | A-69 | Lₐ₂₀₇₄ | R_{y1}-26 | A-70 |
| Lₐ₂₀₇₅ | R_{y1}-26 | A-71 | Lₐ₂₀₇₆ | R_{y1}-26 | A-72 |
| Lₐ₂₀₇₇ | R_{y1}-26 | A-73 | Lₐ₂₀₇₈ | R_{y1}-26 | A-74 |
| Lₐ₂₀₇₉ | R_{y1}-26 | A-75 | Lₐ₂₀₈₀ | R_{y1}-26 | A-76 |
| Lₐ₂₀₈₁ | R_{y1}-26 | A-77 | Lₐ₂₀₈₂ | R_{y1}-26 | A-78 |
| Lₐ₂₀₈₃ | R_{y1}-26 | A-79 | Lₐ₂₀₈₄ | R_{y1}-26 | A-80 |
| Lₐ₂₀₈₅ | R_{y1}-26 | A-81 | Lₐ₂₀₈₆ | R_{y1}-26 | A-82 |
| Lₐ₂₀₈₇ | R_{y1}-26 | A-83 | Lₐ₂₀₈₈ | R_{y1}-26 | A-84 |
| Lₐ₂₀₈₉ | R_{y1}-26 | A-85 | Lₐ₂₀₉₀ | R_{y1}-26 | A-86 |
| Lₐ₂₀₉₁ | R_{y1}-26 | A-87 | Lₐ₂₀₉₂ | R_{y1}-26 | A-88 |
| Lₐ₂₀₉₃ | R_{y1}-26 | A-89 | Lₐ₂₀₉₄ | R_{y1}-26 | A-90 |
| Lₐ₂₀₉₅ | R_{y1}-33 | A-1 | Lₐ₂₀₉₆ | R_{y1}-33 | A-2 |
| Lₐ₂₀₉₇ | R_{y1}-33 | A-3 | Lₐ₂₀₉₈ | R_{y1}-33 | A-4 |
| Lₐ₂₀₉₉ | R_{y1}-33 | A-5 | Lₐ₂₁₀₀ | R_{y1}-33 | A-6 |
| Lₐ₂₁₀₁ | R_{y1}-33 | A-7 | Lₐ₂₁₀₂ | R_{y1}-33 | A-8 |
| Lₐ₂₁₀₃ | R_{y1}-33 | A-9 | Lₐ₂₁₀₄ | R_{y1}-33 | A-10 |
| Lₐ₂₁₀₅ | R_{y1}-33 | A-11 | Lₐ₂₁₀₆ | R_{y1}-33 | A-12 |
| Lₐ₂₁₀₇ | R_{y1}-33 | A-13 | Lₐ₂₁₀₈ | R_{y1}-33 | A-14 |
| Lₐ₂₁₀₉ | R_{y1}-33 | A-15 | Lₐ₂₁₁₀ | R_{y1}-33 | A-16 |
| Lₐ₂₁₁₁ | R_{y1}-33 | A-17 | Lₐ₂₁₁₂ | R_{y1}-33 | A-18 |
| Lₐ₂₁₁₃ | R_{y1}-33 | A-19 | Lₐ₂₁₁₄ | R_{y1}-33 | A-20 |
| Lₐ₂₁₁₅ | R_{y1}-33 | A-21 | Lₐ₂₁₁₆ | R_{y1}-33 | A-22 |
| Lₐ₂₁₁₇ | R_{y1}-33 | A-23 | Lₐ₂₁₁₈ | R_{y1}-33 | A-24 |
| Lₐ₂₁₁₉ | R_{y1}-33 | A-25 | Lₐ₂₁₂₀ | R_{y1}-33 | A-26 |
| Lₐ₂₁₂₁ | R_{y1}-33 | A-27 | Lₐ₂₁₂₂ | R_{y1}-33 | A-28 |
| Lₐ₂₁₂₃ | R_{y1}-33 | A-29 | Lₐ₂₁₂₄ | R_{y1}-33 | A-30 |
| Lₐ₂₁₂₅ | R_{y1}-33 | A-31 | Lₐ₂₁₂₆ | R_{y1}-33 | A-32 |
| Lₐ₂₁₂₇ | R_{y1}-33 | A-33 | Lₐ₂₁₂₈ | R_{y1}-33 | A-34 |
| Lₐ₂₁₂₉ | R_{y1}-33 | A-35 | Lₐ₂₁₃₀ | R_{y1}-33 | A-36 |
| Lₐ₂₁₃₁ | R_{y1}-33 | A-37 | Lₐ₂₁₃₂ | R_{y1}-33 | A-38 |
| Lₐ₂₁₃₃ | R_{y1}-33 | A-39 | Lₐ₂₁₃₄ | R_{y1}-33 | A-40 |
| Lₐ₂₁₃₅ | R_{y1}-33 | A-41 | Lₐ₂₁₃₆ | R_{y1}-33 | A-42 |
| Lₐ₂₁₃₇ | R_{y1}-33 | A-43 | Lₐ₂₁₃₈ | R_{y1}-33 | A-44 |
| Lₐ₂₁₃₉ | R_{y1}-33 | A-45 | Lₐ₂₁₄₀ | R_{y1}-33 | A-46 |
| Lₐ₂₁₄₁ | R_{y1}-33 | A-47 | Lₐ₂₁₄₂ | R_{y1}-33 | A-48 |
| Lₐ₂₁₄₃ | R_{y1}-33 | A-49 | Lₐ₂₁₄₄ | R_{y1}-33 | A-50 |
| Lₐ₂₁₄₅ | R_{y1}-33 | A-51 | Lₐ₂₁₄₆ | R_{y1}-33 | A-52 |
| Lₐ₂₁₄₇ | R_{y1}-33 | A-53 | Lₐ₂₁₄₈ | R_{y1}-33 | A-54 |
| Lₐ₂₁₄₉ | R_{y1}-33 | A-55 | Lₐ₂₁₅₀ | R_{y1}-33 | A-56 |
| Lₐ₂₁₅₁ | R_{y1}-33 | A-57 | Lₐ₂₁₅₂ | R_{y1}-33 | A-58 |
| Lₐ₂₁₅₃ | R_{y1}-33 | A-59 | Lₐ₂₁₅₄ | R_{y1}-33 | A-60 |
| Lₐ₂₁₅₅ | R_{y1}-33 | A-61 | Lₐ₂₁₅₆ | R_{y1}-33 | A-62 |
| Lₐ₂₁₅₇ | R_{y1}-33 | A-63 | Lₐ₂₁₅₈ | R_{y1}-33 | A-64 |
| Lₐ₂₁₅₉ | R_{y1}-33 | A-65 | Lₐ₂₁₆₀ | R_{y1}-33 | A-66 |
| Lₐ₂₁₆₁ | R_{y1}-33 | A-67 | Lₐ₂₁₆₂ | R_{y1}-33 | A-68 |
| Lₐ₂₁₆₃ | R_{y1}-33 | A-69 | Lₐ₂₁₆₄ | R_{y1}-33 | A-70 |
| Lₐ₂₁₆₅ | R_{y1}-33 | A-71 | Lₐ₂₁₆₆ | R_{y1}-33 | A-72 |
| Lₐ₂₁₆₇ | R_{y1}-33 | A-73 | Lₐ₂₁₆₈ | R_{y1}-33 | A-74 |
| Lₐ₂₁₆₉ | R_{y1}-33 | A-75 | Lₐ₂₁₇₀ | R_{y1}-33 | A-76 |
| Lₐ₂₁₇₁ | R_{y1}-33 | A-77 | Lₐ₂₁₇₂ | R_{y1}-33 | A-78 |
| Lₐ₂₁₇₃ | R_{y1}-33 | A-79 | Lₐ₂₁₇₄ | R_{y1}-33 | A-80 |
| Lₐ₂₁₇₅ | R_{y1}-33 | A-81 | Lₐ₂₁₇₆ | R_{y1}-33 | A-82 |
| Lₐ₂₁₇₇ | R_{y1}-33 | A-83 | Lₐ₂₁₇₈ | R_{y1}-33 | A-84 |
| Lₐ₂₁₇₉ | R_{y1}-33 | A-85 | Lₐ₂₁₈₀ | R_{y1}-33 | A-86 |
| Lₐ₂₁₈₁ | R_{y1}-33 | A-87 | Lₐ₂₁₈₂ | R_{y1}-33 | A-88 |
| Lₐ₂₁₈₃ | R_{y1}-33 | A-89 | Lₐ₂₁₈₄ | R_{y1}-33 | A-90 |
| Lₐ₂₁₈₅ | R_{y1}-40 | A-1 | Lₐ₂₁₈₆ | R_{y1}-40 | A-2 |
| Lₐ₂₁₈₇ | R_{y1}-40 | A-3 | Lₐ₂₁₈₈ | R_{y1}-40 | A-4 |
| Lₐ₂₁₈₉ | R_{y1}-40 | A-5 | Lₐ₂₁₉₀ | R_{y1}-40 | A-6 |
| Lₐ₂₁₉₁ | R_{y1}-40 | A-7 | Lₐ₂₁₉₂ | R_{y1}-40 | A-8 |
| Lₐ₂₁₉₃ | R_{y1}-40 | A-9 | Lₐ₂₁₉₄ | R_{y1}-40 | A-10 |
| Lₐ₂₁₉₅ | R_{y1}-40 | A-11 | Lₐ₂₁₉₆ | R_{y1}-40 | A-12 |
| Lₐ₂₁₉₇ | R_{y1}-40 | A-13 | Lₐ₂₁₉₈ | R_{y1}-40 | A-14 |
| Lₐ₂₁₉₉ | R_{y1}-40 | A-15 | Lₐ₂₂₀₀ | R_{y1}-40 | A-16 |
| Lₐ₂₂₀₁ | R_{y1}-40 | A-17 | Lₐ₂₂₀₂ | R_{y1}-40 | A-18 |
| Lₐ₂₂₀₃ | R_{y1}-40 | A-19 | Lₐ₂₂₀₄ | R_{y1}-40 | A-20 |
| Lₐ₂₂₀₅ | R_{y1}-40 | A-21 | Lₐ₂₂₀₆ | R_{y1}-40 | A-22 |
| Lₐ₂₂₀₇ | R_{y1}-40 | A-23 | Lₐ₂₂₀₈ | R_{y1}-40 | A-24 |
| Lₐ₂₂₀₉ | R_{y1}-40 | A-25 | Lₐ₂₂₁₀ | R_{y1}-40 | A-26 |
| Lₐ₂₂₁₁ | R_{y1}-40 | A-27 | Lₐ₂₂₁₂ | R_{y1}-40 | A-28 |
| Lₐ₂₂₁₃ | R_{y1}-40 | A-29 | Lₐ₂₂₁₄ | R_{y1}-40 | A-30 |
| Lₐ₂₂₁₅ | R_{y1}-40 | A-31 | Lₐ₂₂₁₆ | R_{y1}-40 | A-32 |
| Lₐ₂₂₁₇ | R_{y1}-40 | A-33 | Lₐ₂₂₁₈ | R_{y1}-40 | A-34 |
| Lₐ₂₂₁₉ | R_{y1}-40 | A-35 | Lₐ₂₂₂₀ | R_{y1}-40 | A-36 |
| Lₐ₂₂₂₁ | R_{y1}-40 | A-37 | Lₐ₂₂₂₂ | R_{y1}-40 | A-38 |
| Lₐ₂₂₂₃ | R_{y1}-40 | A-39 | Lₐ₂₂₂₄ | R_{y1}-40 | A-40 |
| Lₐ₂₂₂₅ | R_{y1}-40 | A-41 | Lₐ₂₂₂₆ | R_{y1}-40 | A-42 |
| Lₐ₂₂₂₇ | R_{y1}-40 | A-43 | Lₐ₂₂₂₈ | R_{y1}-40 | A-44 |
| Lₐ₂₂₂₉ | R_{y1}-40 | A-45 | Lₐ₂₂₃₀ | R_{y1}-40 | A-46 |
| Lₐ₂₂₃₁ | R_{y1}-40 | A-47 | Lₐ₂₂₃₂ | R_{y1}-40 | A-48 |
| Lₐ₂₂₃₃ | R_{y1}-40 | A-49 | Lₐ₂₂₃₄ | R_{y1}-40 | A-50 |
| Lₐ₂₂₃₅ | R_{y1}-40 | A-51 | Lₐ₂₂₃₆ | R_{y1}-40 | A-52 |
| Lₐ₂₂₃₇ | R_{y1}-40 | A-53 | Lₐ₂₂₃₈ | R_{y1}-40 | A-54 |
| Lₐ₂₂₃₉ | R_{y1}-40 | A-55 | Lₐ₂₂₄₀ | R_{y1}-40 | A-56 |
| Lₐ₂₂₄₁ | R_{y1}-40 | A-57 | Lₐ₂₂₄₂ | R_{y1}-40 | A-58 |
| Lₐ₂₂₄₃ | R_{y1}-40 | A-59 | Lₐ₂₂₄₄ | R_{y1}-40 | A-60 |
| Lₐ₂₂₄₅ | R_{y1}-40 | A-61 | Lₐ₂₂₄₆ | R_{y1}-40 | A-62 |
| Lₐ₂₂₄₇ | R_{y1}-40 | A-63 | Lₐ₂₂₄₈ | R_{y1}-40 | A-64 |
| Lₐ₂₂₄₉ | R_{y1}-40 | A-65 | Lₐ₂₂₅₀ | R_{y1}-40 | A-66 |
| Lₐ₂₂₅₁ | R_{y1}-40 | A-67 | Lₐ₂₂₅₂ | R_{y1}-40 | A-68 |
| Lₐ₂₂₅₃ | R_{y1}-40 | A-69 | Lₐ₂₂₅₄ | R_{y1}-40 | A-70 |
| Lₐ₂₂₅₅ | R_{y1}-40 | A-71 | Lₐ₂₂₅₆ | R_{y1}-40 | A-72 |
| Lₐ₂₂₅₇ | R_{y1}-40 | A-73 | Lₐ₂₂₅₈ | R_{y1}-40 | A-74 |
| Lₐ₂₂₅₉ | R_{y1}-40 | A-75 | Lₐ₂₂₆₀ | R_{y1}-40 | A-76 |
| Lₐ₂₂₆₁ | R_{y1}-40 | A-77 | Lₐ₂₂₆₂ | R_{y1}-40 | A-78 |
| Lₐ₂₂₆₃ | R_{y1}-40 | A-79 | Lₐ₂₂₆₄ | R_{y1}-40 | A-80 |
| Lₐ₂₂₆₅ | R_{y1}-40 | A-81 | Lₐ₂₂₆₆ | R_{y1}-40 | A-82 |
| Lₐ₂₂₆₇ | R_{y1}-40 | A-83 | Lₐ₂₂₆₈ | R_{y1}-40 | A-84 |
| Lₐ₂₂₆₉ | R_{y1}-40 | A-85 | Lₐ₂₂₇₀ | R_{y1}-40 | A-86 |
| Lₐ₂₂₇₁ | R_{y1}-40 | A-87 | Lₐ₂₂₇₂ | R_{y1}-40 | A-88 |
| Lₐ₂₂₇₃ | R_{y1}-40 | A-89 | Lₐ₂₂₇₄ | R_{y1}-40 | A-90 |
| Lₐ₂₂₇₅ | R_{y1}-41 | A-1 | Lₐ₂₂₇₆ | R_{y1}-41 | A-2 |
| Lₐ₂₂₇₇ | R_{y1}-41 | A-3 | Lₐ₂₂₇₈ | R_{y1}-41 | A-4 |
| Lₐ₂₂₇₉ | R_{y1}-41 | A-5 | Lₐ₂₂₈₀ | R_{y1}-41 | A-6 |
| Lₐ₂₂₈₁ | R_{y1}-41 | A-7 | Lₐ₂₂₈₂ | R_{y1}-41 | A-8 |
| Lₐ₂₂₈₃ | R_{y1}-41 | A-9 | Lₐ₂₂₈₄ | R_{y1}-41 | A-10 |
| Lₐ₂₂₈₅ | R_{y1}-41 | A-11 | Lₐ₂₂₈₆ | R_{y1}-41 | A-12 |
| Lₐ₂₂₈₇ | R_{y1}-41 | A-13 | Lₐ₂₂₈₈ | R_{y1}-41 | A-14 |
| Lₐ₂₂₈₉ | R_{y1}-41 | A-15 | Lₐ₂₂₉₀ | R_{y1}-41 | A-16 |
| Lₐ₂₂₉₁ | R_{y1}-41 | A-17 | Lₐ₂₂₉₂ | R_{y1}-41 | A-18 |
| Lₐ₂₂₉₃ | R_{y1}-41 | A-19 | Lₐ₂₂₉₄ | R_{y1}-41 | A-20 |
| Lₐ₂₂₉₅ | R_{y1}-41 | A-21 | Lₐ₂₂₉₆ | R_{y1}-41 | A-22 |
| Lₐ₂₂₉₇ | R_{y1}-41 | A-23 | Lₐ₂₂₉₈ | R_{y1}-41 | A-24 |
| Lₐ₂₂₉₉ | R_{y1}-41 | A-25 | Lₐ₂₃₀₀ | R_{y1}-41 | A-26 |
| Lₐ₂₃₀₁ | R_{y1}-41 | A-27 | Lₐ₂₃₀₂ | R_{y1}-41 | A-28 |
| Lₐ₂₃₀₃ | R_{y1}-41 | A-29 | Lₐ₂₃₀₄ | R_{y1}-41 | A-30 |
| Lₐ₂₃₀₅ | R_{y1}-41 | A-31 | Lₐ₂₃₀₆ | R_{y1}-41 | A-32 |
| Lₐ₂₃₀₇ | R_{y1}-41 | A-33 | Lₐ₂₃₀₈ | R_{y1}-41 | A-34 |
| Lₐ₂₃₀₉ | R_{y1}-41 | A-35 | Lₐ₂₃₁₀ | R_{y1}-41 | A-36 |
| Lₐ₂₃₁₁ | R_{y1}-41 | A-37 | Lₐ₂₃₁₂ | R_{y1}-41 | A-38 |
| Lₐ₂₃₁₃ | R_{y1}-41 | A-39 | Lₐ₂₃₁₄ | R_{y1}-41 | A-40 |
| Lₐ₂₃₁₅ | R_{y1}-41 | A-41 | Lₐ₂₃₁₆ | R_{y1}-41 | A-42 |
| Lₐ₂₃₁₇ | R_{y1}-41 | A-43 | Lₐ₂₃₁₈ | R_{y1}-41 | A-44 |
| Lₐ₂₃₁₉ | R_{y1}-41 | A-45 | Lₐ₂₃₂₀ | R_{y1}-41 | A-46 |
| Lₐ₂₃₂₁ | R_{y1}-41 | A-47 | Lₐ₂₃₂₂ | R_{y1}-41 | A-48 |
| Lₐ₂₃₂₃ | R_{y1}-41 | A-49 | Lₐ₂₃₂₄ | R_{y1}-41 | A-50 |
| Lₐ₂₃₂₅ | R_{y1}-41 | A-51 | Lₐ₂₃₂₆ | R_{y1}-41 | A-52 |
| Lₐ₂₃₂₇ | R_{y1}-41 | A-53 | Lₐ₂₃₂₈ | R_{y1}-41 | A-54 |
| Lₐ₂₃₂₉ | R_{y1}-41 | A-55 | Lₐ₂₃₃₀ | R_{y1}-41 | A-56 |
| Lₐ₂₃₃₁ | R_{y1}-41 | A-57 | Lₐ₂₃₃₂ | R_{y1}-41 | A-58 |
| Lₐ₂₃₃₃ | R_{y1}-41 | A-59 | Lₐ₂₃₃₄ | R_{y1}-41 | A-60 |
| Lₐ₂₃₃₅ | R_{y1}-41 | A-61 | Lₐ₂₃₃₆ | R_{y1}-41 | A-62 |
| Lₐ₂₃₃₇ | R_{y1}-41 | A-63 | Lₐ₂₃₃₈ | R_{y1}-41 | A-64 |
| Lₐ₂₃₃₉ | R_{y1}-41 | A-65 | Lₐ₂₃₄₀ | R_{y1}-41 | A-66 |
| Lₐ₂₃₄₁ | R_{y1}-41 | A-67 | Lₐ₂₃₄₂ | R_{y1}-41 | A-68 |
| Lₐ₂₃₄₃ | R_{y1}-41 | A-69 | Lₐ₂₃₄₄ | R_{y1}-41 | A-70 |
| Lₐ₂₃₄₅ | R_{y1}-41 | A-71 | Lₐ₂₃₄₆ | R_{y1}-41 | A-72 |
| Lₐ₂₃₄₇ | R_{y1}-41 | A-73 | Lₐ₂₃₄₈ | R_{y1}-41 | A-74 |
| Lₐ₂₃₄₉ | R_{y1}-41 | A-75 | Lₐ₂₃₅₀ | R_{y1}-41 | A-76 |
| Lₐ₂₃₅₁ | R_{y1}-41 | A-77 | Lₐ₂₃₅₂ | R_{y1}-41 | A-78 |
| Lₐ₂₃₅₃ | R_{y1}-41 | A-79 | Lₐ₂₃₅₄ | R_{y1}-41 | A-80 |
| Lₐ₂₃₅₅ | R_{y1}-41 | A-81 | Lₐ₂₃₅₆ | R_{y1}-41 | A-82 |
| Lₐ₂₃₅₇ | R_{y1}-41 | A-83 | Lₐ₂₃₅₈ | R_{y1}-41 | A-84 |
| Lₐ₂₃₅₉ | R_{y1}-41 | A-85 | Lₐ₂₃₆₀ | R_{y1}-41 | A-86 |
| Lₐ₂₃₆₁ | R_{y1}-41 | A-87 | Lₐ₂₃₆₂ | R_{y1}-41 | A-88 |
| Lₐ₂₃₆₃ | R_{y1}-41 | A-89 | Lₐ₂₃₆₄ | R_{y1}-41 | A-90 |
| Lₐ₂₃₆₅ | R_{y1}-1 | A-12 | Lₐ₂₃₆₆ | R_{y1}-2 | A-12 |
| Lₐ₂₃₆₇ | R_{y1}-4 | A-12 | Lₐ₂₃₆₈ | R_{y1}-6 | A-12 |
| Lₐ₂₃₆₉ | R_{y1}-7 | A-12 | Lₐ₂₃₇₀ | R_{y1}-8 | A-12 |
| Lₐ₂₃₇₁ | R_{y1}-9 | A-12 | Lₐ₂₃₇₂ | R_{y1}-10 | A-12 |
| Lₐ₂₃₇₃ | R_{y1}-11 | A-12 | Lₐ₂₃₇₄ | R_{y1}-13 | A-12 |
| Lₐ₂₃₇₅ | R_{y1}-14 | A-12 | Lₐ₂₃₇₆ | R_{y1}-17 | A-12 |
| Lₐ₂₃₇₇ | R_{y1}-18 | A-12 | Lₐ₂₃₇₈ | R_{y1}-19 | A-12 |
| Lₐ₂₃₇₉ | R_{y1}-22 | A-12 | Lₐ₂₃₈₀ | R_{y1}-23 | A-12 |
| Lₐ₂₃₈₁ | R_{y1}-24 | A-12 | Lₐ₂₃₈₂ | R_{y1}-27 | A-12 |
| Lₐ₂₃₈₃ | R_{y1}-29 | A-12 | Lₐ₂₃₈₄ | R_{y1}-30 | A-12 |
| Lₐ₂₃₈₅ | R_{y1}-31 | A-12 | Lₐ₂₃₈₆ | R_{y1}-32 | A-12 |
| Lₐ₂₃₈₇ | R_{y1}-33 | A-12 | Lₐ₂₃₈₈ | R_{y1}-34 | A-12 |
| Lₐ₂₃₈₉ | R_{y1}-35 | A-12 | Lₐ₂₃₉₀ | R_{y1}-36 | A-12 |
| Lₐ₂₃₉₁ | R_{y1}-37 | A-12 | Lₐ₂₃₉₂ | R_{y1}-38 | A-12 |
| Lₐ₂₃₉₃ | R_{y1}-39 | A-12 | Lₐ₂₃₉₄ | R_{y1}-42 | A-12 |
| Lₐ₂₃₉₅ | R_{y1}-43 | A-12 | Lₐ₂₃₉₆ | R_{y1}-44 | A-12 |
| Lₐ₂₃₉₇ | R_{y1}-45 | A-12 | Lₐ₂₃₉₈ | R_{y1}-46 | A-12 |
| Lₐ₂₃₉₉ | R_{y1}-1 | A-13 | Lₐ₂₄₀₀ | R_{y1}-2 | A-13 |
| Lₐ₂₄₀₁ | R_{y1}-4 | A-13 | Lₐ₂₄₀₂ | R_{y1}-6 | A-13 |
| Lₐ₂₄₀₃ | R_{y1}-7 | A-13 | Lₐ₂₄₀₄ | R_{y1}-8 | A-13 |
| Lₐ₂₄₀₅ | R_{y1}-9 | A-13 | Lₐ₂₄₀₆ | R_{y1}-10 | A-13 |
| Lₐ₂₄₀₇ | R_{y1}-11 | A-13 | Lₐ₂₄₀₈ | R_{y1}-13 | A-13 |
| Lₐ₂₄₀₉ | R_{y1}-14 | A-13 | Lₐ₂₄₁₀ | R_{y1}-17 | A-13 |
| Lₐ₂₄₁₁ | R_{y1}-18 | A-13 | Lₐ₂₄₁₂ | R_{y1}-19 | A-13 |
| Lₐ₂₄₁₃ | R_{y1}-22 | A-13 | Lₐ₂₄₁₄ | R_{y1}-23 | A-13 |
| Lₐ₂₄₁₅ | R_{y1}-24 | A-13 | Lₐ₂₄₁₆ | R_{y1}-27 | A-13 |
| Lₐ₂₄₁₇ | R_{y1}-29 | A-13 | Lₐ₂₄₁₈ | R_{y1}-30 | A-13 |
| Lₐ₂₄₁₉ | R_{y1}-31 | A-13 | Lₐ₂₄₂₀ | R_{y1}-32 | A-13 |
| Lₐ₂₄₂₁ | R_{y1}-33 | A-13 | Lₐ₂₄₂₂ | R_{y1}-34 | A-13 |
| Lₐ₂₄₂₃ | R_{y1}-35 | A-13 | Lₐ₂₄₂₄ | R_{y1}-36 | A-13 |
| Lₐ₂₄₂₅ | R_{y1}-37 | A-13 | Lₐ₂₄₂₆ | R_{y1}-38 | A-13 |
| Lₐ₂₄₂₇ | R_{y1}-39 | A-13 | Lₐ₂₄₂₈ | R_{y1}-42 | A-13 |
| Lₐ₂₄₂₉ | R_{y1}-43 | A-13 | Lₐ₂₄₃₀ | R_{y1}-44 | A-13 |
| Lₐ₂₄₃₁ | R_{y1}-45 | A-13 | Lₐ₂₄₃₂ | R_{y1}-46 | A-13 |
| Lₐ₂₄₃₃ | R_{y1}-1 | A-26 | Lₐ₂₄₃₄ | R_{y1}-2 | A-26 |
| Lₐ₂₄₃₅ | R_{y1}-4 | A-26 | Lₐ₂₄₃₆ | R_{y1}-6 | A-26 |
| Lₐ₂₄₃₇ | R_{y1}-7 | A-26 | Lₐ₂₄₃₈ | R_{y1}-8 | A-26 |
| Lₐ₂₄₃₉ | R_{y1}-9 | A-26 | Lₐ₂₄₄₀ | R_{y1}-10 | A-26 |
| Lₐ₂₄₄₁ | R_{y1}-11 | A-26 | Lₐ₂₄₄₂ | R_{y1}-13 | A-26 |
| Lₐ₂₄₄₃ | R_{y1}-14 | A-26 | Lₐ₂₄₄₄ | R_{y1}-17 | A-26 |
| Lₐ₂₄₄₅ | R_{y1}-18 | A-26 | Lₐ₂₄₄₆ | R_{y1}-19 | A-26 |
| Lₐ₂₄₄₇ | R_{y1}-22 | A-26 | Lₐ₂₄₄₈ | R_{y1}-23 | A-26 |
| Lₐ₂₄₄₉ | R_{y1}-24 | A-26 | Lₐ₂₄₅₀ | R_{y1}-27 | A-26 |
| Lₐ₂₄₅₁ | R_{y1}-29 | A-26 | Lₐ₂₄₅₂ | R_{y1}-30 | A-26 |
| Lₐ₂₄₅₃ | R_{y1}-31 | A-26 | Lₐ₂₄₅₄ | R_{y1}-32 | A-26 |
| Lₐ₂₄₅₅ | R_{y1}-33 | A-26 | Lₐ₂₄₅₆ | R_{y1}-34 | A-26 |
| Lₐ₂₄₅₇ | R_{y1}-35 | A-26 | Lₐ₂₄₅₈ | R_{y1}-36 | A-26 |
| Lₐ₂₄₅₉ | R_{y1}-37 | A-26 | Lₐ₂₄₆₀ | R_{y1}-38 | A-26 |
| Lₐ₂₄₆₁ | R_{y1}-39 | A-26 | Lₐ₂₄₆₂ | R_{y1}-42 | A-26 |
| Lₐ₂₄₆₃ | R_{y1}-43 | A-26 | Lₐ₂₄₆₄ | R_{y1}-44 | A-26 |
| Lₐ₂₄₆₅ | R_{y1}-45 | A-26 | Lₐ₂₄₆₆ | R_{y1}-46 | A-26 |
| Lₐ₂₄₆₇ | R_{y1}-1 | A-28 | Lₐ₂₄₆₈ | R_{y1}-2 | A-28 |
| Lₐ₂₄₆₉ | R_{y1}-4 | A-28 | Lₐ₂₄₇₀ | R_{y1}-6 | A-28 |
| Lₐ₂₄₇₁ | R_{y1}-7 | A-28 | Lₐ₂₄₇₂ | R_{y1}-8 | A-28 |
| Lₐ₂₄₇₃ | R_{y1}-9 | A-28 | Lₐ₂₄₇₄ | R_{y1}-10 | A-28 |
| Lₐ₂₄₇₅ | R_{y1}-11 | A-28 | Lₐ₂₄₇₆ | R_{y1}-13 | A-28 |
| Lₐ₂₄₇₇ | R_{y1}-14 | A-28 | Lₐ₂₄₇₈ | R_{y1}-17 | A-28 |
| Lₐ₂₄₇₉ | R_{y1}-18 | A-28 | Lₐ₂₄₈₀ | R_{y1}-19 | A-28 |
| Lₐ₂₄₈₁ | R_{y1}-22 | A-28 | Lₐ₂₄₈₂ | R_{y1}-23 | A-28 |
| Lₐ₂₄₈₃ | R_{y1}-24 | A-28 | Lₐ₂₄₈₄ | R_{y1}-27 | A-28 |
| Lₐ₂₄₈₅ | R_{y1}-29 | A-28 | Lₐ₂₄₈₆ | R_{y1}-30 | A-28 |
| Lₐ₂₄₈₇ | R_{y1}-31 | A-28 | Lₐ₂₄₈₈ | R_{y1}-32 | A-28 |
| Lₐ₂₄₈₉ | R_{y1}-33 | A-28 | Lₐ₂₄₉₀ | R_{y1}-34 | A-28 |
| Lₐ₂₄₉₁ | R_{y1}-35 | A-28 | Lₐ₂₄₉₂ | R_{y1}-36 | A-28 |
| Lₐ₂₄₉₃ | R_{y1}-37 | A-28 | Lₐ₂₄₉₄ | R_{y1}-38 | A-28 |
| Lₐ₂₄₉₅ | R_{y1}-39 | A-28 | Lₐ₂₄₉₆ | R_{y1}-42 | A-28 |
| Lₐ₂₄₉₇ | R_{y1}-43 | A-28 | Lₐ₂₄₉₈ | R_{y1}-44 | A-28 |
| Lₐ₂₄₉₉ | R_{y1}-45 | A-28 | Lₐ₂₅₀₀ | R_{y1}-46 | A-28 |
| Lₐ₂₅₀₁ | R_{y1}-1 | A-39 | Lₐ₂₅₀₂ | R_{y1}-2 | A-39 |
| Lₐ₂₅₀₃ | R_{y1}-4 | A-39 | Lₐ₂₅₀₄ | R_{y1}-6 | A-39 |
| Lₐ₂₅₀₅ | R_{y1}-7 | A-39 | Lₐ₂₅₀₆ | R_{y1}-8 | A-39 |
| Lₐ₂₅₀₇ | R_{y1}-9 | A-39 | Lₐ₂₅₀₈ | R_{y1}-10 | A-39 |
| Lₐ₂₅₀₉ | R_{y1}-11 | A-39 | Lₐ₂₅₁₀ | R_{y1}-13 | A-39 |
| Lₐ₂₅₁₁ | R_{y1}-14 | A-39 | Lₐ₂₅₁₂ | R_{y1}-17 | A-39 |
| Lₐ₂₅₁₃ | R_{y1}-18 | A-39 | Lₐ₂₅₁₄ | R_{y1}-19 | A-39 |
| Lₐ₂₅₁₅ | R_{y1}-22 | A-39 | Lₐ₂₅₁₆ | R_{y1}-23 | A-39 |
| Lₐ₂₅₁₇ | R_{y1}-24 | A-39 | Lₐ₂₅₁₈ | R_{y1}-27 | A-39 |
| Lₐ₂₅₁₉ | R_{y1}-29 | A-39 | Lₐ₂₅₂₀ | R_{y1}-30 | A-39 |
| Lₐ₂₅₂₁ | R_{y1}-31 | A-39 | Lₐ₂₅₂₂ | R_{y1}-32 | A-39 |
| Lₐ₂₅₂₃ | R_{y1}-33 | A-39 | Lₐ₂₅₂₄ | R_{y1}-34 | A-39 |
| Lₐ₂₅₂₅ | R_{y1}-35 | A-39 | Lₐ₂₅₂₆ | R_{y1}-36 | A-39 |
| Lₐ₂₅₂₇ | R_{y1}-37 | A-39 | Lₐ₂₅₂₈ | R_{y1}-38 | A-39 |
| Lₐ₂₅₂₉ | R_{y1}-39 | A-39 | Lₐ₂₅₃₀ | R_{y1}-42 | A-39 |
| Lₐ₂₅₃₁ | R_{y1}-43 | A-39 | Lₐ₂₅₃₂ | R_{y1}-44 | A-39 |
| Lₐ₂₅₃₃ | R_{y1}-45 | A-39 | Lₐ₂₅₃₄ | R_{y1}-46 | A-39 |
| Lₐ₂₅₃₅ | R_{y1}-1 | A-40 | Lₐ₂₅₃₆ | R_{y1}-2 | A-40 |
| Lₐ₂₅₃₇ | R_{y1}-4 | A-40 | Lₐ₂₅₃₈ | R_{y1}-6 | A-40 |
| Lₐ₂₅₃₉ | R_{y1}-7 | A-40 | Lₐ₂₅₄₀ | R_{y1}-8 | A-40 |
| Lₐ₂₅₄₁ | R_{y1}-9 | A-40 | Lₐ₂₅₄₂ | R_{y1}-10 | A-40 |
| Lₐ₂₅₄₃ | R_{y1}-11 | A-40 | Lₐ₂₅₄₄ | R_{y1}-13 | A-40 |
| Lₐ₂₅₄₅ | R_{y1}-14 | A-40 | Lₐ₂₅₄₆ | R_{y1}-17 | A-40 |
| Lₐ₂₅₄₇ | R_{y1}-18 | A-40 | Lₐ₂₅₄₈ | R_{y1}-19 | A-40 |
| Lₐ₂₅₄₉ | R_{y1}-22 | A-40 | Lₐ₂₅₅₀ | R_{y1}-23 | A-40 |
| Lₐ₂₅₅₁ | R_{y1}-24 | A-40 | Lₐ₂₅₅₂ | R_{y1}-27 | A-40 |
| Lₐ₂₅₅₃ | R_{y1}-29 | A-40 | Lₐ₂₅₅₄ | R_{y1}-30 | A-40 |
| Lₐ₂₅₅₅ | R_{y1}-31 | A-40 | Lₐ₂₅₅₆ | R_{y1}-32 | A-40 |
| Lₐ₂₅₅₇ | R_{y1}-33 | A-40 | Lₐ₂₅₅₈ | R_{y1}-34 | A-40 |
| Lₐ₂₅₅₉ | R_{y1}-35 | A-40 | Lₐ₂₅₆₀ | R_{y1}-36 | A-40 |
| Lₐ₂₅₆₁ | R_{y1}-37 | A-40 | Lₐ₂₅₆₂ | R_{y1}-38 | A-40 |
| Lₐ₂₅₆₃ | R_{y1}-39 | A-40 | Lₐ₂₅₆₄ | R_{y1}-42 | A-40 |
| Lₐ₂₅₆₅ | R_{y1}-43 | A-40 | Lₐ₂₅₆₆ | R_{y1}-44 | A-40 |
| Lₐ₂₅₆₇ | R_{y1}-45 | A-40 | Lₐ₂₅₆₈ | R_{y1}-46 | A-40 |

wherein R_{y1}-1 to R_{y1}-46 have the following structures: 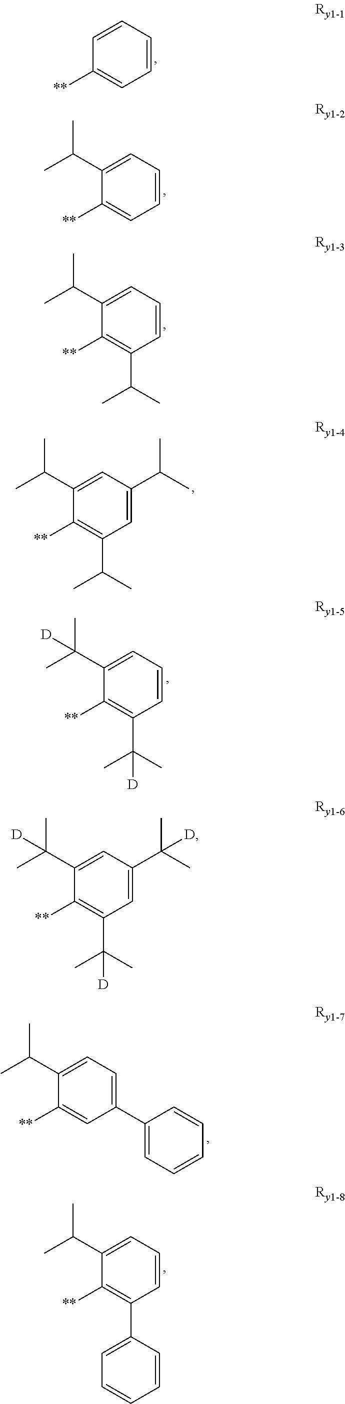 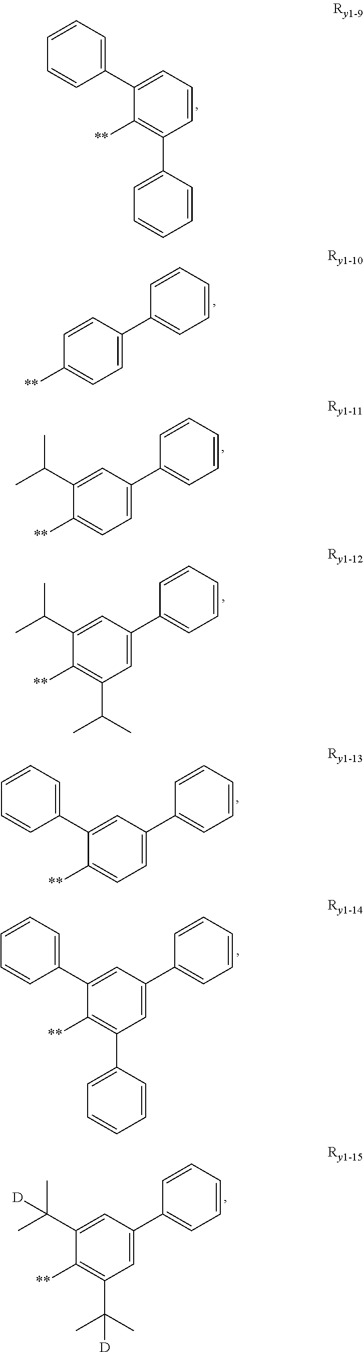 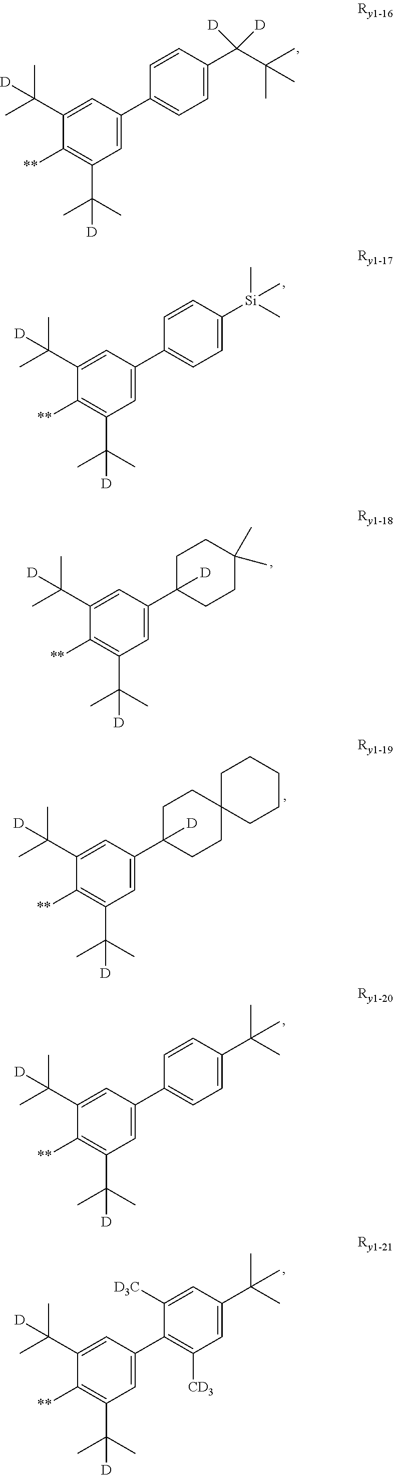 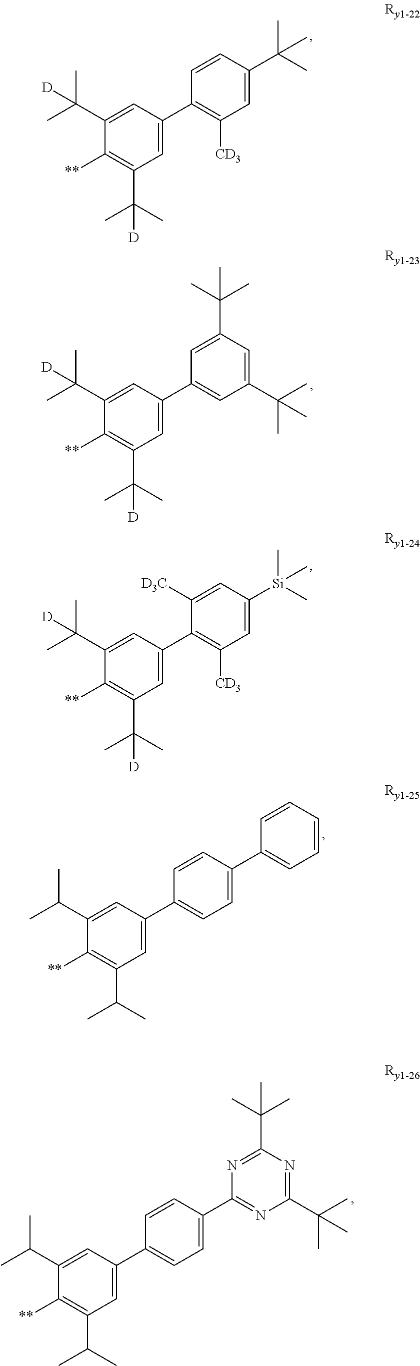 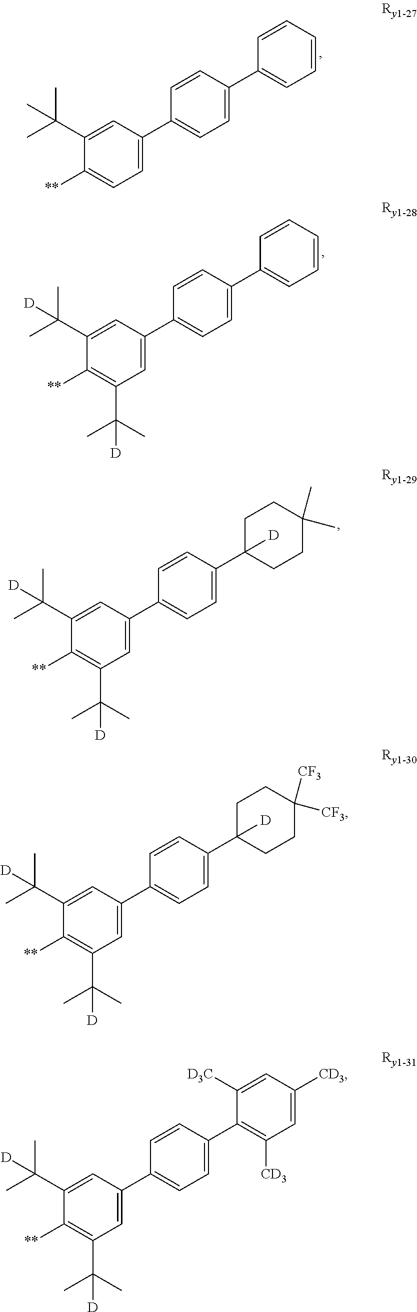 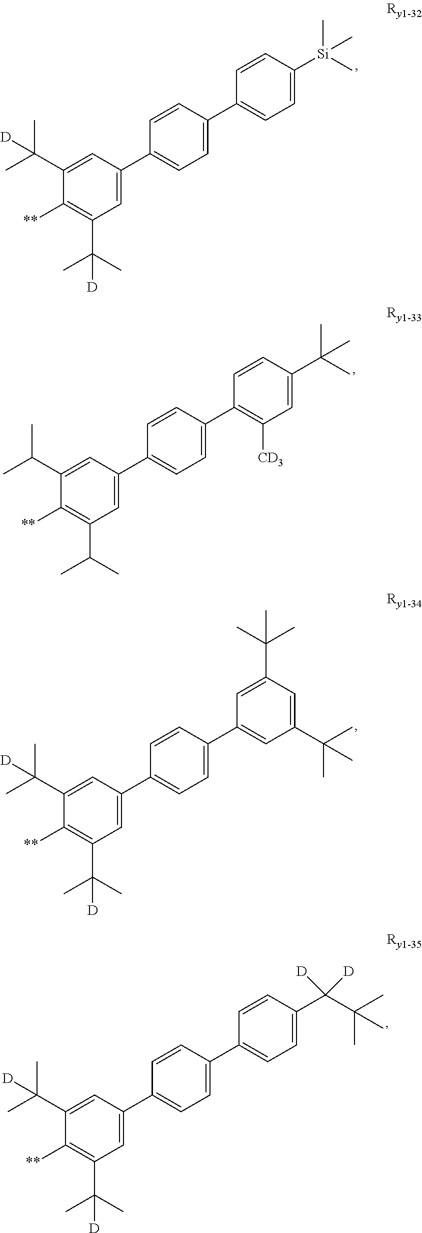 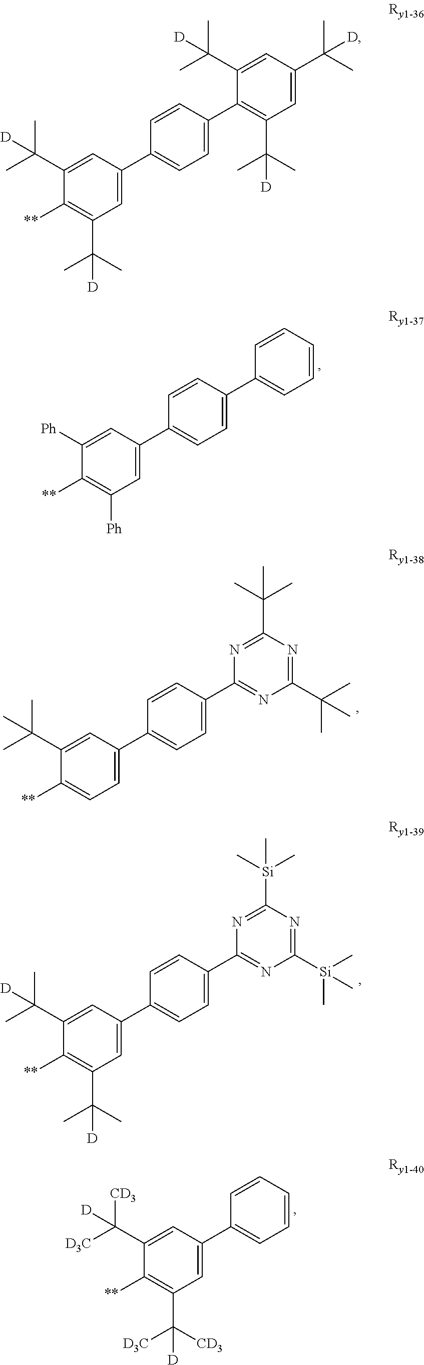 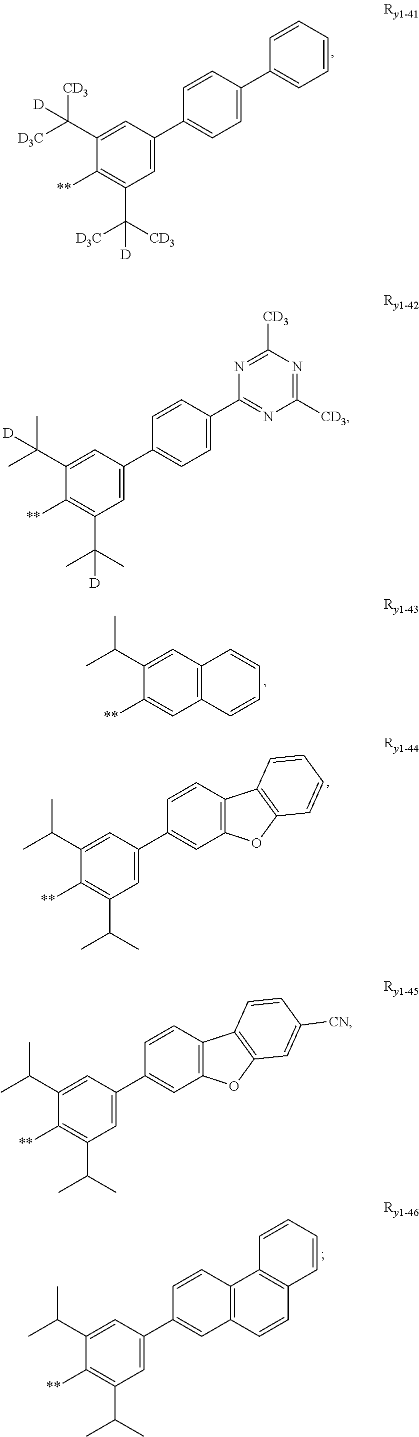
wherein “*” represents a position where an imidazole ring fragment is joined;
wherein Lₐ₂₅₆₉ to Lₐ₂₈₇₄ each have the following structure: 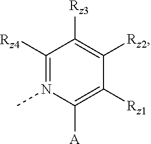
wherein R_{Z1}, R_{Z2}, R_{Z3}, R_{Z4} and Fragment A are selected from the atoms or groups in the following table:

| Lₐ | R_{Z1} | R_{Z2} | R_{Z3} | R_{Z4} | Fragment A |
|---|---|---|---|---|---|
| Lₐ₂₅₆₉ | H | H | H | H | A-1 |
| Lₐ₂₅₇₀ | H | H | H | H | A-2 |
| Lₐ₂₅₇₁ | H | H | H | H | A-3 |
| Lₐ₂₅₇₂ | H | H | H | H | A-4 |
| Lₐ₂₅₇₃ | H | H | H | H | A-5 |
| Lₐ₂₅₇₄ | H | H | H | H | A-6 |
| Lₐ₂₅₇₅ | H | H | H | H | A-7 |
| Lₐ₂₅₇₆ | H | H | H | H | A-8 |
| Lₐ₂₅₇₇ | H | H | H | H | A-9 |
| Lₐ₂₅₇₈ | H | H | H | H | A-10 |
| Lₐ₂₅₇₉ | H | H | H | H | A-11 |
| Lₐ₂₅₈₀ | H | H | H | H | A-12 |
| Lₐ₂₅₈₁ | H | H | H | H | A-13 |
| Lₐ₂₅₈₂ | H | H | H | H | A-14 |
| Lₐ₂₅₈₃ | H | H | H | H | A-15 |
| Lₐ₂₅₈₄ | H | H | H | H | A-16 |
| Lₐ₂₅₈₅ | H | H | H | H | A-17 |
| Lₐ₂₅₈₆ | H | H | H | H | A-18 |
| Lₐ₂₅₈₇ | H | H | H | H | A-19 |
| Lₐ₂₅₈₈ | H | H | H | H | A-20 |
| Lₐ₂₅₈₉ | H | H | H | H | A-21 |
| Lₐ₂₅₉₀ | H | H | H | H | A-22 |
| Lₐ₂₅₉₁ | H | H | H | H | A-23 |
| Lₐ₂₅₉₂ | H | H | H | H | A-24 |
| Lₐ₂₅₉₃ | H | H | H | H | A-25 |
| Lₐ₂₅₉₄ | H | H | H | H | A-26 |
| Lₐ₂₅₉₅ | H | H | H | H | A-27 |
| Lₐ₂₅₉₆ | H | H | H | H | A-28 |
| Lₐ₂₅₉₇ | H | H | H | H | A-29 |
| Lₐ₂₅₉₈ | H | H | H | H | A-30 |
| Lₐ₂₅₉₉ | H | H | H | H | A-31 |
| Lₐ₂₆₀₀ | H | H | H | H | A-32 |
| Lₐ₂₆₀₁ | H | H | H | H | A-33 |
| Lₐ₂₆₀₂ | H | H | H | H | A-34 |
| Lₐ₂₆₀₃ | H | H | H | H | A-35 |
| Lₐ₂₆₀₄ | H | H | H | H | A-36 |
| Lₐ₂₆₀₅ | H | H | H | H | A-37 |
| Lₐ₂₆₀₆ | H | H | H | H | A-38 |
| Lₐ₂₆₀₇ | H | H | H | H | A-39 |
| Lₐ₂₆₀₈ | H | H | H | H | A-40 |
| Lₐ₂₆₀₉ | H | H | H | H | A-41 |
| Lₐ₂₆₁₀ | H | H | H | H | A-42 |
| Lₐ₂₆₁₁ | H | H | H | H | A-43 |
| Lₐ₂₆₁₂ | H | H | H | H | A-44 |
| Lₐ₂₆₁₃ | H | H | H | H | A-45 |
| Lₐ₂₆₁₄ | H | H | H | H | A-46 |
| Lₐ₂₆₁₅ | H | H | H | H | A-47 |
| Lₐ₂₆₁₆ | H | H | H | H | A-48 |
| Lₐ₂₆₁₇ | H | H | H | H | A-49 |
| Lₐ₂₆₁₈ | H | H | H | H | A-50 |
| Lₐ₂₆₁₉ | H | H | H | H | A-51 |
| Lₐ₂₆₂₀ | H | H | H | H | A-52 |
| Lₐ₂₆₂₁ | H | H | H | H | A-53 |
| Lₐ₂₆₂₂ | H | H | H | H | A-54 |
| Lₐ₂₆₂₃ | H | H | H | H | A-55 |
| Lₐ₂₆₂₄ | H | H | H | H | A-56 |
| Lₐ₂₆₂₅ | H | H | H | H | A-57 |
| Lₐ₂₆₂₆ | H | H | H | H | A-58 |
| Lₐ₂₆₂₇ | H | H | H | H | A-59 |
| Lₐ₂₆₂₈ | H | H | H | H | A-60 |
| Lₐ₂₆₂₉ | H | H | H | H | A-61 |
| Lₐ₂₆₃₀ | H | H | H | H | A-62 |
| Lₐ₂₆₃₁ | H | H | H | H | A-63 |
| Lₐ₂₆₃₂ | H | H | H | H | A-64 |
| Lₐ₂₆₃₃ | H | H | H | H | A-65 |
| Lₐ₂₆₃₄ | H | H | H | H | A-66 |
| Lₐ₂₆₃₅ | H | H | H | H | A-67 |
| Lₐ₂₆₃₆ | H | H | H | H | A-68 |
| Lₐ₂₆₃₇ | H | H | H | H | A-69 |
| Lₐ₂₆₃₈ | H | H | H | H | A-70 |
| Lₐ₂₆₃₉ | H | H | H | H | A-71 |
| Lₐ₂₆₄₀ | H | H | H | H | A-72 |
| Lₐ₂₆₄₁ | H | H | H | H | A-73 |
| Lₐ₂₆₄₂ | H | H | H | H | A-74 |
| Lₐ₂₆₄₃ | H | H | H | H | A-75 |
| Lₐ₂₆₄₄ | H | H | H | H | A-76 |
| Lₐ₂₆₄₅ | H | H | H | H | A-77 |
| Lₐ₂₆₄₆ | H | H | H | H | A-78 |
| Lₐ₂₆₄₇ | H | H | H | H | A-79 |
| Lₐ₂₆₄₈ | H | H | H | H | A-80 |
| Lₐ₂₆₄₉ | H | H | H | H | A-81 |
| Lₐ₂₆₅₀ | H | H | H | H | A-82 |
| Lₐ₂₆₅₁ | H | H | H | H | A-83 |
| Lₐ₂₆₅₂ | H | H | H | H | A-84 |
| Lₐ₂₆₅₃ | H | H | H | H | A-85 |
| Lₐ₂₆₅₄ | H | H | H | H | A-86 |
| Lₐ₂₆₅₅ | H | H | H | H | A-87 |
| Lₐ₂₆₅₆ | H | H | H | H | A-88 |
| Lₐ₂₆₅₇ | H | H | H | H | A-89 |
| Lₐ₂₆₅₈ | H | H | H | H | A-90 |
| Lₐ₂₆₅₉ | H | ^{t}Bu | H | H | A-1 |
| Lₐ₂₆₆₀ | H | ^{t}Bu | H | H | A-2 |
| Lₐ₂₆₆₁ | D | ^{t}Bu | H | H | A-3 |
| Lₐ₂₆₆₂ | H | ^{t}Bu | H | H | A-4 |
| Lₐ₂₆₆₃ | H | ^{t}Bu | H | H | A-5 |
| Lₐ₂₆₆₄ | H | ^{t}Bu | H | H | A-6 |
| Lₐ₂₆₆₅ | H | ^{t}Bu | H | H | A-7 |
| Lₐ₂₆₆₆ | H | ^{t}Bu | D | H | A-8 |
| Lₐ₂₆₆₇ | H | ^{t}Bu | H | H | A-9 |
| Lₐ₂₆₆₈ | H | ^{t}Bu | H | H | A-10 |
| Lₐ₂₆₆₉ | H | ^{t}Bu | H | H | A-11 |
| Lₐ₂₆₇₀ | H | ^{t}Bu | H | D | A-12 |
| Lₐ₂₆₇₁ | H | ^{t}Bu | H | H | A-13 |
| Lₐ₂₆₇₂ | H | ^{t}Bu | H | H | A-14 |
| Lₐ₂₆₇₃ | H | ^{t}Bu | H | H | A-15 |
| Lₐ₂₆₇₄ | D | ^{t}Bu | H | H | A-16 |
| Lₐ₂₆₇₅ | H | ^{t}Bu | H | H | A-17 |
| Lₐ₂₆₇₆ | H | ^{t}Bu | H | H | A-18 |
| Lₐ₂₆₇₇ | H | ^{t}Bu | H | H | A-19 |
| Lₐ₂₆₇₈ | H | ^{t}Bu | D | H | A-20 |
| Lₐ₂₆₇₉ | H | ^{t}Bu | H | H | A-21 |
| Lₐ₂₆₈₀ | H | ^{t}Bu | H | H | A-22 |
| Lₐ₂₆₈₁ | H | ^{t}Bu | H | D | A-23 |
| Lₐ₂₆₈₂ | H | ^{t}Bu | H | H | A-24 |
| Lₐ₂₆₈₃ | H | ^{t}Bu | H | H | A-25 |
| Lₐ₂₆₈₄ | H | ^{t}Bu | H | H | A-26 |
| Lₐ₂₆₈₅ | H | ^{t}Bu | H | H | A-27 |
| Lₐ₂₆₈₆ | D | ^{t}Bu | H | H | A-28 |
| Lₐ₂₆₈₇ | H | ^{t}Bu | D | H | A-29 |
| Lₐ₂₆₈₈ | H | ^{t}Bu | H | D | A-30 |
| Lₐ₂₆₈₉ | H | ^{t}Bu | H | H | A-31 |
| Lₐ₂₆₉₀ | H | ^{t}Bu | H | H | A-32 |
| Lₐ₂₆₉₁ | H | ^{t}Bu | H | H | A-33 |
| Lₐ₂₆₉₂ | H | ^{t}Bu | H | H | A-34 |
| Lₐ₂₆₉₃ | H | ^{t}Bu | H | H | A-35 |
| Lₐ₂₆₉₄ | D | ^{t}Bu | H | H | A-36 |
| Lₐ₂₆₉₅ | H | ^{t}Bu | H | H | A-37 |
| Lₐ₂₆₉₆ | H | ^{t}Bu | H | H | A-38 |
| Lₐ₂₆₉₇ | H | ^{t}Bu | D | H | A-39 |
| Lₐ₂₆₉₈ | H | ^{t}Bu | H | H | A-40 |
| Lₐ₂₆₉₉ | H | ^{t}Bu | H | H | A-41 |
| Lₐ₂₇₀₀ | H | ^{t}Bu | H | H | A-42 |
| Lₐ₂₇₀₁ | H | ^{t}Bu | H | H | A-43 |
| Lₐ₂₇₀₂ | H | ^{t}Bu | H | D | A-44 |
| Lₐ₂₇₀₃ | H | ^{t}Bu | H | H | A-45 |
| Lₐ₂₇₀₄ | H | ^{t}Bu | H | H | A-46 |
| Lₐ₂₇₀₅ | H | ^{t}Bu | H | H | A-47 |
| Lₐ₂₇₀₆ | H | ^{t}Bu | D | H | A-48 |
| Lₐ₂₇₀₇ | H | ^{t}Bu | H | H | A-49 |
| Lₐ₂₇₀₈ | H | ^{t}Bu | H | H | A-50 |
| Lₐ₂₇₀₉ | H | ^{t}Bu | H | H | A-51 |
| Lₐ₂₇₁₀ | H | ^{t}Bu | H | H | A-52 |
| Lₐ₂₇₁₁ | H | ^{t}Bu | H | H | A-53 |
| Lₐ₂₇₁₂ | H | ^{t}Bu | H | H | A-54 |
| Lₐ₂₇₁₃ | H | ^{t}Bu | H | H | A-55 |
| Lₐ₂₇₁₄ | H | ^{t}Bu | H | H | A-56 |
| Lₐ₂₇₁₅ | H | ^{t}Bu | H | H | A-57 |
| Lₐ₂₇₁₆ | H | ^{t}Bu | H | H | A-58 |
| Lₐ₂₇₁₇ | D | ^{t}Bu | H | H | A-59 |
| Lₐ₂₇₁₈ | H | ^{t}Bu | H | H | A-60 |
| Lₐ₂₇₁₉ | H | H | ^{t}Bu | H | A-1 |
| Lₐ₂₇₂₀ | H | H | ^{t}Bu | H | A-2 |
| Lₐ₂₇₂₁ | H | H | ^{t}Bu | D | A-11 |
| Lₐ₂₇₂₂ | D | H | ^{t}Bu | H | A-12 |
| Lₐ₂₇₂₃ | H | H | ^{t}Bu | H | A-13 |
| Lₐ₂₇₂₄ | H | H | ^{t}Bu | H | A-20 |
| Lₐ₂₇₂₅ | H | H | ^{t}Bu | H | A-21 |
| Lₐ₂₇₂₆ | H | H | ^{t}Bu | H | A-22 |
| Lₐ₂₇₂₇ | H | H | ^{t}Bu | H | A-23 |
| Lₐ₂₇₂₈ | H | H | ^{t}Bu | H | A-24 |
| Lₐ₂₇₂₉ | D | H | ^{t}Bu | H | A-28 |
| Lₐ₂₇₃₀ | H | H | ^{t}Bu | H | A-30 |
| Lₐ₂₇₃₁ | H | H | ^{t}Bu | H | A-32 |
| Lₐ₂₇₃₂ | H | H | ^{t}Bu | H | A-33 |
| Lₐ₂₇₃₃ | H | H | ^{t}Bu | H | A-34 |
| Lₐ₂₇₃₄ | H | D | ^{t}Bu | H | A-35 |
| Lₐ₂₇₃₅ | H | H | ^{t}Bu | H | A-36 |
| Lₐ₂₇₃₆ | H | H | ^{t}Bu | H | A-39 |
| Lₐ₂₇₃₇ | H | H | ^{t}Bu | D | A-40 |
| Lₐ₂₇₃₈ | H | H | ^{t}Bu | H | A-41 |
| Lₐ₂₇₃₉ | H | H | ^{t}Bu | H | A-42 |
| Lₐ₂₇₄₀ | H | H | ^{t}Bu | H | A-43 |
| Lₐ₂₇₄₁ | D | H | ^{t}Bu | H | A-44 |
| Lₐ₂₇₄₂ | H | H | ^{t}Bu | H | A-45 |
| Lₐ₂₇₄₃ | H | H | ^{t}Bu | H | A-46 |
| Lₐ₂₇₄₄ | H | D | ^{t}Bu | H | A-47 |
| Lₐ₂₇₄₅ | H | H | ^{t}Bu | H | A-48 |
| Lₐ₂₇₄₆ | H | H | ^{t}Bu | H | A-49 |
| Lₐ₂₇₄₇ | H | H | ^{t}Bu | D | A-50 |
| Lₐ₂₇₄₈ | H | H | ^{t}Bu | H | A-51 |
| Lₐ₂₇₄₉ | H | H | ^{t}Bu | H | A-52 |
| Lₐ₂₇₅₀ | H | H | ^{t}Bu | H | A-53 |
| Lₐ₂₇₅₁ | H | D | ^{t}Bu | H | A-54 |
| Lₐ₂₇₅₂ | H | H | ^{t}Bu | H | A-55 |
| Lₐ₂₇₅₃ | H | H | ^{t}Bu | H | A-56 |
| Lₐ₂₇₅₄ | D | H | ^{t}Bu | H | A-57 |
| Lₐ₂₇₅₅ | H | H | ^{t}Bu | H | A-58 |
| Lₐ₂₇₅₆ | H | H | ^{t}Bu | D | A-59 |
| Lₐ₂₇₅₇ | H | H | ^{t}Bu | H | A-60 |
| Lₐ₂₇₅₈ | H | CD₃ | Ph | H | A-1 |
| Lₐ₂₇₅₉ | H | CD₃ | Ph | H | A-2 |
| Lₐ₂₇₆₀ | D | CD₃ | Ph | H | A-11 |
| Lₐ₂₇₆₁ | H | CD₃ | Ph | H | A-12 |
| Lₐ₂₇₆₂ | H | CD₃ | Ph | D | A-13 |
| Lₐ₂₇₆₃ | H | CD₃ | Ph | H | A-20 |
| Lₐ₂₇₆₄ | H | CD₃ | Ph | H | A-21 |
| Lₐ₂₇₆₅ | H | CD₃ | Ph | H | A-22 |
| Lₐ₂₇₆₆ | H | CD₃ | Ph | H | A-23 |
| Lₐ₂₇₆₇ | H | CD₃ | Ph | H | A-24 |
| Lₐ₂₇₆₈ | H | CD₃ | Ph | H | A-28 |
| Lₐ₂₇₆₉ | H | CD₃ | Ph | H | A-30 |
| Lₐ₂₇₇₀ | D | CD₃ | Ph | H | A-32 |
| Lₐ₂₇₇₁ | H | CD₃ | Ph | H | A-33 |
| Lₐ₂₇₇₂ | H | CD₃ | Ph | H | A-34 |
| Lₐ₂₇₇₃ | H | CD₃ | Ph | H | A-35 |
| Lₐ₂₇₇₄ | H | CD₃ | Ph | H | A-36 |
| Lₐ₂₇₇₅ | H | CD₃ | Ph | H | A-39 |
| Lₐ₂₇₇₆ | H | CD₃ | Ph | D | A-40 |
| Lₐ₂₇₇₇ | H | CD₃ | Ph | H | A-41 |
| Lₐ₂₇₇₈ | H | CD₃ | Ph | H | A-42 |
| Lₐ₂₇₇₉ | H | CD₃ | Ph | H | A-43 |
| Lₐ₂₇₈₀ | H | CD₃ | Ph | H | A-44 |
| Lₐ₂₇₈₁ | H | CD₃ | Ph | H | A-45 |
| Lₐ₂₇₈₂ | D | CD₃ | Ph | H | A-46 |
| Lₐ₂₇₈₃ | D | CD₃ | Ph | H | A-47 |
| Lₐ₂₇₈₄ | H | CD₃ | Ph | H | A-48 |
| Lₐ₂₇₈₅ | H | CD₃ | Ph | H | A-49 |
| Lₐ₂₇₈₆ | H | CD₃ | Ph | H | A-50 |
| Lₐ₂₇₈₇ | H | CD₃ | Ph | H | A-51 |
| Lₐ₂₇₈₈ | H | CD₃ | Ph | H | A-52 |
| Lₐ₂₇₈₉ | H | CD₃ | Ph | D | A-53 |
| Lₐ₂₇₉₀ | H | CD₃ | Ph | H | A-54 |
| Lₐ₂₇₉₁ | H | CD₃ | Ph | H | A-55 |
| Lₐ₂₇₉₂ | H | CD₃ | Ph | H | A-56 |
| Lₐ₂₇₉₃ | H | CD₃ | Ph | H | A-57 |
| Lₐ₂₇₉₄ | H | CD₃ | Ph | D | A-58 |
| Lₐ₂₇₉₅ | H | CD₃ | Ph | H | A-59 |
| Lₐ₂₇₉₆ | H | CD₃ | Ph | D | A-60 |
| Lₐ₂₇₉₇ | H | Ph | CD₃ | H | A-1 |
| Lₐ₂₇₉₈ | H | Ph | CD₃ | H | A-2 |
| Lₐ₂₇₉₉ | H | Ph | CD₃ | D | A-11 |
| Lₐ₂₈₀₀ | H | Ph | CD₃ | H | A-12 |
| Lₐ₂₈₀₁ | D | Ph | CD₃ | H | A-13 |
| Lₐ₂₈₀₂ | H | Ph | CD₃ | H | A-20 |
| Lₐ₂₈₀₃ | H | Ph | CD₃ | H | A-21 |
| Lₐ₂₈₀₄ | H | Ph | CD₃ | H | A-22 |
| Lₐ₂₈₀₅ | H | Ph | CD₃ | H | A-23 |
| Lₐ₂₈₀₆ | H | Ph | CD₃ | H | A-24 |
| Lₐ₂₈₀₇ | H | Ph | CD₃ | H | A-28 |
| Lₐ₂₈₀₈ | H | Ph | CD₃ | H | A-30 |
| Lₐ₂₈₀₉ | H | Ph | CD₃ | D | A-32 |
| Lₐ₂₈₁₀ | H | Ph | CD₃ | H | A-33 |
| Lₐ₂₈₁₁ | H | Ph | CD₃ | H | A-34 |
| Lₐ₂₈₁₂ | H | Ph | CD₃ | H | A-35 |
| Lₐ₂₈₁₃ | H | Ph | CD₃ | H | A-36 |
| Lₐ₂₈₁₄ | H | Ph | CD₃ | H | A-39 |
| Lₐ₂₈₁₅ | D | Ph | CD₃ | H | A-40 |
| Lₐ₂₈₁₆ | H | Ph | CD₃ | H | A-41 |
| Lₐ₂₈₁₇ | H | Ph | CD₃ | H | A-42 |
| Lₐ₂₈₁₈ | H | Ph | CD₃ | H | A-43 |
| Lₐ₂₈₁₉ | H | Ph | CD₃ | H | A-44 |
| Lₐ₂₈₂₀ | H | Ph | CD₃ | H | A-45 |
| Lₐ₂₈₂₁ | H | Ph | CD₃ | D | A-46 |
| Lₐ₂₈₂₂ | H | Ph | CD₃ | D | A-47 |
| Lₐ₂₈₂₃ | H | Ph | CD₃ | H | A-48 |
| Lₐ₂₈₂₄ | H | Ph | CD₃ | H | A-49 |
| Lₐ₂₈₂₅ | H | Ph | CD₃ | H | A-50 |
| Lₐ₂₈₂₆ | H | Ph | CD₃ | H | A-51 |
| Lₐ₂₈₂₇ | H | Ph | CD₃ | H | A-52 |
| Lₐ₂₈₂₈ | D | Ph | CD₃ | H | A-53 |
| Lₐ₂₈₂₉ | H | Ph | CD₃ | H | A-54 |
| Lₐ₂₈₃₀ | H | Ph | CD₃ | H | A-55 |
| Lₐ₂₈₃₁ | H | Ph | CD₃ | H | A-56 |
| Lₐ₂₈₃₂ | H | Ph | CD₃ | H | A-57 |
| Lₐ₂₈₃₃ | D | Ph | CD₃ | H | A-58 |
| Lₐ₂₈₃₄ | H | Ph | CD₃ | H | A-59 |
| Lₐ₂₈₃₅ | D | Ph | CD₃ | H | A-60 |
| Lₐ₂₈₃₆ | H | 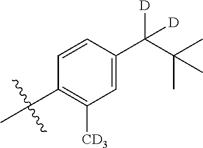 [SMILES: *c1ccc(C([2H])([2H])C(C)(C)C)cc1C([2H])([2H])[2H]] | CD₃ | H | A-1 |
| Lₐ₂₈₃₇ | H | 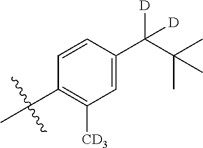 [SMILES: *c1ccc(C([2H])([2H])C(C)(C)C)cc1C([2H])([2H])[2H]] | CD₃ | H | A-2 |
| Lₐ₂₈₃₈ | H | 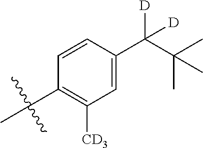 [SMILES: *c1ccc(C([2H])([2H])C(C)(C)C)cc1C([2H])([2H])[2H]] | CD₃ | H | A-11 |
| Lₐ₂₈₃₉ | H | 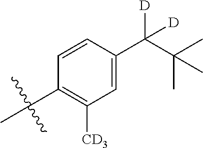 [SMILES: *c1ccc(C([2H])([2H])C(C)(C)C)cc1C([2H])([2H])[2H]] | CD₃ | H | A-12 |
| Lₐ₂₈₄₀ | H | 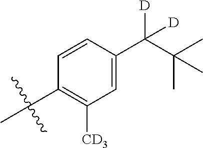 [SMILES: *c1ccc(C([2H])([2H])C(C)(C)C)cc1C([2H])([2H])[2H]] | CD₃ | H | A-13 |
| Lₐ₂₈₄₁ | H | 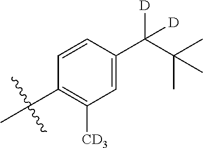 [SMILES: *c1ccc(C([2H])([2H])C(C)(C)C)cc1C([2H])([2H])[2H]] | CD₃ | H | A-20 |
| Lₐ₂₈₄₂ | H | 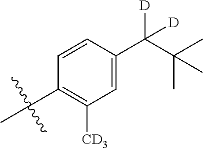 [SMILES: *c1ccc(C([2H])([2H])C(C)(C)C)cc1C([2H])([2H])[2H]] | CD₃ | H | A-21 |
| Lₐ₂₈₄₃ | H | 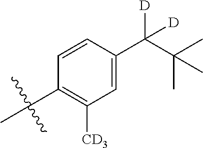 [SMILES: *c1ccc(C([2H])([2H])C(C)(C)C)cc1C([2H])([2H])[2H]] | CD₃ | H | A-22 |
| Lₐ₂₈₄₄ | H | 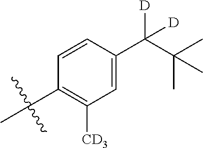 [SMILES: *c1ccc(C([2H])([2H])C(C)(C)C)cc1C([2H])([2H])[2H]] | CD₃ | H | A-23 |
| Lₐ₂₈₄₅ | H | 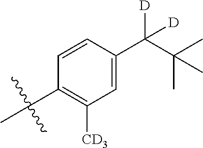 [SMILES: *c1ccc(C([2H])([2H])C(C)(C)C)cc1C([2H])([2H])[2H]] | CD₃ | H | A-24 |
| Lₐ₂₈₄₆ | H | 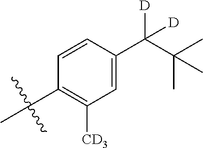 [SMILES: *c1ccc(C([2H])([2H])C(C)(C)C)cc1C([2H])([2H])[2H]] | CD₃ | H | A-28 |
| Lₐ₂₈₄₇ | H | 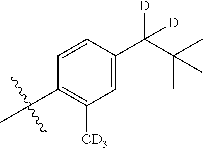 [SMILES: *c1ccc(C([2H])([2H])C(C)(C)C)cc1C([2H])([2H])[2H]] | CD₃ | H | A-30 |
| Lₐ₂₈₄₈ | H | 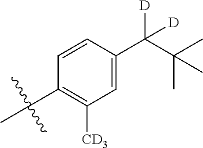 [SMILES: *c1ccc(C([2H])([2H])C(C)(C)C)cc1C([2H])([2H])[2H]] | CD₃ | H | A-32 |
| Lₐ₂₈₄₉ | H | 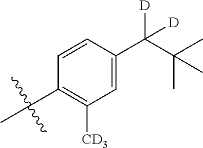 [SMILES: *c1ccc(C([2H])([2H])C(C)(C)C)cc1C([2H])([2H])[2H]] | CD₃ | H | A-33 |
| Lₐ₂₈₅₀ | H | 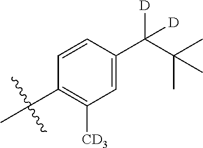 [SMILES: *c1ccc(C([2H])([2H])C(C)(C)C)cc1C([2H])([2H])[2H]] | CD₃ | H | A-34 |
| Lₐ₂₈₅₁ | H | 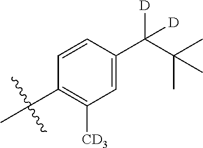 [SMILES: *c1ccc(C([2H])([2H])C(C)(C)C)cc1C([2H])([2H])[2H]] | CH₃ | H | A-35 |
| Lₐ₂₈₅₂ | H | 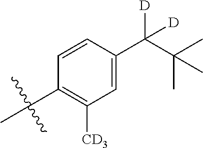 [SMILES: *c1ccc(C([2H])([2H])C(C)(C)C)cc1C([2H])([2H])[2H]] | CD₃ | H | A-36 |
| Lₐ₂₈₅₃ | H | 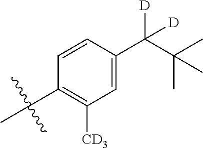 [SMILES: *c1ccc(C([2H])([2H])C(C)(C)C)cc1C([2H])([2H])[2H]] | CD₃ | H | A-39 |
| Lₐ₂₈₅₄ | H | 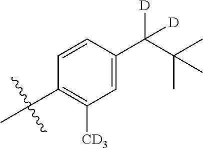 [SMILES: *c1ccc(C([2H])([2H])C(C)(C)C)cc1C([2H])([2H])[2H]] | CH₃ | H | A-40 |
| Lₐ₂₈₅₅ | H | 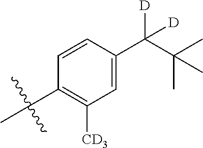 [SMILES: *c1ccc(C([2H])([2H])C(C)(C)C)cc1C([2H])([2H])[2H]] | CD₃ | H | A-41 |
| Lₐ₂₈₅₆ | H | 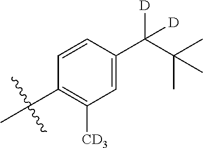 [SMILES: *c1ccc(C([2H])([2H])C(C)(C)C)cc1C([2H])([2H])[2H]] | CD₃ | H | A-42 |
| Lₐ₂₈₅₇ | H | 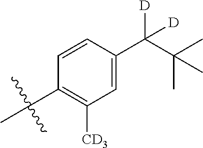 [SMILES: *c1ccc(C([2H])([2H])C(C)(C)C)cc1C([2H])([2H])[2H]] | CH₃ | H | A-43 |
| Lₐ₂₈₅₈ | H | 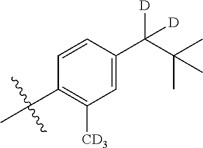 [SMILES: *c1ccc(C([2H])([2H])C(C)(C)C)cc1C([2H])([2H])[2H]] | CD₃ | H | A-44 |
| Lₐ₂₈₅₉ | H | 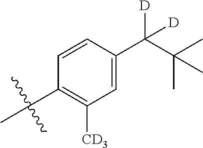 [SMILES: *c1ccc(C([2H])([2H])C(C)(C)C)cc1C([2H])([2H])[2H]] | CD₃ | H | A-45 |
| Lₐ₂₈₆₀ | H | 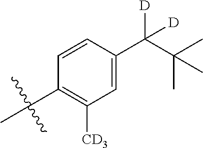 [SMILES: *c1ccc(C([2H])([2H])C(C)(C)C)cc1C([2H])([2H])[2H]] | CD₃ | H | A-46 |
| Lₐ₂₈₆₁ | H | 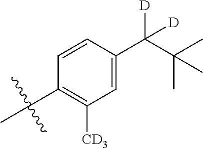 [SMILES: *c1ccc(C([2H])([2H])C(C)(C)C)cc1C([2H])([2H])[2H]] | CD₃ | H | A-47 |
| Lₐ₂₈₆₂ | H | 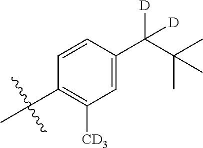 [SMILES: *c1ccc(C([2H])([2H])C(C)(C)C)cc1C([2H])([2H])[2H]] | CD₃ | H | A-48 |
| Lₐ₂₈₆₃ | H | 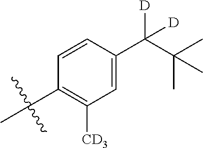 [SMILES: *c1ccc(C([2H])([2H])C(C)(C)C)cc1C([2H])([2H])[2H]] | CD₃ | H | A-49 |
| Lₐ₂₈₆₄ | H | 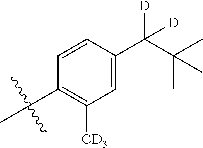 [SMILES: *c1ccc(C([2H])([2H])C(C)(C)C)cc1C([2H])([2H])[2H]] | CD₃ | H | A-50 |
| Lₐ₂₈₆₅ | H | 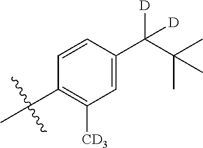 [SMILES: *c1ccc(C([2H])([2H])C(C)(C)C)cc1C([2H])([2H])[2H]] | CD₃ | H | A-51 |
| Lₐ₂₈₆₆ | H | 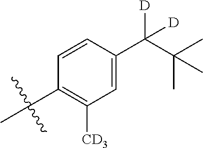 [SMILES: *c1ccc(C([2H])([2H])C(C)(C)C)cc1C([2H])([2H])[2H]] | CD₃ | H | A-52 |
| Lₐ₂₈₆₇ | H | 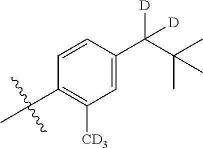 [SMILES: *c1ccc(C([2H])([2H])C(C)(C)C)cc1C([2H])([2H])[2H]] | CD₃ | H | A-53 |
| Lₐ₂₈₆₈ | H | 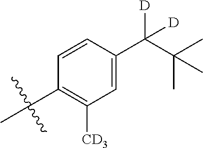 [SMILES: *c1ccc(C([2H])([2H])C(C)(C)C)cc1C([2H])([2H])[2H]] | CD₃ | H | A-54 |
| Lₐ₂₈₆₉ | H | 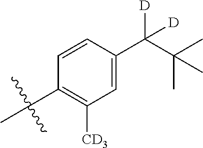 [SMILES: *c1ccc(C([2H])([2H])C(C)(C)C)cc1C([2H])([2H])[2H]] | CD₃ | H | A-55 |
| Lₐ₂₈₇₀ | H | 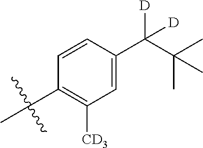 [SMILES: *c1ccc(C([2H])([2H])C(C)(C)C)cc1C([2H])([2H])[2H]] | CD₃ | H | A-56 |
| Lₐ₂₈₇₁ | H | 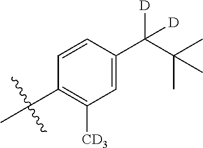 [SMILES: *c1ccc(C([2H])([2H])C(C)(C)C)cc1C([2H])([2H])[2H]] | CD₃ | H | A-57 |
| Lₐ₂₈₇₂ | H | 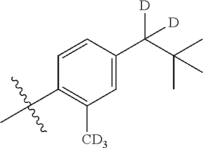 [SMILES: *c1ccc(C([2H])([2H])C(C)(C)C)cc1C([2H])([2H])[2H]] | CD₃ | H | A-58 |
| Lₐ₂₈₇₃ | H | 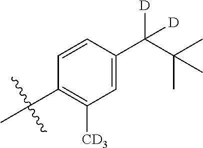 [SMILES: *c1ccc(C([2H])([2H])C(C)(C)C)cc1C([2H])([2H])[2H]] | CD₃ | H | A-59 |
| Lₐ₂₈₇₄ | H | 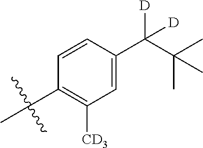 [SMILES: *c1ccc(C([2H])([2H])C(C)(C)C)cc1C([2H])([2H])[2H]] | CD₃ | H | A-60 |

wherein Fragment A-1 to Fragment A-90 have the following structures: 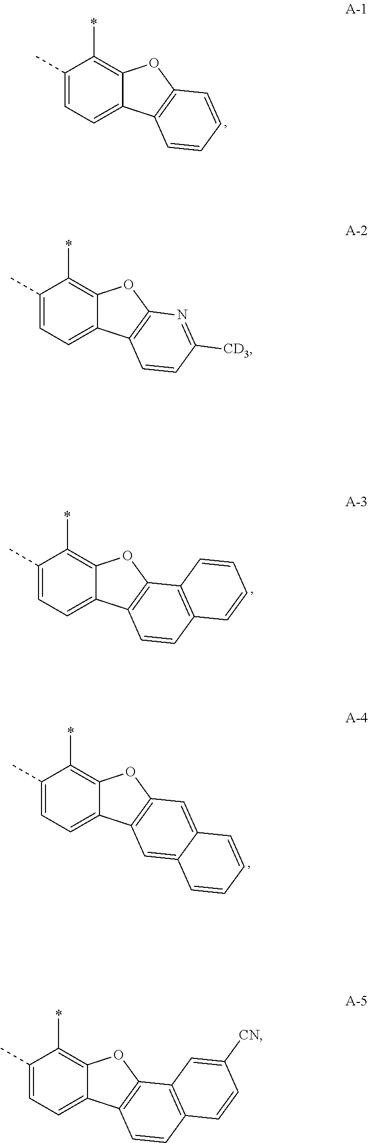 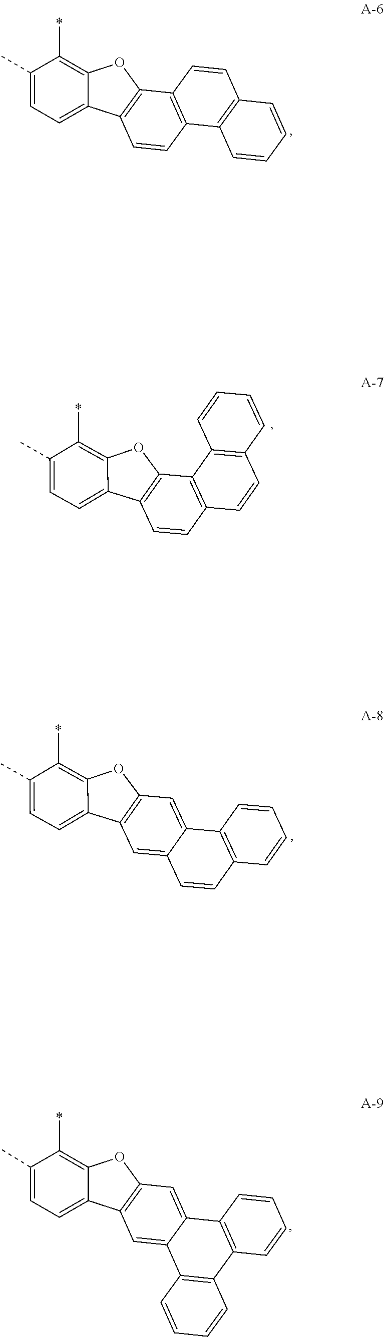 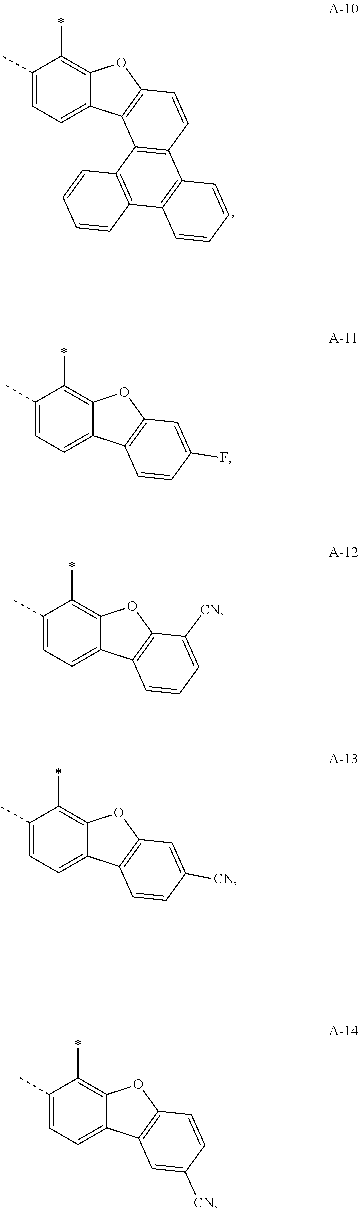 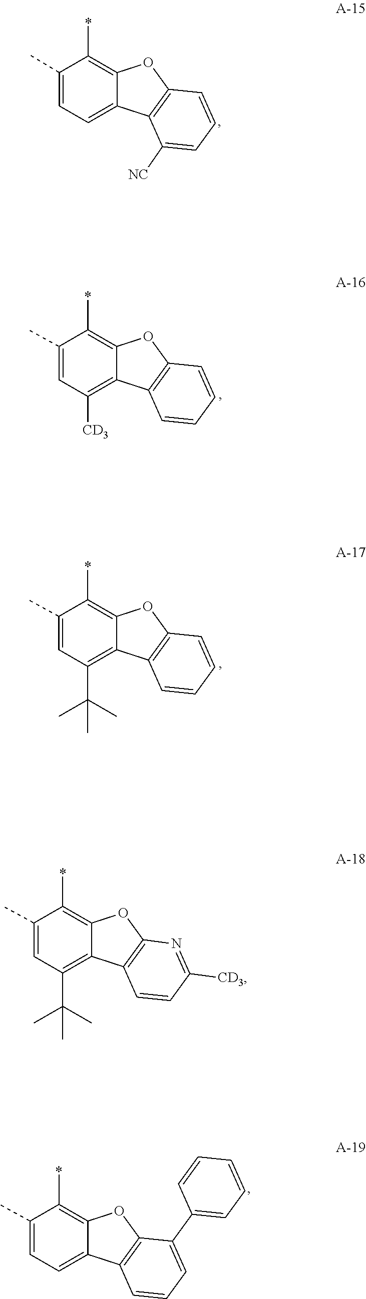 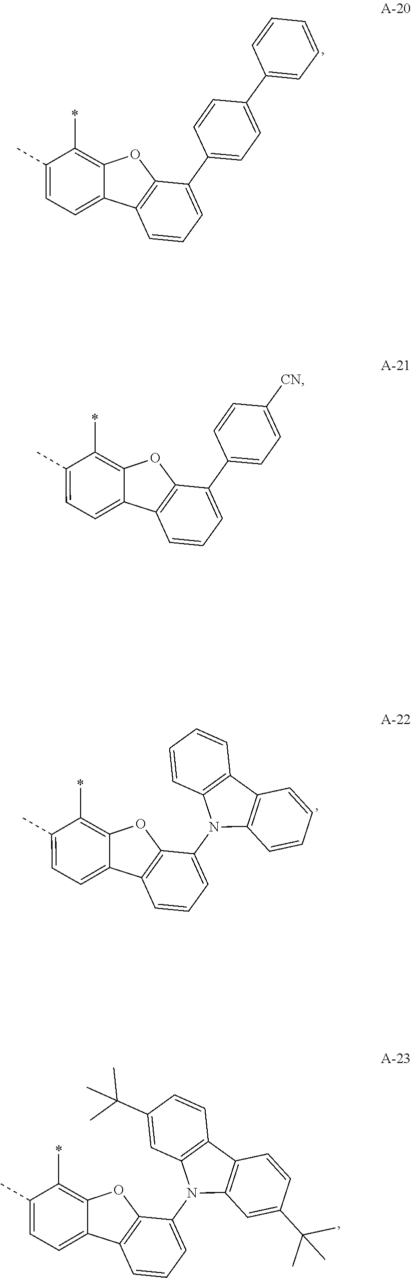 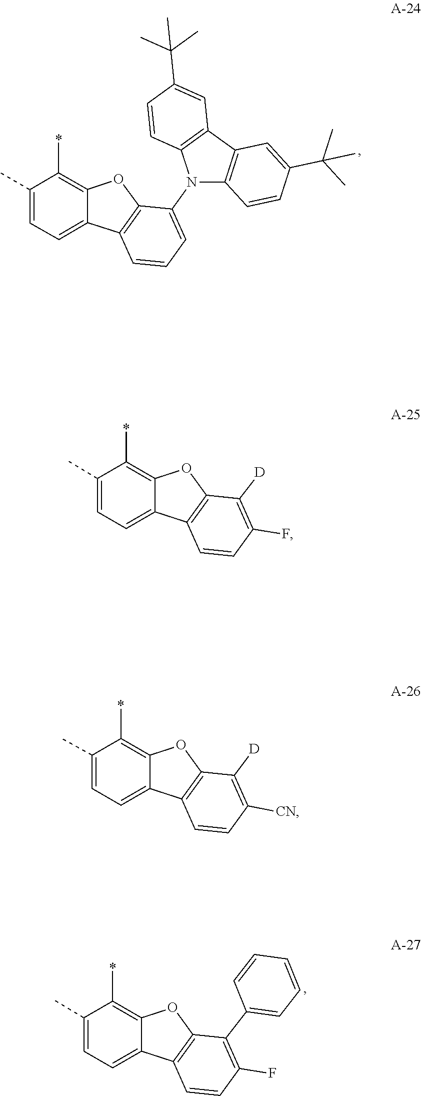 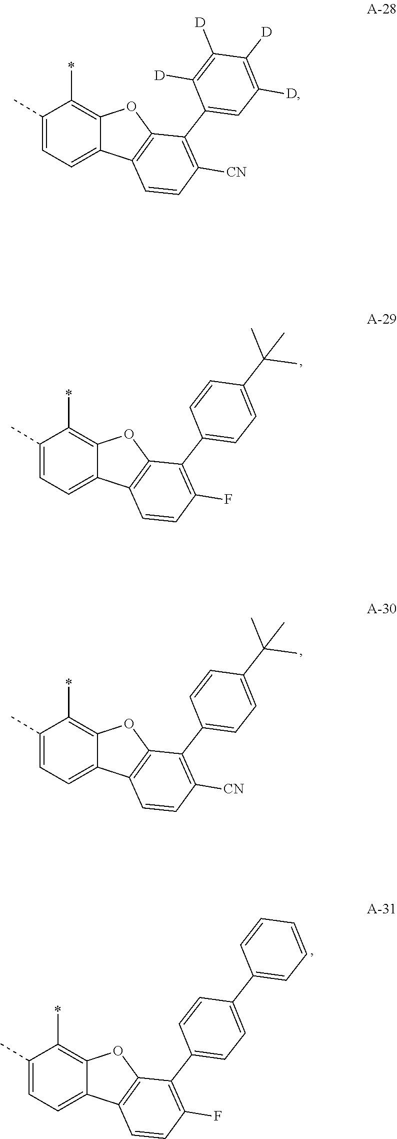 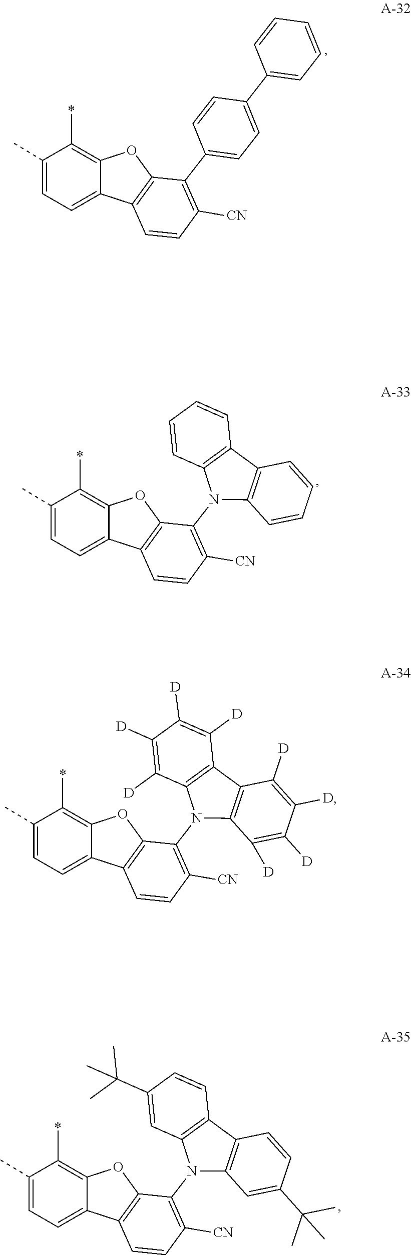 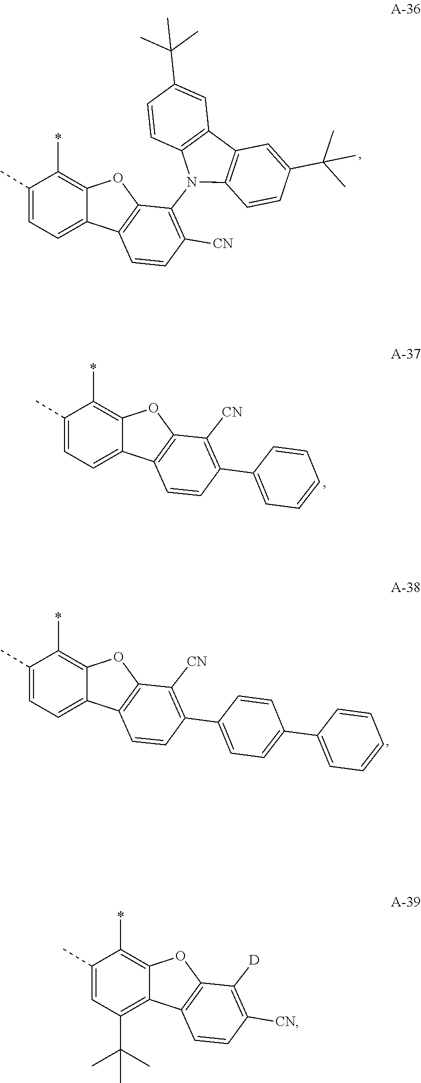 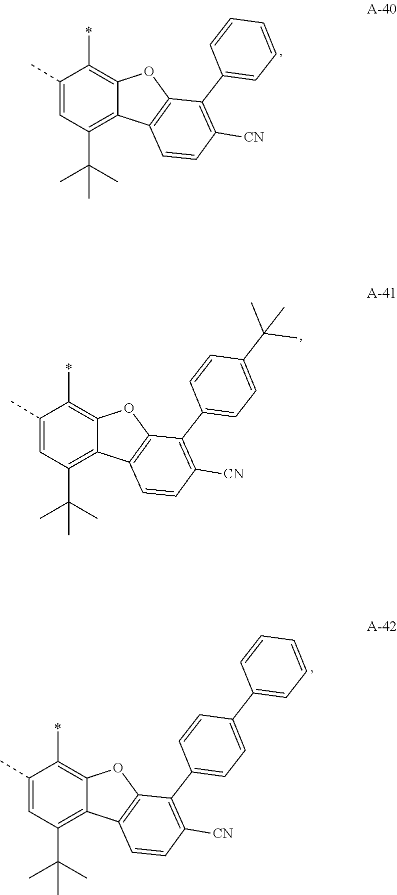 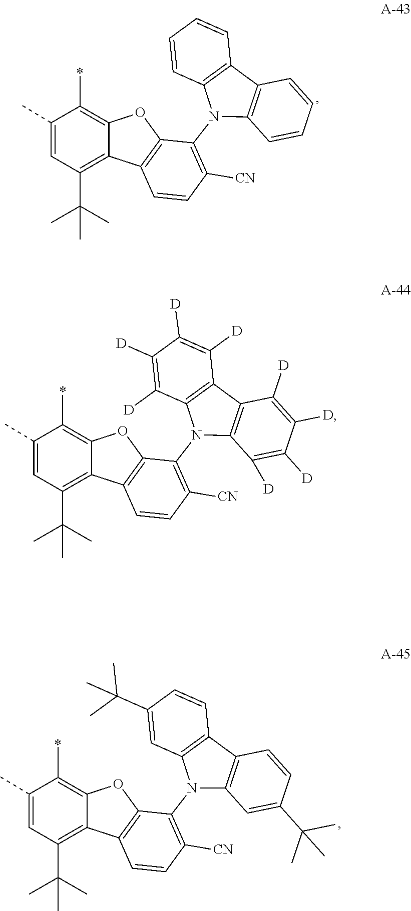 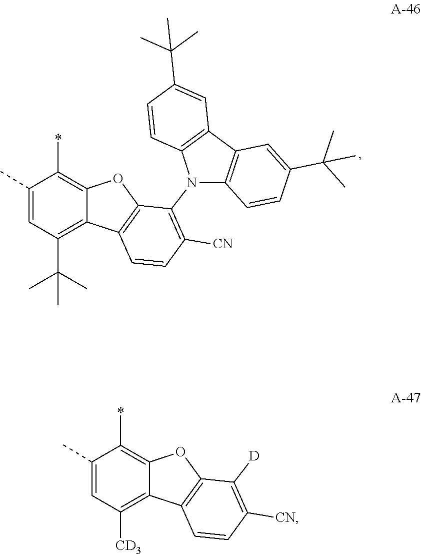 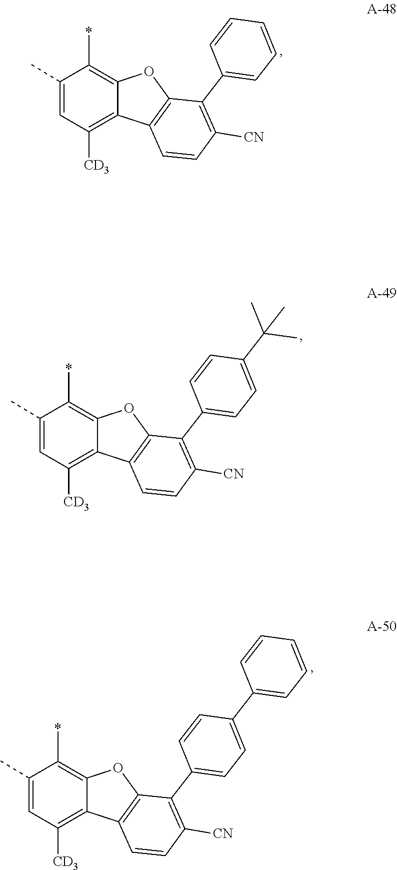 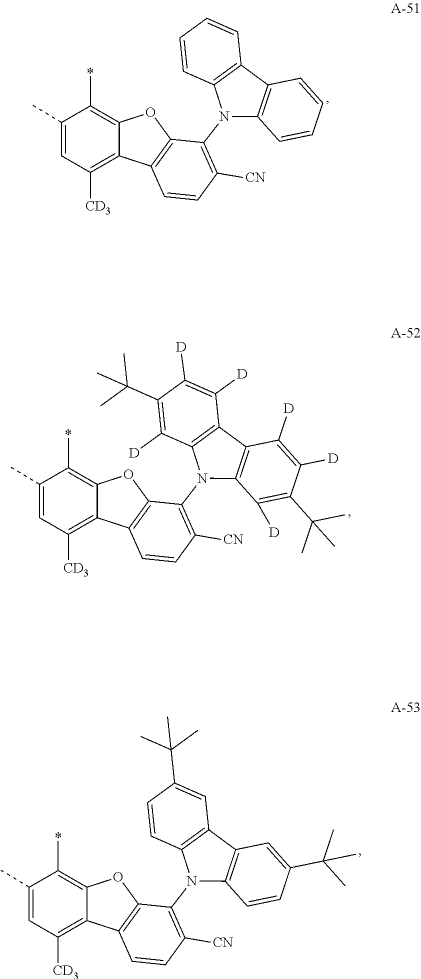 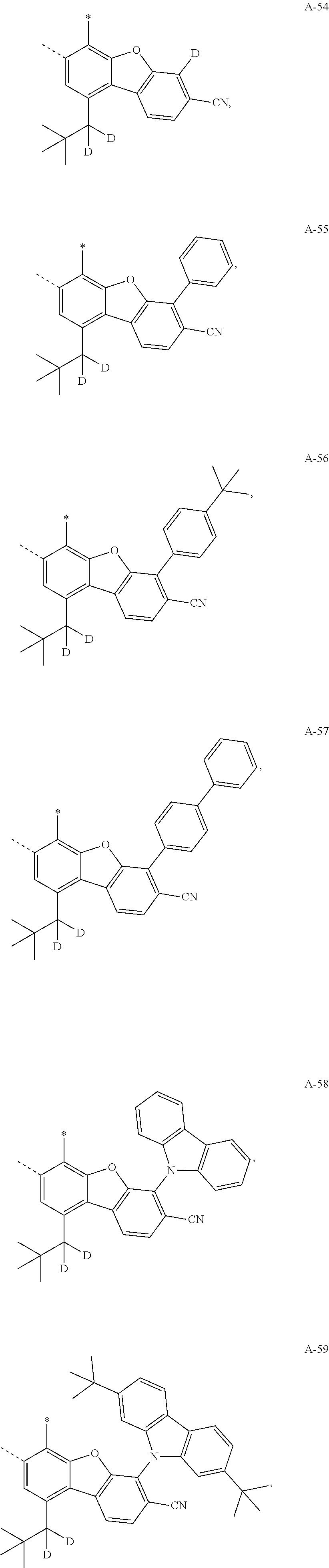 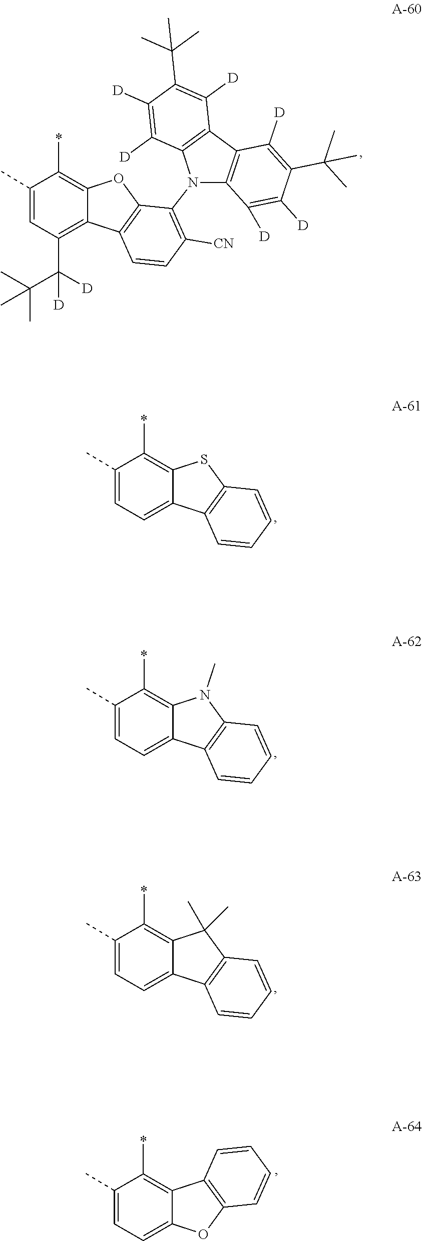 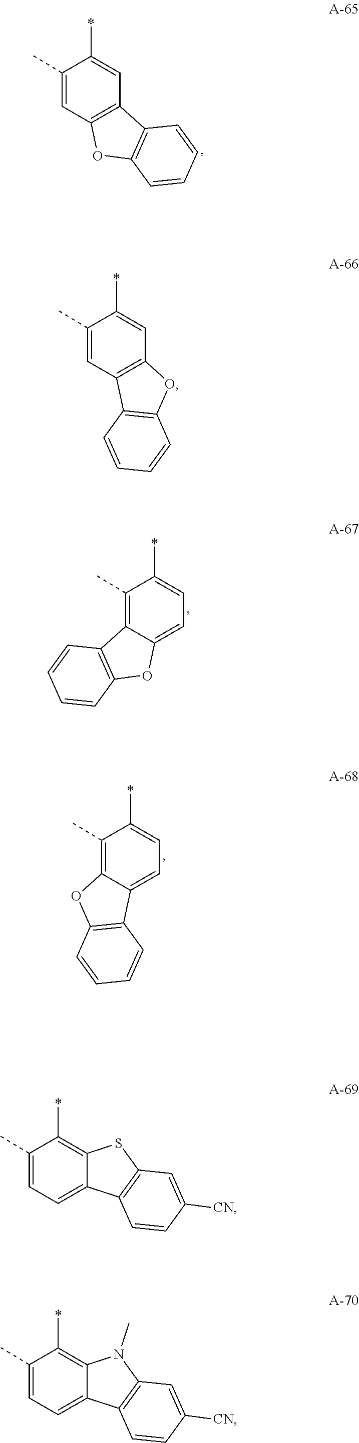 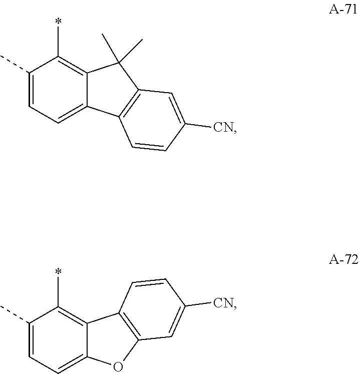 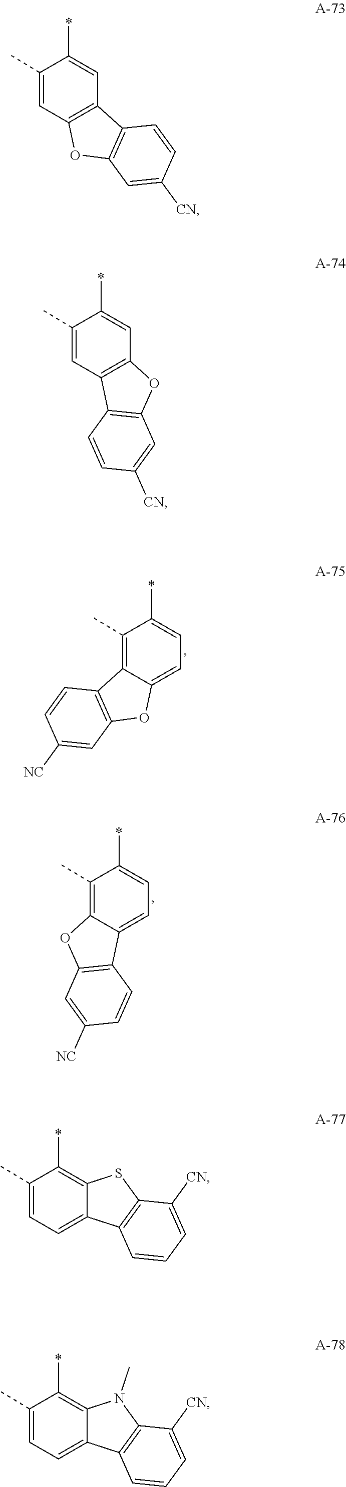 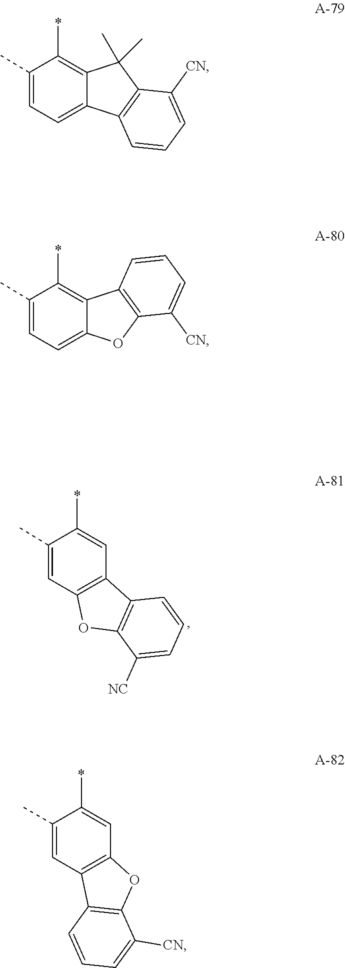 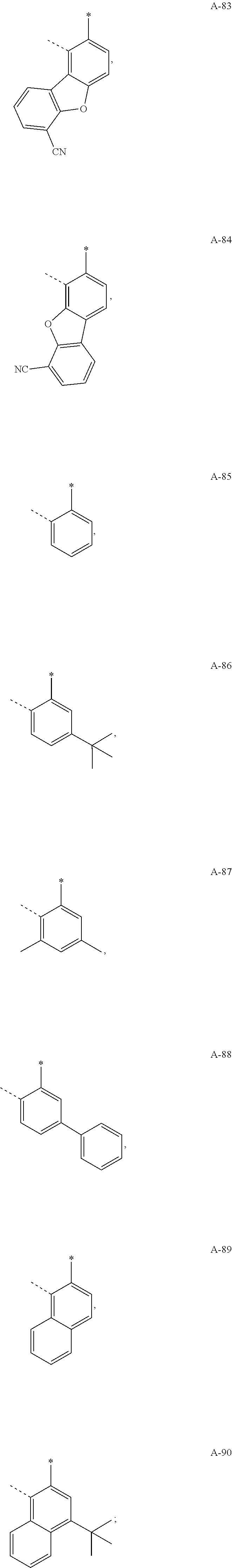
wherein “*” represents a position where an imidazole ring fragment or a pyridine ring fragment is joined;
wherein optionally, hydrogen in Lₐ₁ to Lₐ₂₈₇₄ can be partially or fully substituted with deuterium.

13. The organic electroluminescent device of claim 12, wherein L_{b} is, at each occurrence identically or differently, selected from the group consisting of: 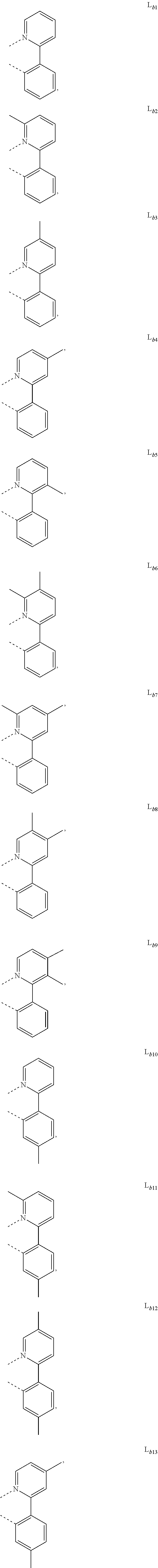 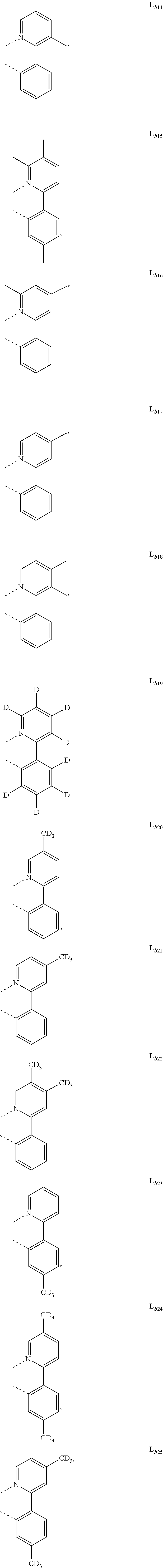 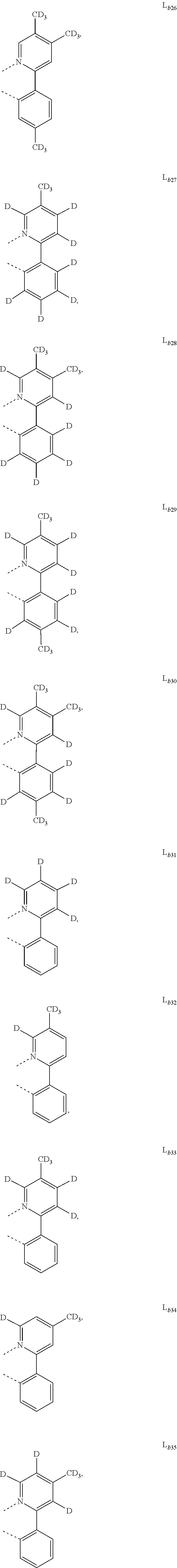 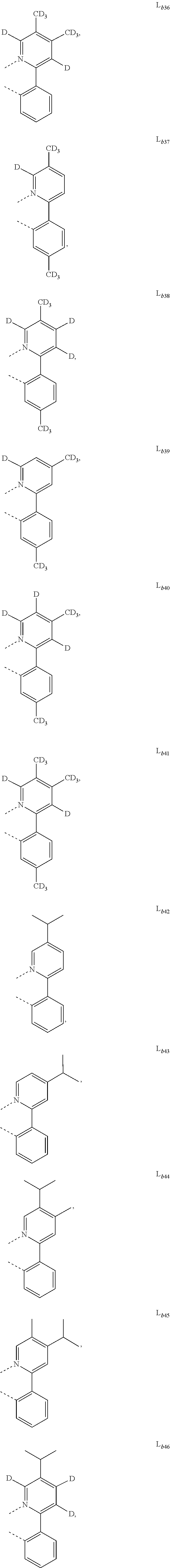 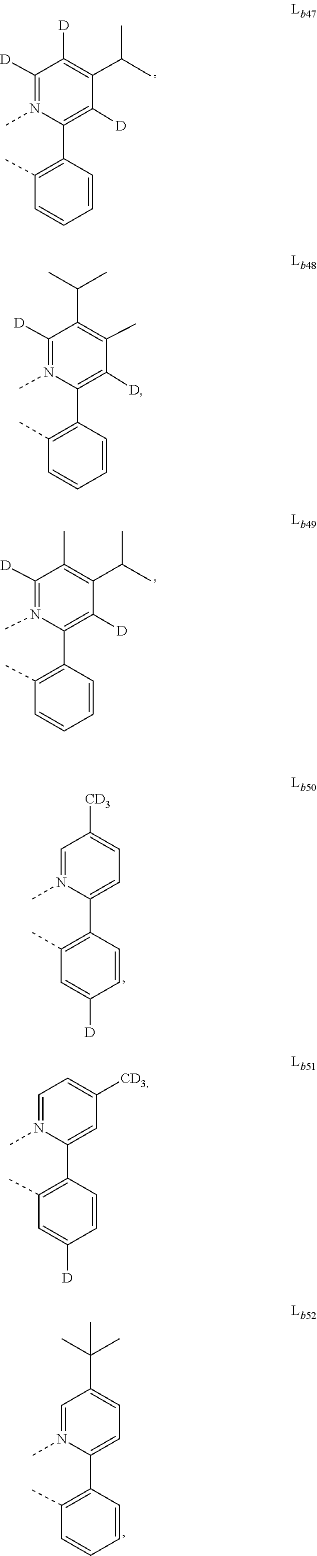 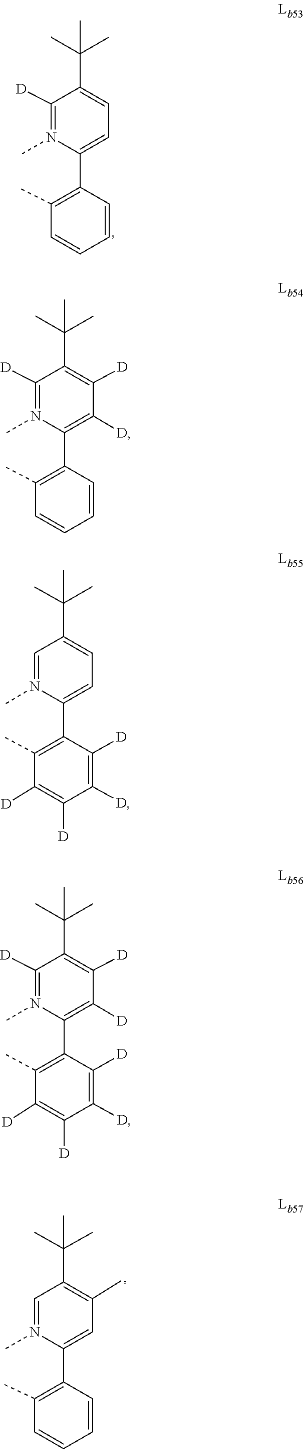 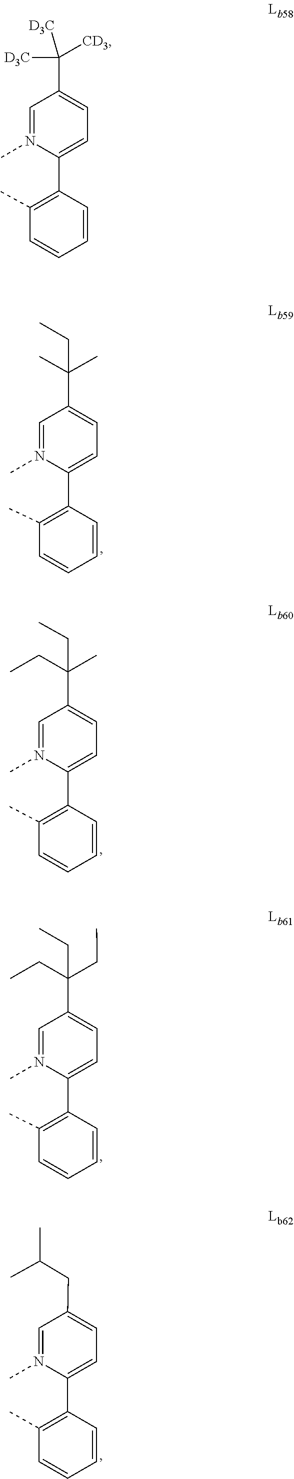 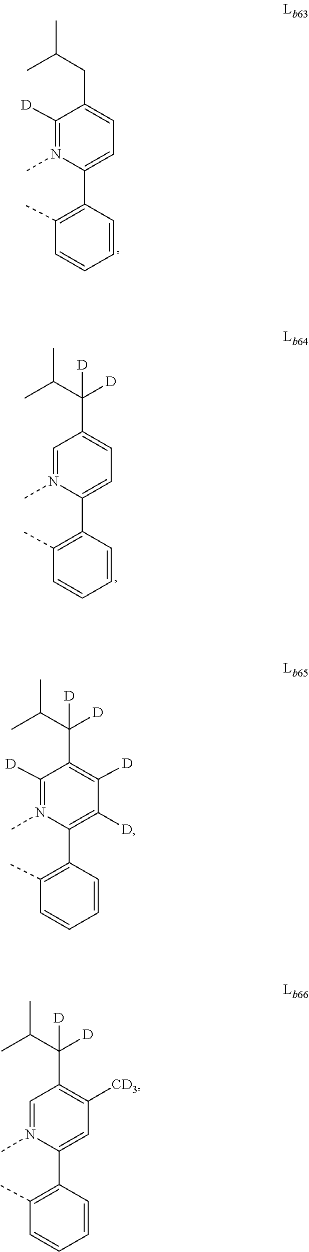 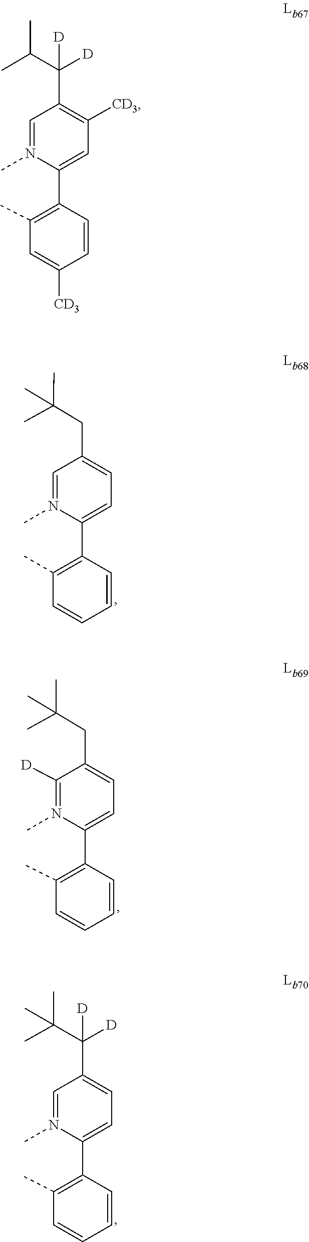 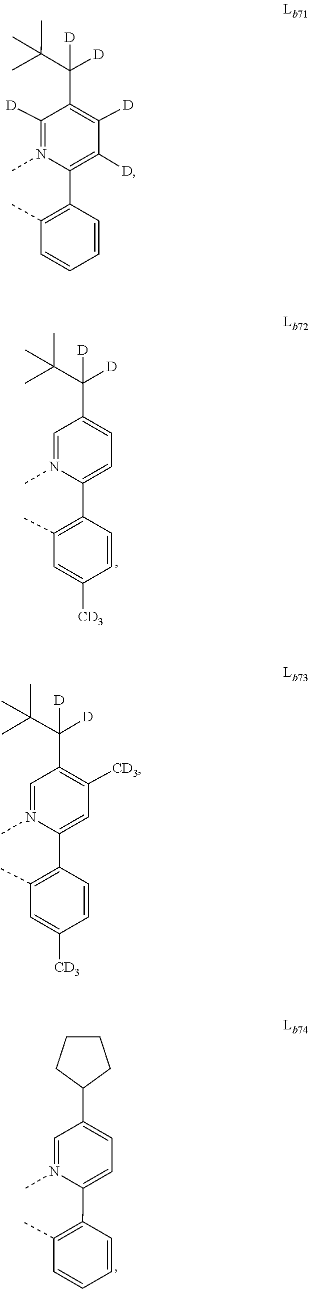 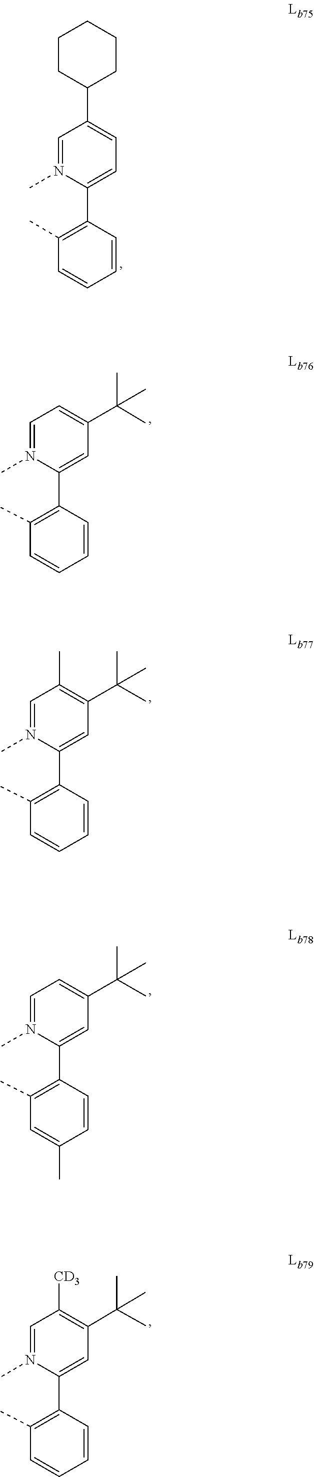 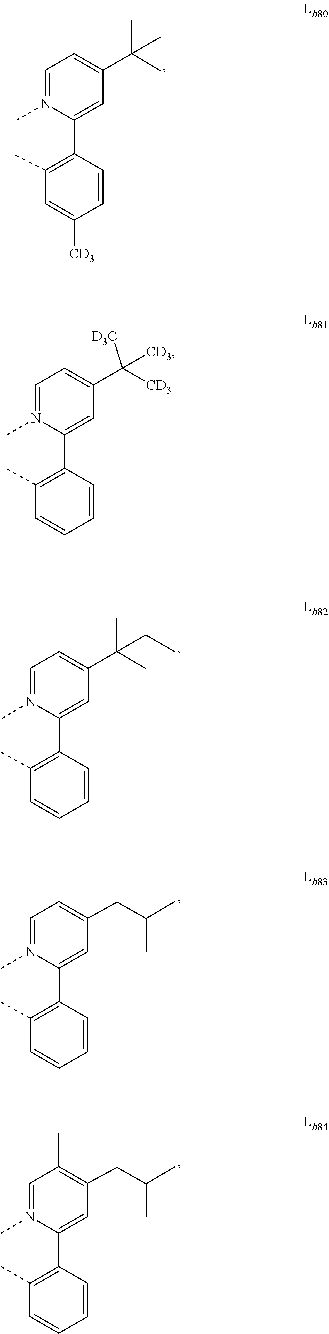 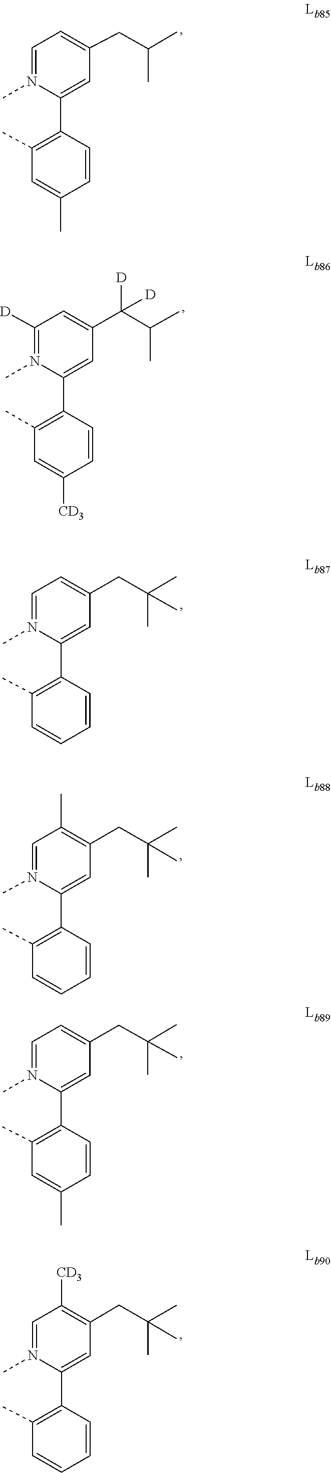 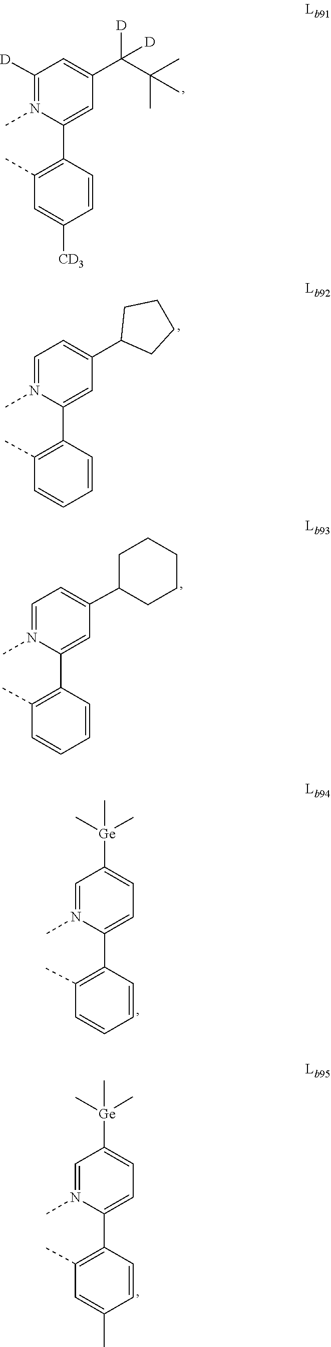 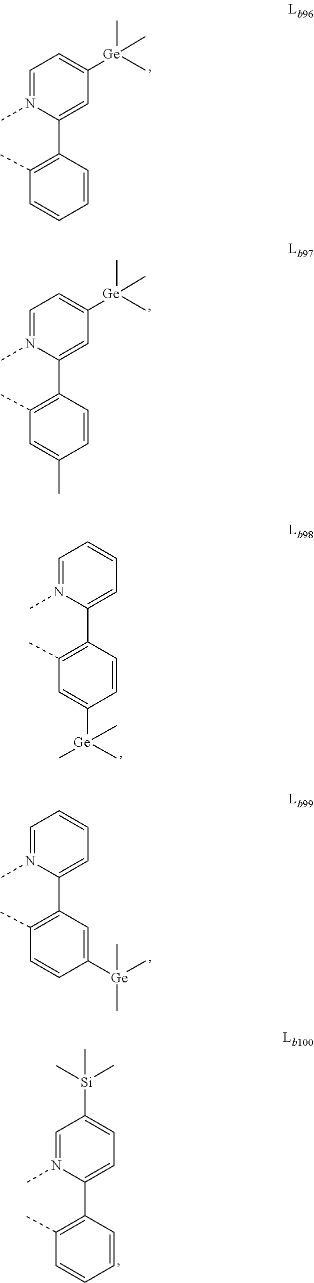 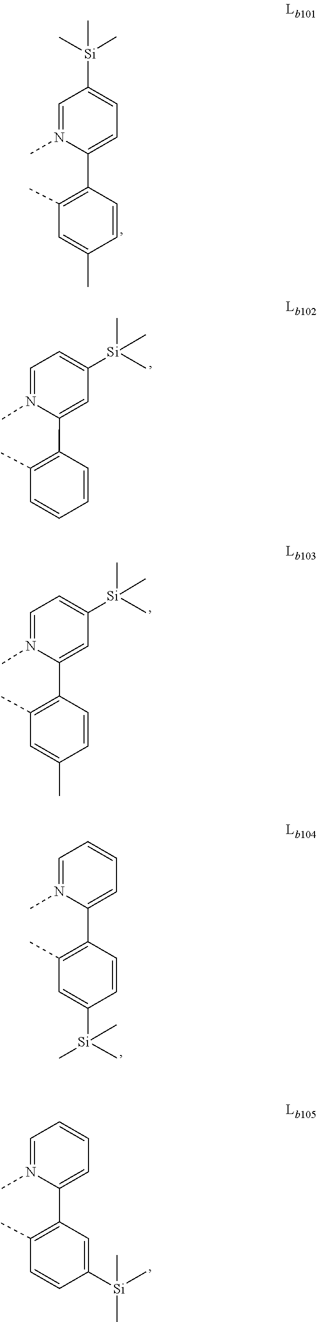 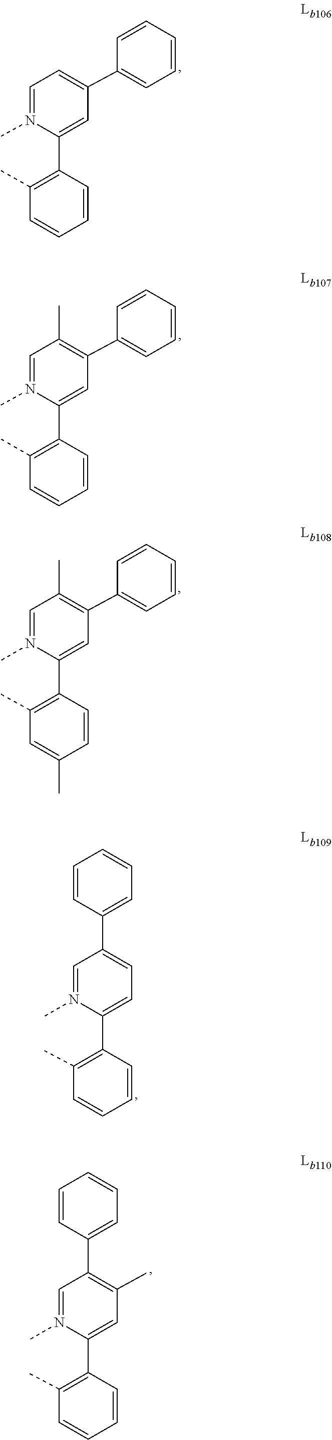 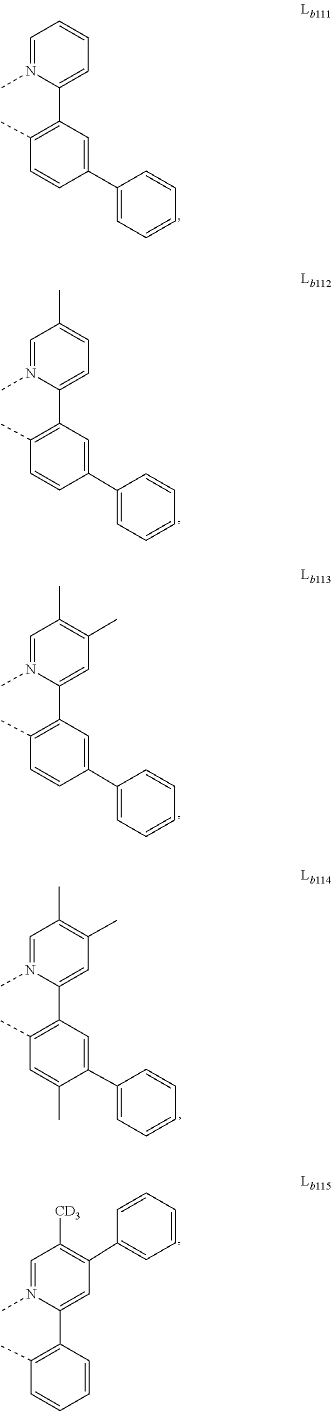 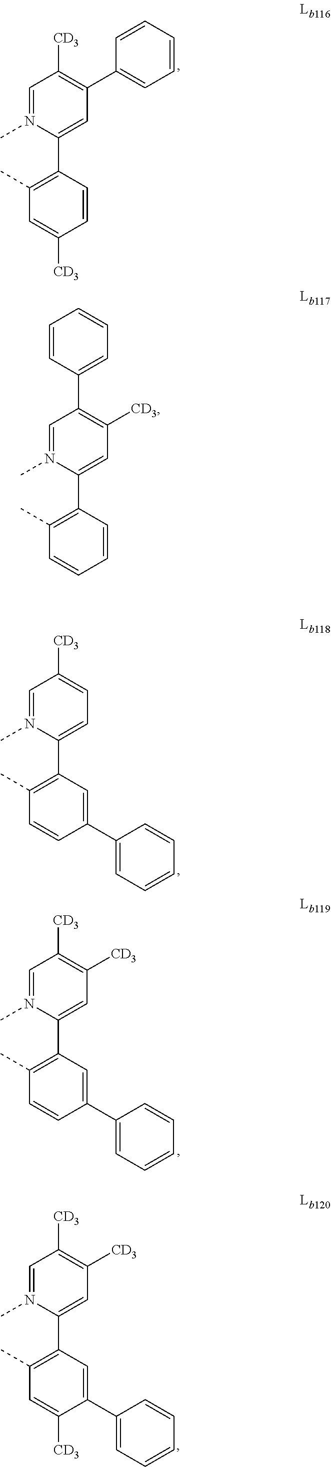 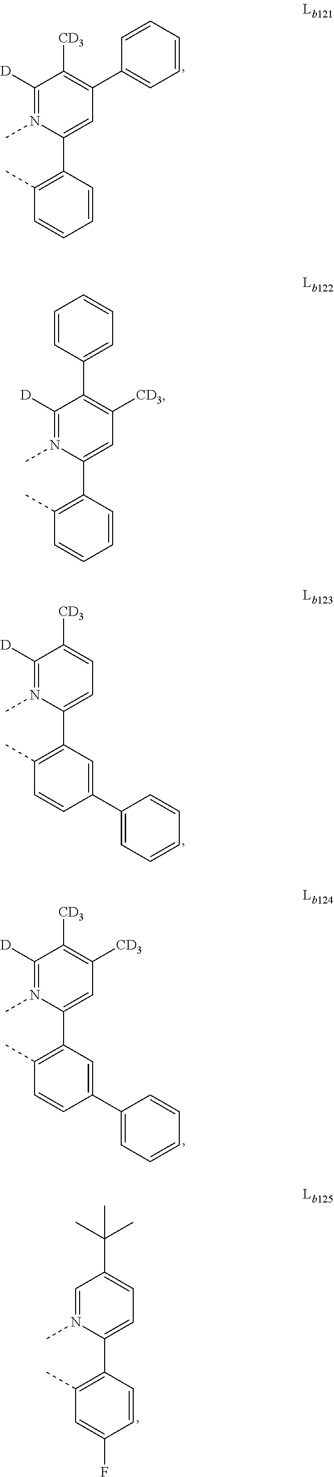 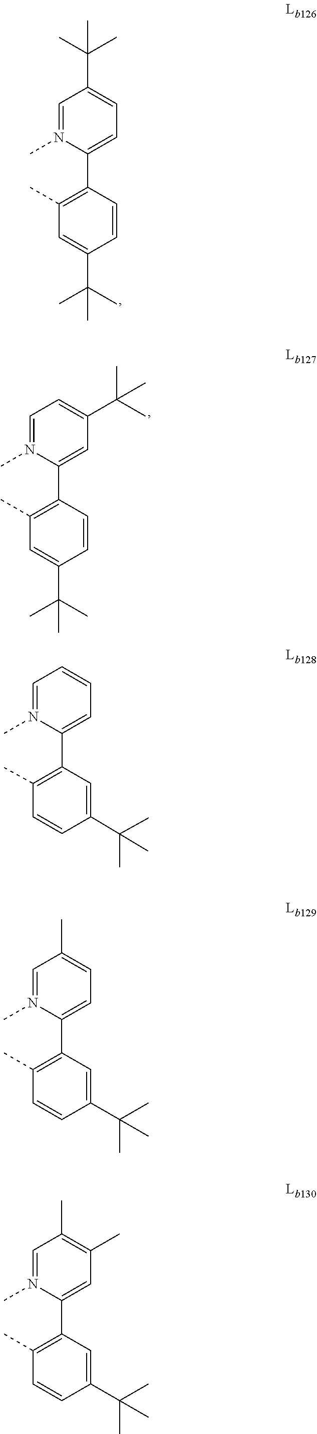 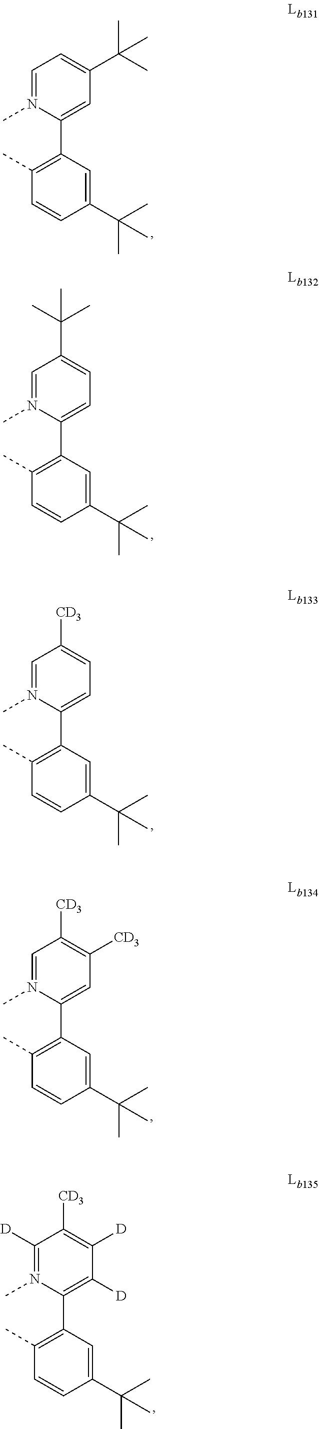 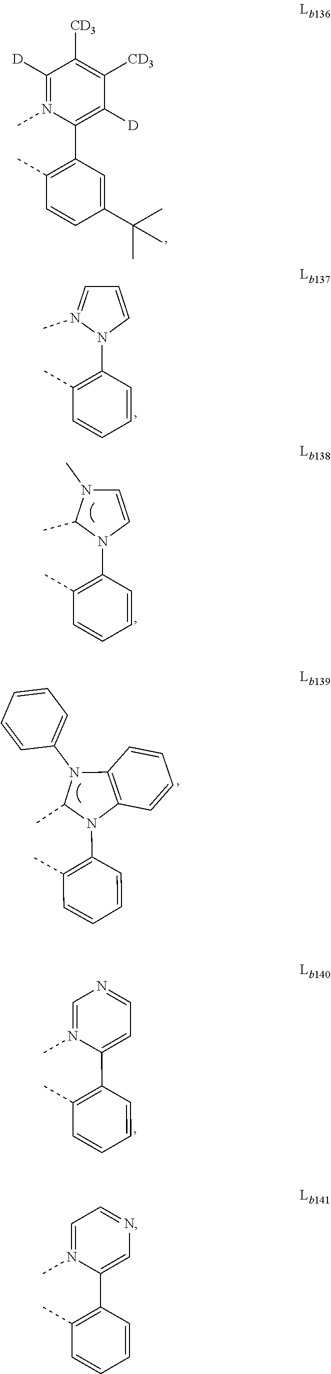 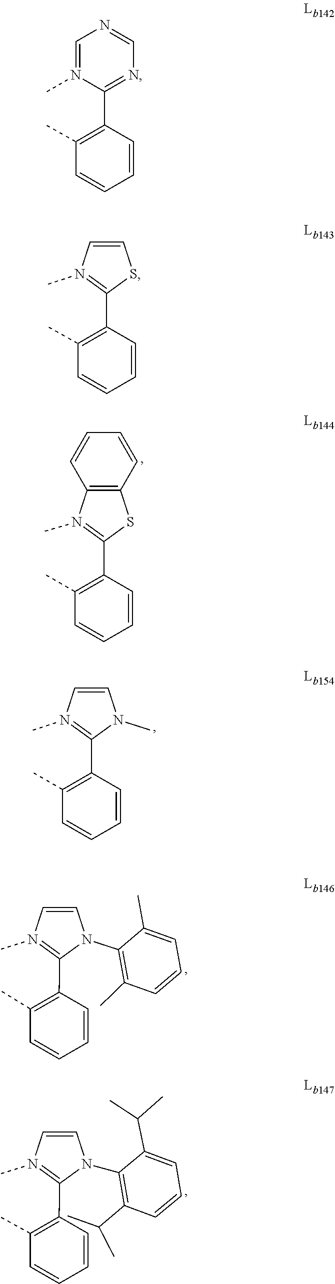 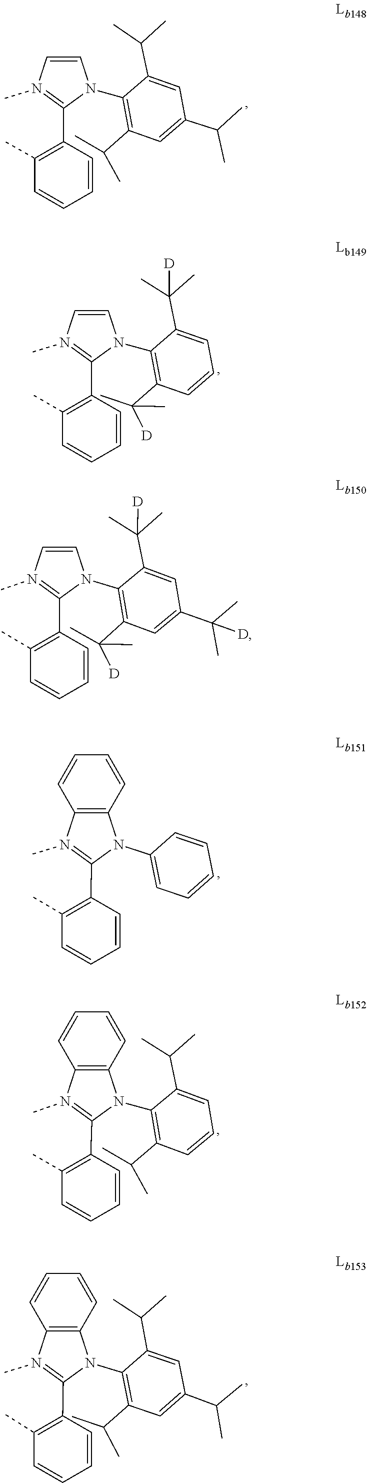 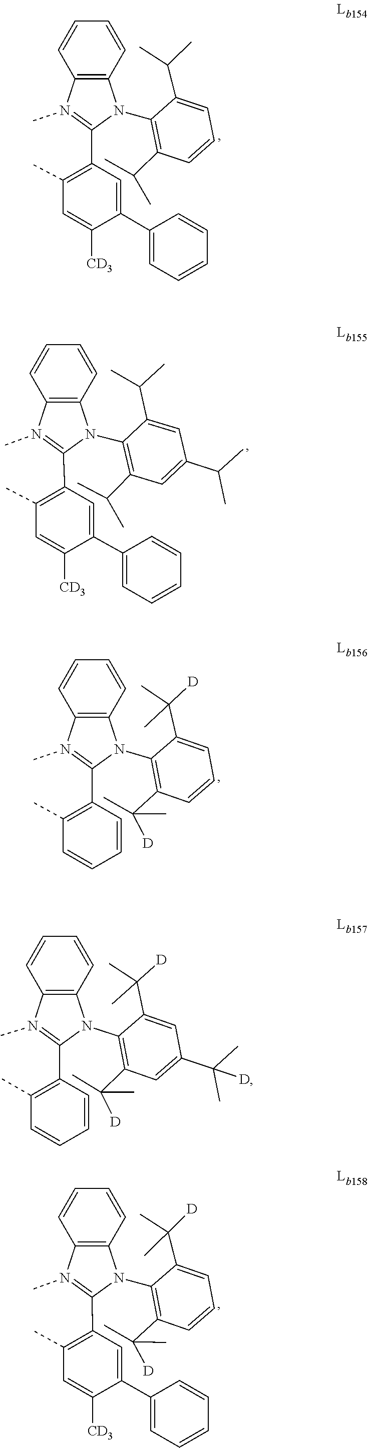 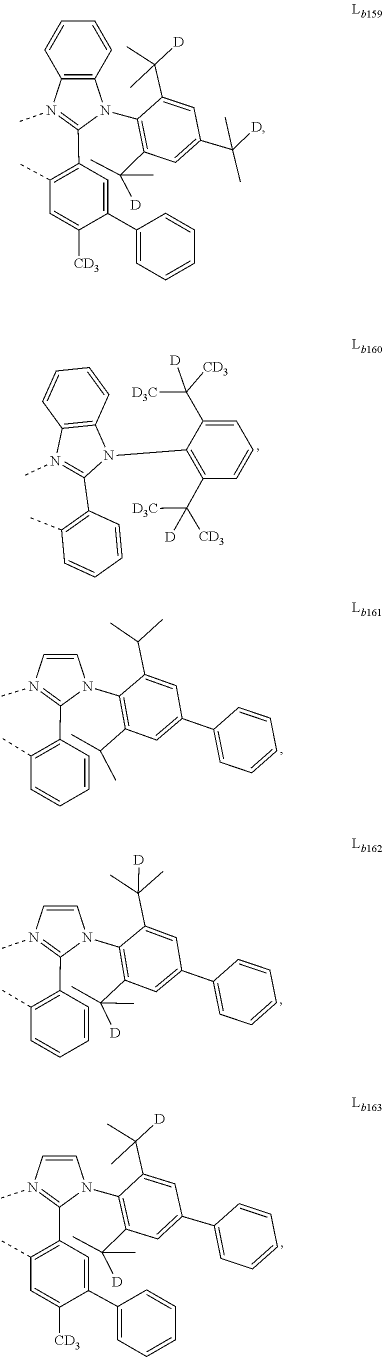 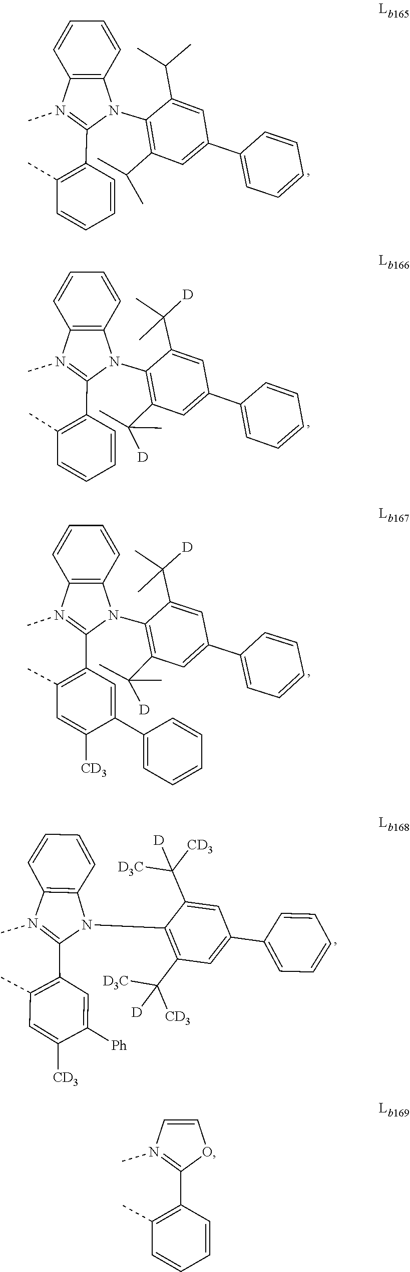 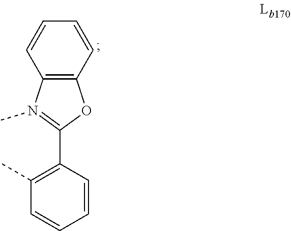
wherein optionally, hydrogen in L_{b1} to L_{b18}, L_{b20} to L_{b26} and L_{b31} to L_{b170} can be partially or fully substituted with deuterium;
wherein preferably, L_{c} is, at each occurrence identically or differently, selected from the group consisting of:

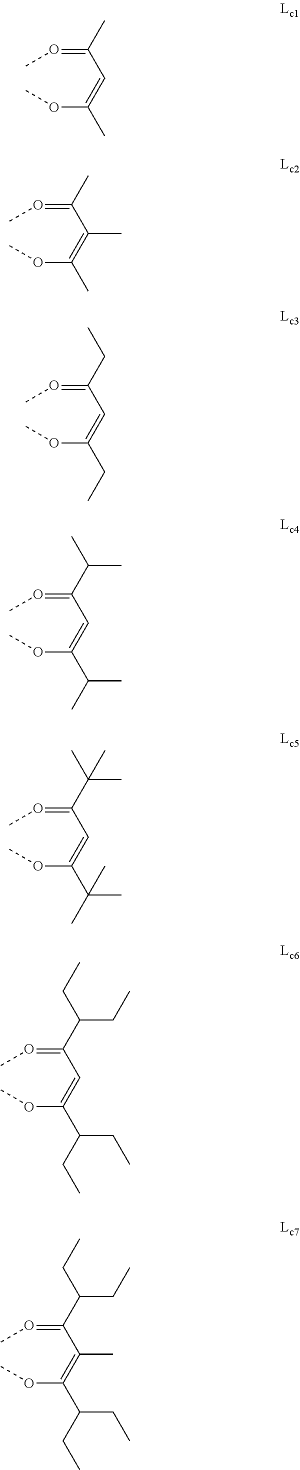

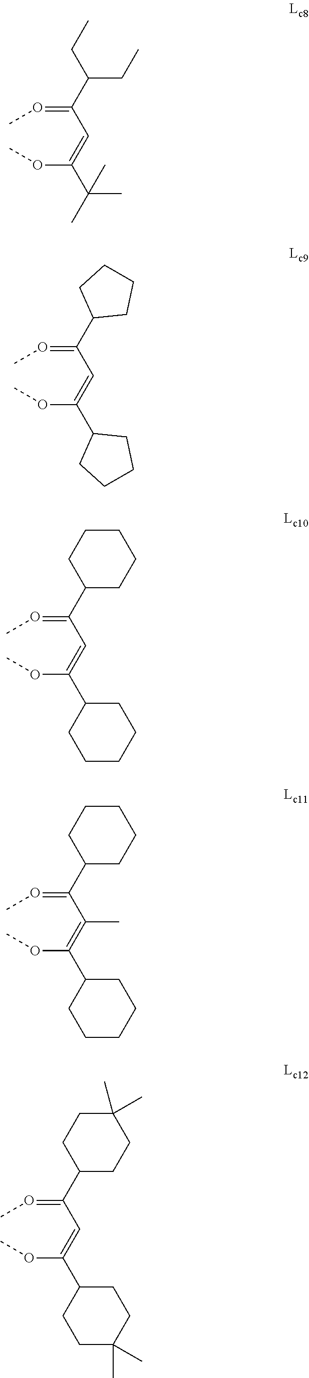

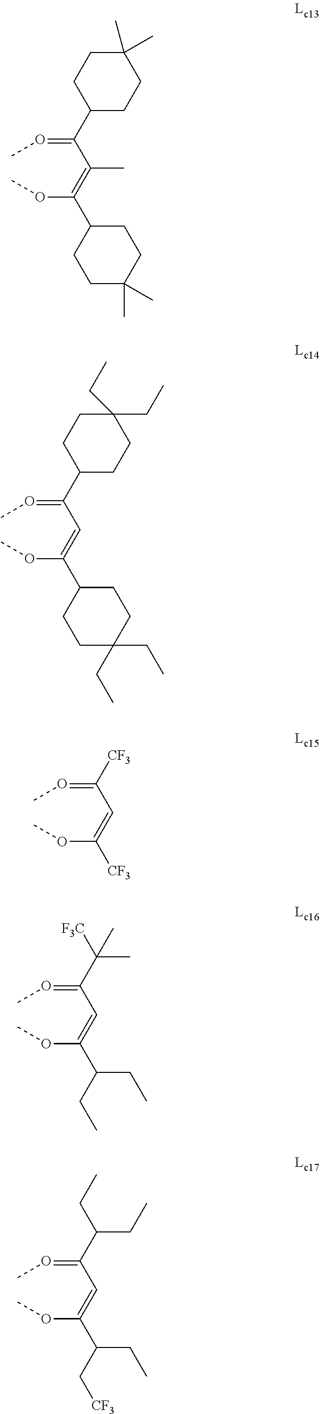

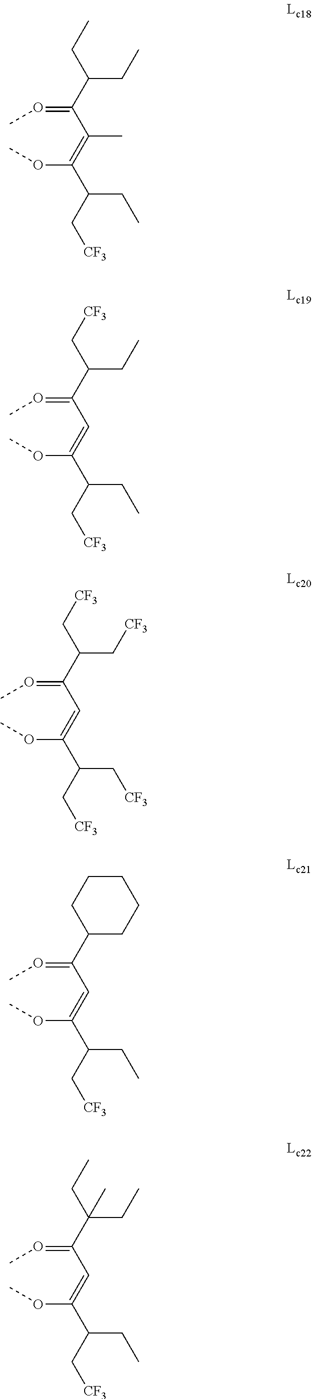

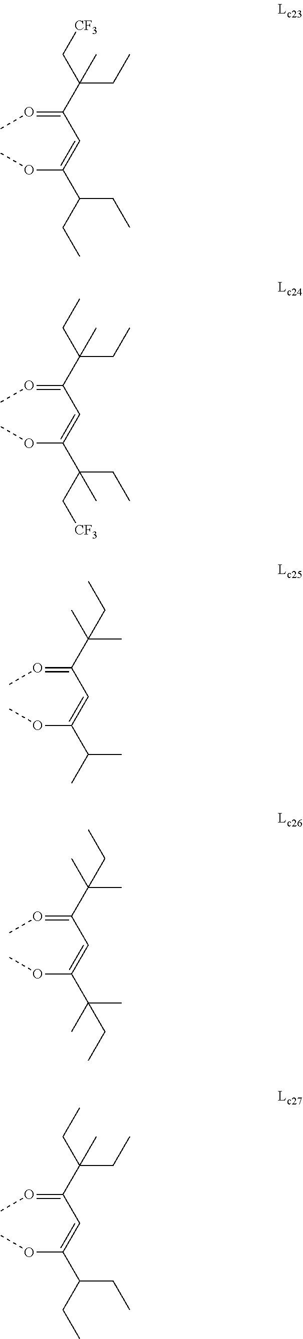

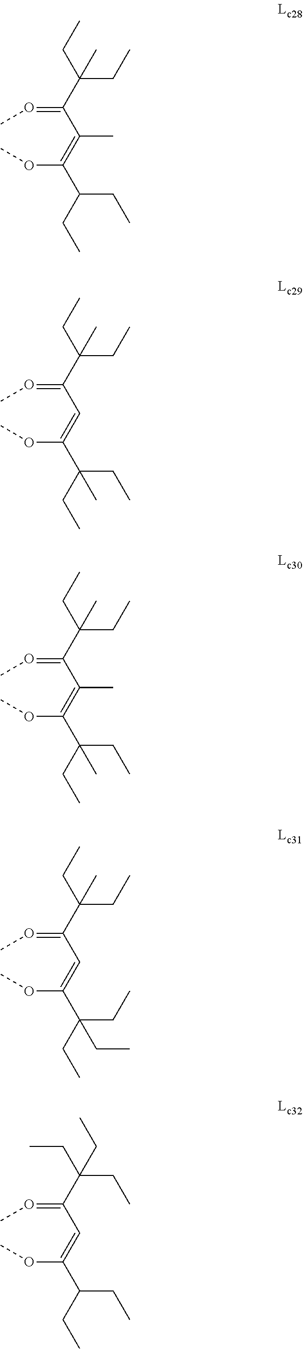

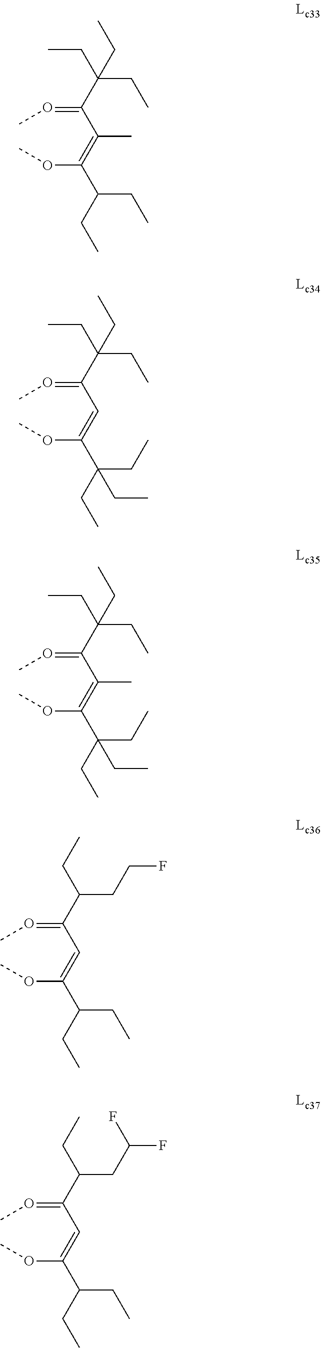

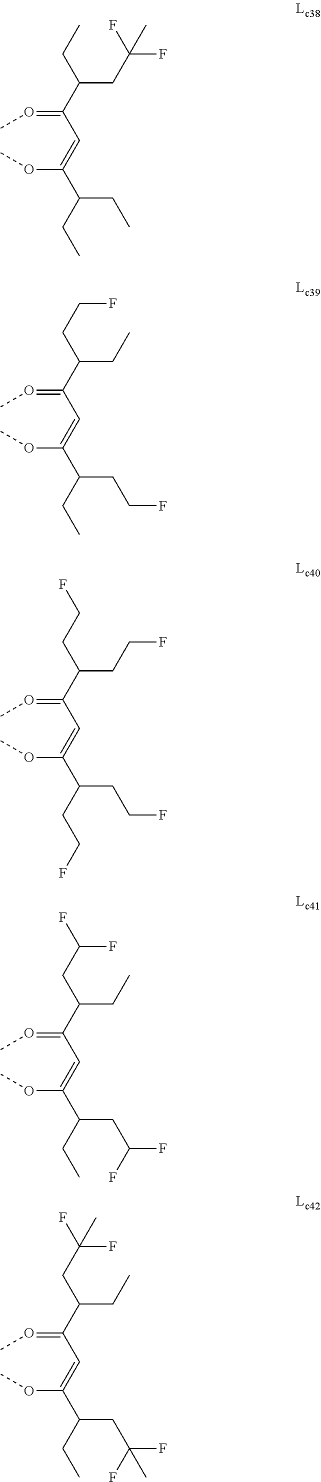

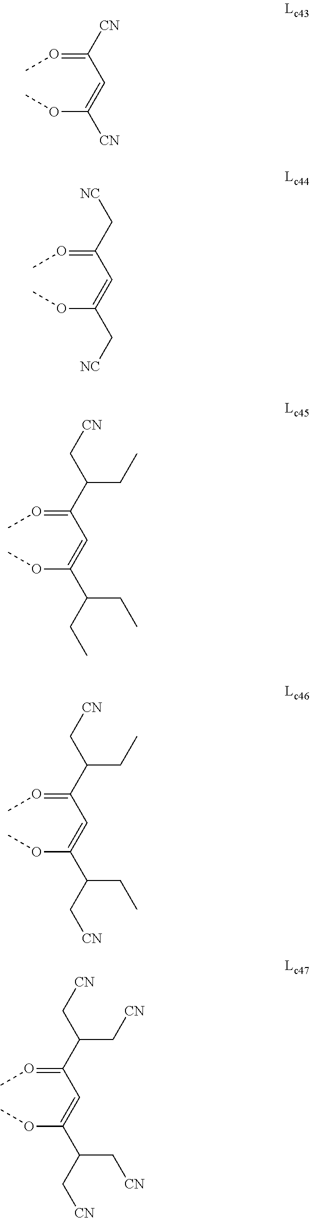

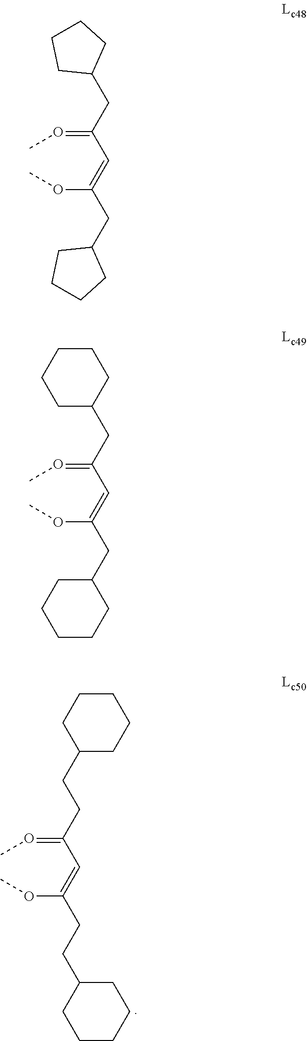

14. The organic electroluminescent device of claim 13, wherein the metal complex has a structure of Ir(Lₐ)(L_{b})₂, wherein the two L_{b} are the same or different, Lₐ is, at each occurrence identically or differently, selected from any one of the group consisting of Lₐ₁ to Lₐ₂₅₆₈, and L_{b} is, at each occurrence identically or differently, selected from any two of the group consisting of L_{b1} to L_{b170};
preferably, the metal complex is selected from the group consisting of Metal Complex 1 to Metal Complex 2530, and Metal Complex 1 to Metal Complex 2520 each have a structure of Ir(Lₐ)(L_{b})₂, wherein the two L_{b} are the same, and Lₐ and L_{b} correspond to the structures in the following table, respectively:

| Metal Complex | Lₐ | L_{b} | Metal Complex | Lₐ | L_{b} |
|---|---|---|---|---|---|
| 1 | Lₐ₁ | L_{b52} | 2 | Lₐ₂ | L_{b52} |
| 3 | Lₐ₃ | L_{b52} | 4 | Lₐ₄ | L_{b52} |
| 5 | Lₐ₅ | L_{b52} | 6 | Lₐ₆ | L_{b52} |
| 7 | Lₐ₇ | L_{b52} | 8 | Lₐ₈ | L_{b52} |
| 9 | Lₐ₉ | L_{b52} | 10 | Lₐ₁₀ | L_{b52} |
| 11 | Lₐ₁₁ | L_{b52} | 12 | Lₐ₁₂ | L_{b52} |
| 13 | Lₐ₁₃ | L_{b52} | 14 | Lₐ₁₄ | L_{b52} |
| 15 | Lₐ₁₅ | L_{b52} | 16 | Lₐ₁₆ | L_{b52} |
| 17 | Lₐ₁₇ | L_{b52} | 18 | Lₐ₁₈ | L_{b52} |
| 19 | Lₐ₁₉ | L_{b52} | 20 | Lₐ₂₀ | L_{b52} |
| 21 | Lₐ₂₁ | L_{b52} | 22 | Lₐ₂₂ | L_{b52} |
| 23 | Lₐ₂₃ | L_{b52} | 24 | Lₐ₂₄ | L_{b52} |
| 25 | Lₐ₂₅ | L_{b52} | 26 | Lₐ₂₆ | L_{b52} |
| 27 | Lₐ₂₇ | L_{b52} | 28 | Lₐ₂₈ | L_{b52} |
| 29 | Lₐ₂₉ | L_{b52} | 30 | Lₐ₃₀ | L_{b52} |
| 31 | Lₐ₃₁ | L_{b52} | 32 | Lₐ₃₂ | L_{b52} |
| 33 | Lₐ₃₃ | L_{b52} | 34 | Lₐ₃₄ | L_{b52} |
| 35 | Lₐ₃₅ | L_{b52} | 36 | Lₐ₃₆ | L_{b52} |
| 37 | Lₐ₃₇ | L_{b52} | 38 | Lₐ₃₈ | L_{b52} |
| 39 | Lₐ₃₉ | L_{b52} | 40 | Lₐ₄₀ | L_{b52} |
| 41 | Lₐ₄₁ | L_{b52} | 42 | Lₐ₄₂ | L_{b52} |
| 43 | Lₐ₄₃ | L_{b52} | 44 | Lₐ₄₄ | L_{b52} |
| 45 | Lₐ₄₅ | L_{b52} | 46 | Lₐ₄₆ | L_{b52} |
| 47 | Lₐ₄₇ | L_{b52} | 48 | Lₐ₄₈ | L_{b52} |
| 49 | Lₐ₄₉ | L_{b52} | 50 | Lₐ₅₀ | L_{b52} |
| 51 | Lₐ₅₁ | L_{b52} | 52 | Lₐ₅₂ | L_{b52} |
| 53 | Lₐ₅₃ | L_{b52} | 54 | Lₐ₅₄ | L_{b52} |
| 55 | Lₐ₅₅ | L_{b52} | 56 | Lₐ₅₆ | L_{b52} |
| 57 | Lₐ₅₇ | L_{b52} | 58 | Lₐ₅₈ | L_{b52} |
| 59 | Lₐ₅₉ | L_{b52} | 60 | Lₐ₆₀ | L_{b52} |
| 61 | Lₐ₆₁ | L_{b52} | 62 | Lₐ₆₂ | L_{b52} |
| 63 | Lₐ₆₃ | L_{b52} | 64 | Lₐ₆₄ | L_{b52} |
| 65 | Lₐ₆₅ | L_{b52} | 66 | Lₐ₆₆ | L_{b52} |
| 67 | Lₐ₆₇ | L_{b52} | 68 | Lₐ₆₈ | L_{b52} |
| 69 | Lₐ₆₉ | L_{b52} | 70 | Lₐ₇₀ | L_{b52} |
| 71 | Lₐ₇₁ | L_{b52} | 72 | Lₐ₇₂ | L_{b52} |
| 73 | Lₐ₇₃ | L_{b52} | 74 | Lₐ₇₄ | L_{b52} |
| 75 | Lₐ₇₅ | L_{b52} | 76 | Lₐ₇₆ | L_{b52} |
| 77 | Lₐ₇₇ | L_{b52} | 78 | Lₐ₇₈ | L_{b52} |
| 79 | Lₐ₇₉ | L_{b52} | 80 | Lₐ₈₀ | L_{b52} |
| 81 | Lₐ₈₁ | L_{b52} | 82 | Lₐ₈₂ | L_{b52} |
| 83 | Lₐ₈₃ | L_{b52} | 84 | Lₐ₈₄ | L_{b52} |
| 85 | Lₐ₈₅ | L_{b52} | 86 | Lₐ₈₆ | L_{b52} |
| 87 | Lₐ₈₇ | L_{b52} | 88 | Lₐ₈₈ | L_{b52} |
| 89 | Lₐ₈₉ | L_{b52} | 90 | Lₐ₉₀ | L_{b52} |
| 91 | Lₐ₁₈₁ | L_{b52} | 92 | Lₐ₁₈₂ | L_{b52} |
| 93 | Lₐ₁₈₃ | L_{b52} | 94 | Lₐ₁₈₄ | L_{b52} |
| 95 | Lₐ₁₈₅ | L_{b52} | 96 | Lₐ₁₈₆ | L_{b52} |
| 97 | Lₐ₁₈₇ | L_{b52} | 98 | Lₐ₁₈₈ | L_{b52} |
| 99 | Lₐ₁₈₉ | L_{b52} | 100 | Lₐ₁₉₀ | L_{b52} |
| 101 | Lₐ₁₉₁ | L_{b52} | 102 | Lₐ₁₉₂ | L_{b52} |
| 103 | Lₐ₁₉₃ | L_{b52} | 104 | Lₐ₁₉₄ | L_{b52} |
| 105 | Lₐ₁₉₅ | L_{b52} | 106 | Lₐ₁₉₆ | L_{b52} |
| 107 | Lₐ₁₉₇ | L_{b52} | 108 | Lₐ₁₉₈ | L_{b52} |
| 109 | Lₐ₁₉₉ | L_{b52} | 110 | Lₐ₂₀₀ | L_{b52} |
| 111 | Lₐ₂₀₁ | L_{b52} | 112 | Lₐ₂₀₂ | L_{b52} |
| 113 | Lₐ₂₀₃ | L_{b52} | 114 | Lₐ₂₀₄ | L_{b52} |
| 115 | Lₐ₂₀₅ | L_{b52} | 116 | Lₐ₂₀₆ | L_{b52} |
| 117 | Lₐ₂₀₇ | L_{b52} | 118 | Lₐ₂₀₈ | L_{b52} |
| 119 | Lₐ₂₀₉ | L_{b52} | 120 | Lₐ₂₁₀ | L_{b52} |
| 121 | Lₐ₂₁₁ | L_{b52} | 122 | Lₐ₂₁₂ | L_{b52} |
| 123 | Lₐ₂₁₃ | L_{b52} | 124 | Lₐ₂₁₄ | L_{b52} |
| 125 | Lₐ₂₁₅ | L_{b52} | 126 | Lₐ₂₁₆ | L_{b52} |
| 127 | Lₐ₂₁₇ | L_{b52} | 128 | Lₐ₂₁₈ | L_{b52} |
| 129 | Lₐ₂₁₉ | L_{b52} | 130 | Lₐ₂₂₀ | L_{b52} |
| 131 | Lₐ₂₂₁ | L_{b52} | 132 | Lₐ₂₂₂ | L_{b52} |
| 133 | Lₐ₂₂₃ | L_{b52} | 134 | Lₐ₂₂₄ | L_{b52} |
| 135 | Lₐ₂₂₅ | L_{b52} | 136 | Lₐ₂₂₆ | L_{b52} |
| 137 | Lₐ₂₂₇ | L_{b52} | 138 | Lₐ₂₂₈ | L_{b52} |
| 139 | Lₐ₂₂₉ | L_{b52} | 140 | Lₐ₂₃₀ | L_{b52} |
| 141 | Lₐ₂₃₁ | L_{b52} | 142 | Lₐ₂₃₂ | L_{b52} |
| 143 | Lₐ₂₃₃ | L_{b52} | 144 | Lₐ₂₃₄ | L_{b52} |
| 145 | Lₐ₂₃₅ | L_{b52} | 146 | Lₐ₂₃₆ | L_{b52} |
| 147 | Lₐ₂₃₇ | L_{b52} | 148 | Lₐ₂₃₈ | L_{b52} |
| 149 | Lₐ₂₃₉ | L_{b52} | 150 | Lₐ₂₄₀ | L_{b52} |
| 151 | Lₐ₂₄₁ | L_{b52} | 152 | Lₐ₂₄₂ | L_{b52} |
| 153 | Lₐ₂₄₃ | L_{b52} | 154 | Lₐ₂₄₄ | L_{b52} |
| 155 | Lₐ₂₄₅ | L_{b52} | 156 | Lₐ₂₄₆ | L_{b52} |
| 157 | Lₐ₂₄₇ | L_{b52} | 158 | Lₐ₂₄₈ | L_{b52} |
| 159 | Lₐ₂₄₉ | L_{b52} | 160 | Lₐ₂₅₀ | L_{b52} |
| 161 | Lₐ₂₅₁ | L_{b52} | 162 | Lₐ₂₅₂ | L_{b52} |
| 163 | Lₐ₂₅₃ | L_{b52} | 164 | Lₐ₂₅₄ | L_{b52} |
| 165 | Lₐ₂₅₅ | L_{b52} | 166 | Lₐ₂₅₆ | L_{b52} |
| 167 | Lₐ₂₅₇ | L_{b52} | 168 | Lₐ₂₅₈ | L_{b52} |
| 169 | Lₐ₂₅₉ | L_{b52} | 170 | Lₐ₂₆₀ | L_{b52} |
| 171 | Lₐ₂₆₁ | L_{b52} | 172 | Lₐ₂₆₂ | L_{b52} |
| 173 | Lₐ₂₆₃ | L_{b52} | 174 | Lₐ₂₆₄ | L_{b52} |
| 175 | Lₐ₂₆₅ | L_{b52} | 176 | Lₐ₂₆₆ | L_{b52} |
| 177 | Lₐ₂₆₇ | L_{b52} | 178 | Lₐ₂₆₈ | L_{b52} |
| 179 | Lₐ₂₆₉ | L_{b52} | 180 | Lₐ₂₇₀ | L_{b52} |
| 181 | Lₐ₁₂₈₅ | L_{b52} | 182 | Lₐ₁₂₈₆ | L_{b52} |
| 183 | Lₐ₁₂₈₇ | L_{b52} | 184 | Lₐ₁₂₈₈ | L_{b52} |
| 185 | Lₐ₁₂₈₉ | L_{b52} | 186 | Lₐ₁₂₉₀ | L_{b52} |
| 187 | Lₐ₁₂₉₁ | L_{b52} | 188 | Lₐ₁₂₉₂ | L_{b52} |
| 189 | Lₐ₁₂₉₃ | L_{b52} | 190 | Lₐ₁₂₉₄ | L_{b52} |
| 191 | Lₐ₁₂₉₅ | L_{b52} | 192 | Lₐ₁₂₉₆ | L_{b52} |
| 193 | Lₐ₁₂₉₇ | L_{b52} | 194 | Lₐ₁₂₉₈ | L_{b52} |
| 195 | Lₐ₁₂₉₉ | L_{b52} | 196 | Lₐ₁₃₀₀ | L_{b52} |
| 197 | Lₐ₁₃₀₁ | L_{b52} | 198 | Lₐ₁₃₀₂ | L_{b52} |
| 199 | Lₐ₁₃₀₃ | L_{b52} | 200 | Lₐ₁₃₀₄ | L_{b52} |
| 201 | Lₐ₁₃₀₅ | L_{b52} | 202 | Lₐ₁₃₀₆ | L_{b52} |
| 203 | Lₐ₁₃₀₇ | L_{b52} | 204 | Lₐ₁₃₀₈ | L_{b52} |
| 205 | Lₐ₁₃₀₉ | L_{b52} | 206 | Lₐ₁₃₁₀ | L_{b52} |
| 207 | Lₐ₁₃₁₁ | L_{b52} | 208 | Lₐ₁₃₁₂ | L_{b52} |
| 209 | Lₐ₁₃₁₃ | L_{b52} | 210 | Lₐ₁₃₁₄ | L_{b52} |
| 211 | Lₐ₁₃₁₅ | L_{b52} | 212 | Lₐ₁₃₁₆ | L_{b52} |
| 213 | Lₐ₁₃₁₇ | L_{b52} | 214 | Lₐ₁₃₁₈ | L_{b52} |
| 215 | Lₐ₁₃₁₉ | L_{b52} | 216 | Lₐ₁₃₂₀ | L_{b52} |
| 217 | Lₐ₁₃₂₁ | L_{b52} | 218 | Lₐ₁₃₂₂ | L_{b52} |
| 219 | Lₐ₁₃₂₃ | L_{b52} | 220 | Lₐ₁₃₂₄ | L_{b52} |
| 221 | Lₐ₁₃₂₅ | L_{b52} | 222 | Lₐ₁₃₂₆ | L_{b52} |
| 223 | Lₐ₁₃₂₇ | L_{b52} | 224 | Lₐ₁₃₂₈ | L_{b52} |
| 225 | Lₐ₁₃₂₉ | L_{b52} | 226 | Lₐ₁₃₃₀ | L_{b52} |
| 227 | Lₐ₁₃₃₁ | L_{b52} | 228 | Lₐ₁₃₃₂ | L_{b52} |
| 229 | Lₐ₁₃₃₃ | L_{b52} | 230 | Lₐ₁₃₃₄ | L_{b52} |
| 231 | Lₐ₁₃₃₅ | L_{b52} | 232 | Lₐ₁₃₃₆ | L_{b52} |
| 233 | Lₐ₁₃₃₇ | L_{b52} | 234 | Lₐ₁₃₃₈ | L_{b52} |
| 235 | Lₐ₁₃₃₉ | L_{b52} | 236 | Lₐ₁₃₄₀ | L_{b52} |
| 237 | Lₐ₁₃₄₁ | L_{b52} | 238 | Lₐ₁₃₄₂ | L_{b52} |
| 239 | Lₐ₁₃₄₃ | L_{b52} | 240 | Lₐ₁₃₄₄ | L_{b52} |
| 241 | Lₐ₁₃₄₅ | L_{b52} | 242 | Lₐ₁₃₄₆ | L_{b52} |
| 243 | Lₐ₁₃₄₇ | L_{b52} | 244 | Lₐ₁₃₄₈ | L_{b52} |
| 245 | Lₐ₁₃₄₉ | L_{b52} | 246 | Lₐ₁₃₅₀ | L_{b52} |
| 247 | Lₐ₁₃₅₁ | L_{b52} | 248 | Lₐ₁₃₅₂ | L_{b52} |
| 249 | Lₐ₁₃₅₃ | L_{b52} | 250 | Lₐ₁₃₅₄ | L_{b52} |
| 251 | Lₐ₁₃₅₅ | L_{b52} | 252 | Lₐ₁₃₅₆ | L_{b52} |
| 253 | Lₐ₁₃₅₇ | L_{b52} | 254 | Lₐ₁₃₅₈ | L_{b52} |
| 255 | Lₐ₁₃₅₉ | L_{b52} | 256 | Lₐ₁₃₆₀ | L_{b52} |
| 257 | Lₐ₁₃₆₁ | L_{b52} | 258 | Lₐ₁₃₆₂ | L_{b52} |
| 259 | Lₐ₁₃₆₃ | L_{b52} | 260 | Lₐ₁₃₆₄ | L_{b52} |
| 261 | Lₐ₁₃₆₅ | L_{b52} | 262 | Lₐ₁₃₆₆ | L_{b52} |
| 263 | Lₐ₁₃₆₇ | L_{b52} | 264 | Lₐ₁₃₆₈ | L_{b52} |
| 265 | Lₐ₁₃₆₉ | L_{b52} | 266 | Lₐ₁₃₇₀ | L_{b52} |
| 267 | Lₐ₁₃₇₁ | L_{b52} | 268 | Lₐ₁₃₇₂ | L_{b52} |
| 269 | Lₐ₁₃₇₃ | L_{b52} | 270 | Lₐ₁₃₇₄ | L_{b52} |
| 271 | Lₐ₁₄₆₅ | L_{b52} | 272 | Lₐ₁₄₆₆ | L_{b52} |
| 273 | Lₐ₁₄₆₇ | L_{b52} | 274 | Lₐ₁₄₆₈ | L_{b52} |
| 275 | Lₐ₁₄₆₉ | L_{b52} | 276 | Lₐ₁₄₇₀ | L_{b52} |
| 277 | Lₐ₁₄₇₁ | L_{b52} | 278 | Lₐ₁₄₇₂ | L_{b52} |
| 279 | Lₐ₁₄₇₃ | L_{b52} | 280 | Lₐ₁₄₇₄ | L_{b52} |
| 281 | Lₐ₁₄₇₅ | L_{b52} | 282 | Lₐ₁₄₇₆ | L_{b52} |
| 283 | Lₐ₁₄₇₇ | L_{b52} | 284 | Lₐ₁₄₇₈ | L_{b52} |
| 285 | Lₐ₁₄₇₉ | L_{b52} | 286 | Lₐ₁₄₈₀ | L_{b52} |
| 287 | Lₐ₁₄₈₁ | L_{b52} | 288 | Lₐ₁₄₈₂ | L_{b52} |
| 289 | Lₐ₁₄₈₃ | L_{b52} | 290 | Lₐ₁₄₈₄ | L_{b52} |
| 291 | Lₐ₁₄₈₅ | L_{b52} | 292 | Lₐ₁₄₈₆ | L_{b52} |
| 293 | Lₐ₁₄₈₇ | L_{b52} | 294 | Lₐ₁₄₈₈ | L_{b52} |
| 295 | Lₐ₁₄₈₉ | L_{b52} | 296 | Lₐ₁₄₉₀ | L_{b52} |
| 297 | Lₐ₁₄₉₁ | L_{b52} | 298 | Lₐ₁₄₉₂ | L_{b52} |
| 299 | Lₐ₁₄₉₃ | L_{b52} | 300 | Lₐ₁₄₉₄ | L_{b52} |
| 301 | Lₐ₁₄₉₅ | L_{b52} | 302 | Lₐ₁₄₉₆ | L_{b52} |
| 303 | Lₐ₁₄₉₇ | L_{b52} | 304 | Lₐ₁₄₉₈ | L_{b52} |
| 305 | Lₐ₁₄₉₉ | L_{b52} | 306 | Lₐ₁₅₀₀ | L_{b52} |
| 307 | Lₐ₁₅₀₁ | L_{b52} | 308 | Lₐ₁₅₀₂ | L_{b52} |
| 309 | Lₐ₁₅₀₃ | L_{b52} | 310 | Lₐ₁₅₀₄ | L_{b52} |
| 311 | Lₐ₁₅₀₅ | L_{b52} | 312 | Lₐ₁₅₀₆ | L_{b52} |
| 313 | Lₐ₁₅₀₇ | L_{b52} | 314 | Lₐ₁₅₀₈ | L_{b52} |
| 315 | Lₐ₁₅₀₉ | L_{b52} | 316 | Lₐ₁₅₁₀ | L_{b52} |
| 317 | Lₐ₁₅₁₁ | L_{b52} | 318 | Lₐ₁₅₁₂ | L_{b52} |
| 319 | Lₐ₁₅₁₃ | L_{b52} | 320 | Lₐ₁₅₁₄ | L_{b52} |
| 321 | Lₐ₁₅₁₅ | L_{b52} | 322 | Lₐ₁₅₁₆ | L_{b52} |
| 323 | Lₐ₁₅₁₇ | L_{b52} | 324 | Lₐ₁₅₁₈ | L_{b52} |
| 325 | Lₐ₁₅₁₉ | L_{b52} | 326 | Lₐ₁₅₂₀ | L_{b52} |
| 327 | Lₐ₁₅₂₁ | L_{b52} | 328 | Lₐ₁₅₂₂ | L_{b52} |
| 329 | Lₐ₁₅₂₃ | L_{b52} | 330 | Lₐ₁₅₂₄ | L_{b52.} |
| 331 | Lₐ₁₅₂₅ | L_{b52} | 332 | Lₐ₁₅₂₆ | L_{b52} |
| 333 | Lₐ₁₅₂₇ | L_{b52} | 334 | Lₐ₁₅₂₈ | L_{b52} |
| 335 | Lₐ₁₅₂₉ | L_{b52} | 336 | Lₐ₁₅₃₀ | L_{b52} |
| 337 | Lₐ₁₅₃₁ | L_{b52} | 338 | Lₐ₁₅₃₂ | L_{b52} |
| 339 | Lₐ₁₅₃₃ | L_{b52} | 340 | Lₐ₁₅₃₄ | L_{b52} |
| 341 | Lₐ₁₅₃₅ | L_{b52} | 342 | Lₐ₁₅₃₆ | L_{b52} |
| 343 | Lₐ₁₅₃₇ | L_{b52} | 344 | Lₐ₁₅₃₈ | L_{b52} |
| 345 | Lₐ₁₅₃₉ | L_{b52} | 346 | Lₐ₁₅₄₀ | L_{b52} |
| 347 | Lₐ₁₅₄₁ | L_{b52} | 348 | Lₐ₁₅₄₂ | L_{b52} |
| 349 | Lₐ₁₅₄₃ | L_{b52} | 350 | Lₐ₁₅₄₄ | L_{b52} |
| 351 | Lₐ₁₅₄₅ | L_{b52} | 352 | Lₐ₁₅₄₆ | L_{b52} |
| 353 | Lₐ₁₅₄₇ | L_{b52} | 354 | Lₐ₁₅₄₈ | L_{b52} |
| 355 | Lₐ₁₅₄₉ | L_{b52} | 356 | Lₐ₁₅₅₀ | L_{b52} |
| 357 | Lₐ₁₅₅₁ | L_{b52} | 358 | Lₐ₁₅₅₂ | L_{b52} |
| 359 | Lₐ₁₅₅₃ | L_{b52} | 360 | Lₐ₁₅₅₄ | L_{b52} |
| 361 | Lₐ₁ | L_{b76} | 362 | Lₐ₂ | L_{b76} |
| 363 | Lₐ₃ | L_{b76} | 364 | Lₐ₄ | L_{b76} |
| 365 | Lₐ₅ | L_{b76} | 366 | Lₐ₆ | L_{b76} |
| 367 | Lₐ₇ | L_{b76} | 368 | Lₐ₈ | L_{b76} |
| 369 | Lₐ₉ | L_{b76} | 370 | Lₐ₁₀ | L_{b76} |
| 371 | Lₐ₁₁ | L_{b76} | 372 | Lₐ₁₂ | L_{b76} |
| 373 | Lₐ₁₃ | L_{b76} | 374 | Lₐ₁₄ | L_{b76} |
| 375 | Lₐ₁₅ | L_{b76} | 376 | Lₐ₁₆ | L_{b76} |
| 377 | Lₐ₁₇ | L_{b76} | 378 | Lₐ₁₈ | L_{b76} |
| 379 | Lₐ₁₉ | L_{b76} | 380 | Lₐ₂₀ | L_{b76} |
| 381 | Lₐ₂₁ | L_{b76} | 382 | Lₐ₂₂ | L_{b76} |
| 383 | Lₐ₂₃ | L_{b76} | 384 | Lₐ₂₄ | L_{b76} |
| 385 | Lₐ₂₅ | L_{b76} | 386 | Lₐ₂₆ | L_{b76} |
| 387 | Lₐ₂₇ | L_{b76} | 388 | Lₐ₂₈ | L_{b76} |
| 389 | Lₐ₂₉ | L_{b76} | 390 | Lₐ₃₀ | L_{b76} |
| 391 | Lₐ₃₁ | L_{b76} | 392 | Lₐ₃₂ | L_{b76} |
| 393 | Lₐ₃₃ | L_{b76} | 394 | Lₐ₃₄ | L_{b76} |
| 395 | Lₐ₃₅ | L_{b76} | 396 | Lₐ₃₆ | L_{b76} |
| 397 | Lₐ₃₇ | L_{b76} | 398 | Lₐ₃₈ | L_{b76} |
| 399 | Lₐ₃₉ | L_{b76} | 400 | Lₐ₄₀ | L_{b76} |
| 401 | Lₐ₄₁ | L_{b76} | 402 | Lₐ₄₂ | L_{b76} |
| 403 | Lₐ₄₃ | L_{b76} | 404 | Lₐ₄₄ | L_{b76} |
| 405 | Lₐ₄₅ | L_{b76} | 406 | Lₐ₄₆ | L_{b76} |
| 407 | Lₐ₄₇ | L_{b76} | 408 | Lₐ₄₈ | L_{b76} |
| 409 | Lₐ₄₉ | L_{b76} | 410 | Lₐ₅₀ | L_{b76} |
| 411 | Lₐ₅₁ | L_{b76} | 412 | Lₐ₅₂ | L_{b76} |
| 413 | Lₐ₅₃ | L_{b76} | 414 | Lₐ₅₄ | L_{b76} |
| 415 | Lₐ₅₅ | L_{b76} | 416 | Lₐ₅₆ | L_{b76} |
| 417 | Lₐ₅₇ | L_{b76} | 418 | Lₐ₅₈ | L_{b76} |
| 419 | Lₐ₅₉ | L_{b76} | 420 | Lₐ₆₀ | L_{b76} |
| 421 | Lₐ₆₁ | L_{b76} | 422 | Lₐ₆₂ | L_{b76} |
| 423 | Lₐ₆₃ | L_{b76} | 424 | Lₐ₆₄ | L_{b76} |
| 425 | Lₐ₆₅ | L_{b76} | 426 | Lₐ₆₆ | L_{b76} |
| 427 | Lₐ₆₇ | L_{b76} | 428 | Lₐ₆₈ | L_{b76} |
| 429 | Lₐ₆₉ | L_{b76} | 430 | Lₐ₇₀ | L_{b76} |
| 431 | Lₐ₇₁ | L_{b76} | 432 | Lₐ₇₂ | L_{b76} |
| 433 | Lₐ₇₃ | L_{b76} | 434 | Lₐ₇₄ | L_{b76} |
| 435 | Lₐ₇₅ | L_{b76} | 436 | Lₐ₇₆ | L_{b76} |
| 437 | Lₐ₇₇ | L_{b76} | 438 | Lₐ₇₈ | L_{b76} |
| 439 | Lₐ₇₉ | L_{b76} | 440 | Lₐ₈₀ | L_{b76} |
| 441 | Lₐ₈₁ | L_{b76} | 442 | Lₐ₈₂ | L_{b76} |
| 443 | Lₐ₈₃ | L_{b76} | 444 | Lₐ₈₄ | L_{b76} |
| 445 | Lₐ₈₅ | L_{b76} | 446 | Lₐ₈₆ | L_{b76} |
| 447 | Lₐ₈₇ | L_{b76} | 448 | Lₐ₈₈ | L_{b76} |
| 449 | Lₐ₈₉ | L_{b76} | 450 | Lₐ₉₀ | L_{b76} |
| 451 | Lₐ₁₈₁ | L_{b76} | 452 | Lₐ₁₈₂ | L_{b76} |
| 453 | Lₐ₁₈₃ | L_{b76} | 454 | Lₐ₁₈₄ | L_{b76} |
| 455 | Lₐ₁₈₅ | L_{b76} | 456 | Lₐ₁₈₆ | L_{b76} |
| 457 | Lₐ₁₈₇ | L_{b76} | 458 | Lₐ₁₈₈ | L_{b76} |
| 459 | Lₐ₁₈₉ | L_{b76} | 460 | Lₐ₁₉₀ | L_{b76} |
| 461 | Lₐ₁₉₁ | L_{b76} | 462 | Lₐ₁₉₂ | L_{b76} |
| 463 | Lₐ₁₉₃ | L_{b76} | 464 | Lₐ₁₉₄ | L_{b76} |
| 465 | Lₐ₁₉₅ | L_{b76} | 466 | Lₐ₁₉₆ | L_{b76} |
| 467 | Lₐ₁₉₇ | L_{b76} | 468 | Lₐ₁₉₈ | L_{b76} |
| 469 | Lₐ₁₉₉ | L_{b76} | 470 | Lₐ₂₀₀ | L_{b76} |
| 471 | Lₐ₂₀₁ | L_{b76} | 472 | Lₐ₂₀₂ | L_{b76} |
| 473 | Lₐ₂₀₃ | L_{b76} | 474 | Lₐ₂₀₄ | L_{b76} |
| 475 | Lₐ₂₀₅ | L_{b76} | 476 | Lₐ₂₀₆ | L_{b76} |
| 477 | Lₐ₂₀₇ | L_{b76} | 478 | Lₐ₂₀₈ | L_{b76} |
| 479 | Lₐ₂₀₉ | L_{b76} | 480 | Lₐ₂₁₀ | L_{b76} |
| 481 | Lₐ₂₁₁ | L_{b76} | 482 | Lₐ₂₁₂ | L_{b76} |
| 483 | Lₐ₂₁₃ | L_{b76} | 484 | Lₐ₂₁₄ | L_{b76} |
| 485 | Lₐ₂₁₅ | L_{b76} | 486 | Lₐ₂₁₆ | L_{b76} |
| 487 | Lₐ₂₁₇ | L_{b76} | 488 | Lₐ₂₁₈ | L_{b76} |
| 489 | Lₐ₂₁₉ | L_{b76} | 490 | Lₐ₂₂₀ | L_{b76} |
| 491 | Lₐ₂₂₁ | L_{b76} | 492 | Lₐ₂₂₂ | L_{b76} |
| 493 | Lₐ₂₂₃ | L_{b76} | 494 | Lₐ₂₂₄ | L_{b76} |
| 495 | Lₐ₂₂₅ | L_{b76} | 496 | Lₐ₂₂₆ | L_{b76} |
| 497 | Lₐ₂₂₇ | L_{b76} | 498 | Lₐ₂₂₈ | L_{b76} |
| 499 | Lₐ₂₂₉ | L_{b76} | 500 | Lₐ₂₃₀ | L_{b76} |
| 501 | Lₐ₂₃₁ | L_{b76} | 502 | Lₐ₂₃₂ | L_{b76} |
| 503 | Lₐ₂₃₃ | L_{b76} | 504 | Lₐ₂₃₄ | L_{b76} |
| 505 | Lₐ₂₃₅ | L_{b76} | 506 | Lₐ₂₃₆ | L_{b76} |
| 507 | Lₐ₂₃₇ | L_{b76} | 508 | Lₐ₂₃₈ | L_{b76} |
| 509 | Lₐ₂₃₉ | L_{b76} | 510 | Lₐ₂₄₀ | L_{b76} |
| 511 | Lₐ₂₄₁ | L_{b76} | 512 | Lₐ₂₄₂ | L_{b76} |
| 513 | Lₐ₂₄₃ | L_{b76} | 514 | Lₐ₂₄₄ | L_{b76} |
| 515 | Lₐ₂₄₅ | L_{b76} | 516 | Lₐ₂₄₆ | L_{b76} |
| 517 | Lₐ₂₄₇ | L_{b76} | 518 | Lₐ₂₄₈ | L_{b76} |
| 519 | Lₐ₂₄₉ | L_{b76} | 520 | Lₐ₂₅₀ | L_{b76} |
| 521 | Lₐ₂₅₁ | L_{b76} | 522 | Lₐ₂₅₂ | L_{b76} |
| 523 | Lₐ₂₅₃ | L_{b76} | 524 | Lₐ₂₅₄ | L_{b76} |
| 525 | Lₐ₂₅₅ | L_{b76} | 526 | Lₐ₂₅₆ | L_{b76} |
| 527 | Lₐ₂₅₇ | L_{b76} | 528 | Lₐ₂₅₈ | L_{b76} |
| 529 | Lₐ₂₅₉ | L_{b76} | 530 | Lₐ₂₆₀ | L_{b76} |
| 531 | Lₐ₂₆₁ | L_{b76} | 532 | Lₐ₂₆₂ | L_{b76} |
| 533 | Lₐ₂₆₃ | L_{b76} | 534 | Lₐ₂₆₄ | L_{b76} |
| 535 | Lₐ₂₆₅ | L_{b76} | 536 | Lₐ₂₆₆ | L_{b76} |
| 537 | Lₐ₂₆₇ | L_{b76} | 538 | Lₐ₂₆₈ | L_{b76} |
| 539 | Lₐ₂₆₉ | L_{b76} | 540 | Lₐ₂₇₀ | L_{b76} |
| 541 | Lₐ₁₂₈₅ | L_{b76} | 542 | Lₐ₁₂₈₆ | L_{b76} |
| 543 | Lₐ₁₂₈₇ | L_{b76} | 544 | Lₐ₁₂₈₈ | L_{b76} |
| 545 | Lₐ₁₂₈₉ | L_{b76} | 546 | Lₐ₁₂₉₀ | L_{b76} |
| 547 | Lₐ₁₂₉₁ | L_{b76} | 548 | Lₐ₁₂₉₂ | L_{b76} |
| 549 | Lₐ₁₂₉₃ | L_{b76} | 550 | Lₐ₁₂₉₄ | L_{b76} |
| 551 | Lₐ₁₂₉₅ | L_{b76} | 552 | Lₐ₁₂₉₆ | L_{b76} |
| 553 | Lₐ₁₂₉₇ | L_{b76} | 554 | Lₐ₁₂₉₈ | L_{b76} |
| 555 | Lₐ₁₂₉₉ | L_{b76} | 556 | Lₐ₁₃₀₀ | L_{b76} |
| 557 | Lₐ₁₃₀₁ | L_{b76} | 558 | Lₐ₁₃₀₂ | L_{b76} |
| 559 | Lₐ₁₃₀₃ | L_{b76} | 560 | Lₐ₁₃₀₄ | L_{b76} |
| 561 | Lₐ₁₃₀₅ | L_{b76} | 562 | Lₐ₁₃₀₆ | L_{b76} |
| 563 | Lₐ₁₃₀₇ | L_{b76} | 564 | Lₐ₁₃₀₈ | L_{b76} |
| 565 | Lₐ₁₃₀₉ | L_{b76} | 566 | Lₐ₁₃₁₀ | L_{b76} |
| 567 | Lₐ₁₃₁₁ | L_{b76} | 568 | Lₐ₁₃₁₂ | L_{b76} |
| 569 | Lₐ₁₃₁₃ | L_{b76} | 570 | Lₐ₁₃₁₄ | L_{b76} |
| 571 | Lₐ₁₃₁₅ | L_{b76} | 572 | Lₐ₁₃₁₆ | L_{b76} |
| 573 | Lₐ₁₃₁₇ | L_{b76} | 574 | Lₐ₁₃₁₈ | L_{b76} |
| 575 | Lₐ₁₃₁₉ | L_{b76} | 576 | Lₐ₁₃₂₀ | L_{b76} |
| 577 | Lₐ₁₃₂₁ | L_{b76} | 578 | Lₐ₁₃₂₂ | L_{b76} |
| 579 | Lₐ₁₃₂₃ | L_{b76} | 580 | Lₐ₁₃₂₄ | L_{b76} |
| 581 | Lₐ₁₃₂₅ | L_{b76} | 582 | Lₐ₁₃₂₆ | L_{b76} |
| 583 | Lₐ₁₃₂₇ | L_{b76} | 584 | Lₐ₁₃₂₈ | L_{b76} |
| 585 | Lₐ₁₃₂₉ | L_{b76} | 586 | Lₐ₁₃₃₀ | L_{b76} |
| 587 | Lₐ₁₃₃₁ | L_{b76} | 588 | Lₐ₁₃₃₂ | L_{b76} |
| 589 | Lₐ₁₃₃₃ | L_{b76} | 590 | Lₐ₁₃₃₄ | L_{b76} |
| 591 | Lₐ₁₃₃₅ | L_{b76} | 592 | Lₐ₁₃₃₆ | L_{b76} |
| 593 | Lₐ₁₃₃₇ | L_{b76} | 594 | Lₐ₁₃₃₈ | L_{b76} |
| 595 | Lₐ₁₃₃₉ | L_{b76} | 596 | Lₐ₁₃₄₀ | L_{b76} |
| 597 | Lₐ₁₃₄₁ | L_{b76} | 598 | Lₐ₁₃₄₂ | L_{b76} |
| 599 | Lₐ₁₃₄₃ | L_{b76} | 600 | Lₐ₁₃₄₄ | L_{b76} |
| 601 | Lₐ₁₃₄₅ | L_{b76} | 602 | Lₐ₁₃₄₆ | L_{b76} |
| 603 | Lₐ₁₃₄₇ | L_{b76} | 604 | Lₐ₁₃₄₈ | L_{b76} |
| 605 | Lₐ₁₃₄₉ | L_{b76} | 606 | Lₐ₁₃₅₀ | L_{b76} |
| 607 | Lₐ₁₃₅₁ | L_{b76} | 608 | Lₐ₁₃₅₂ | L_{b76} |
| 609 | Lₐ₁₃₅₃ | L_{b76} | 610 | Lₐ₁₃₅₄ | L_{b76} |
| 611 | Lₐ₁₃₅₅ | L_{b76} | 612 | Lₐ₁₃₅₆ | L_{b76} |
| 613 | Lₐ₁₃₅₇ | L_{b76} | 614 | Lₐ₁₃₅₈ | L_{b76} |
| 615 | Lₐ₁₃₅₉ | L_{b76} | 616 | Lₐ₁₃₆₀ | L_{b76} |
| 617 | Lₐ₁₃₆₁ | L_{b76} | 618 | Lₐ₁₃₆₂ | L_{b76} |
| 619 | Lₐ₁₃₆₃ | L_{b76} | 620 | Lₐ₁₃₆₄ | L_{b76} |
| 621 | Lₐ₁₃₆₅ | L_{b76} | 622 | Lₐ₁₃₆₆ | L_{b76} |
| 623 | Lₐ₁₃₆₇ | L_{b76} | 624 | Lₐ₁₃₆₈ | L_{b76} |
| 625 | Lₐ₁₃₆₉ | L_{b76} | 626 | Lₐ₁₃₇₀ | L_{b76} |
| 627 | Lₐ₁₃₇₁ | L_{b76} | 628 | Lₐ₁₃₇₂ | L_{b76} |
| 629 | Lₐ₁₃₇₃ | L_{b76} | 630 | Lₐ₁₃₇₄ | L_{b76} |
| 631 | Lₐ₁₄₆₅ | L_{b76} | 632 | Lₐ₁₄₆₆ | L_{b76} |
| 633 | Lₐ₁₄₆₇ | L_{b76} | 634 | Lₐ₁₄₆₈ | L_{b76} |
| 635 | Lₐ₁₄₆₉ | L_{b76} | 636 | Lₐ₁₄₇₀ | L_{b76} |
| 637 | Lₐ₁₄₇₁ | L_{b76} | 638 | Lₐ₁₄₇₂ | L_{b76} |
| 639 | Lₐ₁₄₇₃ | L_{b76} | 640 | Lₐ₁₄₇₄ | L_{b76} |
| 641 | Lₐ₁₄₇₅ | L_{b76} | 642 | Lₐ₁₄₇₆ | L_{b76} |
| 643 | Lₐ₁₄₇₇ | L_{b76} | 644 | Lₐ₁₄₇₈ | L_{b76} |
| 645 | Lₐ₁₄₇₉ | L_{b76} | 646 | Lₐ₁₄₈₀ | L_{b76} |
| 647 | Lₐ₁₄₈₁ | L_{b76} | 648 | Lₐ₁₄₈₂ | L_{b76} |
| 649 | Lₐ₁₄₈₃ | L_{b76} | 650 | Lₐ₁₄₈₄ | L_{b76} |
| 651 | Lₐ₁₄₈₅ | L_{b76} | 652 | Lₐ₁₄₈₆ | L_{b76} |
| 653 | Lₐ₁₄₈₇ | L_{b76} | 654 | Lₐ₁₄₈₈ | L_{b76} |
| 655 | Lₐ₁₄₈₉ | L_{b76} | 656 | Lₐ₁₄₉₀ | L_{b76} |
| 657 | Lₐ₁₄₉₁ | L_{b76} | 658 | Lₐ₁₄₉₂ | L_{b76} |
| 659 | Lₐ₁₄₉₃ | L_{b76} | 660 | Lₐ₁₄₉₄ | L_{b76} |
| 661 | Lₐ₁₄₉₅ | L_{b76} | 662 | Lₐ₁₄₉₆ | L_{b76} |
| 663 | Lₐ₁₄₉₇ | L_{b76} | 664 | Lₐ₁₄₉₈ | L_{b76} |
| 665 | Lₐ₁₄₉₉ | L_{b76} | 666 | Lₐ₁₅₀₀ | L_{b76} |
| 667 | Lₐ₁₅₀₁ | L_{b76} | 668 | Lₐ₁₅₀₂ | L_{b76} |
| 669 | Lₐ₁₅₀₃ | L_{b76} | 670 | Lₐ₁₅₀₄ | L_{b76} |
| 671 | Lₐ₁₅₀₅ | L_{b76} | 672 | Lₐ₁₅₀₆ | L_{b76} |
| 673 | Lₐ₁₅₀₇ | L_{b76} | 674 | Lₐ₁₅₀₈ | L_{b76} |
| 675 | Lₐ₁₅₀₉ | L_{b76} | 676 | Lₐ₁₅₁₀ | L_{b76} |
| 677 | Lₐ₁₅₁₁ | L_{b76} | 678 | Lₐ₁₅₁₂ | L_{b76} |
| 679 | Lₐ₁₅₁₃ | L_{b76} | 680 | Lₐ₁₅₁₄ | L_{b76} |
| 681 | Lₐ₁₅₁₅ | L_{b76} | 682 | Lₐ₁₅₁₆ | L_{b76} |
| 683 | Lₐ₁₅₁₇ | L_{b76} | 684 | Lₐ₁₅₁₈ | L_{b76} |
| 685 | Lₐ₁₅₁₉ | L_{b76} | 686 | Lₐ₁₅₂₀ | L_{b76} |
| 687 | Lₐ₁₅₂₁ | L_{b76} | 688 | Lₐ₁₅₂₂ | L_{b76} |
| 689 | Lₐ₁₅₂₃ | L_{b76} | 690 | Lₐ₁₅₂₄ | L_{b76} |
| 691 | Lₐ₁₅₂₅ | L_{b76} | 692 | Lₐ₁₅₂₆ | L_{b76} |
| 693 | Lₐ₁₅₂₇ | L_{b76} | 694 | Lₐ₁₅₂₈ | L_{b76} |
| 695 | Lₐ₁₅₂₉ | L_{b76} | 696 | Lₐ₁₅₃₀ | L_{b76} |
| 697 | Lₐ₁₅₃₁ | L_{b76} | 698 | Lₐ₁₅₃₂ | L_{b76} |
| 699 | Lₐ₁₅₃₃ | L_{b76} | 700 | Lₐ₁₅₃₄ | L_{b76} |
| 701 | Lₐ₁₅₃₅ | L_{b76} | 702 | Lₐ₁₅₃₆ | L_{b76} |
| 703 | Lₐ₁₅₃₇ | L_{b76} | 704 | Lₐ₁₅₃₈ | L_{b76} |
| 705 | Lₐ₁₅₃₉ | L_{b76} | 706 | Lₐ₁₅₄₀ | L_{b76} |
| 707 | Lₐ₁₅₄₁ | L_{b76} | 708 | Lₐ₁₅₄₂ | L_{b76} |
| 709 | Lₐ₁₅₄₃ | L_{b76} | 710 | Lₐ₁₅₄₄ | L_{b76} |
| 711 | Lₐ₁₅₄₅ | L_{b76} | 712 | Lₐ₁₅₄₆ | L_{b76} |
| 713 | Lₐ₁₅₄₇ | L_{b76} | 714 | Lₐ₁₅₄₈ | L_{b76} |
| 715 | Lₐ₁₅₄₉ | L_{b76} | 716 | Lₐ₁₅₅₀ | L_{b76} |
| 717 | Lₐ₁₅₅₁ | L_{b76} | 718 | Lₐ₁₅₅₂ | L_{b76} |
| 719 | Lₐ₁₅₅₃ | L_{b76} | 720 | Lₐ₁₅₅₄ | L_{b76} |
| 721 | Lₐ₁ | L_{b132} | 722 | Lₐ₂ | L_{b132} |
| 723 | Lₐ₃ | L_{b132} | 724 | Lₐ₄ | L_{b132} |
| 725 | Lₐ₅ | L_{b132} | 726 | Lₐ₆ | L_{b132} |
| 727 | Lₐ₇ | L_{b132} | 728 | Lₐ₈ | L_{b132} |
| 729 | Lₐ₉ | L_{b132} | 730 | Lₐ₁₀ | L_{b132} |
| 731 | Lₐ₁₁ | L_{b132} | 732 | Lₐ₁₂ | L_{b132} |
| 733 | Lₐ₁₃ | L_{b132} | 734 | Lₐ₁₄ | L_{b132} |
| 735 | Lₐ₁₅ | L_{b132} | 736 | Lₐ₁₆ | L_{b132} |
| 737 | Lₐ₁₇ | L_{b132} | 738 | Lₐ₁₈ | L_{b132} |
| 739 | Lₐ₁₉ | L_{b132} | 740 | Lₐ₂₀ | L_{b132} |
| 741 | Lₐ₂₁ | L_{b132} | 742 | Lₐ₂₂ | L_{b132} |
| 743 | Lₐ₂₃ | L_{b132} | 744 | Lₐ₂₄ | L_{b132} |
| 745 | Lₐ₂₅ | L_{b132} | 746 | Lₐ₂₆ | L_{b132} |
| 747 | Lₐ₂₇ | L_{b132} | 748 | Lₐ₂₈ | L_{b132} |
| 749 | Lₐ₂₉ | L_{b132} | 750 | Lₐ₃₀ | L_{b132} |
| 751 | Lₐ₃₁ | L_{b132} | 752 | Lₐ₃₂ | L_{b132} |
| 753 | Lₐ₃₃ | L_{b132} | 754 | Lₐ₃₄ | L_{b132} |
| 755 | Lₐ₃₅ | L_{b132} | 756 | Lₐ₃₆ | L_{b132} |
| 757 | Lₐ₃₇ | L_{b132} | 758 | Lₐ₃₈ | L_{b132} |
| 759 | Lₐ₃₉ | L_{b132} | 760 | Lₐ₄₀ | L_{b132} |
| 761 | Lₐ₄₁ | L_{b132} | 762 | Lₐ₄₂ | L_{b132} |
| 763 | Lₐ₄₃ | L_{b132} | 764 | Lₐ₄₄ | L_{b132} |
| 765 | Lₐ₄₅ | L_{b132} | 766 | Lₐ₄₆ | L_{b132} |
| 767 | Lₐ₄₇ | L_{b132} | 768 | Lₐ₄₈ | L_{b132} |
| 769 | Lₐ₄₉ | L_{b132} | 770 | Lₐ₅₀ | L_{b132} |
| 771 | Lₐ₅₁ | L_{b132} | 772 | Lₐ₅₂ | L_{b132} |
| 773 | Lₐ₅₃ | L_{b132} | 774 | Lₐ₅₄ | L_{b132} |
| 775 | Lₐ₅₅ | L_{b132} | 776 | Lₐ₅₆ | L_{b132} |
| 777 | Lₐ₅₇ | L_{b132} | 778 | Lₐ₅₈ | L_{b132} |
| 779 | Lₐ₅₉ | L_{b132} | 780 | Lₐ₆₀ | L_{b132} |
| 781 | Lₐ₆₁ | L_{b132} | 782 | Lₐ₆₂ | L_{b132} |
| 783 | Lₐ₆₃ | L_{b132} | 784 | Lₐ₆₄ | L_{b132} |
| 785 | Lₐ₆₅ | L_{b132} | 786 | Lₐ₆₆ | L_{b132} |
| 787 | Lₐ₆₇ | L_{b132} | 788 | Lₐ₆₈ | L_{b132} |
| 789 | Lₐ₆₉ | L_{b132} | 790 | Lₐ₇₀ | L_{b132} |
| 791 | Lₐ₇₁ | L_{b132} | 792 | Lₐ₇₂ | L_{b132} |
| 793 | Lₐ₇₃ | L_{b132} | 794 | Lₐ₇₄ | L_{b132} |
| 795 | Lₐ₇₅ | L_{b132} | 796 | Lₐ₇₆ | L_{b132} |
| 797 | Lₐ₇₇ | L_{b132} | 798 | Lₐ₇₈ | L_{b132} |
| 799 | Lₐ₇₉ | L_{b132} | 800 | Lₐ₈₀ | L_{b132} |
| 801 | Lₐ₈₁ | L_{b132} | 802 | Lₐ₈₂ | L_{b132} |
| 803 | Lₐ₈₃ | L_{b132} | 804 | Lₐ₈₄ | L_{b132} |
| 805 | Lₐ₈₅ | L_{b132} | 806 | Lₐ₈₆ | L_{b132} |
| 807 | Lₐ₈₇ | L_{b132} | 808 | Lₐ₈₈ | L_{b132} |
| 809 | Lₐ₈₉ | L_{b132} | 810 | Lₐ₉₀ | L_{b132} |
| 811 | Lₐ₁₈₁ | L_{b132} | 812 | Lₐ₁₈₂ | L_{b132} |
| 813 | Lₐ₁₈₃ | L_{b132} | 814 | Lₐ₁₈₄ | L_{b132} |
| 815 | Lₐ₁₈₅ | L_{b132} | 816 | Lₐ₁₈₆ | L_{b132} |
| 817 | Lₐ₁₈₇ | L_{b132} | 818 | Lₐ₁₈₈ | L_{b132} |
| 819 | Lₐ₁₈₉ | L_{b132} | 820 | Lₐ₁₉₀ | L_{b132} |
| 821 | Lₐ₁₉₁ | L_{b132} | 822 | Lₐ₁₉₂ | L_{b132} |
| 823 | Lₐ₁₉₃ | L_{b132} | 824 | Lₐ₁₉₄ | L_{b132} |
| 825 | Lₐ₁₉₅ | L_{b132} | 826 | Lₐ₁₉₆ | L_{b132} |
| 827 | Lₐ₁₉₇ | L_{b132} | 828 | Lₐ₁₉₈ | L_{b132} |
| 829 | Lₐ₁₉₉ | L_{b132} | 830 | Lₐ₂₀₀ | L_{b132} |
| 831 | Lₐ₂₀₁ | L_{b132} | 832 | Lₐ₂₀₂ | L_{b132} |
| 833 | Lₐ₂₀₃ | L_{b132} | 834 | Lₐ₂₀₄ | L_{b132} |
| 835 | Lₐ₂₀₅ | L_{b132} | 836 | Lₐ₂₀₆ | L_{b132} |
| 837 | Lₐ₂₀₇ | L_{b132} | 838 | Lₐ₂₀₈ | L_{b132} |
| 839 | Lₐ₂₀₉ | L_{b132} | 840 | Lₐ₂₁₀ | L_{b132} |
| 841 | Lₐ₂₁₁ | L_{b132} | 842 | Lₐ₂₁₂ | L_{b132} |
| 843 | Lₐ₂₁₃ | L_{b132} | 844 | Lₐ₂₁₄ | L_{b132} |
| 845 | Lₐ₂₁₅ | L_{b132} | 846 | Lₐ₂₁₆ | L_{b132} |
| 847 | Lₐ₂₁₇ | L_{b132} | 848 | Lₐ₂₁₈ | L_{b132} |
| 849 | Lₐ₂₁₉ | L_{b132} | 850 | Lₐ₂₂₀ | L_{b132} |
| 851 | Lₐ₂₂₁ | L_{b132} | 852 | Lₐ₂₂₂ | L_{b132} |
| 853 | Lₐ₂₂₃ | L_{b132} | 854 | Lₐ₂₂₄ | L_{b132} |
| 855 | Lₐ₂₂₅ | L_{b132} | 856 | Lₐ₂₂₆ | L_{b132} |
| 857 | Lₐ₂₂₇ | L_{b132} | 858 | Lₐ₂₂₈ | L_{b132} |
| 859 | Lₐ₂₂₉ | L_{b132} | 860 | Lₐ₂₃₀ | L_{b132} |
| 861 | Lₐ₂₃₁ | L_{b132} | 862 | Lₐ₂₃₂ | L_{b132} |
| 863 | Lₐ₂₃₃ | L_{b132} | 864 | Lₐ₂₃₄ | L_{b132} |
| 865 | Lₐ₂₃₅ | L_{b132} | 866 | Lₐ₂₃₆ | L_{b132} |
| 867 | Lₐ₂₃₇ | L_{b132} | 868 | Lₐ₂₃₈ | L_{b132} |
| 869 | Lₐ₂₃₉ | L_{b132} | 870 | Lₐ₂₄₀ | L_{b132} |
| 871 | Lₐ₂₄₁ | L_{b132} | 872 | Lₐ₂₄₂ | L_{b132} |
| 873 | Lₐ₂₄₃ | L_{b132} | 874 | Lₐ₂₄₄ | L_{b132} |
| 875 | Lₐ₂₄₅ | L_{b132} | 876 | Lₐ₂₄₆ | L_{b132} |
| 877 | Lₐ₂₄₇ | L_{b132} | 878 | Lₐ₂₄₈ | L_{b132} |
| 879 | Lₐ₂₄₉ | L_{b132} | 880 | Lₐ₂₅₀ | L_{b132} |
| 881 | Lₐ₂₅₁ | L_{b132} | 882 | Lₐ₂₅₂ | L_{b132} |
| 883 | Lₐ₂₅₃ | L_{b132} | 884 | Lₐ₂₅₄ | L_{b132} |
| 885 | Lₐ₂₅₅ | L_{b132} | 886 | Lₐ₂₅₆ | L_{b132} |
| 887 | Lₐ₂₅₇ | L_{b132} | 888 | Lₐ₂₅₈ | L_{b132} |
| 889 | Lₐ₂₅₉ | L_{b132} | 890 | Lₐ₂₆₀ | L_{b132} |
| 891 | Lₐ₂₆₁ | L_{b132} | 892 | Lₐ₂₆₂ | L_{b132} |
| 893 | Lₐ₂₆₃ | L_{b132} | 894 | Lₐ₂₆₄ | L_{b132} |
| 895 | Lₐ₂₆₅ | L_{b132} | 896 | Lₐ₂₆₆ | L_{b132} |
| 897 | Lₐ₂₆₇ | L_{b132} | 898 | Lₐ₂₆₈ | L_{b132} |
| 899 | Lₐ₂₆₉ | L_{b132} | 900 | Lₐ₂₇₀ | L_{b132} |
| 901 | Lₐ₁₂₈₅ | L_{b132} | 902 | Lₐ₁₂₈₆ | L_{b132} |
| 903 | Lₐ₁₂₈₇ | L_{b132} | 904 | Lₐ₁₂₈₈ | L_{b132} |
| 905 | Lₐ₁₂₈₉ | L_{b132} | 906 | Lₐ₁₂₉₀ | L_{b132} |
| 907 | Lₐ₁₂₉₁ | L_{b132} | 908 | Lₐ₁₂₉₂ | L_{b132} |
| 909 | Lₐ₁₂₉₃ | L_{b132} | 910 | Lₐ₁₂₉₄ | L_{b132} |
| 911 | Lₐ₁₂₉₅ | L_{b132} | 912 | Lₐ₁₂₉₆ | L_{b132} |
| 913 | Lₐ₁₂₉₇ | L_{b132} | 914 | Lₐ₁₂₉₈ | L_{b132} |
| 915 | Lₐ₁₂₉₉ | L_{b132} | 916 | Lₐ₁₃₀₀ | L_{b132} |
| 917 | Lₐ₁₃₀₁ | L_{b132} | 918 | Lₐ₁₃₀₂ | L_{b132} |
| 919 | Lₐ₁₃₀₃ | L_{b132} | 920 | Lₐ₁₃₀₄ | L_{b132} |
| 921 | Lₐ₁₃₀₅ | L_{b132} | 922 | Lₐ₁₃₀₆ | L_{b132} |
| 923 | Lₐ₁₃₀₇ | L_{b132} | 924 | Lₐ₁₃₀₈ | L_{b132} |
| 925 | Lₐ₁₃₀₉ | L_{b132} | 926 | Lₐ₁₃₁₀ | L_{b132} |
| 927 | Lₐ₁₃₁₁ | L_{b132} | 928 | Lₐ₁₃₁₂ | L_{b132} |
| 929 | Lₐ₁₃₁₃ | L_{b132} | 930 | Lₐ₁₃₁₄ | L_{b132} |
| 931 | Lₐ₁₃₁₅ | L_{b132} | 932 | Lₐ₁₃₁₆ | L_{b132} |
| 933 | Lₐ₁₃₁₇ | L_{b132} | 934 | Lₐ₁₃₁₈ | L_{b132} |
| 935 | Lₐ₁₃₁₉ | L_{b132} | 936 | Lₐ₁₃₂₀ | L_{b132} |
| 937 | Lₐ₁₃₂₁ | L_{b132} | 938 | Lₐ₁₃₂₂ | L_{b132} |
| 939 | Lₐ₁₃₂₃ | L_{b132} | 940 | Lₐ₁₃₂₄ | L_{b132} |
| 941 | Lₐ₁₃₂₅ | L_{b132} | 942 | Lₐ₁₃₂₆ | L_{b132} |
| 943 | Lₐ₁₃₂₇ | L_{b132} | 944 | Lₐ₁₃₂₈ | L_{b132} |
| 945 | Lₐ₁₃₂₉ | L_{b132} | 946 | Lₐ₁₃₃₀ | L_{b132} |
| 947 | Lₐ₁₃₃₁ | L_{b132} | 948 | Lₐ₁₃₃₂ | L_{b132} |
| 949 | Lₐ₁₃₃₃ | L_{b132} | 950 | Lₐ₁₃₃₄ | L_{b132} |
| 951 | Lₐ₁₃₃₅ | L_{b132} | 952 | Lₐ₁₃₃₆ | L_{b132} |
| 953 | Lₐ₁₃₃₇ | L_{b132} | 954 | Lₐ₁₃₃₈ | L_{b132} |
| 955 | Lₐ₁₃₃₉ | L_{b132} | 956 | Lₐ₁₃₄₀ | L_{b132} |
| 957 | Lₐ₁₃₄₁ | L_{b132} | 958 | Lₐ₁₃₄₂ | L_{b132} |
| 959 | Lₐ₁₃₄₃ | L_{b132} | 960 | Lₐ₁₃₄₄ | L_{b132} |
| 961 | Lₐ₁₃₄₅ | L_{b132} | 962 | Lₐ₁₃₄₆ | L_{b132} |
| 963 | Lₐ₁₃₄₇ | L_{b132} | 964 | Lₐ₁₃₄₈ | L_{b132} |
| 965 | Lₐ₁₃₄₉ | L_{b132} | 966 | Lₐ₁₃₅₀ | L_{b132} |
| 967 | Lₐ₁₃₅₁ | L_{b132} | 968 | Lₐ₁₃₅₂ | L_{b132} |
| 969 | Lₐ₁₃₅₃ | L_{b132} | 970 | Lₐ₁₃₅₄ | L_{b132} |
| 971 | Lₐ₁₃₅₅ | L_{b132} | 972 | Lₐ₁₃₅₆ | L_{b132} |
| 973 | Lₐ₁₃₅₇ | L_{b132} | 974 | Lₐ₁₃₅₈ | L_{b132} |
| 975 | Lₐ₁₃₅₉ | L_{b132} | 976 | Lₐ₁₃₆₀ | L_{b132} |
| 977 | Lₐ₁₃₆₁ | L_{b132} | 978 | Lₐ₁₃₆₂ | L_{b132} |
| 979 | Lₐ₁₃₆₃ | L_{b132} | 980 | Lₐ₁₃₆₄ | L_{b132} |
| 981 | Lₐ₁₃₆₅ | L_{b132} | 982 | Lₐ₁₃₆₆ | L_{b132} |
| 983 | Lₐ₁₃₆₇ | L_{b132} | 984 | Lₐ₁₃₆₈ | L_{b132} |
| 985 | Lₐ₁₃₆₉ | L_{b132} | 986 | Lₐ₁₃₇₀ | L_{b132} |
| 987 | Lₐ₁₃₇₁ | L_{b132} | 988 | Lₐ₁₃₇₂ | L_{b132} |
| 989 | Lₐ₁₃₇₃ | L_{b132} | 990 | Lₐ₁₃₇₄ | L_{b132} |
| 991 | Lₐ₁₄₆₅ | L_{b132} | 992 | Lₐ₁₄₆₆ | L_{b132} |
| 993 | Lₐ₁₄₆₇ | L_{b132} | 994 | Lₐ₁₄₆₈ | L_{b132} |
| 995 | Lₐ₁₄₆₉ | L_{b132} | 996 | Lₐ₁₄₇₀ | L_{b132} |
| 997 | Lₐ₁₄₇₁ | L_{b132} | 998 | Lₐ₁₄₇₂ | L_{b132} |
| 999 | Lₐ₁₄₇₃ | L_{b132} | 1000 | Lₐ₁₄₇₄ | L_{b132} |
| 1001 | Lₐ₁₄₇₅ | L_{b132} | 1002 | Lₐ₁₄₇₆ | L_{b132} |
| 1003 | Lₐ₁₄₇₇ | L_{b132} | 1004 | Lₐ₁₄₇₈ | L_{b132} |
| 1005 | Lₐ₁₄₇₉ | L_{b132} | 1006 | Lₐ₁₄₈₀ | L_{b132} |
| 1007 | Lₐ₁₄₈₁ | L_{b132} | 1008 | Lₐ₁₄₈₂ | L_{b132} |
| 1009 | Lₐ₁₄₈₃ | L_{b132} | 1010 | Lₐ₁₄₈₄ | L_{b132} |
| 1011 | Lₐ₁₄₈₅ | L_{b132} | 1012 | Lₐ₁₄₈₆ | L_{b132} |
| 1013 | Lₐ₁₄₈₇ | L_{b132} | 1014 | Lₐ₁₄₈₈ | L_{b132} |
| 1015 | Lₐ₁₄₈₉ | L_{b132} | 1016 | Lₐ₁₄₉₀ | L_{b132} |
| 1017 | Lₐ₁₄₉₁ | L_{b132} | 1018 | Lₐ₁₄₉₂ | L_{b132} |
| 1019 | Lₐ₁₄₉₃ | L_{b132} | 1020 | Lₐ₁₄₉₄ | L_{b132} |
| 1021 | Lₐ₁₄₉₅ | L_{b132} | 1022 | Lₐ₁₄₉₆ | L_{b132} |
| 1023 | Lₐ₁₄₉₇ | L_{b132} | 1024 | Lₐ₁₄₉₈ | L_{b132} |
| 1025 | Lₐ₁₄₉₉ | L_{b132} | 1026 | Lₐ₁₅₀₀ | L_{b132} |
| 1027 | Lₐ₁₅₀₁ | L_{b132} | 1028 | Lₐ₁₅₀₂ | L_{b132} |
| 1029 | Lₐ₁₅₀₃ | L_{b132} | 1030 | Lₐ₁₅₀₄ | L_{b132} |
| 1031 | Lₐ₁₅₀₅ | L_{b132} | 1032 | Lₐ₁₅₀₆ | L_{b132} |
| 1033 | Lₐ₁₅₀₇ | L_{b132} | 1034 | Lₐ₁₅₀₈ | L_{b132} |
| 1035 | Lₐ₁₅₀₉ | L_{b132} | 1036 | Lₐ₁₅₁₀ | L_{b132} |
| 1037 | Lₐ₁₅₁₁ | L_{b132} | 1038 | Lₐ₁₅₁₂ | L_{b132} |
| 1039 | Lₐ₁₅₁₃ | L_{b132} | 1040 | Lₐ₁₅₁₄ | L_{b132} |
| 1041 | Lₐ₁₅₁₅ | L_{b132} | 1042 | Lₐ₁₅₁₆ | L_{b132} |
| 1043 | Lₐ₁₅₁₇ | L_{b132} | 1044 | Lₐ₁₅₁₈ | L_{b132} |
| 1045 | Lₐ₁₅₁₉ | L_{b132} | 1046 | Lₐ₁₅₂₀ | L_{b132} |
| 1047 | Lₐ₁₅₂₁ | L_{b132} | 1048 | Lₐ₁₅₂₂ | L_{b132} |
| 1049 | Lₐ₁₅₂₃ | L_{b132} | 1050 | Lₐ₁₅₂₄ | L_{b132} |
| 1051 | Lₐ₁₅₂₅ | L_{b132} | 1052 | Lₐ₁₅₂₆ | L_{b132} |
| 1053 | Lₐ₁₅₂₇ | L_{b132} | 1054 | Lₐ₁₅₂₈ | L_{b132} |
| 1055 | Lₐ₁₅₂₉ | L_{b132} | 1056 | Lₐ₁₅₃₀ | L_{b132} |
| 1057 | Lₐ₁₅₃₁ | L_{b132} | 1058 | Lₐ₁₅₃₂ | L_{b132} |
| 1059 | Lₐ₁₅₃₃ | L_{b132} | 1060 | Lₐ₁₅₃₄ | L_{b132} |
| 1061 | Lₐ₁₅₃₅ | L_{b132} | 1062 | Lₐ₁₅₃₆ | L_{b132} |
| 1063 | Lₐ₁₅₃₇ | L_{b132} | 1064 | Lₐ₁₅₃₈ | L_{b132} |
| 1065 | Lₐ₁₅₃₉ | L_{b132} | 1066 | Lₐ₁₅₄₀ | L_{b132} |
| 1067 | Lₐ₁₅₄₁ | L_{b132} | 1068 | Lₐ₁₅₄₂ | L_{b132} |
| 1069 | Lₐ₁₅₄₃ | L_{b132} | 1070 | Lₐ₁₅₄₄ | L_{b132} |
| 1071 | Lₐ₁₅₄₅ | L_{b132} | 1072 | Lₐ₁₅₄₆ | L_{b132} |
| 1073 | Lₐ₁₅₄₇ | L_{b132} | 1074 | Lₐ₁₅₄₈ | L_{b132} |
| 1075 | Lₐ₁₅₄₉ | L_{b132} | 1076 | Lₐ₁₅₅₀ | L_{b132} |
| 1077 | Lₐ₁₅₅₁ | L_{b132} | 1078 | Lₐ₁₅₅₂ | L_{b132} |
| 1079 | Lₐ₁₅₅₃ | L_{b132} | 1080 | Lₐ₁₅₅₄ | L_{b132} |
| 1081 | Lₐ₁ | L_{b100} | 1082 | Lₐ₂ | L_{b100} |
| 1083 | Lₐ₃ | L_{b100} | 1084 | Lₐ₄ | L_{b100} |
| 1085 | Lₐ₅ | L_{b100} | 1086 | Lₐ₆ | L_{b100} |
| 1087 | Lₐ₇ | L_{b100} | 1088 | Lₐ₈ | L_{b100} |
| 1089 | Lₐ₉ | L_{b100} | 1090 | Lₐ₁₀ | L_{b100} |
| 1091 | Lₐ₁₁ | L_{b100} | 1092 | Lₐ₁₂ | L_{b100} |
| 1093 | Lₐ₁₃ | L_{b100} | 1094 | Lₐ₁₄ | L_{b100} |
| 1095 | Lₐ₁₅ | L_{b100} | 1096 | Lₐ₁₆ | L_{b100} |
| 1097 | Lₐ₁₇ | L_{b100} | 1098 | Lₐ₁₈ | L_{b100} |
| 1099 | Lₐ₁₉ | L_{b100} | 1100 | Lₐ₂₀ | L_{b100} |
| 1101 | Lₐ₂₁ | L_{b100} | 1102 | Lₐ₂₂ | L_{b100} |
| 1103 | Lₐ₂₃ | L_{b100} | 1104 | Lₐ₂₄ | L_{b100} |
| 1105 | Lₐ₂₅ | L_{b100} | 1106 | Lₐ₂₆ | L_{b100} |
| 1107 | Lₐ₂₇ | L_{b100} | 1108 | Lₐ₂₈ | L_{b100} |
| 1109 | Lₐ₂₉ | L_{b100} | 1110 | Lₐ₃₀ | L_{b100} |
| 1111 | Lₐ₃₁ | L_{b100} | 1112 | Lₐ₃₂ | L_{b100} |
| 1113 | Lₐ₃₃ | L_{b100} | 1114 | Lₐ₃₄ | L_{b100} |
| 1115 | Lₐ₃₅ | L_{b100} | 1116 | Lₐ₃₆ | L_{b100} |
| 1117 | Lₐ₃₇ | L_{b100} | 1118 | Lₐ₃₈ | L_{b100} |
| 1119 | Lₐ₃₉ | L_{b100} | 1120 | Lₐ₄₀ | L_{b100} |
| 1121 | Lₐ₄₁ | L_{b100} | 1122 | Lₐ₄₂ | L_{b100} |
| 1123 | Lₐ₄₃ | L_{b100} | 1124 | Lₐ₄₄ | L_{b100} |
| 1125 | Lₐ₄₅ | L_{b100} | 1126 | Lₐ₄₆ | L_{b100} |
| 1127 | Lₐ₄₇ | L_{b100} | 1128 | Lₐ₄₈ | L_{b100} |
| 1129 | Lₐ₄₉ | L_{b100} | 1130 | Lₐ₅₀ | L_{b100} |
| 1131 | Lₐ₅₁ | L_{b100} | 1132 | Lₐ₅₂ | L_{b100} |
| 1133 | Lₐ₅₃ | L_{b100} | 1134 | Lₐ₅₄ | L_{b100} |
| 1135 | Lₐ₅₅ | L_{b100} | 1136 | Lₐ₅₆ | L_{b100} |
| 1137 | Lₐ₅₇ | L_{b100} | 1138 | Lₐ₅₈ | L_{b100} |
| 1139 | Lₐ₅₉ | L_{b100} | 1140 | Lₐ₆₀ | L_{b100} |
| 1141 | Lₐ₆₁ | L_{b100} | 1142 | Lₐ₆₂ | L_{b100} |
| 1143 | Lₐ₆₃ | L_{b100} | 1144 | Lₐ₆₄ | L_{b100} |
| 1145 | Lₐ₆₅ | L_{b100} | 1146 | Lₐ₆₆ | L_{b100} |
| 1147 | Lₐ₆₇ | L_{b100} | 1148 | Lₐ₆₈ | L_{b100} |
| 1149 | Lₐ₆₉ | L_{b100} | 1150 | Lₐ₇₀ | L_{b100} |
| 1151 | Lₐ₇₁ | L_{b100} | 1152 | Lₐ₇₂ | L_{b100} |
| 1153 | Lₐ₇₃ | L_{b100} | 1154 | Lₐ₇₄ | L_{b100} |
| 1155 | Lₐ₇₅ | L_{b100} | 1156 | Lₐ₇₆ | L_{b100} |
| 1157 | Lₐ₇₇ | L_{b100} | 1158 | Lₐ₇₈ | L_{b100} |
| 1159 | Lₐ₇₉ | L_{b100} | 1160 | Lₐ₈₀ | L_{b100} |
| 1161 | Lₐ₈₁ | L_{b100} | 1162 | Lₐ₈₂ | L_{b100} |
| 1163 | Lₐ₈₃ | L_{b100} | 1164 | Lₐ₈₄ | L_{b100} |
| 1165 | Lₐ₈₅ | L_{b100} | 1166 | Lₐ₈₆ | L_{b100} |
| 1167 | Lₐ₈₇ | L_{b100} | 1168 | Lₐ₈₈ | L_{b100} |
| 1169 | Lₐ₈₉ | L_{b100} | 1170 | Lₐ₉₀ | L_{b100} |
| 1171 | Lₐ₁₈₁ | L_{b100} | 1172 | Lₐ₁₈₂ | L_{b100} |
| 1173 | Lₐ₁₈₃ | L_{b100} | 1174 | Lₐ₁₈₄ | L_{b100} |
| 1175 | Lₐ₁₈₅ | L_{b100} | 1176 | Lₐ₁₈₆ | L_{b100} |
| 1177 | Lₐ₁₈₇ | L_{b100} | 1178 | Lₐ₁₈₈ | L_{b100} |
| 1179 | Lₐ₁₈₉ | L_{b100} | 1180 | Lₐ₁₉₀ | L_{b100} |
| 1181 | Lₐ₁₉₁ | L_{b100} | 1182 | Lₐ₁₉₂ | L_{b100} |
| 1183 | Lₐ₁₉₃ | L_{b100} | 1184 | Lₐ₁₉₄ | L_{b100} |
| 1185 | Lₐ₁₉₅ | L_{b100} | 1186 | Lₐ₁₉₆ | L_{b100} |
| 1187 | Lₐ₁₉₇ | L_{b100} | 1188 | Lₐ₁₉₈ | L_{b100} |
| 1189 | Lₐ₁₉₉ | L_{b100} | 1190 | Lₐ₂₀₀ | L_{b100} |
| 1191 | Lₐ₂₀₁ | L_{b100} | 1192 | Lₐ₂₀₂ | L_{b100} |
| 1193 | Lₐ₂₀₃ | L_{b100} | 1194 | Lₐ₂₀₄ | L_{b100} |
| 1195 | Lₐ₂₀₅ | L_{b100} | 1196 | Lₐ₂₀₆ | L_{b100} |
| 1197 | Lₐ₂₀₇ | L_{b100} | 1198 | Lₐ₂₀₈ | L_{b100} |
| 1199 | Lₐ₂₀₉ | L_{b100} | 1200 | Lₐ₂₁₀ | L_{b100} |
| 1201 | Lₐ₂₁₁ | L_{b100} | 1202 | Lₐ₂₁₂ | L_{b100} |
| 1203 | Lₐ₂₁₃ | L_{b100} | 1204 | Lₐ₂₁₄ | L_{b100} |
| 1205 | Lₐ₂₁₅ | L_{b100} | 1206 | Lₐ₂₁₆ | L_{b100} |
| 1207 | Lₐ₂₁₇ | L_{b100} | 1208 | Lₐ₂₁₈ | L_{b100} |
| 1209 | Lₐ₂₁₉ | L_{b100} | 1210 | Lₐ₂₂₀ | L_{b100} |
| 1211 | Lₐ₂₂₁ | L_{b100} | 1212 | Lₐ₂₂₂ | L_{b100} |
| 1213 | Lₐ₂₂₃ | L_{b100} | 1214 | Lₐ₂₂₄ | L_{b100} |
| 1215 | Lₐ₂₂₅ | L_{b100} | 1216 | Lₐ₂₂₆ | L_{b100} |
| 1217 | Lₐ₂₂₇ | L_{b100} | 1218 | Lₐ₂₂₈ | L_{b100} |
| 1219 | Lₐ₂₂₉ | L_{b100} | 1220 | Lₐ₂₃₀ | L_{b100} |
| 1221 | Lₐ₂₃₁ | L_{b100} | 1222 | Lₐ₂₃₂ | L_{b100} |
| 1223 | Lₐ₂₃₃ | L_{b100} | 1224 | Lₐ₂₃₄ | L_{b100} |
| 1225 | Lₐ₂₃₅ | L_{b100} | 1226 | Lₐ₂₃₆ | L_{b100} |
| 1227 | Lₐ₂₃₇ | L_{b100} | 1228 | Lₐ₂₃₈ | L_{b100} |
| 1229 | Lₐ₂₃₉ | L_{b100} | 1230 | Lₐ₂₄₀ | L_{b100} |
| 1231 | Lₐ₂₄₁ | L_{b100} | 1232 | Lₐ₂₄₂ | L_{b100} |
| 1233 | Lₐ₂₄₃ | L_{b100} | 1234 | Lₐ₂₄₄ | L_{b100} |
| 1235 | Lₐ₂₄₅ | L_{b100} | 1236 | Lₐ₂₄₆ | L_{b100} |
| 1237 | Lₐ₂₄₇ | L_{b100} | 1238 | Lₐ₂₄₈ | L_{b100} |
| 1239 | Lₐ₂₄₉ | L_{b100} | 1240 | Lₐ₂₅₀ | L_{b100} |
| 1241 | Lₐ₂₅₁ | L_{b100} | 1242 | Lₐ₂₅₂ | L_{b100} |
| 1243 | Lₐ₂₅₃ | L_{b100} | 1244 | Lₐ₂₅₄ | L_{b100} |
| 1245 | Lₐ₂₅₅ | L_{b100} | 1246 | Lₐ₂₅₆ | L_{b100} |
| 1247 | Lₐ₂₅₇ | L_{b100} | 1248 | Lₐ₂₅₈ | L_{b100} |
| 1249 | Lₐ₂₅₉ | L_{b100} | 1250 | Lₐ₂₆₀ | L_{b100} |
| 1251 | Lₐ₂₆₁ | L_{b100} | 1252 | Lₐ₂₆₂ | L_{b100} |
| 1253 | Lₐ₂₆₃ | L_{b100} | 1254 | Lₐ₂₆₄ | L_{b100} |
| 1255 | Lₐ₂₆₅ | L_{b100} | 1256 | Lₐ₂₆₆ | L_{b100} |
| 1257 | Lₐ₂₆₇ | L_{b100} | 1258 | Lₐ₂₆₈ | L_{b100} |
| 1259 | Lₐ₂₆₉ | L_{b100} | 1260 | Lₐ₂₇₀ | L_{b100} |
| 1261 | Lₐ₁₂₈₅ | L_{b100} | 1262 | Lₐ₁₂₈₆ | L_{b100} |
| 1263 | Lₐ₁₂₈₇ | L_{b100} | 1264 | Lₐ₁₂₈₈ | L_{b100} |
| 1265 | Lₐ₁₂₈₉ | L_{b100} | 1266 | Lₐ₁₂₉₀ | L_{b100} |
| 1267 | Lₐ₁₂₉₁ | L_{b100} | 1268 | Lₐ₁₂₉₂ | L_{b100} |
| 1269 | Lₐ₁₂₉₃ | L_{b100} | 1270 | Lₐ₁₂₉₄ | L_{b100} |
| 1271 | Lₐ₁₂₉₅ | L_{b100} | 1272 | Lₐ₁₂₉₆ | L_{b100} |
| 1273 | Lₐ₁₂₉₇ | L_{b100} | 1274 | Lₐ₁₂₉₈ | L_{b100} |
| 1275 | Lₐ₁₂₉₉ | L_{b100} | 1276 | Lₐ₁₃₀₀ | L_{b100} |
| 1277 | Lₐ₁₃₀₁ | L_{b100} | 1278 | Lₐ₁₃₀₂ | L_{b100} |
| 1279 | Lₐ₁₃₀₃ | L_{b100} | 1280 | Lₐ₁₃₀₄ | L_{b100} |
| 1281 | Lₐ₁₃₀₅ | L_{b100} | 1282 | Lₐ₁₃₀₆ | L_{b100} |
| 1283 | Lₐ₁₃₀₇ | L_{b100} | 1284 | Lₐ₁₃₀₈ | L_{b100} |
| 1285 | Lₐ₁₃₀₉ | L_{b100} | 1286 | Lₐ₁₃₁₀ | L_{b100} |
| 1287 | Lₐ₁₃₁₁ | L_{b100} | 1288 | Lₐ₁₃₁₂ | L_{b100} |
| 1289 | Lₐ₁₃₁₃ | L_{b100} | 1290 | Lₐ₁₃₁₄ | L_{b100} |
| 1291 | Lₐ₁₃₁₅ | L_{b100} | 1292 | Lₐ₁₃₁₆ | L_{b100} |
| 1293 | Lₐ₁₃₁₇ | L_{b100} | 1294 | Lₐ₁₃₁₈ | L_{b100} |
| 1295 | Lₐ₁₃₁₉ | L_{b100} | 1296 | Lₐ₁₃₂₀ | L_{b100} |
| 1297 | Lₐ₁₃₂₁ | L_{b100} | 1298 | Lₐ₁₃₂₂ | L_{b100} |
| 1299 | Lₐ₁₃₂₃ | L_{b100} | 1300 | Lₐ₁₃₂₄ | L_{b100} |
| 1301 | Lₐ₁₃₂₅ | L_{b100} | 1302 | Lₐ₁₃₂₆ | L_{b100} |
| 1303 | Lₐ₁₃₂₇ | L_{b100} | 1304 | Lₐ₁₃₂₈ | L_{b100} |
| 1305 | Lₐ₁₃₂₉ | L_{b100} | 1306 | Lₐ₁₃₃₀ | L_{b100} |
| 1307 | Lₐ₁₃₃₁ | L_{b100} | 1308 | Lₐ₁₃₃₂ | L_{b100} |
| 1309 | Lₐ₁₃₃₃ | L_{b100} | 1310 | Lₐ₁₃₃₄ | L_{b100} |
| 1311 | Lₐ₁₃₃₅ | L_{b100} | 1312 | Lₐ₁₃₃₆ | L_{b100} |
| 1313 | Lₐ₁₃₃₇ | L_{b100} | 1314 | Lₐ₁₃₃₈ | L_{b100} |
| 1315 | Lₐ₁₃₃₉ | L_{b100} | 1316 | Lₐ₁₃₄₀ | L_{b100} |
| 1317 | Lₐ₁₃₄₁ | L_{b100} | 1318 | Lₐ₁₃₄₂ | L_{b100} |
| 1319 | Lₐ₁₃₄₃ | L_{b100} | 1320 | Lₐ₁₃₄₄ | L_{b100} |
| 1321 | Lₐ₁₃₄₅ | L_{b100} | 1322 | Lₐ₁₃₄₆ | L_{b100} |
| 1323 | Lₐ₁₃₄₇ | L_{b100} | 1324 | Lₐ₁₃₄₈ | L_{b100} |
| 1325 | Lₐ₁₃₄₉ | L_{b100} | 1326 | Lₐ₁₃₅₀ | L_{b100} |
| 1327 | Lₐ₁₃₅₁ | L_{b100} | 1328 | Lₐ₁₃₅₂ | L_{b100} |
| 1329 | Lₐ₁₃₅₃ | L_{b100} | 1330 | Lₐ₁₃₅₄ | L_{b100} |
| 1331 | Lₐ₁₃₅₅ | L_{b100} | 1332 | Lₐ₁₃₅₆ | L_{b100} |
| 1333 | Lₐ₁₃₅₇ | L_{b100} | 1334 | Lₐ₁₃₅₈ | L_{b100} |
| 1335 | Lₐ₁₃₅₉ | L_{b100} | 1336 | Lₐ₁₃₆₀ | L_{b100} |
| 1337 | Lₐ₁₃₆₁ | L_{b100} | 1338 | Lₐ₁₃₆₂ | L_{b100} |
| 1339 | Lₐ₁₃₆₃ | L_{b100} | 1340 | Lₐ₁₃₆₄ | L_{b100} |
| 1341 | Lₐ₁₃₆₅ | L_{b100} | 1342 | Lₐ₁₃₆₆ | L_{b100} |
| 1343 | Lₐ₁₃₆₇ | L_{b100} | 1344 | Lₐ₁₃₆₈ | L_{b100} |
| 1345 | Lₐ₁₃₆₉ | L_{b100} | 1346 | Lₐ₁₃₇₀ | L_{b100} |
| 1347 | Lₐ₁₃₇₁ | L_{b100} | 1348 | Lₐ₁₃₇₂ | L_{b100} |
| 1349 | Lₐ₁₃₇₃ | L_{b100} | 1350 | Lₐ₁₃₇₄ | L_{b100} |
| 1351 | Lₐ₁₄₆₅ | L_{b100} | 1352 | Lₐ₁₄₆₆ | L_{b100} |
| 1353 | Lₐ₁₄₆₇ | L_{b100} | 1354 | Lₐ₁₄₆₈ | L_{b100} |
| 1355 | Lₐ₁₄₆₉ | L_{b100} | 1356 | Lₐ₁₄₇₀ | L_{b100} |
| 1357 | Lₐ₁₄₇₁ | L_{b100} | 1358 | Lₐ₁₄₇₂ | L_{b100} |
| 1359 | Lₐ₁₄₇₃ | L_{b100} | 1360 | Lₐ₁₄₇₄ | L_{b100} |
| 1361 | Lₐ₁₄₇₅ | L_{b100} | 1362 | Lₐ₁₄₇₆ | L_{b100} |
| 1363 | Lₐ₁₄₇₇ | L_{b100} | 1364 | Lₐ₁₄₇₈ | L_{b100} |
| 1365 | Lₐ₁₄₇₉ | L_{b100} | 1366 | Lₐ₁₄₈₀ | L_{b100} |
| 1367 | Lₐ₁₄₈₁ | L_{b100} | 1368 | Lₐ₁₄₈₂ | L_{b100} |
| 1369 | Lₐ₁₄₈₃ | L_{b100} | 1370 | Lₐ₁₄₈₄ | L_{b100} |
| 1371 | Lₐ₁₄₈₅ | L_{b100} | 1372 | Lₐ₁₄₈₆ | L_{b100} |
| 1373 | Lₐ₁₄₈₇ | L_{b100} | 1374 | Lₐ₁₄₈₈ | L_{b100} |
| 1375 | Lₐ₁₄₈₉ | L_{b100} | 1376 | Lₐ₁₄₉₀ | L_{b100} |
| 1377 | Lₐ₁₄₉₁ | L_{b100} | 1378 | Lₐ₁₄₉₂ | L_{b100} |
| 1379 | Lₐ₁₄₉₃ | L_{b100} | 1380 | Lₐ₁₄₉₄ | L_{b100} |
| 1381 | Lₐ₁₄₉₅ | L_{b100} | 1382 | Lₐ₁₄₉₆ | L_{b100} |
| 1383 | Lₐ₁₄₉₇ | L_{b100} | 1384 | Lₐ₁₄₉₈ | L_{b100} |
| 1385 | Lₐ₁₄₉₉ | L_{b100} | 1386 | Lₐ₁₅₀₀ | L_{b100} |
| 1387 | Lₐ₁₅₀₁ | L_{b100} | 1388 | Lₐ₁₅₀₂ | L_{b100} |
| 1389 | Lₐ₁₅₀₃ | L_{b100} | 1390 | Lₐ₁₅₀₄ | L_{b100} |
| 1391 | Lₐ₁₅₀₅ | L_{b100} | 1392 | Lₐ₁₅₀₆ | L_{b100} |
| 1393 | Lₐ₁₅₀₇ | L_{b100} | 1394 | Lₐ₁₅₀₈ | L_{b100} |
| 1395 | Lₐ₁₅₀₉ | L_{b100} | 1396 | Lₐ₁₅₁₀ | L_{b100} |
| 1397 | Lₐ₁₅₁₁ | L_{b100} | 1398 | Lₐ₁₅₁₂ | L_{b100} |
| 1399 | Lₐ₁₅₁₃ | L_{b100} | 1400 | Lₐ₁₅₁₄ | L_{b100} |
| 1401 | Lₐ₁₅₁₅ | L_{b100} | 1402 | Lₐ₁₅₁₆ | L_{b100} |
| 1403 | Lₐ₁₅₁₇ | L_{b100} | 1404 | Lₐ₁₅₁₈ | L_{b100} |
| 1405 | Lₐ₁₅₁₉ | L_{b100} | 1406 | Lₐ₁₅₂₀ | L_{b100} |
| 1407 | Lₐ₁₅₂₁ | L_{b100} | 1408 | Lₐ₁₅₂₂ | L_{b100} |
| 1409 | Lₐ₁₅₂₃ | L_{b100} | 1410 | Lₐ₁₅₂₄ | L_{b100} |
| 1411 | Lₐ₁₅₂₅ | L_{b100} | 1412 | Lₐ₁₅₂₆ | L_{b100} |
| 1413 | Lₐ₁₅₂₇ | L_{b100} | 1414 | Lₐ₁₅₂₈ | L_{b100} |
| 1415 | Lₐ₁₅₂₉ | L_{b100} | 1416 | Lₐ₁₅₃₀ | L_{b100} |
| 1417 | Lₐ₁₅₃₁ | L_{b100} | 1418 | Lₐ₁₅₃₂ | L_{b100} |
| 1419 | Lₐ₁₅₃₃ | L_{b100} | 1420 | Lₐ₁₅₃₄ | L_{b100} |
| 1421 | Lₐ₁₅₃₅ | L_{b100} | 1422 | Lₐ₁₅₃₆ | L_{b100} |
| 1423 | Lₐ₁₅₃₇ | L_{b100} | 1424 | Lₐ₁₅₃₈ | L_{b100} |
| 1425 | Lₐ₁₅₃₉ | L_{b100} | 1426 | Lₐ₁₅₄₀ | L_{b100} |
| 1427 | Lₐ₁₅₄₁ | L_{b100} | 1428 | Lₐ₁₅₄₂ | L_{b100} |
| 1429 | Lₐ₁₅₄₃ | L_{b100} | 1430 | Lₐ₁₅₄₄ | L_{b100} |
| 1431 | Lₐ₁₅₄₅ | L_{b100} | 1432 | Lₐ₁₅₄₆ | L_{b100} |
| 1433 | Lₐ₁₅₄₇ | L_{b100} | 1434 | Lₐ₁₅₄₈ | L_{b100} |
| 1435 | Lₐ₁₅₄₉ | L_{b100} | 1436 | Lₐ₁₅₅₀ | L_{b100} |
| 1437 | Lₐ₁₅₅₁ | L_{b100} | 1438 | Lₐ₁₅₅₂ | L_{b100} |
| 1439 | Lₐ₁₅₅₃ | L_{b100} | 1440 | Lₐ₁₅₅₄ | L_{b100} |
| 1441 | Lₐ₁ | L_{b125} | 1442 | Lₐ₂ | L_{b125} |
| 1443 | Lₐ₃ | L_{b125} | 1444 | Lₐ₄ | L_{b125} |
| 1445 | Lₐ₅ | L_{b125} | 1446 | Lₐ₆ | L_{b125} |
| 1447 | Lₐ₇ | L_{b125} | 1448 | Lₐ₈ | L_{b125} |
| 1449 | Lₐ₉ | L_{b125} | 1450 | Lₐ₁₀ | L_{b125} |
| 1451 | Lₐ₁₁ | L_{b125} | 1452 | Lₐ₁₂ | L_{b125} |
| 1453 | Lₐ₁₃ | L_{b125} | 1454 | Lₐ₁₄ | L_{b125} |
| 1455 | Lₐ₁₅ | L_{b125} | 1456 | Lₐ₁₆ | L_{b125} |
| 1457 | Lₐ₁₇ | L_{b125} | 1458 | Lₐ₁₈ | L_{b125} |
| 1459 | Lₐ₁₉ | L_{b125} | 1460 | Lₐ₂₀ | L_{b125} |
| 1461 | Lₐ₂₁ | L_{b125} | 1462 | Lₐ₂₂ | L_{b125} |
| 1463 | Lₐ₂₃ | L_{b125} | 1464 | Lₐ₂₄ | L_{b125} |
| 1465 | Lₐ₂₅ | L_{b125} | 1466 | Lₐ₂₆ | L_{b125} |
| 1467 | Lₐ₂₇ | L_{b125} | 1468 | Lₐ₂₈ | L_{b125} |
| 1469 | Lₐ₂₉ | L_{b125} | 1470 | Lₐ₃₀ | L_{b125} |
| 1471 | Lₐ₃₁ | L_{b125} | 1472 | Lₐ₃₂ | L_{b125} |
| 1473 | Lₐ₃₃ | L_{b125} | 1474 | Lₐ₃₄ | L_{b125} |
| 1475 | Lₐ₃₅ | L_{b125} | 1476 | Lₐ₃₆ | L_{b125} |
| 1477 | Lₐ₃₇ | L_{b125} | 1478 | Lₐ₃₈ | L_{b125} |
| 1479 | Lₐ₃₉ | L_{b125} | 1480 | Lₐ₄₀ | L_{b125} |
| 1481 | Lₐ₄₁ | L_{b125} | 1482 | Lₐ₄₂ | L_{b125} |
| 1483 | Lₐ₄₃ | L_{b125} | 1484 | Lₐ₄₄ | L_{b125} |
| 1485 | Lₐ₄₅ | L_{b125} | 1486 | Lₐ₄₆ | L_{b125} |
| 1487 | Lₐ₄₇ | L_{b125} | 1488 | Lₐ₄₈ | L_{b125} |
| 1489 | Lₐ₄₉ | L_{b125} | 1490 | Lₐ₅₀ | L_{b125} |
| 1491 | Lₐ₅₁ | L_{b125} | 1492 | Lₐ₅₂ | L_{b125} |
| 1493 | Lₐ₅₃ | L_{b125} | 1494 | Lₐ₅₄ | L_{b125} |
| 1495 | Lₐ₅₅ | L_{b125} | 1496 | Lₐ₅₆ | L_{b125} |
| 1497 | Lₐ₅₇ | L_{b125} | 1498 | Lₐ₅₈ | L_{b125} |
| 1499 | Lₐ₅₉ | L_{b125} | 1500 | Lₐ₆₀ | L_{b125} |
| 1501 | Lₐ₆₁ | L_{b125} | 1502 | Lₐ₆₂ | L_{b125} |
| 1503 | Lₐ₆₃ | L_{b125} | 1504 | Lₐ₆₄ | L_{b125} |
| 1505 | Lₐ₆₅ | L_{b125} | 1506 | Lₐ₆₆ | L_{b125} |
| 1507 | Lₐ₆₇ | L_{b125} | 1508 | Lₐ₆₈ | L_{b125} |
| 1509 | Lₐ₆₉ | L_{b125} | 1510 | Lₐ₇₀ | L_{b125} |
| 1511 | Lₐ₇₁ | L_{b125} | 1512 | Lₐ₇₂ | L_{b125} |
| 1513 | Lₐ₇₃ | L_{b125} | 1514 | Lₐ₇₄ | L_{b125} |
| 1515 | Lₐ₇₅ | L_{b125} | 1516 | Lₐ₇₆ | L_{b125} |
| 1517 | Lₐ₇₇ | L_{b125} | 1518 | Lₐ₇₈ | L_{b125} |
| 1519 | Lₐ₇₉ | L_{b125} | 1520 | Lₐ₈₀ | L_{b125} |
| 1521 | Lₐ₈₁ | L_{b125} | 1522 | Lₐ₈₂ | L_{b125} |
| 1523 | Lₐ₈₃ | L_{b125} | 1524 | Lₐ₈₄ | L_{b125} |
| 1525 | Lₐ₈₅ | L_{b125} | 1526 | Lₐ₈₆ | L_{b125} |
| 1527 | Lₐ₈₇ | L_{b125} | 1528 | Lₐ₈₈ | L_{b125} |
| 1529 | Lₐ₈₉ | L_{b125} | 1530 | Lₐ₉₀ | L_{b125} |
| 1531 | Lₐ₁₈₁ | L_{b125} | 1532 | Lₐ₁₈₂ | L_{b125} |
| 1533 | Lₐ₁₈₃ | L_{b125} | 1534 | Lₐ₁₈₄ | L_{b125} |
| 1535 | Lₐ₁₈₅ | L_{b125} | 1536 | Lₐ₁₈₆ | L_{b125} |
| 1537 | Lₐ₁₈₇ | L_{b125} | 1538 | Lₐ₁₈₈ | L_{b125} |
| 1539 | Lₐ₁₈₉ | L_{b125} | 1540 | Lₐ₁₉₀ | L_{b125} |
| 1541 | Lₐ₁₉₁ | L_{b125} | 1542 | Lₐ₁₉₂ | L_{b125} |
| 1543 | Lₐ₁₉₃ | L_{b125} | 1544 | Lₐ₁₉₄ | L_{b125} |
| 1545 | Lₐ₁₉₅ | L_{b125} | 1546 | Lₐ₁₉₆ | L_{b125} |
| 1547 | Lₐ₁₉₇ | L_{b125} | 1548 | Lₐ₁₉₈ | L_{b125} |
| 1549 | Lₐ₁₉₉ | L_{b125} | 1550 | Lₐ₂₀₀ | L_{b125} |
| 1551 | Lₐ₂₀₁ | L_{b125} | 1552 | Lₐ₂₀₂ | L_{b125} |
| 1553 | Lₐ₂₀₃ | L_{b125} | 1554 | Lₐ₂₀₄ | L_{b125} |
| 1555 | Lₐ₂₀₅ | L_{b125} | 1556 | Lₐ₂₀₆ | L_{b125} |
| 1557 | Lₐ₂₀₇ | L_{b125} | 1558 | Lₐ₂₀₈ | L_{b125} |
| 1559 | Lₐ₂₀₉ | L_{b125} | 1560 | Lₐ₂₁₀ | L_{b125} |
| 1561 | Lₐ₂₁₁ | L_{b125} | 1562 | Lₐ₂₁₂ | L_{b125} |
| 1563 | Lₐ₂₁₃ | L_{b125} | 1564 | Lₐ₂₁₄ | L_{b125} |
| 1565 | Lₐ₂₁₅ | L_{b125} | 1566 | Lₐ₂₁₆ | L_{b125} |
| 1567 | Lₐ₂₁₇ | L_{b125} | 1568 | Lₐ₂₁₈ | L_{b125} |
| 1569 | Lₐ₂₁₉ | L_{b125} | 1570 | Lₐ₂₂₀ | L_{b125} |
| 1571 | Lₐ₂₂₁ | L_{b125} | 1572 | Lₐ₂₂₂ | L_{b125} |
| 1573 | Lₐ₂₂₃ | L_{b125} | 1574 | Lₐ₂₂₄ | L_{b125} |
| 1575 | Lₐ₂₂₅ | L_{b125} | 1576 | Lₐ₂₂₆ | L_{b125} |
| 1577 | Lₐ₂₂₇ | L_{b125} | 1578 | Lₐ₂₂₈ | L_{b125} |
| 1579 | Lₐ₂₂₉ | L_{b125} | 1580 | Lₐ₂₃₀ | L_{b125} |
| 1581 | Lₐ₂₃₁ | L_{b125} | 1582 | Lₐ₂₃₂ | L_{b125} |
| 1583 | Lₐ₂₃₃ | L_{b125} | 1584 | Lₐ₂₃₄ | L_{b125} |
| 1585 | Lₐ₂₃₅ | L_{b125} | 1586 | Lₐ₂₃₆ | L_{b125} |
| 1587 | Lₐ₂₃₇ | L_{b125} | 1588 | Lₐ₂₃₈ | L_{b125} |
| 1589 | Lₐ₂₃₉ | L_{b125} | 1590 | Lₐ₂₄₀ | L_{b125} |
| 1591 | Lₐ₂₄₁ | L_{b125} | 1592 | Lₐ₂₄₂ | L_{b125} |
| 1593 | Lₐ₂₄₃ | L_{b125} | 1594 | Lₐ₂₄₄ | L_{b125} |
| 1595 | Lₐ₂₄₅ | L_{b125} | 1596 | Lₐ₂₄₆ | L_{b125} |
| 1597 | Lₐ₂₄₇ | L_{b125} | 1598 | Lₐ₂₄₈ | L_{b125} |
| 1599 | Lₐ₂₄₉ | L_{b125} | 1600 | Lₐ₂₅₀ | L_{b125} |
| 1601 | Lₐ₂₅₁ | L_{b125} | 1602 | Lₐ₂₅₂ | L_{b125} |
| 1603 | Lₐ₂₅₃ | L_{b125} | 1604 | Lₐ₂₅₄ | L_{b125} |
| 1605 | Lₐ₂₅₅ | L_{b125} | 1606 | Lₐ₂₅₆ | L_{b125} |
| 1607 | Lₐ₂₅₇ | L_{b125} | 1608 | Lₐ₂₅₈ | L_{b125} |
| 1609 | Lₐ₂₅₉ | L_{b125} | 1610 | Lₐ₂₆₀ | L_{b125} |
| 1611 | Lₐ₂₆₁ | L_{b125} | 1612 | Lₐ₂₆₂ | L_{b125} |
| 1613 | Lₐ₂₆₃ | L_{b125} | 1614 | Lₐ₂₆₄ | L_{b125} |
| 1615 | Lₐ₂₆₅ | L_{b125} | 1616 | Lₐ₂₆₆ | L_{b125} |
| 1617 | Lₐ₂₆₇ | L_{b125} | 1618 | Lₐ₂₆₈ | L_{b125} |
| 1619 | Lₐ₂₆₉ | L_{b125} | 1620 | Lₐ₂₇₀ | L_{b125} |
| 1621 | Lₐ₁₂₈₅ | L_{b125} | 1622 | Lₐ₁₂₈₆ | L_{b125} |
| 1623 | Lₐ₁₂₈₇ | L_{b125} | 1624 | Lₐ₁₂₈₈ | L_{b125} |
| 1625 | Lₐ₁₂₈₉ | L_{b125} | 1626 | Lₐ₁₂₉₀ | L_{b125} |
| 1627 | Lₐ₁₂₉₁ | L_{b125} | 1628 | Lₐ₁₂₉₂ | L_{b125} |
| 1629 | Lₐ₁₂₉₃ | L_{b125} | 1630 | Lₐ₁₂₉₄ | L_{b125} |
| 1631 | Lₐ₁₂₉₅ | L_{b125} | 1632 | Lₐ₁₂₉₆ | L_{b125} |
| 1633 | Lₐ₁₂₉₇ | L_{b125} | 1634 | Lₐ₁₂₉₈ | L_{b125} |
| 1635 | Lₐ₁₂₉₉ | L_{b125} | 1636 | Lₐ₁₃₀₀ | L_{b125} |
| 1637 | Lₐ₁₃₀₁ | L_{b125} | 1638 | Lₐ₁₃₀₂ | L_{b125} |
| 1639 | Lₐ₁₃₀₃ | L_{b125} | 1640 | Lₐ₁₃₀₄ | L_{b125} |
| 1641 | Lₐ₁₃₀₅ | L_{b125} | 1642 | Lₐ₁₃₀₆ | L_{b125} |
| 1643 | Lₐ₁₃₀₇ | L_{b125} | 1644 | Lₐ₁₃₀₈ | L_{b125} |
| 1645 | Lₐ₁₃₀₉ | L_{b125} | 1646 | Lₐ₁₃₁₀ | L_{b125} |
| 1647 | Lₐ₁₃₁₁ | L_{b125} | 1648 | Lₐ₁₃₁₂ | L_{b125} |
| 1649 | Lₐ₁₃₁₃ | L_{b125} | 1650 | Lₐ₁₃₁₄ | L_{b125} |
| 1651 | Lₐ₁₃₁₅ | L_{b125} | 1652 | Lₐ₁₃₁₆ | L_{b125} |
| 1653 | Lₐ₁₃₁₇ | L_{b125} | 1654 | Lₐ₁₃₁₈ | L_{b125} |
| 1655 | Lₐ₁₃₁₉ | L_{b125} | 1656 | Lₐ₁₃₂₀ | L_{b125} |
| 1657 | Lₐ₁₃₂₁ | L_{b125} | 1658 | Lₐ₁₃₂₂ | L_{b125} |
| 1659 | Lₐ₁₃₂₃ | L_{b125} | 1660 | Lₐ₁₃₂₄ | L_{b125} |
| 1661 | Lₐ₁₃₂₅ | L_{b125} | 1662 | Lₐ₁₃₂₆ | L_{b125} |
| 1663 | Lₐ₁₃₂₇ | L_{b125} | 1664 | Lₐ₁₃₂₈ | L_{b125} |
| 1665 | Lₐ₁₃₂₉ | L_{b125} | 1666 | Lₐ₁₃₃₀ | L_{b125} |
| 1667 | Lₐ₁₃₃₁ | L_{b125} | 1668 | Lₐ₁₃₃₂ | L_{b125} |
| 1669 | Lₐ₁₃₃₃ | L_{b125} | 1670 | Lₐ₁₃₃₄ | L_{b125} |
| 1671 | Lₐ₁₃₃₅ | L_{b125} | 1672 | Lₐ₁₃₃₆ | L_{b125} |
| 1673 | Lₐ₁₃₃₇ | L_{b125} | 1674 | Lₐ₁₃₃₈ | L_{b125} |
| 1675 | Lₐ₁₃₃₉ | L_{b125} | 1676 | Lₐ₁₃₄₀ | L_{b125} |
| 1677 | Lₐ₁₃₄₁ | L_{b125} | 1678 | Lₐ₁₃₄₂ | L_{b125} |
| 1679 | Lₐ₁₃₄₃ | L_{b125} | 1680 | Lₐ₁₃₄₄ | L_{b125} |
| 1681 | Lₐ₁₃₄₅ | L_{b125} | 1682 | Lₐ₁₃₄₆ | L_{b125} |
| 1683 | Lₐ₁₃₄₇ | L_{b125} | 1684 | Lₐ₁₃₄₈ | L_{b125} |
| 1685 | Lₐ₁₃₄₉ | L_{b125} | 1686 | Lₐ₁₃₅₀ | L_{b125} |
| 1687 | Lₐ₁₃₅₁ | L_{b125} | 1688 | Lₐ₁₃₅₂ | L_{b125} |
| 1689 | Lₐ₁₃₅₃ | L_{b125} | 1690 | Lₐ₁₃₅₄ | L_{b125} |
| 1691 | Lₐ₁₃₅₅ | L_{b125} | 1692 | Lₐ₁₃₅₆ | L_{b125} |
| 1693 | Lₐ₁₃₅₇ | L_{b125} | 1694 | Lₐ₁₃₅₈ | L_{b125} |
| 1695 | Lₐ₁₃₅₉ | L_{b125} | 1696 | Lₐ₁₃₆₀ | L_{b125} |
| 1697 | Lₐ₁₃₆₁ | L_{b125} | 1698 | Lₐ₁₃₆₂ | L_{b125} |
| 1699 | Lₐ₁₃₆₃ | L_{b125} | 1700 | Lₐ₁₃₆₄ | L_{b125} |
| 1701 | Lₐ₁₃₆₅ | L_{b125} | 1702 | Lₐ₁₃₆₆ | L_{b125} |
| 1703 | Lₐ₁₃₆₇ | L_{b125} | 1704 | Lₐ₁₃₆₈ | L_{b125} |
| 1705 | Lₐ₁₃₆₉ | L_{b125} | 1706 | Lₐ₁₃₇₀ | L_{b125} |
| 1707 | Lₐ₁₃₇₁ | L_{b125} | 1708 | Lₐ₁₃₇₂ | L_{b125} |
| 1709 | Lₐ₁₃₇₃ | L_{b125} | 1710 | Lₐ₁₃₇₄ | L_{b125} |
| 1711 | Lₐ₁₄₆₅ | L_{b125} | 1712 | Lₐ₁₄₆₆ | L_{b125} |
| 1713 | Lₐ₁₄₆₇ | L_{b125} | 1714 | Lₐ₁₄₆₈ | L_{b125} |
| 1715 | Lₐ₁₄₆₉ | L_{b125} | 1716 | Lₐ₁₄₇₀ | L_{b125} |
| 1717 | Lₐ₁₄₇₁ | L_{b125} | 1718 | Lₐ₁₄₇₂ | L_{b125} |
| 1719 | Lₐ₁₄₇₃ | L_{b125} | 1720 | Lₐ₁₄₇₄ | L_{b125} |
| 1721 | Lₐ₁₄₇₅ | L_{b125} | 1722 | Lₐ₁₄₇₆ | L_{b125} |
| 1723 | Lₐ₁₄₇₇ | L_{b125} | 1724 | Lₐ₁₄₇₈ | L_{b125} |
| 1725 | Lₐ₁₄₇₉ | L_{b125} | 1726 | Lₐ₁₄₈₀ | L_{b125} |
| 1727 | Lₐ₁₄₈₁ | L_{b125} | 1728 | Lₐ₁₄₈₂ | L_{b125} |
| 1729 | Lₐ₁₄₈₃ | L_{b125} | 1730 | Lₐ₁₄₈₄ | L_{b125} |
| 1731 | Lₐ₁₄₈₅ | L_{b125} | 1732 | Lₐ₁₄₈₆ | L_{b125} |
| 1733 | Lₐ₁₄₈₇ | L_{b125} | 1734 | Lₐ₁₄₈₈ | L_{b125} |
| 1735 | Lₐ₁₄₈₉ | L_{b125} | 1736 | Lₐ₁₄₉₀ | L_{b125} |
| 1737 | Lₐ₁₄₉₁ | L_{b125} | 1738 | Lₐ₁₄₉₂ | L_{b125} |
| 1739 | Lₐ₁₄₉₃ | L_{b125} | 1740 | Lₐ₁₄₉₄ | L_{b125} |
| 1741 | Lₐ₁₄₉₅ | L_{b125} | 1742 | Lₐ₁₄₉₆ | L_{b125} |
| 1743 | Lₐ₁₄₉₇ | L_{b125} | 1744 | Lₐ₁₄₉₈ | L_{b125} |
| 1745 | Lₐ₁₄₉₉ | L_{b125} | 1746 | Lₐ₁₅₀₀ | L_{b125} |
| 1747 | Lₐ₁₅₀₁ | L_{b125} | 1748 | Lₐ₁₅₀₂ | L_{b125} |
| 1749 | Lₐ₁₅₀₃ | L_{b125} | 1750 | Lₐ₁₅₀₄ | L_{b125} |
| 1751 | Lₐ₁₅₀₅ | L_{b125} | 1752 | Lₐ₁₅₀₆ | L_{b125} |
| 1753 | Lₐ₁₅₀₇ | L_{b125} | 1754 | Lₐ₁₅₀₈ | L_{b125} |
| 1755 | Lₐ₁₅₀₉ | L_{b125} | 1756 | Lₐ₁₅₁₀ | L_{b125} |
| 1757 | Lₐ₁₅₁₁ | L_{b125} | 1758 | Lₐ₁₅₁₂ | L_{b125} |
| 1759 | Lₐ₁₅₁₃ | L_{b125} | 1760 | Lₐ₁₅₁₄ | L_{b125} |
| 1761 | Lₐ₁₅₁₅ | L_{b125} | 1762 | Lₐ₁₅₁₆ | L_{b125} |
| 1763 | Lₐ₁₅₁₇ | L_{b125} | 1764 | Lₐ₁₅₁₈ | L_{b125} |
| 1765 | Lₐ₁₅₁₉ | L_{b125} | 1766 | Lₐ₁₅₂₀ | L_{b125} |
| 1767 | Lₐ₁₅₂₁ | L_{b125} | 1768 | Lₐ₁₅₂₂ | L_{b125} |
| 1769 | Lₐ₁₅₂₃ | L_{b125} | 1770 | Lₐ₁₅₂₄ | L_{b125} |
| 1771 | Lₐ₁₅₂₅ | L_{b125} | 1772 | Lₐ₁₅₂₆ | L_{b125} |
| 1773 | Lₐ₁₅₂₇ | L_{b125} | 1774 | Lₐ₁₅₂₈ | L_{b125} |
| 1775 | Lₐ₁₅₂₉ | L_{b125} | 1776 | Lₐ₁₅₃₀ | L_{b125} |
| 1777 | Lₐ₁₅₃₁ | L_{b125} | 1778 | Lₐ₁₅₃₂ | L_{b125} |
| 1779 | Lₐ₁₅₃₃ | L_{b125} | 1780 | Lₐ₁₅₃₄ | L_{b125} |
| 1781 | Lₐ₁₅₃₅ | L_{b125} | 1782 | Lₐ₁₅₃₆ | L_{b125} |
| 1783 | Lₐ₁₅₃₇ | L_{b125} | 1784 | Lₐ₁₅₃₈ | L_{b125} |
| 1785 | Lₐ₁₅₃₉ | L_{b125} | 1786 | Lₐ₁₅₄₀ | L_{b125} |
| 1787 | Lₐ₁₅₄₁ | L_{b125} | 1788 | Lₐ₁₅₄₂ | L_{b125} |
| 1789 | Lₐ₁₅₄₃ | L_{b125} | 1790 | Lₐ₁₅₄₄ | L_{b125} |
| 1791 | Lₐ₁₅₄₅ | L_{b125} | 1792 | Lₐ₁₅₄₆ | L_{b125} |
| 1793 | Lₐ₁₅₄₇ | L_{b125} | 1794 | Lₐ₁₅₄₈ | L_{b125} |
| 1795 | Lₐ₁₅₄₉ | L_{b125} | 1796 | Lₐ₁₅₅₀ | L_{b125} |
| 1797 | Lₐ₁₅₅₁ | L_{b125} | 1798 | Lₐ₁₅₅₂ | L_{b125} |
| 1799 | Lₐ₁₅₅₃ | L_{b125} | 1800 | Lₐ₁₅₅₄ | L_{b125} |
| 1801 | Lₐ₁₃₇₅ | L_{b52} | 1802 | Lₐ₁₃₇₆ | L_{b52} |
| 1803 | Lₐ₁₃₈₂ | L_{b52} | 1804 | Lₐ₁₃₈₅ | L_{b52} |
| 1805 | Lₐ₁₃₈₆ | L_{b52} | 1806 | Lₐ₁₃₈₇ | L_{b52} |
| 1807 | Lₐ₁₃₉₄ | L_{b52} | 1808 | Lₐ₁₃₉₇ | L_{b52} |
| 1809 | Lₐ₁₄₀₀ | L_{b52} | 1810 | Lₐ₁₄₀₂ | L_{b52} |
| 1811 | Lₐ₁₄₀₅ | L_{b52} | 1812 | Lₐ₁₄₀₆ | L_{b52} |
| 1813 | Lₐ₁₄₀₇ | L_{b52} | 1814 | Lₐ₁₄₁₁ | L_{b52} |
| 1815 | Lₐ₁₄₁₃ | L_{b52} | 1816 | Lₐ₁₄₁₄ | L_{b52} |
| 1817 | Lₐ₁₄₁₆ | L_{b52} | 1818 | Lₐ₁₄₁₉ | L_{b52} |
| 1819 | Lₐ₁₅₅₅ | L_{b52} | 1820 | Lₐ₁₅₅₆ | L_{b52} |
| 1821 | Lₐ₁₅₆₂ | L_{b52} | 1822 | Lₐ₁₅₆₅ | L_{b52} |
| 1823 | Lₐ₁₅₆₆ | L_{b52} | 1824 | Lₐ₁₅₆₇ | L_{b52} |
| 1825 | Lₐ₁₅₇₄ | L_{b52} | 1826 | Lₐ₁₅₇₇ | L_{b52} |
| 1827 | Lₐ₁₅₈₀ | L_{b52} | 1828 | Lₐ₁₅₈₂ | L_{b52} |
| 1829 | Lₐ₁₅₈₅ | L_{b52} | 1830 | Lₐ₁₅₈₆ | L_{b52} |
| 1831 | Lₐ₁₅₈₇ | L_{b52} | 1832 | Lₐ₁₅₉₁ | L_{b52} |
| 1833 | Lₐ₁₅₉₃ | L_{b52} | 1834 | Lₐ₁₅₉₄ | L_{b52} |
| 1835 | Lₐ₁₅₉₆ | L_{b52} | 1836 | Lₐ₁₅₉₉ | L_{b52} |
| 1837 | Lₐ₁₉₁₅ | L_{b52} | 1838 | Lₐ₁₉₁₆ | L_{b52} |
| 1839 | Lₐ₁₉₂₂ | L_{b52} | 1840 | Lₐ₁₉₂₅ | L_{b52} |
| 1841 | Lₐ₁₉₂₆ | L_{b52} | 1842 | Lₐ₁₉₂₇ | L_{b52} |
| 1843 | Lₐ₁₉₃₄ | L_{b52} | 1844 | Lₐ₁₉₃₇ | L_{b52} |
| 1845 | Lₐ₁₉₄₀ | L_{b52} | 1846 | Lₐ₁₉₄₂ | L_{b52} |
| 1847 | Lₐ₁₉₄₅ | L_{b52} | 1848 | Lₐ₁₉₄₆ | L_{b52} |
| 1849 | Lₐ₁₉₄₇ | L_{b52} | 1850 | Lₐ₁₉₅₁ | L_{b52} |
| 1851 | Lₐ₁₉₅₃ | L_{b52} | 1852 | Lₐ₁₉₅₄ | L_{b52} |
| 1853 | Lₐ₁₉₅₆ | L_{b52} | 1854 | Lₐ₁₉₅₉ | L_{b52} |
| 1855 | Lₐ₂₀₀₅ | L_{b52} | 1856 | Lₐ₂₀₀₆ | L_{b52} |
| 1857 | Lₐ₂₀₁₂ | L_{b52} | 1858 | Lₐ₂₀₁₅ | L_{b52} |
| 1859 | Lₐ₂₀₁₆ | L_{b52} | 1860 | Lₐ₂₀₁₇ | L_{b52} |
| 1861 | Lₐ₂₀₂₄ | L_{b52} | 1862 | Lₐ₂₀₂₇ | L_{b52} |
| 1863 | Lₐ₂₀₃₀ | L_{b52} | 1864 | Lₐ₂₀₃₂ | L_{b52} |
| 1865 | Lₐ₂₀₃₅ | L_{b52} | 1866 | Lₐ₂₀₃₆ | L_{b52} |
| 1867 | Lₐ₂₀₃₇ | L_{b52} | 1868 | Lₐ₂₀₄₁ | L_{b52} |
| 1869 | Lₐ₂₀₄₃ | L_{b52} | 1870 | Lₐ₂₀₄₄ | L_{b52} |
| 1871 | Lₐ₂₀₄₆ | L_{b52} | 1872 | Lₐ₂₀₄₉ | L_{b52} |
| 1873 | Lₐ₂₀₉₅ | L_{b52} | 1874 | Lₐ₂₀₉₆ | L_{b52} |
| 1875 | Lₐ₂₁₀₂ | L_{b52} | 1876 | Lₐ₂₁₀₅ | L_{b52} |
| 1877 | Lₐ₂₁₀₆ | L_{b52} | 1878 | Lₐ₂₁₀₇ | L_{b52} |
| 1879 | Lₐ₂₁₁₄ | L_{b52} | 1880 | Lₐ₂₁₁₇ | L_{b52} |
| 1881 | Lₐ₂₁₂₀ | L_{b52} | 1882 | Lₐ₂₁₂₂ | L_{b52} |
| 1883 | Lₐ₂₁₂₅ | L_{b52} | 1884 | Lₐ₂₁₂₆ | L_{b52} |
| 1885 | Lₐ₂₁₂₇ | L_{b52} | 1886 | Lₐ₂₁₃₁ | L_{b52} |
| 1887 | Lₐ₂₁₃₃ | L_{b52} | 1888 | Lₐ₂₁₃₄ | L_{b52} |
| 1889 | Lₐ₂₁₃₆ | L_{b52} | 1890 | Lₐ₂₁₃₉ | L_{b52} |
| 1891 | Lₐ₁₃₇₅ | L_{b76} | 1892 | Lₐ₁₃₇₆ | L_{b76} |
| 1893 | Lₐ₁₃₈₂ | L_{b76} | 1894 | Lₐ₁₃₈₅ | L_{b76} |
| 1895 | Lₐ₁₃₈₆ | L_{b76} | 1896 | Lₐ₁₃₈₇ | L_{b76} |
| 1897 | Lₐ₁₃₉₄ | L_{b76} | 1898 | Lₐ₁₃₉₇ | L_{b76} |
| 1899 | Lₐ₁₄₀₀ | L_{b76} | 1900 | Lₐ₁₄₀₂ | L_{b76} |
| 1901 | Lₐ₁₄₀₅ | L_{b76} | 1902 | Lₐ₁₄₀₆ | L_{b76} |
| 1903 | Lₐ₁₄₀₇ | L_{b76} | 1904 | Lₐ₁₄₁₁ | L_{b76} |
| 1905 | Lₐ₁₄₁₃ | L_{b76} | 1906 | Lₐ₁₄₁₄ | L_{b76} |
| 1907 | Lₐ₁₄₁₆ | L_{b76} | 1908 | Lₐ₁₄₁₉ | L_{b76} |
| 1909 | Lₐ₁₅₅₅ | L_{b76} | 1910 | Lₐ₁₅₅₆ | L_{b76} |
| 1911 | Lₐ₁₅₆₂ | L_{b76} | 1912 | Lₐ₁₅₆₅ | L_{b76} |
| 1913 | Lₐ₁₅₆₆ | L_{b76} | 1914 | Lₐ₁₅₆₇ | L_{b76} |
| 1915 | Lₐ₁₅₇₄ | L_{b76} | 1916 | Lₐ₁₅₇₇ | L_{b76} |
| 1917 | Lₐ₁₅₈₀ | L_{b76} | 1918 | Lₐ₁₅₈₂ | L_{b76} |
| 1919 | Lₐ₁₅₈₅ | L_{b76} | 1920 | Lₐ₁₅₈₆ | L_{b76} |
| 1921 | Lₐ₁₅₈₇ | L_{b76} | 1922 | Lₐ₁₅₉₁ | L_{b76} |
| 1923 | Lₐ₁₅₉₃ | L_{b76} | 1924 | Lₐ₁₅₉₄ | L_{b76} |
| 1925 | Lₐ₁₅₉₆ | L_{b76} | 1926 | Lₐ₁₅₉₉ | L_{b76} |
| 1927 | Lₐ₁₉₁₅ | L_{b76} | 1928 | Lₐ₁₉₁₆ | L_{b76} |
| 1929 | Lₐ₁₉₂₂ | L_{b76} | 1930 | Lₐ₁₉₂₅ | L_{b76} |
| 1931 | Lₐ₁₉₂₆ | L_{b76} | 1932 | Lₐ₁₉₂₇ | L_{b76} |
| 1933 | Lₐ₁₉₃₄ | L_{b76} | 1934 | Lₐ₁₉₃₇ | L_{b76} |
| 1935 | Lₐ₁₉₄₀ | L_{b76} | 1936 | Lₐ₁₉₄₂ | L_{b76} |
| 1937 | Lₐ₁₉₄₅ | L_{b76} | 1938 | Lₐ₁₉₄₆ | L_{b76} |
| 1939 | Lₐ₁₉₄₇ | L_{b76} | 1940 | Lₐ₁₉₅₁ | L_{b76} |
| 1941 | Lₐ₁₉₅₃ | L_{b76} | 1942 | Lₐ₁₉₅₄ | L_{b76} |
| 1943 | Lₐ₁₉₅₆ | L_{b76} | 1944 | Lₐ₁₉₅₉ | L_{b76} |
| 1945 | Lₐ₂₀₀₅ | L_{b76} | 1946 | Lₐ₂₀₀₆ | L_{b76} |
| 1947 | Lₐ₂₀₁₂ | L_{b76} | 1948 | Lₐ₂₀₁₅ | L_{b76} |
| 1949 | Lₐ₂₀₁₆ | L_{b76} | 1950 | Lₐ₂₀₁₇ | L_{b76} |
| 1951 | Lₐ₂₀₂₄ | L_{b76} | 1952 | Lₐ₂₀₂₇ | L_{b76} |
| 1953 | Lₐ₂₀₃₀ | L_{b76} | 1954 | Lₐ₂₀₃₂ | L_{b76} |
| 1955 | Lₐ₂₀₃₅ | L_{b76} | 1956 | Lₐ₂₀₃₆ | L_{b76} |
| 1957 | Lₐ₂₀₃₇ | L_{b76} | 1958 | Lₐ₂₀₄₁ | L_{b76} |
| 1959 | Lₐ₂₀₄₃ | L_{b76} | 1960 | Lₐ₂₀₄₄ | L_{b76} |
| 1961 | Lₐ₂₀₄₆ | L_{b76} | 1962 | Lₐ₂₀₄₉ | L_{b76} |
| 1963 | Lₐ₂₀₉₅ | L_{b76} | 1964 | Lₐ₂₀₉₆ | L_{b76} |
| 1965 | Lₐ₂₁₀₂ | L_{b76} | 1966 | Lₐ₂₁₀₅ | L_{b76} |
| 1967 | Lₐ₂₁₀₆ | L_{b76} | 1968 | Lₐ₂₁₀₇ | L_{b76} |
| 1969 | Lₐ₂₁₁₄ | L_{b76} | 1970 | Lₐ₂₁₁₇ | L_{b76} |
| 1971 | Lₐ₂₁₂₀ | L_{b76} | 1972 | Lₐ₂₁₂₂ | L_{b76} |
| 1973 | Lₐ₂₁₂₅ | L_{b76} | 1974 | Lₐ₂₁₂₆ | L_{b76} |
| 1975 | Lₐ₂₁₂₇ | L_{b76} | 1976 | Lₐ₂₁₃₁ | L_{b76} |
| 1977 | Lₐ₂₁₃₃ | L_{b76} | 1978 | Lₐ₂₁₃₄ | L_{b76} |
| 1979 | Lₐ₂₁₃₆ | L_{b76} | 1980 | Lₐ₂₁₃₉ | L_{b76} |
| 1981 | Lₐ₁₃₇₅ | L_{b132} | 1982 | Lₐ₁₃₇₆ | L_{b132} |
| 1983 | Lₐ₁₃₈₂ | L_{b132} | 1984 | Lₐ₁₃₈₅ | L_{b132} |
| 1985 | Lₐ₁₃₈₆ | L_{b132} | 1986 | Lₐ₁₃₈₇ | L_{b132} |
| 1987 | Lₐ₁₃₉₄ | L_{b132} | 1988 | Lₐ₁₃₉₇ | L_{b132} |
| 1989 | Lₐ₁₄₀₀ | L_{b132} | 1990 | Lₐ₁₄₀₂ | L_{b132} |
| 1991 | Lₐ₁₄₀₅ | L_{b132} | 1992 | Lₐ₁₄₀₆ | L_{b132} |
| 1993 | Lₐ₁₄₀₇ | L_{b132} | 1994 | Lₐ₁₄₁₁ | L_{b132} |
| 1995 | Lₐ₁₄₁₃ | L_{b132} | 1996 | Lₐ₁₄₁₄ | L_{b132} |
| 1997 | Lₐ₁₄₁₆ | L_{b132} | 1998 | Lₐ₁₄₁₉ | L_{b132} |
| 1999 | Lₐ₁₅₅₅ | L_{b132} | 2000 | Lₐ₁₅₅₆ | L_{b132} |
| 2001 | Lₐ₁₅₆₂ | L_{b132} | 2002 | Lₐ₁₅₆₅ | L_{b132} |
| 2003 | Lₐ₁₅₆₆ | L_{b132} | 2004 | Lₐ₁₅₆₇ | L_{b132} |
| 2005 | Lₐ₁₅₇₄ | L_{b132} | 2006 | Lₐ₁₅₇₇ | L_{b132} |
| 2007 | Lₐ₁₅₈₀ | L_{b132} | 2008 | Lₐ₁₅₈₂ | L_{b132} |
| 2009 | Lₐ₁₅₈₅ | L_{b132} | 2010 | Lₐ₁₅₈₆ | L_{b132} |
| 2011 | Lₐ₁₅₈₇ | L_{b132} | 2012 | Lₐ₁₅₉₁ | L_{b132} |
| 2013 | Lₐ₁₅₉₃ | L_{b132} | 2014 | Lₐ₁₅₉₄ | L_{b132} |
| 2015 | Lₐ₁₅₉₆ | L_{b132} | 2016 | Lₐ₁₅₉₉ | L_{b132} |
| 2017 | Lₐ₁₉₁₅ | L_{b132} | 2018 | Lₐ₁₉₁₆ | L_{b132} |
| 2019 | Lₐ₁₉₂₂ | L_{b132} | 2020 | Lₐ₁₉₂₅ | L_{b132} |
| 2021 | Lₐ₁₉₂₆ | L_{b132} | 2022 | Lₐ₁₉₂₇ | L_{b132} |
| 2023 | Lₐ₁₉₃₄ | L_{b132} | 2024 | Lₐ₁₉₃₇ | L_{b132} |
| 2025 | Lₐ₁₉₄₀ | L_{b132} | 2026 | Lₐ₁₉₄₂ | L_{b132} |
| 2027 | Lₐ₁₉₄₅ | L_{b132} | 2028 | Lₐ₁₉₄₆ | L_{b132} |
| 2029 | Lₐ₁₉₄₇ | L_{b132} | 2030 | Lₐ₁₉₅₁ | L_{b132} |
| 2031 | Lₐ₁₉₅₃ | L_{b132} | 2032 | Lₐ₁₉₅₄ | L_{b132} |
| 2033 | Lₐ₁₉₅₆ | L_{b132} | 2034 | Lₐ₁₉₅₉ | L_{b132} |
| 2035 | Lₐ₂₀₀₅ | L_{b132} | 2036 | Lₐ₂₀₀₆ | L_{b132} |
| 2037 | Lₐ₂₀₁₂ | L_{b132} | 2038 | Lₐ₂₀₁₅ | L_{b132} |
| 2039 | Lₐ₂₀₁₆ | L_{b132} | 2040 | Lₐ₂₀₁₇ | L_{b132} |
| 2041 | Lₐ₂₀₂₄ | L_{b132} | 2042 | Lₐ₂₀₂₇ | L_{b132} |
| 2043 | Lₐ₂₀₃₀ | L_{b132} | 2044 | Lₐ₂₀₃₂ | L_{b132} |
| 2045 | Lₐ₂₀₃₅ | L_{b132} | 2046 | Lₐ₂₀₃₆ | L_{b132} |
| 2047 | Lₐ₂₀₃₇ | L_{b132} | 2048 | Lₐ₂₀₄₁ | L_{b132} |
| 2049 | Lₐ₂₀₄₃ | L_{b132} | 2050 | Lₐ₂₀₄₄ | L_{b132} |
| 2051 | Lₐ₂₀₄₆ | L_{b132} | 2052 | Lₐ₂₀₄₉ | L_{b132} |
| 2053 | Lₐ₂₀₉₅ | L_{b132} | 2054 | Lₐ₂₀₉₆ | L_{b132} |
| 2055 | Lₐ₂₁₀₂ | L_{b132} | 2056 | Lₐ₂₁₀₅ | L_{b132} |
| 2057 | Lₐ₂₁₀₆ | L_{b132} | 2058 | Lₐ₂₁₀₇ | L_{b132} |
| 2059 | Lₐ₂₁₁₄ | L_{b132} | 2060 | Lₐ₂₁₁₇ | L_{b132} |
| 2061 | Lₐ₂₁₂₀ | L_{b132} | 2062 | Lₐ₂₁₂₂ | L_{b132} |
| 2063 | Lₐ₂₁₂₅ | L_{b132} | 2064 | Lₐ₂₁₂₆ | L_{b132} |
| 2065 | Lₐ₂₁₂₇ | L_{b132} | 2066 | Lₐ₂₁₃₁ | L_{b132} |
| 2067 | Lₐ₂₁₃₃ | L_{b132} | 2068 | Lₐ₂₁₃₄ | L_{b132} |
| 2069 | Lₐ₂₁₃₆ | L_{b132} | 2070 | Lₐ₂₁₃₉ | L_{b132} |
| 2071 | Lₐ₁₃₇₅ | L_{b100} | 2072 | Lₐ₁₃₇₆ | L_{b100} |
| 2073 | Lₐ₁₃₈₂ | L_{b100} | 2074 | Lₐ₁₃₈₅ | L_{b100} |
| 2075 | Lₐ₁₃₈₆ | L_{b100} | 2076 | Lₐ₁₃₈₇ | L_{b100} |
| 2077 | Lₐ₁₃₉₄ | L_{b100} | 2078 | Lₐ₁₃₉₇ | L_{b100} |
| 2079 | Lₐ₁₄₀₀ | L_{b100} | 2080 | Lₐ₁₄₀₂ | L_{b100} |
| 2081 | Lₐ₁₄₀₅ | L_{b100} | 2082 | Lₐ₁₄₀₆ | L_{b100} |
| 2083 | Lₐ₁₄₀₇ | L_{b100} | 2084 | Lₐ₁₄₁₁ | L_{b100} |
| 2085 | Lₐ₁₄₁₃ | L_{b100} | 2086 | Lₐ₁₄₁₄ | L_{b100} |
| 2087 | Lₐ₁₄₁₆ | L_{b100} | 2088 | Lₐ₁₄₁₉ | L_{b100} |
| 2089 | Lₐ₁₅₅₅ | L_{b100} | 2090 | Lₐ₁₅₅₆ | L_{b100} |
| 2091 | Lₐ₁₅₆₂ | L_{b100} | 2092 | Lₐ₁₅₆₅ | L_{b100} |
| 2093 | Lₐ₁₅₆₆ | L_{b100} | 2094 | Lₐ₁₅₆₇ | L_{b100} |
| 2095 | Lₐ₁₅₇₄ | L_{b100} | 2096 | Lₐ₁₅₇₇ | L_{b100} |
| 2097 | Lₐ₁₅₈₀ | L_{b100} | 2098 | Lₐ₁₅₈₂ | L_{b100} |
| 2099 | Lₐ₁₅₈₅ | L_{b100} | 2100 | Lₐ₁₅₈₆ | L_{b100} |
| 2101 | Lₐ₁₅₈₇ | L_{b100} | 2102 | Lₐ₁₅₉₁ | L_{b100} |
| 2103 | Lₐ₁₅₉₃ | L_{b100} | 2104 | Lₐ₁₅₉₄ | L_{b100} |
| 2105 | Lₐ₁₅₉₆ | L_{b100} | 2106 | Lₐ₁₅₉₉ | L_{b100} |
| 2107 | Lₐ₁₉₁₅ | L_{b100} | 2108 | Lₐ₁₉₁₆ | L_{b100} |
| 2109 | Lₐ₁₉₂₂ | L_{b100} | 2110 | Lₐ₁₉₂₅ | L_{b100} |
| 2111 | Lₐ₁₉₂₆ | L_{b100} | 2112 | Lₐ₁₉₂₇ | L_{b100} |
| 2113 | Lₐ₁₉₃₄ | L_{b100} | 2114 | Lₐ₁₉₃₇ | L_{b100} |
| 2115 | Lₐ₁₉₄₀ | L_{b100} | 2116 | Lₐ₁₉₄₂ | L_{b100} |
| 2117 | Lₐ₁₉₄₅ | L_{b100} | 2118 | Lₐ₁₉₄₆ | L_{b100} |
| 2119 | Lₐ₁₉₄₇ | L_{b100} | 2120 | Lₐ₁₉₅₁ | L_{b100} |
| 2121 | Lₐ₁₉₅₃ | L_{b100} | 2122 | Lₐ₁₉₅₄ | L_{b100} |
| 2123 | Lₐ₁₉₅₆ | L_{b100} | 2124 | Lₐ₁₉₅₉ | L_{b100} |
| 2125 | Lₐ₂₀₀₅ | L_{b100} | 2126 | Lₐ₂₀₀₆ | L_{b100} |
| 2127 | Lₐ₂₀₁₂ | L_{b100} | 2128 | Lₐ₂₀₁₅ | L_{b100} |
| 2129 | Lₐ₂₀₁₆ | L_{b100} | 2130 | Lₐ₂₀₁₇ | L_{b100} |
| 2131 | Lₐ₂₀₂₄ | L_{b100} | 2132 | Lₐ₂₀₂₇ | L_{b100} |
| 2133 | Lₐ₂₀₃₀ | L_{b100} | 2134 | Lₐ₂₀₃₂ | L_{b100} |
| 2135 | Lₐ₂₀₃₅ | L_{b100} | 2136 | Lₐ₂₀₃₆ | L_{b100} |
| 2137 | Lₐ₂₀₃₇ | L_{b100} | 2138 | Lₐ₂₀₄₁ | L_{b100} |
| 2139 | Lₐ₂₀₄₃ | L_{b100} | 2140 | Lₐ₂₀₄₄ | L_{b100} |
| 2141 | Lₐ₂₀₄₆ | L_{b100} | 2142 | Lₐ₂₀₄₉ | L_{b100} |
| 2143 | Lₐ₂₀₉₅ | L_{b100} | 2144 | Lₐ₂₀₉₆ | L_{b100} |
| 2145 | Lₐ₂₁₀₂ | L_{b100} | 2146 | Lₐ₂₁₀₅ | L_{b100} |
| 2147 | Lₐ₂₁₀₆ | L_{b100} | 2148 | Lₐ₂₁₀₇ | L_{b100} |
| 2149 | Lₐ₂₁₁₄ | L_{b100} | 2150 | Lₐ₂₁₁₇ | L_{b100} |
| 2151 | Lₐ₂₁₂₀ | L_{b100} | 2152 | Lₐ₂₁₂₂ | L_{b100} |
| 2153 | Lₐ₂₁₂₅ | L_{b100} | 2154 | Lₐ₂₁₂₆ | L_{b100} |
| 2155 | Lₐ₂₁₂₇ | L_{b100} | 2156 | Lₐ₂₁₃₁ | L_{b100} |
| 2157 | Lₐ₂₁₃₃ | L_{b100} | 2158 | Lₐ₂₁₃₄ | L_{b100} |
| 2159 | Lₐ₂₁₃₆ | L_{b100} | 2160 | Lₐ₂₁₃₉ | L_{b100} |
| 2161 | Lₐ₂₅₆₉ | L_{b147} | 2162 | Lₐ₂₅₇₀ | L_{b147} |
| 2163 | Lₐ₂₅₇₁ | L_{b147} | 2164 | Lₐ₂₅₇₂ | L_{b147} |
| 2165 | Lₐ₂₅₇₃ | L_{b147} | 2166 | Lₐ₂₅₇₄ | L_{b147} |
| 2167 | Lₐ₂₅₇₅ | L_{b147} | 2168 | Lₐ₂₅₇₆ | L_{b147} |
| 2169 | Lₐ₂₅₇₇ | L_{b147} | 2170 | Lₐ₂₅₇₈ | L_{b147} |
| 2171 | Lₐ₂₅₇₉ | L_{b147} | 2172 | Lₐ₂₅₈₀ | L_{b147} |
| 2173 | Lₐ₂₅₈₁ | L_{b147} | 2174 | Lₐ₂₅₈₂ | L_{b147} |
| 2175 | Lₐ₂₅₈₃ | L_{b147} | 2176 | Lₐ₂₅₈₄ | L_{b147} |
| 2177 | Lₐ₂₅₈₅ | L_{b147} | 2178 | Lₐ₂₅₈₆ | L_{b147} |
| 2179 | Lₐ₂₅₈₇ | L_{b147} | 2180 | Lₐ₂₅₈₈ | L_{b147} |
| 2181 | Lₐ₂₅₈₉ | L_{b147} | 2182 | Lₐ₂₅₉₀ | L_{b147} |
| 2183 | Lₐ₂₅₉₁ | L_{b147} | 2184 | Lₐ₂₅₉₂ | L_{b147} |
| 2185 | Lₐ₂₅₉₃ | L_{b147} | 2186 | Lₐ₂₅₉₄ | L_{b147} |
| 2187 | Lₐ₂₅₉₅ | L_{b147} | 2188 | Lₐ₂₅₉₆ | L_{b147} |
| 2189 | Lₐ₂₅₉₇ | L_{b147} | 2190 | Lₐ₂₅₉₈ | L_{b147} |
| 2191 | Lₐ₂₅₉₉ | L_{b147} | 2192 | Lₐ₂₆₀₀ | L_{b147} |
| 2193 | Lₐ₂₆₀₁ | L_{b147} | 2194 | Lₐ₂₆₀₂ | L_{b147} |
| 2195 | Lₐ₂₆₀₃ | L_{b147} | 2196 | Lₐ₂₆₀₄ | L_{b147} |
| 2197 | Lₐ₂₆₀₅ | L_{b147} | 2198 | Lₐ₂₆₀₆ | L_{b147} |
| 2199 | Lₐ₂₆₀₇ | L_{b147} | 2200 | Lₐ₂₆₀₈ | L_{b147} |
| 2201 | Lₐ₂₆₀₉ | L_{b147} | 2202 | Lₐ₂₆₁₀ | L_{b147} |
| 2203 | Lₐ₂₆₁₁ | L_{b147} | 2204 | Lₐ₂₆₁₂ | L_{b147} |
| 2205 | Lₐ₂₆₁₃ | L_{b147} | 2206 | Lₐ₂₆₁₄ | L_{b147} |
| 2207 | Lₐ₂₆₁₅ | L_{b147} | 2208 | Lₐ₂₆₁₆ | L_{b147} |
| 2209 | Lₐ₂₆₁₇ | L_{b147} | 2210 | Lₐ₂₆₁₈ | L_{b147} |
| 2211 | Lₐ₂₆₁₉ | L_{b147} | 2212 | Lₐ₂₆₂₀ | L_{b147} |
| 2213 | Lₐ₂₆₂₁ | L_{b147} | 2214 | Lₐ₂₆₂₂ | L_{b147} |
| 2215 | Lₐ₂₆₂₃ | L_{b147} | 2216 | Lₐ₂₆₂₄ | L_{b147} |
| 2217 | Lₐ₂₆₂₅ | L_{b147} | 2218 | Lₐ₂₆₂₆ | L_{b147} |
| 2219 | Lₐ₂₆₂₇ | L_{b147} | 2220 | Lₐ₂₆₂₈ | L_{b147} |
| 2221 | Lₐ₂₆₂₉ | L_{b147} | 2222 | Lₐ₂₆₃₀ | L_{b147} |
| 2223 | Lₐ₂₆₃₁ | L_{b147} | 2224 | Lₐ₂₆₃₂ | L_{b147} |
| 2225 | Lₐ₂₆₃₃ | L_{b147} | 2226 | Lₐ₂₆₃₄ | L_{b147} |
| 2227 | Lₐ₂₆₃₅ | L_{b147} | 2228 | Lₐ₂₆₃₆ | L_{b147} |
| 2229 | Lₐ₂₆₃₇ | L_{b147} | 2230 | Lₐ₂₆₃₈ | L_{b147} |
| 2231 | Lₐ₂₆₃₉ | L_{b147} | 2232 | Lₐ₂₆₄₀ | L_{b147} |
| 2233 | Lₐ₂₆₄₁ | L_{b147} | 2234 | Lₐ₂₆₄₂ | L_{b147} |
| 2235 | Lₐ₂₆₄₃ | L_{b147} | 2236 | Lₐ₂₆₄₄ | L_{b147} |
| 2237 | Lₐ₂₆₄₅ | L_{b147} | 2238 | Lₐ₂₆₄₆ | L_{b147} |
| 2239 | Lₐ₂₆₄₇ | L_{b147} | 2240 | Lₐ₂₆₄₈ | L_{b147} |
| 2241 | Lₐ₂₆₄₉ | L_{b147} | 2242 | Lₐ₂₆₅₀ | L_{b147} |
| 2243 | Lₐ₂₆₅₁ | L_{b147} | 2244 | Lₐ₂₆₅₂ | L_{b147} |
| 2245 | Lₐ₂₆₅₃ | L_{b147} | 2246 | Lₐ₂₆₅₄ | L_{b147} |
| 2247 | Lₐ₂₆₅₅ | L_{b147} | 2248 | Lₐ₂₆₅₆ | L_{b147} |
| 2249 | Lₐ₂₆₅₇ | L_{b147} | 2250 | Lₐ₂₆₅₈ | L_{b147} |
| 2251 | Lₐ₂₅₆₉ | L_{b152} | 2252 | Lₐ₂₅₇₀ | L_{b152} |
| 2253 | Lₐ₂₅₇₁ | L_{b152} | 2254 | Lₐ₂₅₇₂ | L_{b152} |
| 2255 | Lₐ₂₅₇₃ | L_{b152} | 2256 | Lₐ₂₅₇₄ | L_{b152} |
| 2257 | Lₐ₂₅₇₅ | L_{b152} | 2258 | Lₐ₂₅₇₆ | L_{b152} |
| 2259 | Lₐ₂₅₇₇ | L_{b152} | 2260 | Lₐ₂₅₇₈ | L_{b152} |
| 2261 | Lₐ₂₅₇₉ | L_{b152} | 2262 | Lₐ₂₅₈₀ | L_{b152} |
| 2263 | Lₐ₂₅₈₁ | L_{b152} | 2264 | Lₐ₂₅₈₂ | L_{b152} |
| 2265 | Lₐ₂₅₈₃ | L_{b152} | 2266 | Lₐ₂₅₈₄ | L_{b152} |
| 2267 | Lₐ₂₅₈₅ | L_{b152} | 2268 | Lₐ₂₅₈₆ | L_{b152} |
| 2269 | Lₐ₂₅₈₇ | L_{b152} | 2270 | Lₐ₂₅₈₈ | L_{b152} |
| 2271 | Lₐ₂₅₈₉ | L_{b152} | 2272 | Lₐ₂₅₉₀ | L_{b152} |
| 2273 | Lₐ₂₅₉₁ | L_{b152} | 2274 | Lₐ₂₅₉₂ | L_{b152} |
| 2275 | Lₐ₂₅₉₃ | L_{b152} | 2276 | Lₐ₂₅₉₄ | L_{b152} |
| 2277 | Lₐ₂₅₉₅ | L_{b152} | 2278 | Lₐ₂₅₉₆ | L_{b152} |
| 2279 | Lₐ₂₅₉₇ | L_{b152} | 2280 | Lₐ₂₅₉₈ | L_{b152} |
| 2281 | Lₐ₂₅₉₉ | L_{b152} | 2282 | Lₐ₂₆₀₀ | L_{b152} |
| 2283 | Lₐ₂₆₀₁ | L_{b152} | 2284 | Lₐ₂₆₀₂ | L_{b152} |
| 2285 | Lₐ₂₆₀₃ | L_{b152} | 2286 | Lₐ₂₆₀₄ | L_{b152} |
| 2287 | Lₐ₂₆₀₅ | L_{b152} | 2288 | Lₐ₂₆₀₆ | L_{b152} |
| 2289 | Lₐ₂₆₀₇ | L_{b152} | 2290 | Lₐ₂₆₀₈ | L_{b152} |
| 2291 | Lₐ₂₆₀₉ | L_{b152} | 2292 | Lₐ₂₆₁₀ | L_{b152} |
| 2293 | Lₐ₂₆₁₁ | L_{b152} | 2294 | Lₐ₂₆₁₂ | L_{b152} |
| 2295 | Lₐ₂₆₁₃ | L_{b152} | 2296 | Lₐ₂₆₁₄ | L_{b152} |
| 2297 | Lₐ₂₆₁₅ | L_{b152} | 2298 | Lₐ₂₆₁₆ | L_{b152} |
| 2299 | Lₐ₂₆₁₇ | L_{b152} | 2300 | Lₐ₂₆₁₈ | L_{b152} |
| 2301 | Lₐ₂₆₁₉ | L_{b152} | 2302 | Lₐ₂₆₂₀ | L_{b152} |
| 2303 | Lₐ₂₆₂₁ | L_{b152} | 2304 | Lₐ₂₆₂₂ | L_{b152} |
| 2305 | Lₐ₂₆₂₃ | L_{b152} | 2306 | Lₐ₂₆₂₄ | L_{b152} |
| 2307 | Lₐ₂₆₂₅ | L_{b152} | 2308 | Lₐ₂₆₂₆ | L_{b152} |
| 2309 | Lₐ₂₆₂₇ | L_{b152} | 2310 | Lₐ₂₆₂₈ | L_{b152} |
| 2311 | Lₐ₂₆₂₉ | L_{b152} | 2312 | Lₐ₂₆₃₀ | L_{b152} |
| 2313 | Lₐ₂₆₃₁ | L_{b152} | 2314 | Lₐ₂₆₃₂ | L_{b152} |
| 2315 | Lₐ₂₆₃₃ | L_{b152} | 2316 | Lₐ₂₆₃₄ | L_{b152} |
| 2317 | Lₐ₂₆₃₅ | L_{b152} | 2318 | Lₐ₂₆₃₆ | L_{b152} |
| 2319 | Lₐ₂₆₃₇ | L_{b152} | 2320 | Lₐ₂₆₃₈ | L_{b152} |
| 2321 | Lₐ₂₆₃₉ | L_{b152} | 2322 | Lₐ₂₆₄₀ | L_{b152} |
| 2323 | Lₐ₂₆₄₁ | L_{b152} | 2324 | Lₐ₂₆₄₂ | L_{b152} |
| 2325 | Lₐ₂₆₄₃ | L_{b152} | 2326 | Lₐ₂₆₄₄ | L_{b152} |
| 2327 | Lₐ₂₆₄₅ | L_{b152} | 2328 | Lₐ₂₆₄₆ | L_{b152} |
| 2329 | Lₐ₂₆₄₇ | L_{b152} | 2330 | Lₐ₂₆₄₈ | L_{b152} |
| 2331 | Lₐ₂₆₄₉ | L_{b152} | 2332 | Lₐ₂₆₅₀ | L_{b152} |
| 2333 | Lₐ₂₆₅₁ | L_{b152} | 2334 | Lₐ₂₆₅₂ | L_{b152} |
| 2335 | Lₐ₂₆₅₃ | L_{b152} | 2336 | Lₐ₂₆₅₄ | L_{b152} |
| 2337 | Lₐ₂₆₅₅ | L_{b152} | 2338 | Lₐ₂₆₅₆ | L_{b152} |
| 2339 | Lₐ₂₆₅₇ | L_{b152} | 2340 | Lₐ₂₆₅₈ | L_{b152} |
| 2341 | Lₐ₂₅₆₉ | L_{b161} | 2342 | Lₐ₂₅₇₀ | L_{b161} |
| 2343 | Lₐ₂₅₇₁ | L_{b161} | 2344 | Lₐ₂₅₇₂ | L_{b161} |
| 2345 | Lₐ₂₅₇₃ | L_{b161} | 2346 | Lₐ₂₅₇₄ | L_{b161} |
| 2347 | Lₐ₂₅₇₅ | L_{b161} | 2348 | Lₐ₂₅₇₆ | L_{b161} |
| 2349 | Lₐ₂₅₇₇ | L_{b161} | 2350 | Lₐ₂₅₇₈ | L_{b161} |
| 2351 | Lₐ₂₅₇₉ | L_{b161} | 2352 | Lₐ₂₅₈₀ | L_{b161} |
| 2353 | Lₐ₂₅₈₁ | L_{b161} | 2354 | Lₐ₂₅₈₂ | L_{b161} |
| 2355 | Lₐ₂₅₈₃ | L_{b161} | 2356 | Lₐ₂₅₈₄ | L_{b161} |
| 2357 | Lₐ₂₅₈₅ | L_{b161} | 2358 | Lₐ₂₅₈₆ | L_{b161} |
| 2359 | Lₐ₂₅₈₇ | L_{b161} | 2360 | Lₐ₂₅₈₈ | L_{b161} |
| 2361 | Lₐ₂₅₈₉ | L_{b161} | 2362 | Lₐ₂₅₉₀ | L_{b161} |
| 2363 | Lₐ₂₅₉₁ | L_{b161} | 2364 | Lₐ₂₅₉₂ | L_{b161} |
| 2365 | Lₐ₂₅₉₃ | L_{b161} | 2366 | Lₐ₂₅₉₄ | L_{b161} |
| 2367 | Lₐ₂₅₉₅ | L_{b161} | 2368 | Lₐ₂₅₉₆ | L_{b161} |
| 2369 | Lₐ₂₅₉₇ | L_{b161} | 2370 | Lₐ₂₅₉₈ | L_{b161} |
| 2371 | Lₐ₂₅₉₉ | L_{b161} | 2372 | Lₐ₂₆₀₀ | L_{b161} |
| 2373 | Lₐ₂₆₀₁ | L_{b161} | 2374 | Lₐ₂₆₀₂ | L_{b161} |
| 2375 | Lₐ₂₆₀₃ | L_{b161} | 2376 | Lₐ₂₆₀₄ | L_{b161} |
| 2377 | Lₐ₂₆₀₅ | L_{b161} | 2378 | Lₐ₂₆₀₆ | L_{b161} |
| 2379 | Lₐ₂₆₀₇ | L_{b161} | 2380 | Lₐ₂₆₀₈ | L_{b161} |
| 2381 | Lₐ₂₆₀₉ | L_{b161} | 2382 | Lₐ₂₆₁₀ | L_{b161} |
| 2383 | Lₐ₂₆₁₁ | L_{b161} | 2384 | Lₐ₂₆₁₂ | L_{b161} |
| 2385 | Lₐ₂₆₁₃ | L_{b161} | 2386 | Lₐ₂₆₁₄ | L_{b161} |
| 2387 | Lₐ₂₆₁₅ | L_{b161} | 2388 | Lₐ₂₆₁₆ | L_{b161} |
| 2389 | Lₐ₂₆₁₇ | L_{b161} | 2390 | Lₐ₂₆₁₈ | L_{b161} |
| 2391 | Lₐ₂₆₁₉ | L_{b161} | 2392 | Lₐ₂₆₂₀ | L_{b161} |
| 2393 | Lₐ₂₆₂₁ | L_{b161} | 2394 | Lₐ₂₆₂₂ | L_{b161} |
| 2395 | Lₐ₂₆₂₃ | L_{b161} | 2396 | Lₐ₂₆₂₄ | L_{b161} |
| 2397 | Lₐ₂₆₂₅ | L_{b161} | 2398 | Lₐ₂₆₂₆ | L_{b161} |
| 2399 | Lₐ₂₆₂₇ | L_{b161} | 2400 | Lₐ₂₆₂₈ | L_{b161} |
| 2401 | Lₐ₂₆₂₉ | L_{b161} | 2402 | Lₐ₂₆₃₀ | L_{b161} |
| 2403 | Lₐ₂₆₃₁ | L_{b161} | 2404 | Lₐ₂₆₃₂ | L_{b161} |
| 2405 | Lₐ₂₆₃₃ | L_{b161} | 2406 | Lₐ₂₆₃₄ | L_{b161} |
| 2407 | Lₐ₂₆₃₅ | L_{b161} | 2408 | Lₐ₂₆₃₆ | L_{b161} |
| 2409 | Lₐ₂₆₃₇ | L_{b161} | 2410 | Lₐ₂₆₃₈ | L_{b161} |
| 2411 | Lₐ₂₆₃₉ | L_{b161} | 2412 | Lₐ₂₆₄₀ | L_{b161} |
| 2413 | Lₐ₂₆₄₁ | L_{b161} | 2414 | Lₐ₂₆₄₂ | L_{b161} |
| 2415 | Lₐ₂₆₄₃ | L_{b161} | 2416 | Lₐ₂₆₄₄ | L_{b161} |
| 2417 | Lₐ₂₆₄₅ | L_{b161} | 2418 | Lₐ₂₆₄₆ | L_{b161} |
| 2419 | Lₐ₂₆₄₇ | L_{b161} | 2420 | Lₐ₂₆₄₈ | L_{b161} |
| 2421 | Lₐ₂₆₄₉ | L_{b161} | 2422 | Lₐ₂₆₅₀ | L_{b161} |
| 2423 | Lₐ₂₆₅₁ | L_{b161} | 2424 | Lₐ₂₆₅₂ | L_{b161} |
| 2425 | Lₐ₂₆₅₃ | L_{b161} | 2426 | Lₐ₂₆₅₄ | L_{b161} |
| 2427 | Lₐ₂₆₅₅ | L_{b161} | 2428 | Lₐ₂₆₅₆ | L_{b161} |
| 2429 | Lₐ₂₆₅₇ | L_{b161} | 2430 | Lₐ₂₆₅₈ | L_{b161} |
| 2431 | Lₐ₂₅₆₉ | L_{b165} | 2432 | Lₐ₂₅₇₀ | L_{b165} |
| 2433 | Lₐ₂₅₇₁ | L_{b165} | 2434 | Lₐ₂₅₇₂ | L_{b165} |
| 2435 | Lₐ₂₅₇₃ | L_{b165} | 2436 | Lₐ₂₅₇₄ | L_{b165} |
| 2437 | Lₐ₂₅₇₅ | L_{b165} | 2438 | Lₐ₂₅₇₆ | L_{b165} |
| 2439 | Lₐ₂₅₇₇ | L_{b165} | 2440 | Lₐ₂₅₇₈ | L_{b165} |
| 2441 | Lₐ₂₅₇₉ | L_{b165} | 2442 | Lₐ₂₅₈₀ | L_{b165} |
| 2443 | Lₐ₂₅₈₁ | L_{b165} | 2444 | Lₐ₂₅₈₂ | L_{b165} |
| 2445 | Lₐ₂₅₈₃ | L_{b165} | 2446 | Lₐ₂₅₈₄ | L_{b165} |
| 2447 | Lₐ₂₅₈₅ | L_{b165} | 2448 | Lₐ₂₅₈₆ | L_{b165} |
| 2449 | Lₐ₂₅₈₇ | L_{b165} | 2450 | Lₐ₂₅₈₈ | L_{b165} |
| 2451 | Lₐ₂₅₈₉ | L_{b165} | 2452 | Lₐ₂₅₉₀ | L_{b165} |
| 2453 | Lₐ₂₅₉₁ | L_{b165} | 2454 | Lₐ₂₅₉₂ | L_{b165} |
| 2455 | Lₐ₂₅₉₃ | L_{b165} | 2456 | Lₐ₂₅₉₄ | L_{b165} |
| 2457 | Lₐ₂₅₉₅ | L_{b165} | 2458 | Lₐ₂₅₉₆ | L_{b165} |
| 2459 | Lₐ₂₅₉₇ | L_{b165} | 2460 | Lₐ₂₅₉₈ | L_{b165} |
| 2461 | Lₐ₂₅₉₉ | L_{b165} | 2462 | Lₐ₂₆₀₀ | L_{b165} |
| 2463 | Lₐ₂₆₀₁ | L_{b165} | 2464 | Lₐ₂₆₀₂ | L_{b165} |
| 2465 | Lₐ₂₆₀₃ | L_{b165} | 2466 | Lₐ₂₆₀₄ | L_{b165} |
| 2467 | Lₐ₂₆₀₅ | L_{b165} | 2468 | Lₐ₂₆₀₆ | L_{b165} |
| 2469 | Lₐ₂₆₀₇ | L_{b165} | 2470 | Lₐ₂₆₀₈ | L_{b165} |
| 2471 | Lₐ₂₆₀₉ | L_{b165} | 2472 | Lₐ₂₆₁₀ | L_{b165} |
| 2473 | Lₐ₂₆₁₁ | L_{b165} | 2474 | Lₐ₂₆₁₂ | L_{b165} |
| 2475 | Lₐ₂₆₁₃ | L_{b165} | 2476 | Lₐ₂₆₁₄ | L_{b165} |
| 2477 | Lₐ₂₆₁₅ | L_{b165} | 2478 | Lₐ₂₆₁₆ | L_{b165} |
| 2479 | Lₐ₂₆₁₇ | L_{b165} | 2480 | Lₐ₂₆₁₈ | L_{b165} |
| 2481 | Lₐ₂₆₁₉ | L_{b165} | 2482 | Lₐ₂₆₂₀ | L_{b165} |
| 2483 | Lₐ₂₆₂₁ | L_{b165} | 2484 | Lₐ₂₆₂₂ | L_{b165} |
| 2485 | Lₐ₂₆₂₃ | L_{b165} | 2486 | Lₐ₂₆₂₄ | L_{b165} |
| 2487 | Lₐ₂₆₂₅ | L_{b165} | 2488 | Lₐ₂₆₂₆ | L_{b165} |
| 2489 | Lₐ₂₆₂₇ | L_{b165} | 2490 | Lₐ₂₆₂₈ | L_{b165} |
| 2491 | Lₐ₂₆₂₉ | L_{b165} | 2492 | Lₐ₂₆₃₀ | L_{b165} |
| 2493 | Lₐ₂₆₃₁ | L_{b165} | 2494 | Lₐ₂₆₃₂ | L_{b165} |
| 2495 | Lₐ₂₆₃₃ | L_{b165} | 2496 | Lₐ₂₆₃₄ | L_{b165} |
| 2497 | Lₐ₂₆₃₅ | L_{b165} | 2498 | Lₐ₂₆₃₆ | L_{b165} |
| 2499 | Lₐ₂₆₃₇ | L_{b165} | 2500 | Lₐ₂₆₃₈ | L_{b165} |
| 2501 | Lₐ₂₆₃₉ | L_{b165} | 2502 | Lₐ₂₆₄₀ | L_{b165} |
| 2503 | Lₐ₂₆₄₁ | L_{b165} | 2504 | Lₐ₂₆₄₂ | L_{b165} |
| 2505 | Lₐ₂₆₄₃ | L_{b165} | 2506 | Lₐ₂₆₄₄ | L_{b165} |
| 2507 | Lₐ₂₆₄₅ | L_{b165} | 2508 | Lₐ₂₆₄₆ | L_{b165} |
| 2509 | Lₐ₂₆₄₇ | L_{b165} | 2510 | Lₐ₂₆₄₈ | L_{b165} |
| 2511 | Lₐ₂₆₄₉ | L_{b165} | 2512 | Lₐ₂₆₅₀ | L_{b165} |
| 2513 | Lₐ₂₆₅₁ | L_{b165} | 2514 | Lₐ₂₆₅₂ | L_{b165} |
| 2515 | Lₐ₂₆₅₃ | L_{b165} | 2516 | Lₐ₂₆₅₄ | L_{b165} |
| 2517 | Lₐ₂₆₅₅ | L_{b165} | 2518 | Lₐ₂₆₅₆ | L_{b165} |
| 2519 | Lₐ₂₆₅₇ | L_{b165} | 2520 | Lₐ₂₆₅₈ | L_{b165} |

wherein the metal complex has structures of Metal Complex 2521 to Metal Complex 2530: 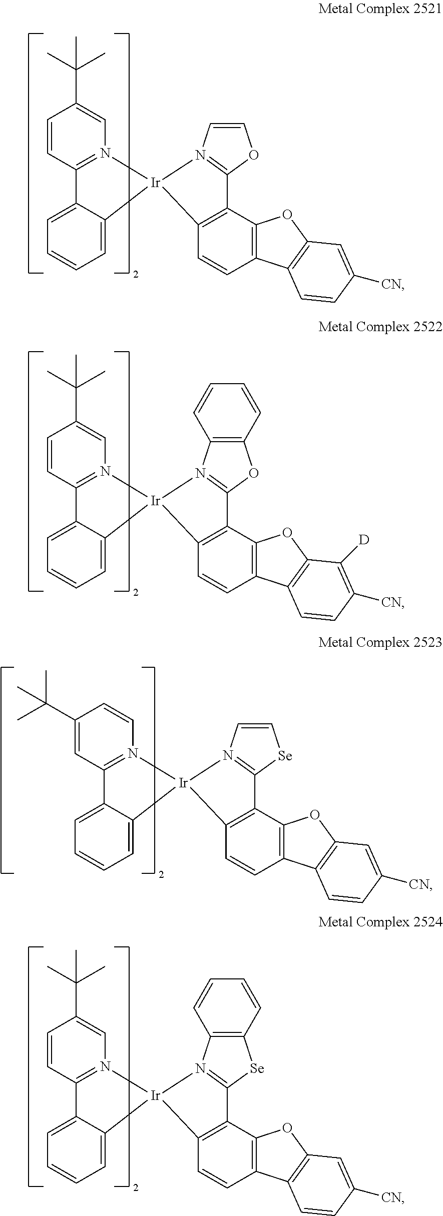 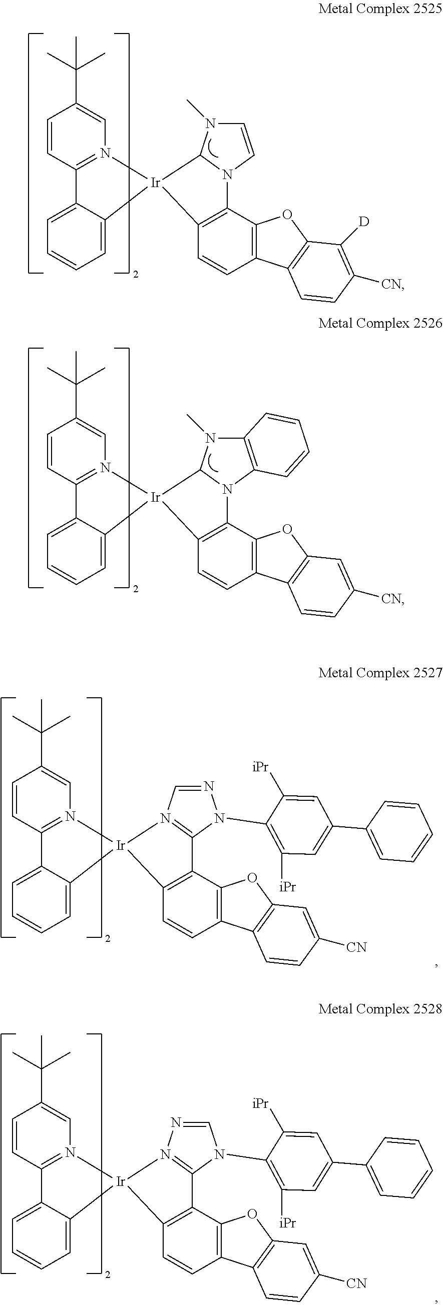 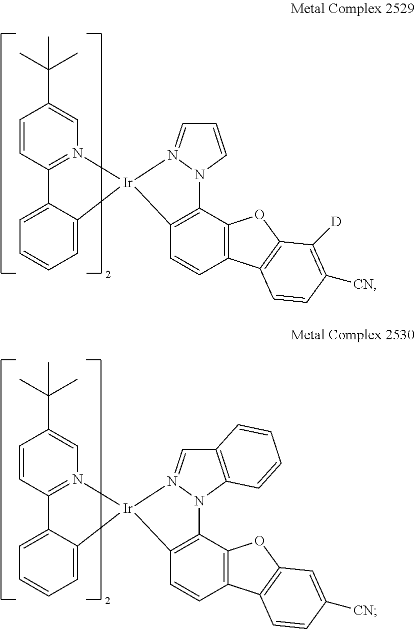
wherein optionally, hydrogen in Metal Complex 1 to Metal Complex 2530 can be partially or fully substituted with deuterium.

15. The organic electroluminescent device of claim 1, wherein the phosphorescence sensitizer accounts for a proportion of 0.001% to 25% of a total weight of the emissive layer;
preferably, the phosphorescence sensitizer accounts for a proportion of less than 0.01% to 15% of a total weight of the emissive layer; and
more preferably, the phosphorescence sensitizer accounts for a proportion of less than 0.1% to 10% of a total weight of the emissive layer.

16. The organic electroluminescent device of claim 1, wherein the fluorescent material comprises at least one boron-nitrogen heterocyclic structure;
preferably, the fluorescent material comprises at least one substituted or unsubstituted carbazole structure;
preferably, the fluorescent material comprises at least two substituted or unsubstituted carbazole structures;
preferably, the fluorescent material comprises at least one substituted or unsubstituted diarylamino structure;
preferably, the fluorescent material comprises at least two substituted or unsubstituted diarylamino structures; and
preferably, the fluorescent material comprises at least one substituted or unsubstituted carbazole group and at least one substituted or unsubstituted diarylamino structure.

17. The organic electroluminescent device of claim 16, wherein the fluorescent material structure has a structure represented by Formula 5: 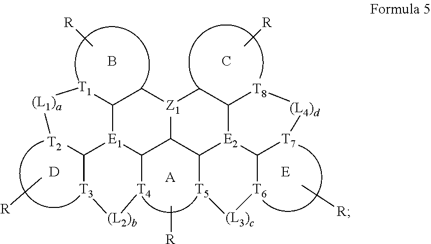
wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1};
T₁ to T₈ are each independently selected from C, CRₜ or N;
a, b, c and d are each independently selected from 0 or 1;
L₁, L₂, L₃ and L₄ are, at each occurrence identically or differently, selected from a single bond, O, S, Se, BR_{L} or NR_{L};
R represents, at each occurrence identically or differently, mono-substitution, multiple substitutions or non-substitution;
R, R₁, R_{L}, R_{Si1} and R_{Ge1} are at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R₁, R_{L}, R_{Si1}, R_{Ge1} and R^{B} can be optionally joined to form a ring.

18. The organic electroluminescent device of claim 16, wherein the fluorescent material has a structure represented by Formula 6: 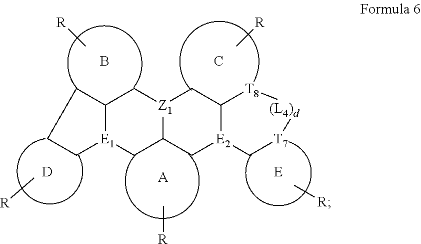
wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1};
T₇ and T₈ are each independently selected from C, CRₜ or N;
d is selected from 0 and 1;
L₄ is, at each occurrence identically or differently, selected from a single bond, O, S, Se, BR_{L} or NR_{L};
R represents, at each occurrence identically or differently, mono-substitution, multiple substitutions or non-substitution;
R, R₁, R_{L}, R_{Si1} and R_{Ge1} are at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, R₁, R_{L}, R_{Si1}, R_{Ge1} and R^{B} can be optionally joined to form a ring.

19. The organic electroluminescent device of claim 17, wherein the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms;
preferably, the ring A, the ring B, the ring C, the ring D and the ring E are each independently selected from a five-membered unsaturated carbocyclic ring, an aromatic ring having 6 to 18 carbon atoms or a heteroaromatic ring having 3 to 18 carbon atoms; and
preferably, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

20. The organic electroluminescent device of claim 19, wherein Z₁ is selected from B, P═O or P═S, and E₁ and E₂ are each independently selected from N or P;
preferably, Z₁ is selected from B, and E₁ and E₂ are selected from N;
preferably, Z₁ is selected from N or P, and E₁ and E₂ are each independently selected from B, P═O or P═S; and
preferably, Z₁ is selected from N, and E₁ and E₂ are selected from B.

21. The organic electroluminescent device of claim 17, wherein L₁, L₂, L₃ and L₄ are, at each occurrence identically or differently, selected from a single bond, O, BR_{L} or NR_{L}.

22. The organic electroluminescent device of claim 17, wherein a+b+c+d is greater than or equal to 1;
preferably, a+d is greater than or equal to 1;
preferably, a is 0, and d is 1; and
preferably, a is 1, and d is 1.

23. The organic electroluminescent device of claim 16, wherein the fluorescent material has a structure represented by any one of Formula 5-1 to Formula 5-8: 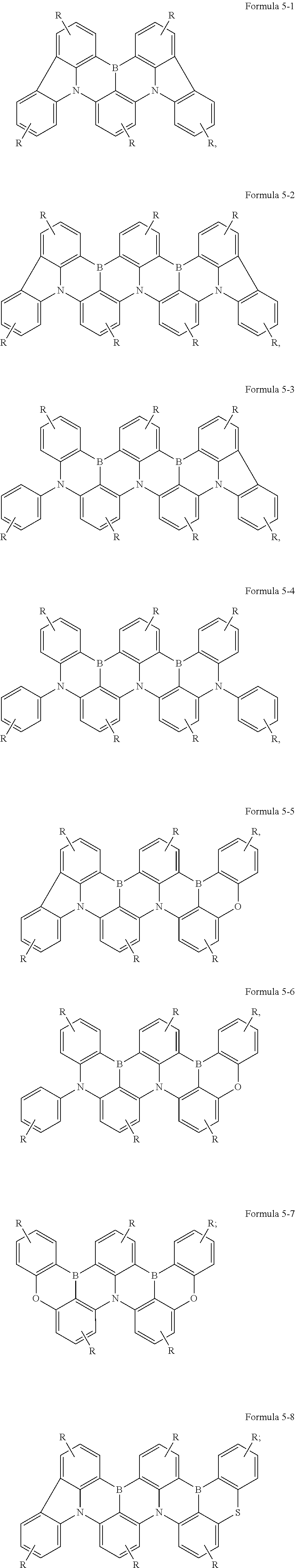
wherein,
R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R and R^{B} can be optionally joined to form a ring; and
preferably, the fluorescent material has a structure represented by Formula 5-1 or Formula 5-2.

24. The organic electroluminescent device of claim 23, wherein R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms and combinations thereof;
preferably, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof; and
preferably, multiple R are present in Formula 5-1 to Formula 5-8, and at least one of the multiple R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof.

25. The organic electroluminescent device of claim 17, wherein the fluorescent material is selected from the group consisting of Compound DF-1 to Compound DF-160: 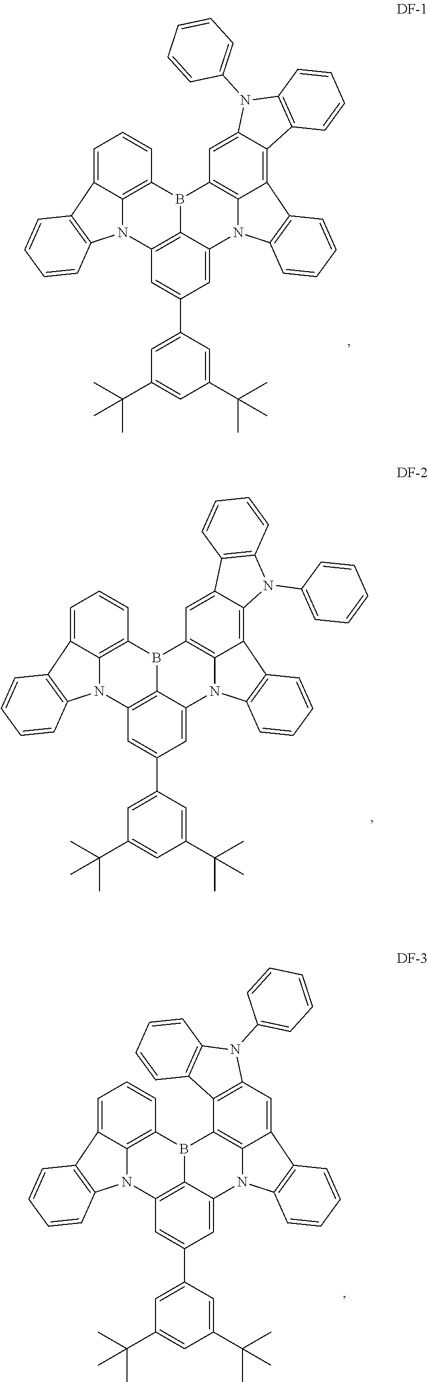 [SMILES: CC(C)(C)c1cc(-c2cc3c4c(c2)-n2c5ccccc5c5c6c7ccccc7n(-c7ccccc7)c6cc(c52)B4c2cccc4c5ccccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cccc4c5ccccc5n-3c24)cc(C(C)(C)C)c1 ; CC(C)(C)c1cc(-c2cc3c4c(c2)-n2c5ccccc5c5cc6c(c(c52)B4c2cccc4c5ccccc5n-3c24)c2ccccc2n6-c2ccccc2)cc(C(C)(C)C)c1] 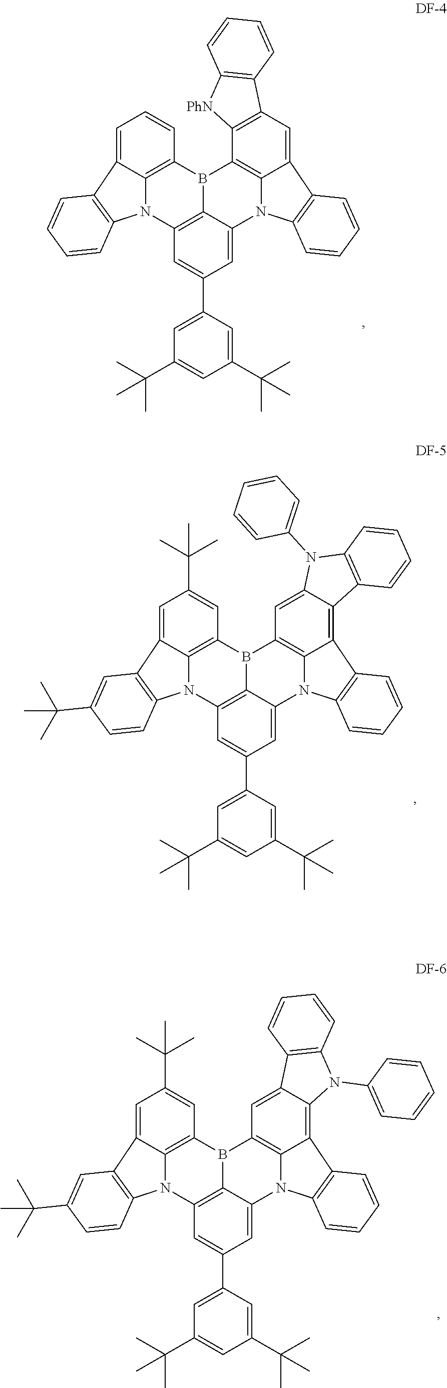 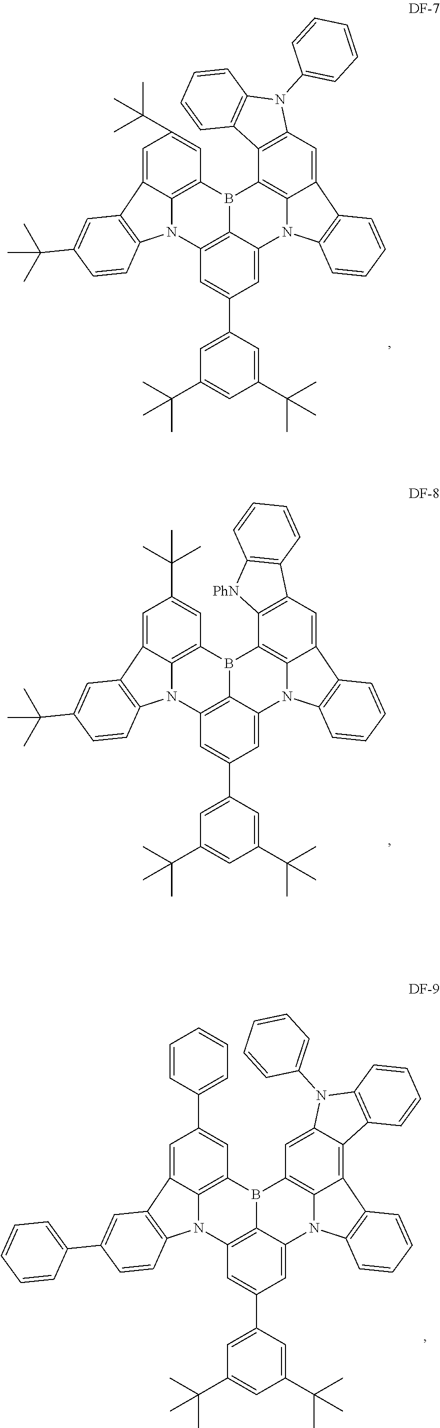 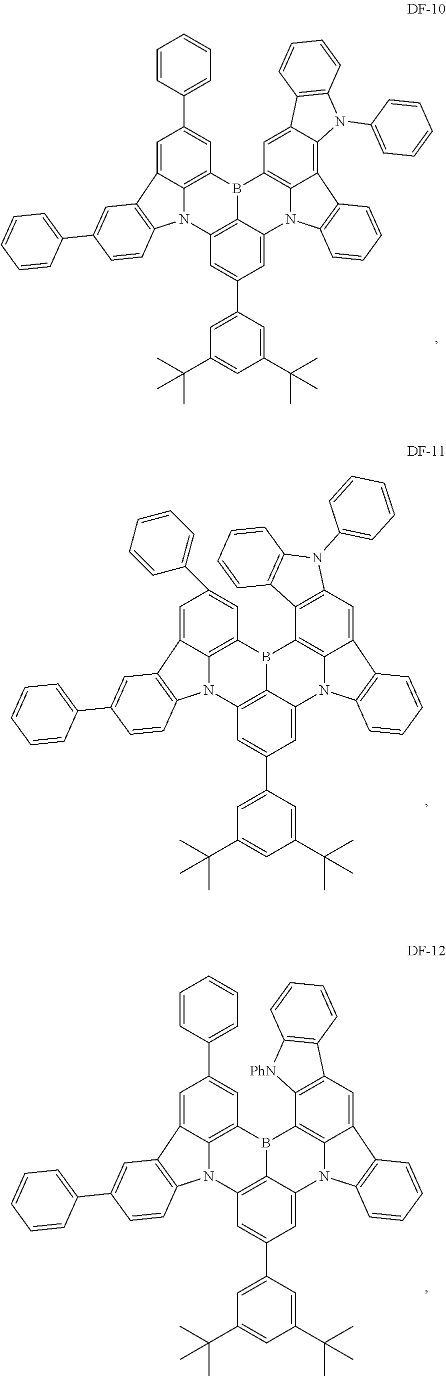 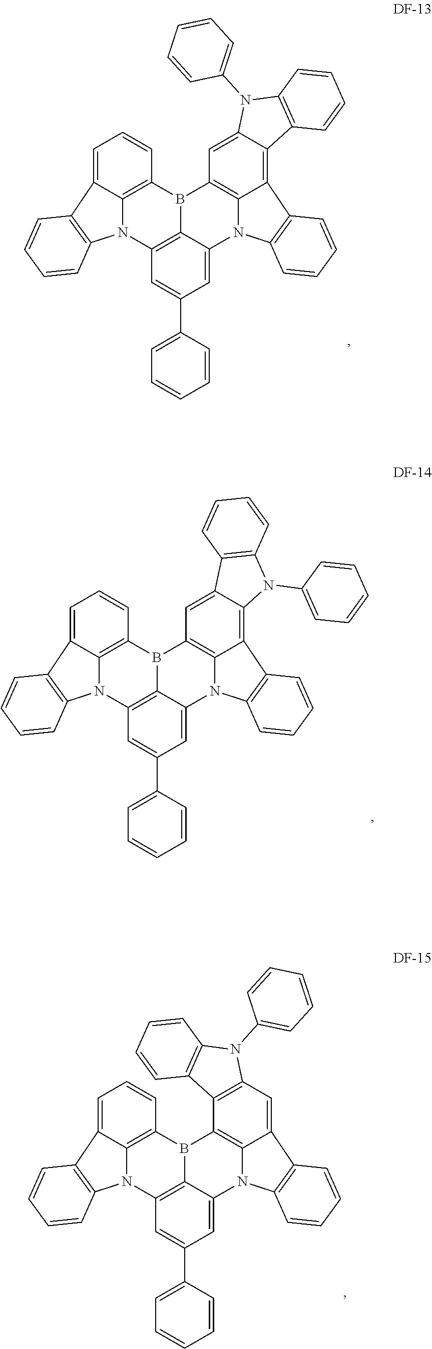 [SMILES: c1ccc(-c2cc3c4c(c2)-n2c5ccccc5c5c6c7ccccc7n(-c7ccccc7)c6cc(c52)B4c2cccc4c5ccccc5n-3c24)cc1 ; c1ccc(-c2cc3c4c(c2)-n2c5ccccc5c5c2c(cc2c6ccccc6n(-c6ccccc6)c25)B4c2cccc4c5ccccc5n-3c24)cc1 ; c1ccc(-c2cc3c4c(c2)-n2c5ccccc5c5cc6c(c(c52)B4c2cccc4c5ccccc5n-3c24)c2ccccc2n6-c2ccccc2)cc1] 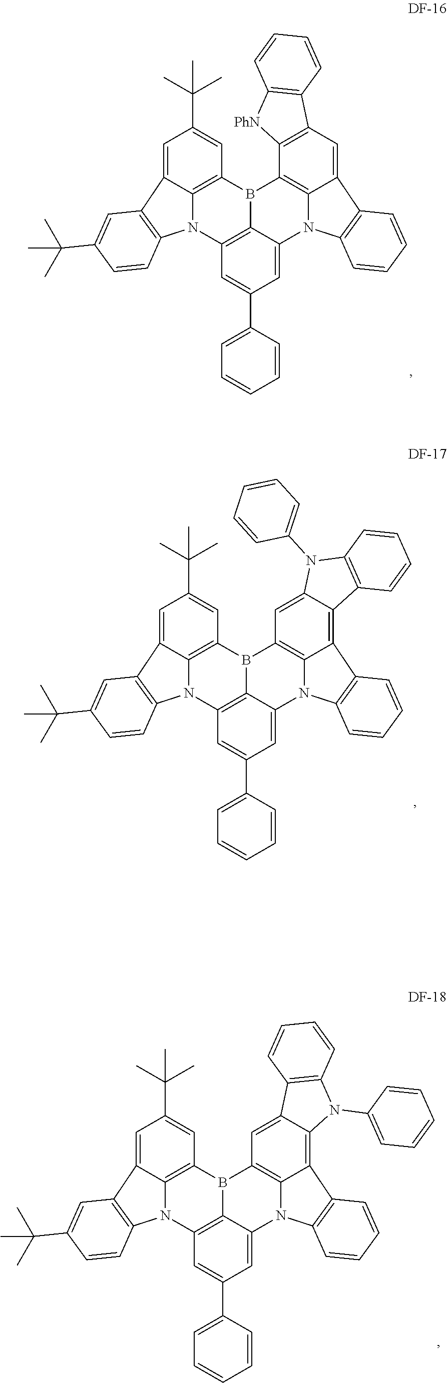 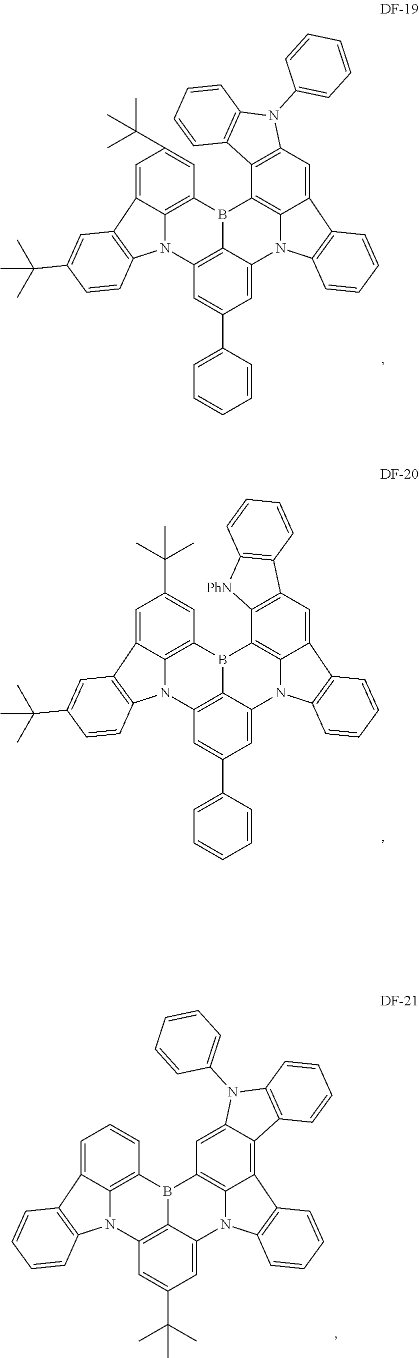 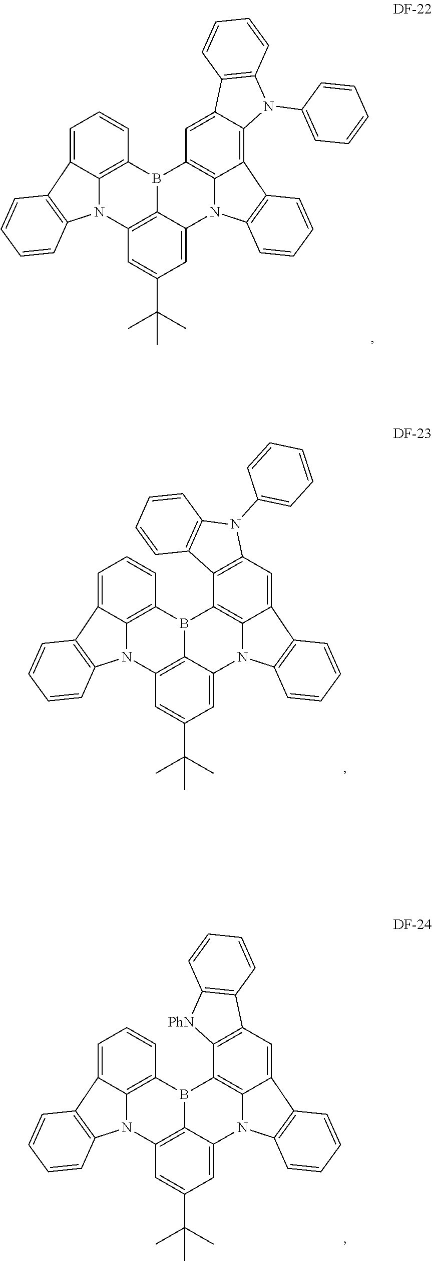 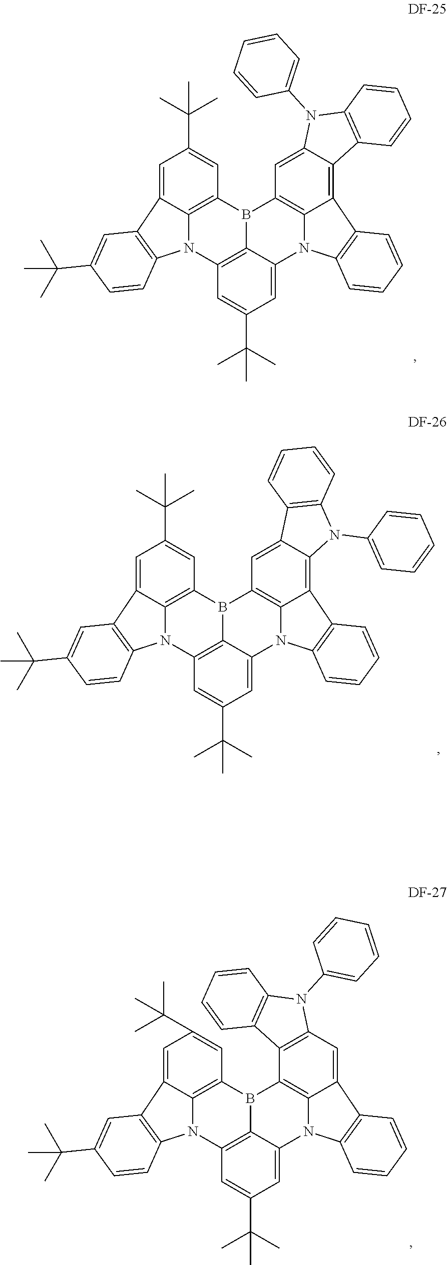 [SMILES: CC(C)(C)c1cc2c3c(c1)-n1c4ccccc4c4c5c6ccccc6n(-c6ccccc6)c5cc(c41)B3c1cc(C(C)(C)C)cc3c4cc(C(C)(C)C)ccc4n-2c13 ; CC(C)(C)c1cc2c3c(c1)-n1c4ccccc4c4c1c(cc1c5ccccc5n(-c5ccccc5)c14)B3c1cc(C(C)(C)C)cc3c4cc(C(C)(C)C)ccc4n-2c13 ; CC(C)(C)c1cc2c3c(c1)-n1c4ccccc4c4cc5c(c(c41)B3c1cc(C(C)(C)C)cc3c4cc(C(C)(C)C)ccc4n-2c13)c1ccccc1n5-c1ccccc1] 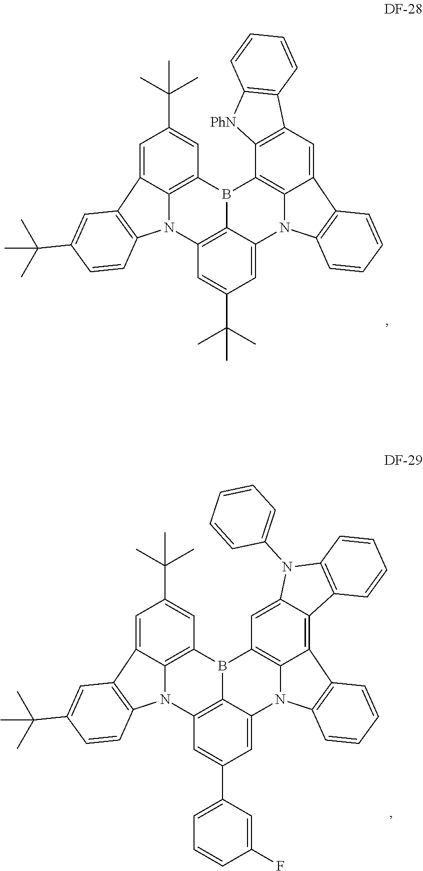 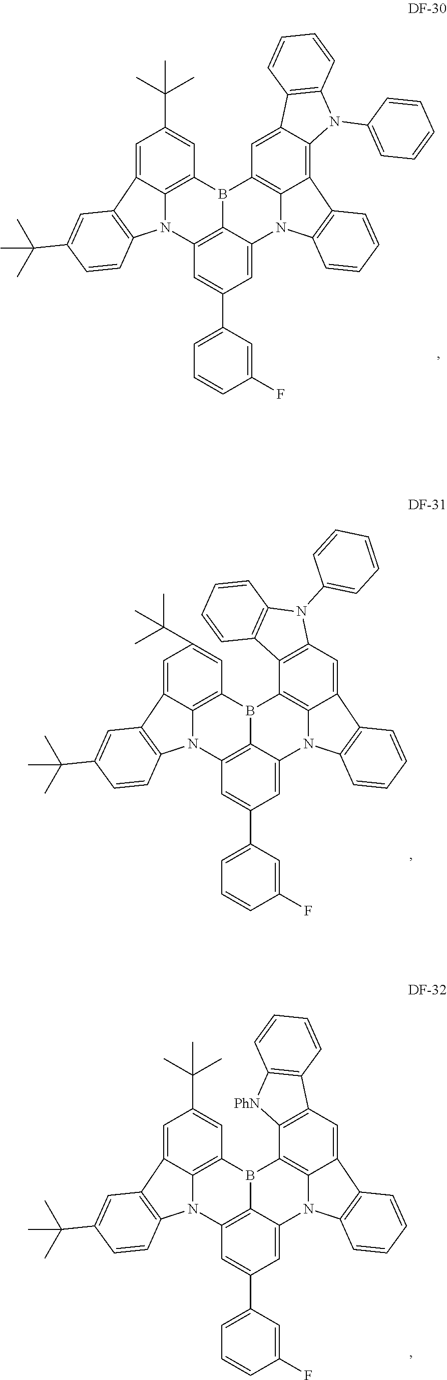 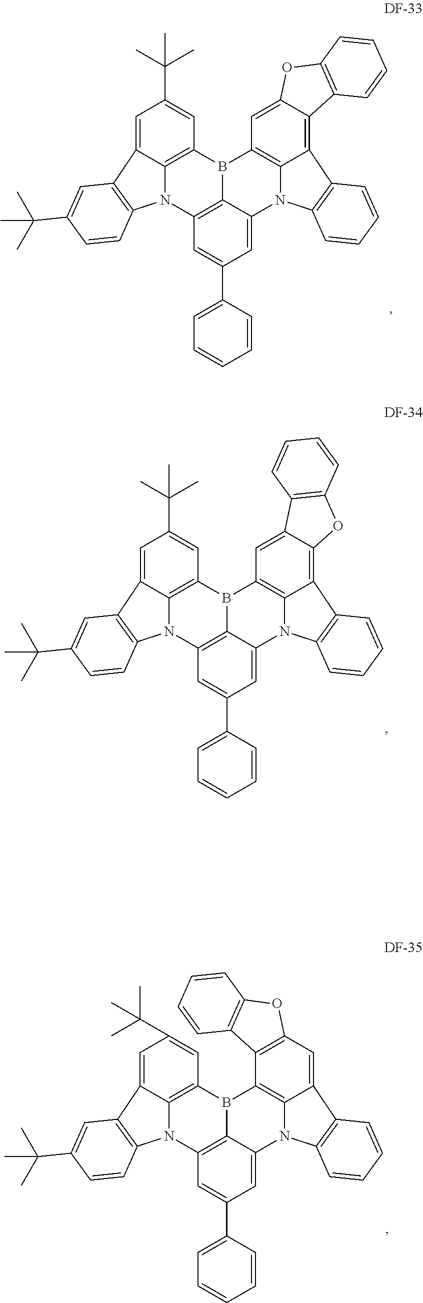 [SMILES: CC(C)(C)c1ccc2c(c1)c1cc(C(C)(C)C)cc3c1n2-c1cc(-c2ccccc2)cc2c1B3c1cc3oc4ccccc4c3c3c4ccccc4n-2c13 ; CC(C)(C)c1ccc2c(c1)c1cc(C(C)(C)C)cc3c1n2-c1cc(-c2ccccc2)cc2c1B3c1cc3c4ccccc4oc3c3c4ccccc4n-2c13 ; CC(C)(C)c1ccc2c(c1)c1cc(C(C)(C)C)cc3c1n2-c1cc(-c2ccccc2)cc2c1B3c1c3c(cc4c5ccccc5n-2c14)oc1ccccc13] 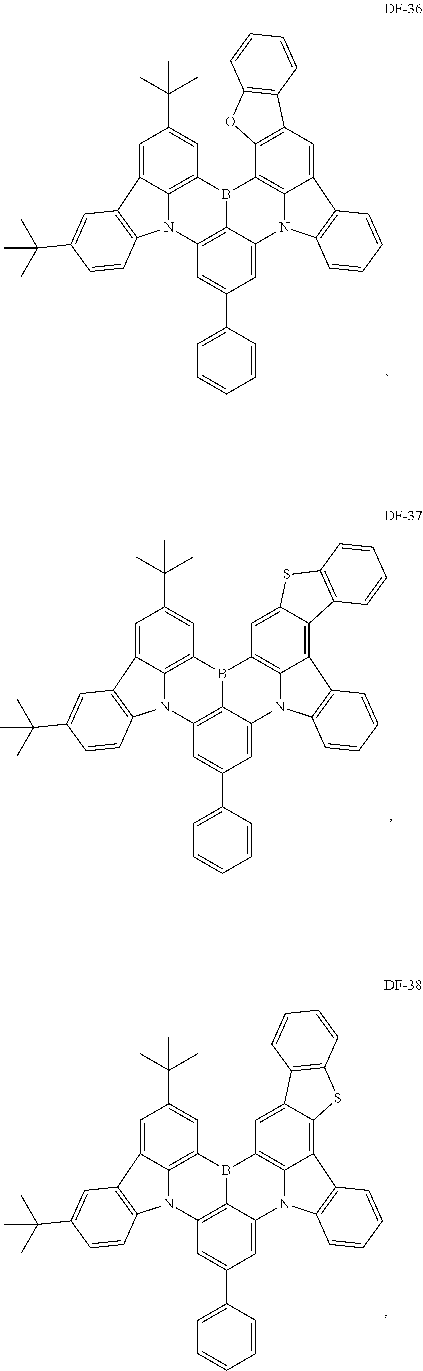 [SMILES: CC(C)(C)c1ccc2c(c1)c1cc(C(C)(C)C)cc3c1n2-c1cc(-c2ccccc2)cc2c1B3c1c3oc4ccccc4c3cc3c4ccccc4n-2c13 ; CC(C)(C)c1ccc2c(c1)c1cc(C(C)(C)C)cc3c1n2-c1cc(-c2ccccc2)cc2c1B3c1cc3sc4ccccc4c3c3c4ccccc4n-2c13 ; CC(C)(C)c1ccc2c(c1)c1cc(C(C)(C)C)cc3c1n2-c1cc(-c2ccccc2)cc2c1B3c1cc3c4ccccc4sc3c3c4ccccc4n-2c13] 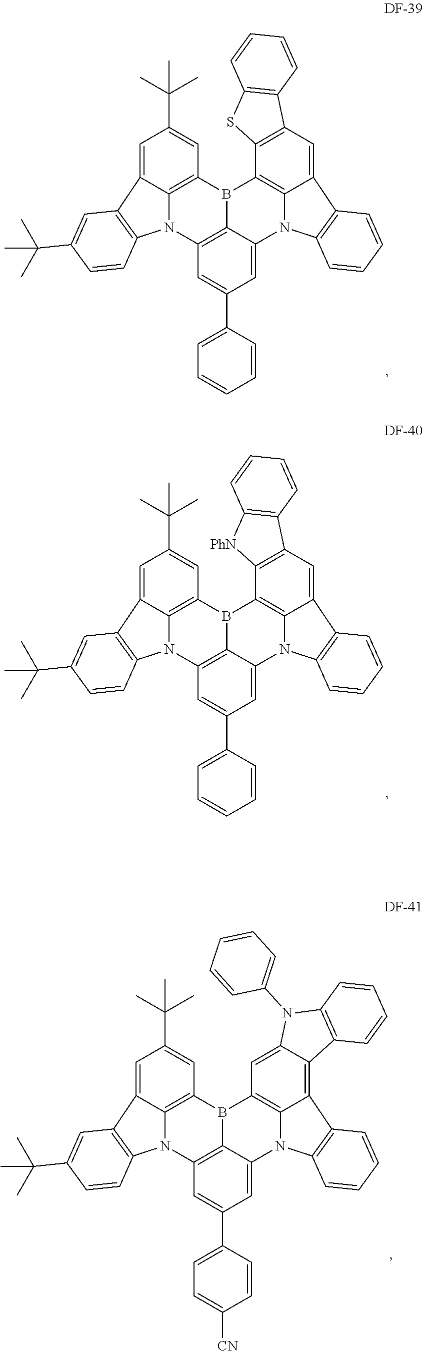 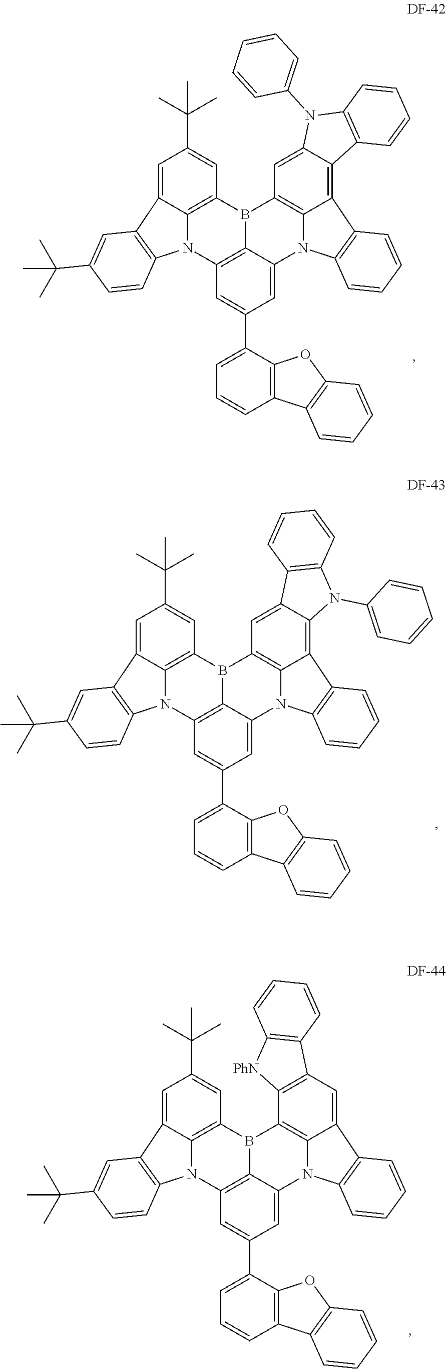 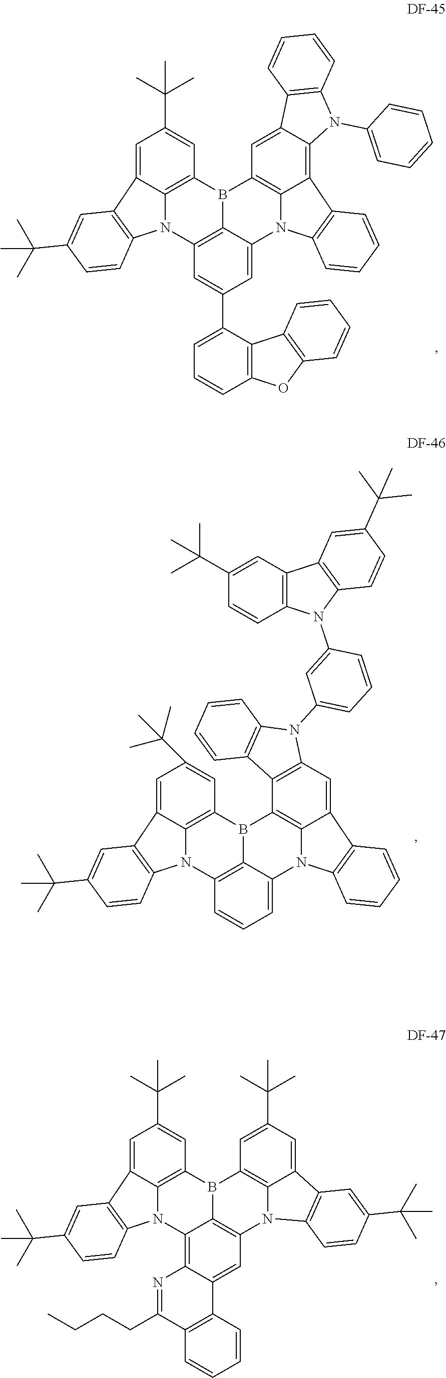 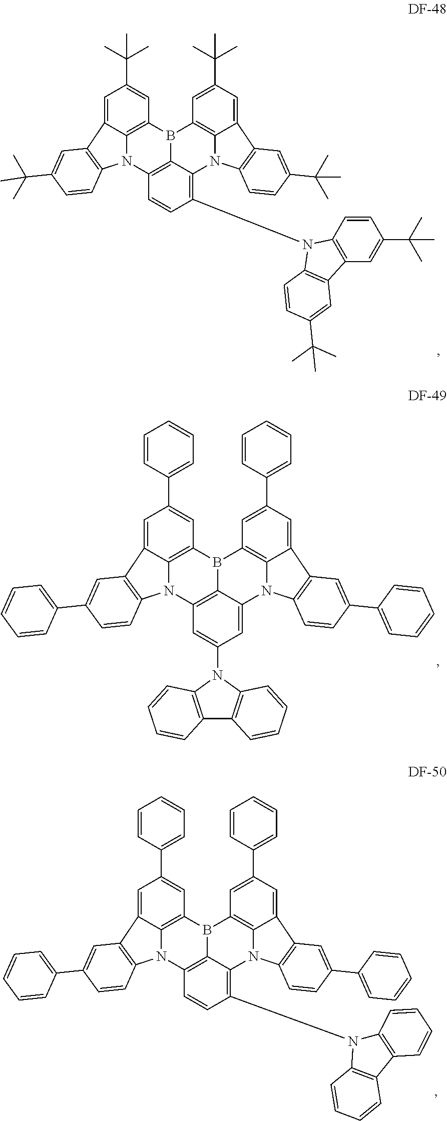 [SMILES: CC(C)(C)c1ccc2c(c1)c1cc(C(C)(C)C)ccc1n2-c1ccc2c3c1-n1c4ccc(C(C)(C)C)cc4c4cc(C(C)(C)C)cc(c41)B3c1cc(C(C)(C)C)cc3c4cc(C(C)(C)C)ccc4n-2c13 ; c1ccc(-c2ccc3c(c2)c2cc(-c4ccccc4)cc4c2n3-c2cc(-n3c5ccccc5c5ccccc53)cc3c2B4c2cc(-c4ccccc4)cc4c5cc(-c6ccccc6)ccc5n-3c24)cc1 ; c1ccc(-c2ccc3c(c2)c2cc(-c4ccccc4)cc4c2n3-c2ccc(-n3c5ccccc5c5ccccc53)c3c2B4c2cc(-c4ccccc4)cc4c5cc(-c6ccccc6)ccc5n-3c24)cc1] 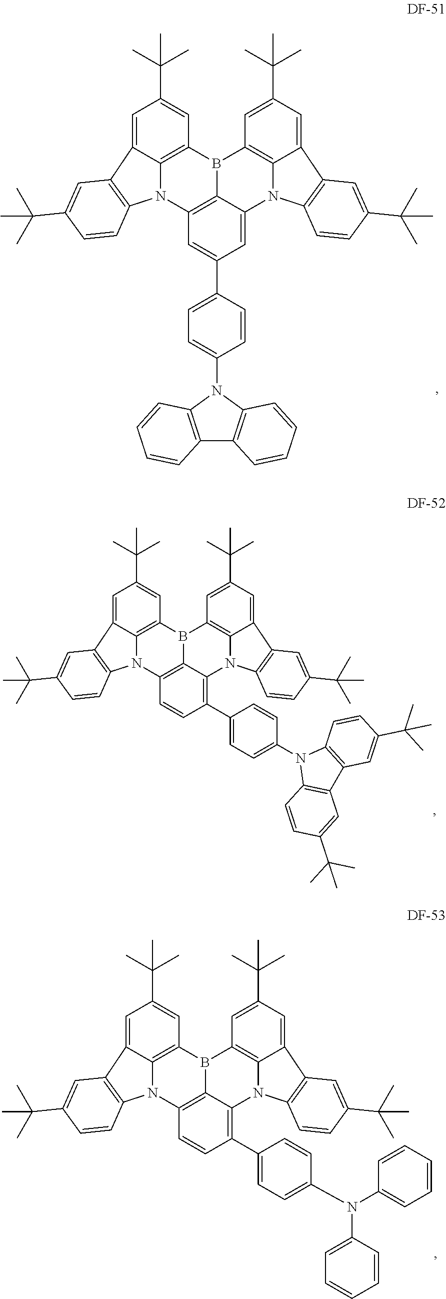 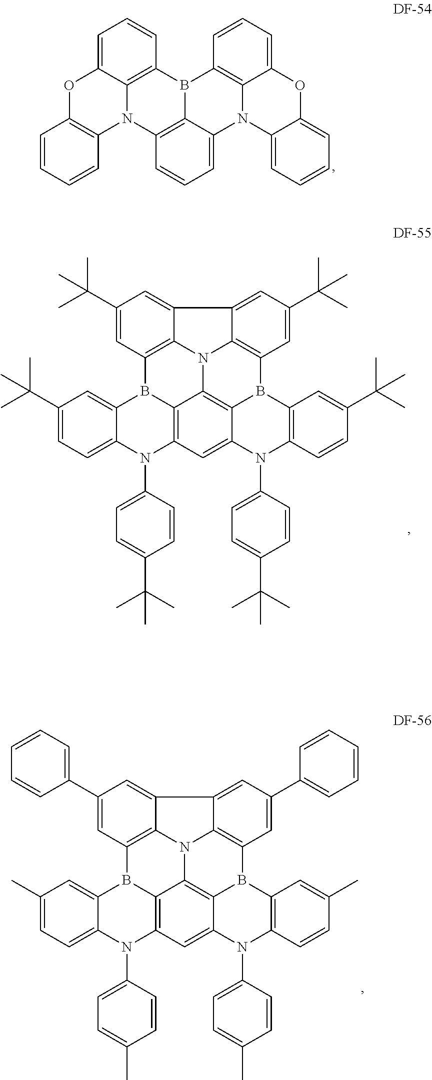 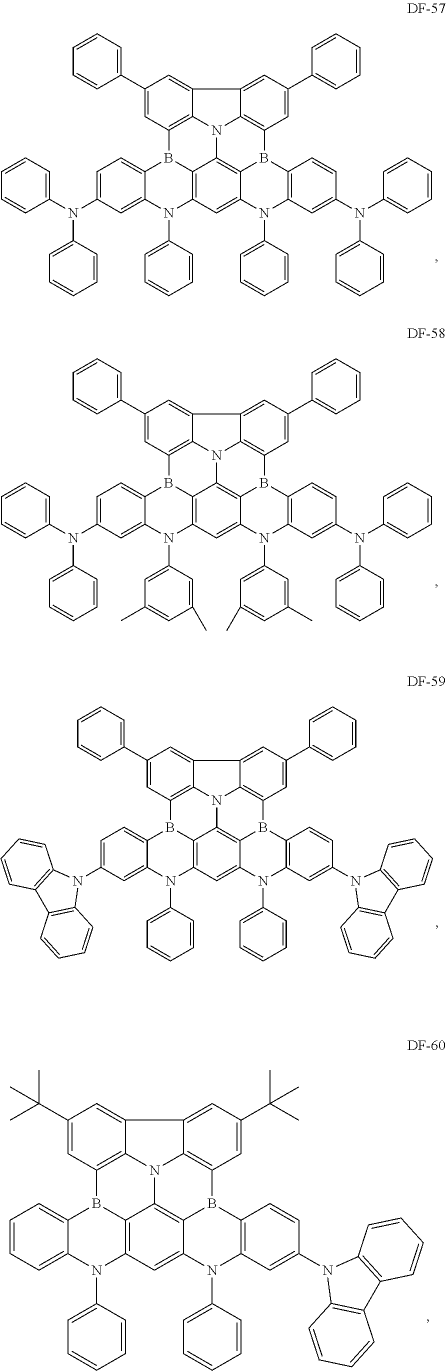 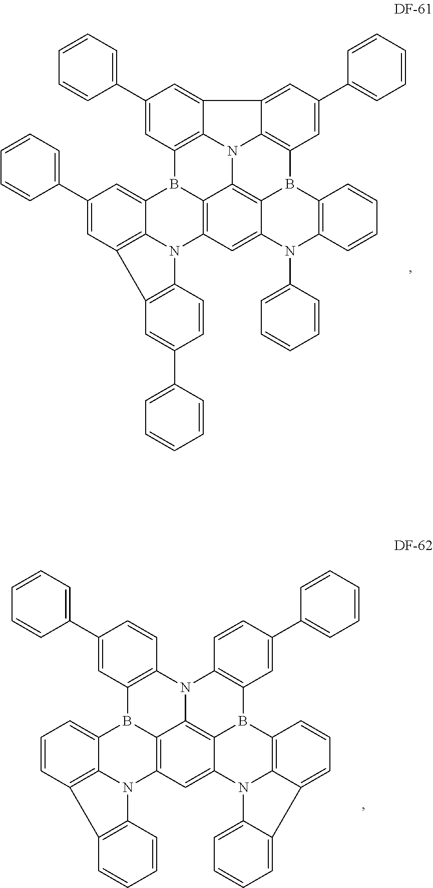 [SMILES: c1ccc(-c2ccc3c(c2)c2cc(-c4ccccc4)cc4c2n3-c2cc3c5c6c2B4c2cc(-c4ccccc4)cc4c7cc(-c8ccccc8)cc(c7n-6c24)B5c2ccccc2N3c2ccccc2)cc1 ; c1ccc(-c2ccc3c(c2)B2c4c(cc5c6c4N3c3ccc(-c4ccccc4)cc3B6c3cccc4c6ccccc6n-5c34)-n3c4ccccc4c4cccc2c43)cc1] 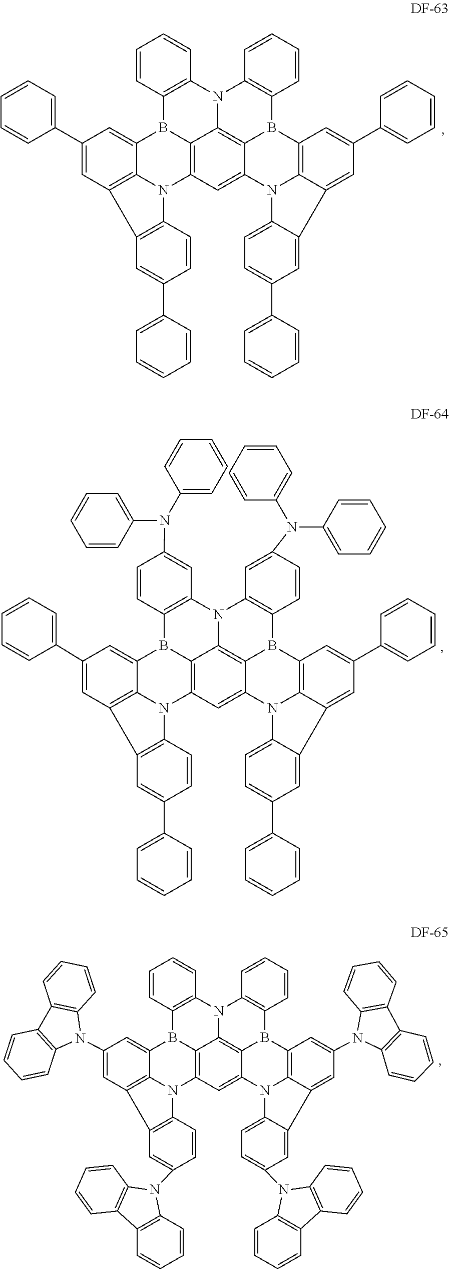 [SMILES: c1ccc(-c2ccc3c(c2)c2cc(-c4ccccc4)cc4c2n3-c2cc3c5c6c2B4c2ccccc2N6c2ccccc2B5c2cc(-c4ccccc4)cc4c5cc(-c6ccccc6)ccc5n-3c24)cc1 ; c1ccc(-c2ccc3c(c2)c2cc(-c4ccccc4)cc4c2n3-c2cc3c5c6c2B4c2ccc(N(c4ccccc4)c4ccccc4)cc2N6c2cc(N(c4ccccc4)c4ccccc4)ccc2B5c2cc(-c4ccccc4)cc4c5cc(-c6ccccc6)ccc5n-3c24)cc1 ; c1ccc2c(c1)B1c3c(cc4c5c3N2c2ccccc2B5c2cc(-n3c5ccccc5c5ccccc53)cc3c5cc(-n6c7ccccc7c7ccccc76)ccc5n-4c23)-n2c3ccc(-n4c5ccccc5c5ccccc54)cc3c3cc(-n4c5ccccc5c5ccccc54)cc1c32] 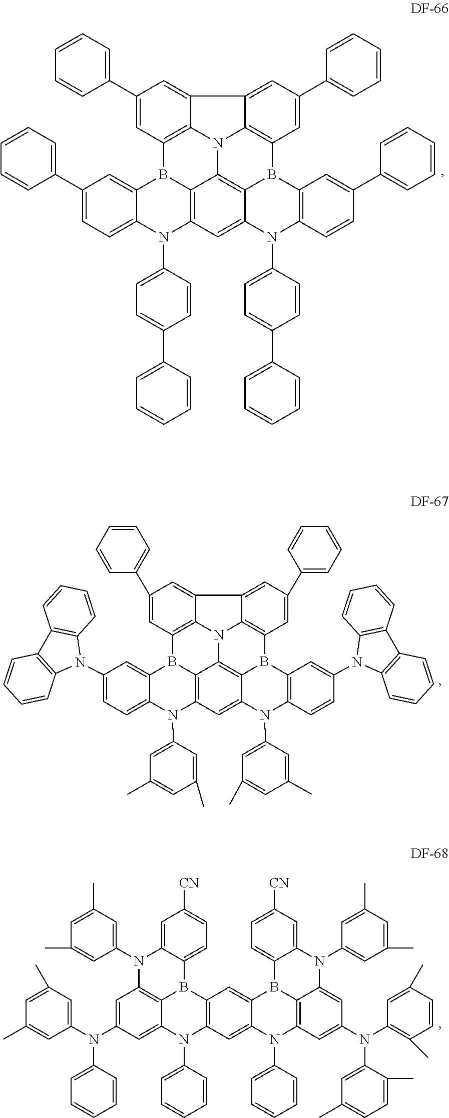 [SMILES: c1ccc(-c2ccc(N3c4ccc(-c5ccccc5)cc4B4c5c3cc3c6c5-n5c7c4cc(-c4ccccc4)cc7c4cc(-c7ccccc7)cc(c45)B6c4cc(-c5ccccc5)ccc4N3c3ccc(-c4ccccc4)cc3)cc2)cc1 ; Cc1cc(C)cc(N2c3ccc(-n4c5ccccc5c5ccccc54)cc3B3c4c2cc2c5c4-n4c6c3cc(-c3ccccc3)cc6c3cc(-c6ccccc6)cc(c34)B5c3cc(-n4c5ccccc5c5ccccc54)ccc3N2c2cc(C)cc(C)c2)c1 ; Cc1cc(C)cc(N(c2ccccc2)c2cc3c4c(c2)N(c2ccccc2)c2cc5c(cc2B4c2ccc(C#N)cc2N3c2cc(C)cc(C)c2)B2c3ccc(C#N)cc3N(c3cc(C)cc(C)c3)c3cc(N(c4cc(C)ccc4C)c4cc(C)ccc4C)cc(c32)N5c2ccccc2)c1] 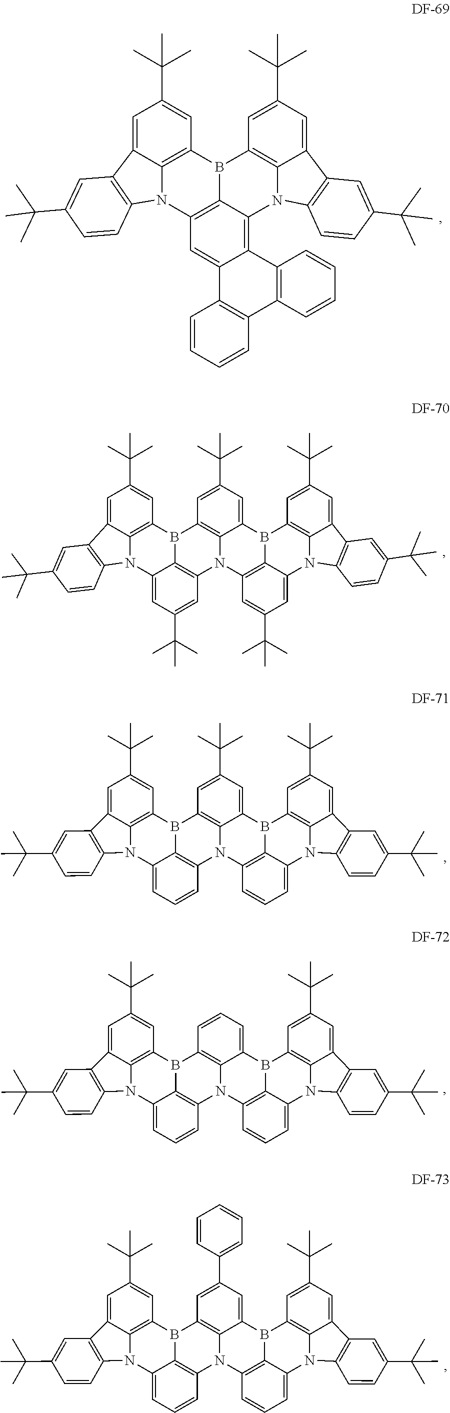 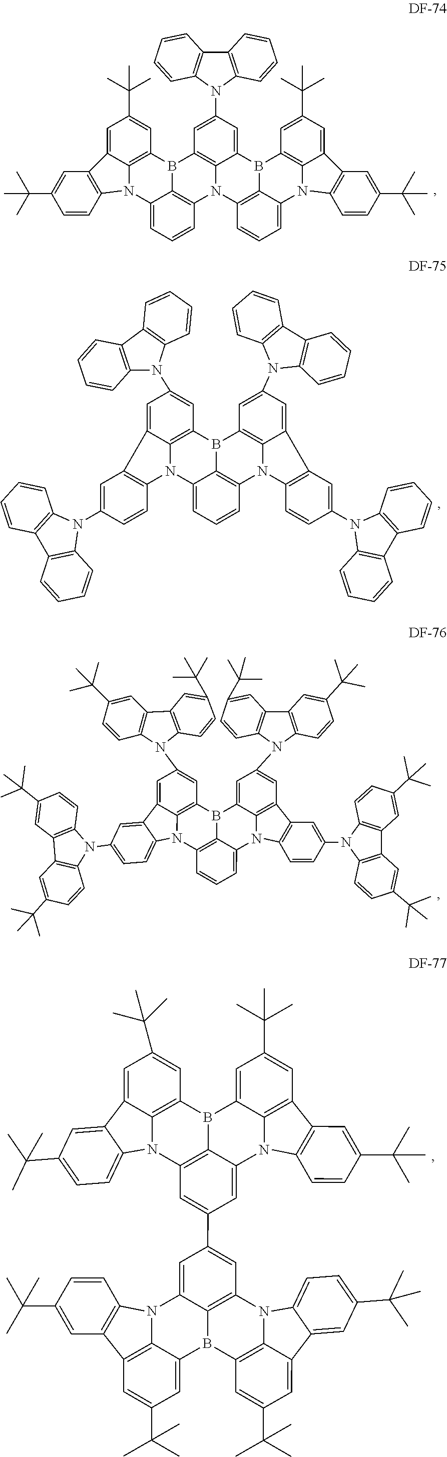 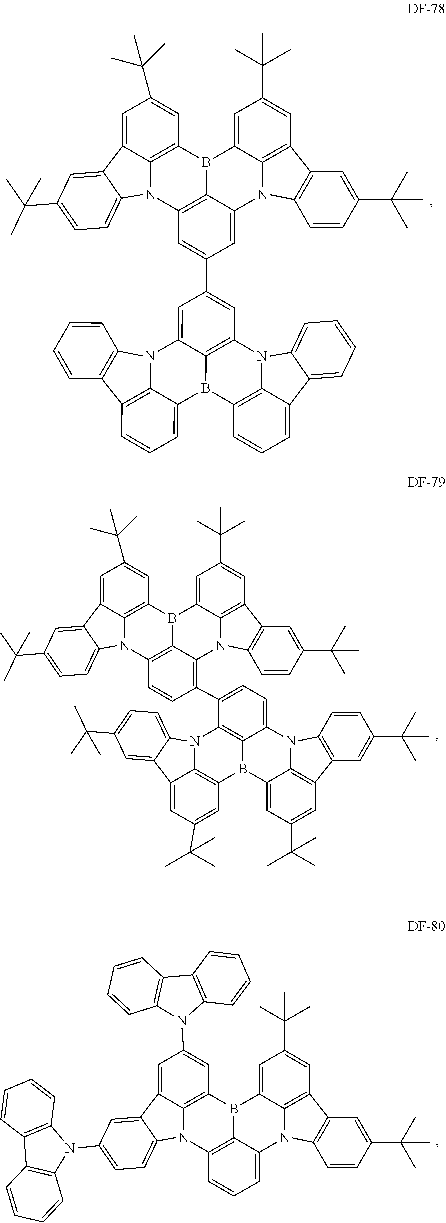 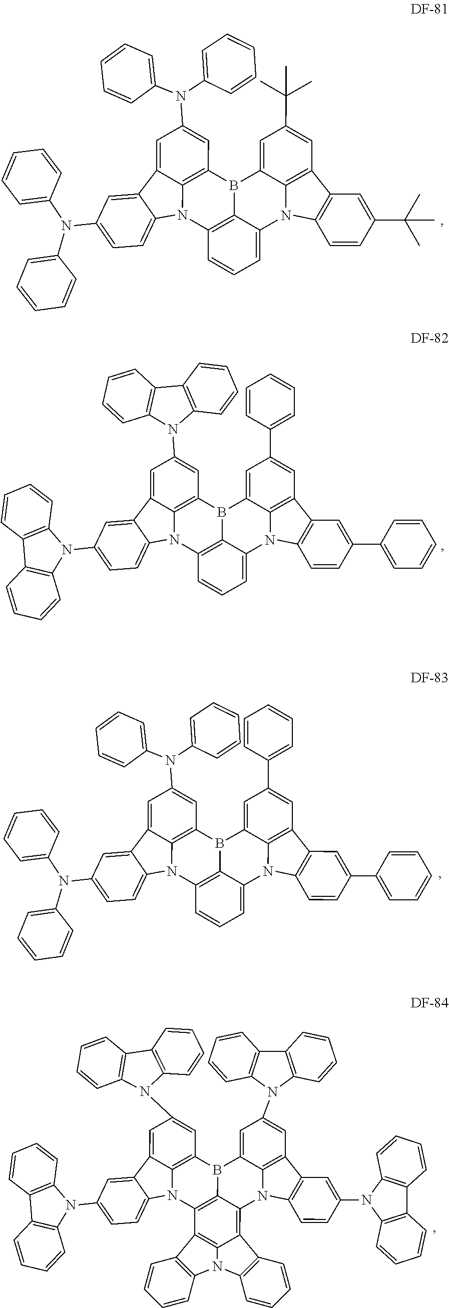 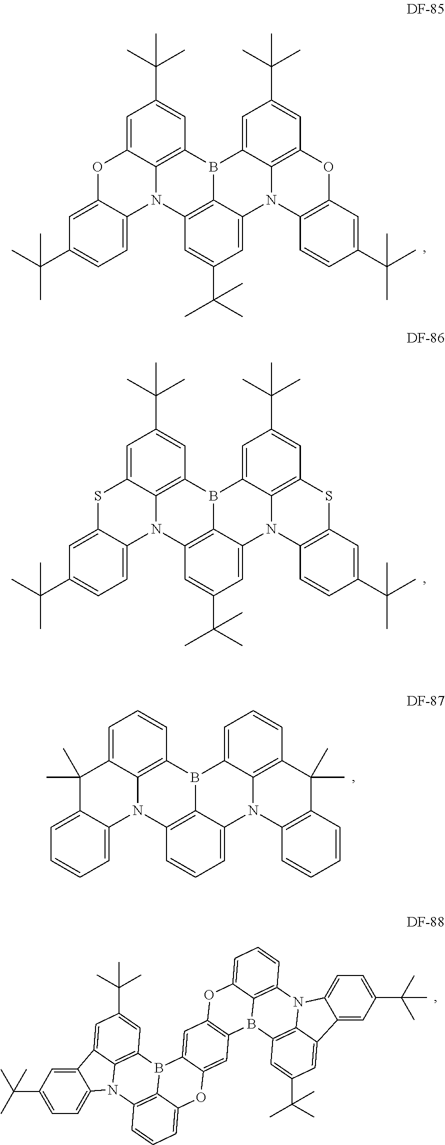 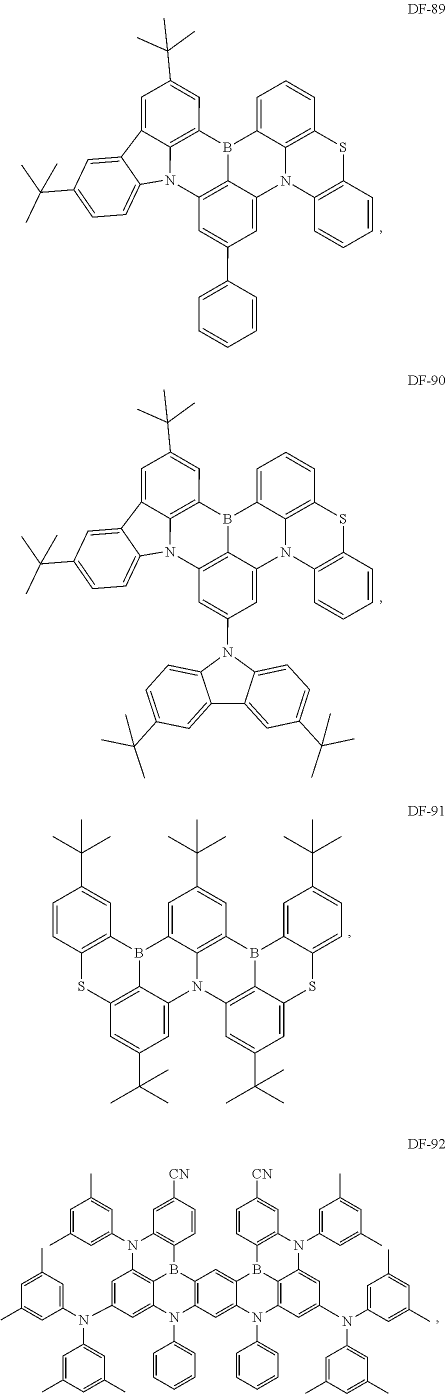 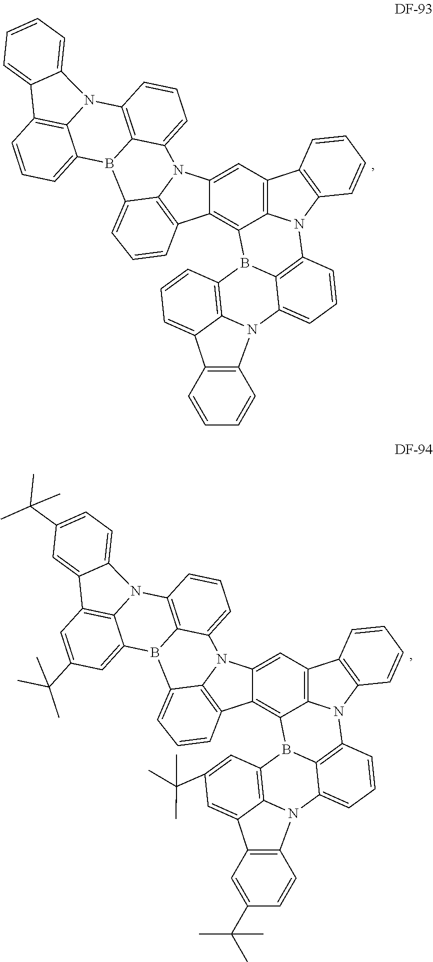 [SMILES: c1cc2c3c(c1)-n1c4ccccc4c4cc5c(c(c41)B3c1cccc3c4ccccc4n-2c13)c1cccc2c1n5-c1cccc3c1B2c1cccc2c4ccccc4n-3c12 ; CC(C)(C)c1ccc2c(c1)c1cc(C(C)(C)C)cc3c1n2-c1cccc2c1B3c1c3c4cccc5c4n(c3cc3c4ccccc4n-2c13)-c1cccc2c1B5c1cc(C(C)(C)C)cc3c4cc(C(C)(C)C)ccc4n-2c13] 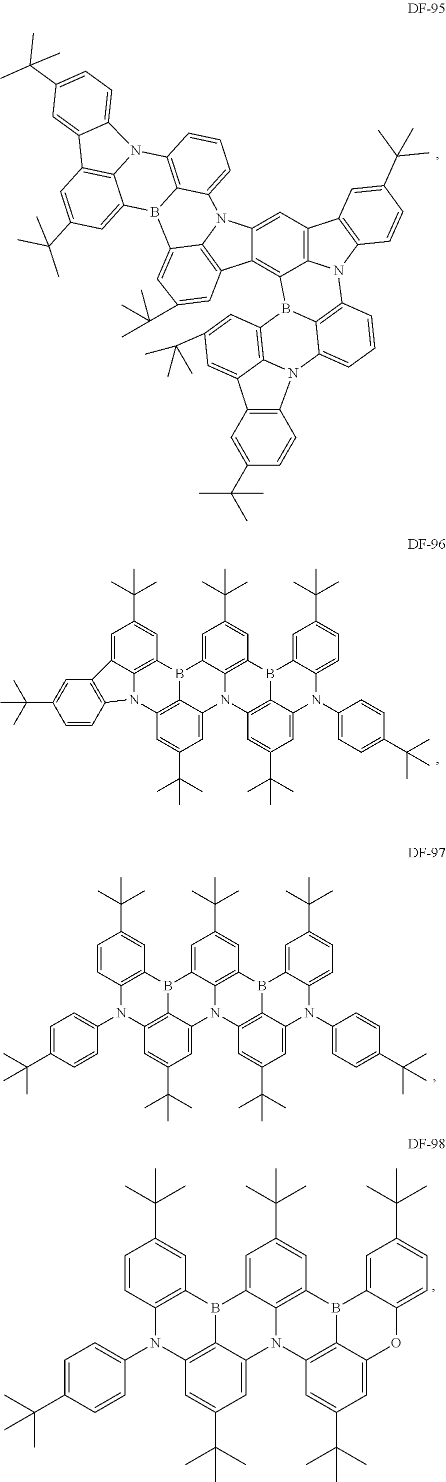 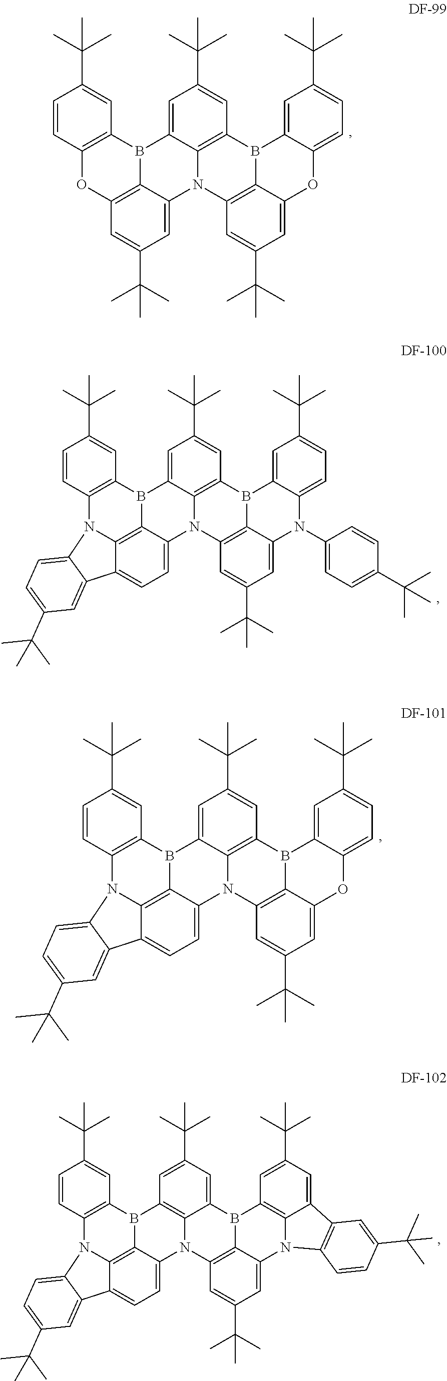 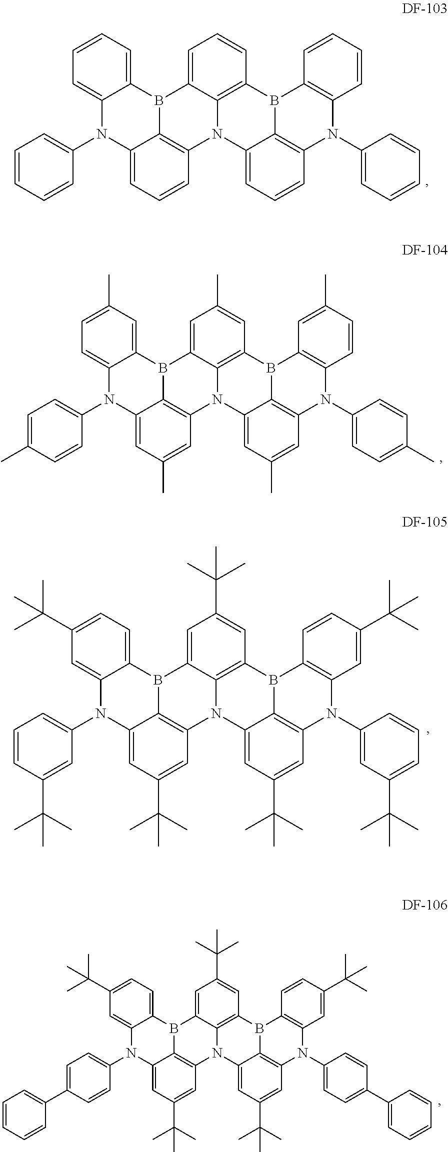 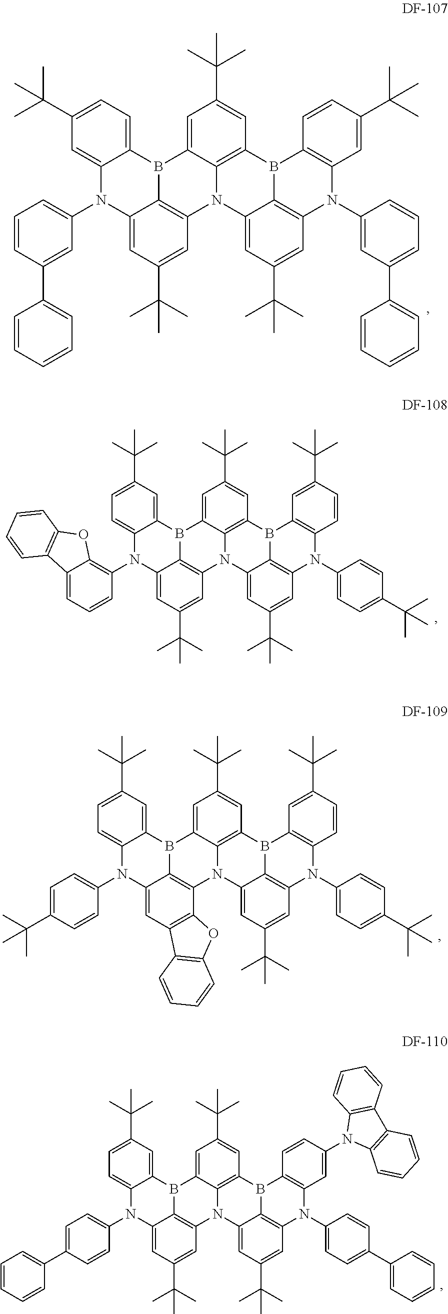 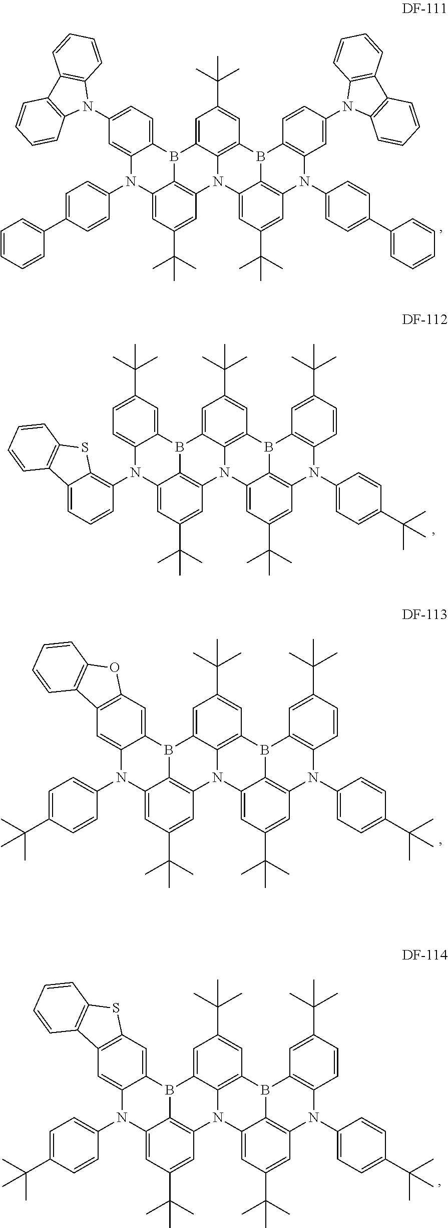 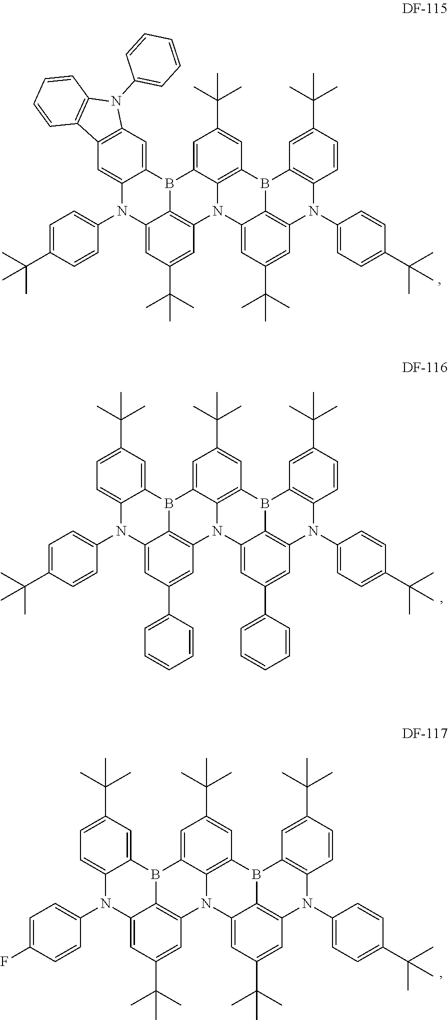 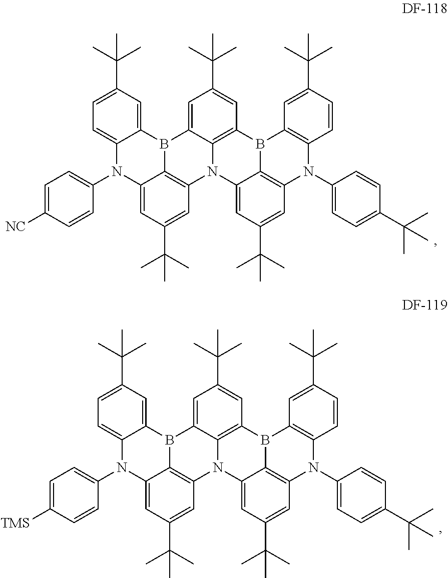 [SMILES: CC(C)(C)c1ccc(N2c3ccc(C(C)(C)C)cc3B3c4cc(C(C)(C)C)cc5c4N(c4cc(C(C)(C)C)cc6c4B5c4cc(C(C)(C)C)ccc4N6c4ccc(C#N)cc4)c4cc(C(C)(C)C)cc2c43)cc1 ; CC(C)(C)c1ccc(N2c3ccc(C(C)(C)C)cc3B3c4cc(C(C)(C)C)cc5c4N(c4cc(C(C)(C)C)cc2c43)c2cc(C(C)(C)C)cc3c2B5c2cc(C(C)(C)C)ccc2N3c2ccc([Si](C)(C)C)cc2)cc1] 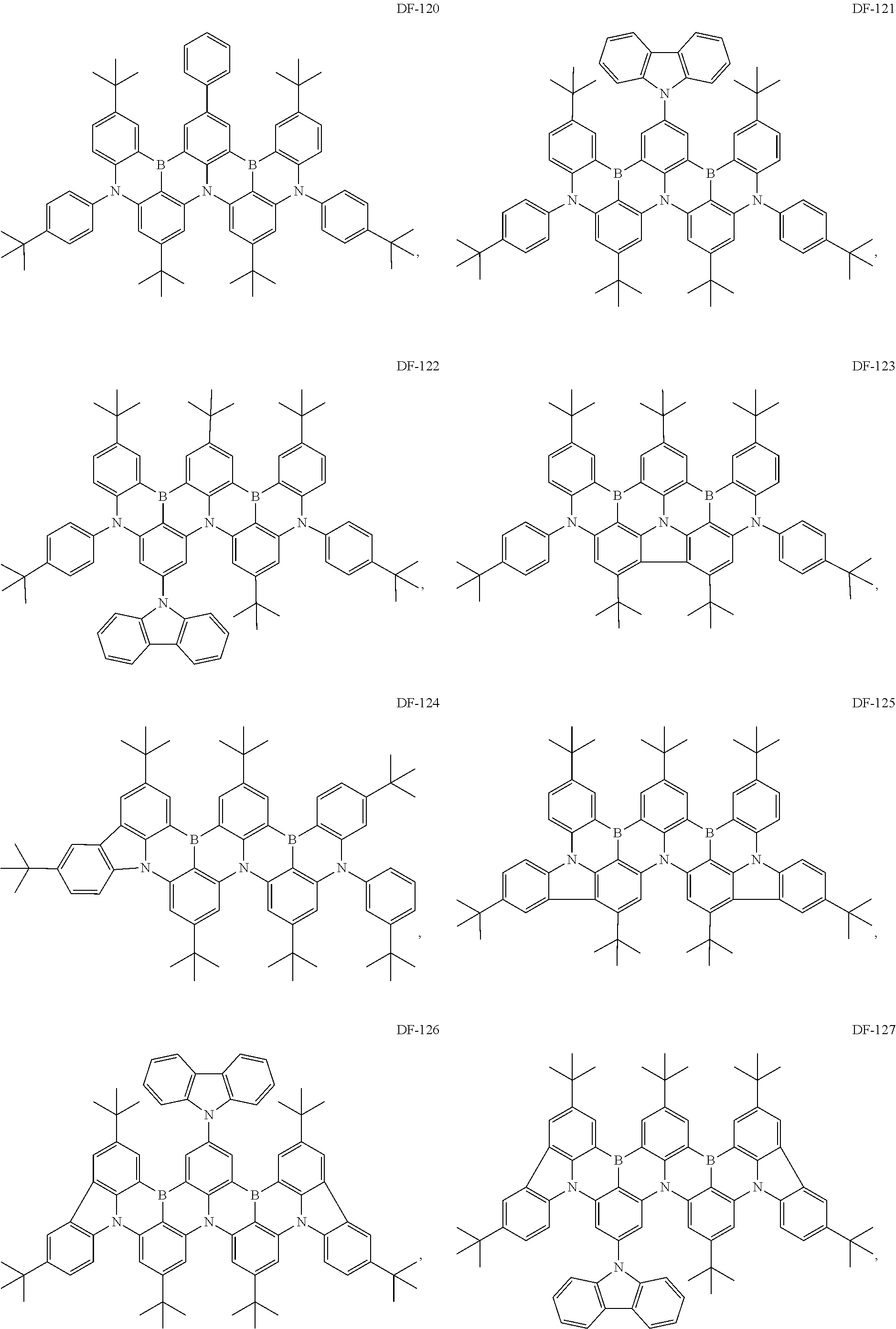 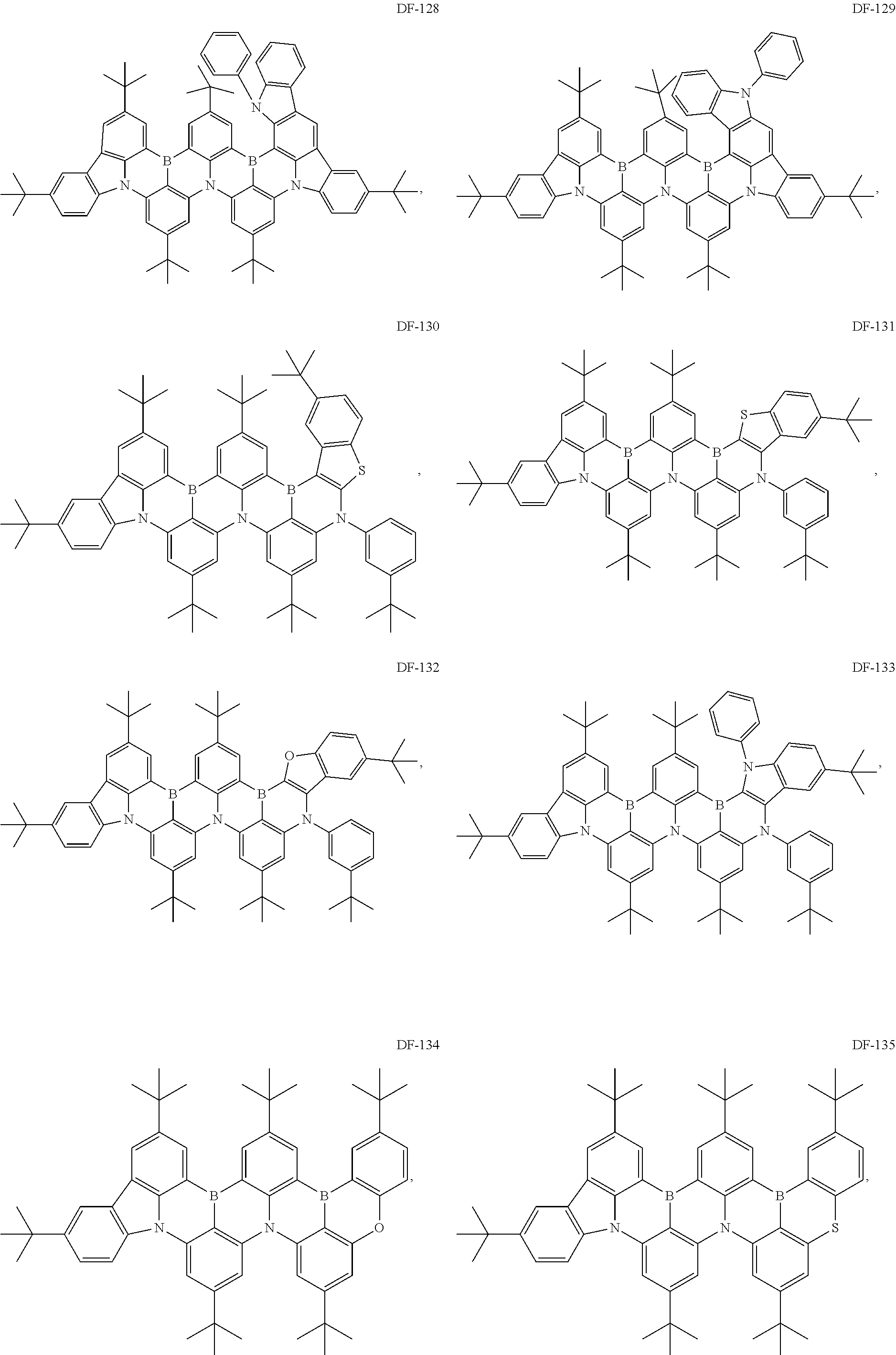 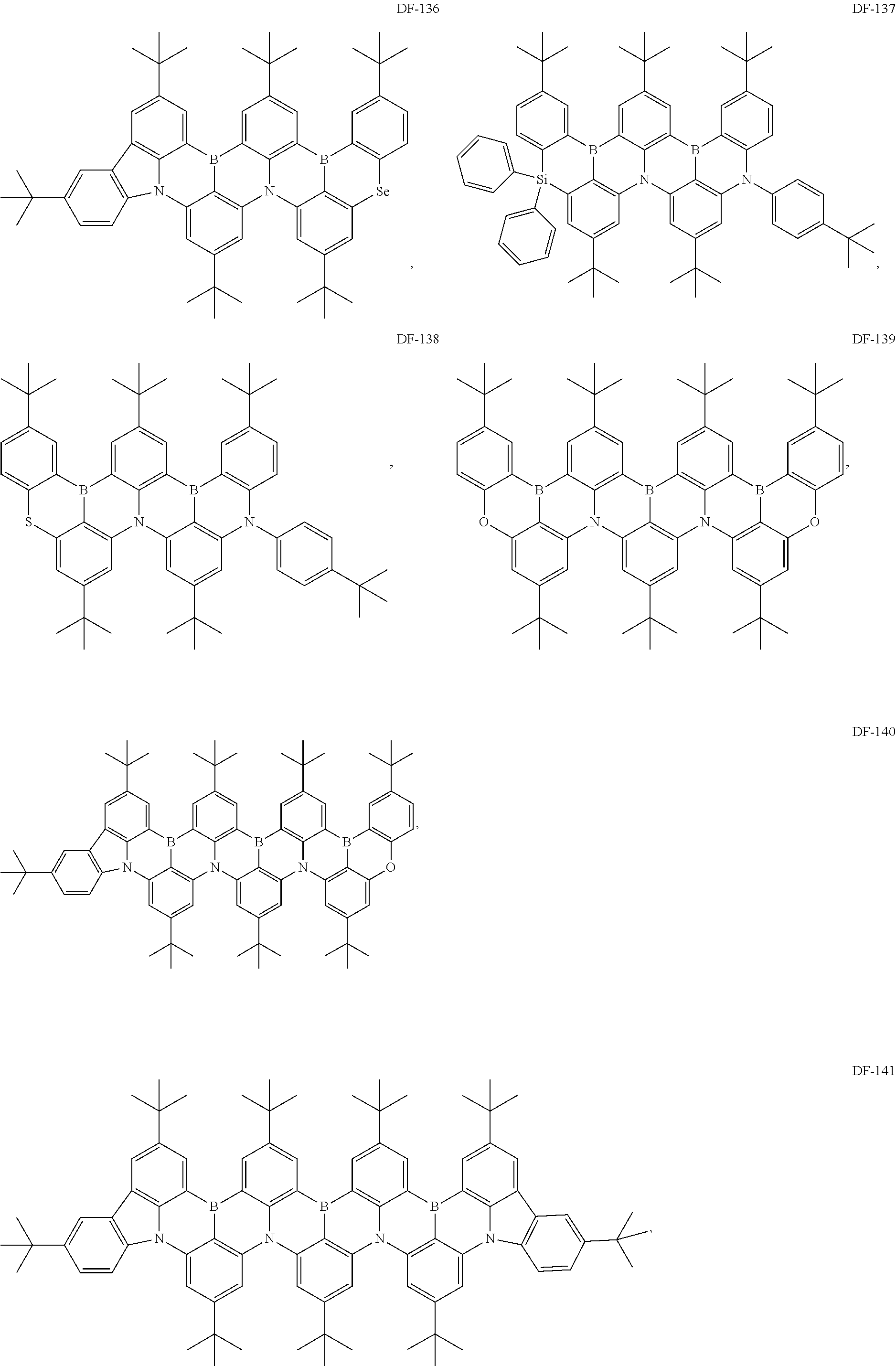 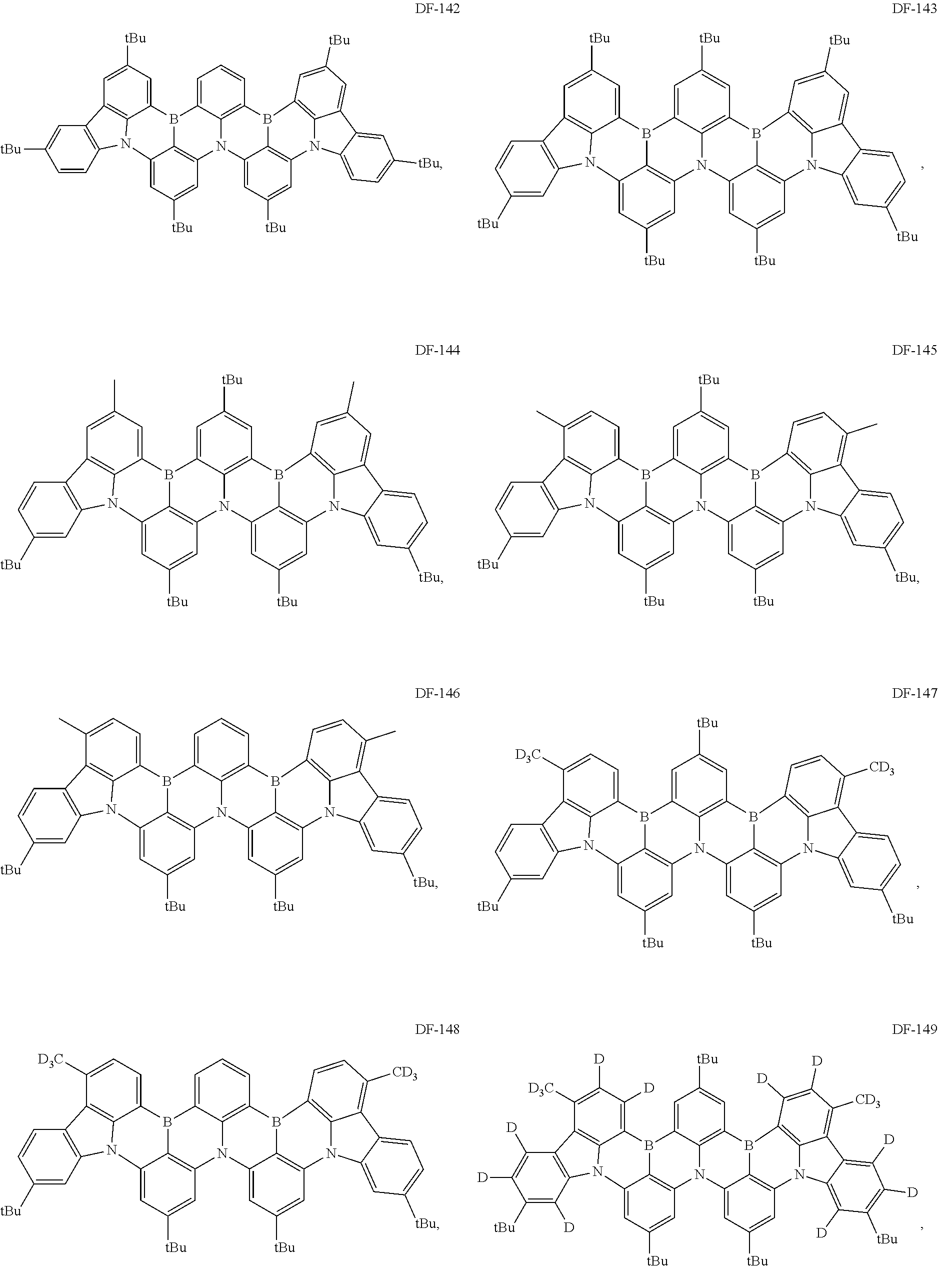 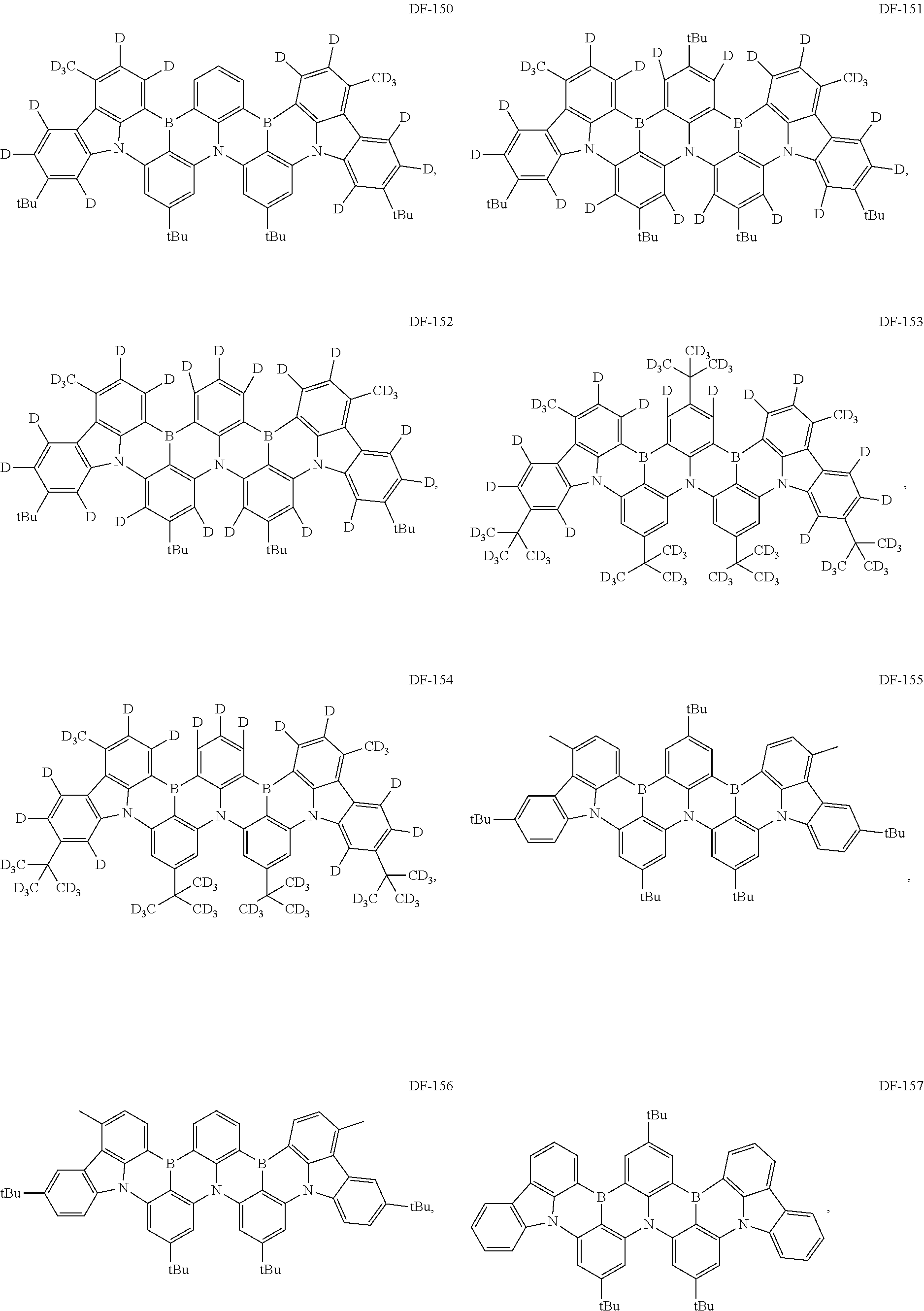 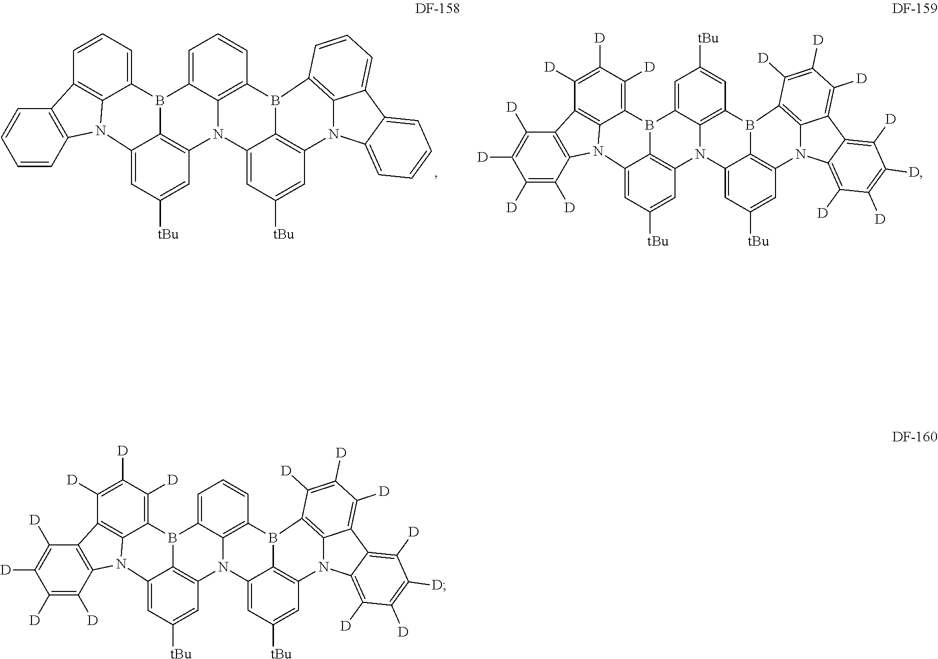
wherein optionally, hydrogen in Compound DF-1 to Compound DF-160 can be partially or fully substituted with deuterium.

26. The organic electroluminescent device of claim 23, wherein the fluorescent material is a delayed fluorescent material; preferably, the fluorescent material is a thermally activated delayed fluorescent material.

27. The organic electroluminescent device of claim 26, wherein the emissive layer further comprises a host material;
preferably, the emissive layer comprises a first host compound;
more preferably, the emissive layer further comprises a second host compound; and
more preferably, the first host compound and/or the second host compound comprise at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

28. A material combination, comprising a phosphorescence sensitizer having a structure of Formula 1 and a fluorescent material;
the fluorescent material comprises at least one B atom;
the phosphorescence sensitizer is a metal complex, and the metal is Ir;
the phosphorescence sensitizer comprises a structure represented by a fragment of Formula 1; 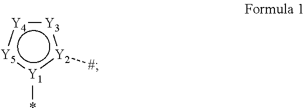
wherein “#” represents a position where the metal Ir is joined, and “*” represents a position where another fragment in the metal complex is joined;
Y₁ and Y₂ are each independently selected from C or N;
Y₃ to Y₅ are each independently selected from CR_{y}, N, NR_{y1}, O or Se;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{y} and R_{y1} can be optionally joined to form a ring; and
the phosphorescence sensitizer comprises at most two fragments of Formula 1.

29. A display assembly, comprising the organic electroluminescent device of claim 1.
